(19) United States
(12) Patent Application Publication
(10) Pub. No.: US 2022/0416167 A1
(43) Pub. Date: Dec. 29, 2022

(54) OSMIUM-CONTAINING CONJUGATED POLYMER AND METHODS THEREOF

(71) Applicant: Xiamen University, Xiamen (CN)

(72) Inventors: Haiping Xia, Xiamen (CN); Shiyan Chen, Xiamen (CN); Xiang Gao, Xiamen (CN); Ying Zhang, Xiamen (CN); Yanan Liu, Xiamen (CN); Yongfa Zhu, Xiamen (CN); Lixia Peng, Xiamen (CN); Yapeng Cai, Xiamen (CN); Qingde Zhuo, Xiamen (CN); Liulin Yang, Xiamen (CN); Xumin He, Xiamen (CN); Hong Zhang, Xiamen (CN)

(21) Appl. No.: 17/860,505

(22) Filed: Jul. 8, 2022

Related U.S. Application Data
(63) Continuation of application No. PCT/CN2021/071324, filed on Jan. 12, 2021.

(30) Foreign Application Priority Data
Jan. 16, 2020 (CN) 202010057042.4
Nov. 6, 2020 (CN) 202011235716.1

(51) Int. Cl. H01L 51/00; C08G 61/12; C09K 11/06

(52) U.S. Cl. CPC H01L 51/0035; C08G 61/123; C09K 11/06; H01L 51/0039; H01L 51/0043; H01L 51/5012

(57) ABSTRACT

An osmium-containing conjugated polymer and methods thereof. A structural formula of the osmium-containing conjugated polymer is formula I, a reaction formula of the osmium-containing conjugated polymer is a formula II.

### RELATED APPLICATIONS

This application is a continuation of and claims priority to International patent application number PCT/CN2021/071324, filed Jan. 12, 2021, which claims priority to Chinese patent application number 202010057042.4, filed on Jan. 16, 2020 and Chinese patent application number 202011235716.1, filed on Nov. 6, 2020. International patent application number PCT/CN2021/071324, Chinese patent application number 202010057042.4, and Chinese patent application number 202011235716.1 are incorporated herein by reference.

### FIELD OF THE DISCLOSURE

The present disclosure relates to a technical field of metal-organic chemistry, and in particular relates to an osmium-containing conjugated polymer and methods thereof.

### BACKGROUND OF THE DISCLOSURE

Conjugated polymer refers to polymers with large conjugated delocalized t bonds. Its main feature is that electrons and energy can migrate throughout the polymer backbone. Not only does conjugated polymer have excellent photoelectric properties but conjugated polymer also has good processing and mechanical properties (Chemical reviews 2007, 107 (4), 1324-38). Because of its application in light emitting diodes (LEDs) (J. Mater. Chem. C 2015, 3 (13), 2974-3002), solar cells (Advanced materials 2014, 26 (7), 1006-24), chemical sensors (Nature communications 2014, 5, 5404), and other fields, it has attracted much attention. However, traditional organic conjugated polymer materials can no longer meet the development needs of future energy chemistry.

The introduction of transition metals into the framework of organic primitives can bring about subversive mutations in the basic properties of substances, thus exhibiting unique properties. For example, in 2013, Xia et al. (Nat. Chem. 2013, 5, 698-703) reported a new type of metal bridged metal heterofused ring compound-osmium heteropentane compound. The compound has the characteristics of aggregation-induced luminescence enhancement effect, large stock shift, and long luminescence lifetime, and has important application prospects in the field of organic optoelectronics. In 2014, Xia et al. reported osmium heteropentylene compounds with specific substituents, which have good ultraviolet (UV)-visible light absorption properties (Angew. Chem. Int. Ed. 2014, 53, 6232-6236). In 2015, Xia et al. reported another type of metal bridged osmium heterocyclic compound, which has good photoacoustic imaging and photothermal performance, and has potential application prospects in tumor diagnosis and treatment (Angew. Chem. Int. Ed. 2015, 54, 6181-6185). In 2017, Xia et al. reported another type of metal osmium heteropentalyne derivative substituted with rivet groups, which have good single-molecule conductivity (J. Am. Chem. Soc., 2017, 139, 14344-14347).

The metal-organic π-conjugated (dπ-pπ conjugated) system is quite different from the pure organic π-conjugated (pπ-pπ conjugated) system. Conjugated polymers containing transition metals are also quite different from traditional pure organic conjugated polymers. The introduction of transition metal elements into the backbone of the conjugated polymer can enhance its spin-orbit coupling (SOC) and promote intersystem crossing (ISC) from singlet to triplet, to make the conjugated polymer obtain more triplet excited states, thereby exhibiting different physical properties (Chem. Soc. Rev. 2016, 45 (19), 5264-5295). Compared with the adjacent conjugated organic unit, its metal center has more electron-rich structure characteristics. It can induce better migration of electrons and energy on the polymer. At the same time, due to the variety of transition metals, adjustable valence states, longer excited state lifetime, and strong designability of functional ligands, not only is the designability of the polymer structure increased, but the linking groups with different function orientations can also realize the functionalization of the final polymer. Conjugated polymers containing transition metals are expected to become a new functional materials for applications in the field of energy chemistry.

A new type of metal bridging metal heteroaromatic compound-osmium heteropentane compound, which is stable, introduces the d orbital of transition metal osmium into the organic π-conjugated framework, forming a unique d_{π}-p_{π} conjugated system, making it exhibit completely different physical properties (Acc. Chem. Res. 2018, 51, 1691-1700). For example, it has important application prospects in the enhancement of aggregation-induced luminescence (Nat. Chem. 2013, 5, 698-703) and the electron transport layer of organic solar cells (Nat. Commun. 2020, 11, 4651). The new system means new materials. The introduction of the metal osmium heteropentalyne into the main chain of the conjugated polymer will hopefully obtain a new class of d_{π}-p_{π} conjugated polymer materials, which will exhibit richer properties and new functions. Therefore, it is particularly important to develop a method and strategy for synthesizing conjugated polymer with osmium-containing heteropentylene in the main chain.

However, the synthesis of such polymers is extremely difficult, which further hinders the application research of its performance. Therefore, it is particularly important to develop a simple and rapid method and strategy for synthesizing transition metal-containing conjugated polymers.

### BRIEF SUMMARY OF THE DISCLOSURE

An objective of the present disclosure is to provide an osmium-containing conjugated polymer, a repeating unit of the osmium-containing conjugated polymer consists of osmapentalyne groups, a conjugated linking group R₁, and a vinyl group. A third position of an osmapentalyne group is connected to the conjugated linking group R₁, and the conjugated linking group R₁ is then connected to the vinyl group. The vinyl group is connected to a seventh position of a next osmapentalyne group of osmapentalyne groups, and a structural formula of the osmium-containing conjugated polymer is as follows:

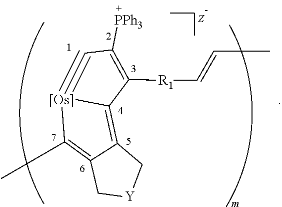

The [Os] is OsAL₂, OsA₂L, or OsL₃, wherein A is at least one of —H, halogen group, —SCN, or —CN, and L is at least one of a phosphine ligand, a CO ligand, a pyridine ligand, a nitrogen heterocyclic carbene ligand, a nitrile ligand, or an isocyanic two-electron ligands. The halogen group is at least one of —F, —Cl, —Br or —I.

The Y is at least one of CH₂, O, C(COO(CH₂)ₖMe)₂, N, or S, wherein k is an integer between 0 and 18, k is preferably an integer between 0 and 12, and k is more preferably an integer between of 0 and 6.

The conjugated linking group R₁ is at least one of a first substituted aryl group, a first unsubstituted aryl group, a substituted alkenyl group, an unsubstituted alkenyl group, a substituted alkynyl group, or an unsubstituted alkynyl group, wherein a substituted vinyl group or an unsubstituted vinyl group is a trans vinyl group when the substituted alkenyl group or the unsubstituted alkenyl group is the substituted vinyl group or the unsubstituted vinyl group.

The Z⁻ is an anion.

In a preferred embodiment of the present disclosure, the anion comprises at least one of F⁻, Cl⁻, Br⁻, I⁻, BF₄⁻, H₂PO₄⁻, C₂O₄²⁻, SO₄²⁻, CF₃SO₃⁻, CH₃COO⁻, (CF₃SO₂)₂N⁻, NO₃⁻, ClO₄⁻, PF₆⁻, or BPh₄⁻. In a more preferred embodiment, the anion comprises at least one of Cl⁻, Br⁻, BF₄⁻, CF₃SO₃⁻, PF₆⁻, or BPh₄⁻.

In a preferred embodiment of the present disclosure, the m is an integer between 3 and 300, the m is preferably an integer between 3 and 200, and the m is more preferably an integer between 3 and 100.

In a preferred embodiment, a phosphine ligand of the L in the [Os] comprises at least one of alkyl phosphine, cycloalkyl phosphine, or arylphosphine with 3-24 carbon atoms, preferably 5-20 carbon atoms, more preferably with 6-18 carbon atoms. In a more preferred embodiment, the phosphine ligand is at least one of trimethylphosphine, triethylphosphine, tripropylphosphine, triisopropylphosphine, tri-tert-butylphosphine, tricyclohexylphosphine, or triphenylphosphine.

In a preferred embodiment, a pyridine ligand of the L in the [Os] is a ligand containing a pyridine structural unit or bipyridine structural unit. Preferably, the pyridine ligand is at least one of methylpyridine, ethylpyridine, 1,4-bipyridine, 1,2-bis(4-pyridyl)ethylene, vinylpyridine, ethynylpyridine, pyridine boronic acid, aminopyridine, cyanopyridine, mercaptopyridine, dimethylaminopyridine, phenylpyridine, or 1,2-bis(4-pyridyl)ethane.

In a preferred embodiment, an N-heterocyclic carbene ligand of the L in the [Os] is any ligand containing an N-heterocyclic carbene structural unit, the N-heterocyclic carbene ligand is preferably at least one of an imidazole-type N-heterocyclic carbene, imidazoline-type N-heterocyclic carbene, thiazole-type N-heterocyclic carbene, or triazole-type N-heterocyclic carbene.

In a preferred embodiment, a nitrile ligand of the L in the [Os] is a ligand containing a nitrile group structural unit, and the nitrile ligand is preferably acetonitrile, propionitrile, or benzonitrile.

In a preferred embodiment, an isocyanate-type two-electron ligand of the L in the [Os] is a ligand containing an isocyano structural unit, the isocyanate-type two-electron ligand is preferably at least one of cyclohexyl isocyanide, tert-butyl isocyanide, or phenyl isocyanide.

In a preferred embodiment of the present disclosure, the L in the [Os] is at least one of triphenylphosphine, trimethylphosphine, triethylphosphine, tripropylphosphine, triisopropylphosphine, tri-tert-butylphosphine, tricyclohexylphosphine, methylpyridine, ethylpyridine, 1,4-bipyridine, 1,2-bis(4-pyridyl)ethylene, vinylpyridine, ethynyl Pyridine, pyridine boronic acid, aminopyridine, cyanopyridine, mercaptopyridine, dimethylaminopyridine, phenylpyridine, 1,2-bis(4-pyridyl)ethane, imidazole-type N-heterocyclic carbene, imidazoline-type N-heterocyclic carbene, thiazole-type N-heterocyclic carbene, triazol-type N-heterocyclic carbene, acetonitrile, propionitrile, benzonitrile, cyclohexyl isocyanide, tert-butyl isocyanide, or phenyl isocyanide.

In a preferred embodiment, the L₂ in the [Os] is at least one of a bidentate nitrogen ligand, a bidentate phosphine ligand, a bidentate carbon-nitrogen ligand, or a bidentate oxygen-nitrogen ligand.

In a preferred embodiment, the bidentate nitrogen ligand of the L₂ in the [Os] is a ligand using a bidentate nitrogen atom as a coordinating atom, and the bidentate nitrogen ligand comprises at least one of ethylenediamine, 2,2′-bipyridine, or 1,10-phenanthroline.

In a preferred embodiment, the bidentate phosphine ligand of the L₂ in the [Os] is a ligand using a bidentate phosphine atom as a coordinating atom, and the bidentate phosphine ligand comprises at least one of 1,1-bis(diphenylphosphino)methane (DPPM), 1,2-Bis(diphenylphosphino)ethane (DPPE), or 1,3-bis(diphenylphosphino) propane (DPPP).

In a preferred embodiment, the bidentate carbon-nitrogen ligand of the L₂ in the [Os] is a ligand using a bidentate carbon-nitrogen atom as a coordinating atom, and the bidentate carbon-nitrogen ligand comprises ortho-phenylpyridine.

In a preferred embodiment, the bidentate oxygen-nitrogen ligand of the L₂ in the [Os] is a ligand using a bidentate oxygen-nitrogen atom as a coordinating atom, and the bidentate oxygen-nitrogen ligand comprises 8-hydroxyquinoline.

In a preferred embodiment of the present disclosure, the L₂ in the [Os] is integrated, and L₂ is at least one of ethylenediamine, 2,2′-bipyridine, 1,10-phenanthroline, 1,1-bis(diphenylphosphine)methane, 1,2-bis (diphenylphosphine)ethane, 1,3-bis(diphenylphosphine)propane, ortho-phenylpyridine, or 8-hydroxyquinoline.

In a preferred embodiment, the AL₂ in the [Os] is a terpyridine or a tridentate pincer (clamp-shaped) ligand, the tridentate pincer (clamp-shaped) ligand comprises a clamp-shaped ligand, and the clamp-shaped ligand comprises at least one of a PPP-type tridentate ligand, a PNP-type tridentate ligand, a PCP-type tridentate ligand, an NNN-type tridentate ligand, an NCN-type tridentate ligand, an NPN-type tridentate ligand, an ONO-type tridentate ligand, an OPO-type tridentate ligand, an OCO-type tridentate ligand, an SCS-type tridentate ligand, or a CCC-type tridentate ligand.

In a preferred embodiment of the present disclosure, the AL₂ in the [Os] is integrated, and the AL₂ is at least one of a terpyridine, a PPP-type tridentate ligand, a PNP-type tridentate ligand, a PCP-type tridentate ligand, an NNN-type tridentate ligand, an NCN-type tridentate ligand, an NPN-type tridentate ligand, an ONO-type tridentate ligand, an OPO-type tridentate ligand, an OCO-type tridentate ligand, an SCS-type tridentate ligand, or a CCC-type tridentate ligand.

In a preferred embodiment, the first substituted aryl group or the first unsubstituted aryl group is at least one of phenyl, diphenyl, terphenyl, naphthyl, anthryl, fiki, pyrene, thienyl, dithienyl, terthienyl, dithienylethene, thiazolyl, thiadiazolyl, bis-thiadiazolyl, bis-terthienyl, furanyl, pyridyl, pyrrolyl, porphyrin, fluorenyl, bifluorenyl, terfluorenyl, carbazolyl, bicarbazolyl, tercarbazolyl, benzothiadiazolyl, tetrastyryl, hexabenzocoronyl, diketopyrrolopyrrole-based, benzodithienyl, indacenodithienyl, silyl fluorenyl, dithienocyclodecadiene, dithienosilole-based, dithienopyrrole-based, triphenylamino, naphthalenedithiadiazolyl, naphthalenetetracarboxylic diimide-based, perylenetetracarboxylic diimide-based, isoindigo-based, thienopyrroledione-based, benzopyrroledione-based, benzotriazolyl, thiadiazolobenzotriazolyl, pyridothiadiazolyl, or thieno[3,4-b]thienyl.

Further, the first substituted aryl group or the first unsubstituted aryl group can improve conductive performance of the osmium-containing conjugated polymer. Substitution reactions at all positions of the first substituted aryl group or the first unsubstituted aryl group can occur.

Even further, a substitution base used in a substitution reaction with an aryl group comprises alkyl with 1-28 carbon atoms, preferably alkyl with 1-20 carbon atoms, more preferably alkyl with 1-14 carbon atoms, alkoxy, alkylthio, acyl, ester, amino, or amide with 1-20 carbon atoms, preferably alkoxy, alkylthio, acyl, ester, amine, or amide with 1-17 carbon atoms, more preferably alkoxy, alkylthio, acyl, ester, amine, or amide with 1-14 carbon atoms, amide substituted with 2-20 carbon atoms, preferably amide substituted with 2-17 carbon atoms, more preferably amide substituted with 2-8 carbon atoms, cycloalkyl with 3-20 carbon atoms, preferably cycloalkyl with 3-17 carbon atoms, more preferably cycloalkyl with 3-8 carbon atoms, alkenyl or alkynyl with 1-20 carbon atoms, preferably alkenyl or alkynyl with 1-17 carbon atoms, more preferably alkenyl or alkynyl with 1-14 carbon atoms, nitro, cyano, or halogen. The substitution base can improve water solubility of the osmium-containing conjugated polymer.

Specially, the alkyl with the 1-28 carbon atoms is at least one of methyl, ethyl, n-propyl, isopropyl, n-butyl, isobutyl, sec-butyl, tert-butyl, n-pentyl, isopentyl, neopentyl, sec-pentyl, tert-pentyl, n-hexyl, isohexyl, neohexyl, sec-hexyl, tert-hexyl, n-heptyl, isoheptyl, neoheptyl, sec-heptyl, tert-heptyl, n-octyl, isooctyl, neooctyl, sec-octyl, tert-octyl, n-dodecyl, n-hexadecyl, n-octadecyl, n-eicosyl,

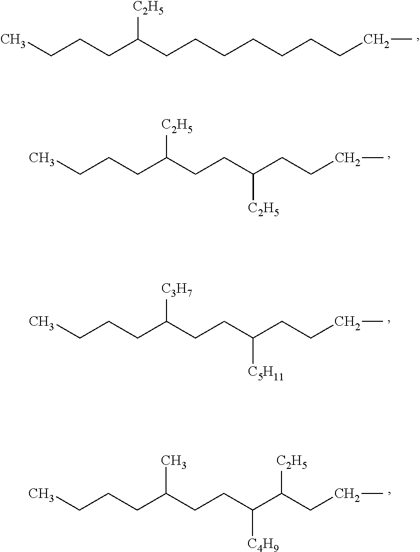

2-ethylhexyl, 2-butylhexyl, 2-hexyloctyl, 2-octyldecyl, 2-decyldodecyl, 2-decyltetradecyl, or 2-dodecylhexadecyl.

Specially, the alkoxy with the 1-20 carbon atoms is at least one of methoxy, ethoxy, n-propoxy, isopropoxy, n-butoxy, isobutoxy, sec-butoxy, tert-butoxy, n-pentyloxy, isopentyloxy, neopentyloxy, sec-pentyloxy, tert-pentyloxy, n-hexyloxy, isohexyloxy, neohexyloxy, sec-hexyloxy, tert-hexyloxy, n-heptyloxy, isoheptyloxy, neoheptyloxy, sec-heptyloxy, tert-heptyloxy, n-octyloxy, isooctyloxy, neooctyloxy, sec-octyloxy, tert-octyloxy, n-dodecyloxy, n-hexadecyloxy, n-octadecyloxy, or n-eicosyloxy.

Specially, the alkylthio with the 1-20 carbon atoms is at least one of methylthio, ethylthio, n-propylthio, isopropylthio, n-butylthio, isobutylthio, sec-butylthio, tert-butylthio, n-pentylthio, isopentylthio, neopentylthio, sec-pentylthio, tert-pentylthio, n-hexylthio, isohexylthio, neohexylthio, sec-hexylthio, tert-hexylthio, n-heptylthio, isoheptylthio, neoheptylthio, sec-heptylthio, tert-heptylthio, n-octylthio, isooctylthio, neooctylthio, sec-octylthio, tert-octylthio, n-dodecylthio, n-hexadecylthio, n-octadecylthio, or n-eicosylthio.

Specially, the acyl with the 1-20 carbon atoms is at least one of

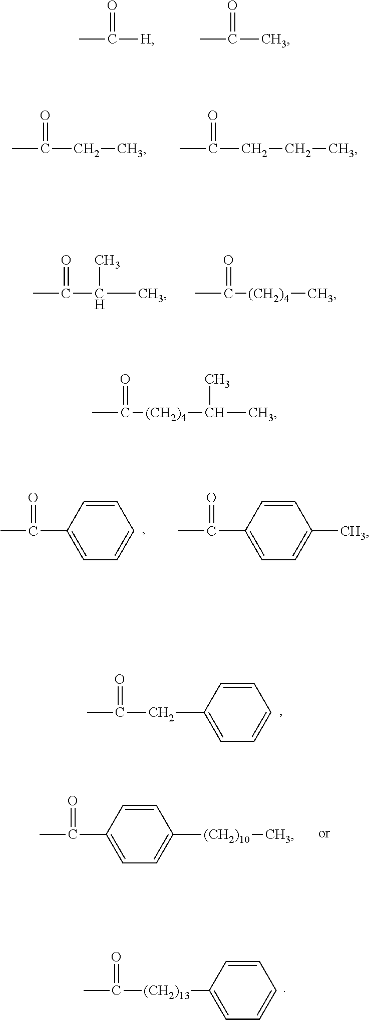

Specially, the ester with the 1-20 carbon atoms is a monovalent group with 1-20 carbon atoms and containing

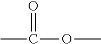

of an ester bond. The ester with the 1-20 carbon atoms is at least one of

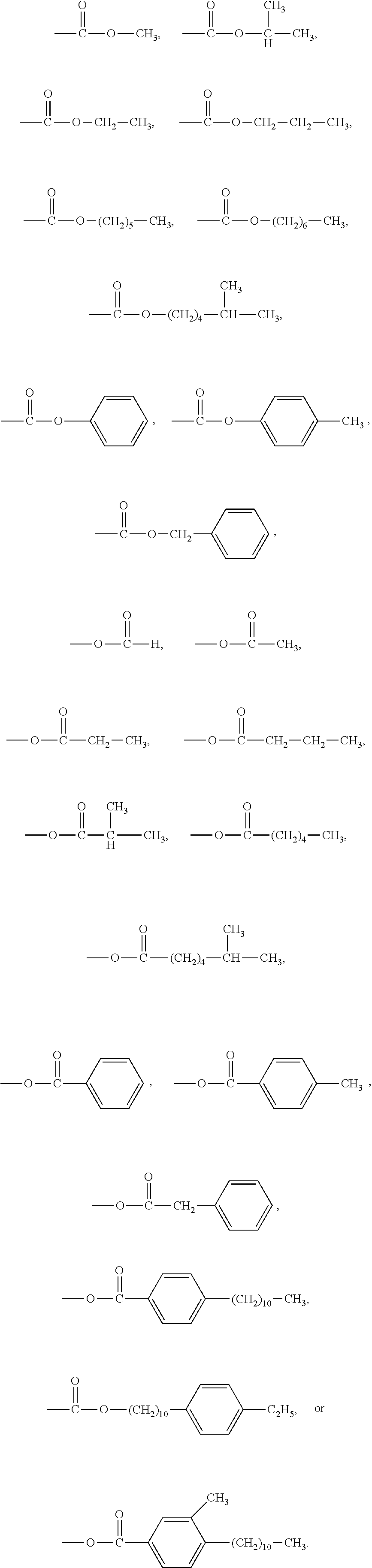

Specially, the amino with the 1-20 carbon atoms is at least one of methylamino, ethylamino, propylamino, butylamino, pentylamino, hexylamino, heptylamino, actylamino, dimethylamino (NMe2), diethylamino (NEt2), dipropylamino, dibutylamino, n-dodecylamino, n-hexadecylamino, n-octadecylamino, or n-eicosylamino.

Specially, the amide with the 1-20 carbon atoms is a monovalent group with 1-20 carbon atoms and containing

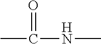

of an amide bond. The amide with the 1-20 carbon atoms is at least one of

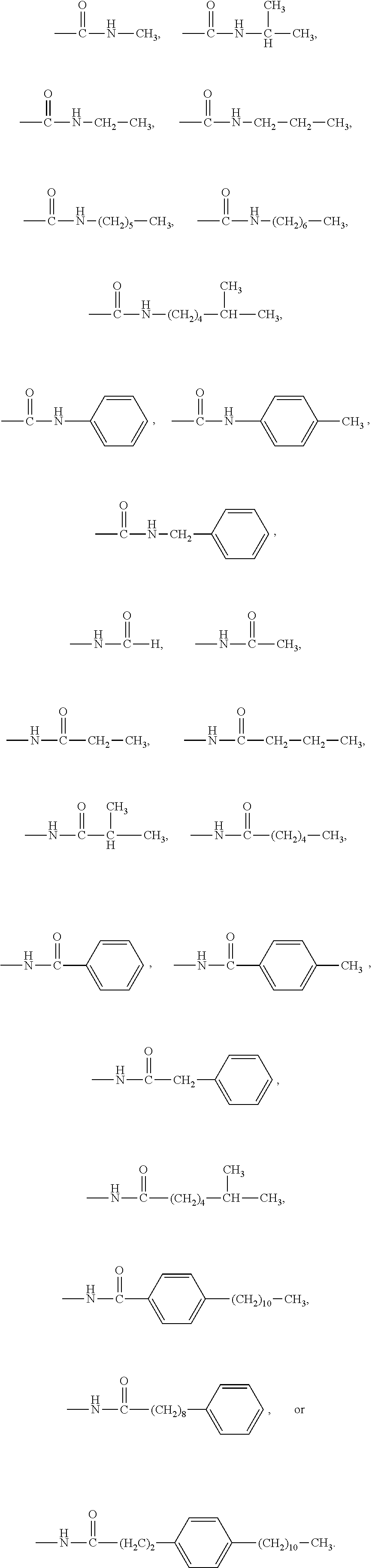

Specially, the amide substituted with 2-20 carbon atoms is a substitution base that hydrogen connected to N in an amide bond

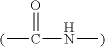

of the amide substituted with 2-20 carbon atoms is substituted by an alkyl with 1-20 carbon atoms, preferably 1-17 carbon atoms, more preferably 1-8 carbon atoms. The alkyl with the 1-20 carbon atoms, preferably the 1-17 carbon atoms, more preferably the 1-8 carbon atoms is same as the alkyl with the 1-28 carbon atoms.

Specially, the amide substituted with 2-20 carbon atoms is at least one of

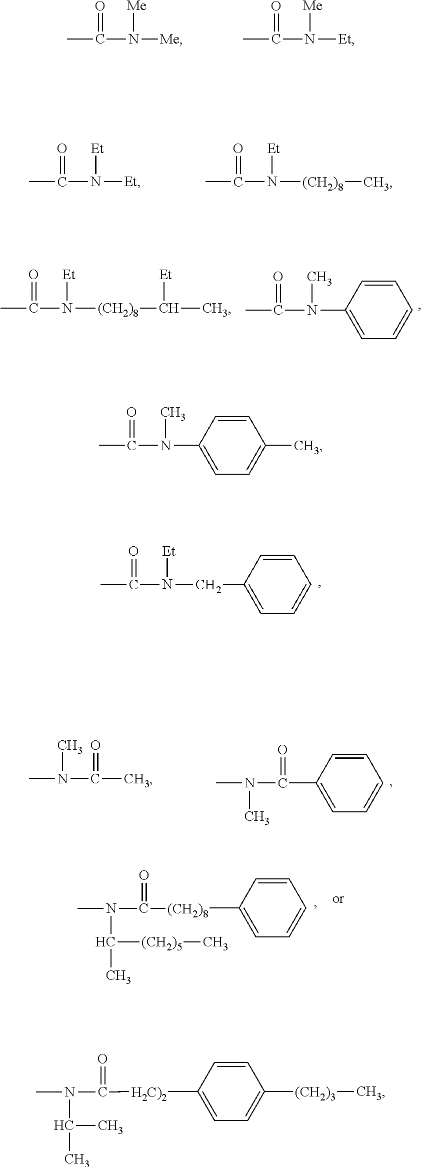

Specially, the cycloalkyl substituted with 3-20 carbon atoms is at least one of cyclopropyl, cyclobutyl, cyclopentyl, cyclohexyl, cycloheptyl, cyclooctyl, cyclododecyl, cyclohexadecyl, cyclooctadecyl, or cycloeicosyl.

Specially, the alkenyl with 2-20 carbon atoms is at least one of

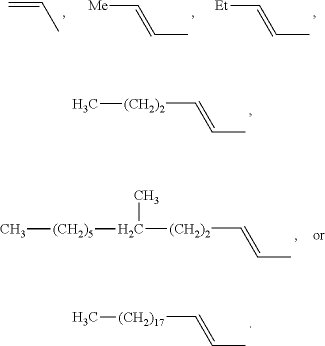

Specially, the alkynyl with 2-20 carbon atoms is at least one of

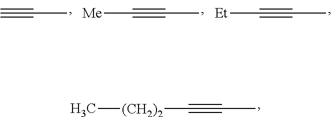

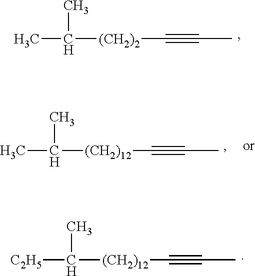

Specially, the substitution base that can improve the water solubility is at least one of a residue of polyethylene glycol, a residue of hyaluronic acid, polyacrylic acid, or a residue of a sugar derivative. The residue of the polyethylene glycol is a remaining part after an H is removed from a hydroxyl group on one end of the polyethylene glycol. A weight-average molecular weight of the polyethylene glycol is 200-200,000. The residue of the hyaluronic acid is a remaining part after an H is removed from a hydroxyl group on D-glucuronic acid or N-acetylglucosamine of the hyaluronic acid or a remaining part after a hydroxyl group (—OH) is removed from a carboxyl of D-glucuronic acid of the hyaluronic acid. A weight-average molecular weight of the hyaluronic acid is 2000-2000000. Residue sugar derivative is a remaining part after an H is removed from any hydroxyl group of the sugar derivative. The sugar derivative is a derivative of glucose, sucrose, maltose, galactose, lactose, fructose, or sialic acid. The sugar derivative is glucuronic acid, glucose acetal, glucose hemiacetal, or carboxymethyl lactose.

A substituent reacting with the alkenyl group and the alkenyl group consists of 2-80 carbon atoms of a second substituted aryl group and a second unsubstituted aryl group, preferably 2-60 carbon atoms of a second substituted aryl group and a second unsubstituted aryl group, more preferably 2-40 carbon atoms of a second substituted aryl group and a second unsubstituted aryl group, wherein the second substituted aryl group or the second unsubstituted aryl group is the same the first substituted aryl group or the first unsubstituted aryl group.

In a preferred embodiment of the present disclosure, the A in the [Os] is at least one of H, F, Cl, Br, or SCN. The L in the [Os] is at least one of a CO ligand, a triphenylphosphine ligand, a trimethylphosphine ligand, or a triethylphosphine ligand.

The conjugated linking group R1 is at least one of

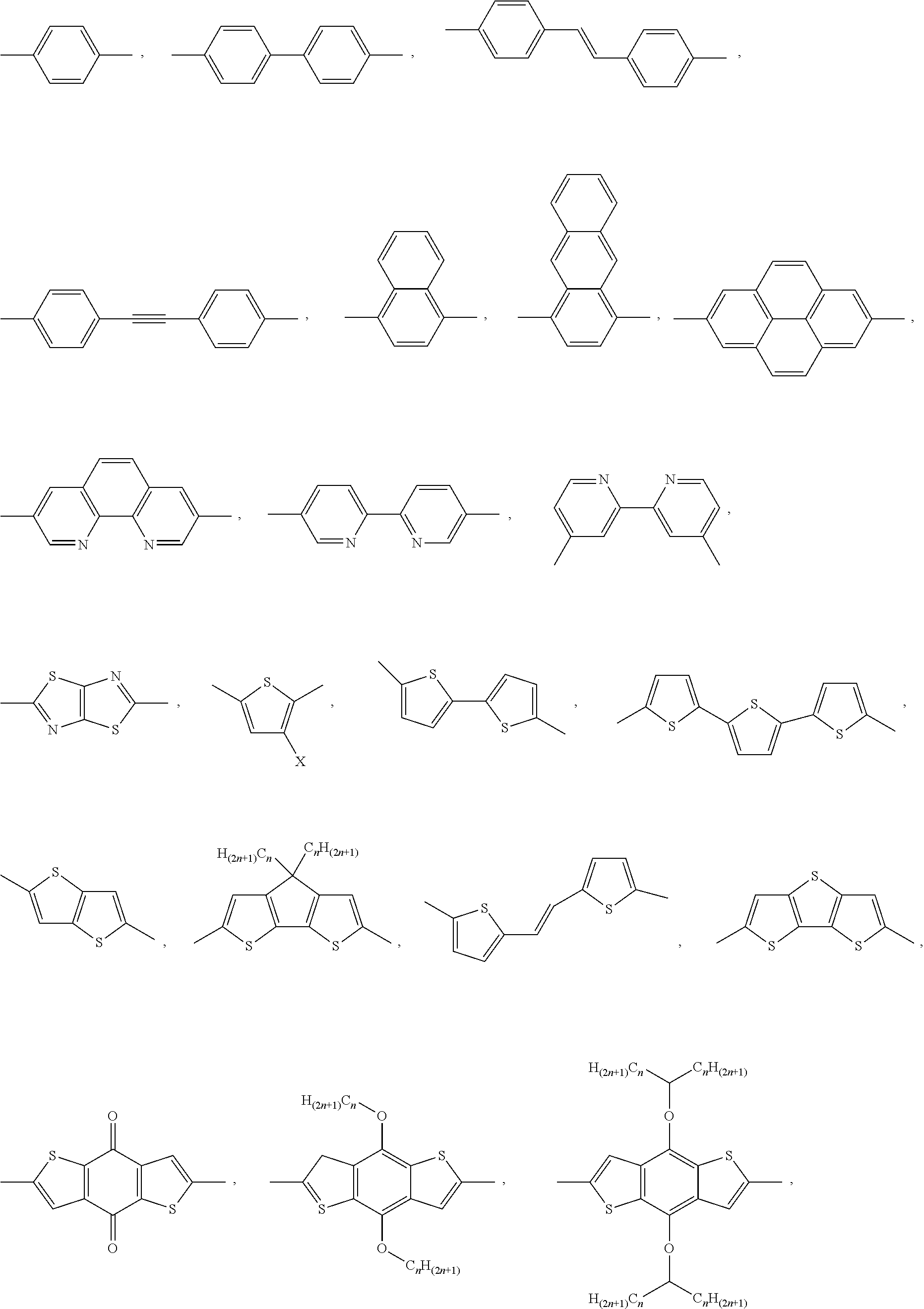

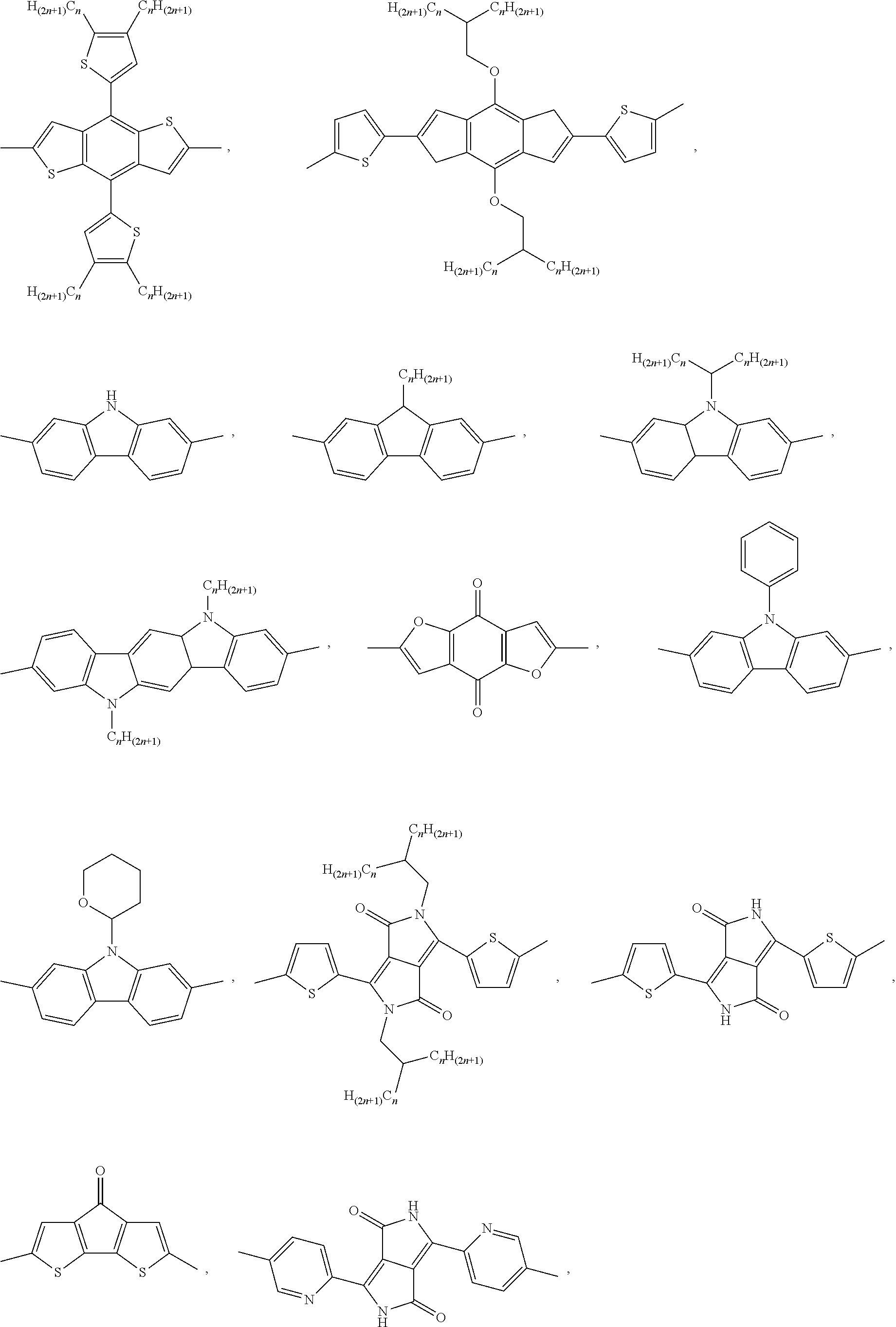

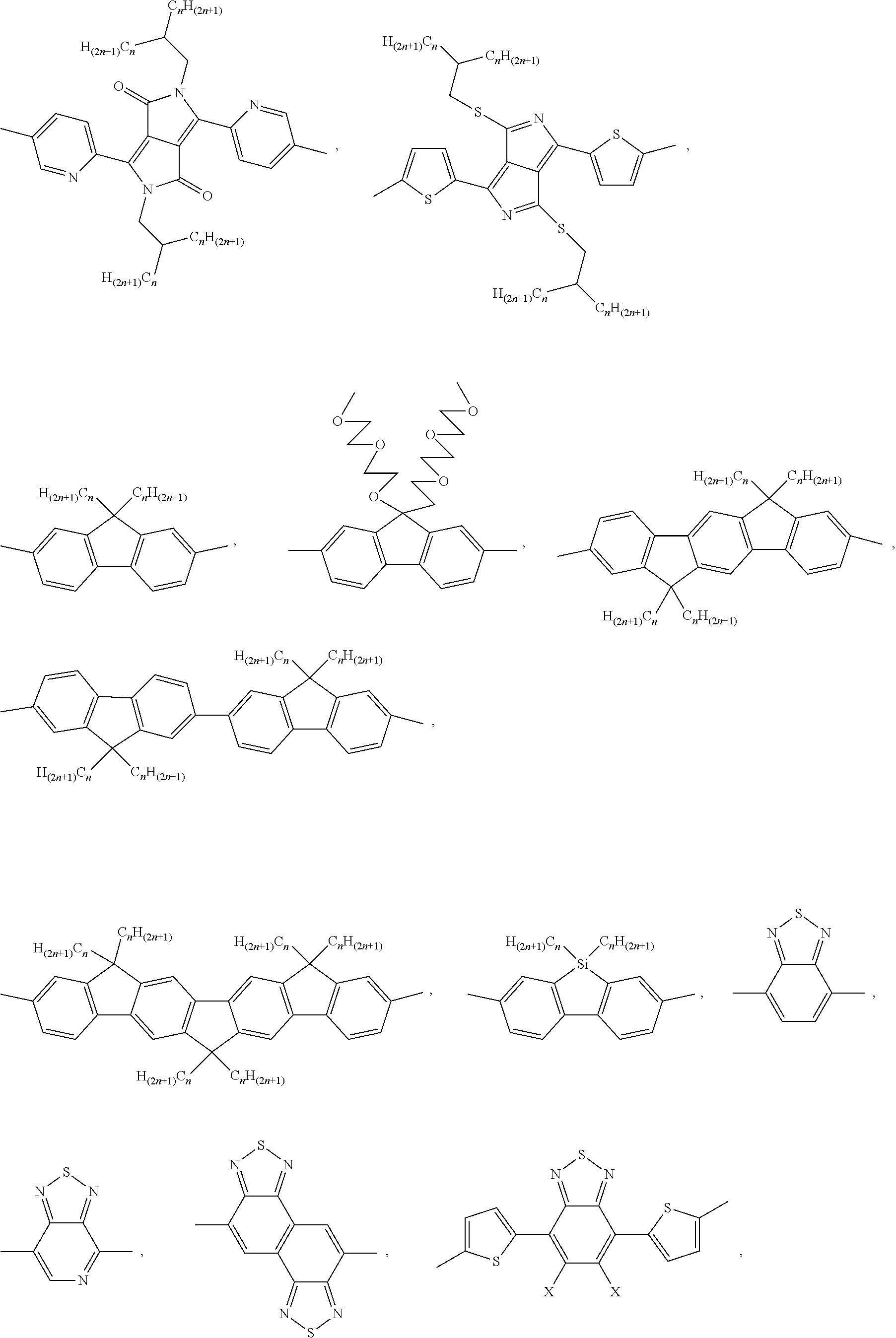

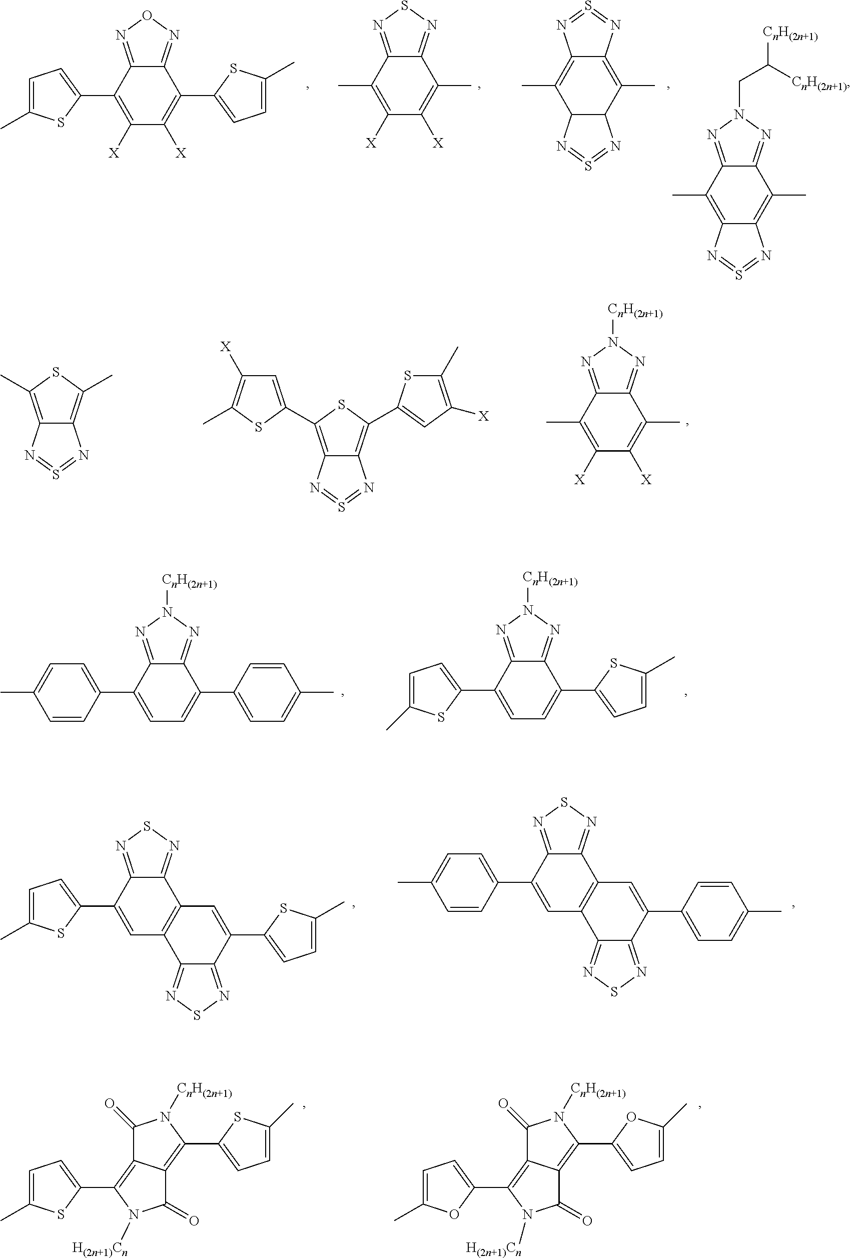

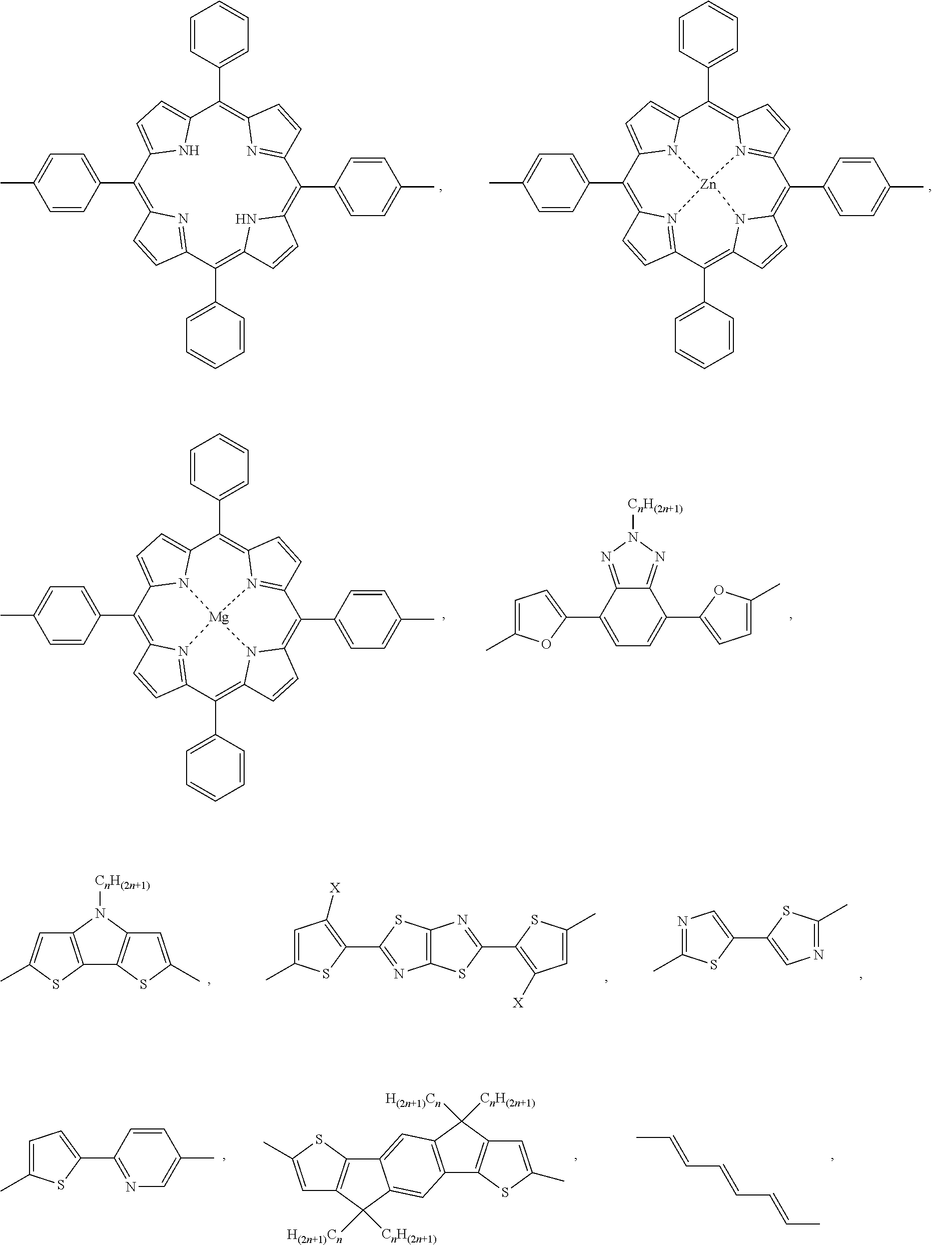

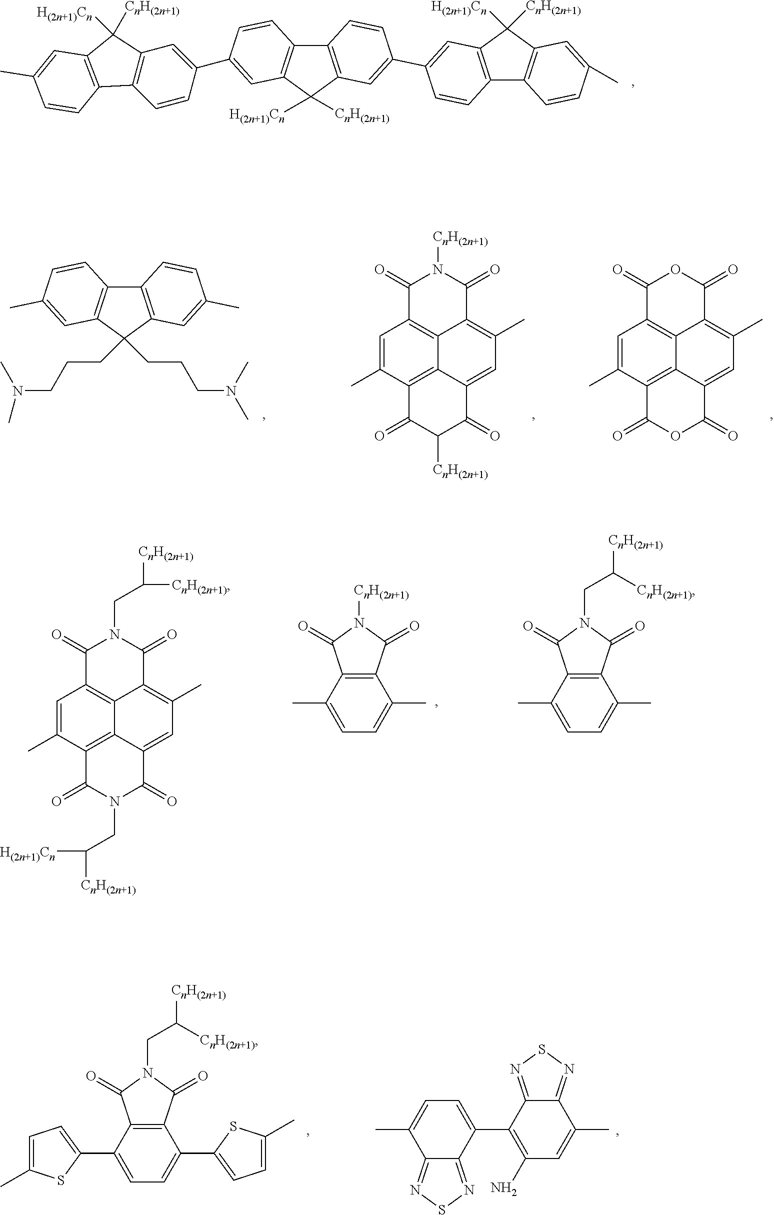

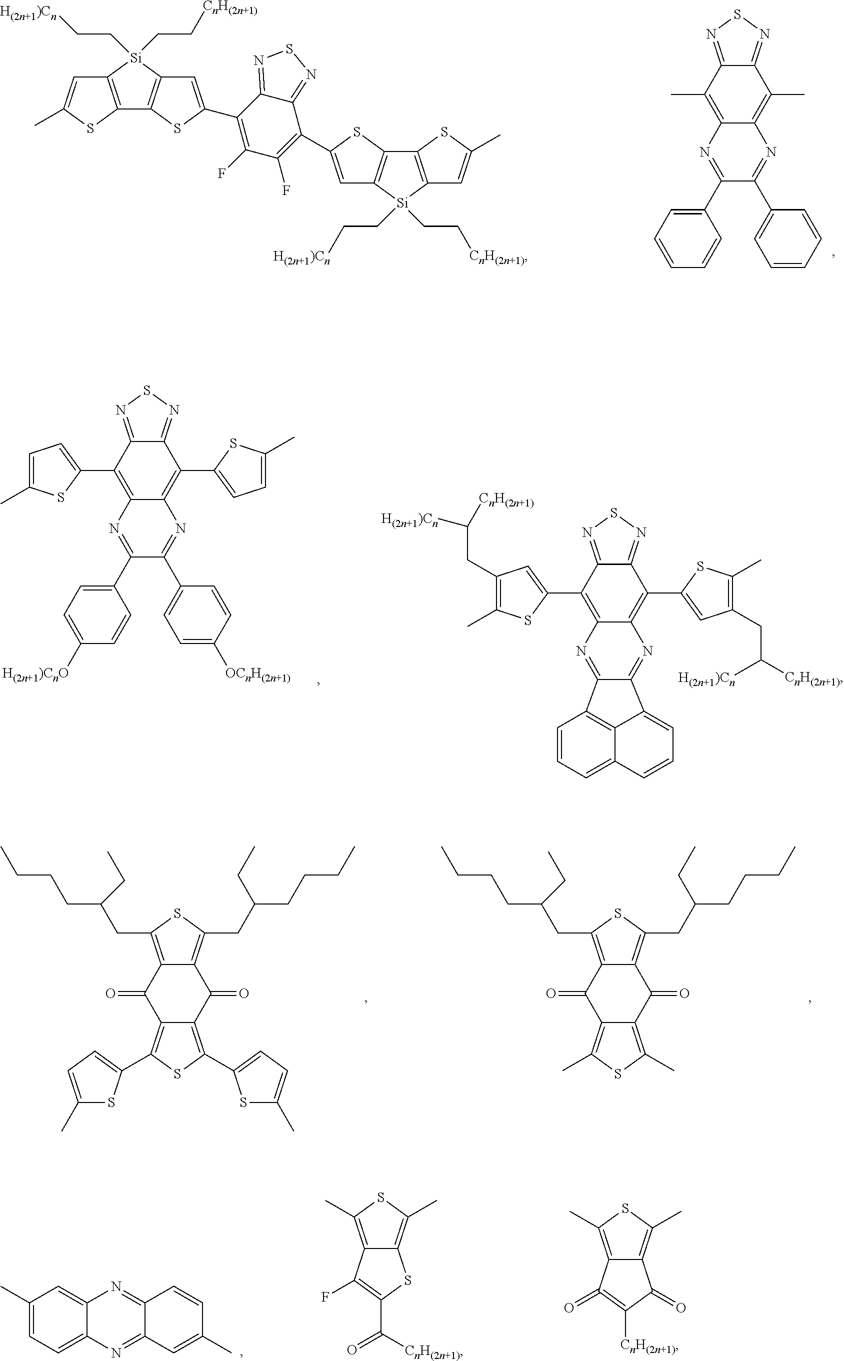

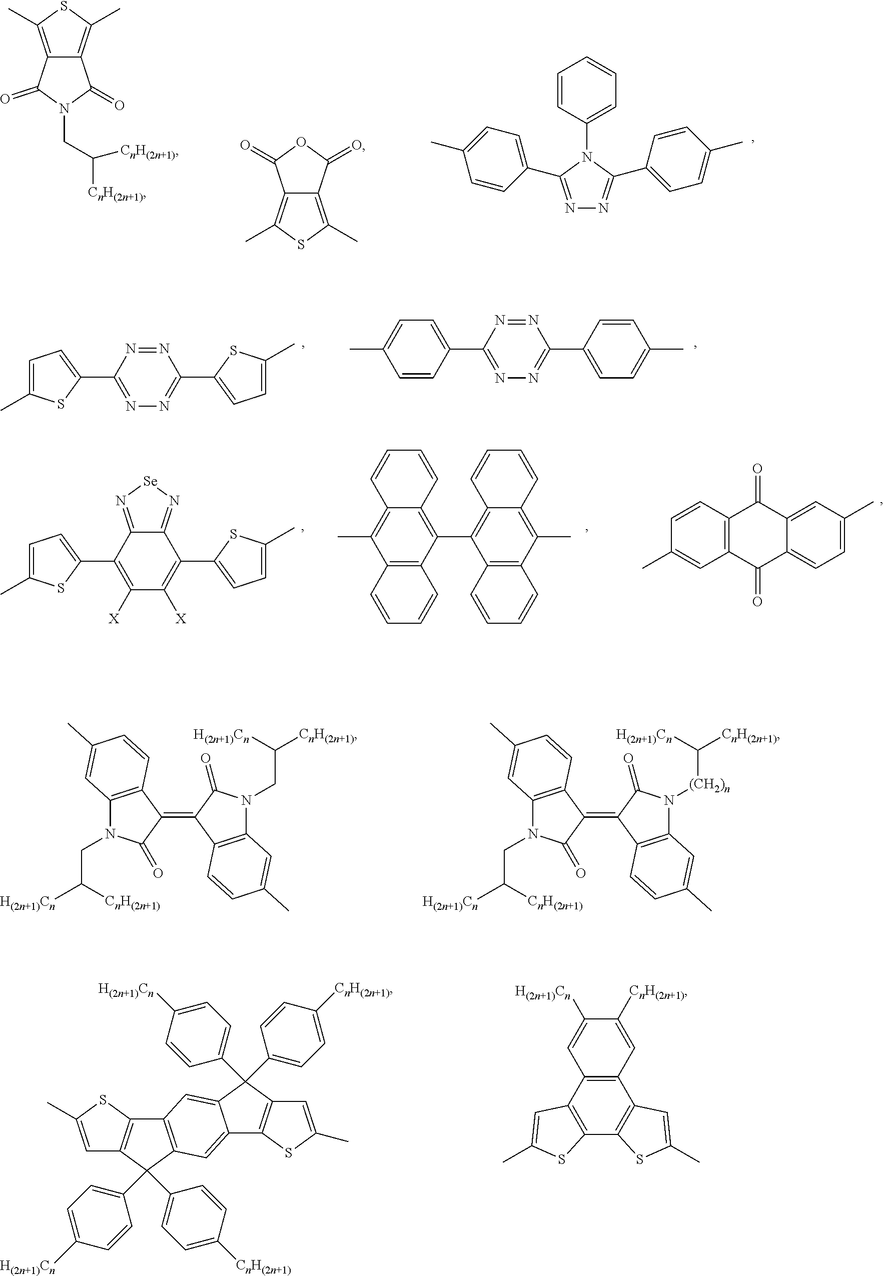

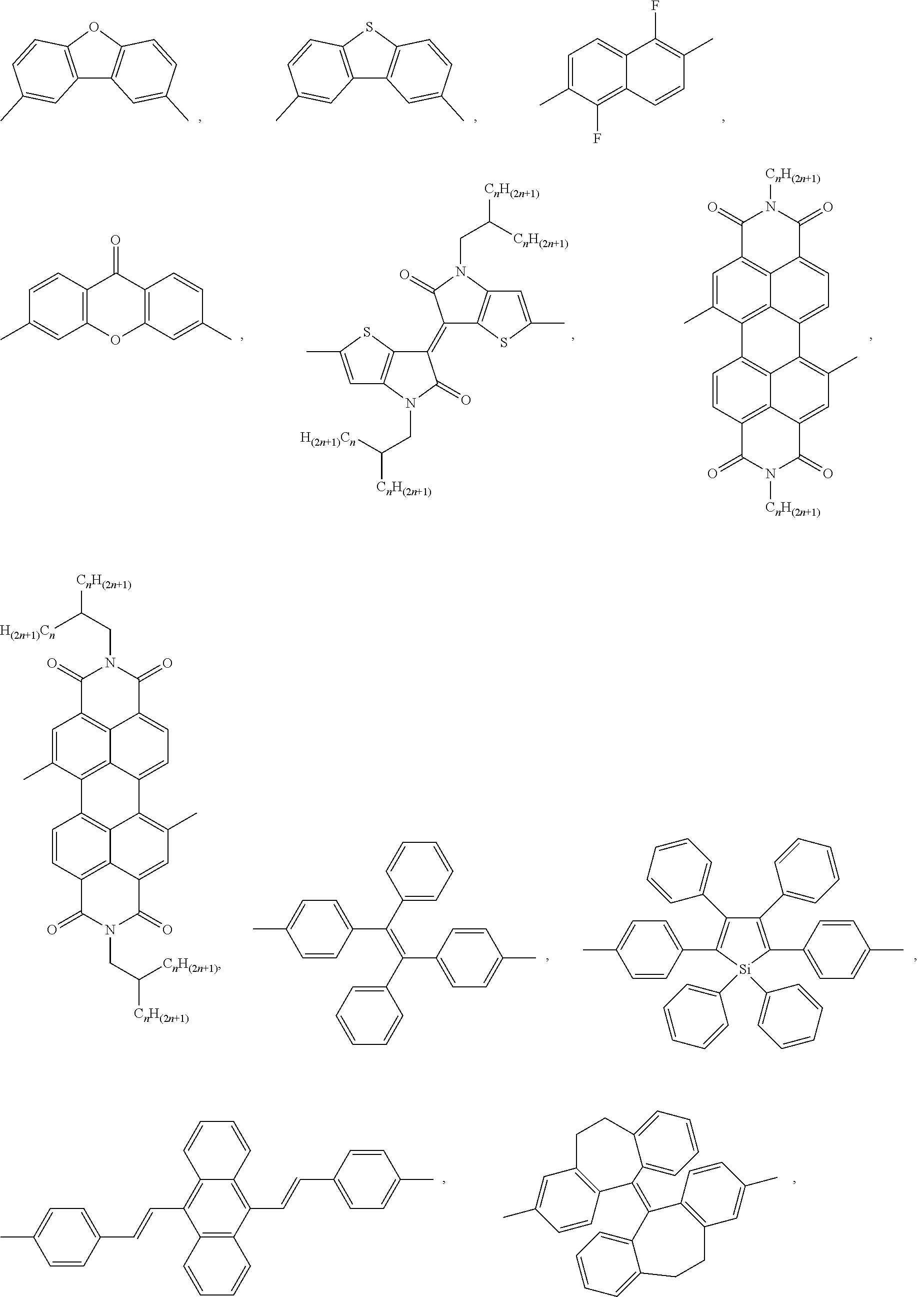

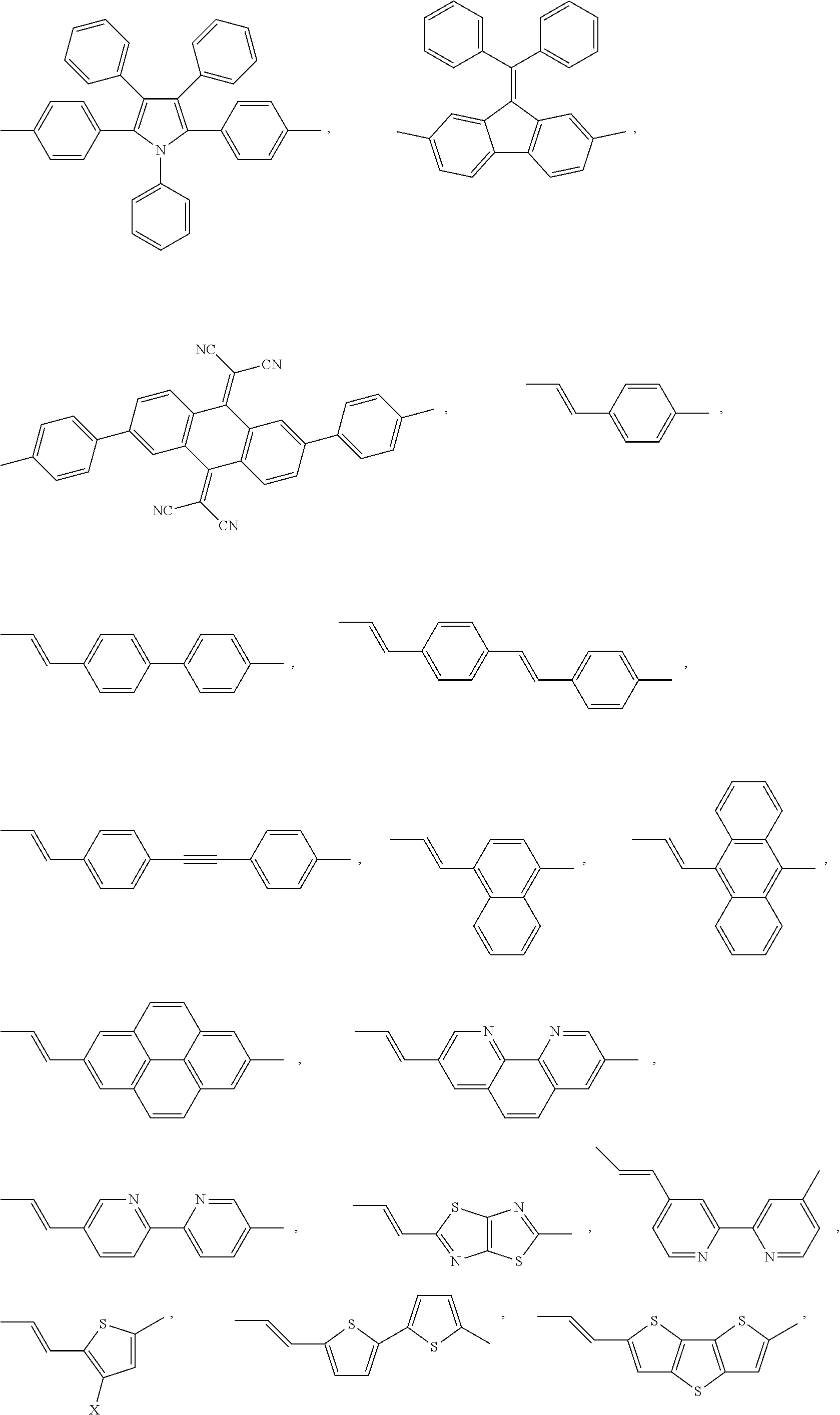

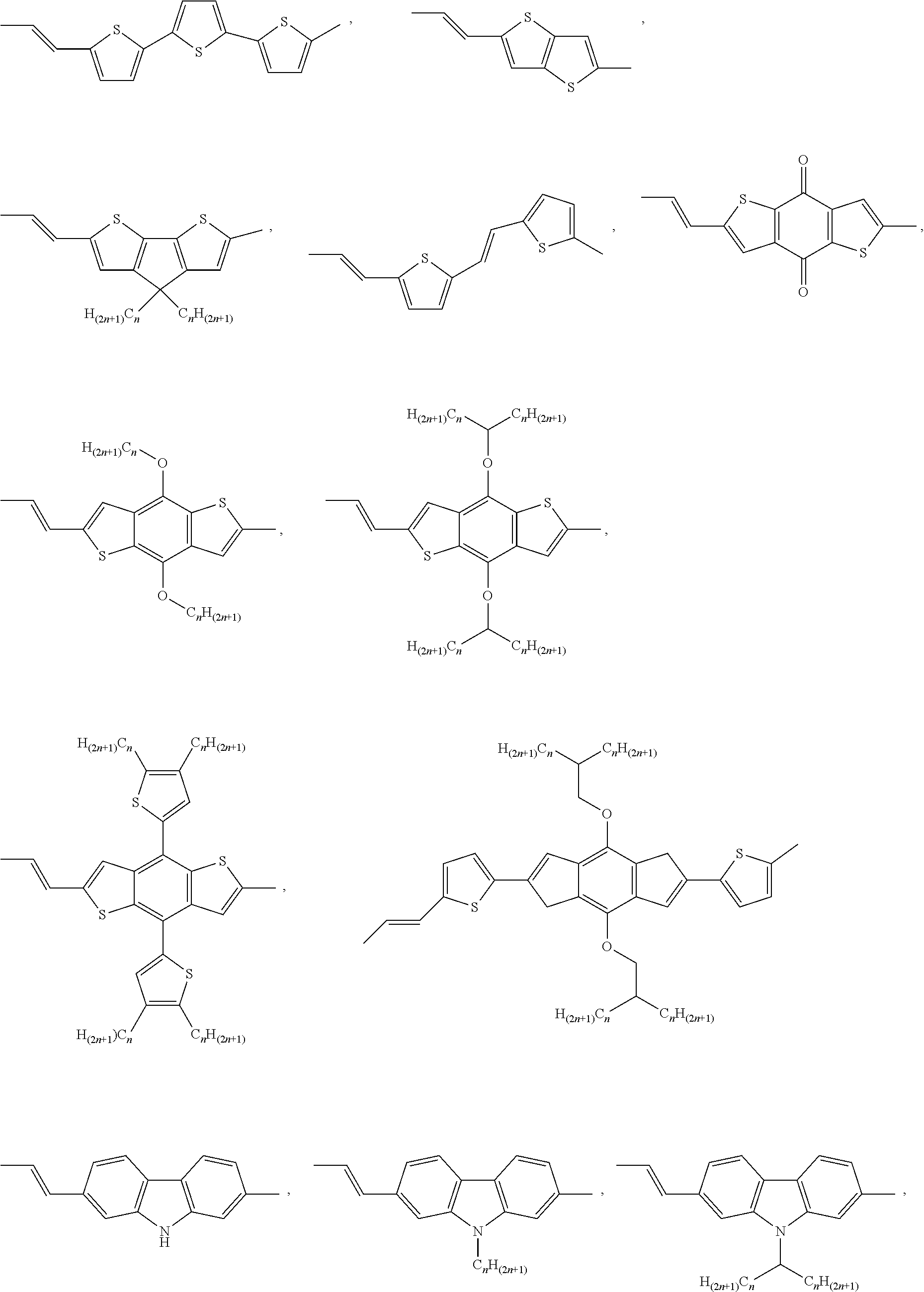

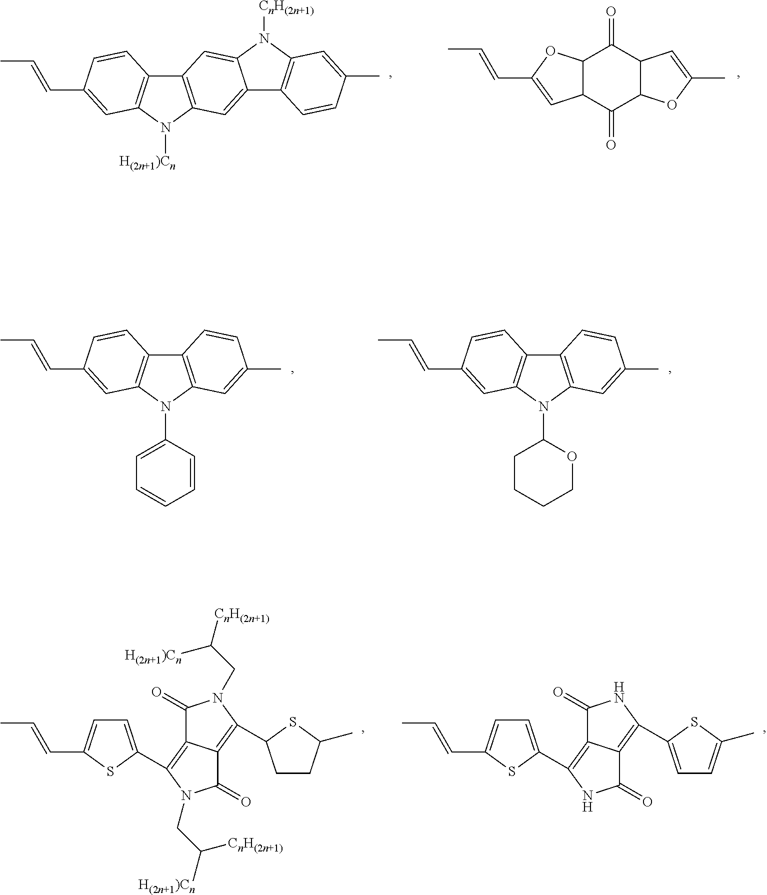

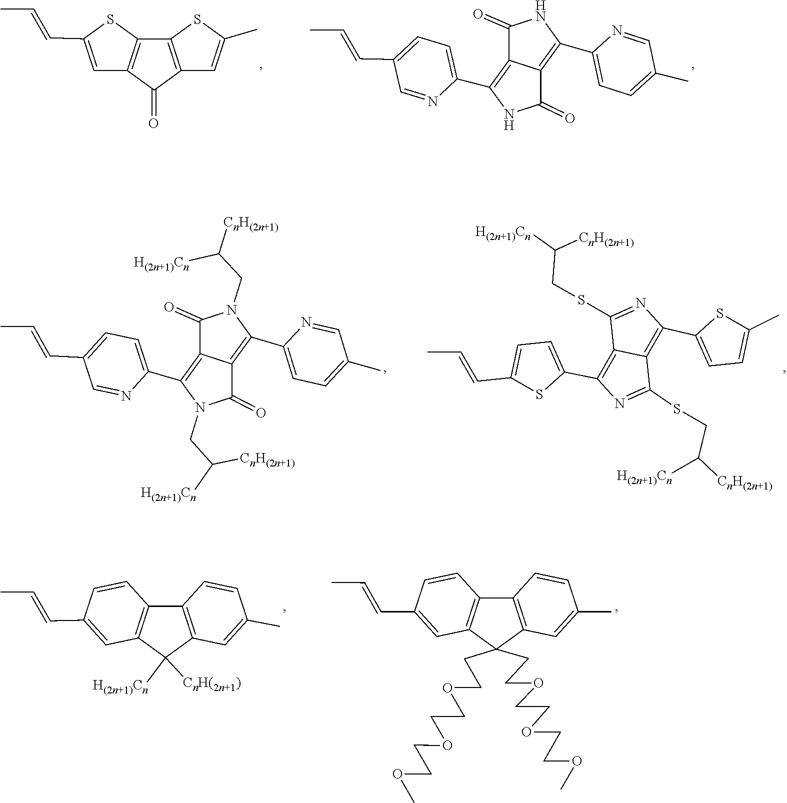

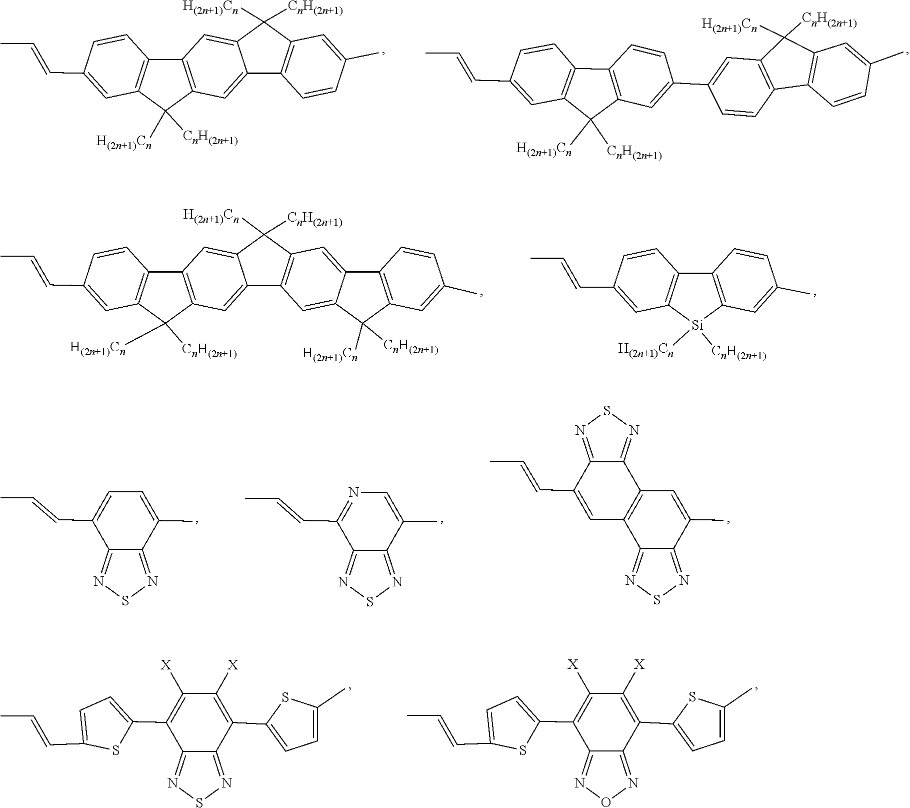

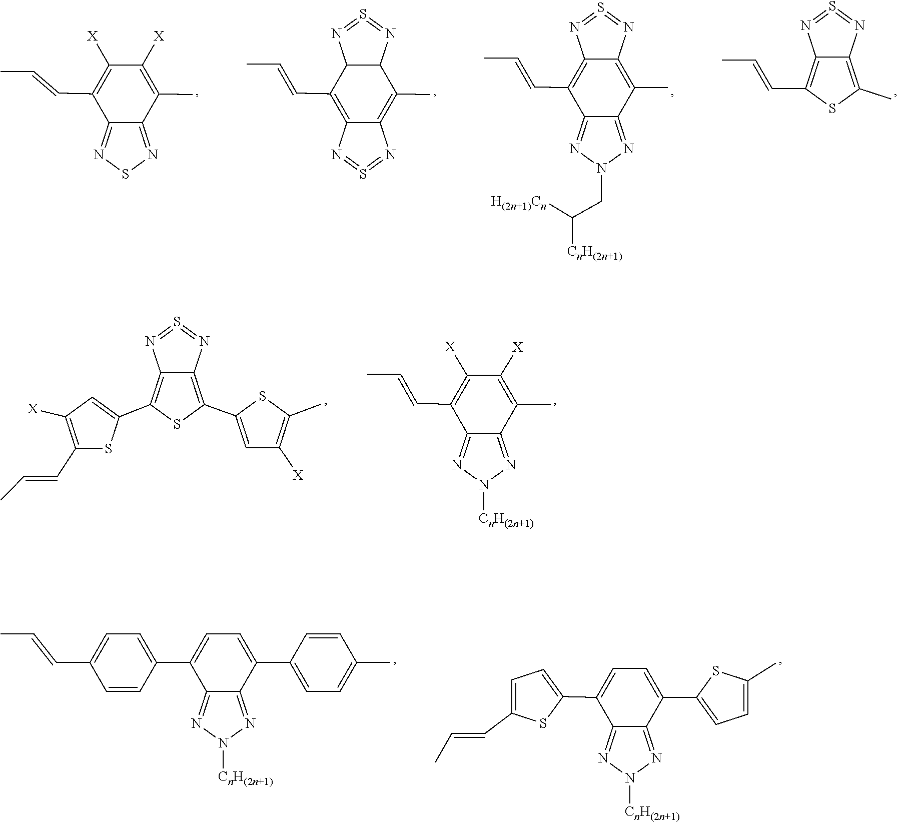

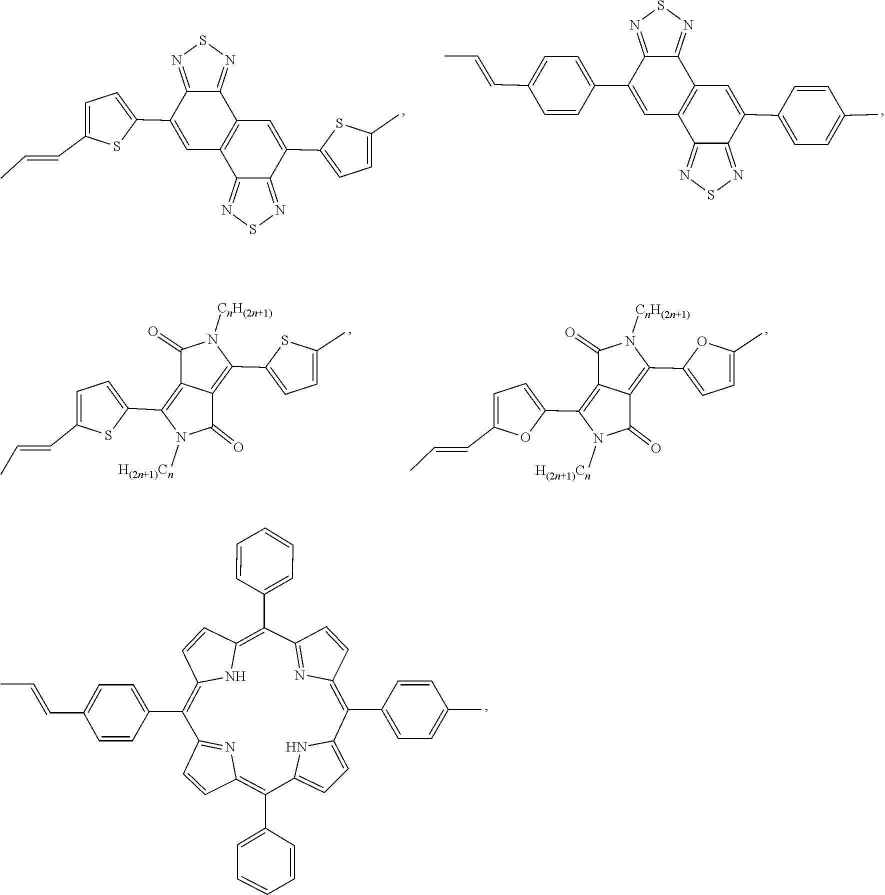

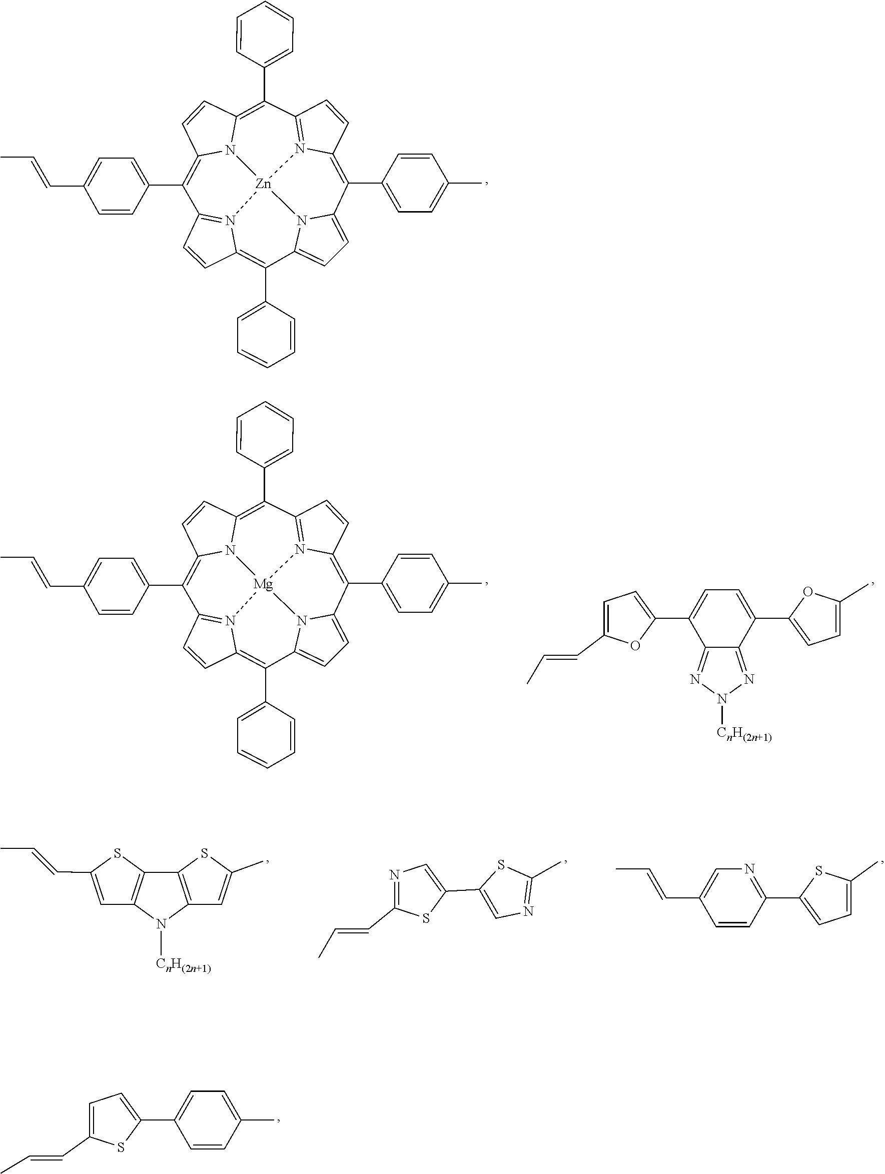

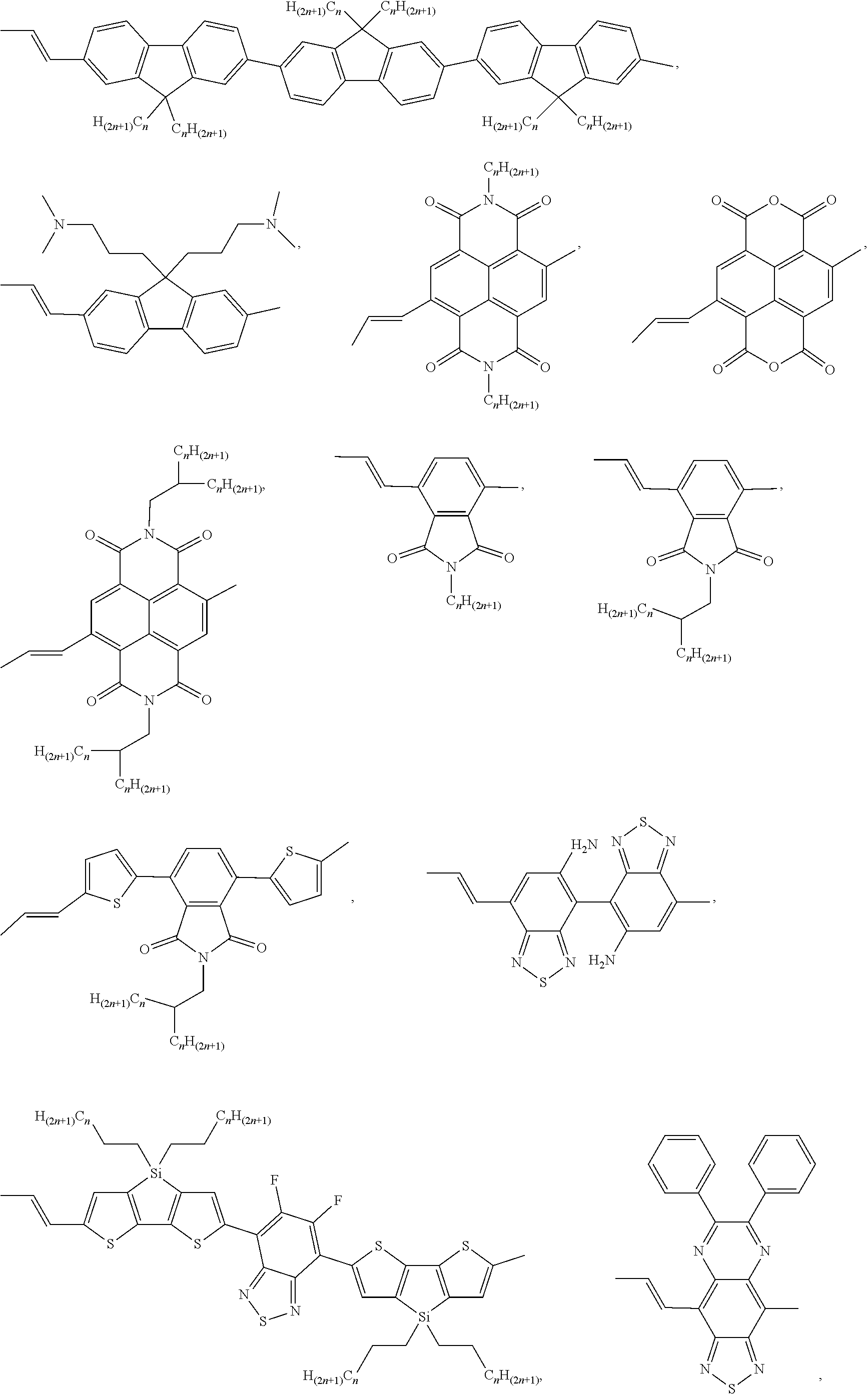

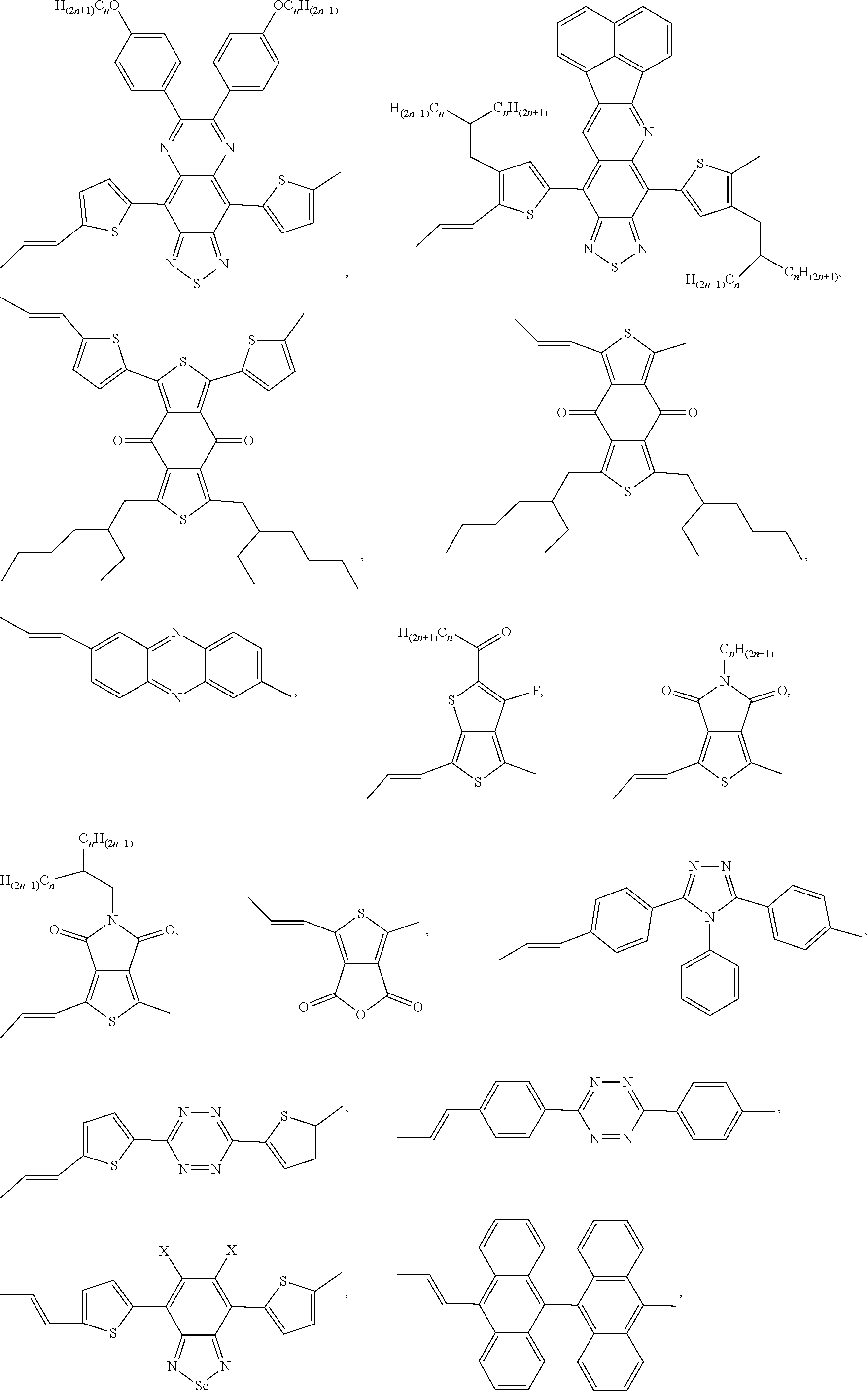

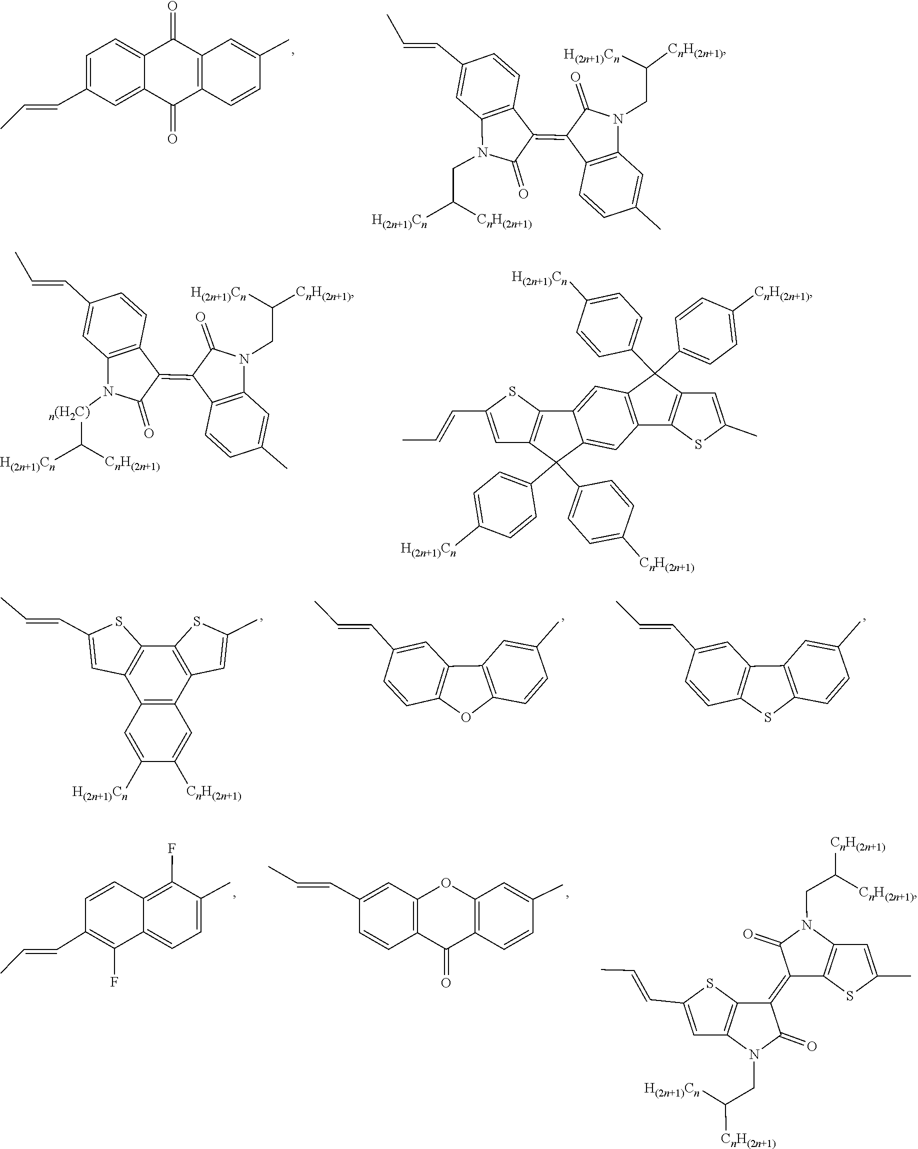

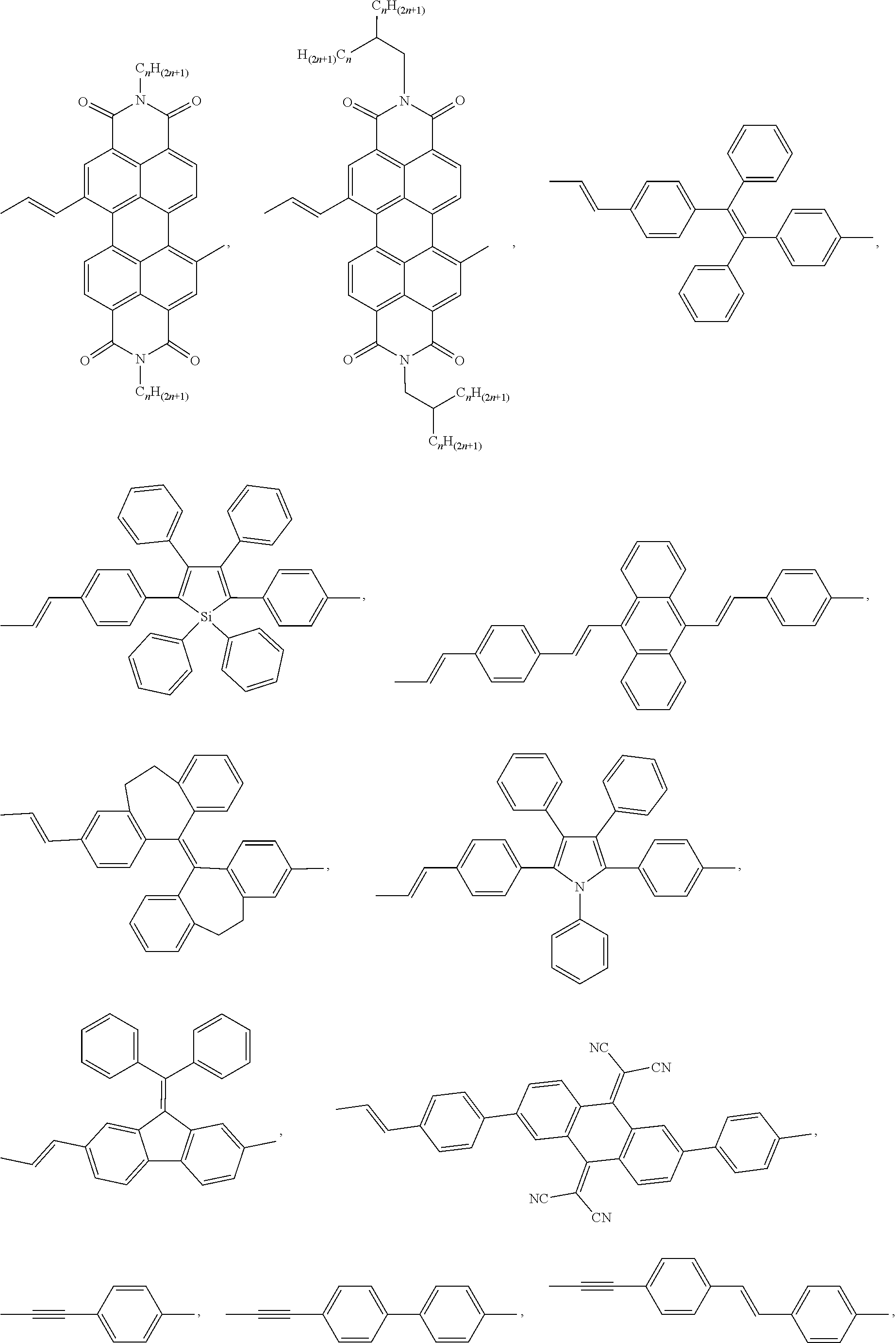

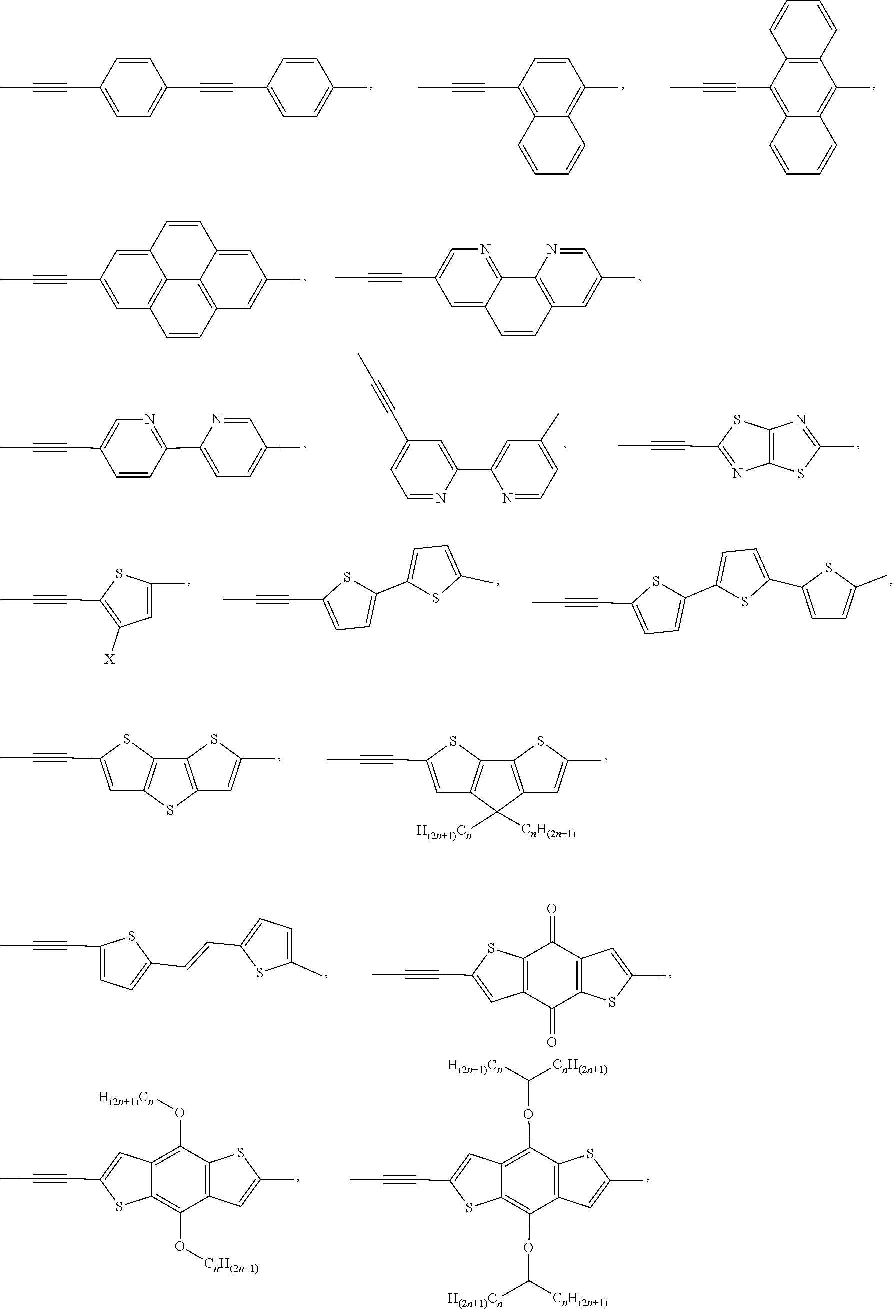

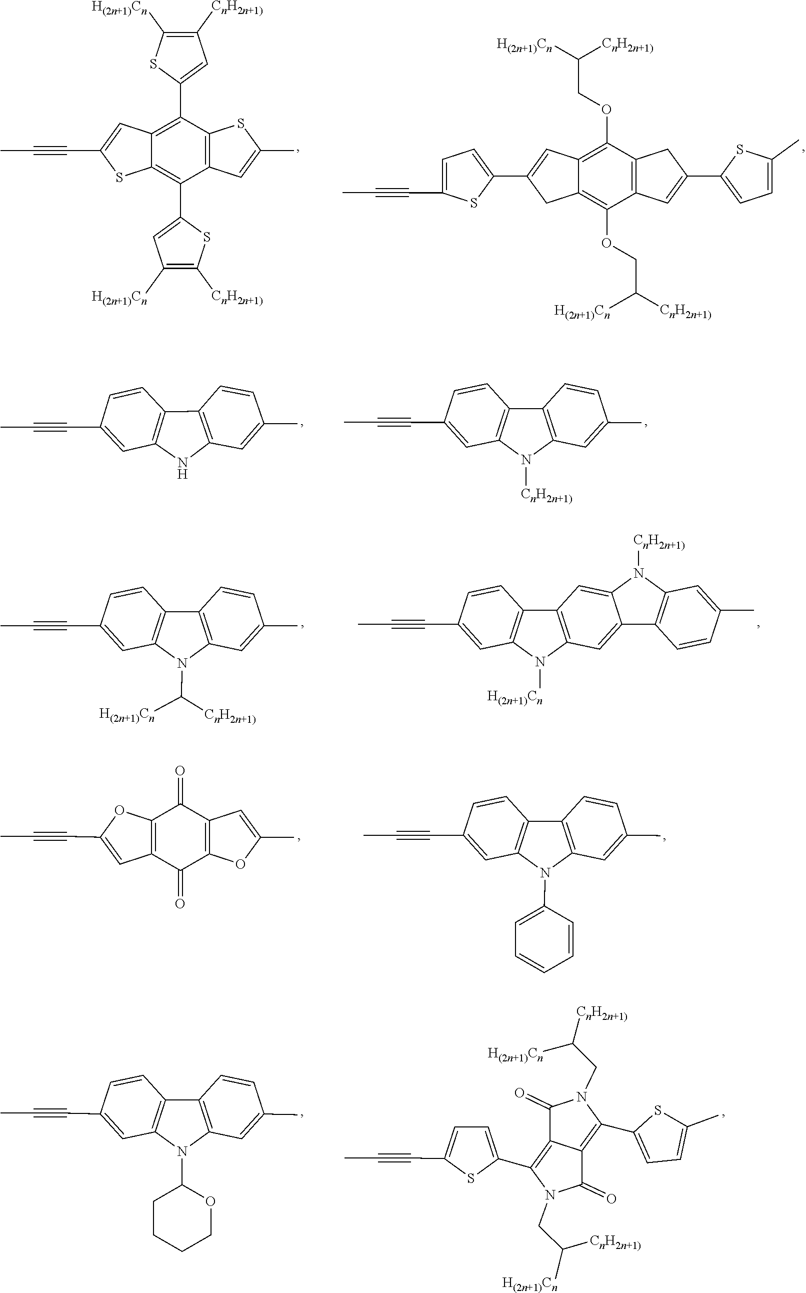

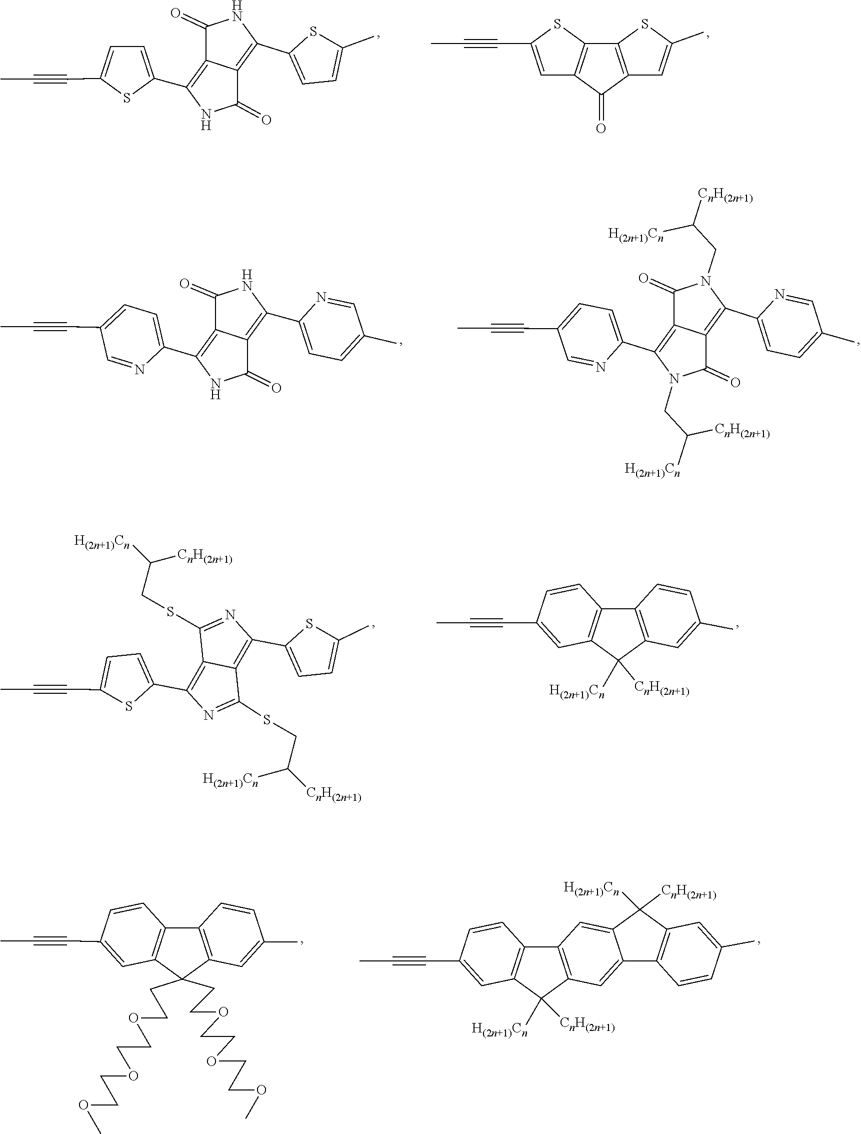

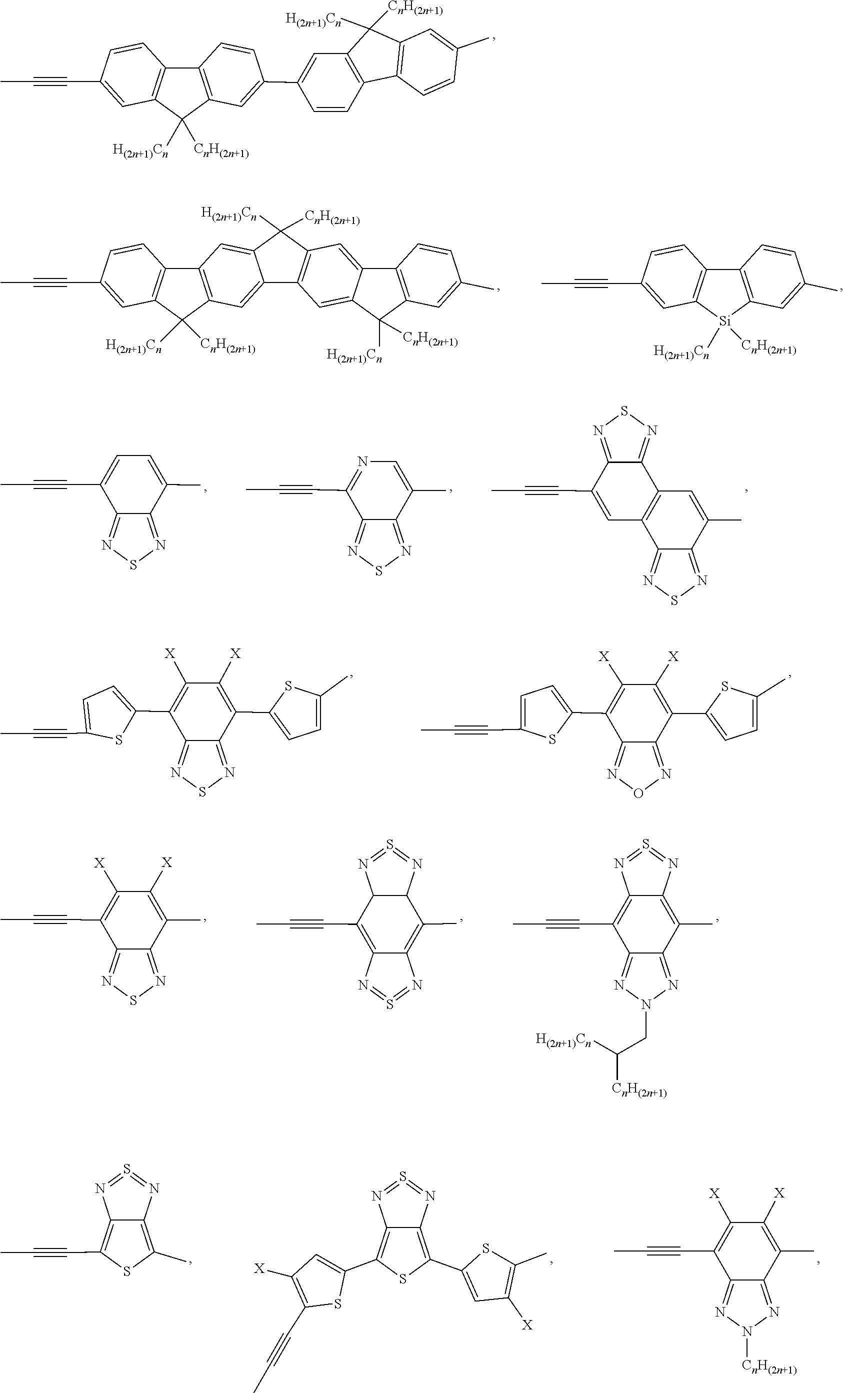

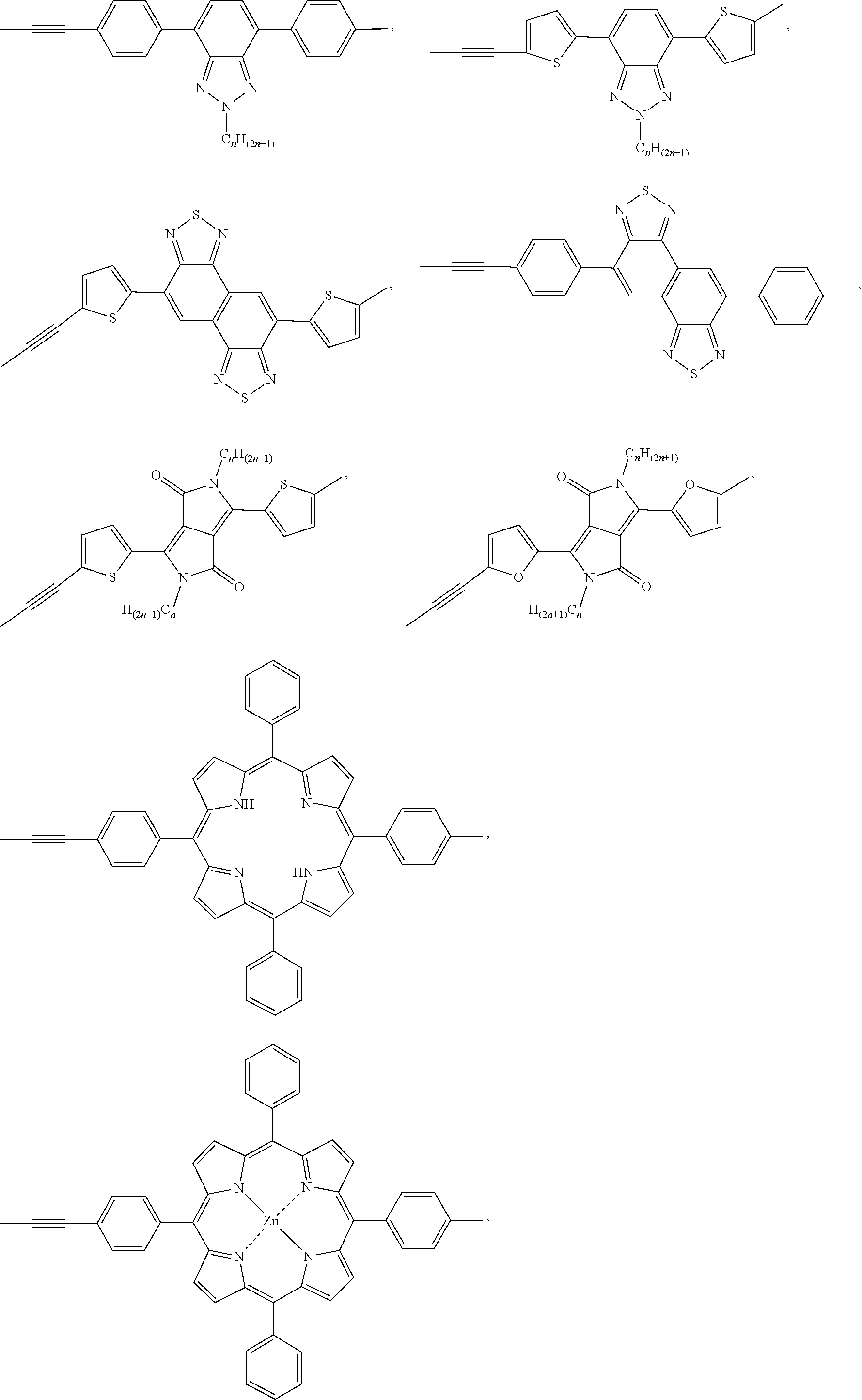

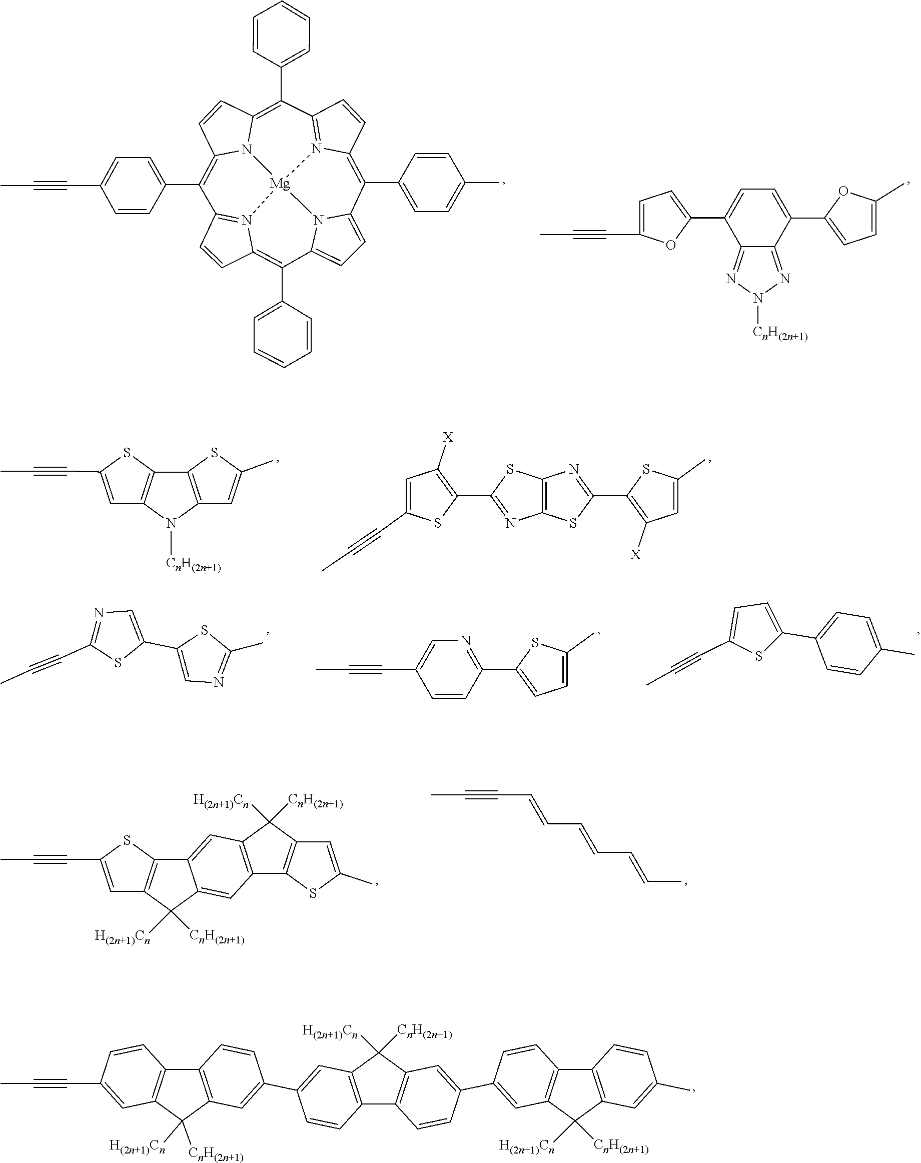

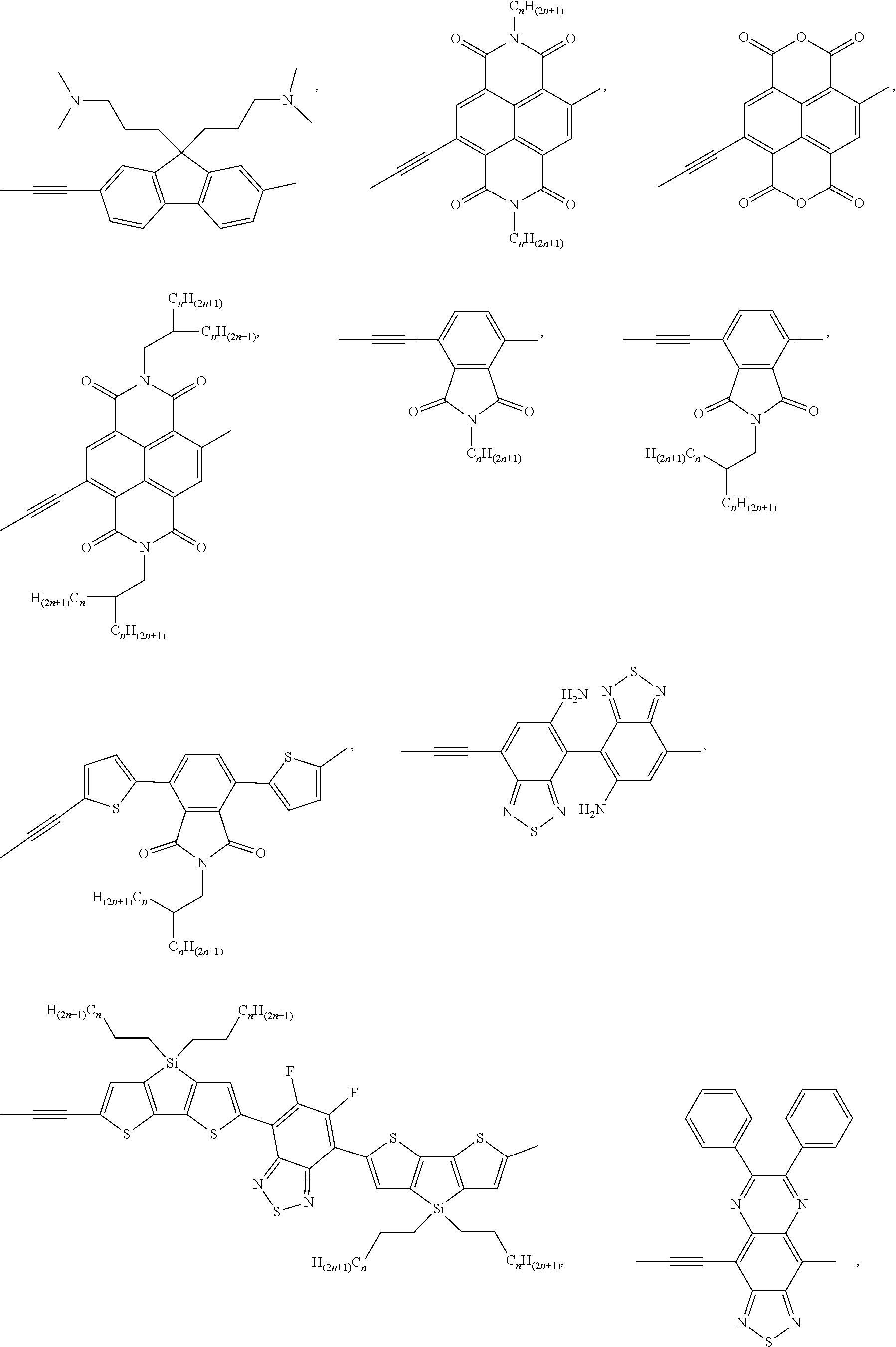

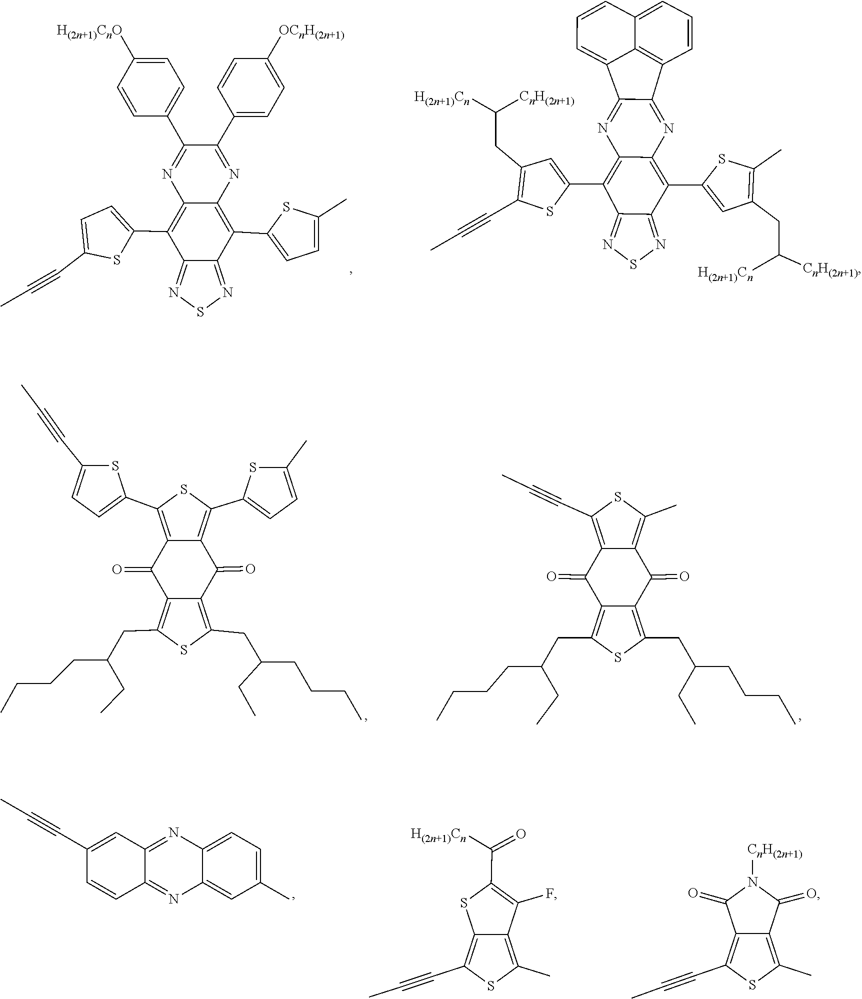

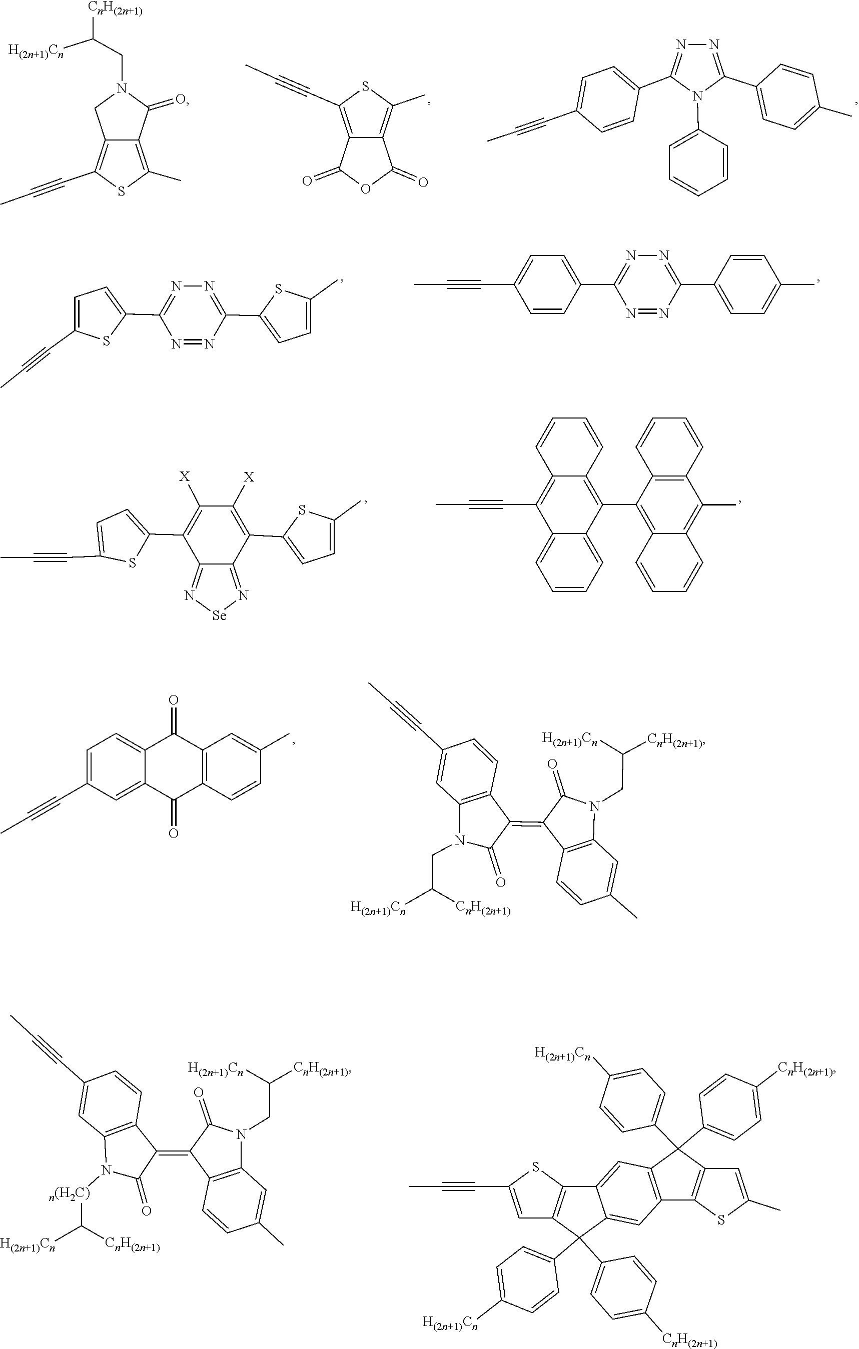

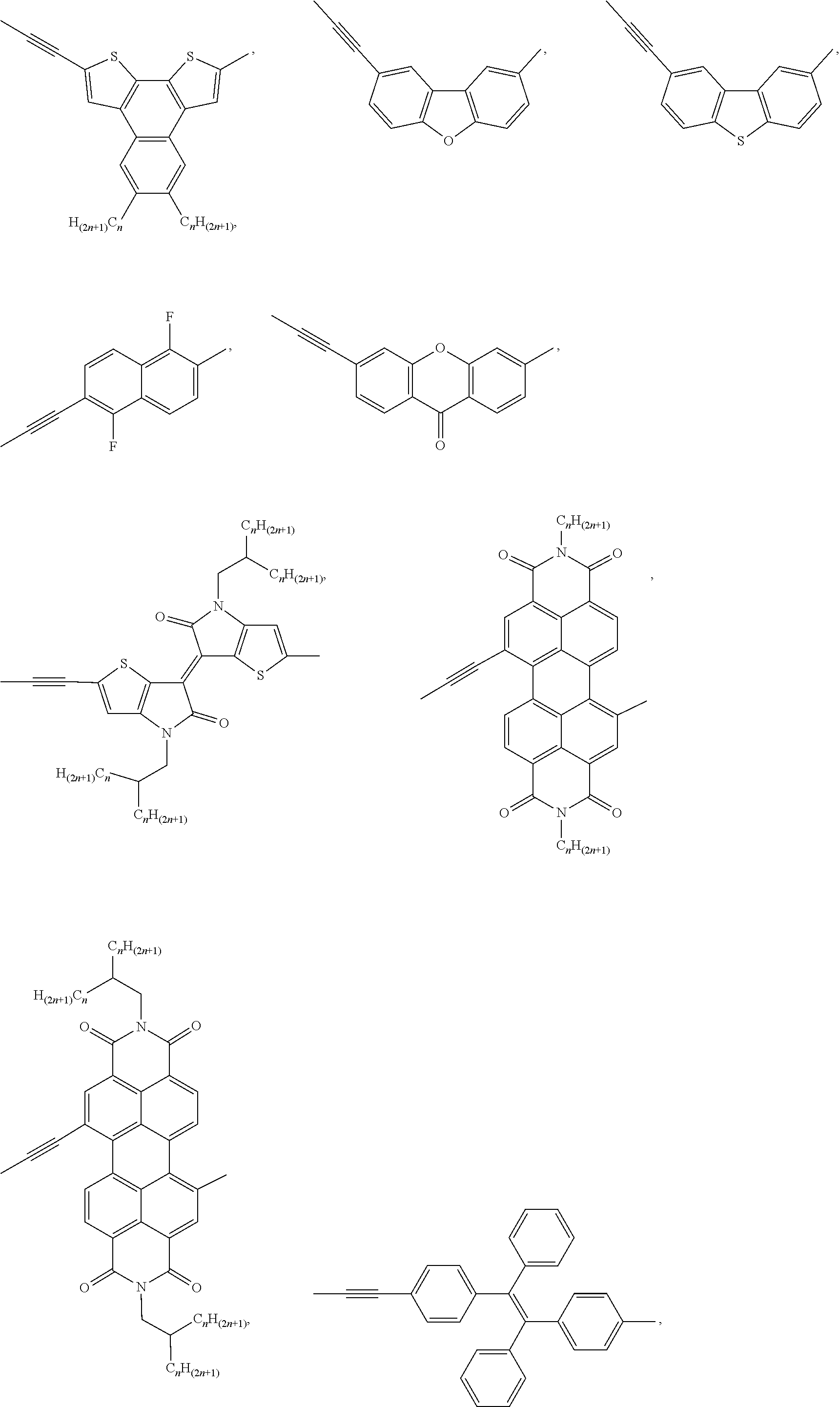

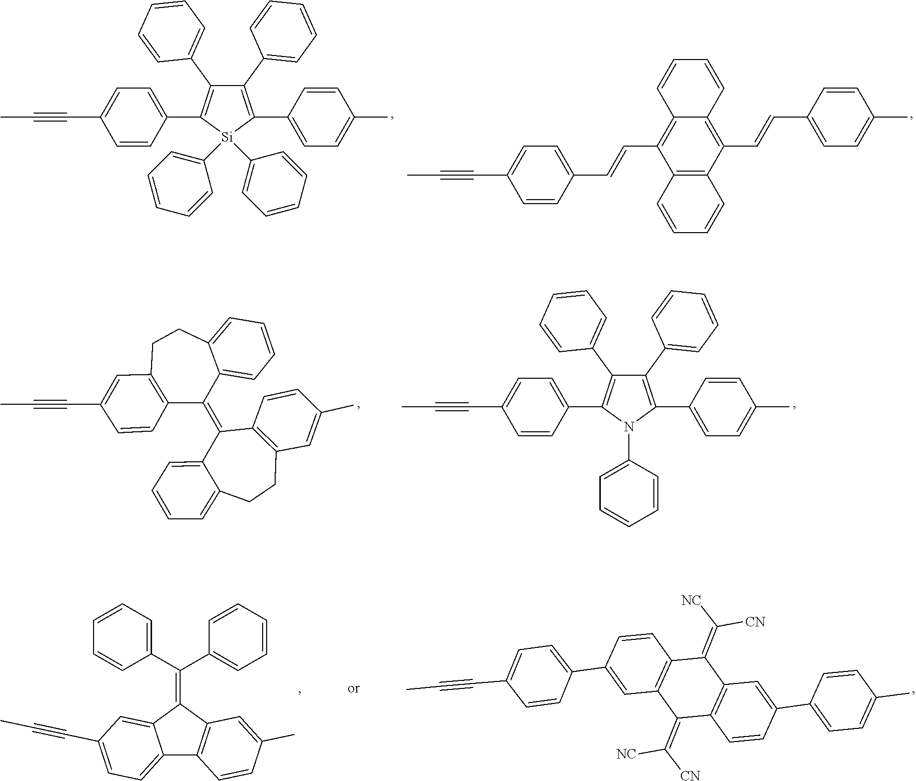

wherein n is an integer between 0 and 30, preferably an integer between 0 and 20, more preferably an integer between 0 and 12, X is hydrogen, fluorine, amino, nitro, or alkoxy with 1-32 carbon atoms, preferably alkoxy with 1-20 carbon atoms, more preferably alkoxy with 1-16 carbon atoms.

The osmium-containing-conjugated polymer is at least one of

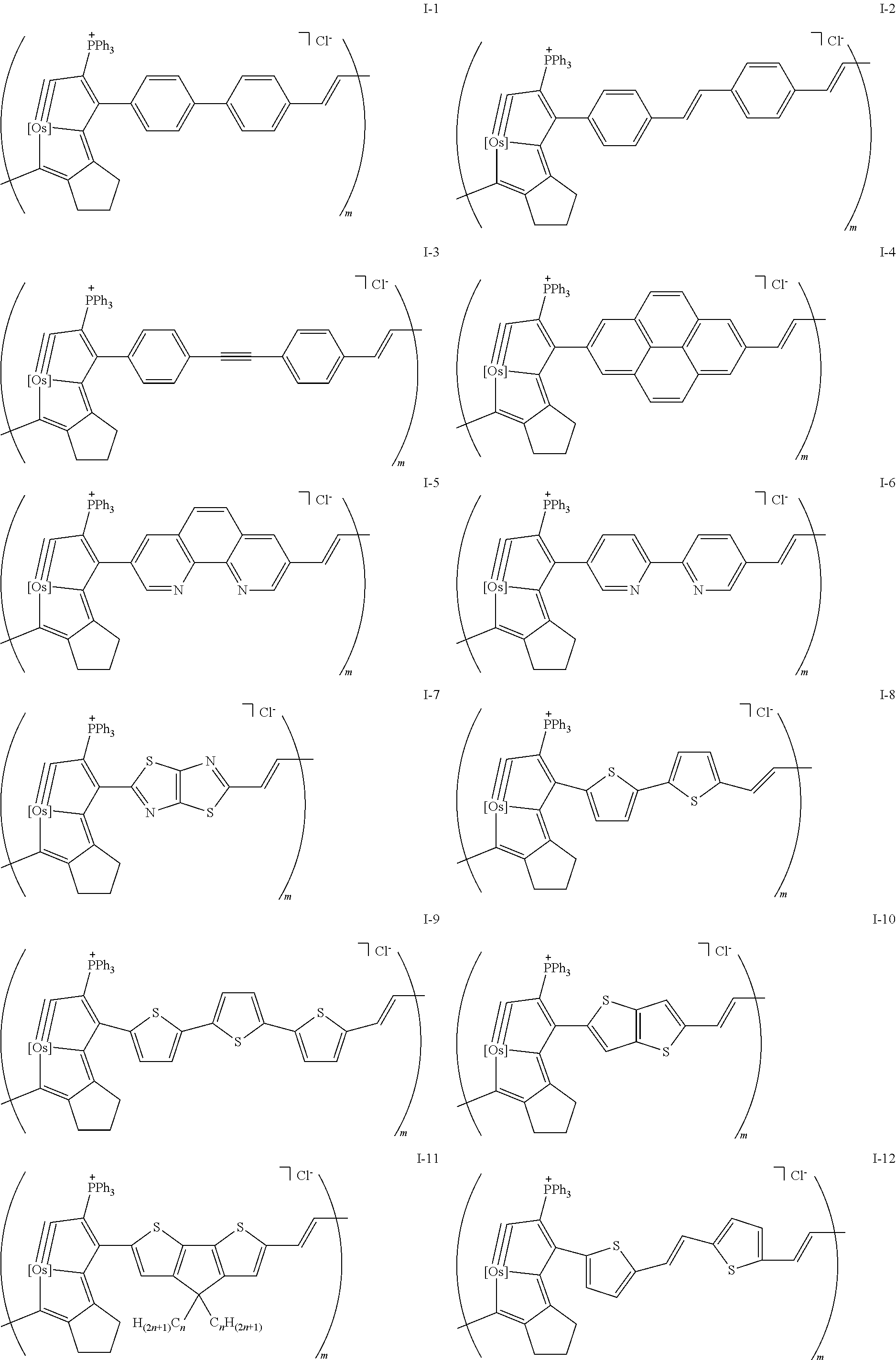

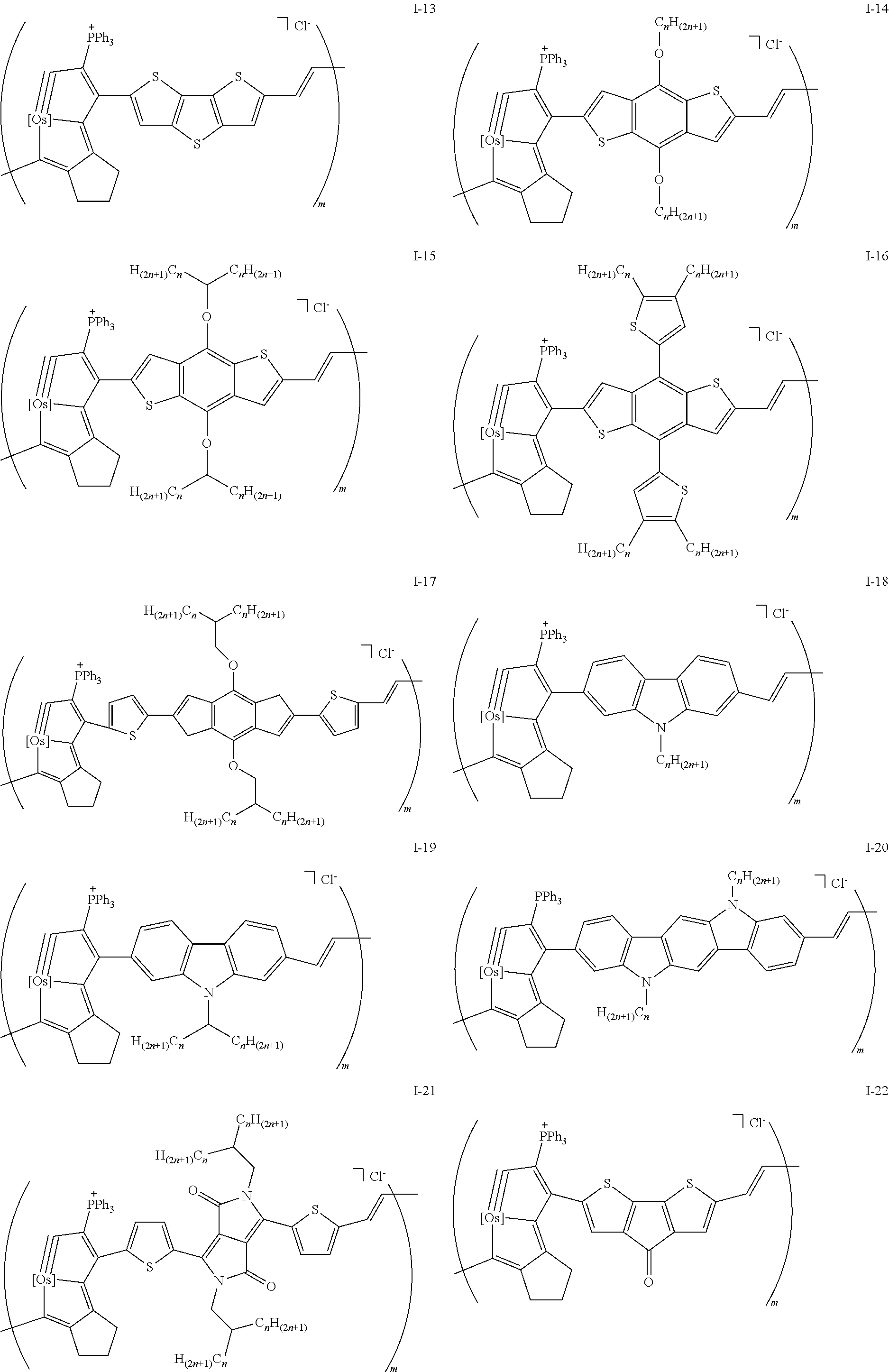

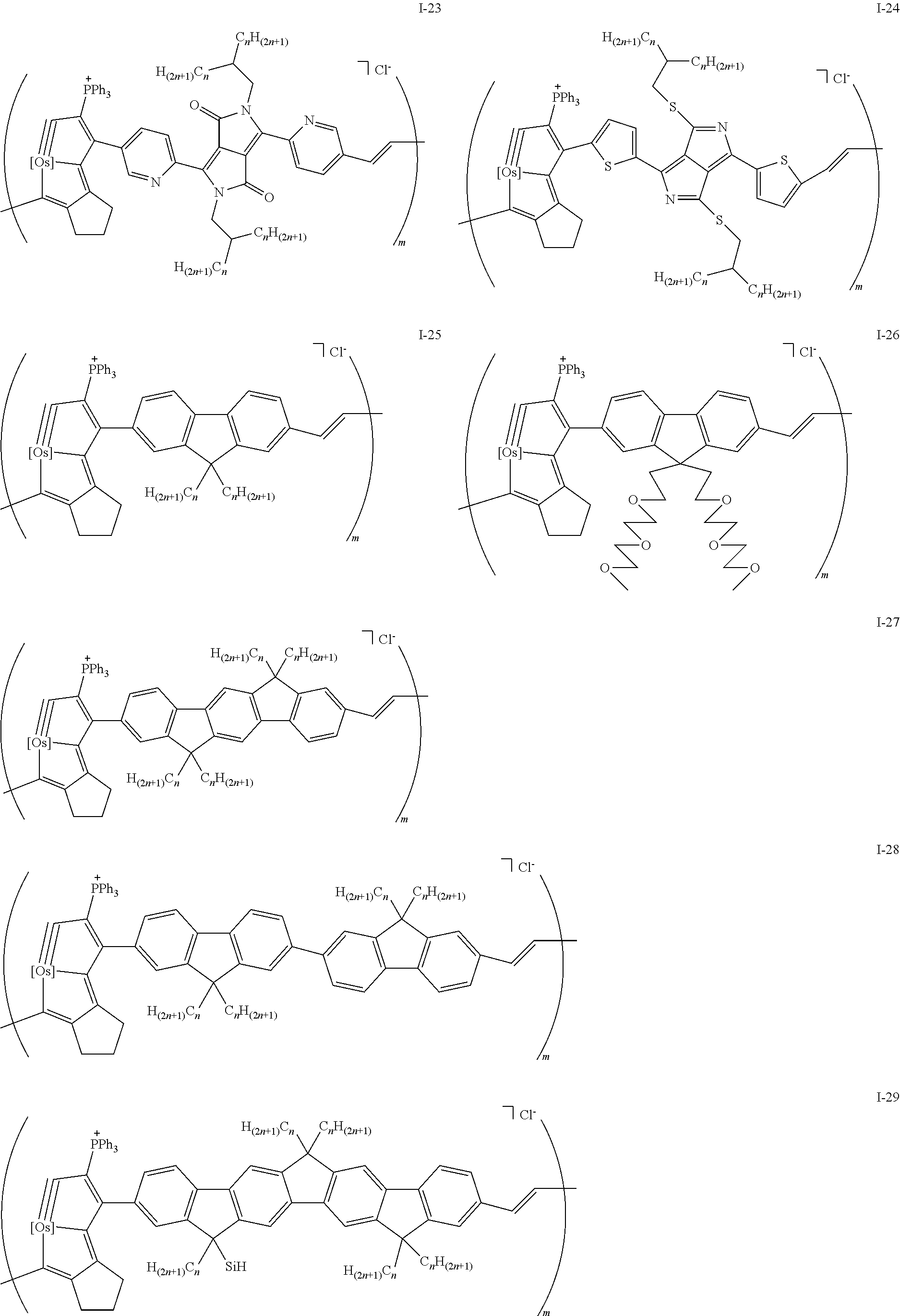

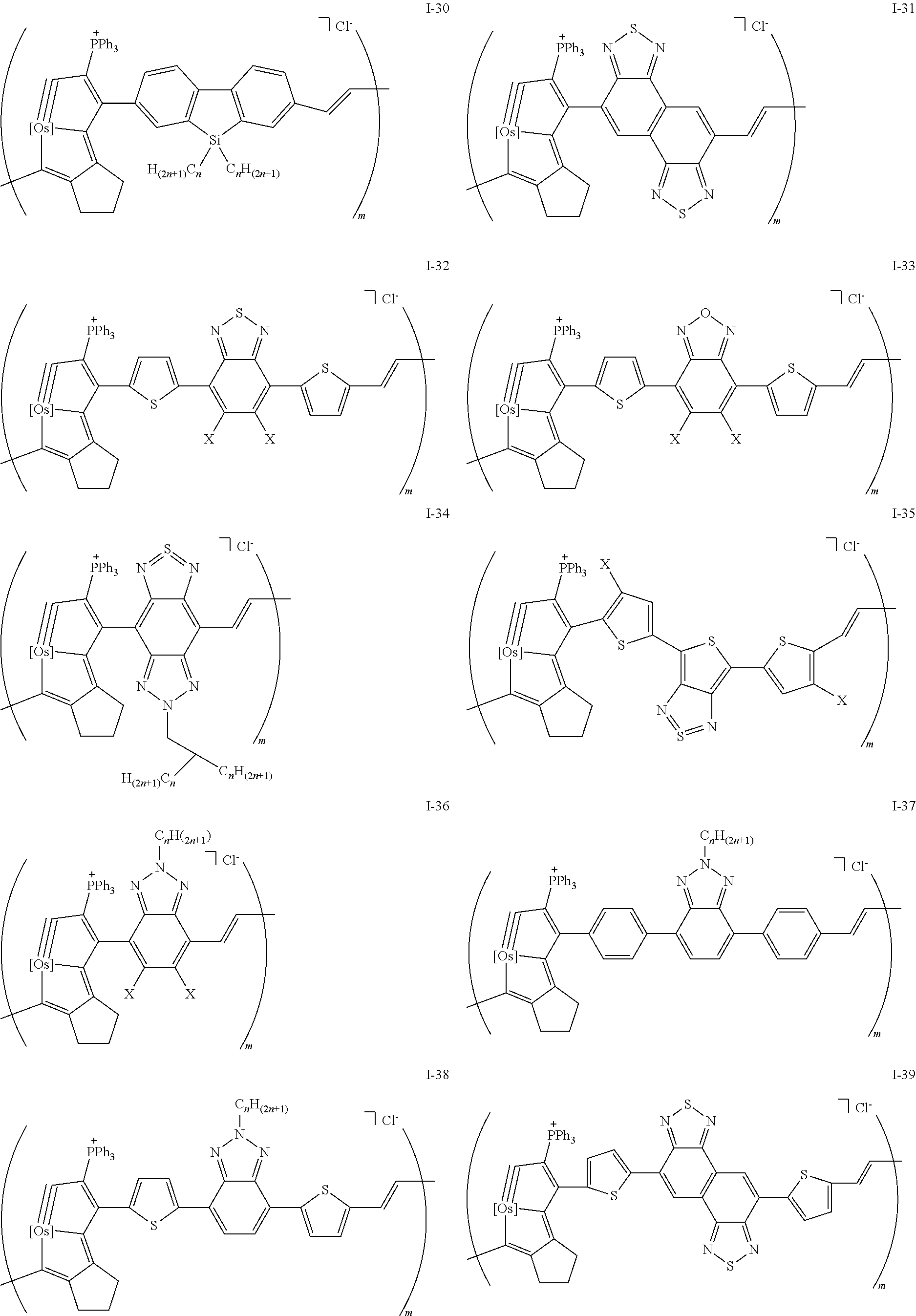

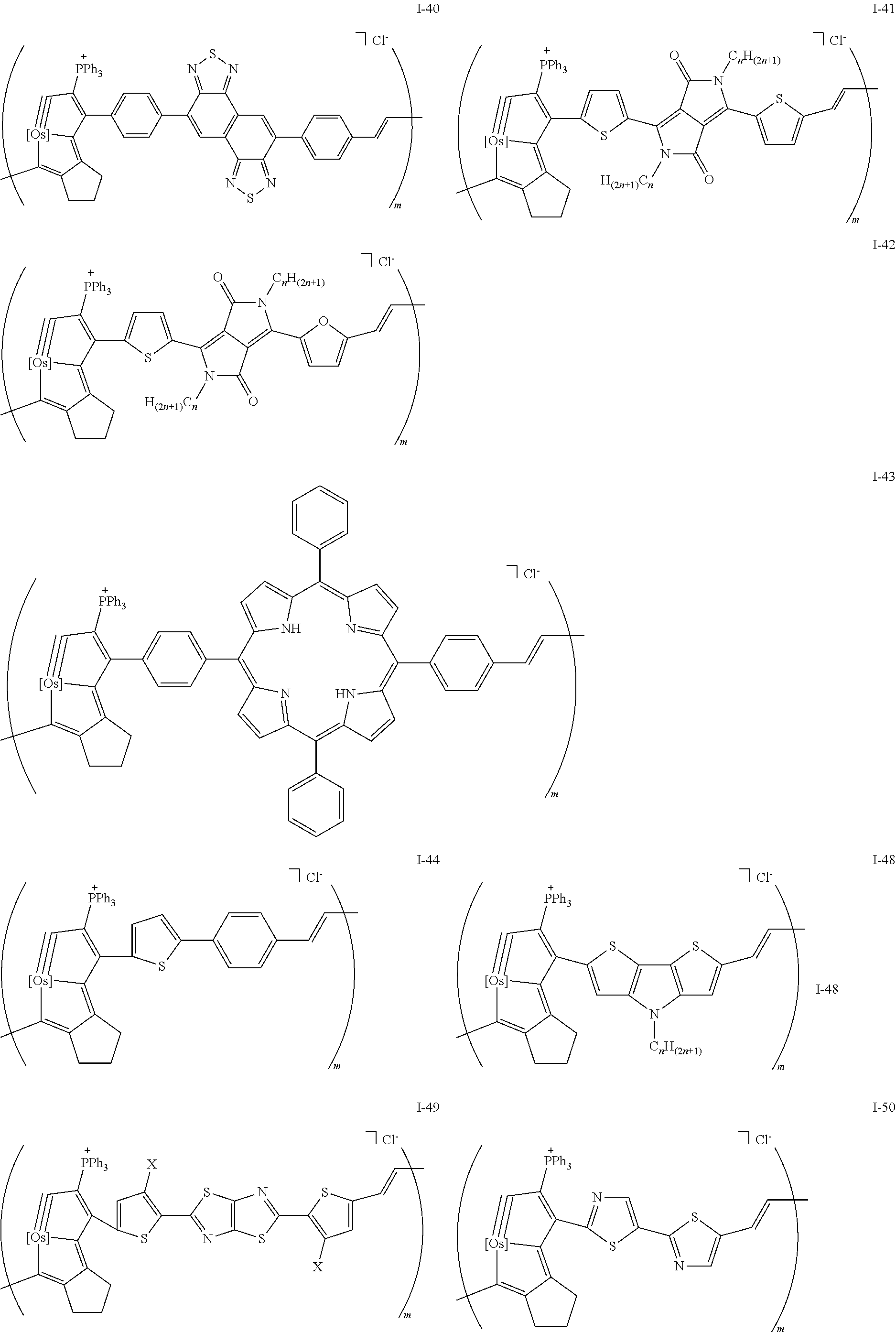

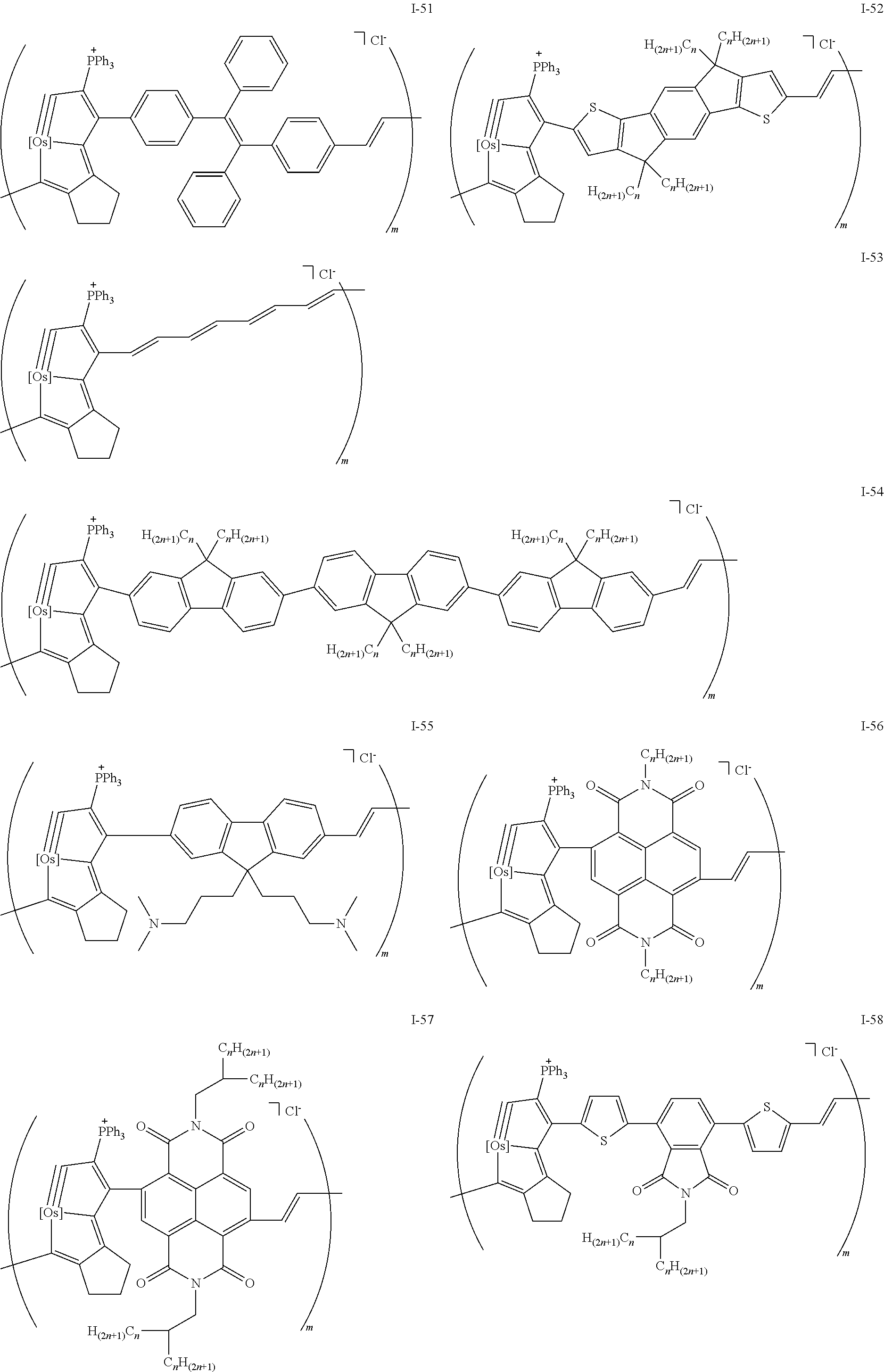

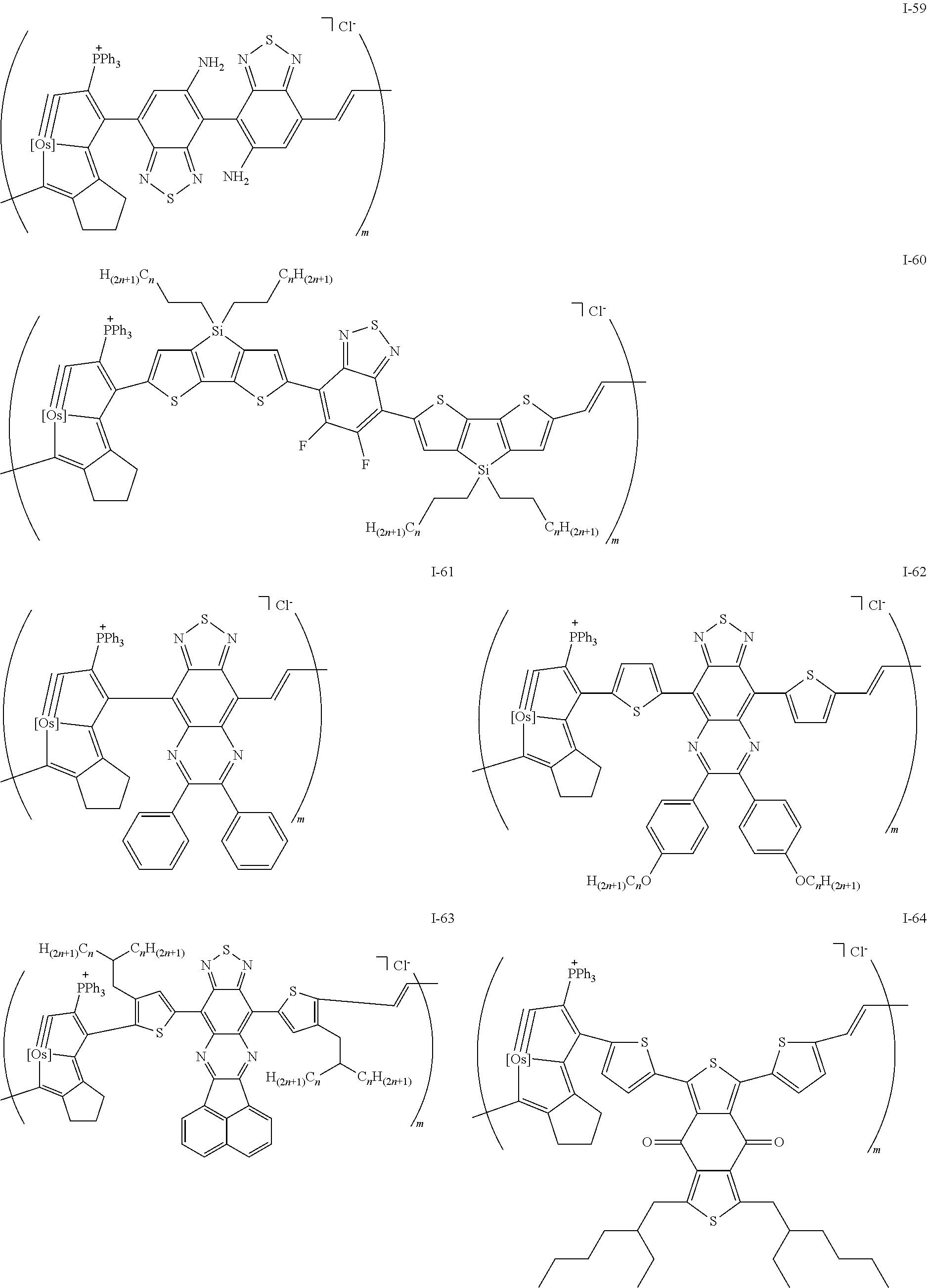

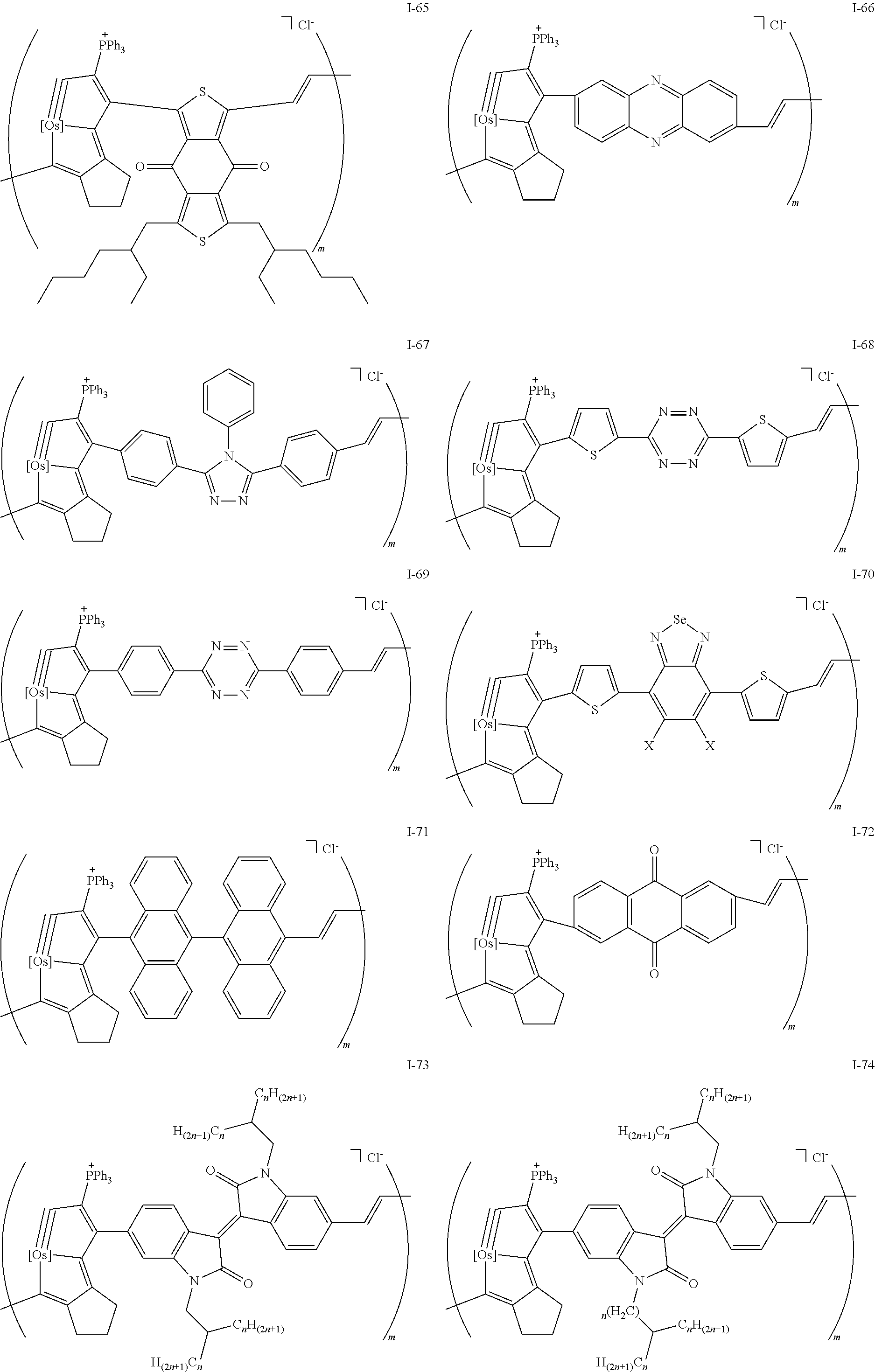

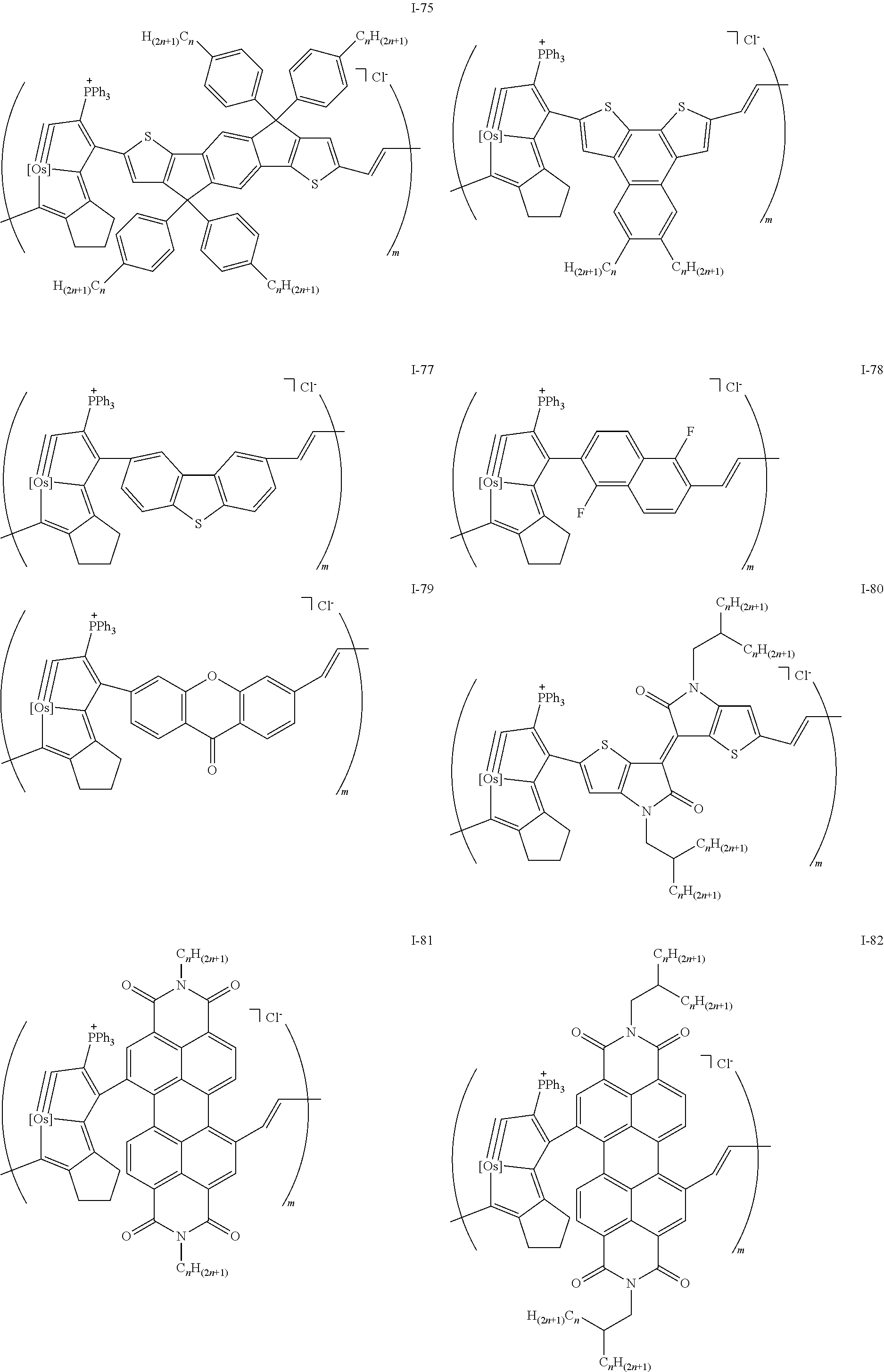

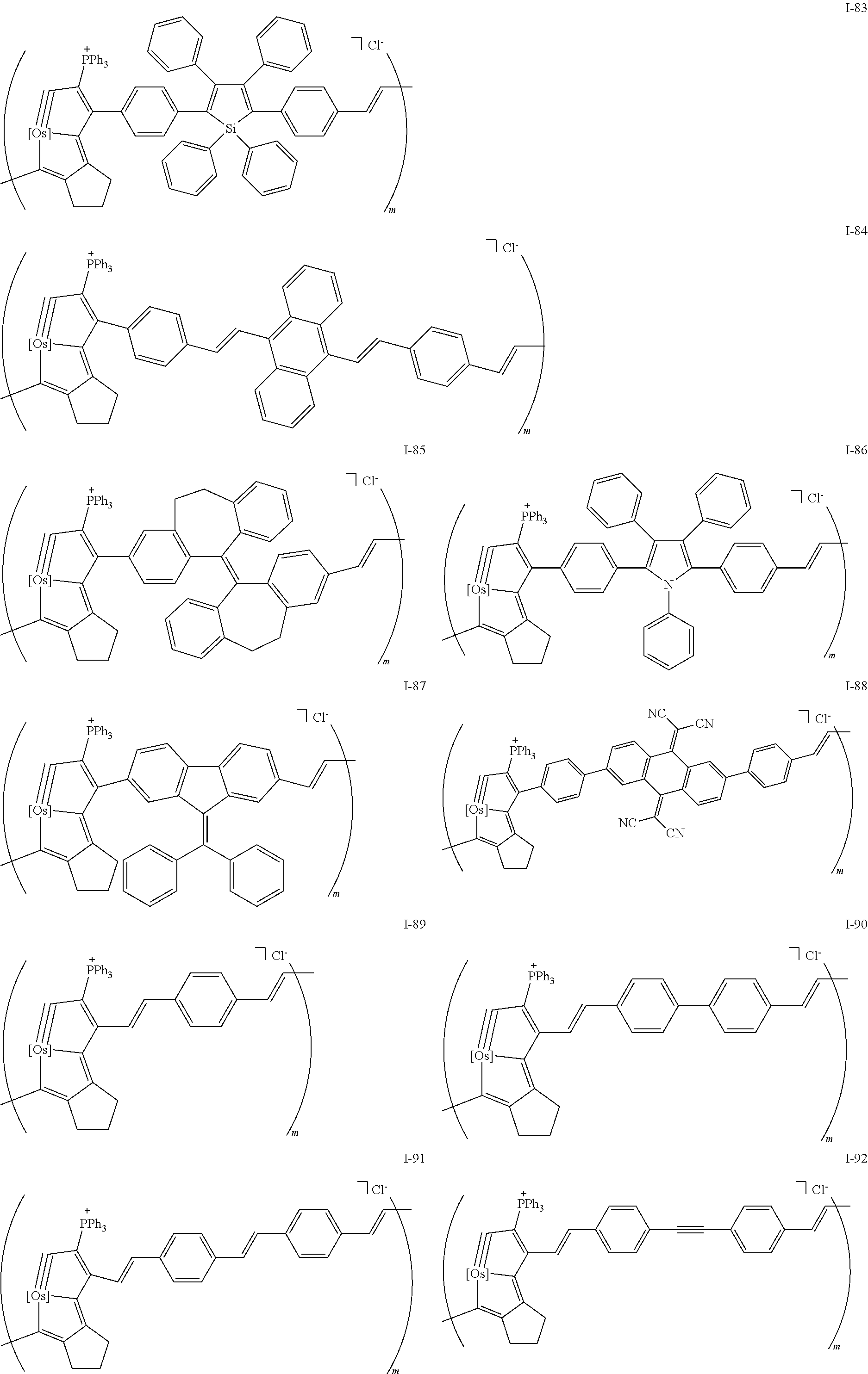

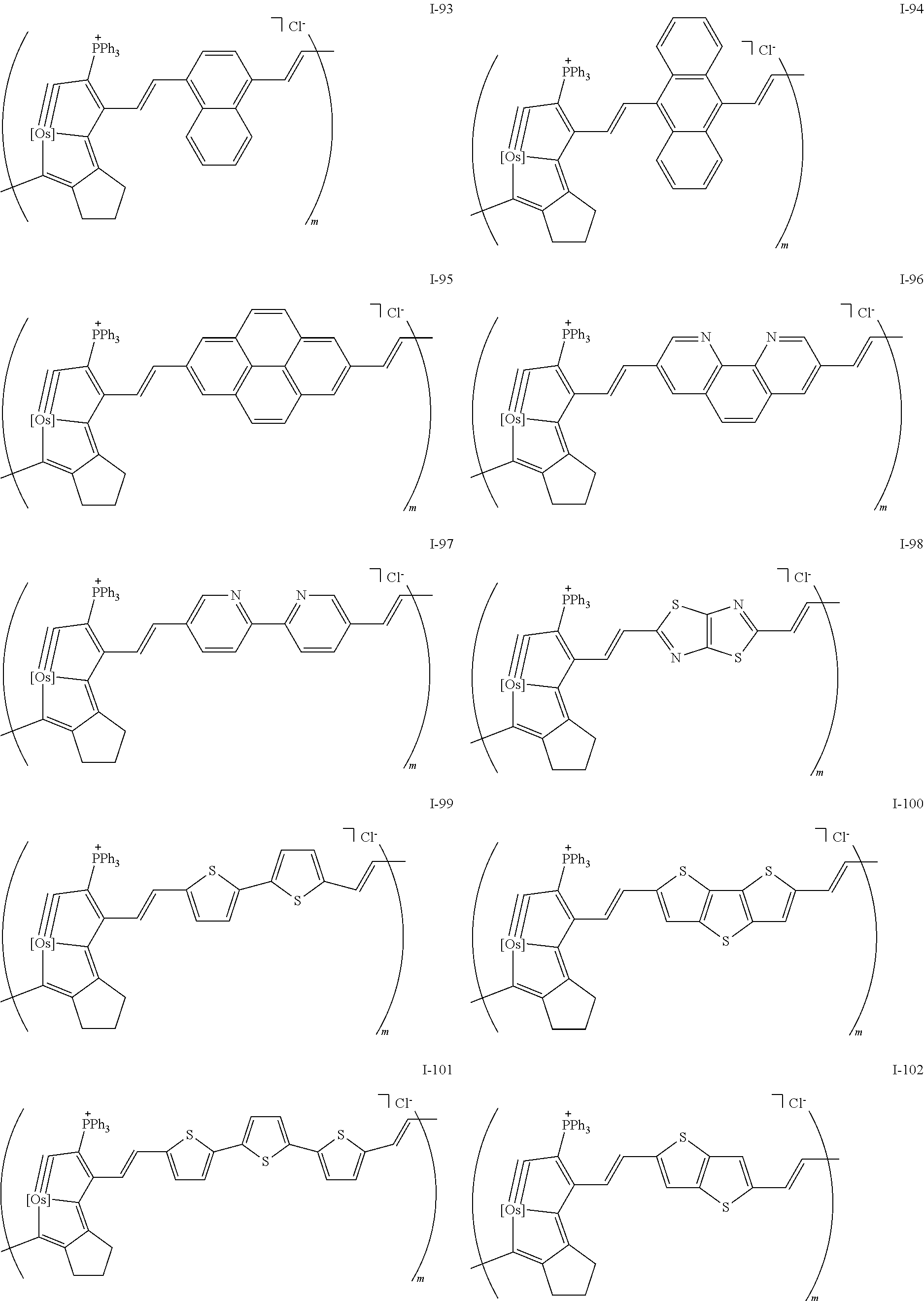

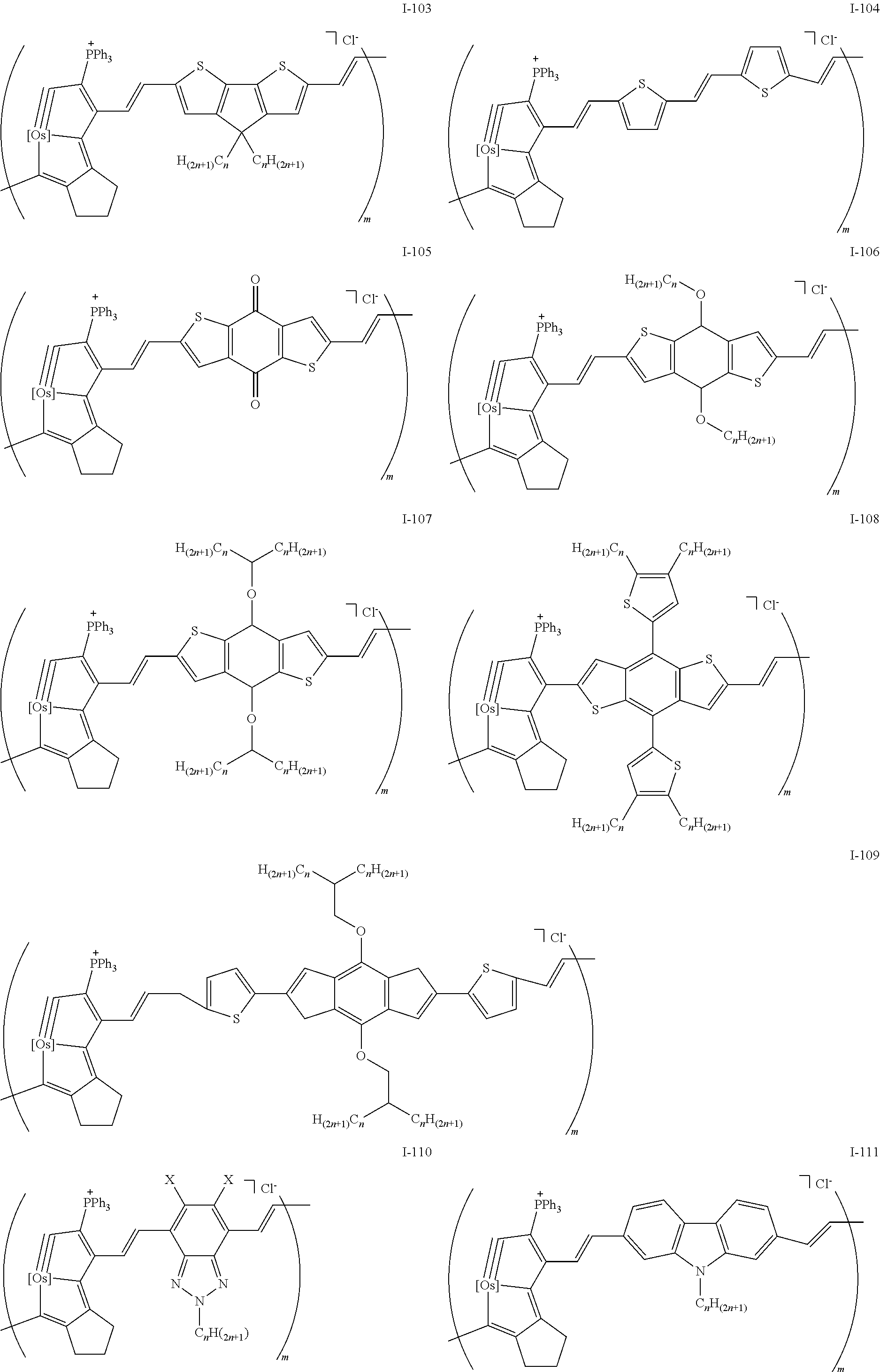

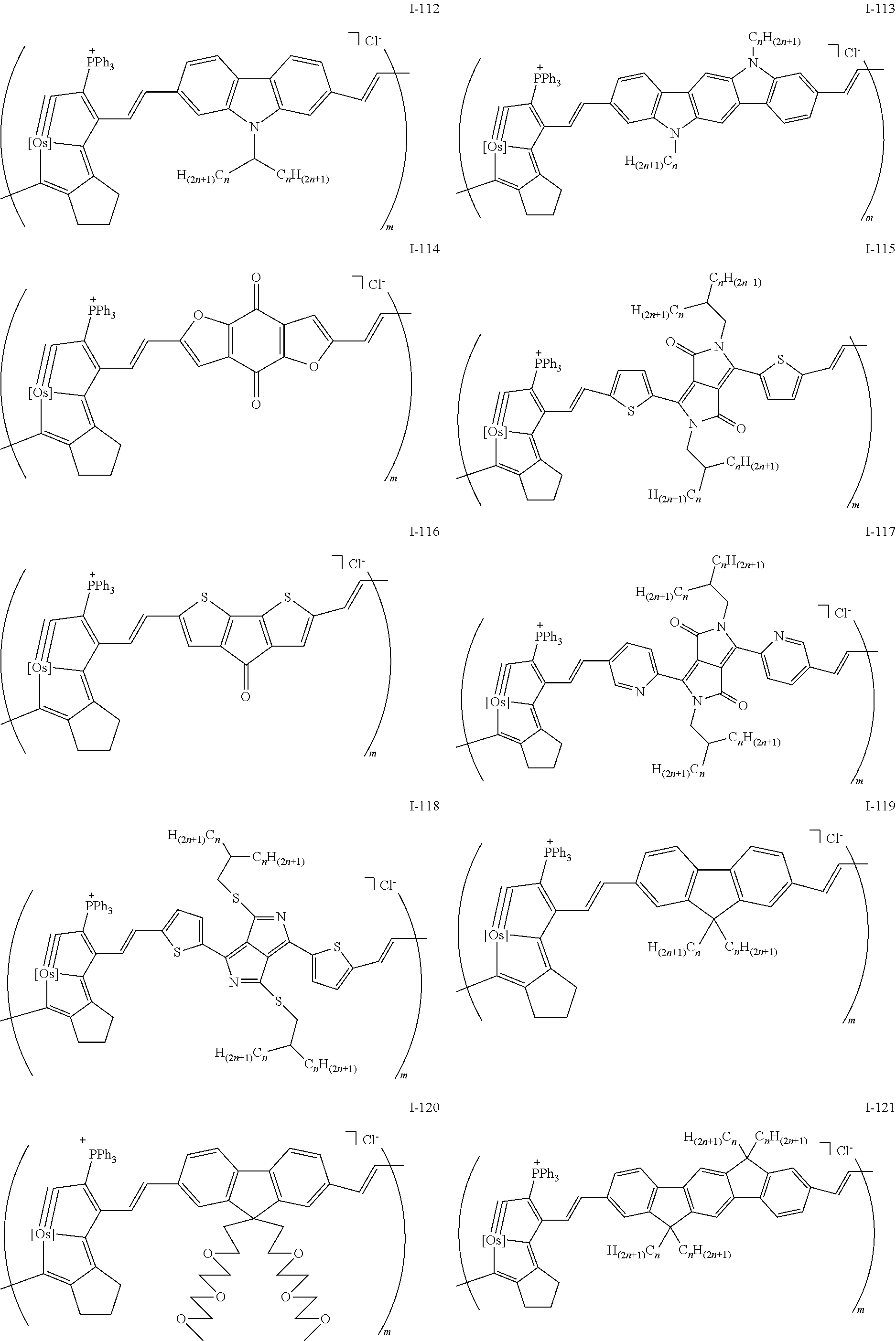

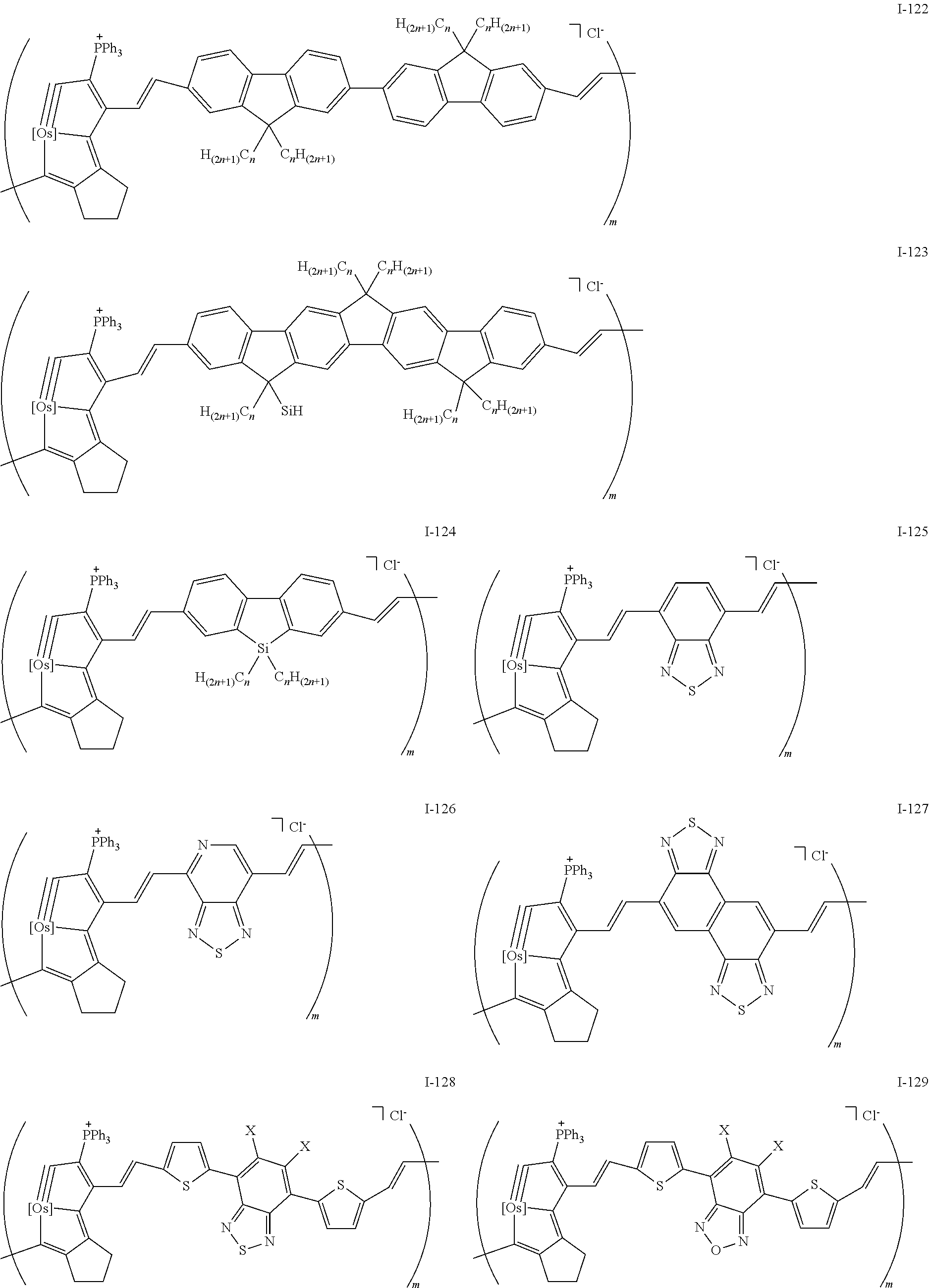

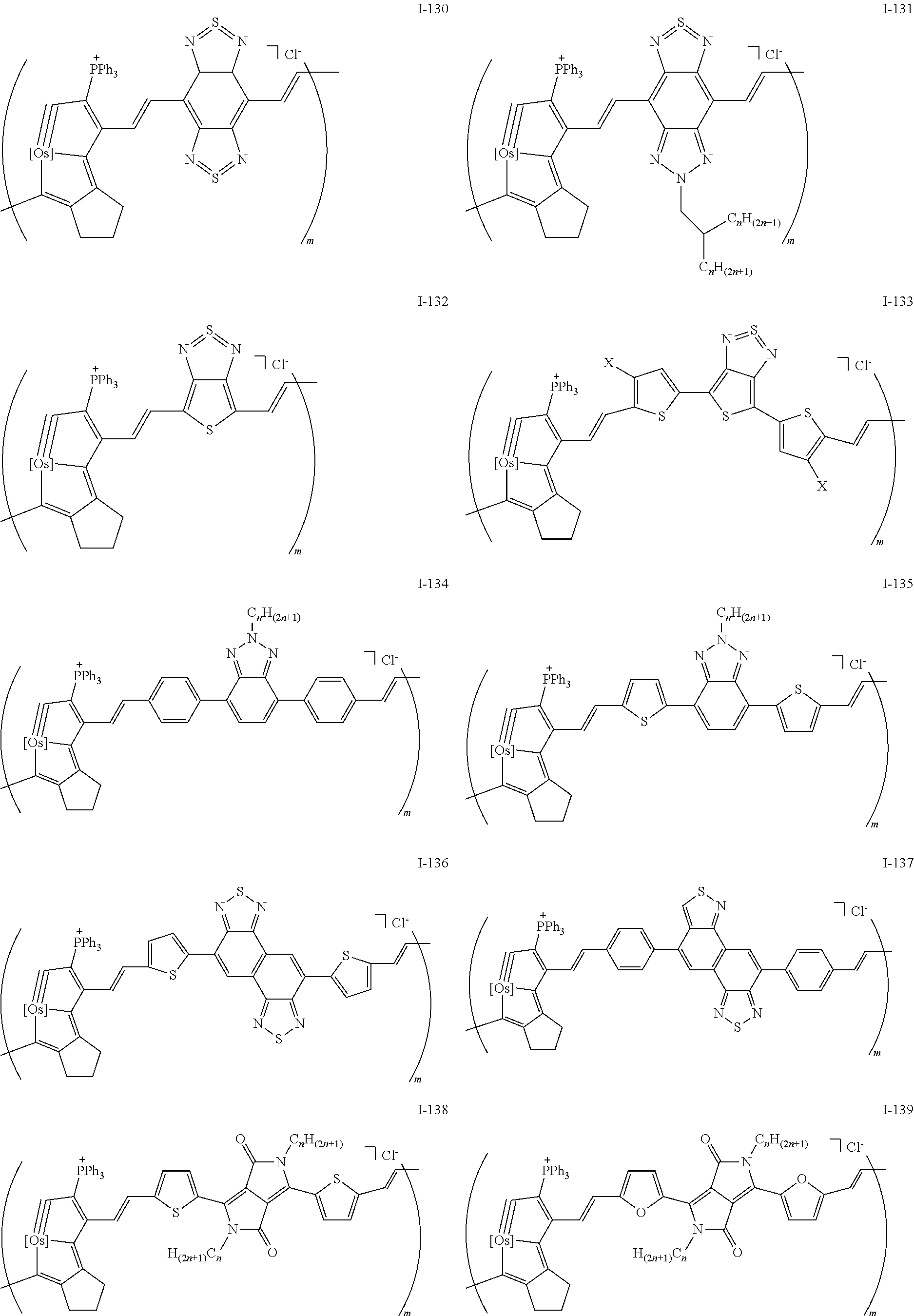

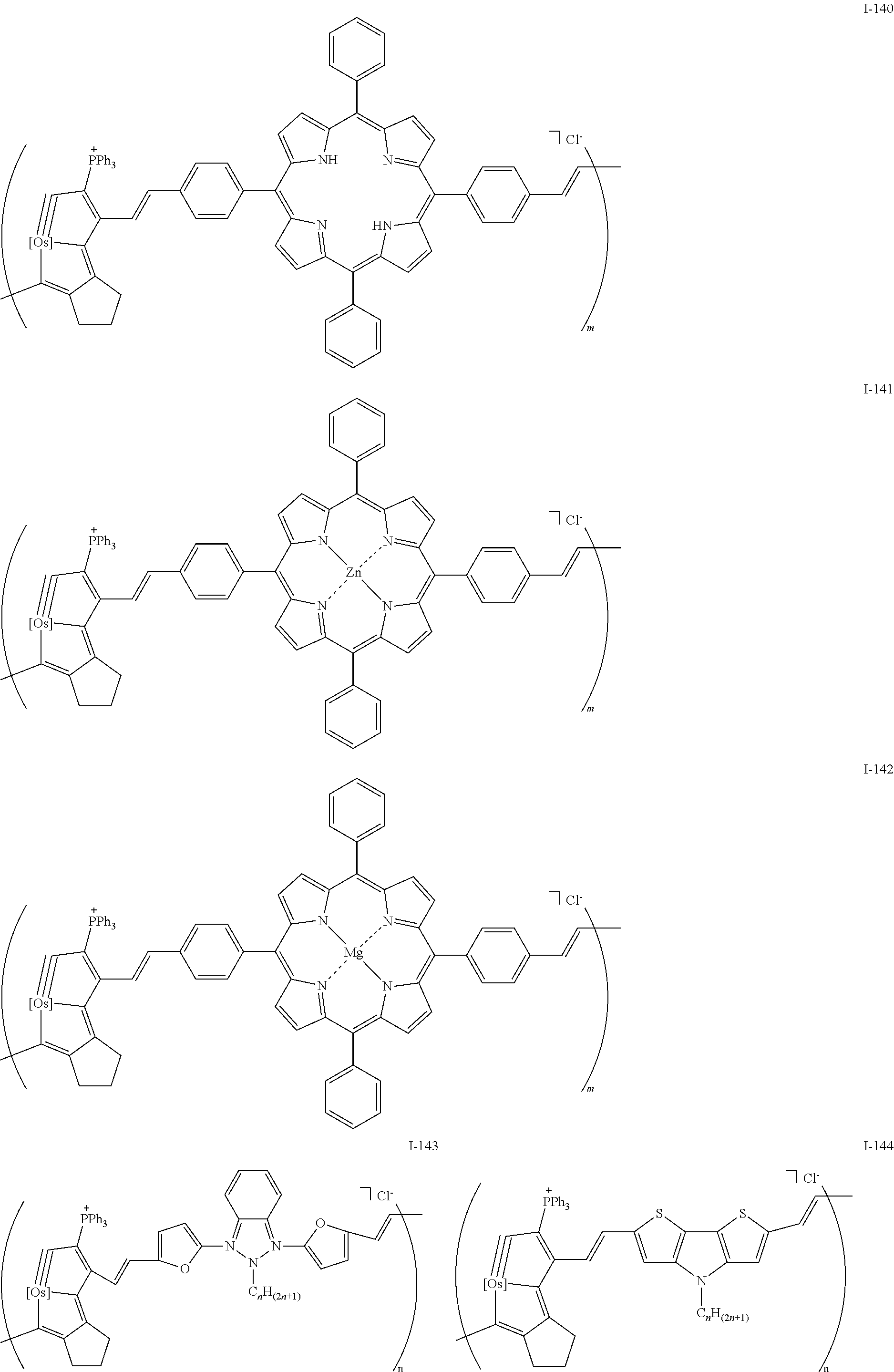

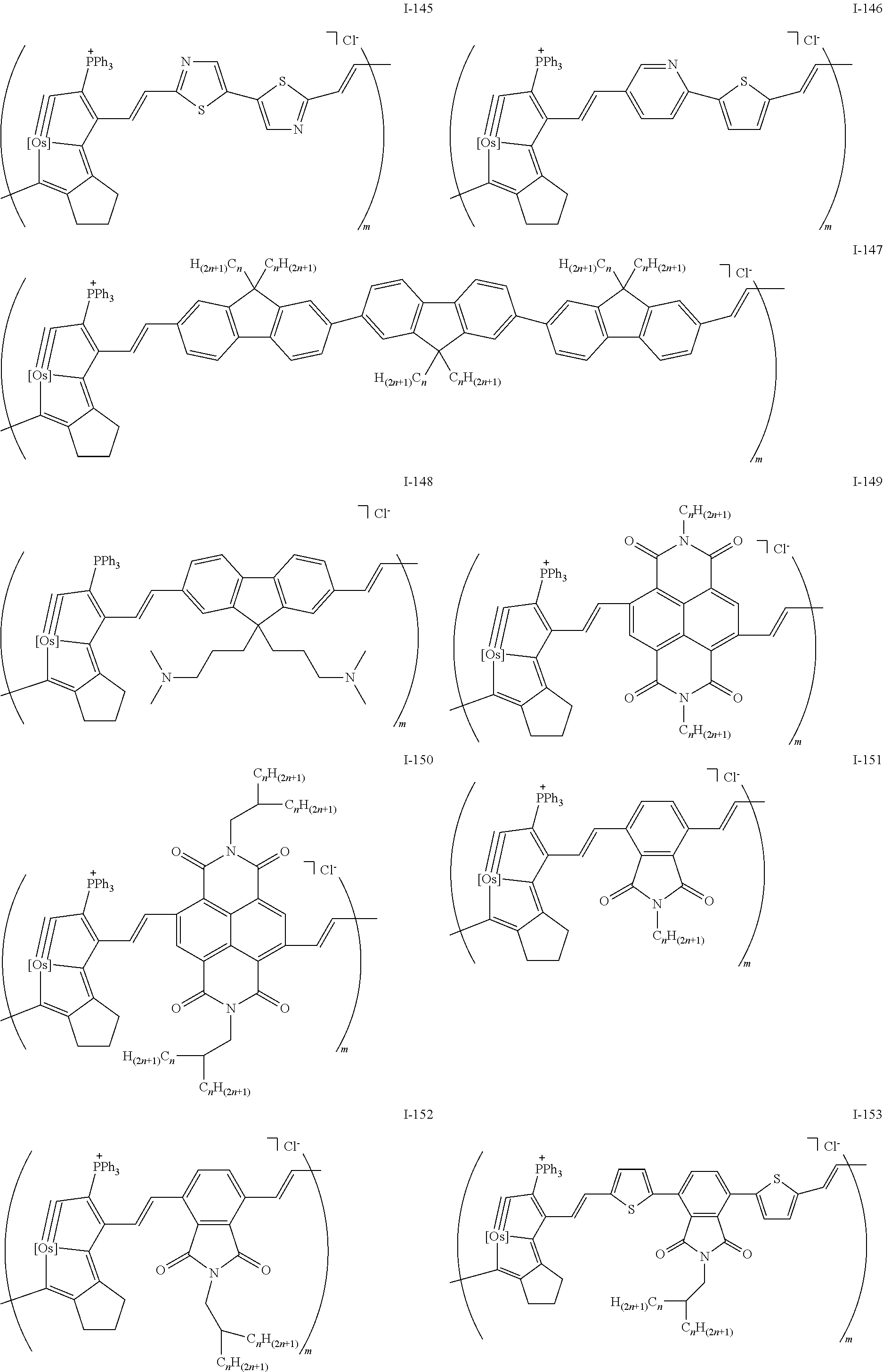

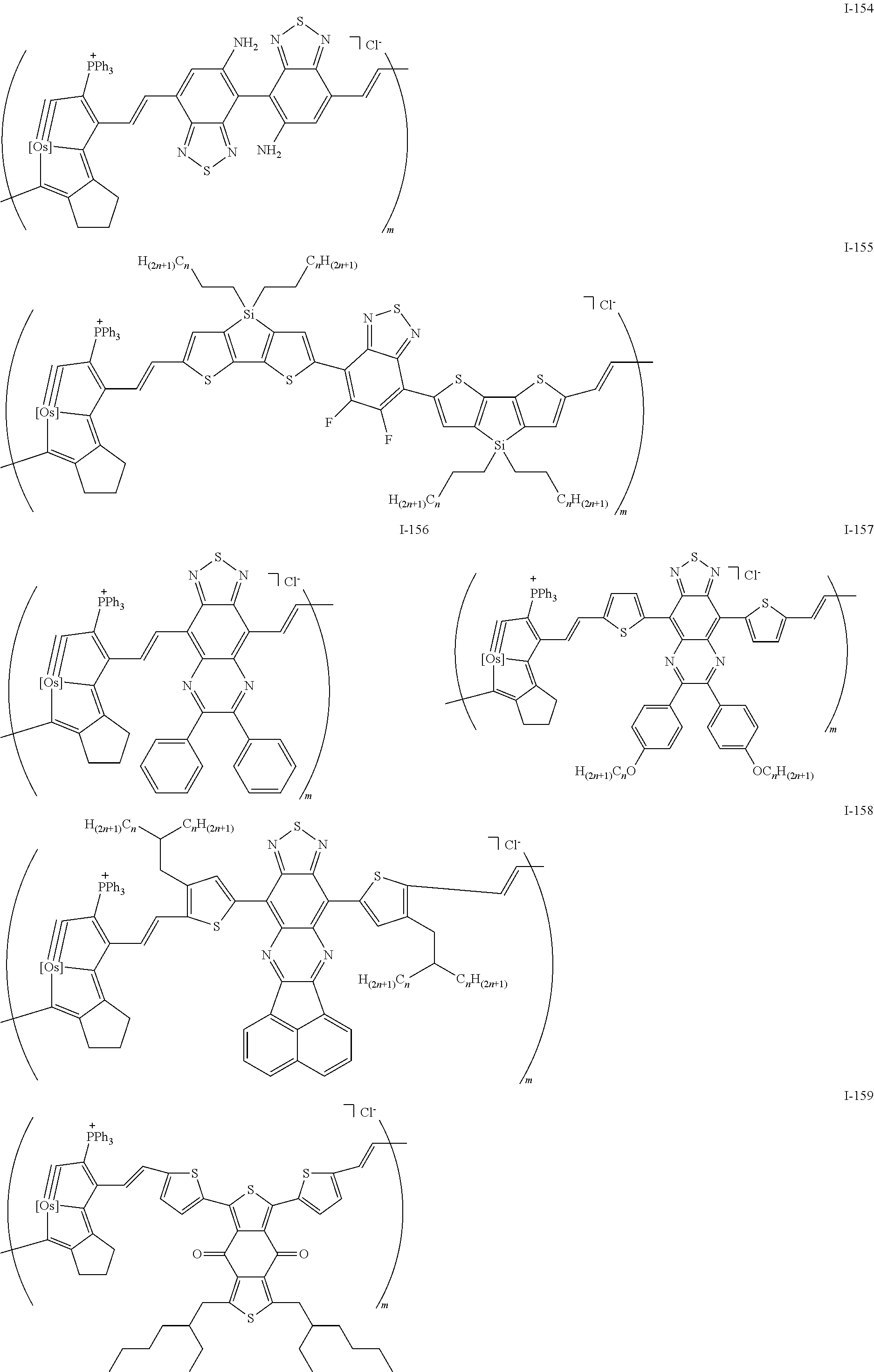

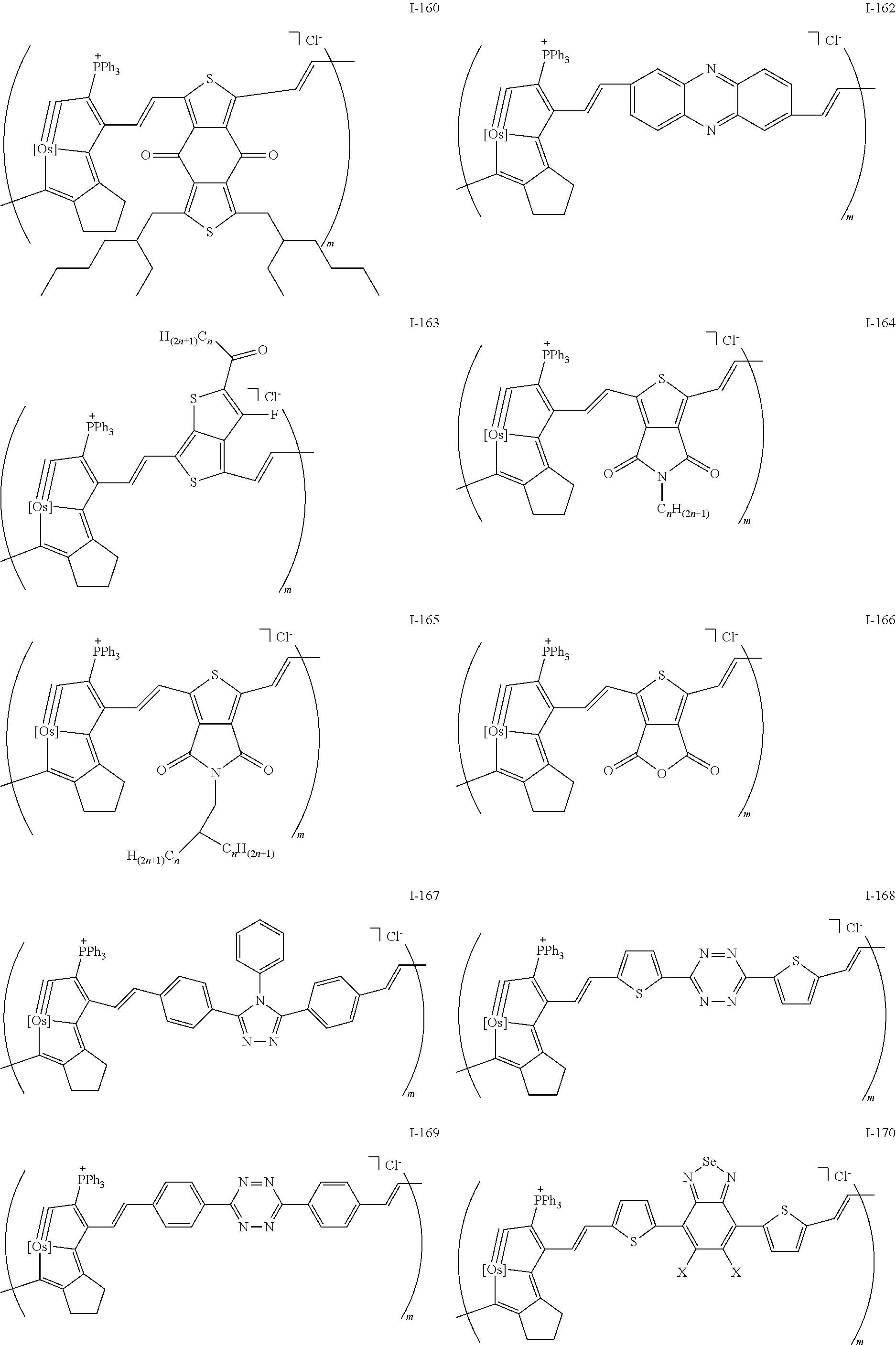

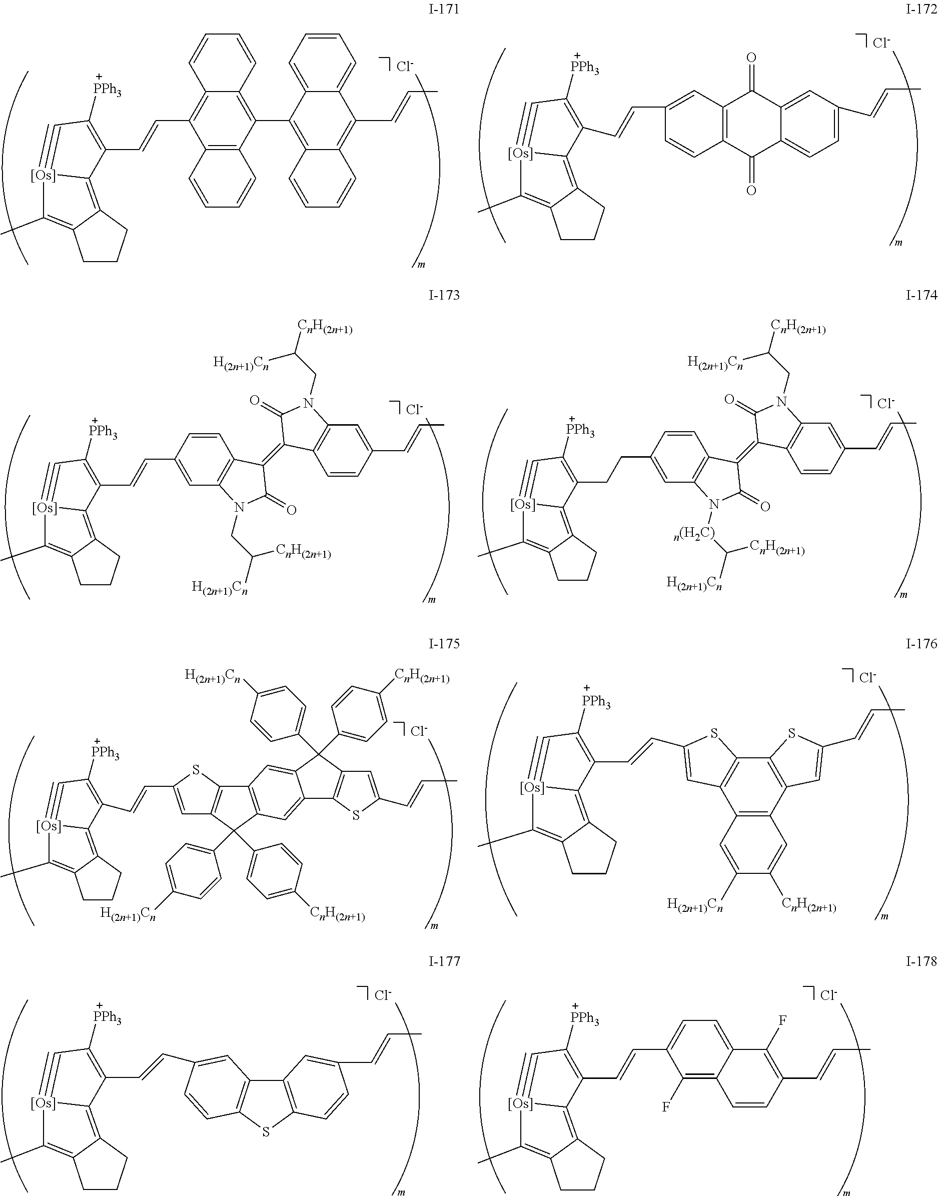

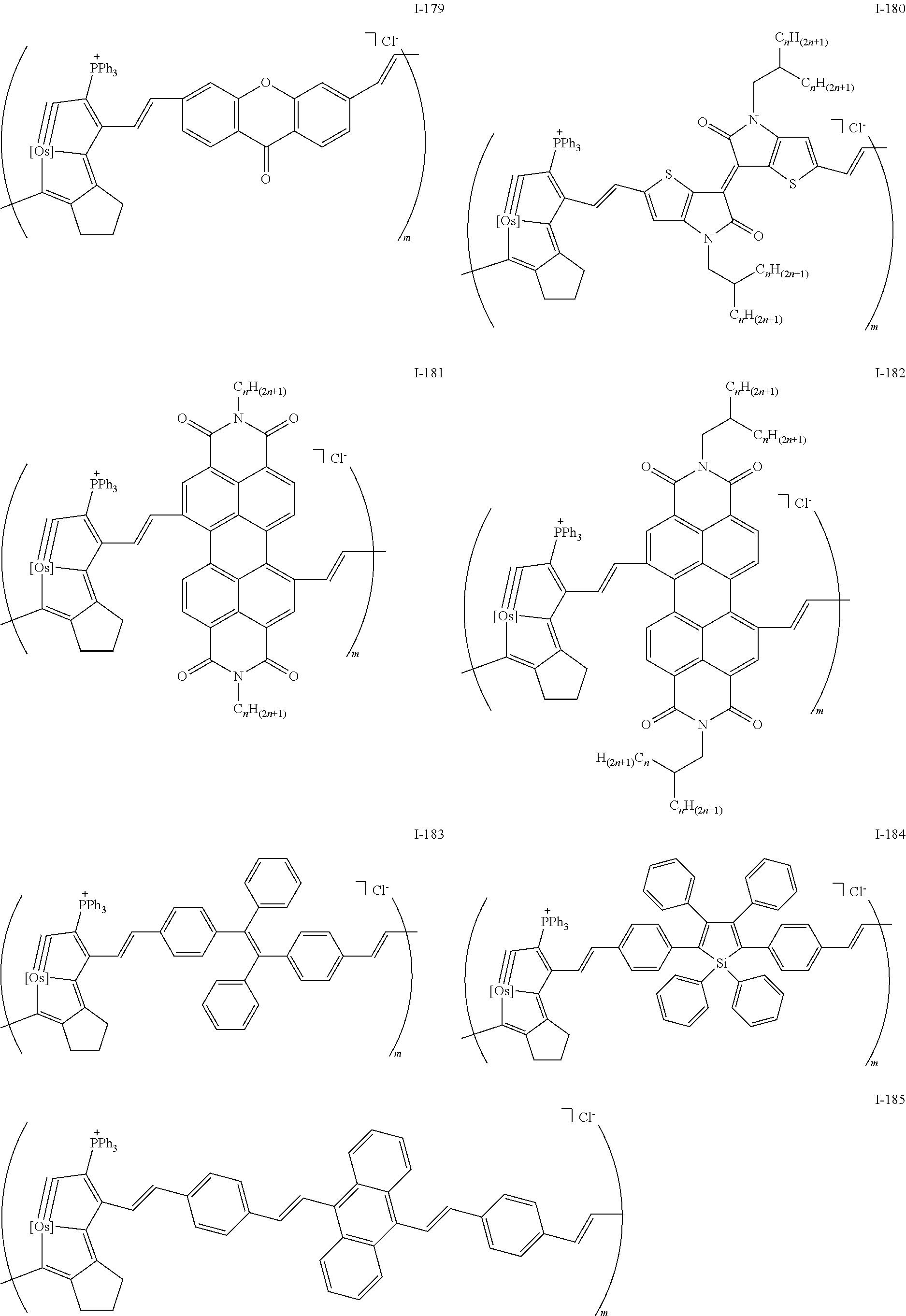

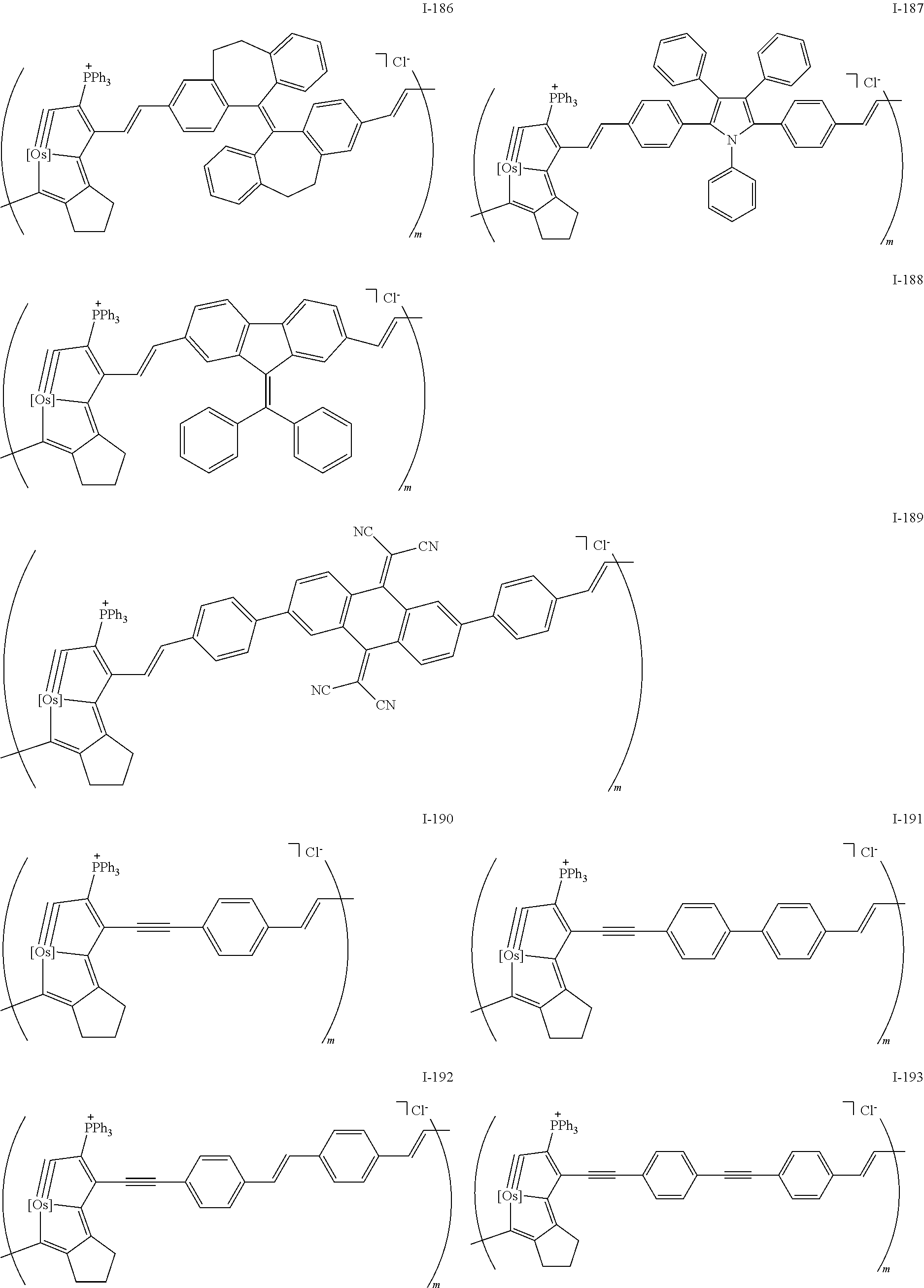

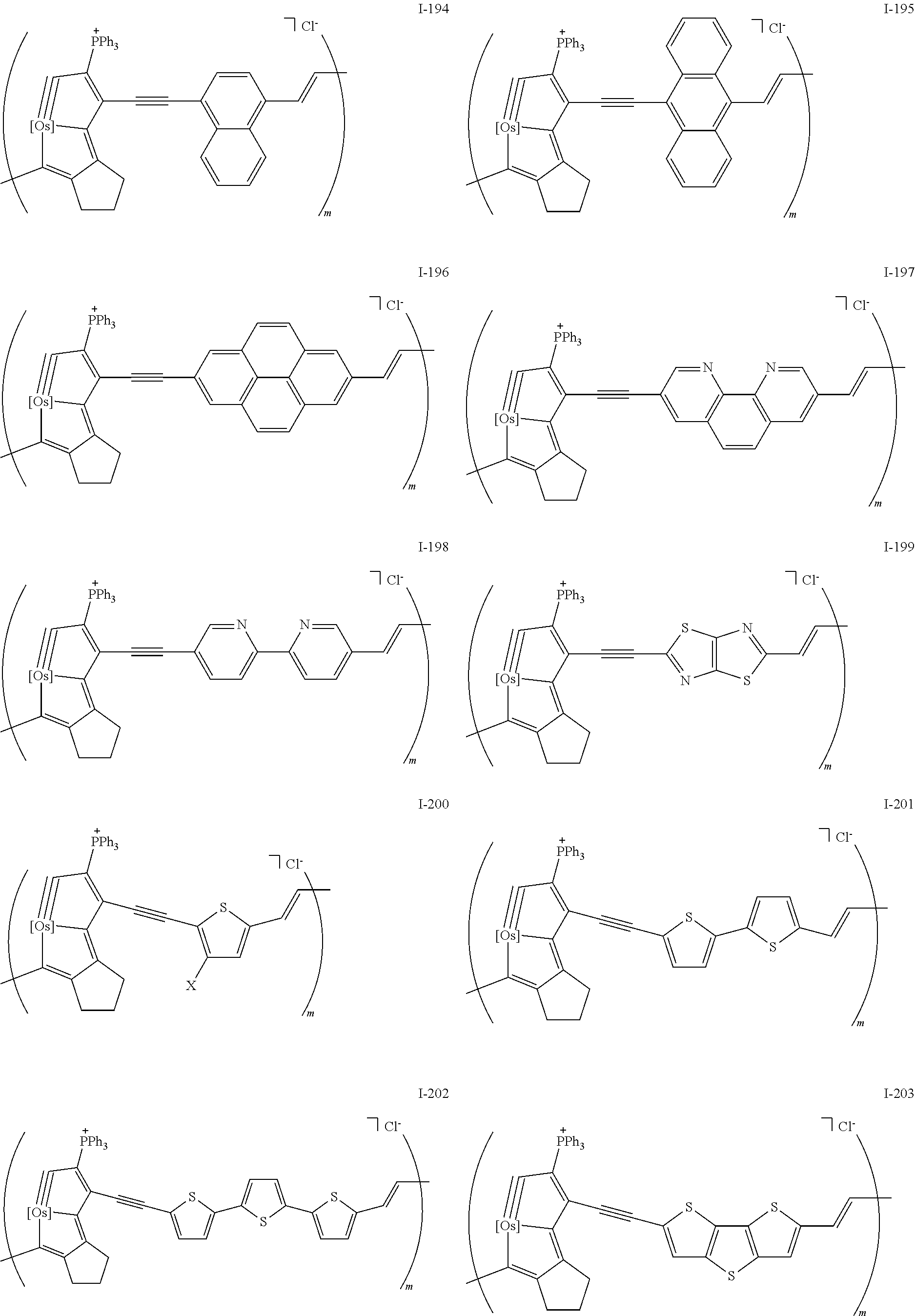

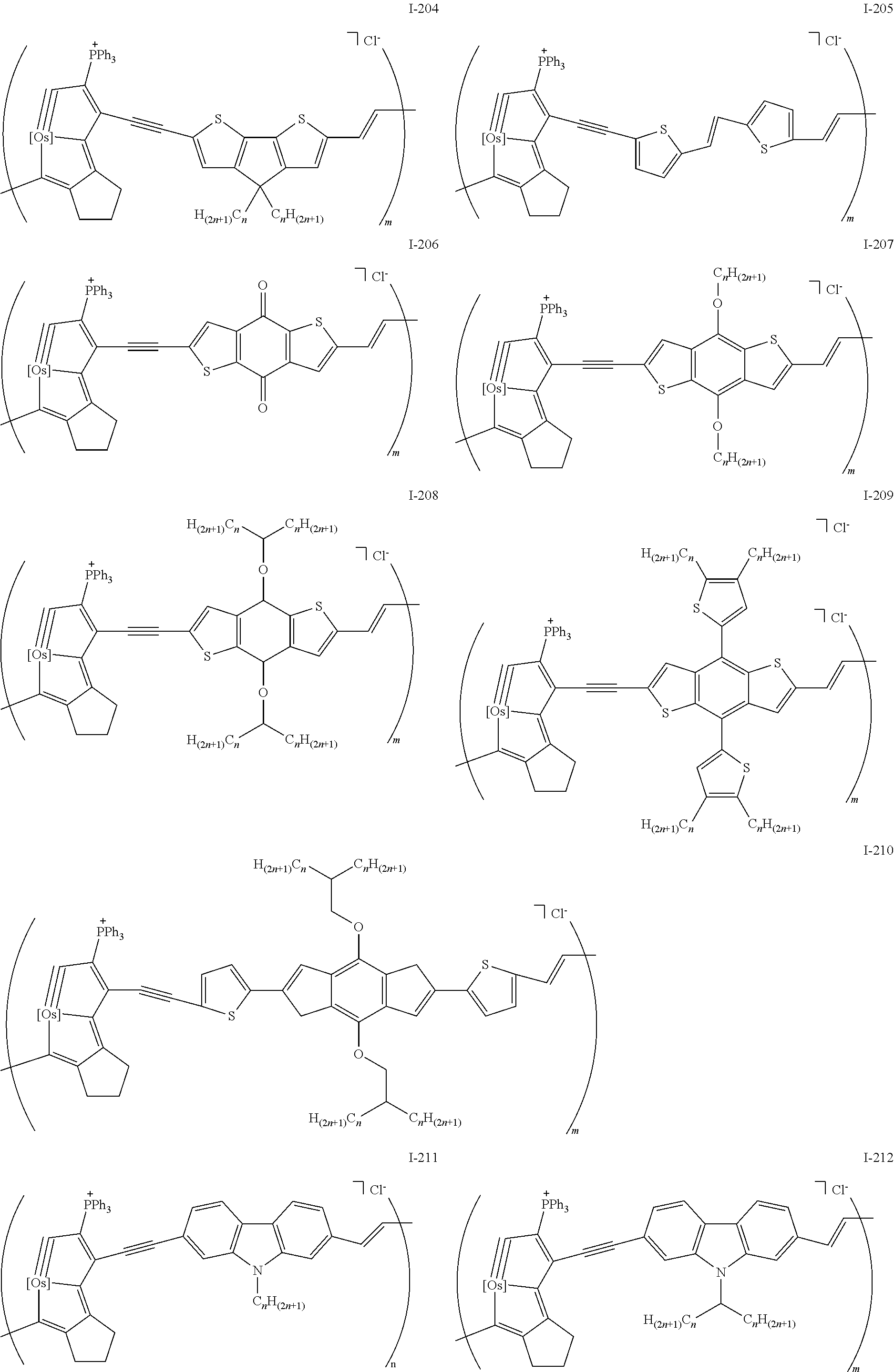

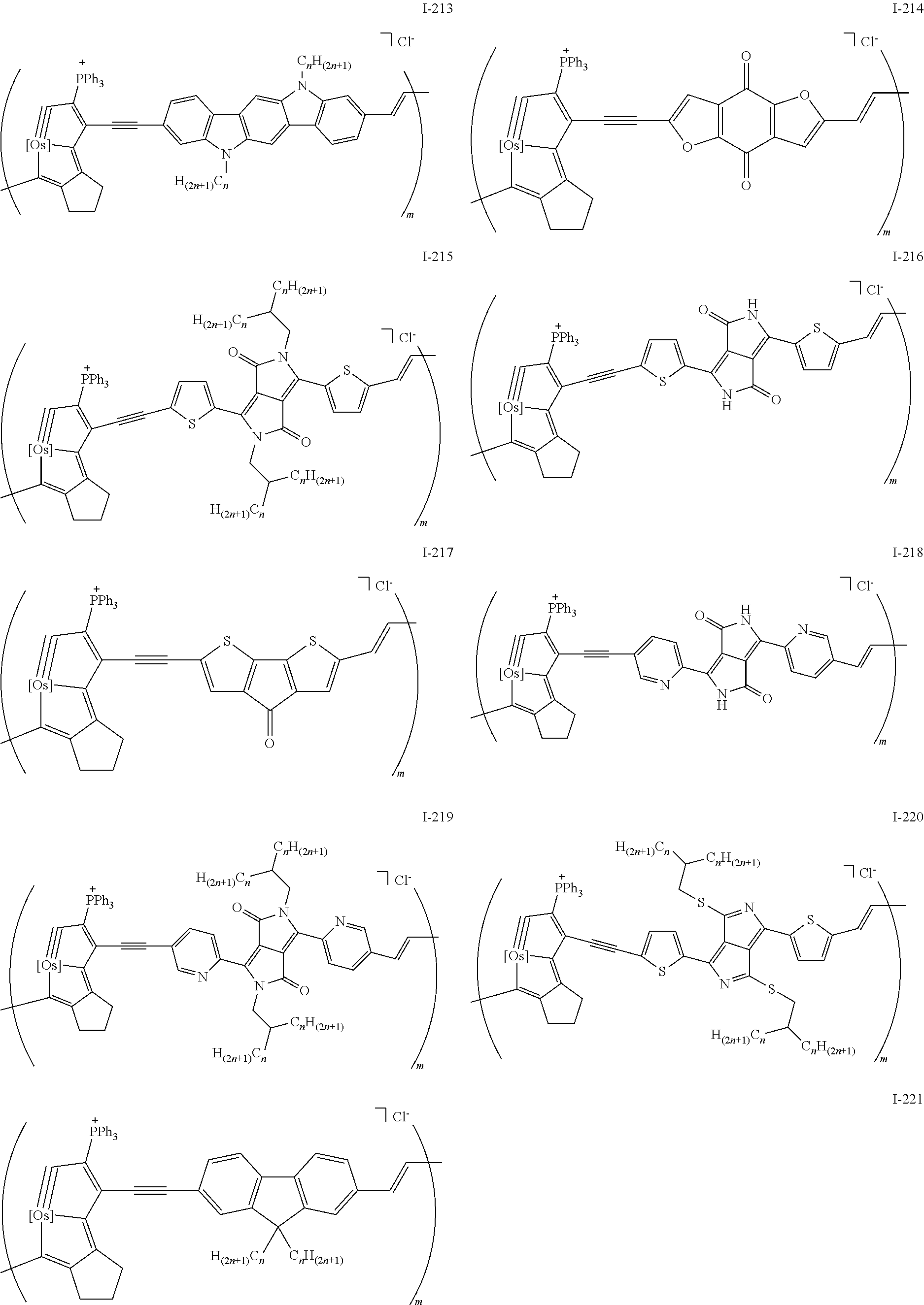

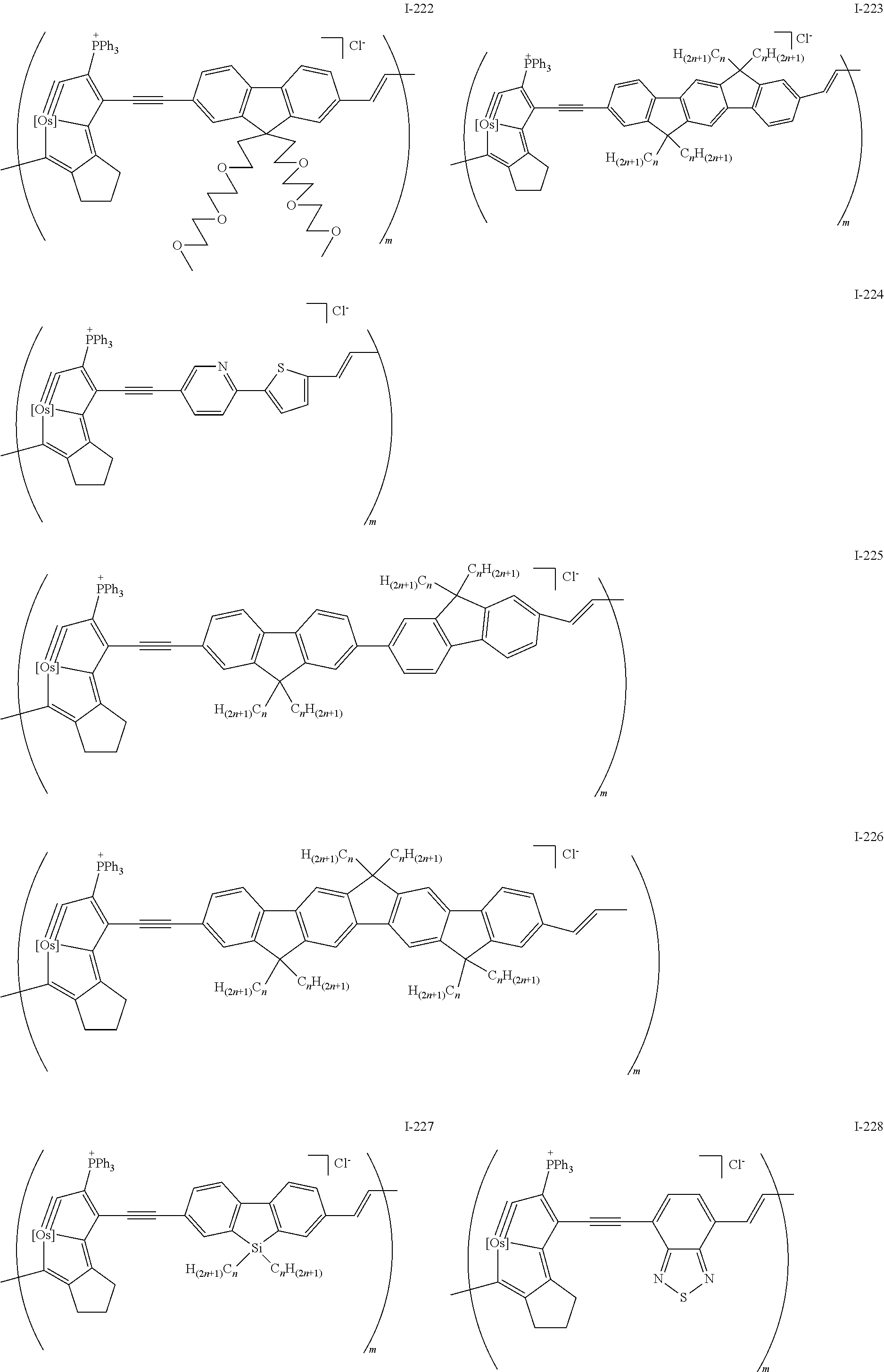

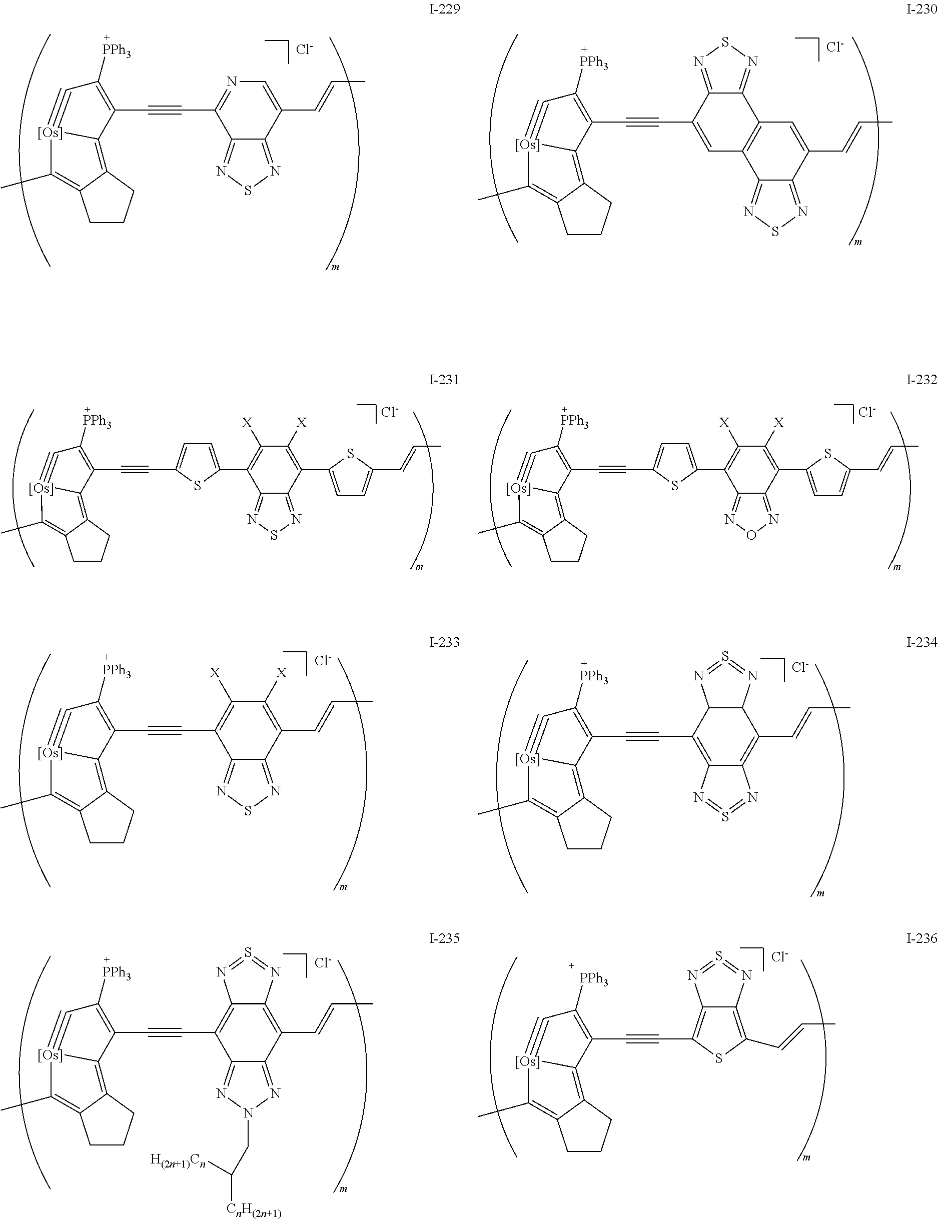

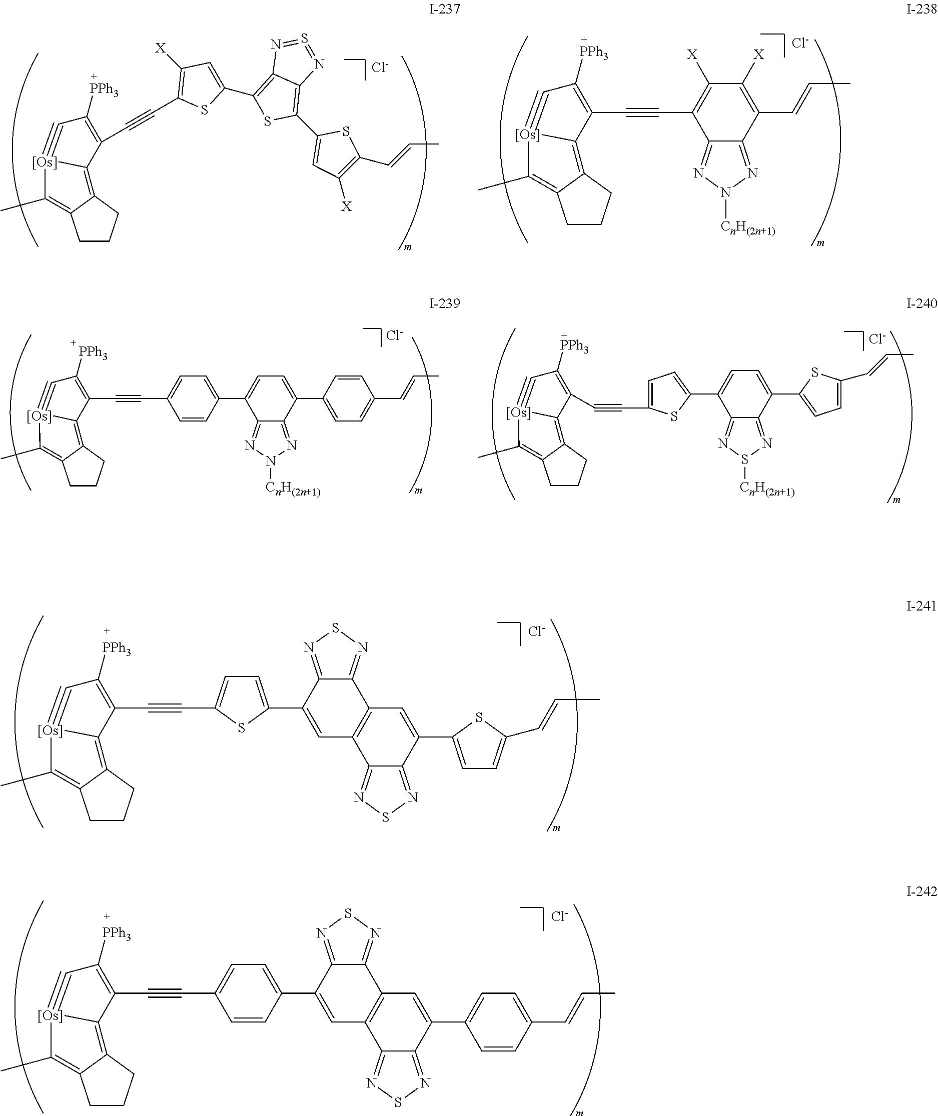

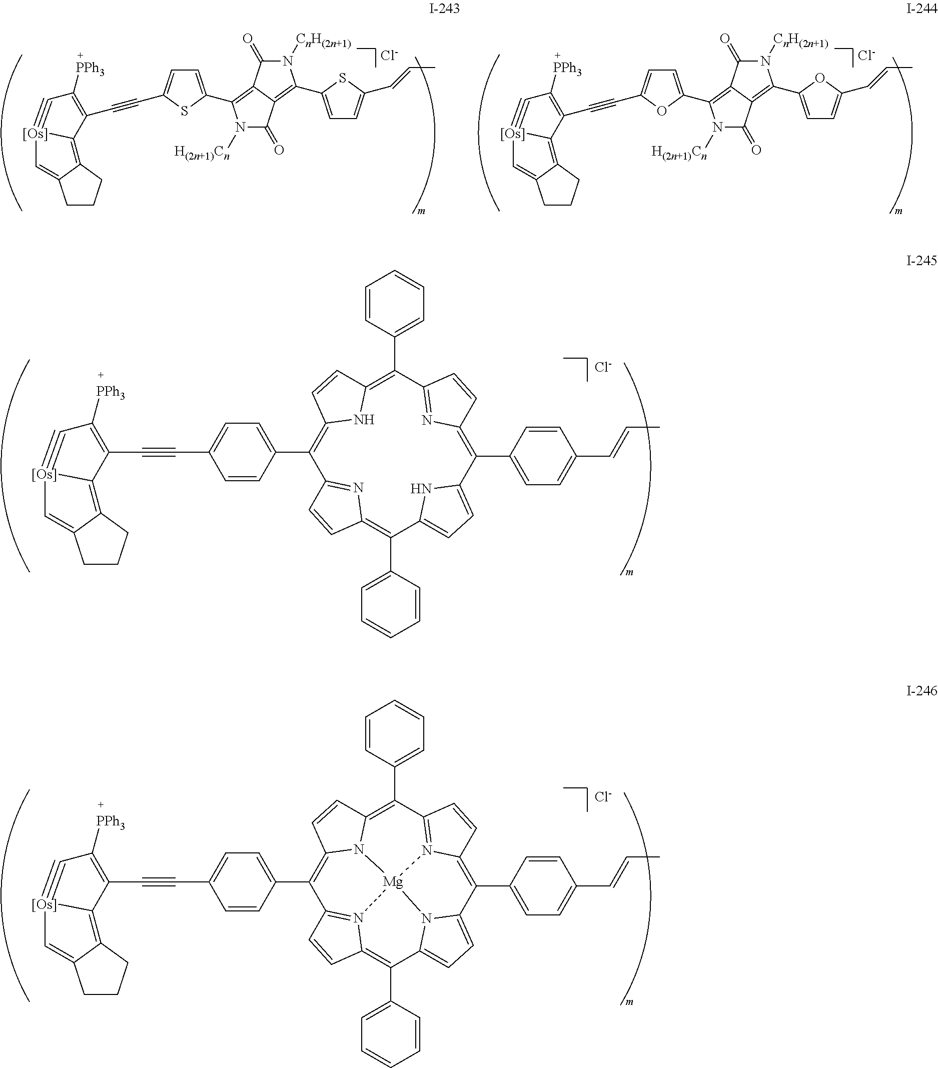

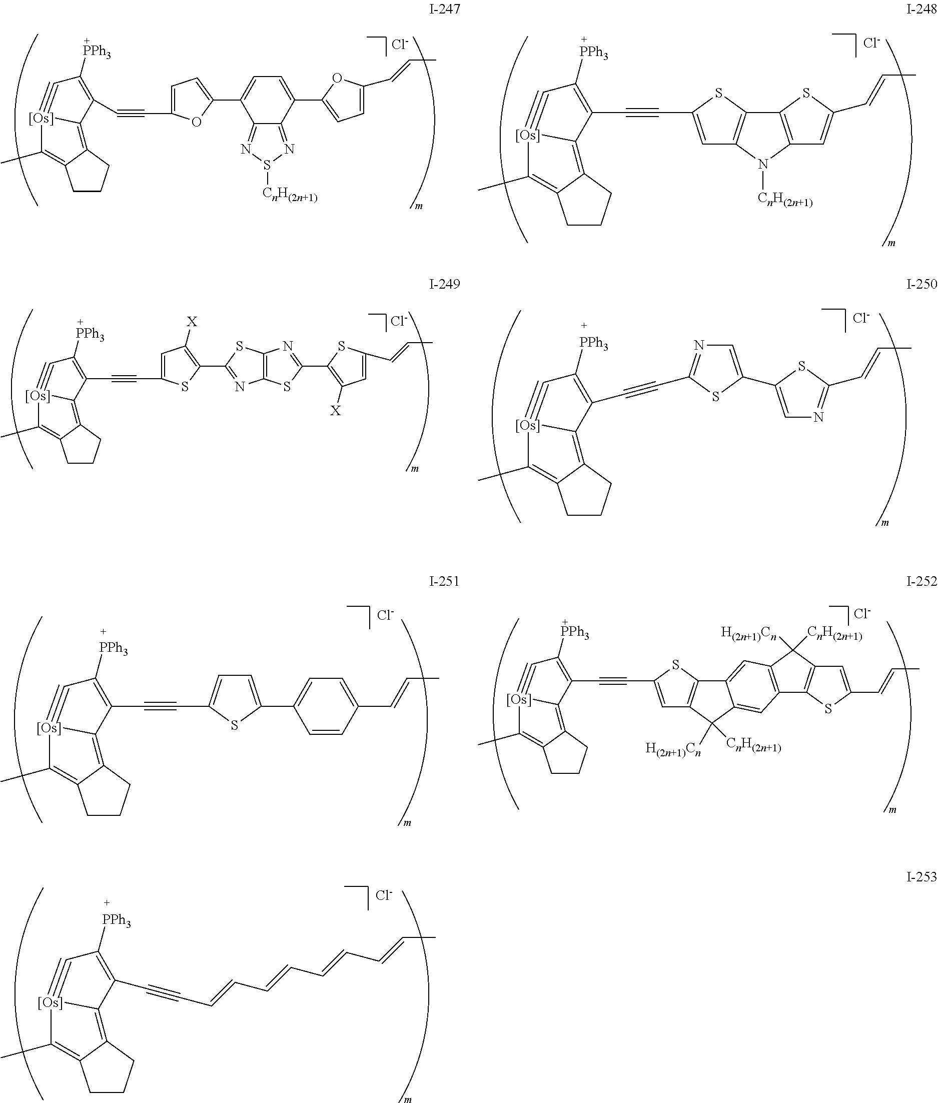

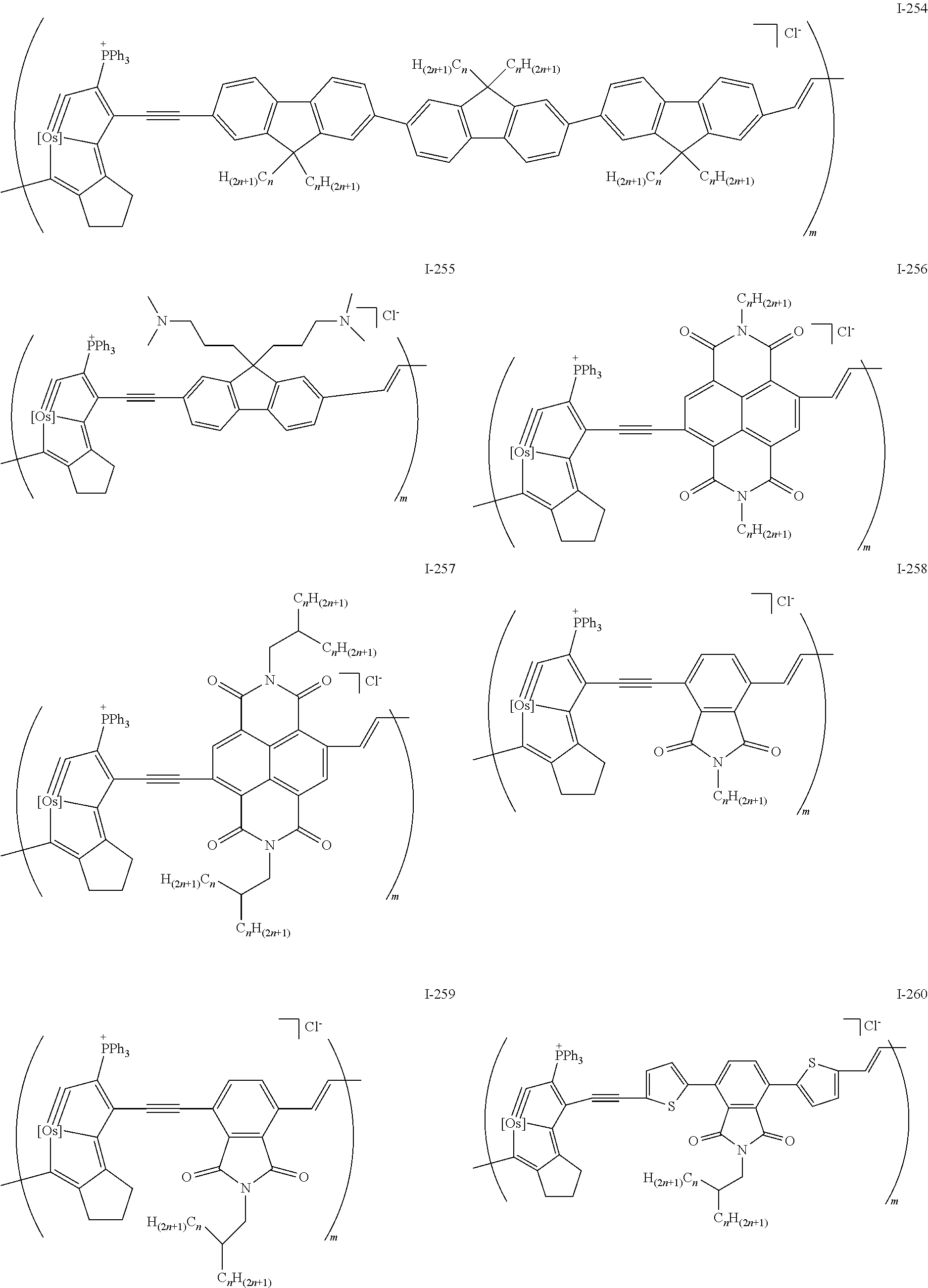

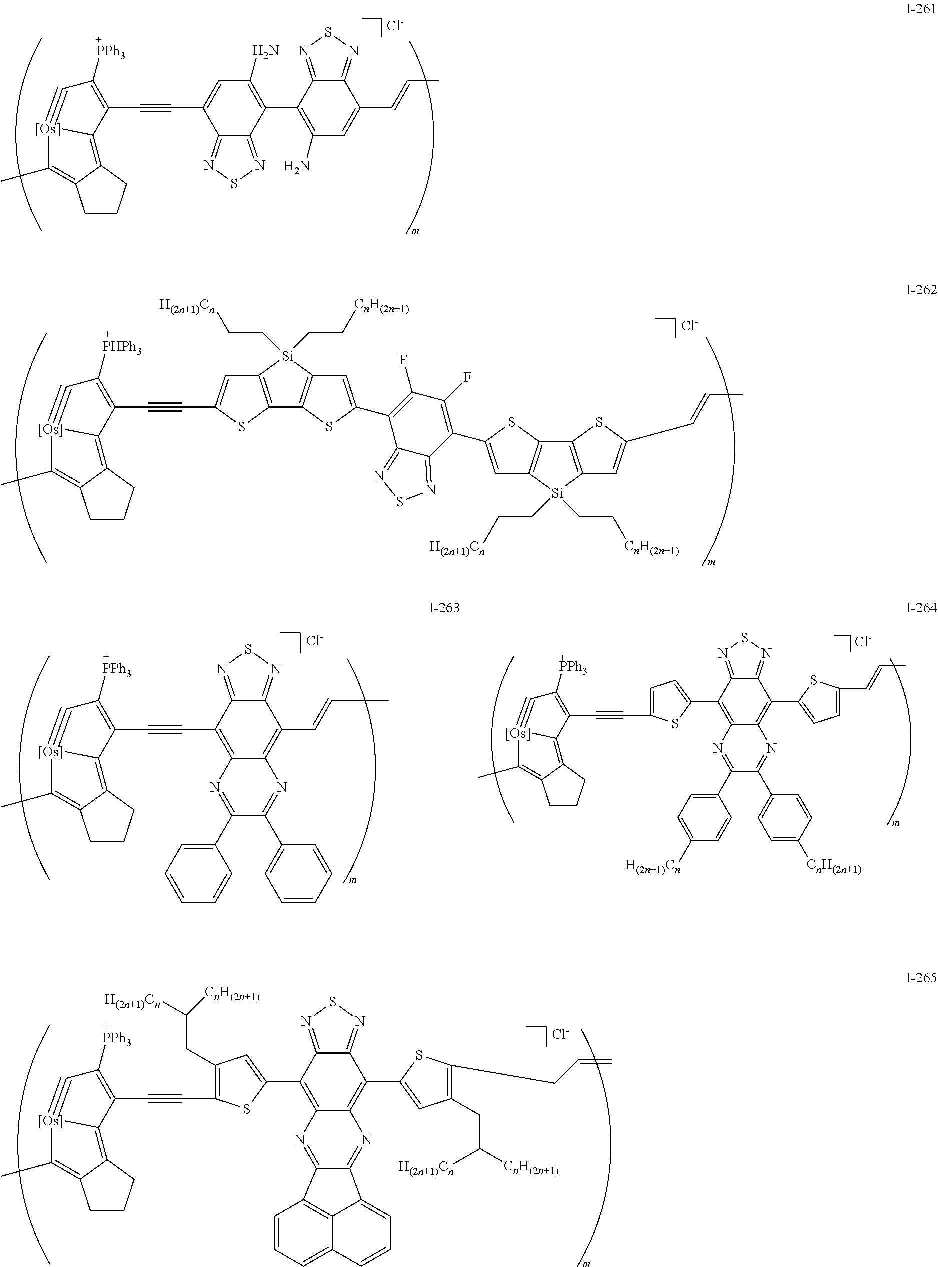

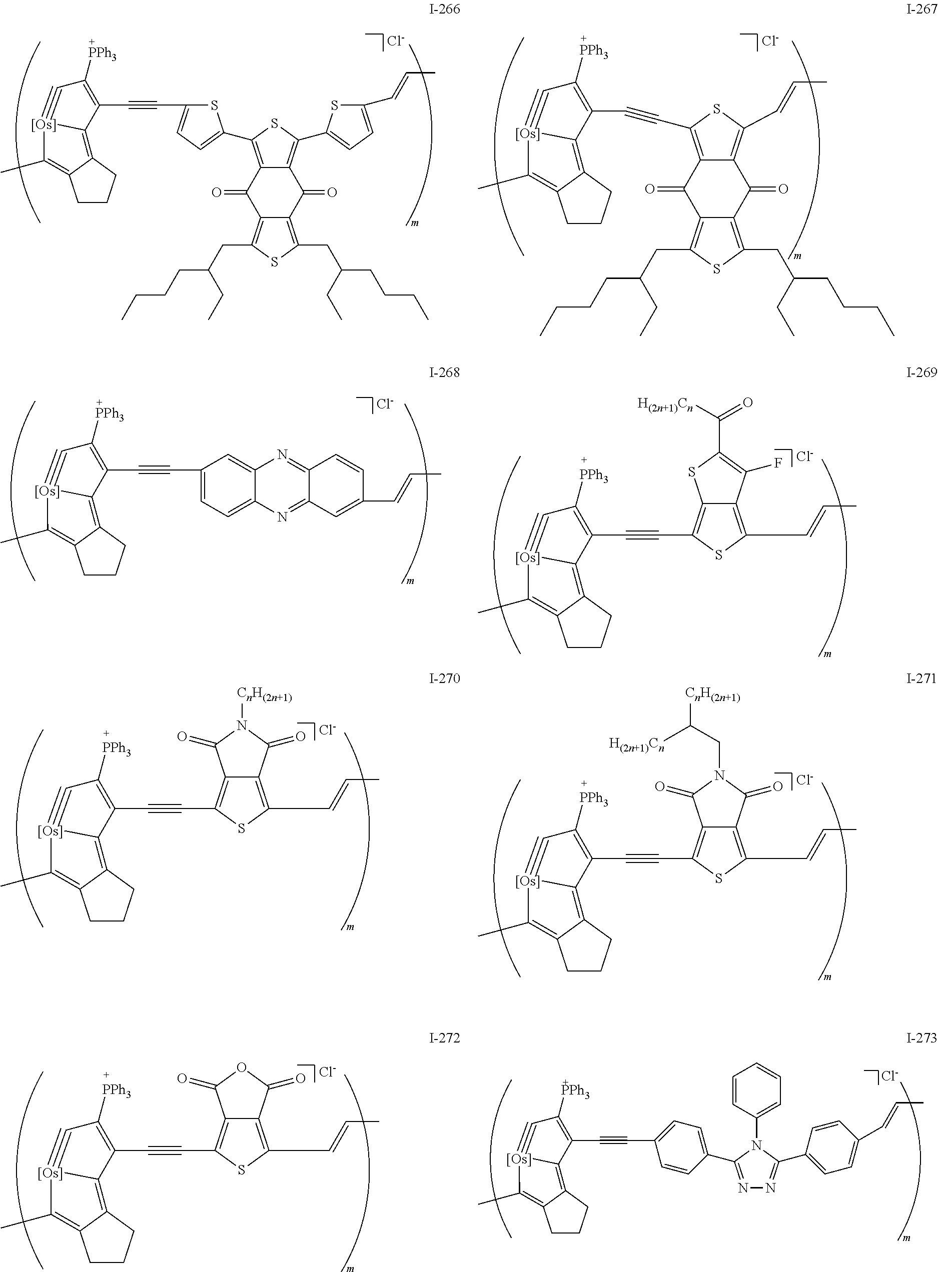

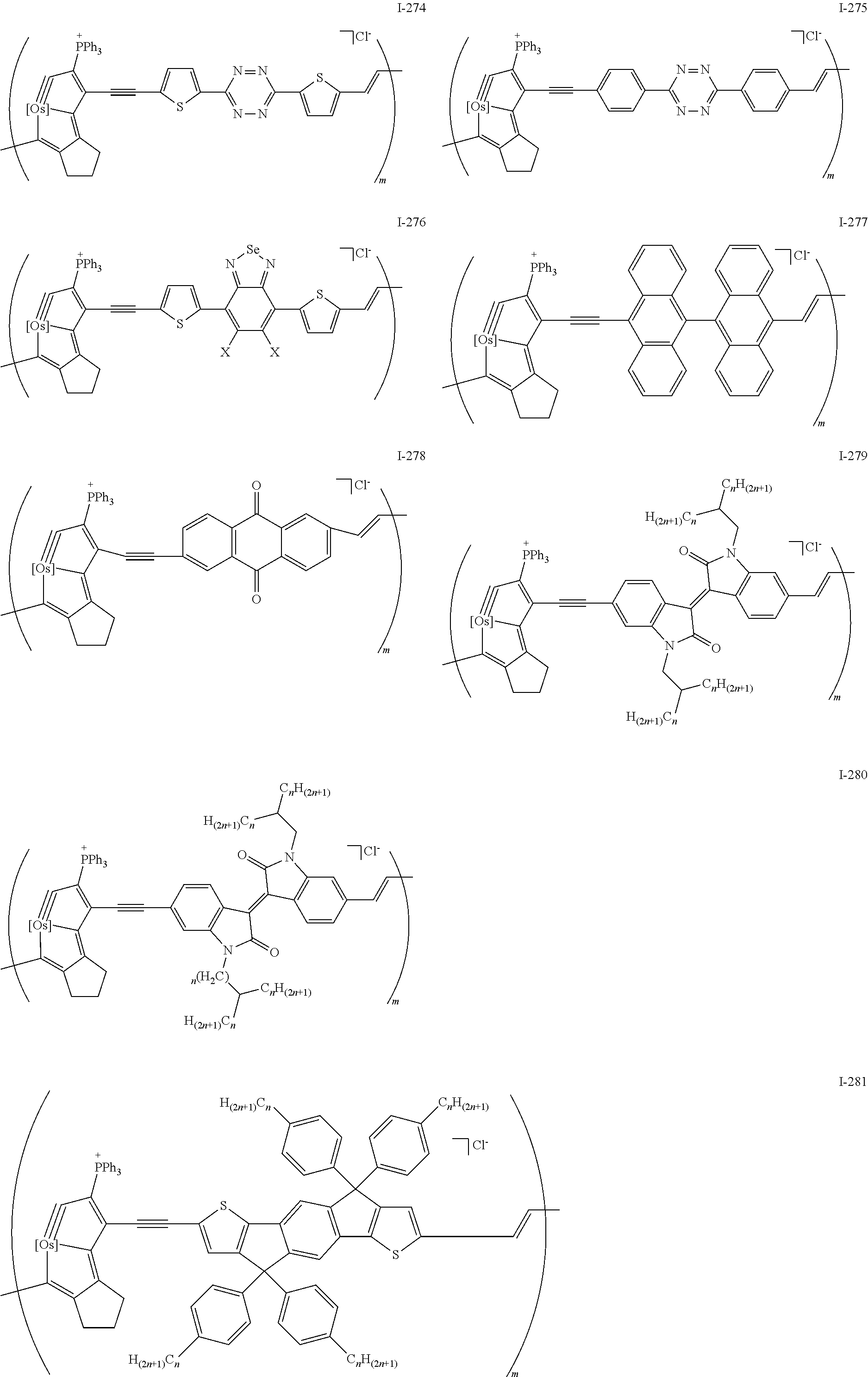

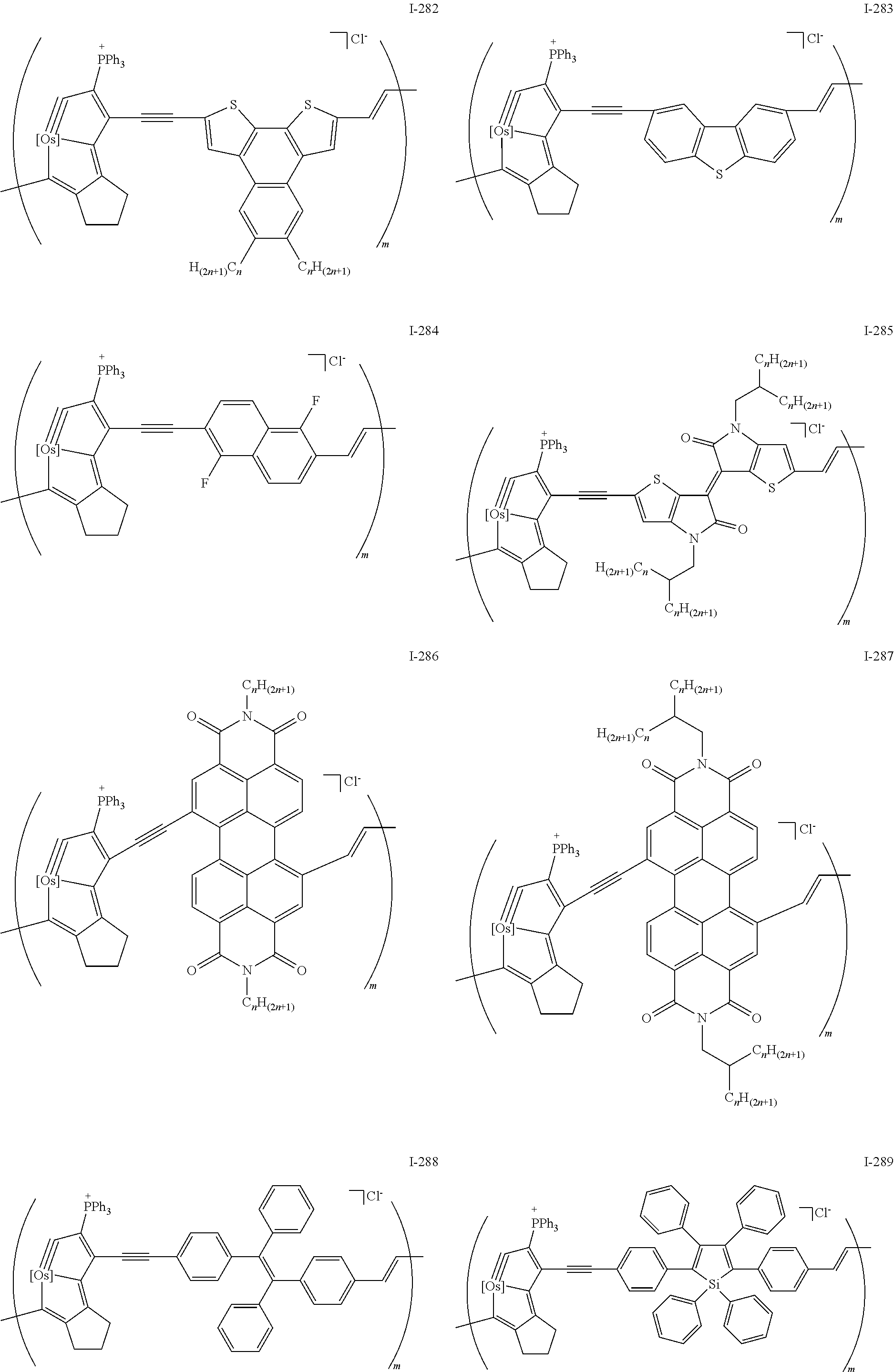

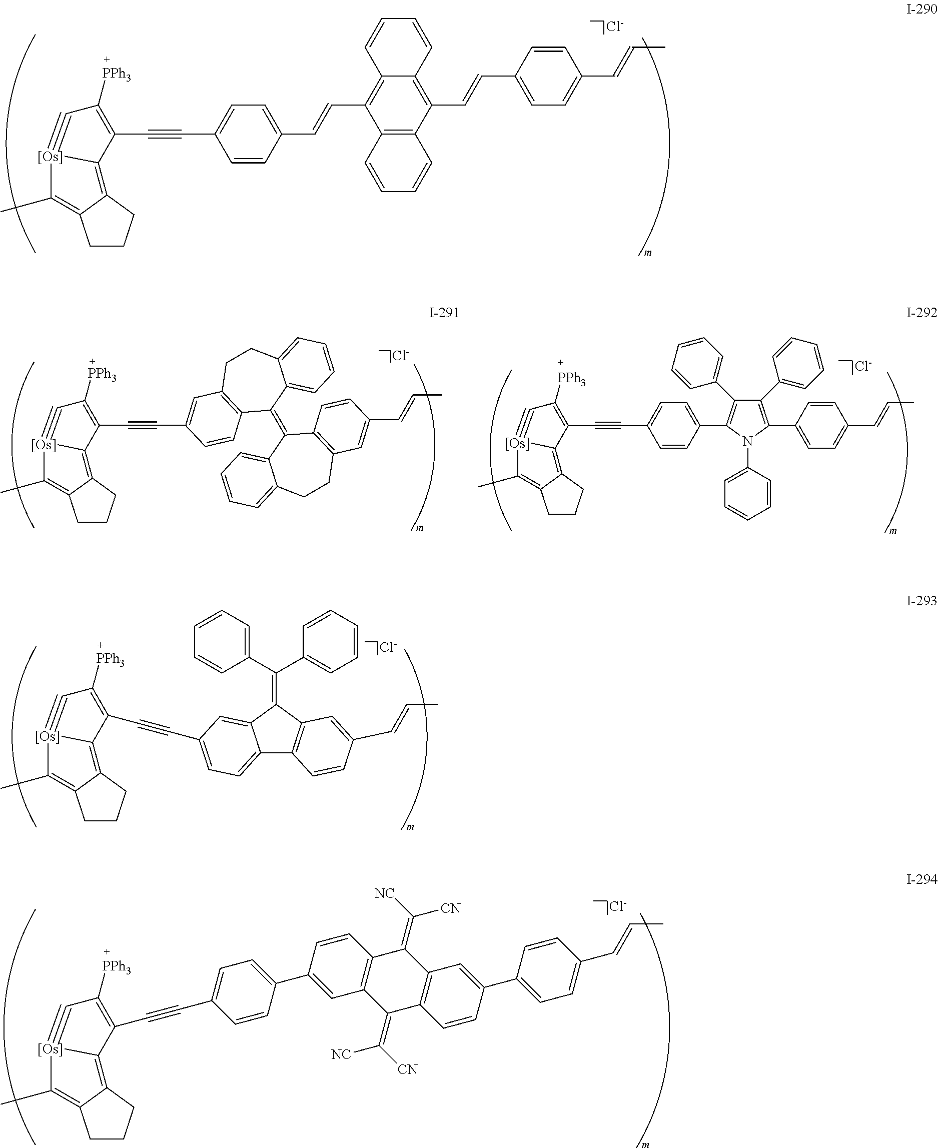

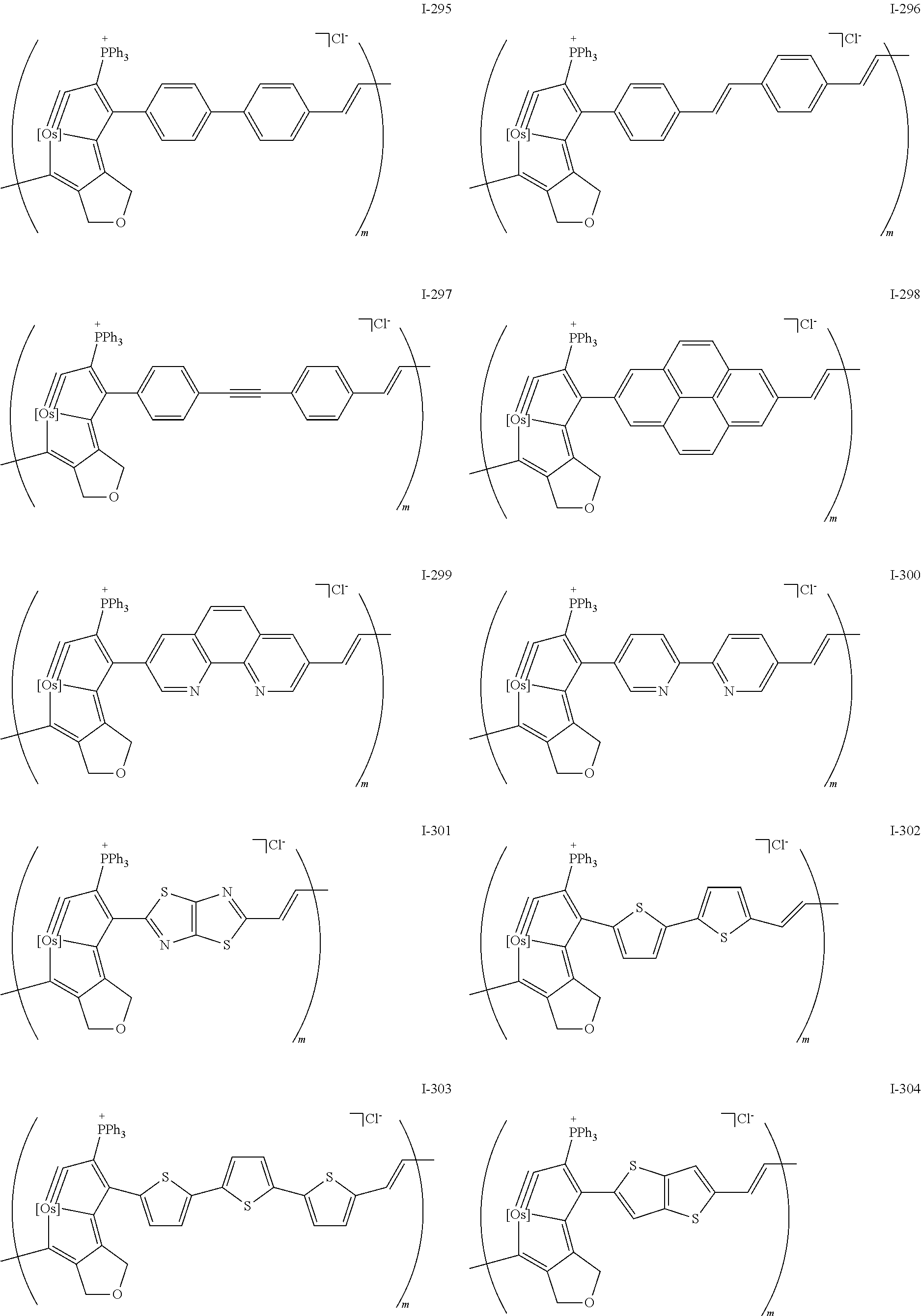

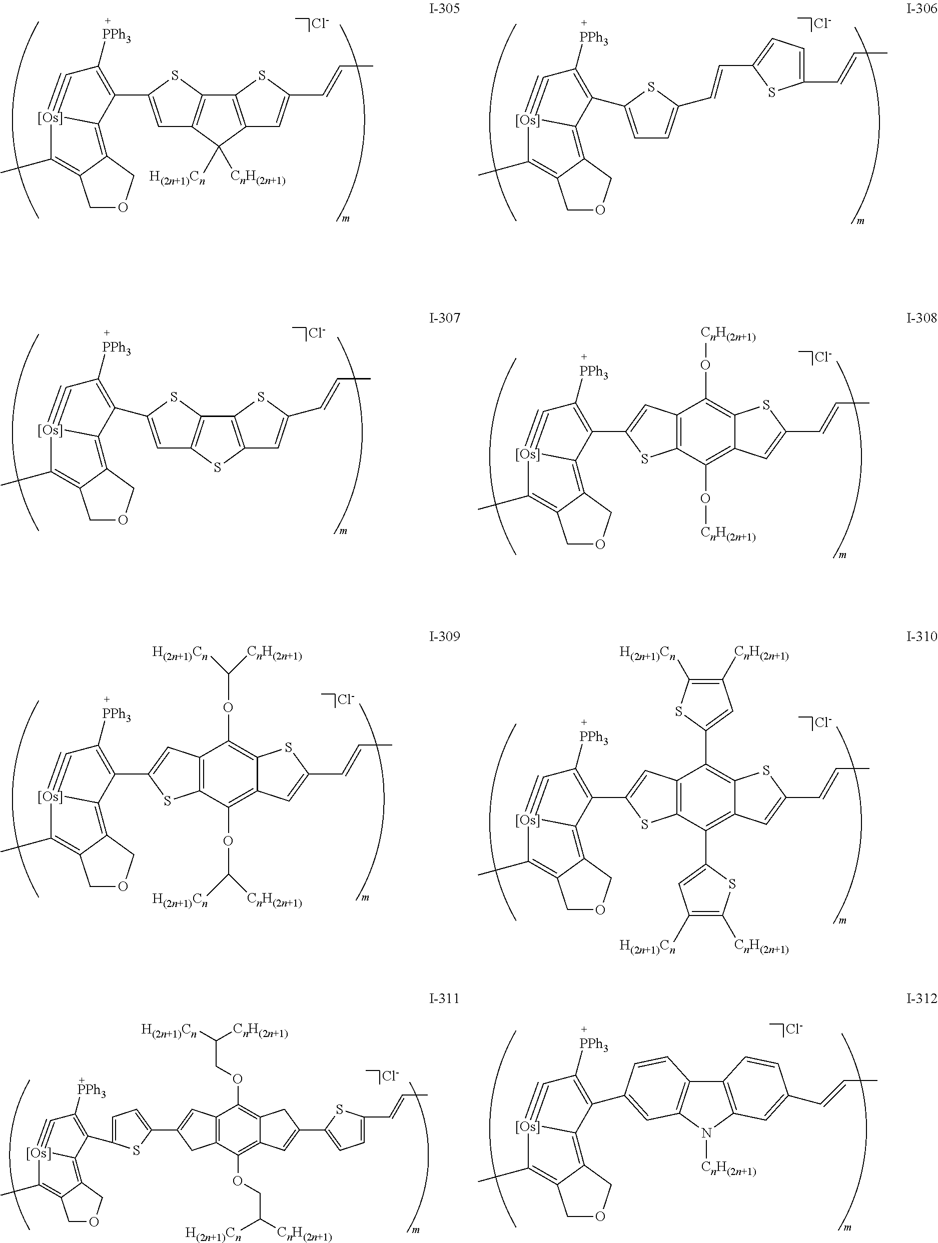

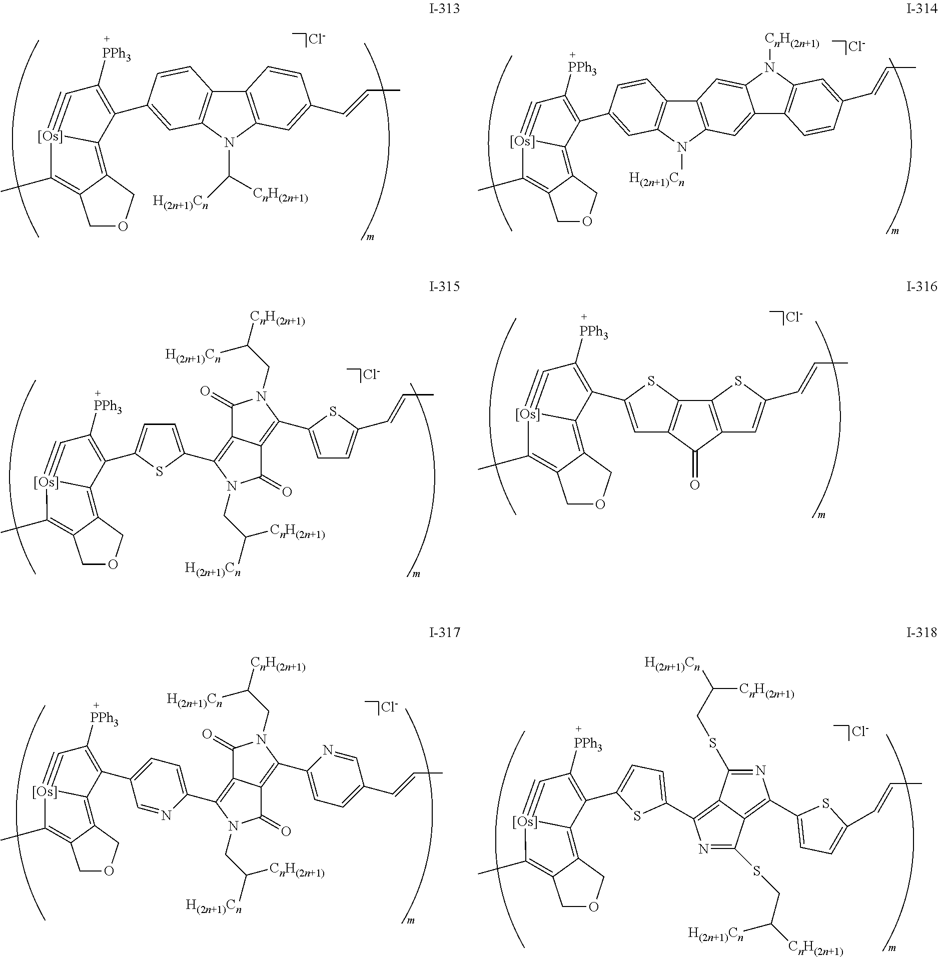

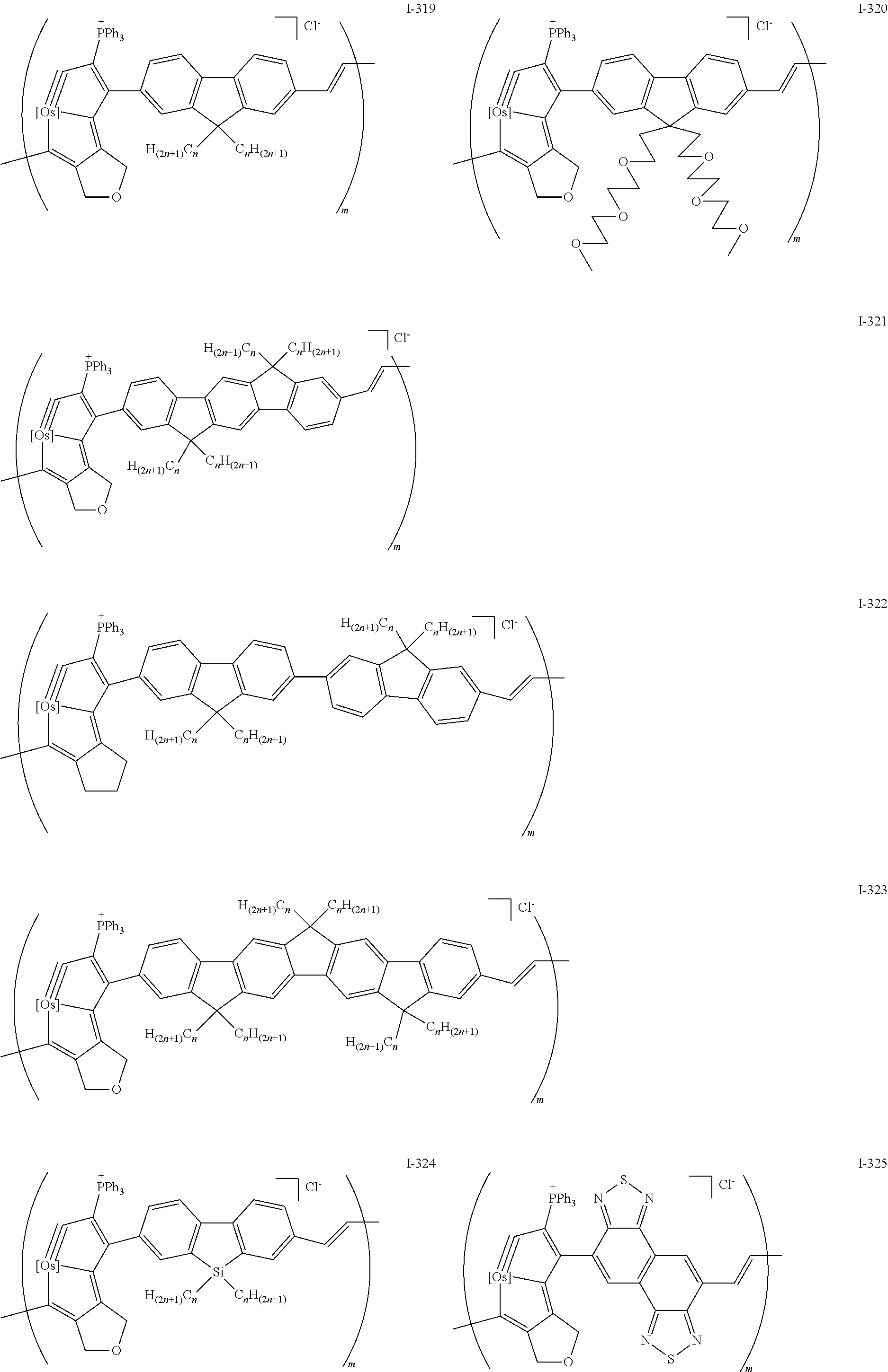

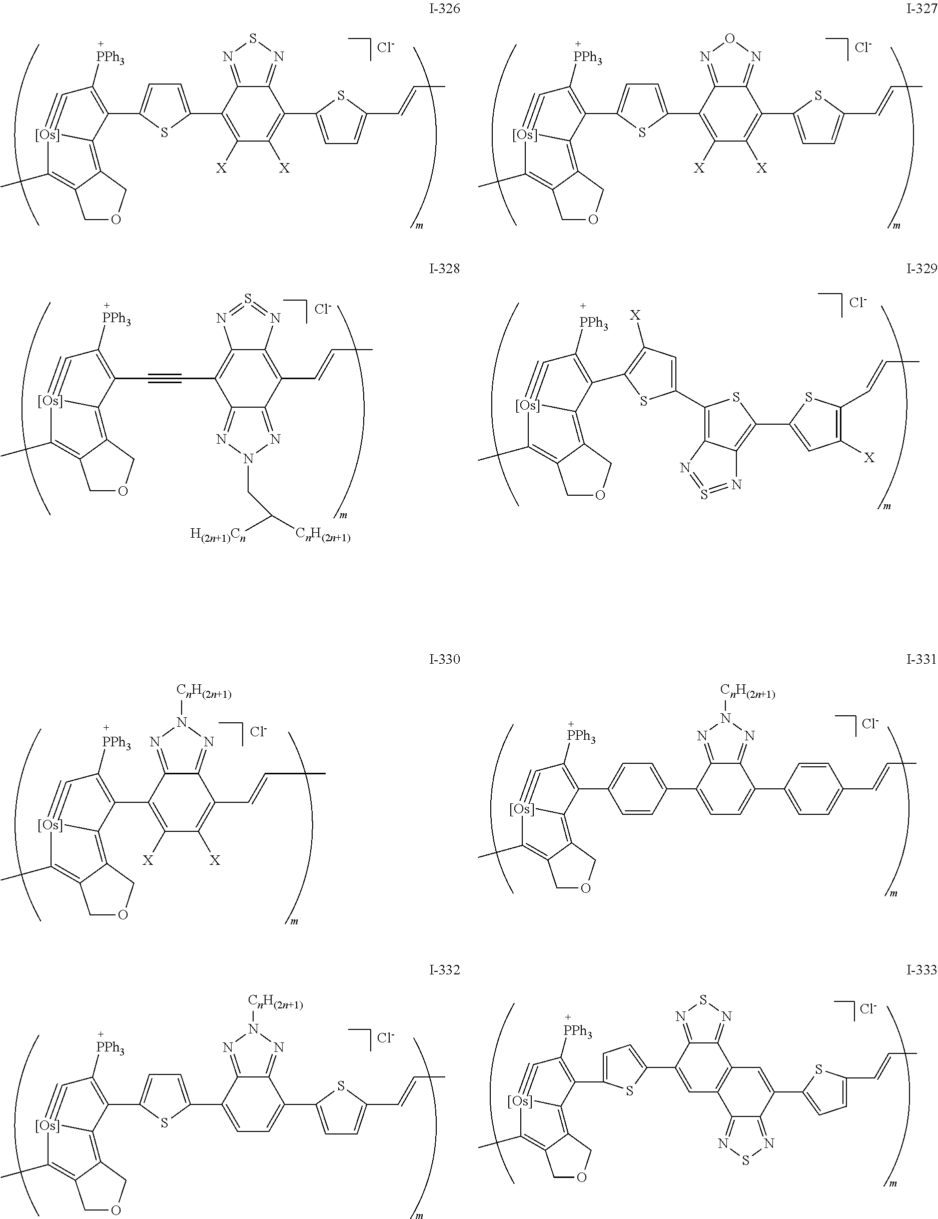

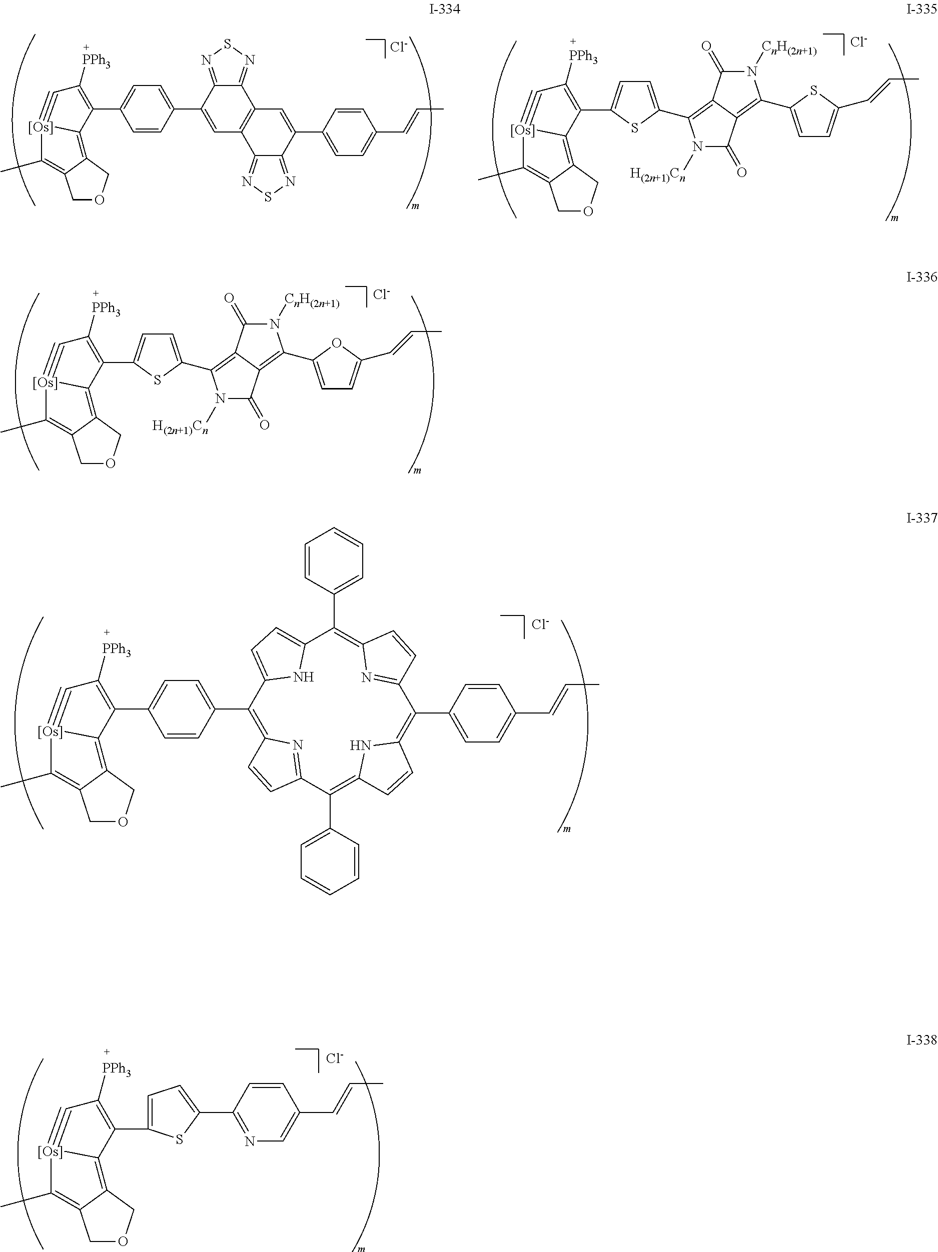

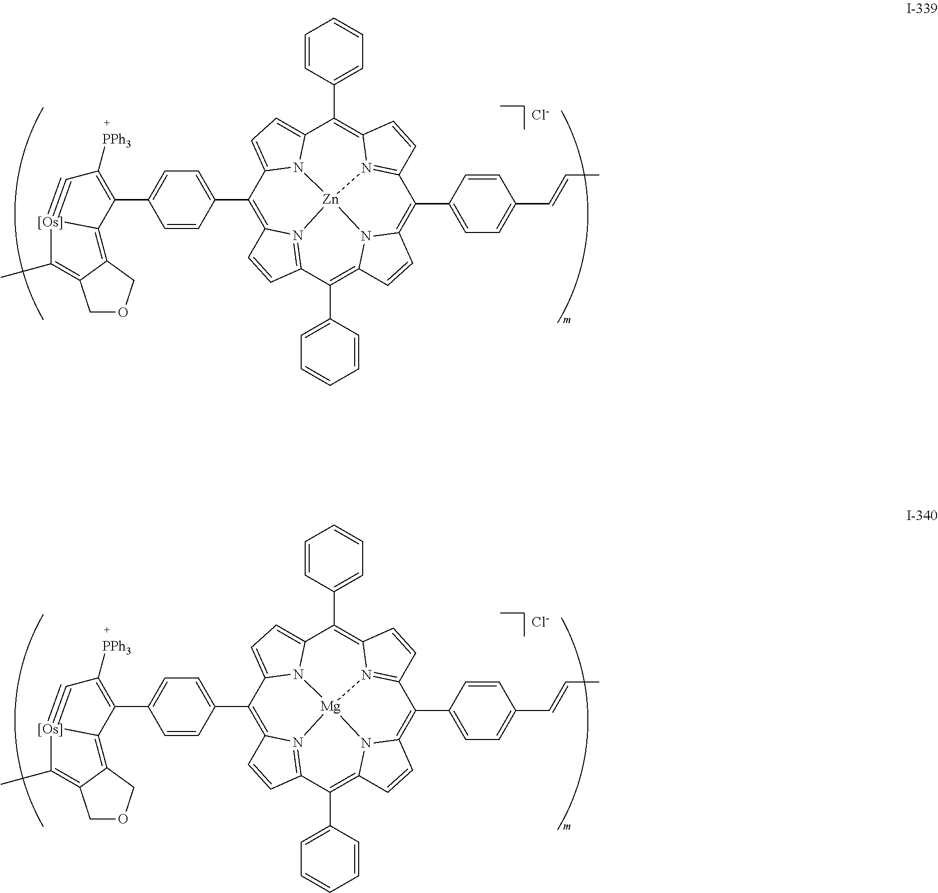

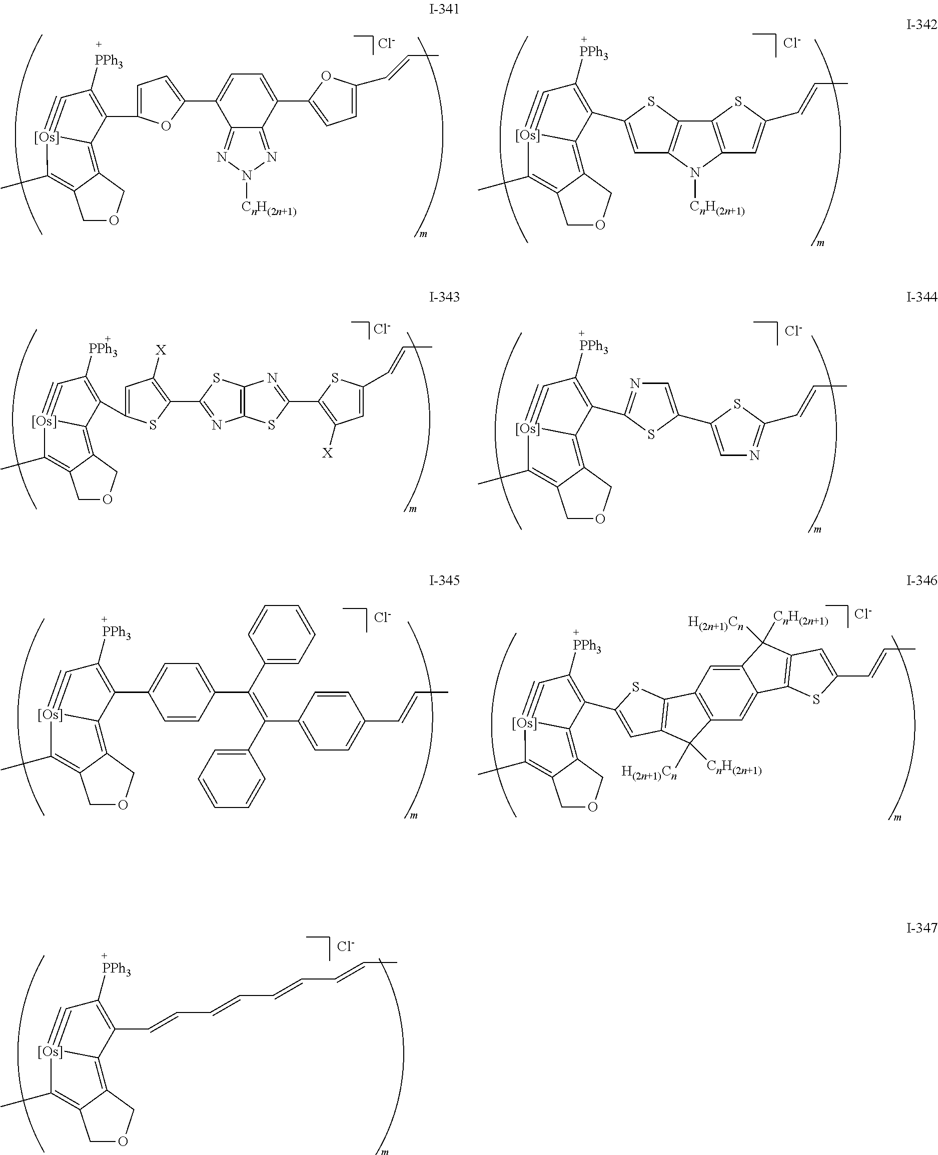

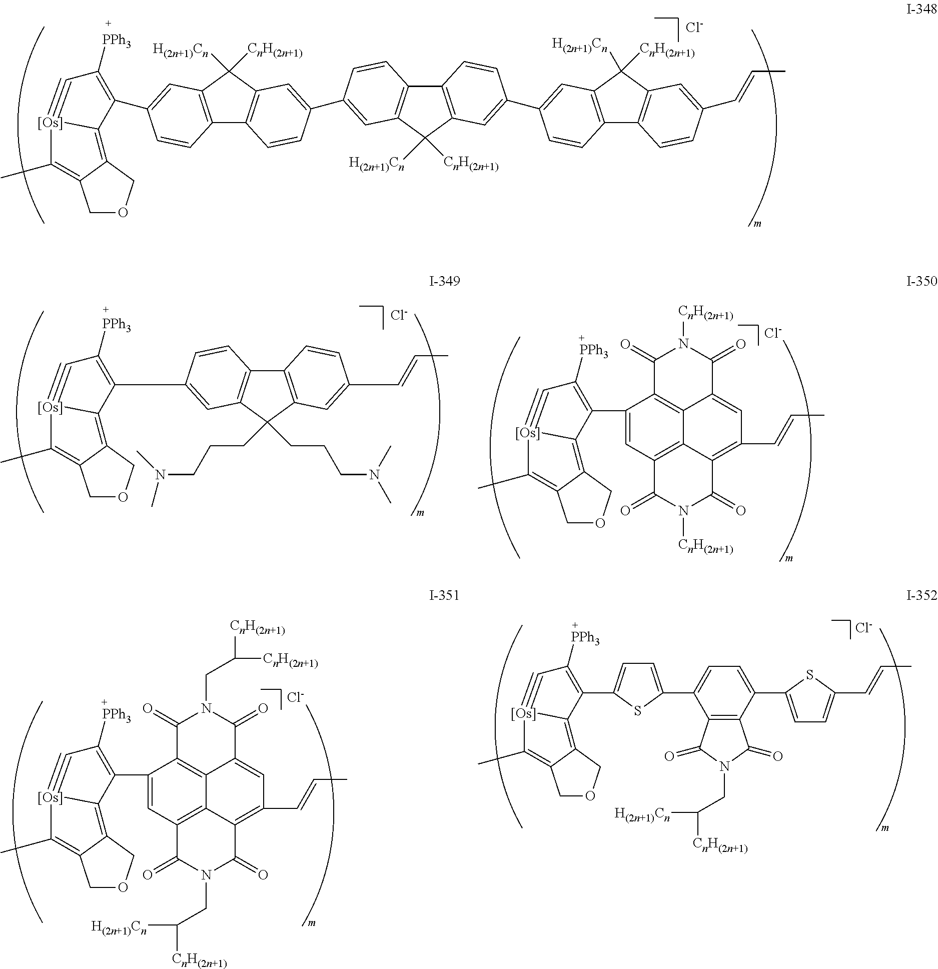

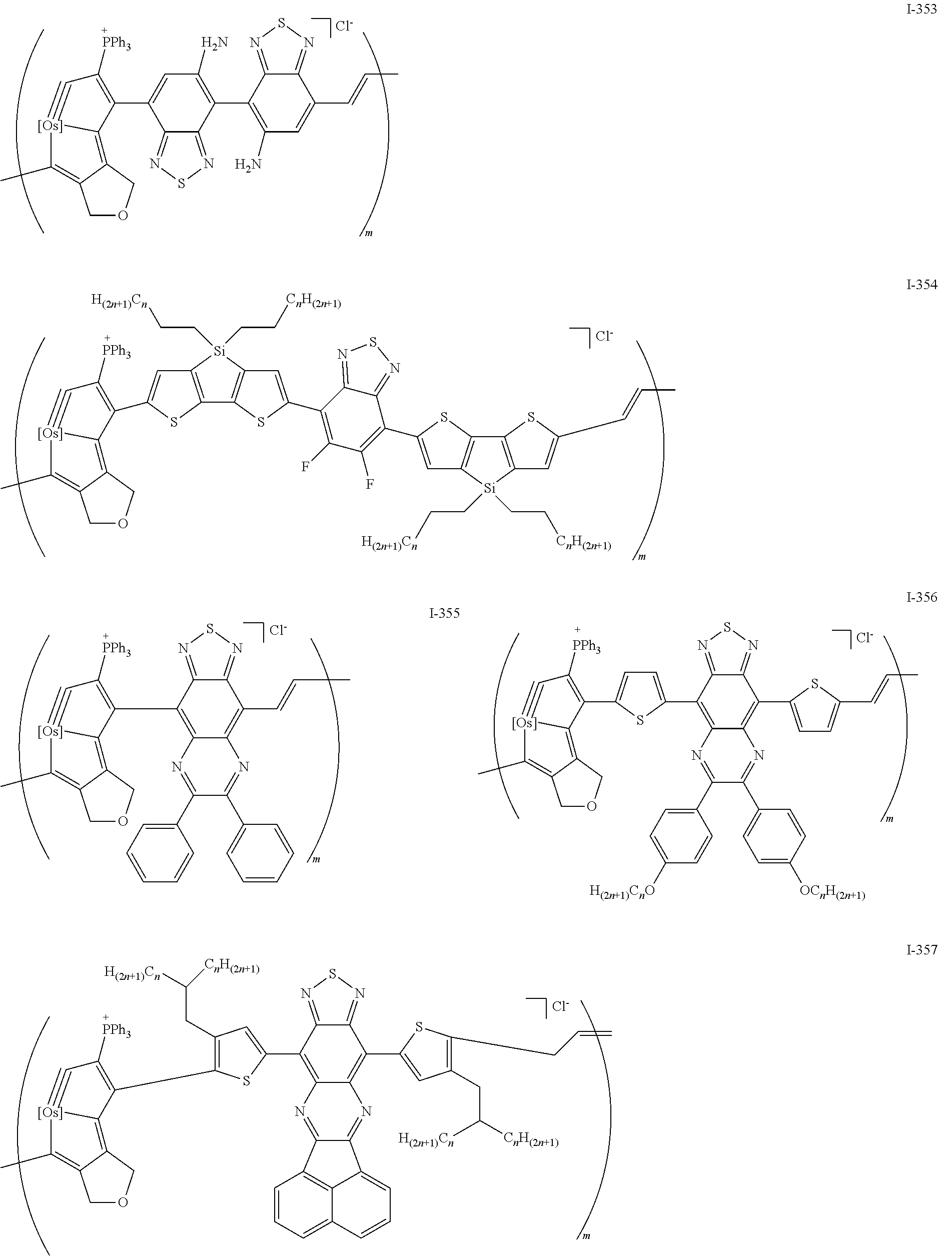

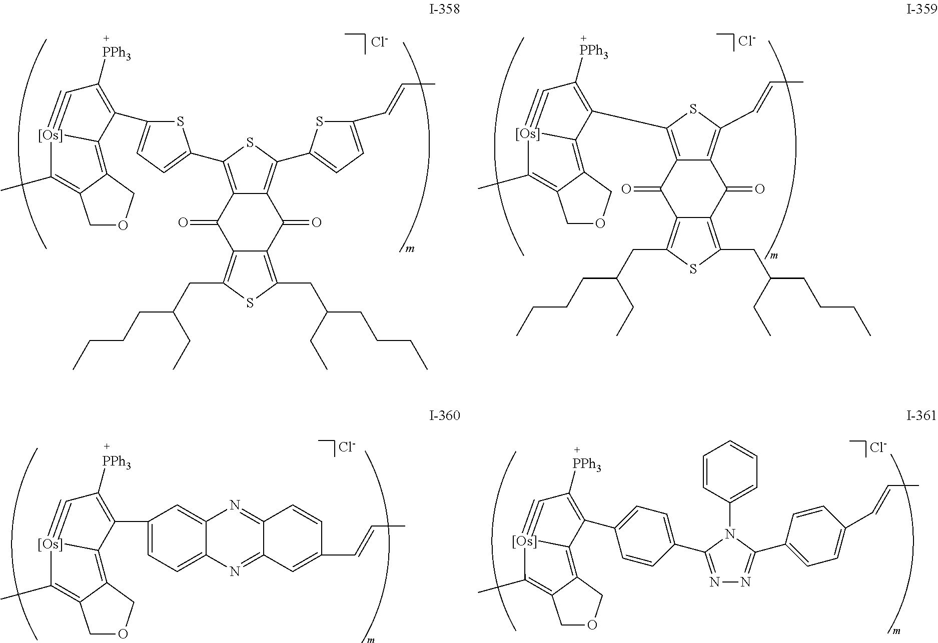

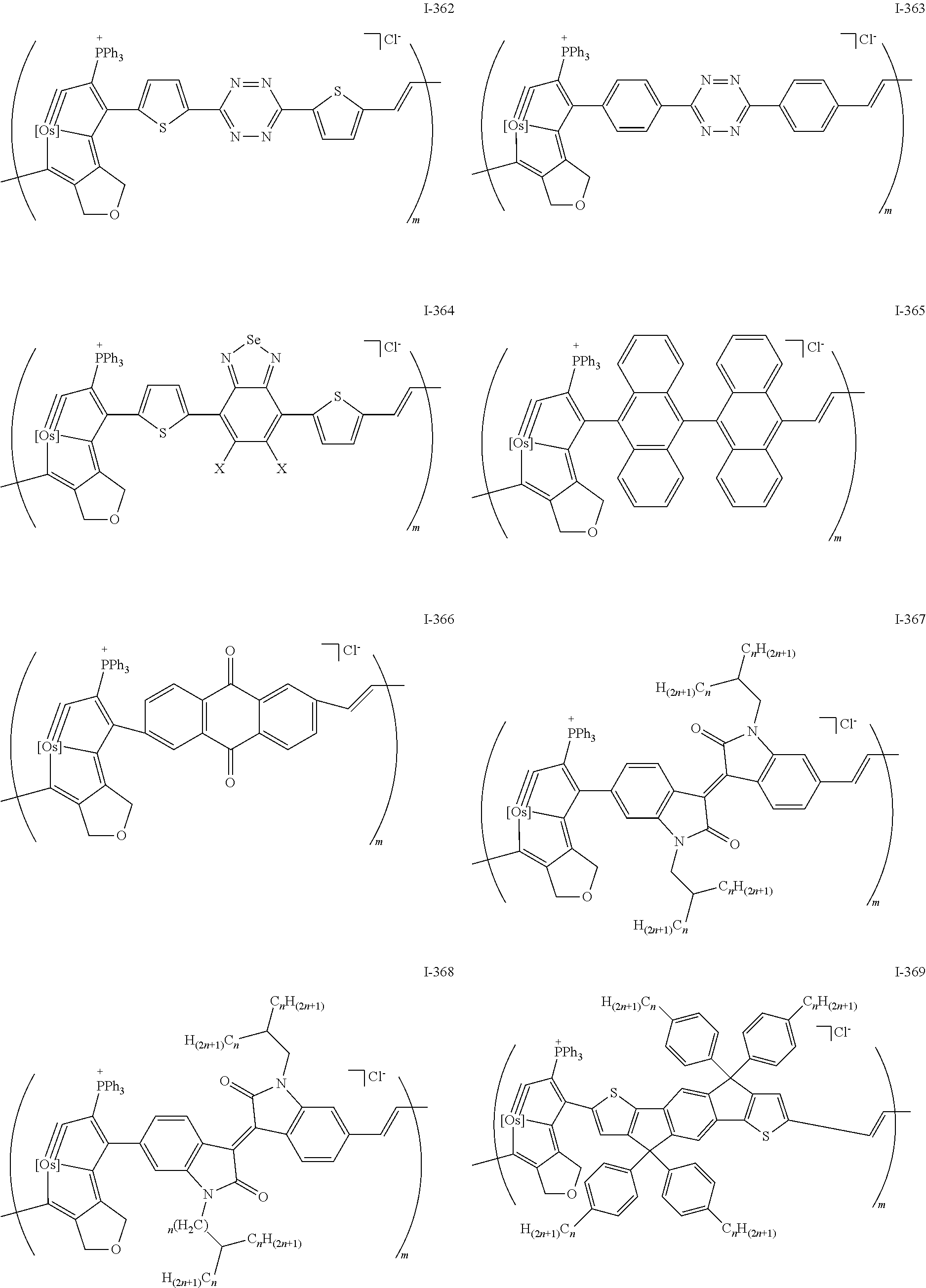

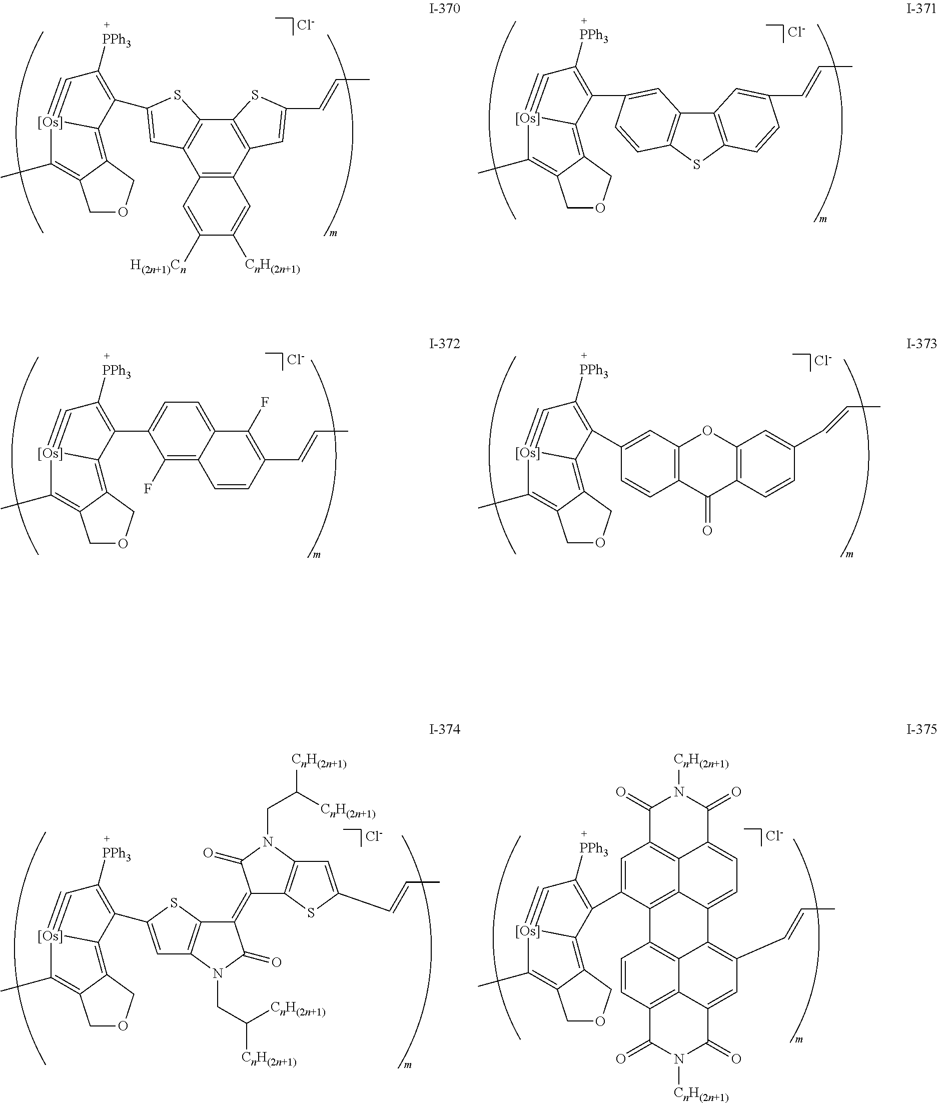

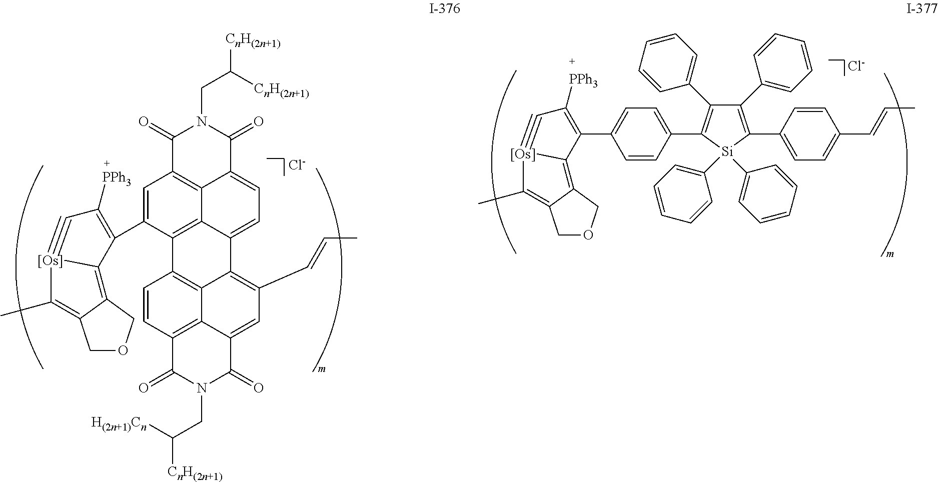

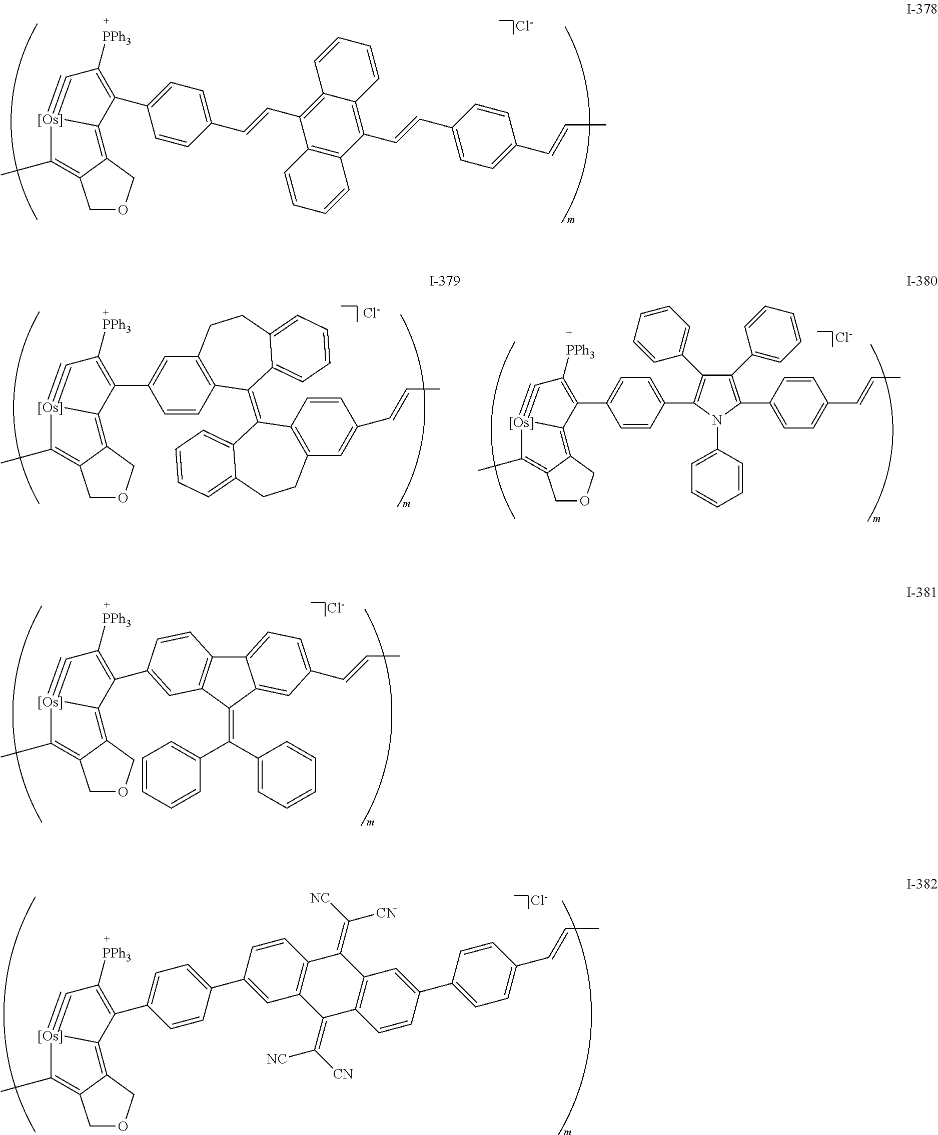

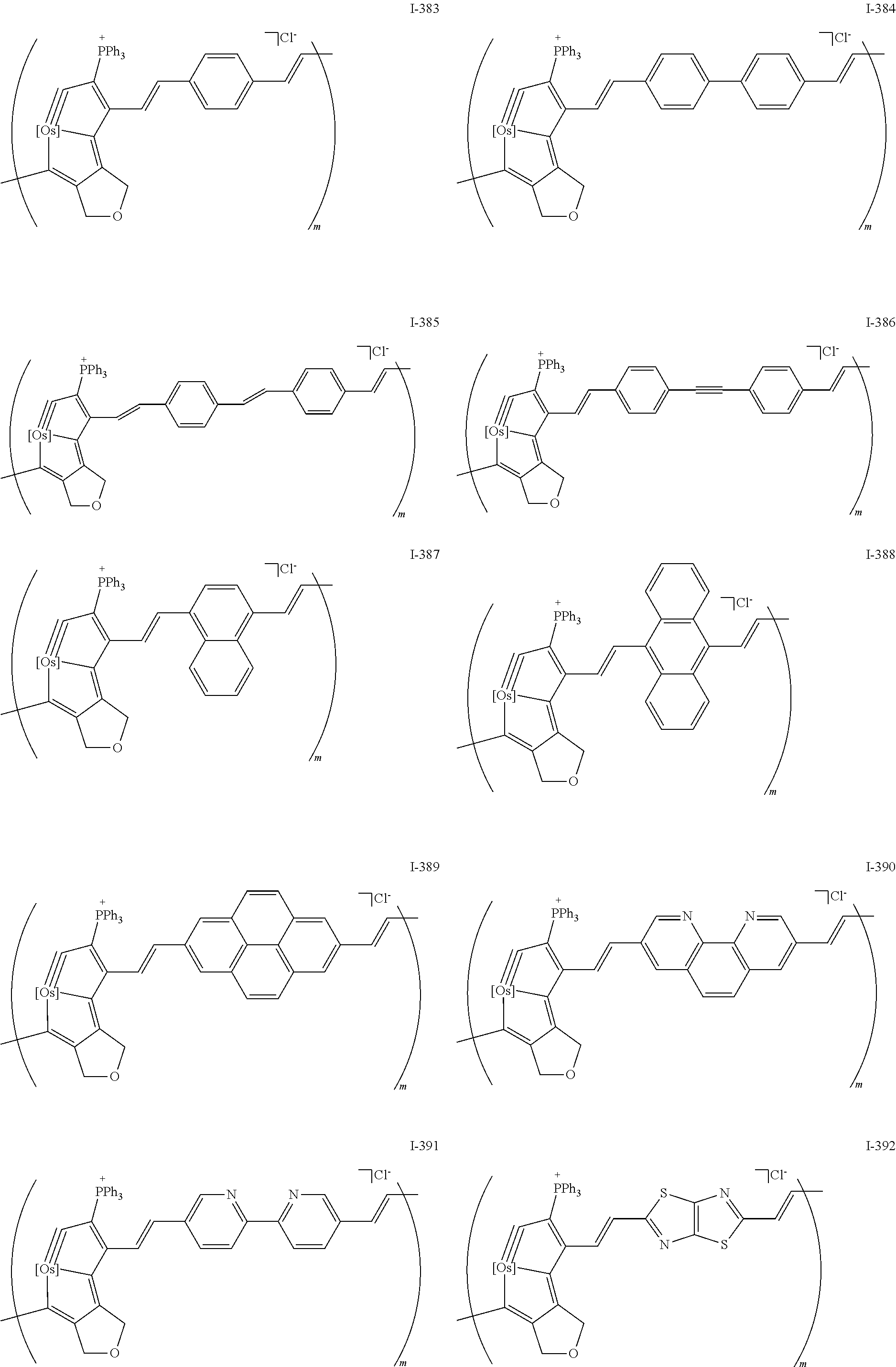

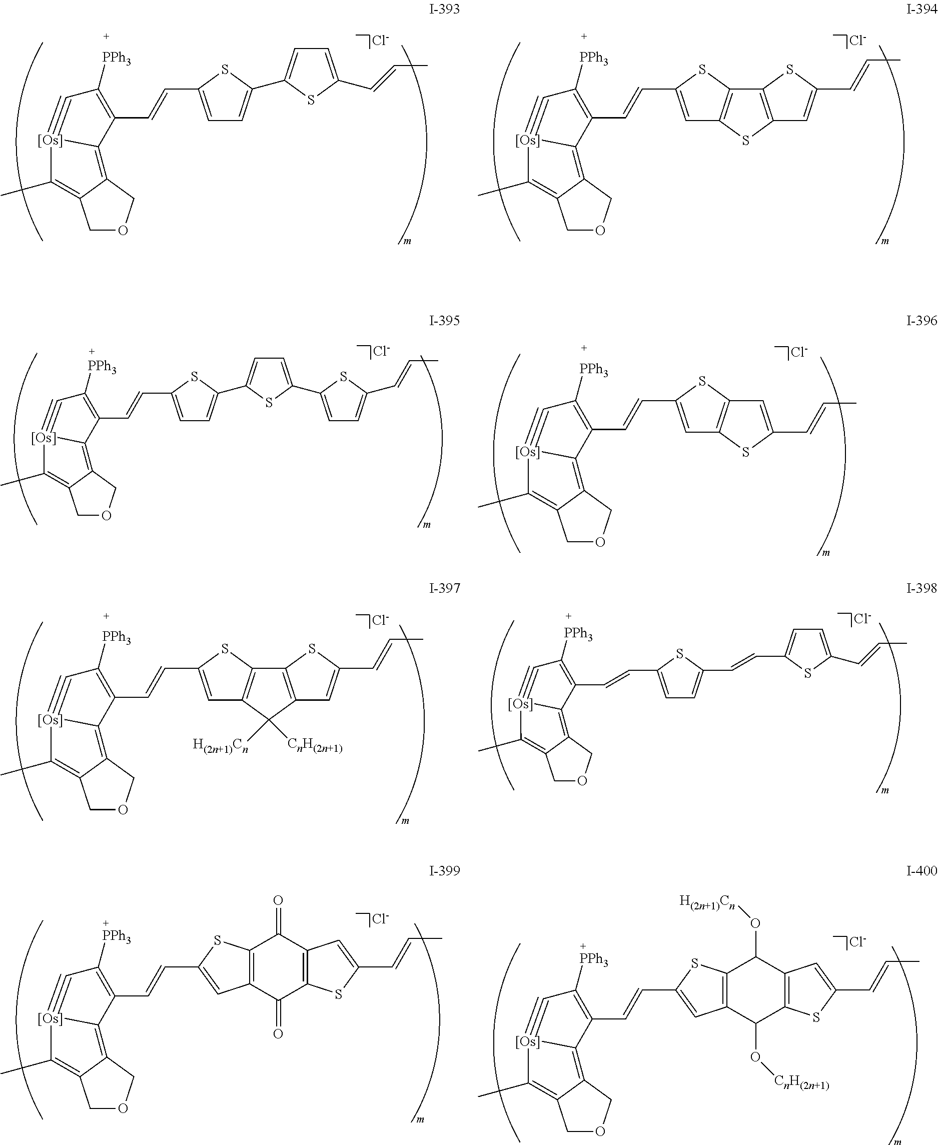

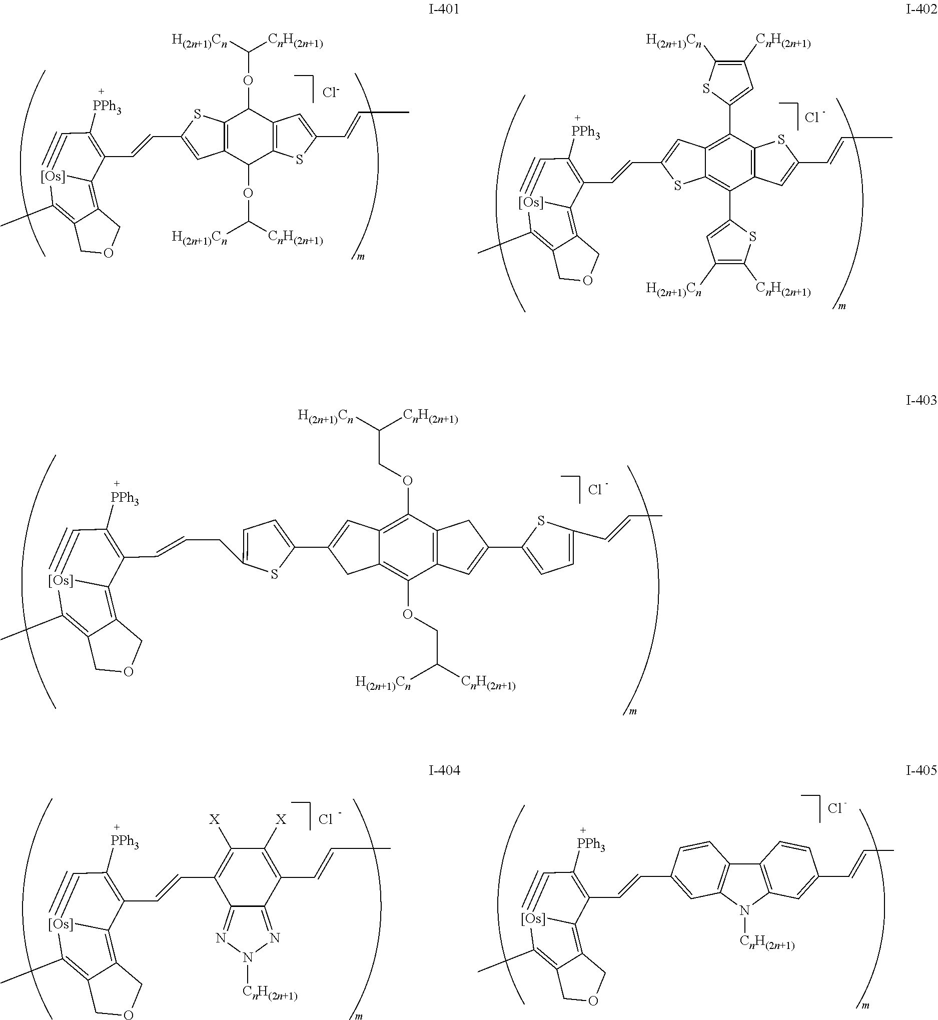

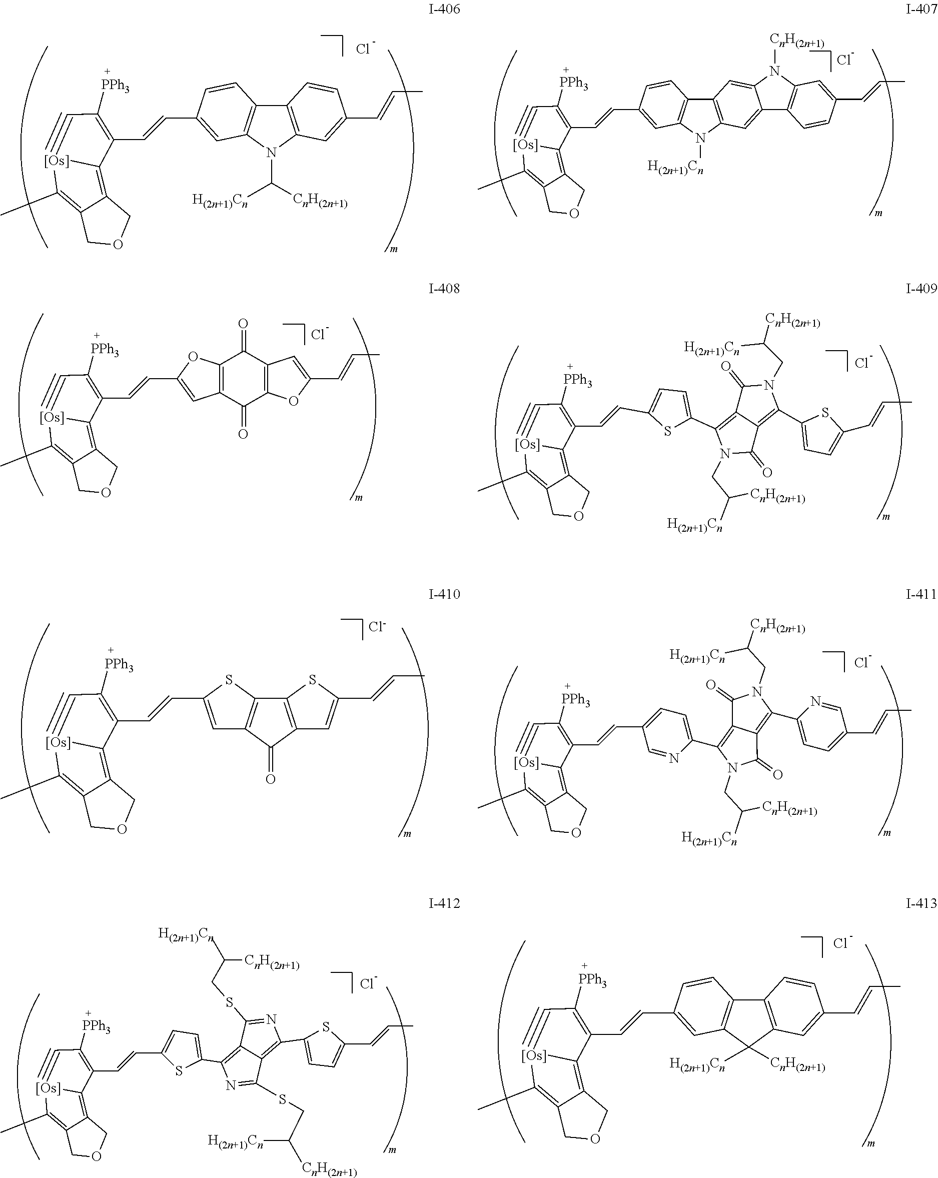

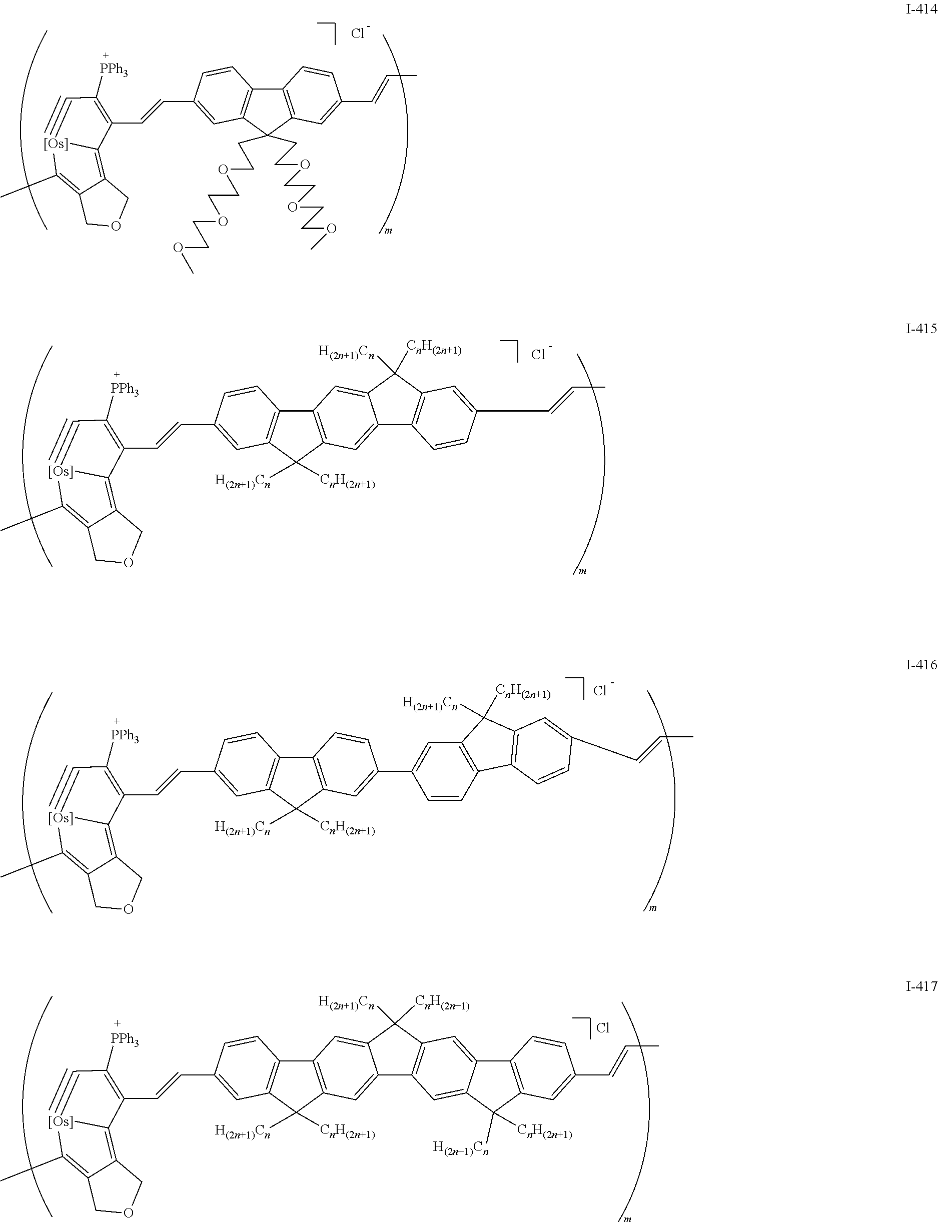

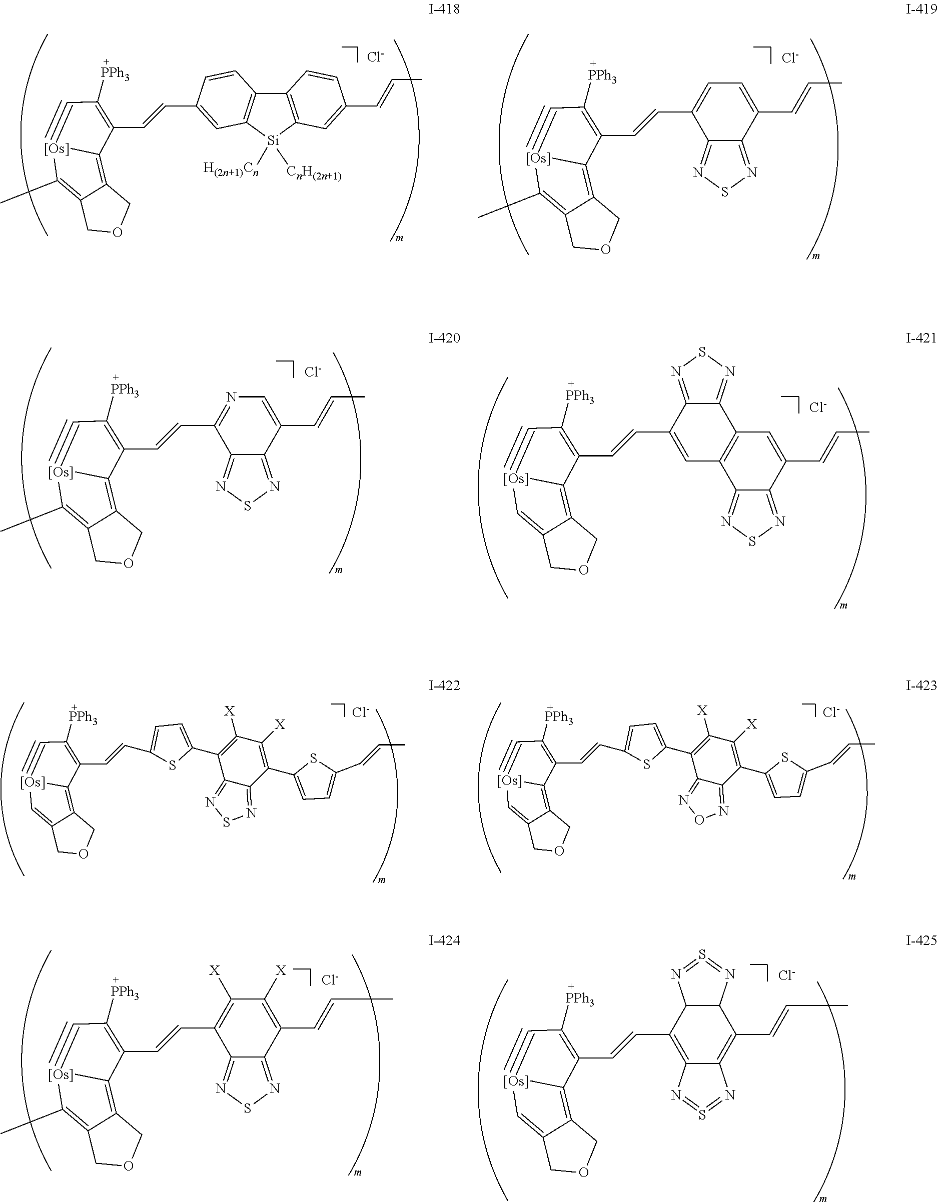

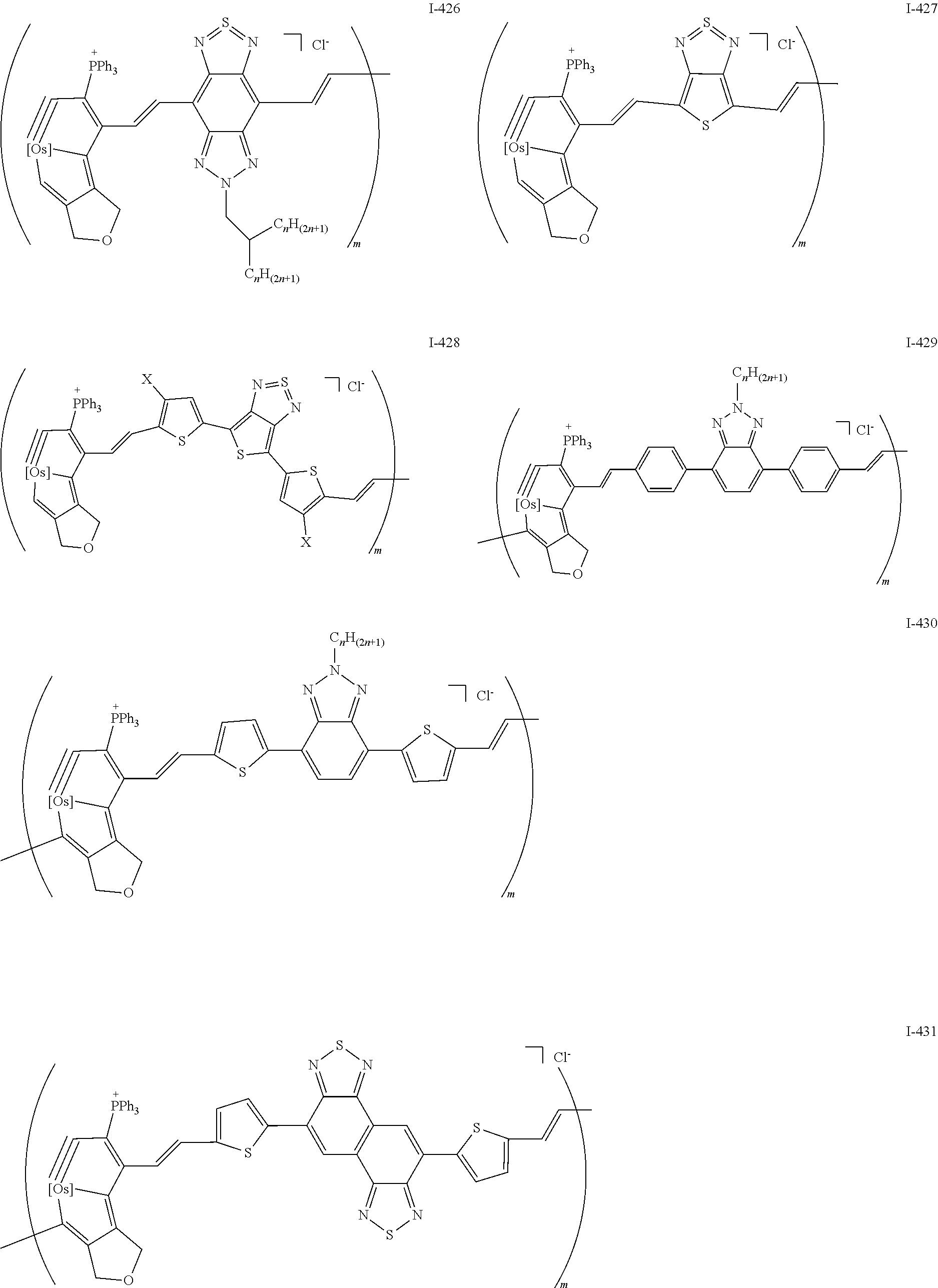

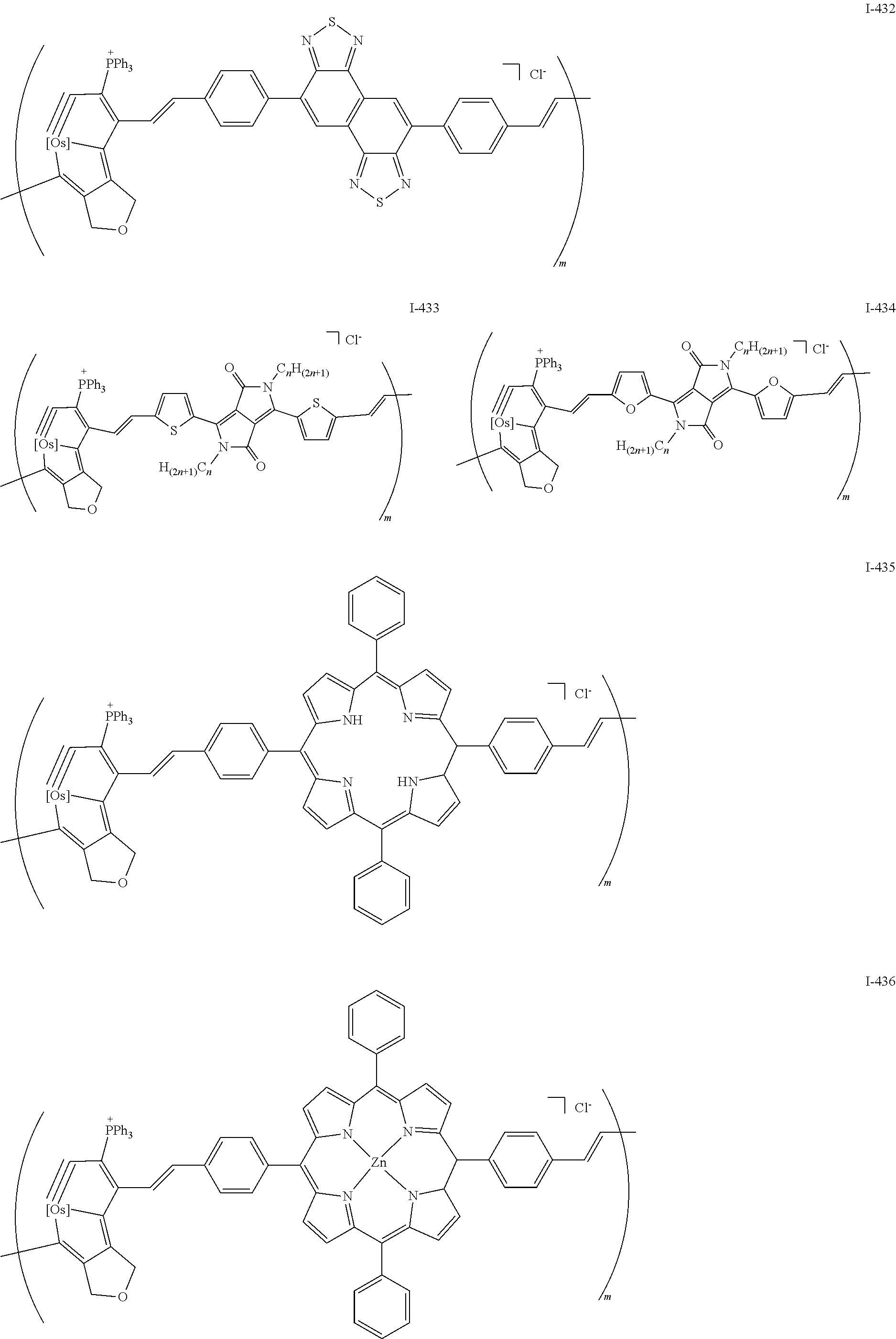

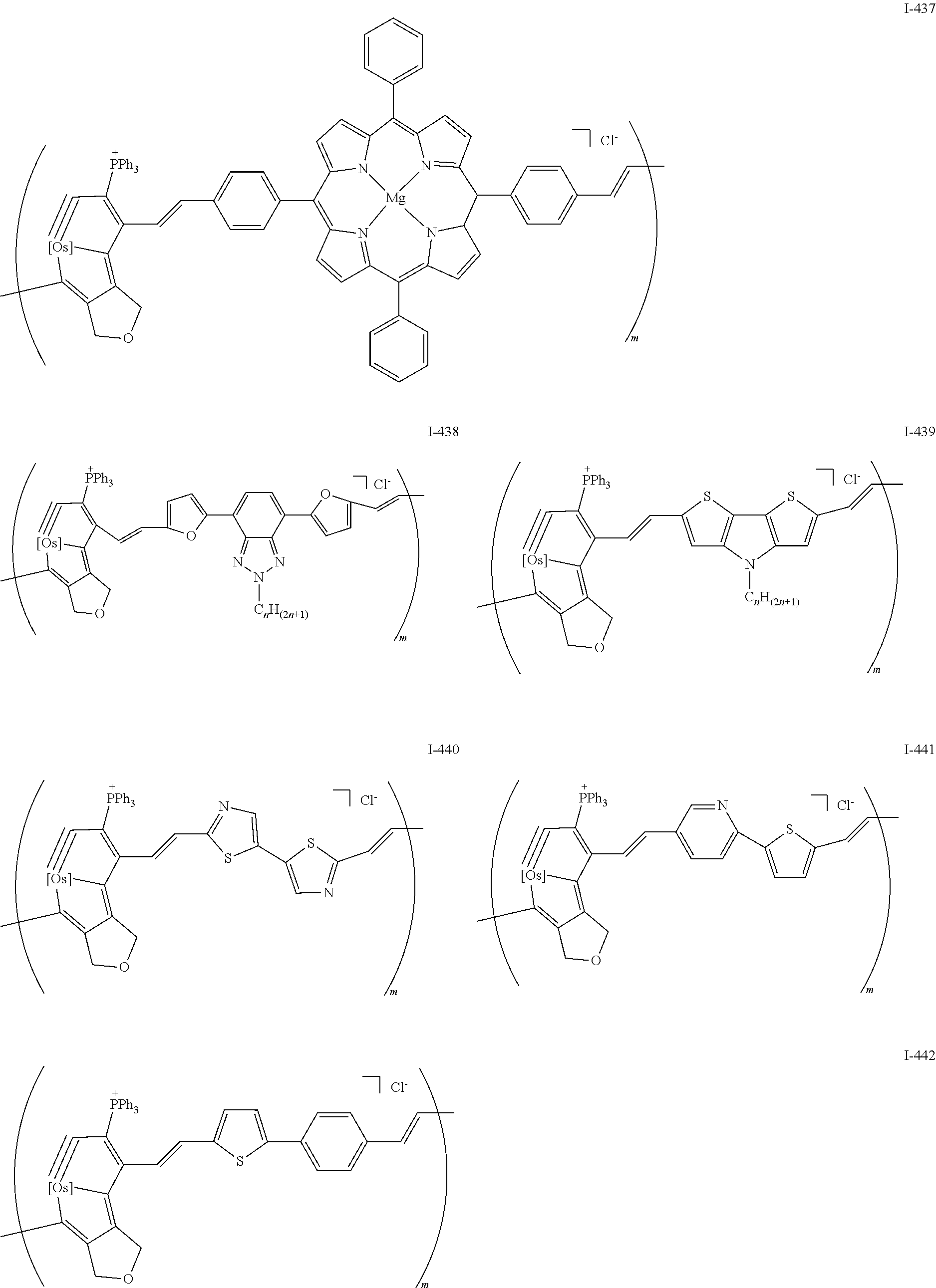

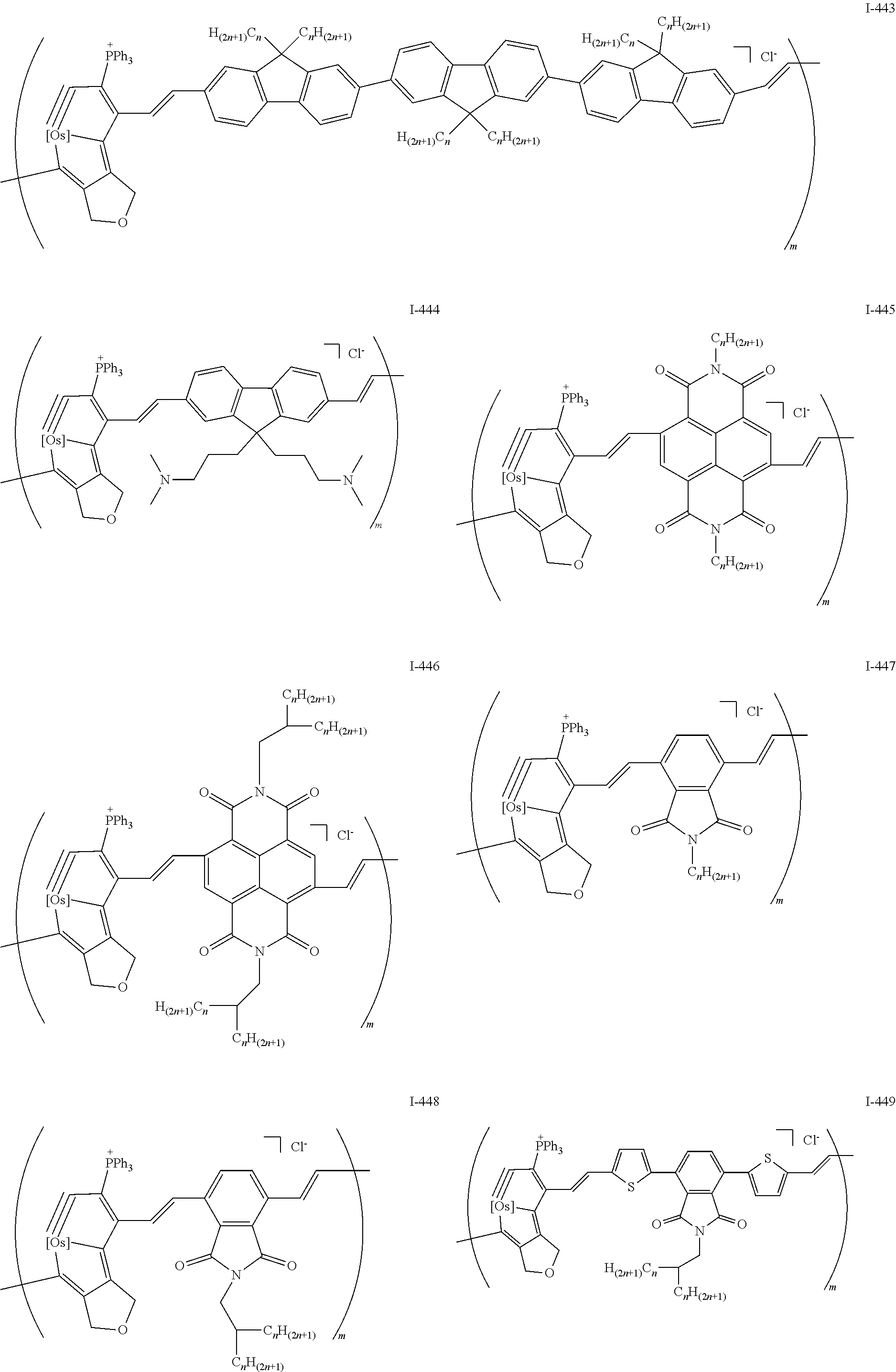

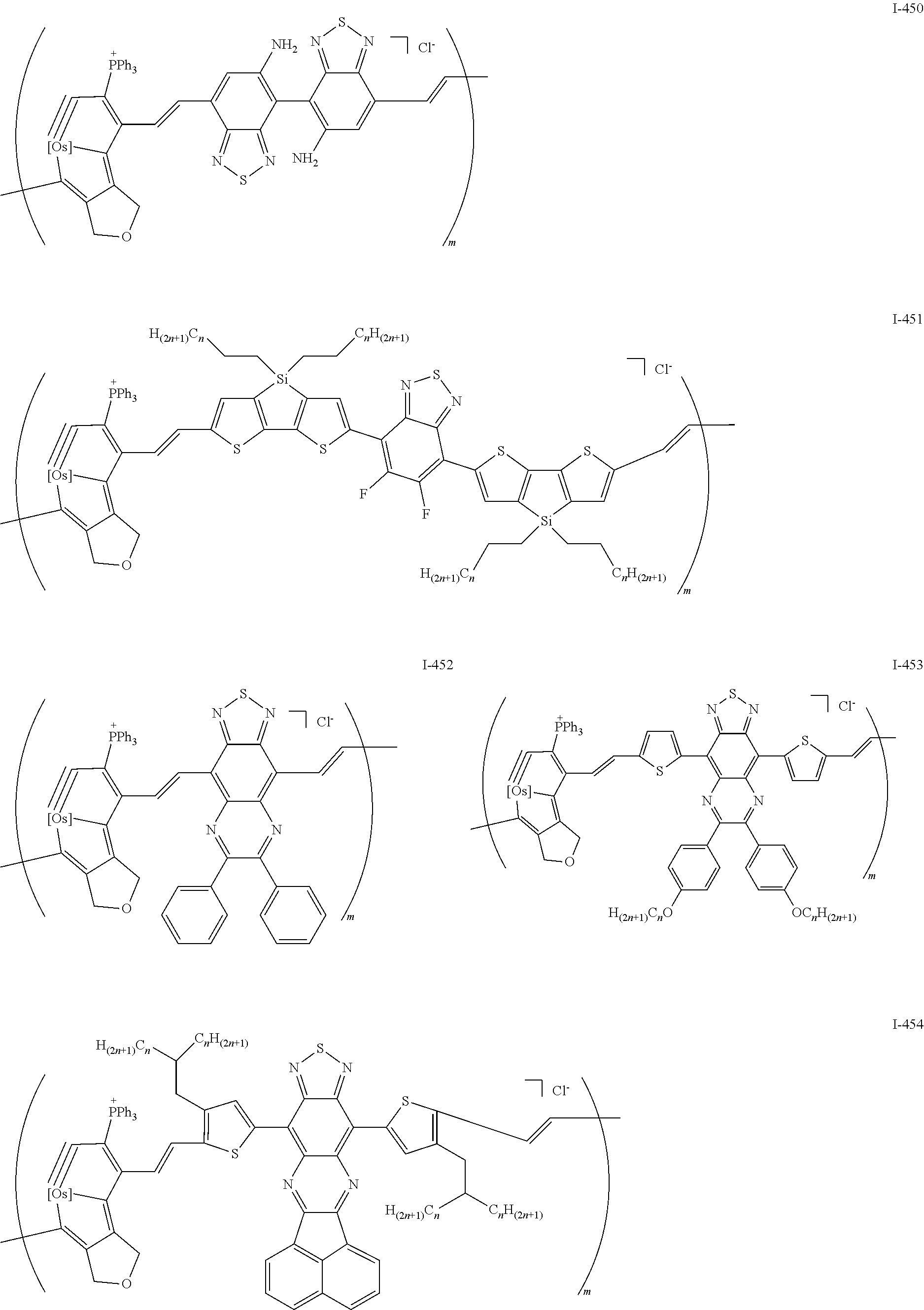

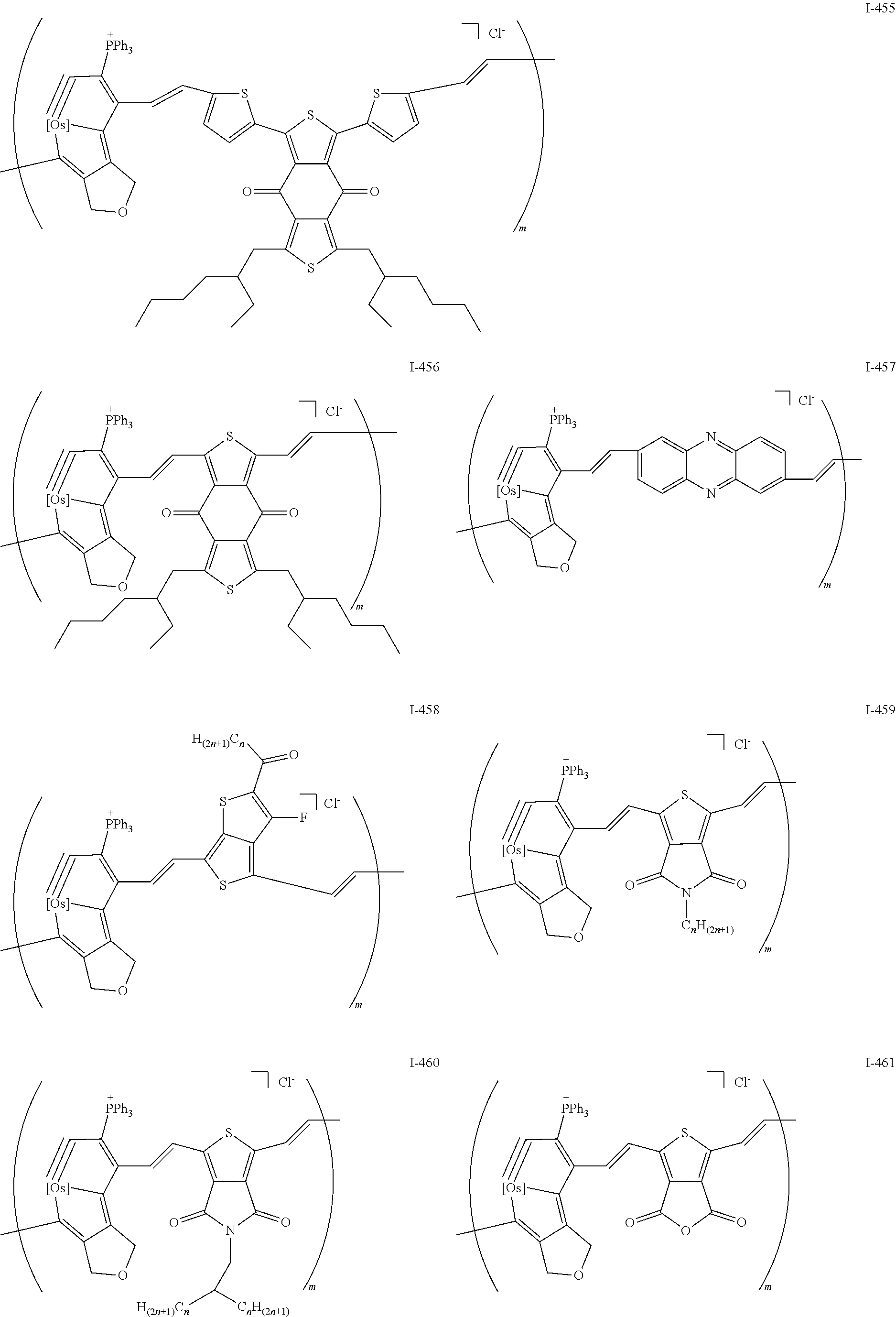

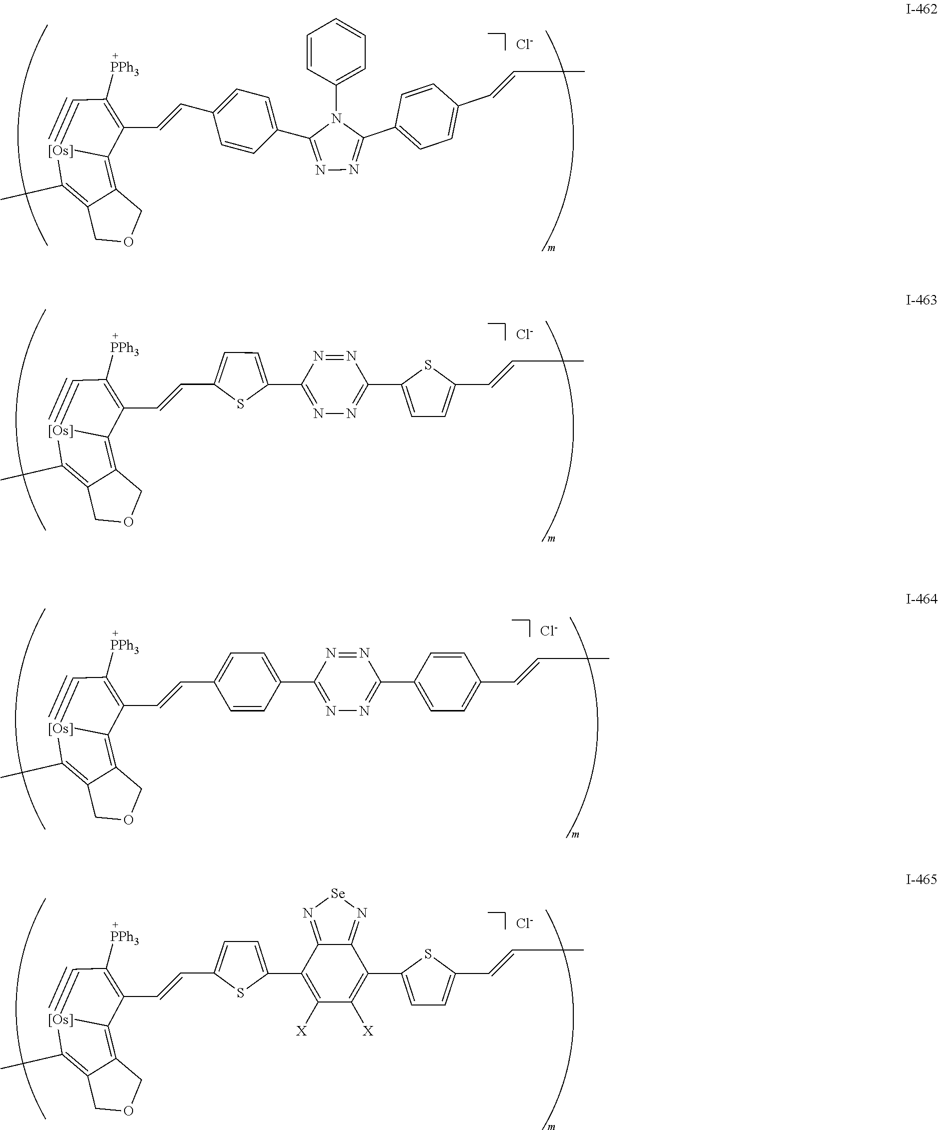

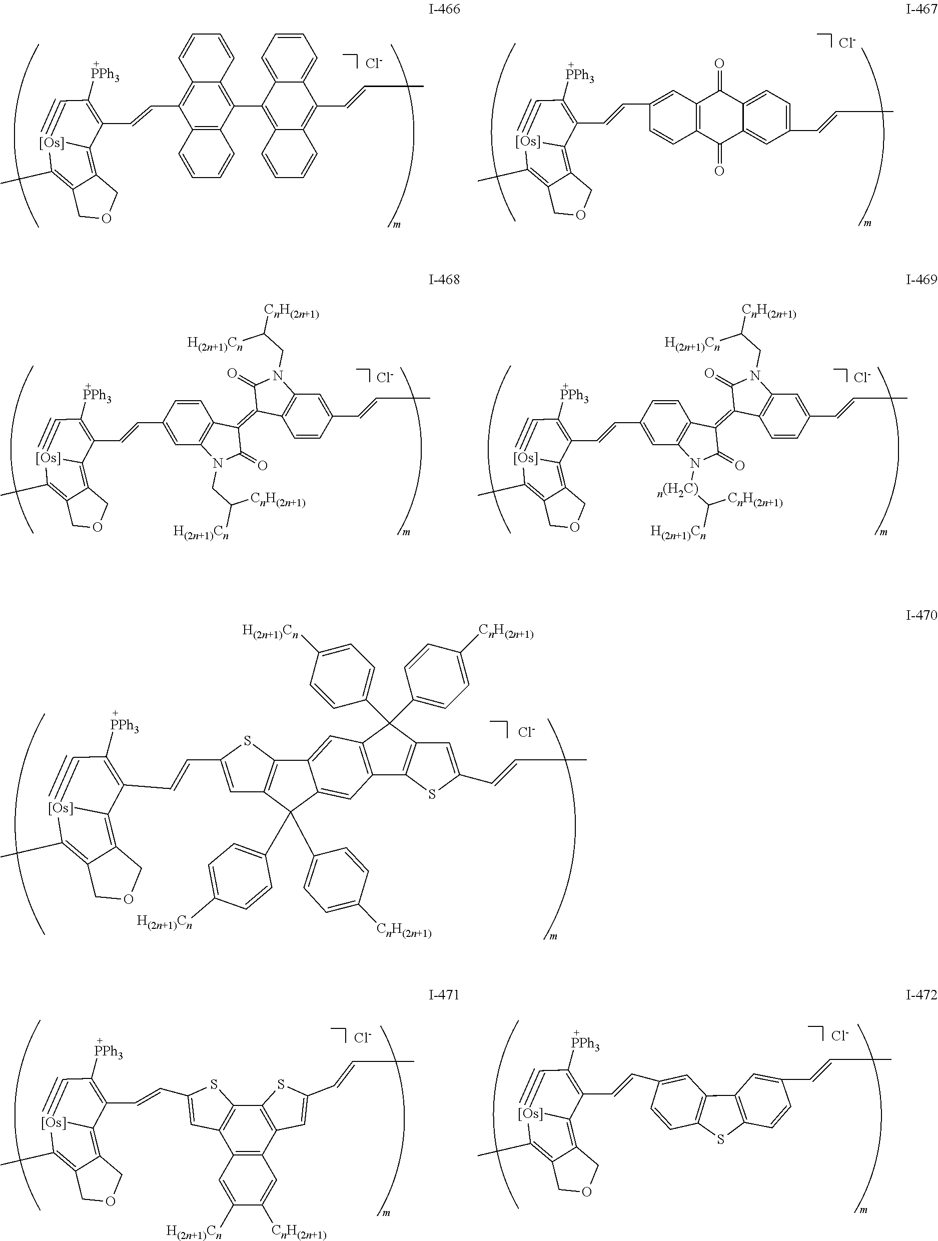

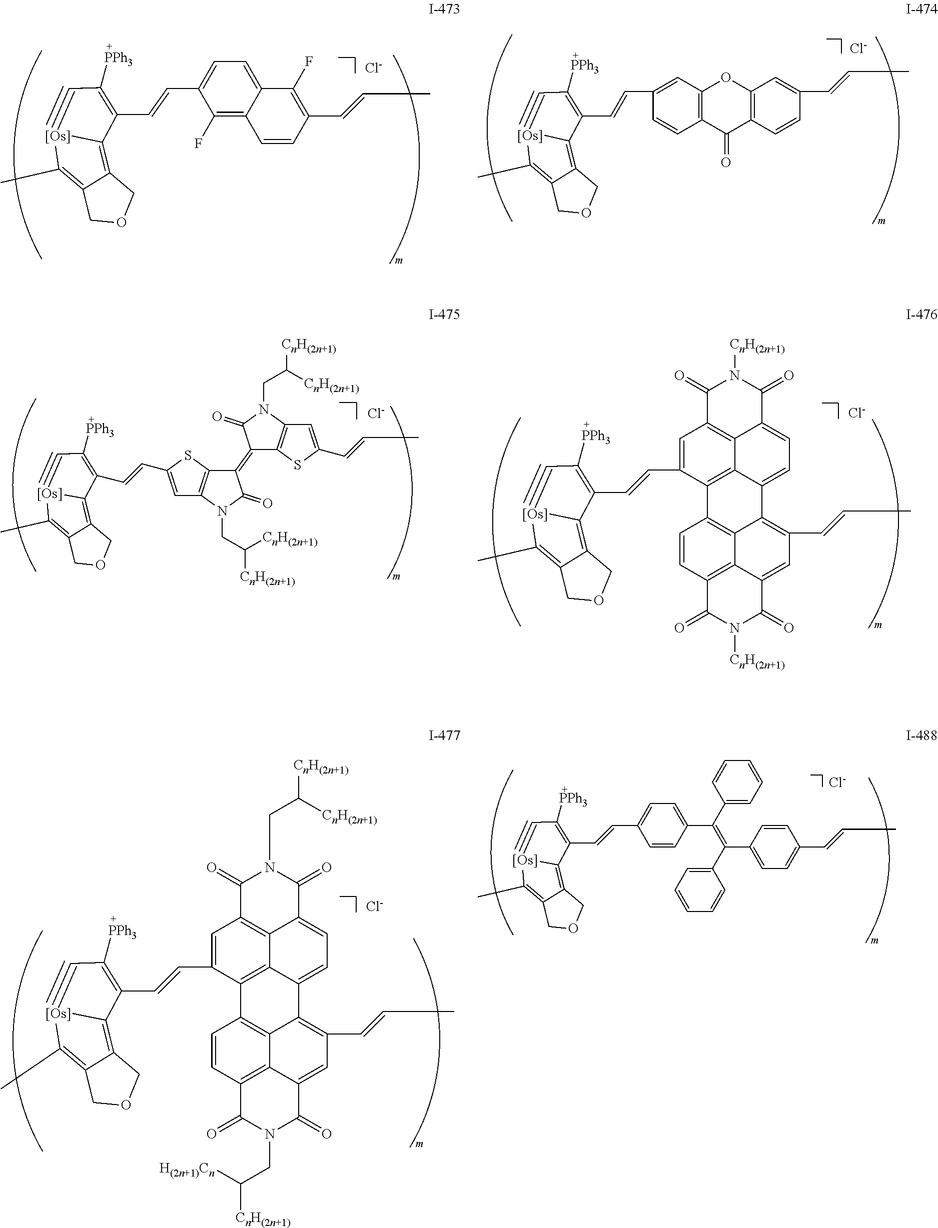

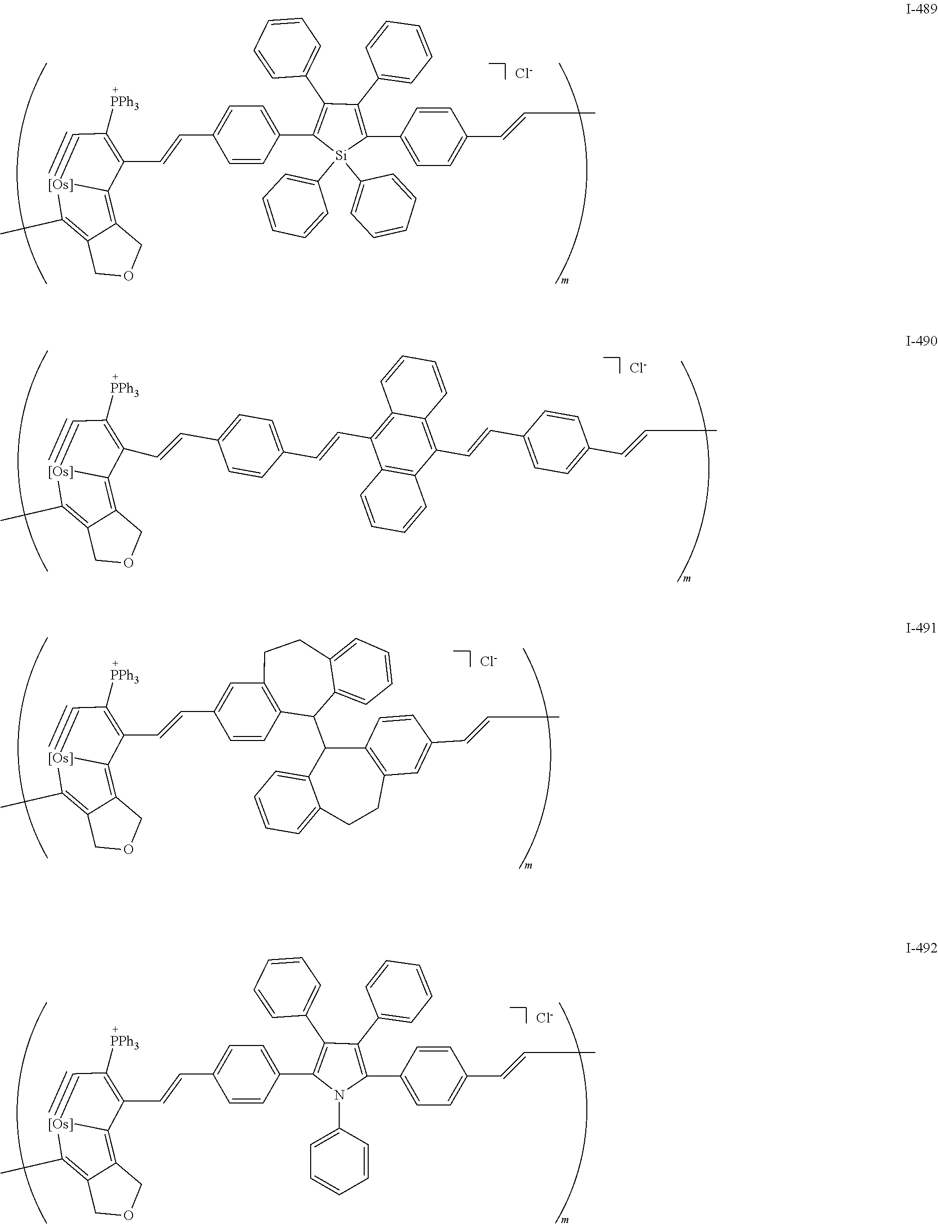

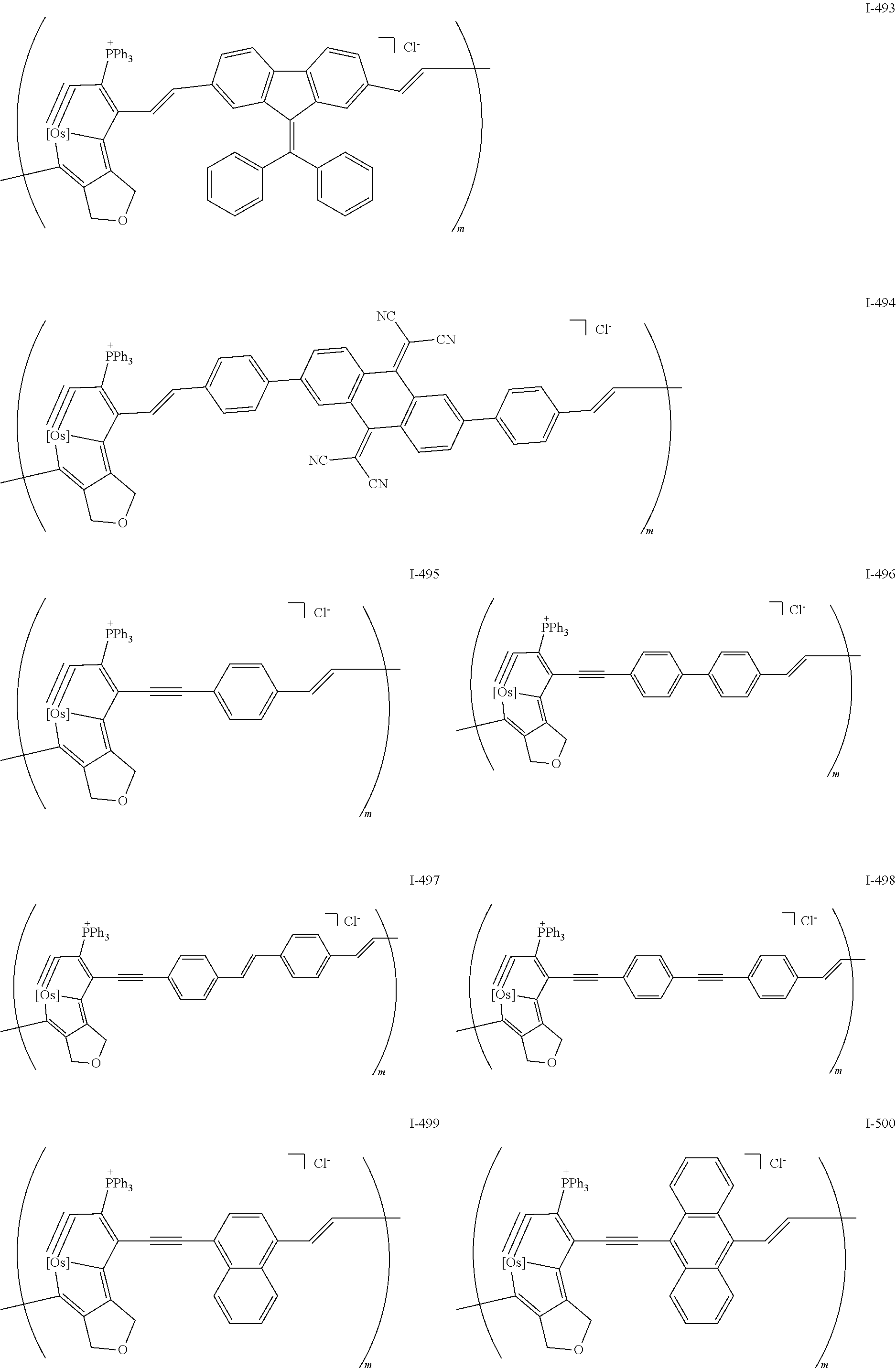

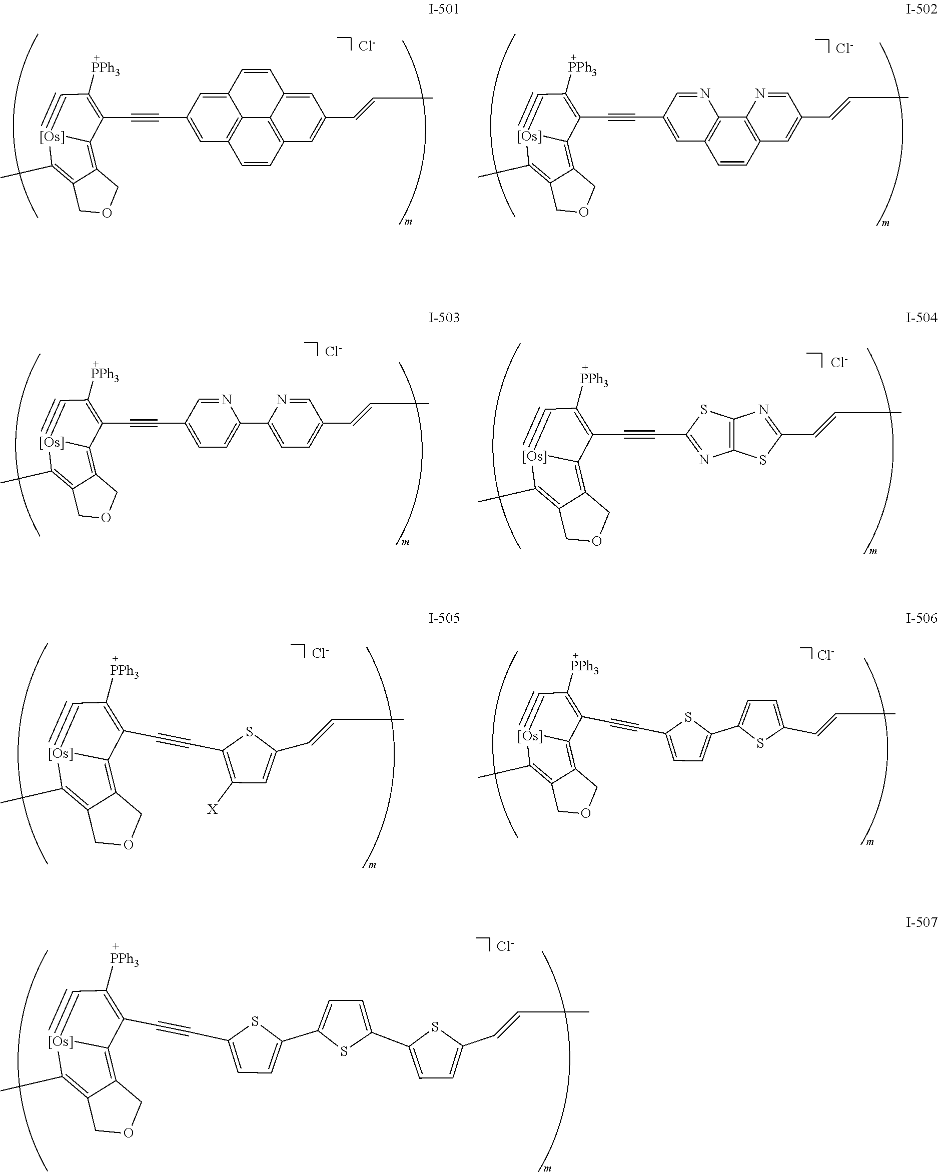

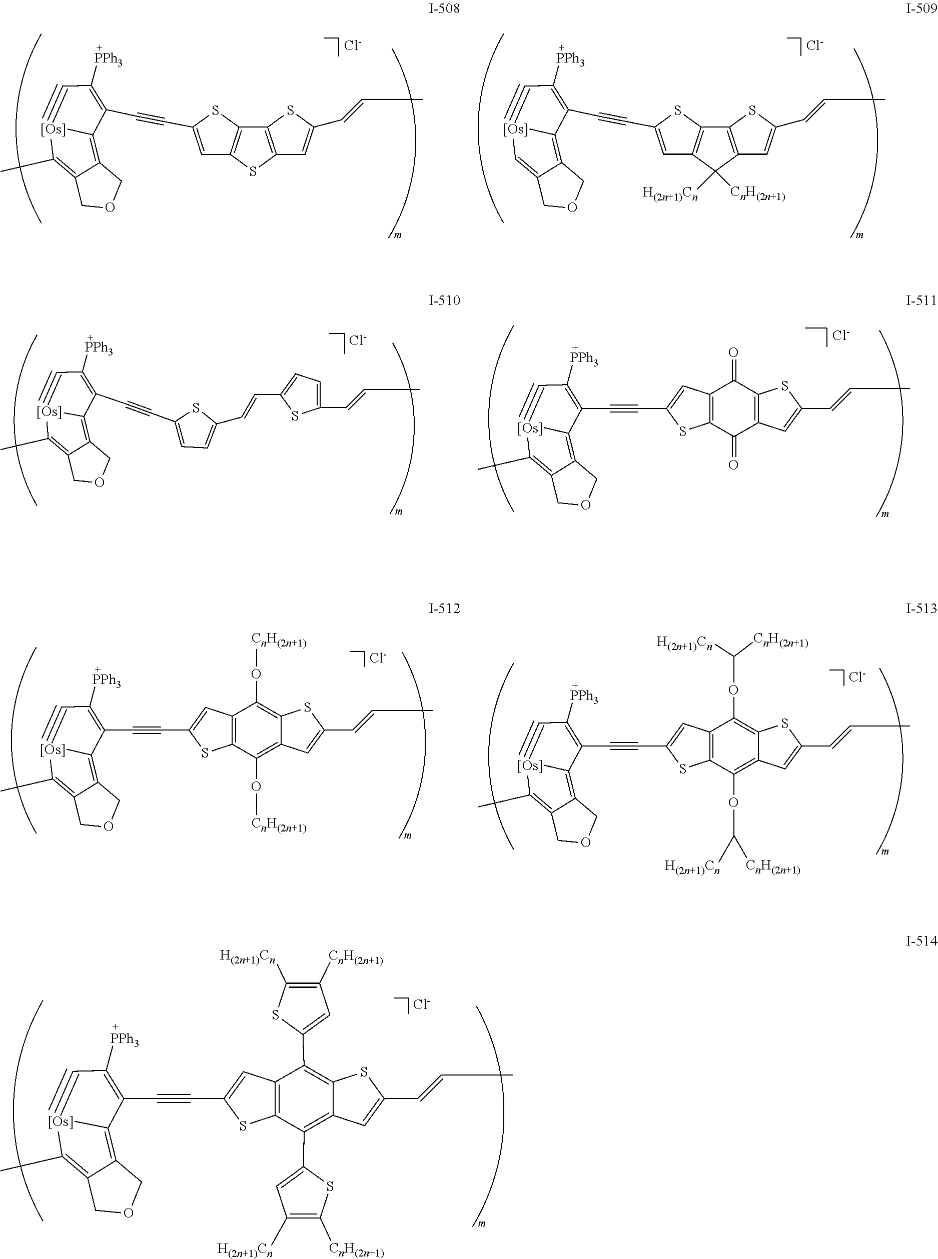

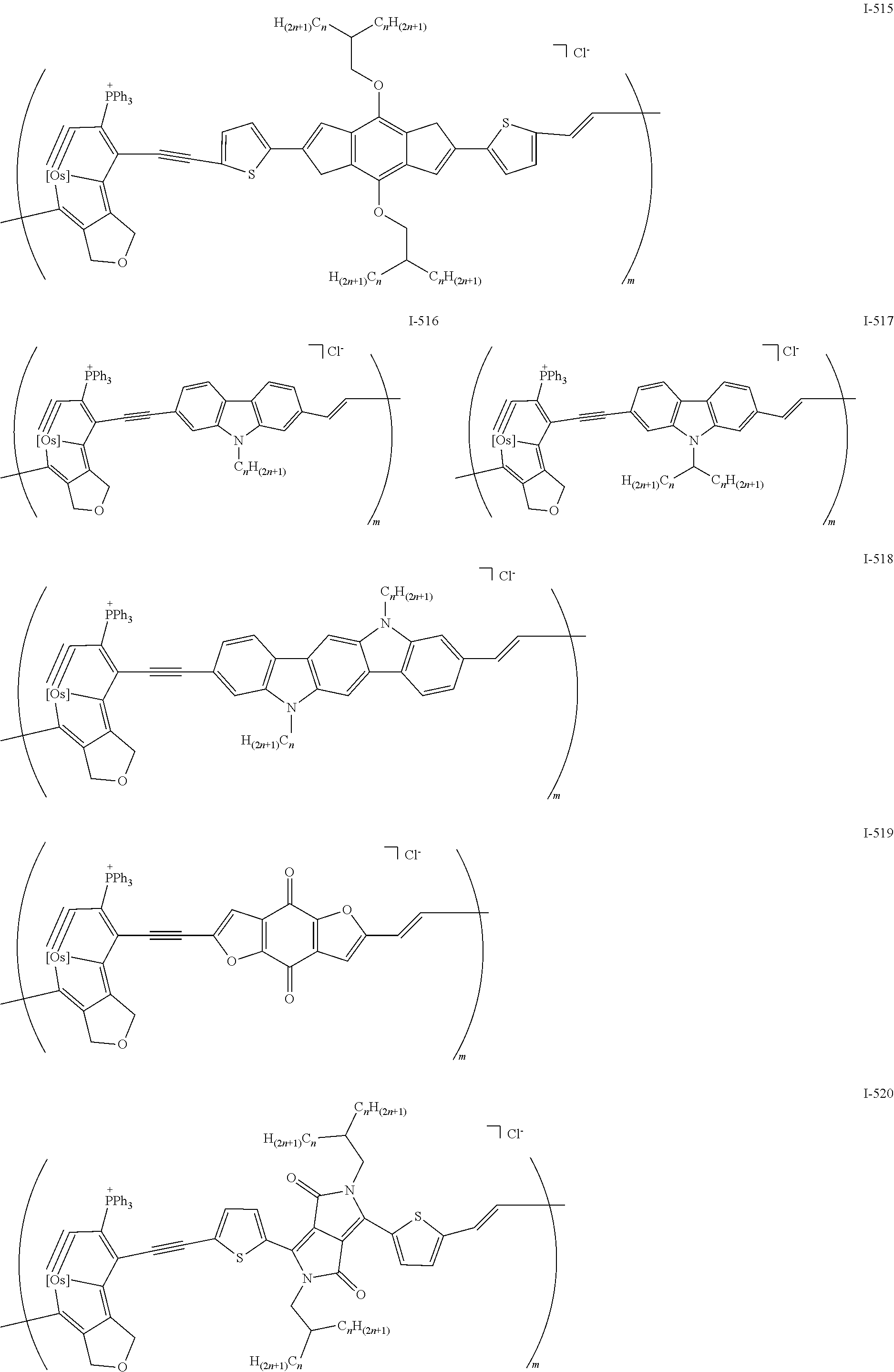

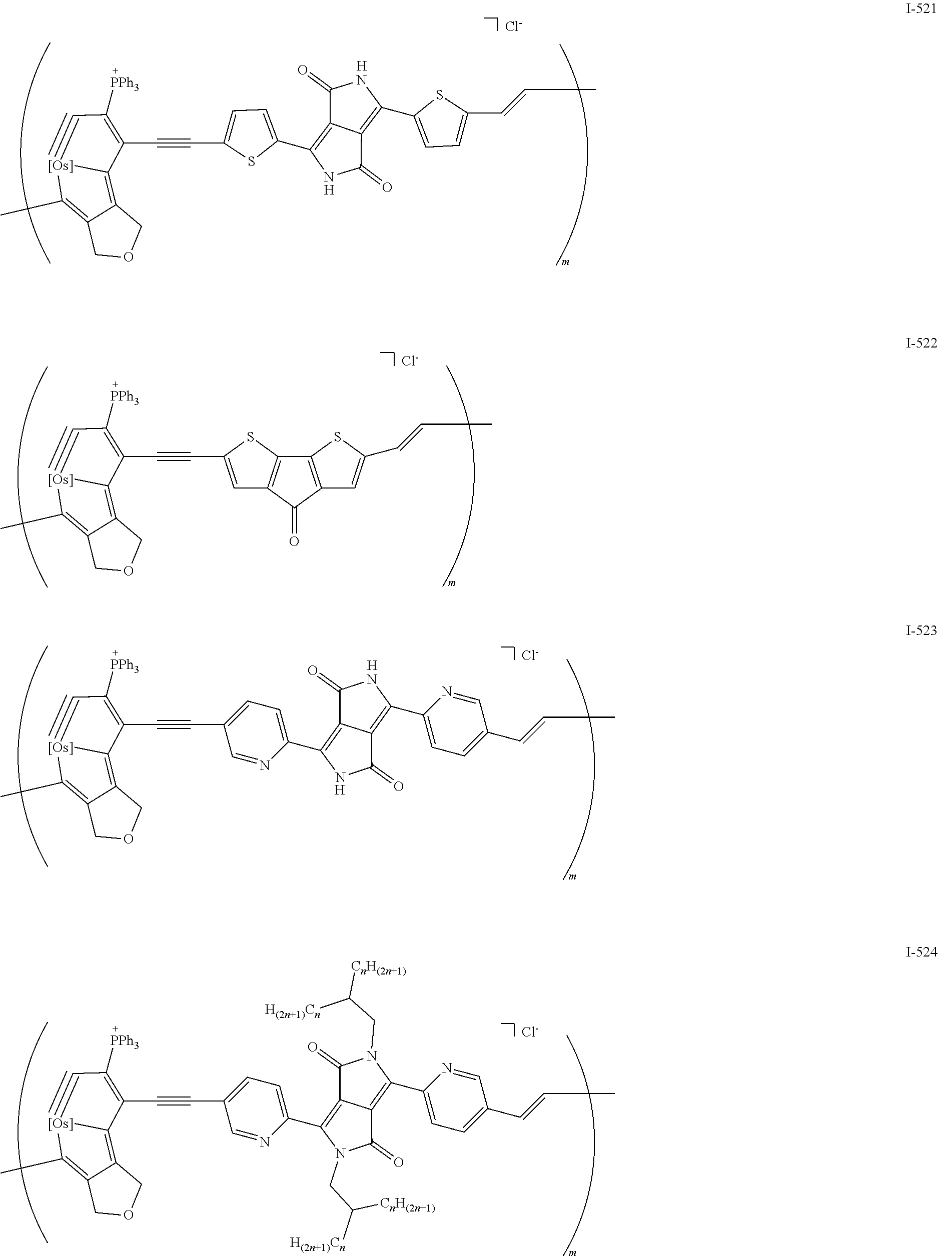

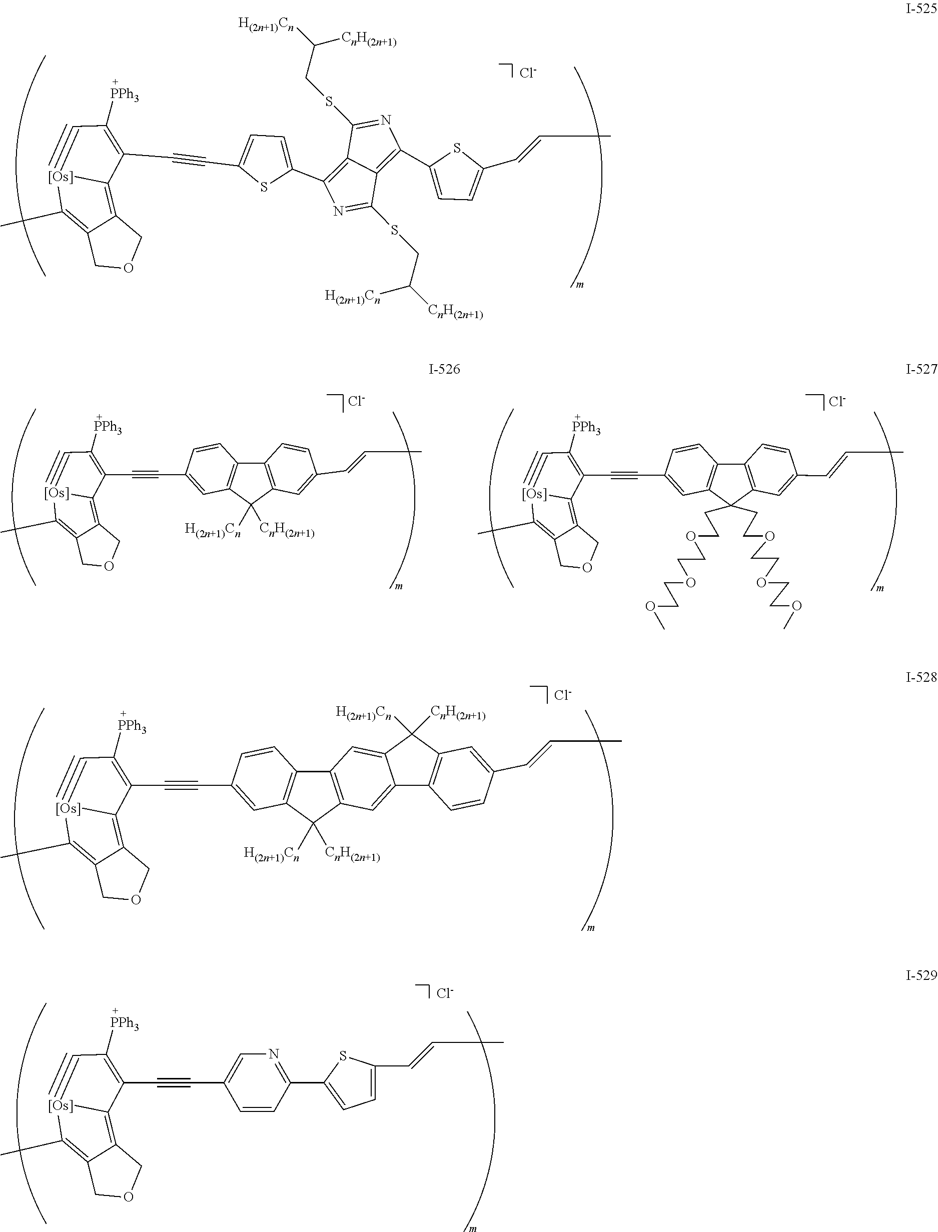

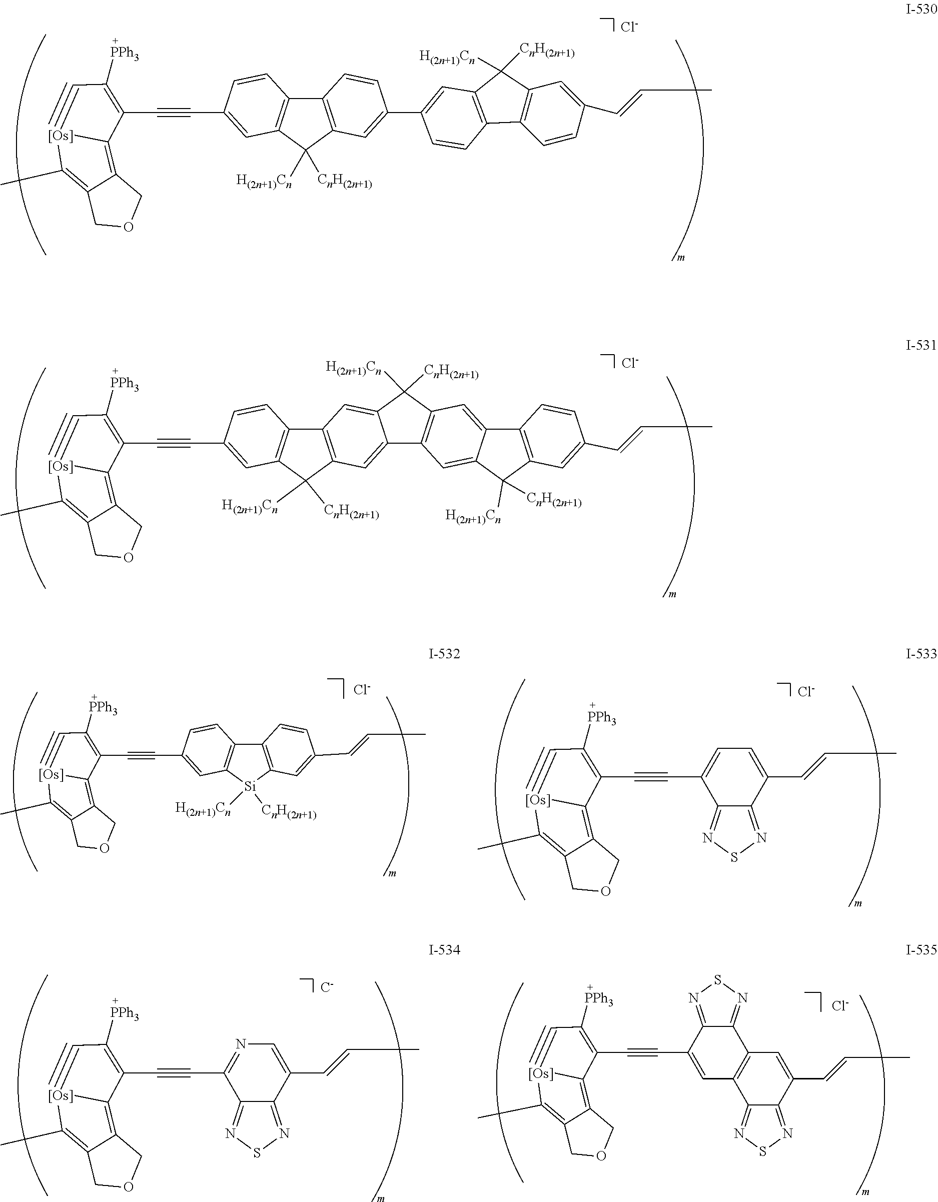

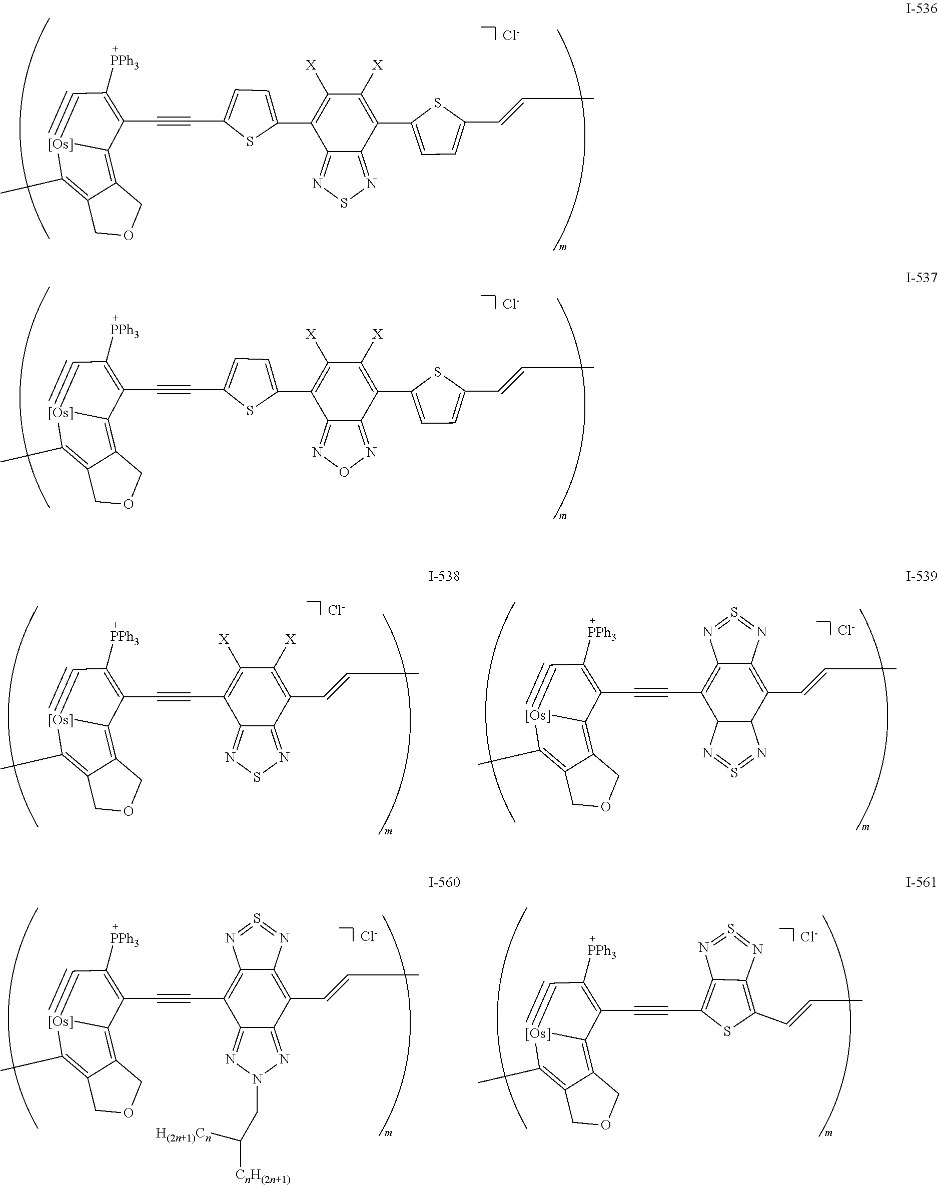

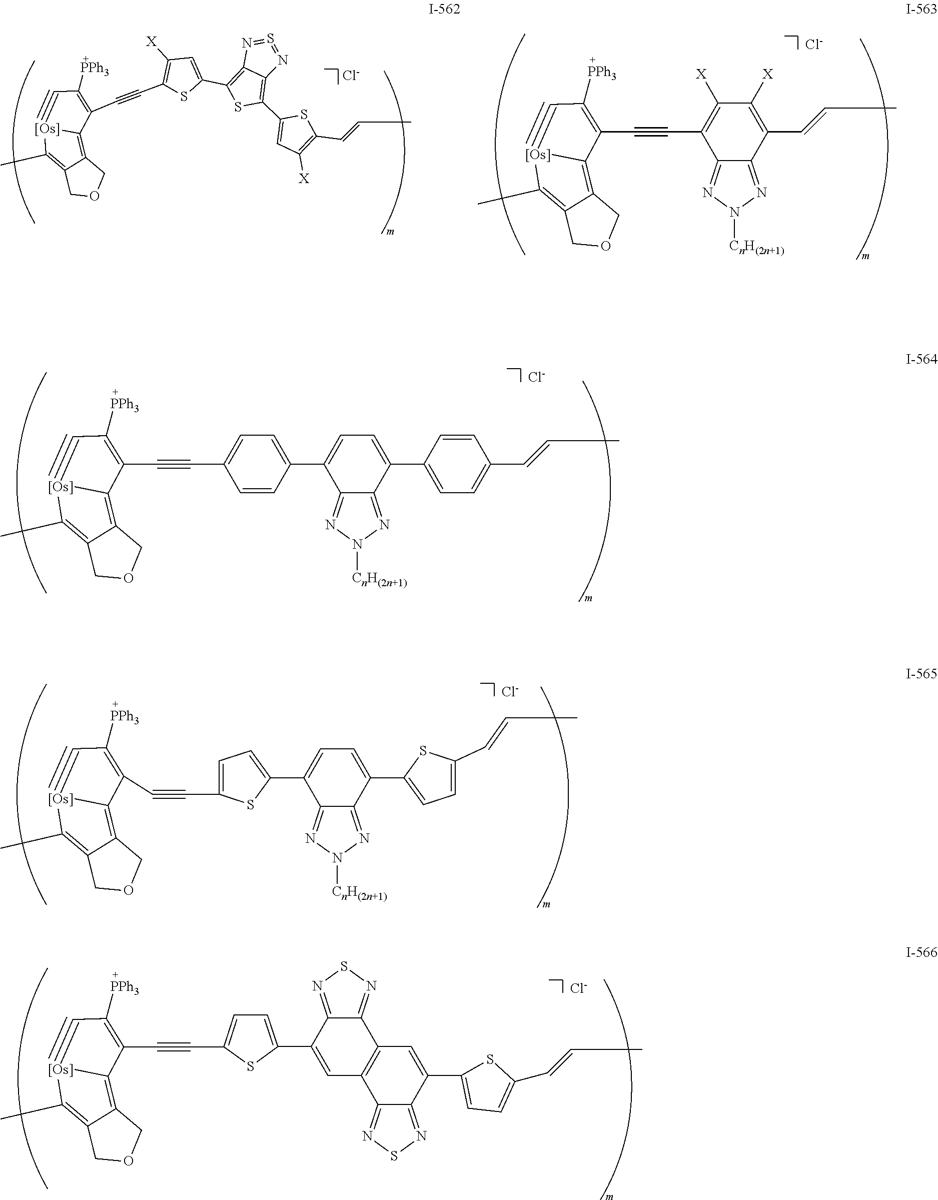

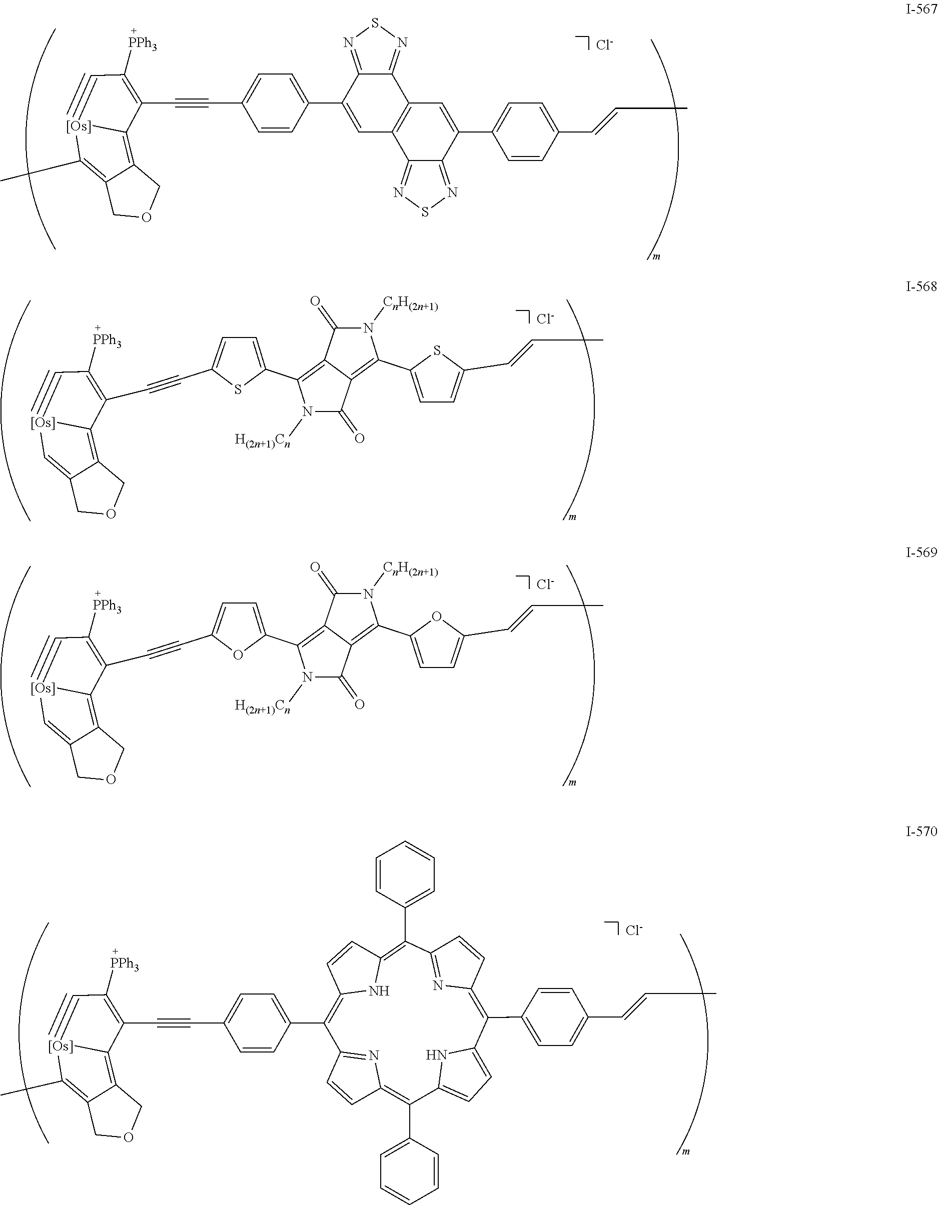

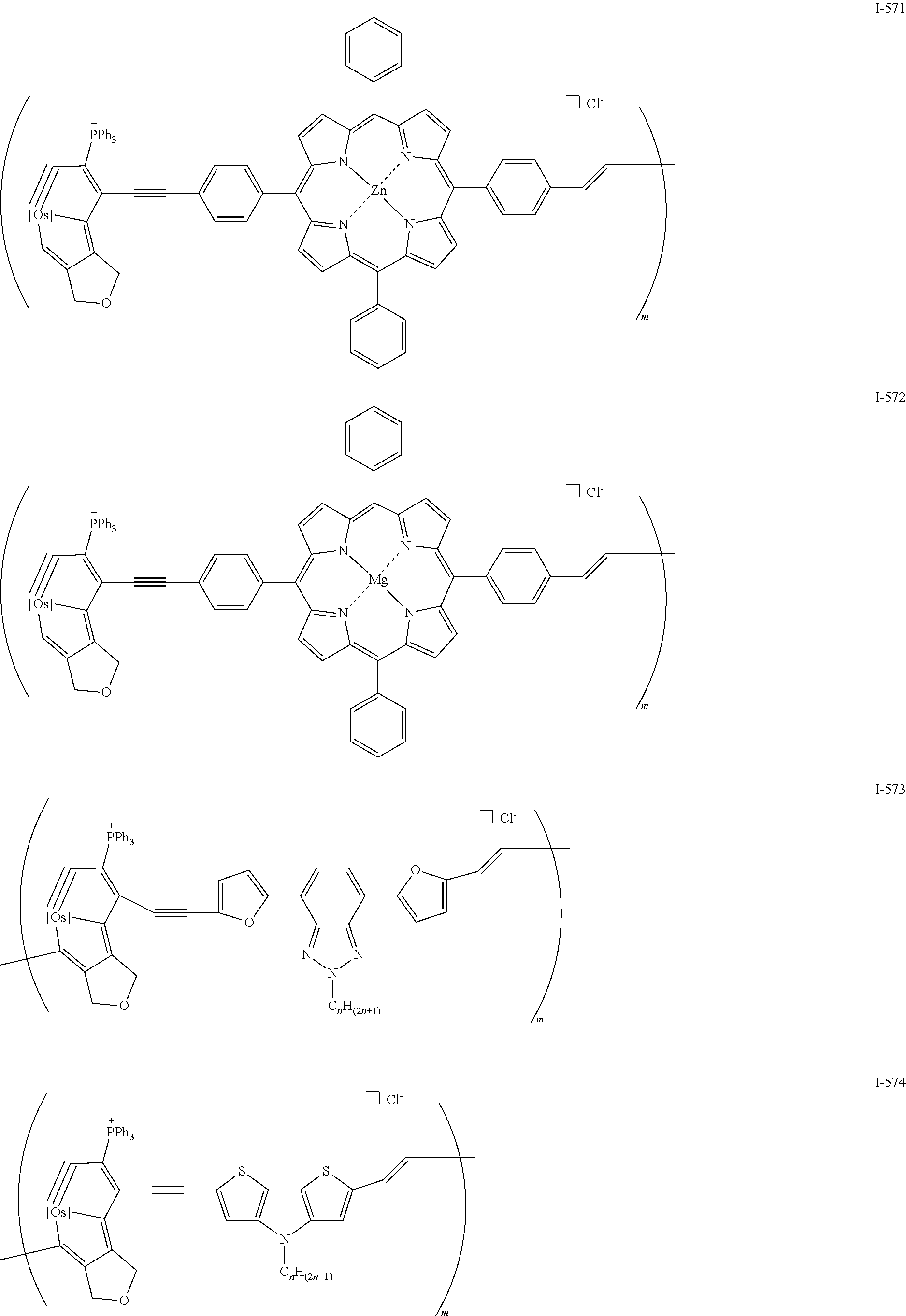

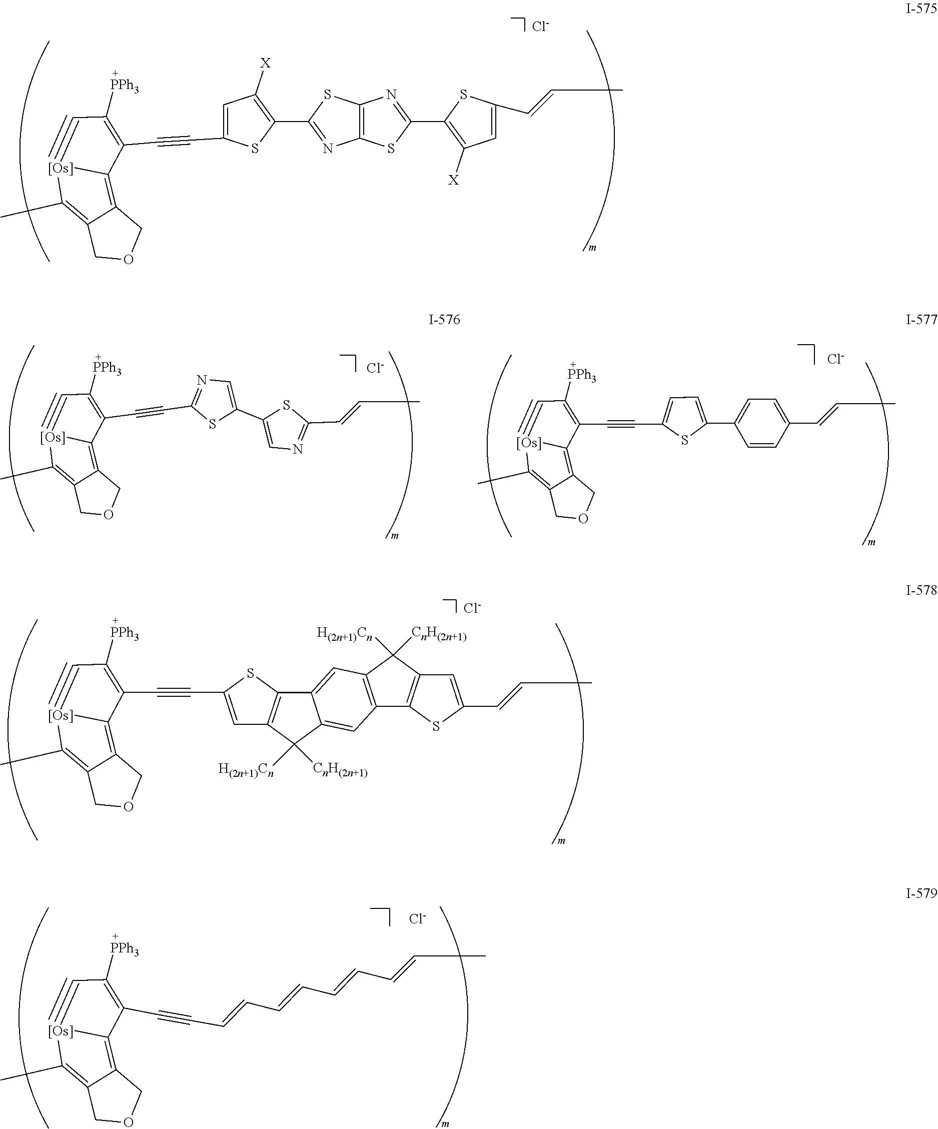

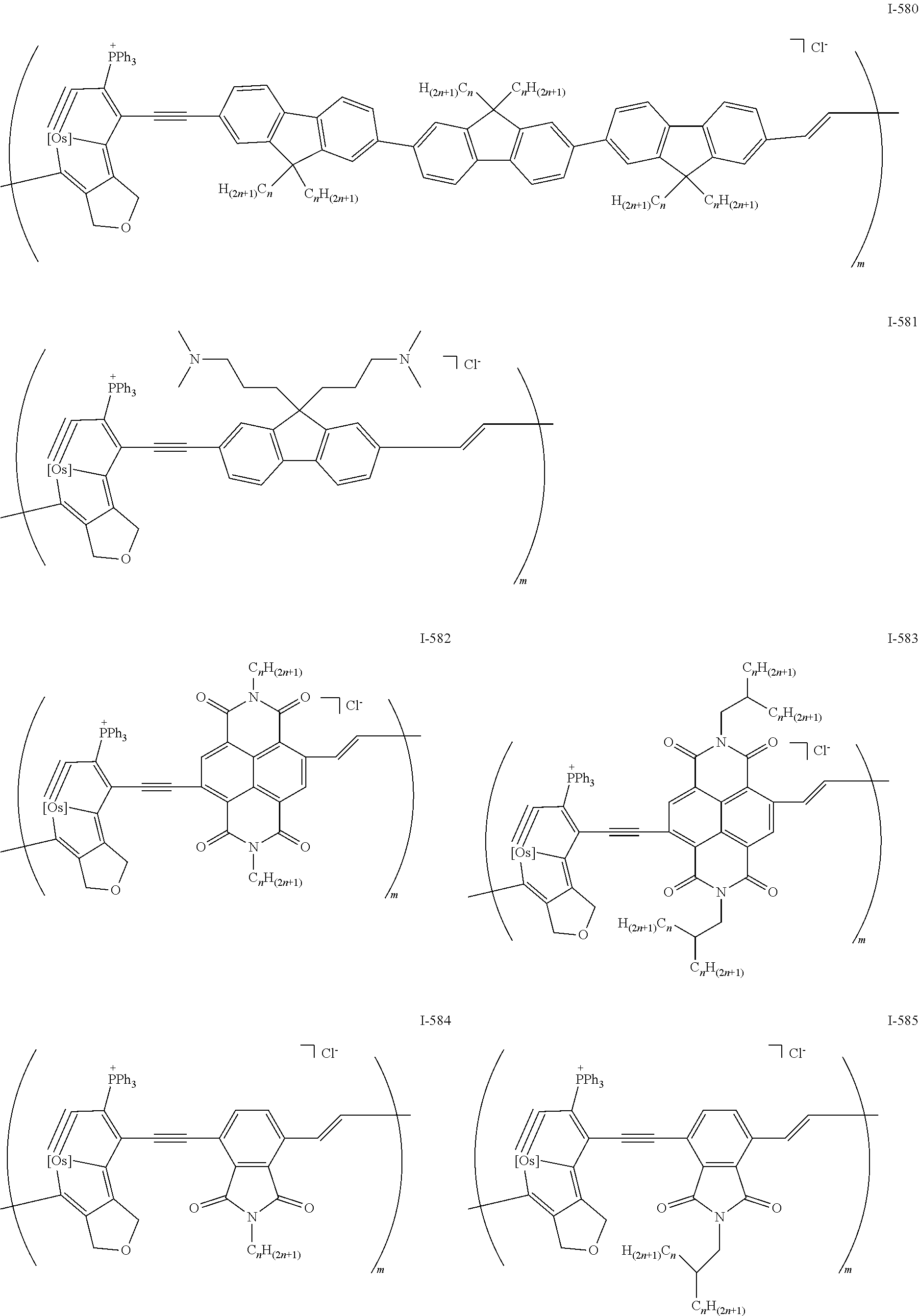

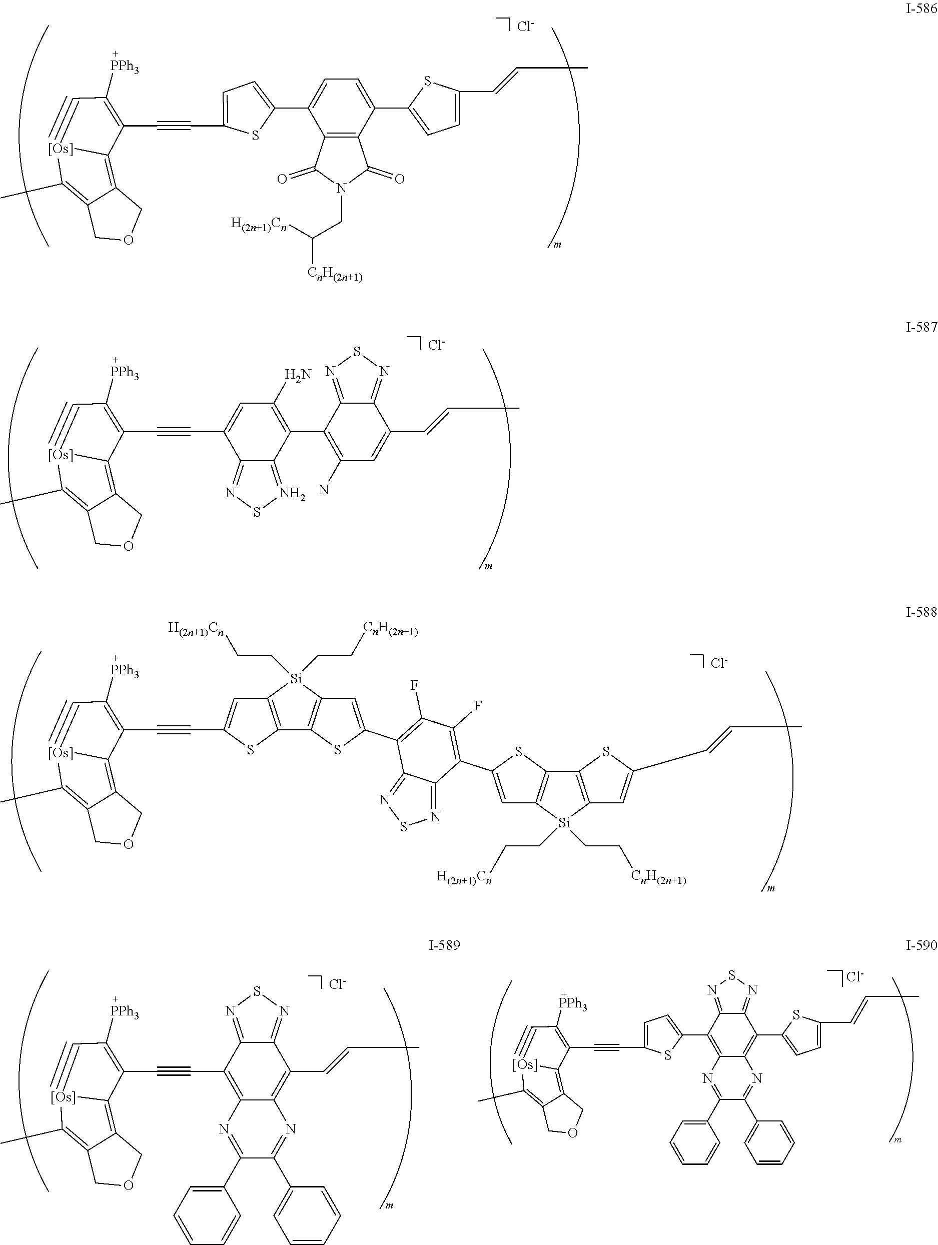

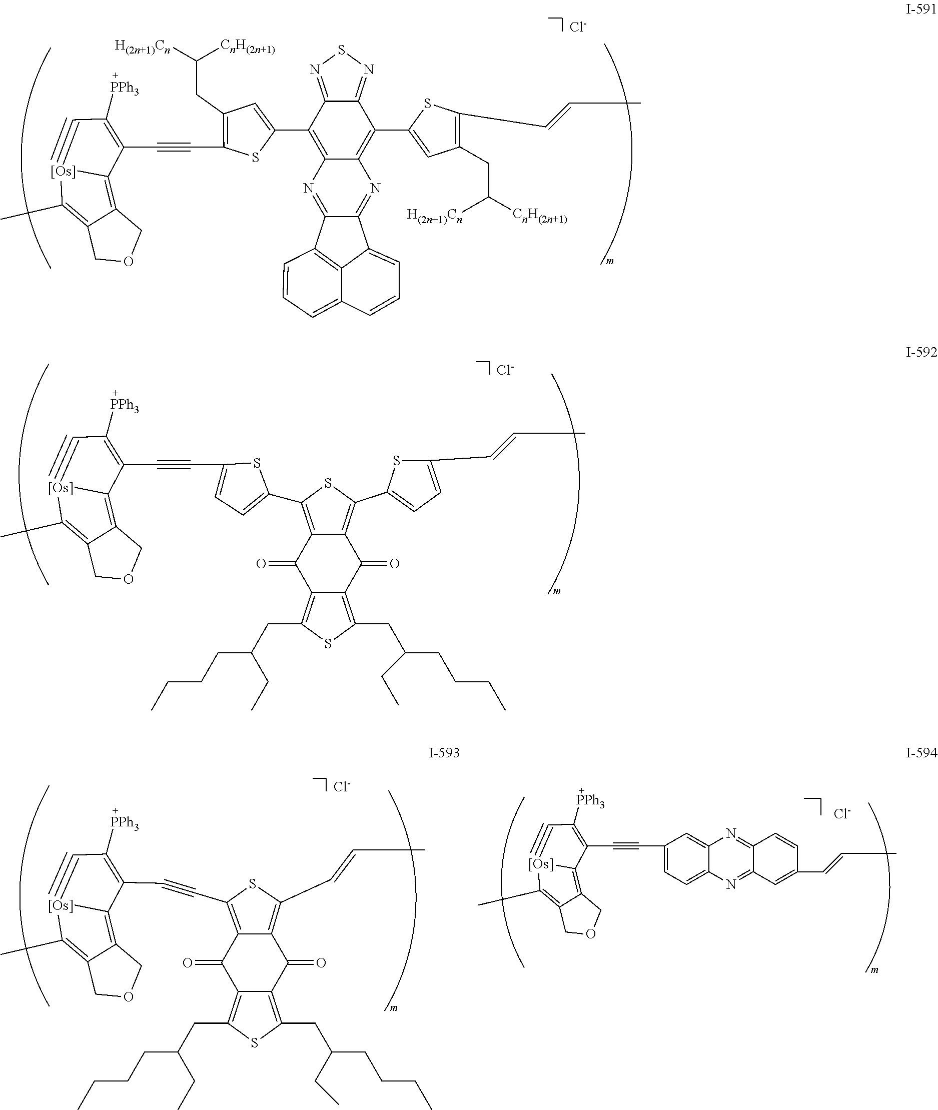

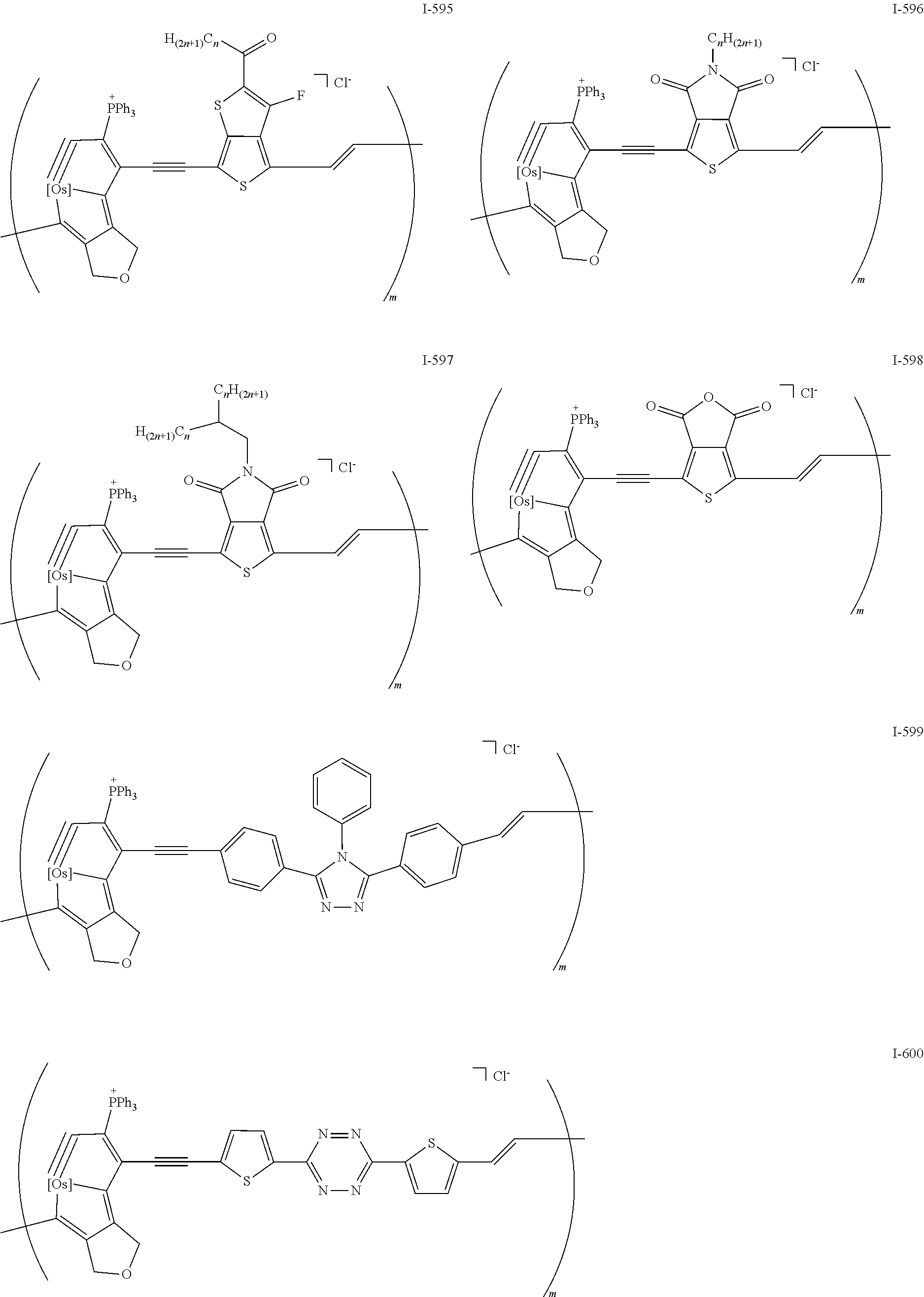

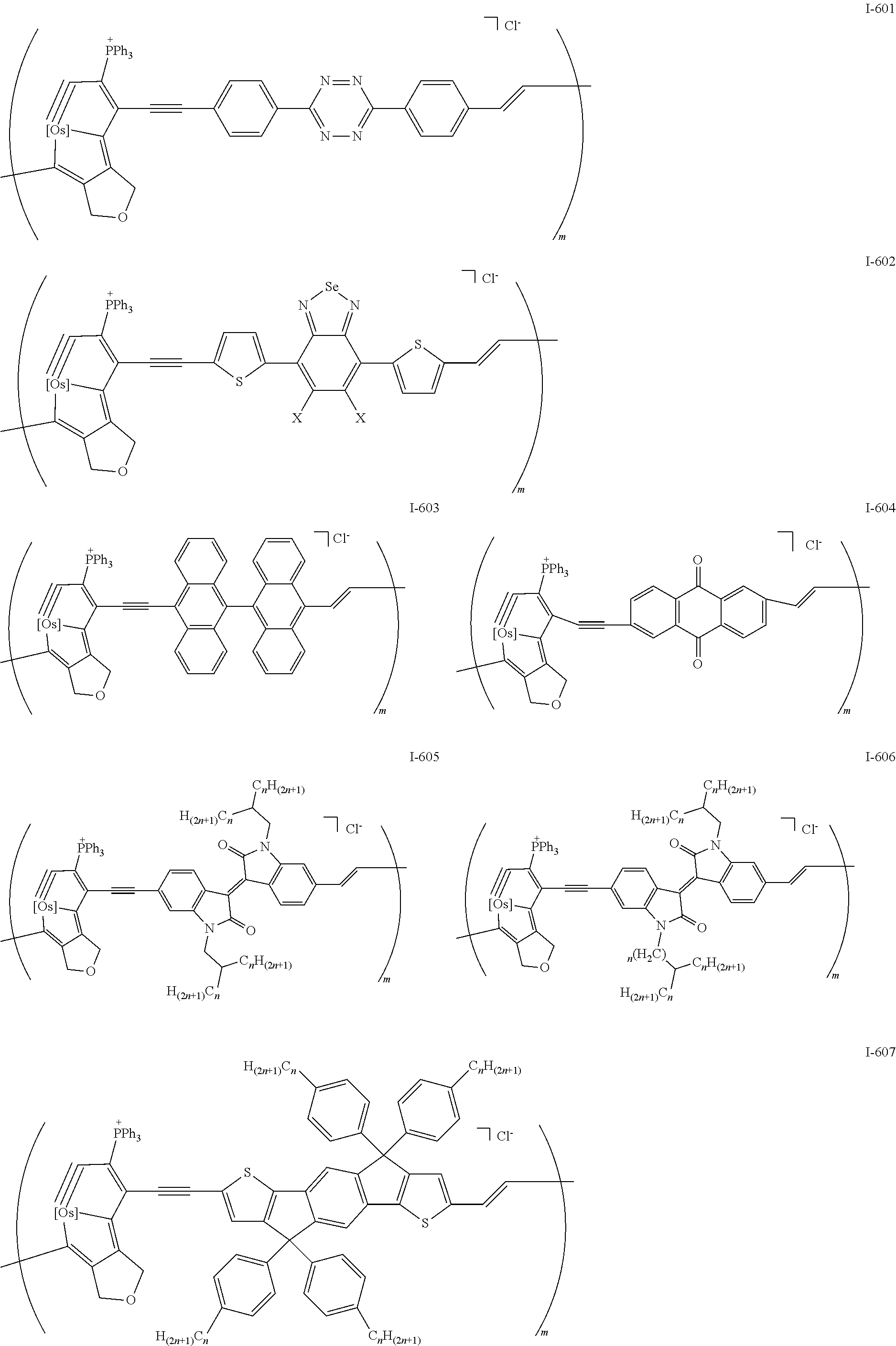

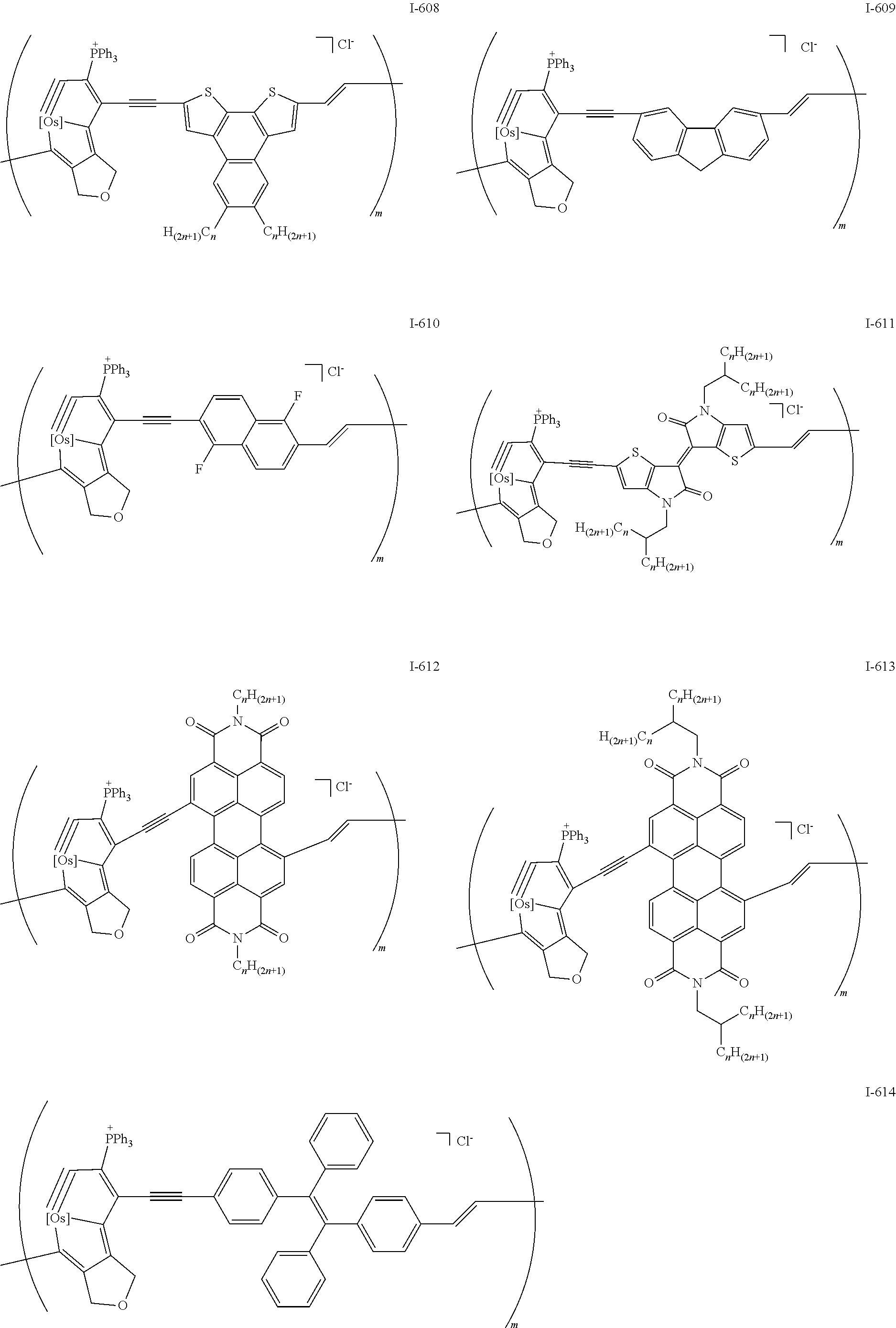

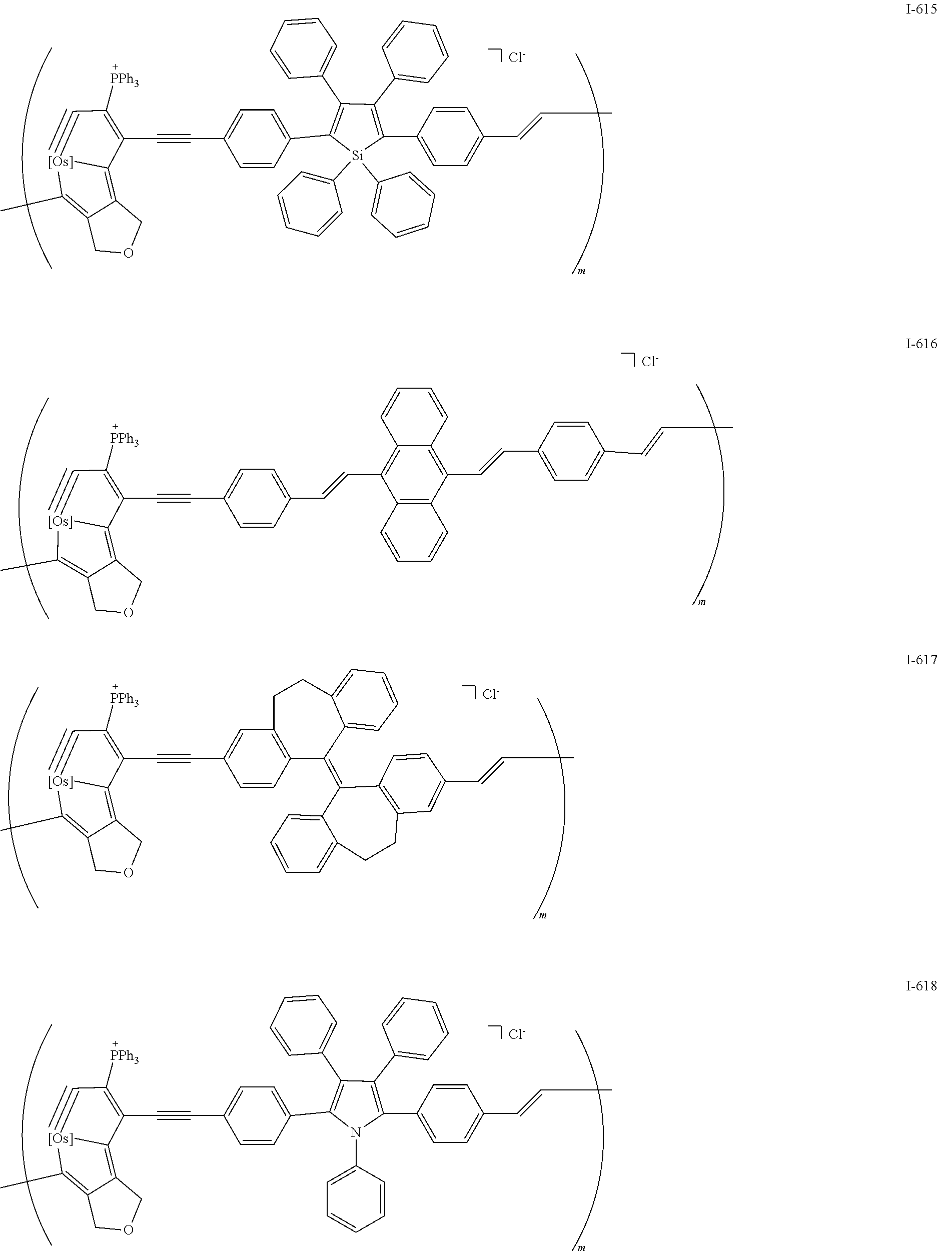

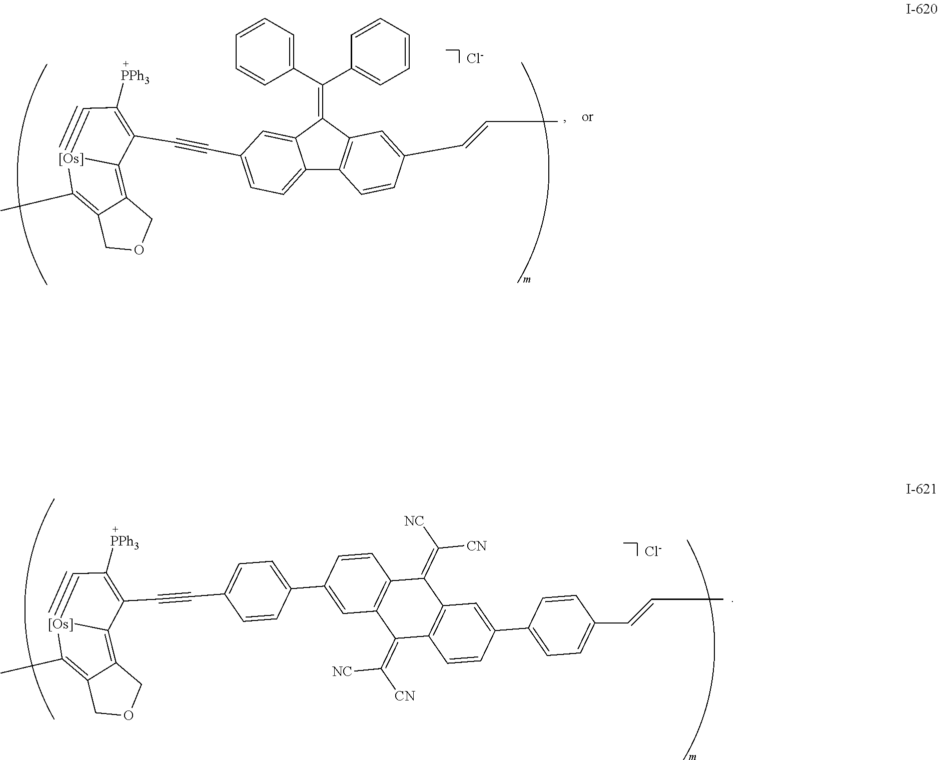

wherein the [Os] is OsCl(PPh3)2, n is an integer number of 0-30, preferably an integer between 0 and 20, more preferably an integer between 0 and 12, m is an integer between 3 and 300, preferably an integer between 3 and 200, more preferably an integer between 3 and 200, and X is hydrogen, fluorine, amino, nitro, or alkoxy with 1-32 carbon atoms, preferably alkoxy with 1-20 carbon atoms, more preferably alkoxy with 1-16 carbon atoms.

Another objective of the present disclosure is to provide a method for preparing the osmium-containing conjugated polymer. The technical solution comprises following steps: dissolving a monomer of the osmium-containing conjugated polymer in an organic solvent, and processing a polymerization reaction under acidic conditions to obtain the osmium-containing conjugated polymer, wherein a reaction formula of the method is as follows.

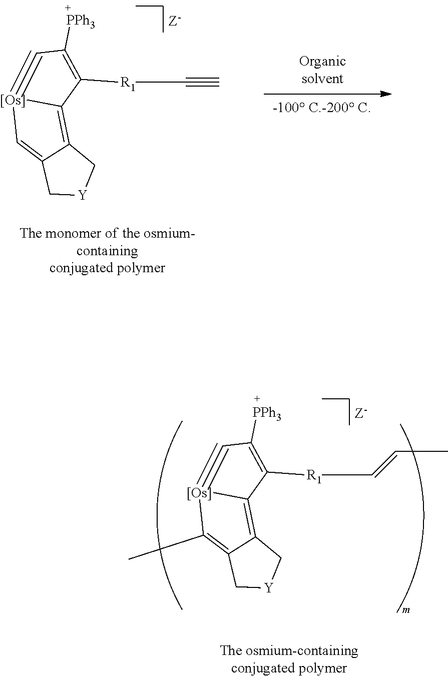

In a preferred embodiment of the present disclosure, an acid used in the acidic conditions comprises at least one of an inorganic acid or an organic acid.

Further, the inorganic acid comprises at least one of HClO₄, HI, HBr, HCl, HNO₃, H₂SeO₄, H₂SO₄, HClO₃, H₂C₂O₄, H₂SO₃, H₃PO₄, HNO₂, HF, H₂CO₃, H₂S, HClO, H₃BO₃, or H₂SiO₃.

Further, the organic acid comprises at least one of CH₃SO₃H, CF₃COOH, CCl₃COOH, CHCl₂COOH, CH₃COOH, or HCOOH.

In a preferred embodiment of the present disclosure, a reaction temperature is −100° C.-200° C.

In a preferred embodiment of the present disclosure, a reaction time is 1 minute-2 days, preferably 0.5 hours-1 day.

In a preferred embodiment of the present disclosure, the organic solvent comprises at least one of dichloromethane, dichloroethane, chloroform, methanol, ethanol, acetone, butanone, tetrahydrofuran, dimethyl sulfoxide, N,N-dimethylformamide, toluene, benzene, dioxane, diethyl ether, or acetonitrile, preferably dichloromethane.

The polymerization reaction is terminated by a terminal alkyne substituted with a substituent of 2-80 carbon atoms, preferably a terminal alkyne substituted with a substituent of 2-60 carbon atoms, more preferably a terminal alkyne substituted with a substituent of 2-40 carbon atoms, wherein the substituent comprises at least one of a third substituted aryl group, a third unsubstituted aryl group, a substituted alkyl group, an unsubstituted alkyl group, a substituted cycloalkyl group, or an unsubstituted cycloalkyl group.

The product is concentrated and precipitated to obtain a solid substance, and the solid substance is then filtered, washed, and separated to obtain the osmium-containing conjugated polymer.

Another objective of the present disclosure is to provide a method for applying the osmium-containing conjugated polymer in preparing organic optoelectronic members. The organic optoelectronic members specially comprises solar cells, light-emitting diodes, field-effect transistors, chemical sensors, photothermal therapy, or chemical switches.

Preferably, in the osmium-containing conjugated polymer, [Os] is OsCl(PPh₃)₂, X is CH₂ or O, R1 is vinyl substituted with aryl, preferably difluorenyl vinyl substituted with alkyl with 1-28 carbon atoms. The osmium-containing conjugated polymer is specially applicable for the solar energy cells. Further, the osmium-containing conjugated polymer is used as a material of a transport layer of the solar energy cells.

Preferably, in the osmium-containing conjugated polymer, [Os] is OsCl(PPh₃)₂, X is CH₂ or O, R1 is vinyl substituted with aryl, preferably vinyl substituted with dithienyl vinyl substituted with alkyl with 1-28 carbon atoms. The osmium-containing conjugated polymer is specially applicable for the light-emitting diodes. Further, the osmium-containing conjugated polymer is used as a material of a light-emitting layer of the light-emitting diodes.

Another objective of the present disclosure is to provide a main chain comprising an osmapentalyne-containing conjugated polymer and methods thereof.

A technical solution of the present disclosure is as follows.

A main chain comprising an osmapentalyne-containing conjugated polymer, a repeating unit of the osmapentalyne-containing conjugated polymer consists of a first group and a second group, the first group consists of a diosmapentalyne bridged with a conjugated linking group R₁, and the second group consists of a divinyl group bridged with a conjugated linking group R₂, wherein a specific structural formula of the repeating unit is as follows:

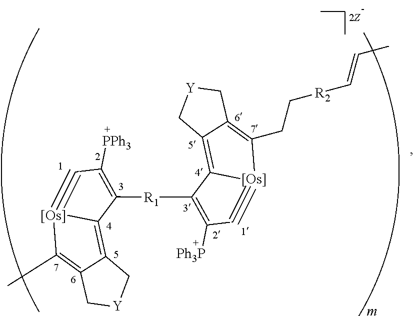

A 3rd position and a 3′rd position in the repeating unit are connected by the conjugated linking group R₁, and the divinyl group is connected to a 7th position and a 7′th position of the diosmapentalyne compound.

The [Os] is OsAL₂, wherein A is at least one of —H, halogen, —SCN, or —CN, L is at least one of a phosphine ligand, a CO ligand, a pyridine ligand, a nitrile ligand, or an isocyanide two-electron ligand, and the halogen at least one of —F, —Cl, —Br, or —I.

The Y is at least one of CH₂, O, or C(COO(CH₂)ₖMe)₂, and k is an integer between 0 and 12, preferably an integer between 0 and 18, more preferably an integer between 0 and 6.

The conjugated linking group R₁ is at least one of a first substituted aryl group, a first unsubstituted aryl group, a substituted alkenyl group, an unsubstituted alkenyl group, a substituted alkynyl group, or an unsubstituted alkynyl group, wherein a substituted vinyl group or an unsubstituted vinyl group is a trans vinyl group when the substituted alkenyl group or the unsubstituted alkenyl group is the substituted vinyl group or the unsubstituted vinyl group.

The conjugated linking group R₂ is at least one of the first substituted aryl group, the first unsubstituted aryl group, the substituted alkenyl group, the unsubstituted alkenyl group, the substituted alkynyl group, or the unsubstituted alkynyl group, wherein the substituted vinyl group or the unsubstituted vinyl group is the trans vinyl group when the substituted alkenyl group or the unsubstituted alkenyl group is the substituted vinyl group or the unsubstituted vinyl group.

The Z⁻ is an anion.

The m is an integer between 3 and 300, preferably an integer between 3 and 200, more preferably an integer between 3 and 100.

In a preferred embodiment of the present disclosure, the anion comprises at least one of F⁻, Cl⁻, Br⁻, I⁻, BF₄, H₂PO₄⁻, C₂O₄²⁻, SO₄²⁻, CF₃SO₃⁻, CH₃COO⁻, (CF₃SO₂)₂N⁻, NO₃⁻, ClO₄⁻, PF₆⁻, or BPh₄⁻. Further, the Z⁻ is at least one of Cl⁻, Br⁻, BF₄⁻, CF₃SO₃⁻, PF₆⁻, or BPh₄⁻.

In a preferred embodiment, a phosphine ligand of the L in the [Os] comprises at least one of alkyl phosphine, cycloalkyl phosphine, or arylphosphine with 3-24 carbon atoms, preferably 5-20 carbon atoms, more preferably with 6-18 carbon atoms. In a more preferred embodiment, the phosphine ligand is at least one of trimethylphosphine, triethylphosphine, tripropylphosphine, triisopropylphosphine, tri-tert-butylphosphine, tricyclohexylphosphine, or triphenylphosphine.

In a preferred embodiment, a pyridine ligand of the L in the [Os] is a ligand containing a pyridine structural unit or bipyridine structural unit. Preferably, the pyridine ligand is at least one of methylpyridine, ethylpyridine, 1,4-bipyridine, 1,2-bis(4-pyridyl)ethylene, vinylpyridine, ethynylpyridine, pyridine boronic acid, aminopyridine, cyanopyridine, mercaptopyridine, dimethylaminopyridine, phenylpyridine, or 1,2-bis(4-pyridyl)ethane.

In a preferred embodiment, a nitrile ligand of the L in the [Os] is a ligand containing a nitrile group structural unit, and the nitrile ligand is preferably acetonitrile, propionitrile, or benzonitrile.

In a preferred embodiment, an isocyanate-type two-electron ligand of the L in the [Os] is a ligand containing an isocyano structural unit, the isocyanate-type two-electron ligand is preferably at least one of cyclohexyl isocyanide, tert-butyl isocyanide, or phenyl isocyanide.

In a preferred embodiment of the present disclosure, the L in the [Os] is at least one of triphenylphosphine, trimethylphosphine, triethylphosphine, tripropylphosphine, triisopropylphosphine, tri-tert-butylphosphine, tricyclohexylphosphine, methylpyridine, ethylpyridine, 1,4-bipyridine, 1,2-bis(4-pyridyl)ethylene, vinylpyridine, ethynyl Pyridine, pyridine boronic acid, aminopyridine, cyanopyridine, mercaptopyridine, dimethylaminopyridine, phenylpyridine, 1,2-bis(4-pyridyl)ethane, imidazole-type N-heterocyclic carbene, imidazoline-type N-heterocyclic carbene, thiazole-type N-heterocyclic carbene, triazol-type N-heterocyclic carbene, acetonitrile, propionitrile, benzonitrile, cyclohexyl isocyanide, tert-butyl isocyanide, or phenyl isocyanide.

In a preferred embodiment, the L₂ in the [Os] is at least one of a bidentate nitrogen ligand, a bidentate phosphine ligand, a bidentate carbon-nitrogen ligand, or a bidentate oxygen-nitrogen ligand.

In a preferred embodiment, the bidentate nitrogen ligand of the L₂ in the [Os] is a ligand using a bidentate nitrogen atom as a coordinating atom, and the bidentate nitrogen ligand comprises at least one of ethylenediamine, 2,2′-bipyridine, or 1,10-phenanthroline.

In a preferred embodiment, the bidentate phosphine ligand of the L₂ in the [Os] is a ligand using a bidentate phosphine atom as a coordinating atom, and the bidentate phosphine ligand comprises at least one of 1,1-bis(diphenylphosphino)methane (DPPM), 1,2-Bis(diphenylphosphino)ethane (DPPE), or 1,3-bis(diphenylphosphino) propane (DPPP).

In a preferred embodiment, the bidentate carbon-nitrogen ligand of the L₂ in the [Os] is a ligand using a bidentate carbon-nitrogen atom as a coordinating atom, and the bidentate carbon-nitrogen ligand comprises ortho-phenylpyridine.

In a preferred embodiment, the bidentate oxygen-nitrogen ligand of the L₂ in the [Os] is a ligand using a bidentate oxygen-nitrogen atom as a coordinating atom, and the bidentate oxygen-nitrogen ligand comprises 8-hydroxyquinoline.

In a preferred embodiment of the present disclosure, the L₂ in the [Os] is integrated, and L₂ is at least one of ethylenediamine, 2,2′-bipyridine, 1,10-phenanthroline, 1,1-bis(diphenylphosphine)methane, 1,2-bis (diphenylphosphine)ethane, 1,3-bis(diphenylphosphine)propane, ortho-phenylpyridine, or 8-hydroxyquinoline.

In a preferred embodiment, an aryl group in the first substituted aryl group or the first unsubstituted aryl group is at least one of phenyl, diphenyl, terphenyl, naphthyl, anthryl, fiki, pyrene, thienyl, dithienyl, terthienyl, dithienyl vinyl, thiazolyl, thiadiazolyl, bis-thiadiazolyl, bis-terthienyl, furanyl, pyridyl, pyrrolyl, porphyrin, fluorenyl, bifluorenyl, terfluorenyl, carbazolyl, bicarbazolyl, tercarbazolyl, benzothiadiazolyl, tetrastyryl, hexabenzocoronyl, diketopyrrolopyrrole-based, benzodithienyl, indacenodithienyl, silyl fluorenyl, dithienocyclodecadiene, dithienosilole-based, dithienopyrrole-based, triphenylamino, naphthalenedithiadiazolyl, naphthalenetetracarboxylic diimide-based, perylenetetracarboxylic diimide-based, isoindigo-based, thienopyrroledione-based, benzopyrroledione-based, benzotriazolyl, thiadiazolobenzotriazolyl, pyridothiadiazolyl, or thieno[3,4-b]thienyl. The aryl group can improve a conductive performance of the osmapentalyne-containing conjugated polymer. A substitution reaction can occur at any position of the aryl group.

Even further, a substitution base in the first substituted aryl group or the first unsubstituted aryl group comprises at least one of alkyl with 1-28 carbon atoms, preferably alkyl with 1-20 carbon atoms, more preferably alkyl with 1-14 carbon atoms, alkoxy, alkylthio, acyl, ester, amino, or amide with 1-20 carbon atoms, preferably alkoxy, alkylthio, acyl, ester, amine, or amide with 1-17 carbon atoms, more preferably alkoxy, alkylthio, acyl, ester, amine, or amide with 1-14 carbon atoms, amide substituted with 2-20 carbon atoms, preferably amide substituted with 2-17 carbon atoms, more preferably amide substituted with 2-8 carbon atoms, cycloalkyl with 3-20 carbon atoms, preferably cycloalkyl with 3-17 carbon atoms, more preferably cycloalkyl with 3-8 carbon atoms, alkenyl or alkynyl with 1-20 carbon atoms, preferably alkenyl or alkynyl with 1-17 carbon atoms, more preferably alkenyl or alkynyl with 1-14 carbon atoms, nitro, cyano, or halogen. The substitution base can improve water solubility of the osmapentalyne-containing conjugated polymer.

Specially, the alkyl with the 1-28 carbon atoms is at least one of methyl, ethyl, n-propyl, isopropyl, n-butyl, isobutyl, sec-butyl, tert-butyl, n-pentyl, isopentyl, neopentyl, sec-pentyl, tert-pentyl, n-hexyl, isohexyl, neohexyl, sec-hexyl, tert-hexyl, n-heptyl, isoheptyl, neoheptyl, sec-heptyl, tert-heptyl, n-octyl, isooctyl, neooctyl, sec-octyl, tert-octyl, n-dodecyl, n-hexadecyl, n-octadecyl, n-eicosyl,

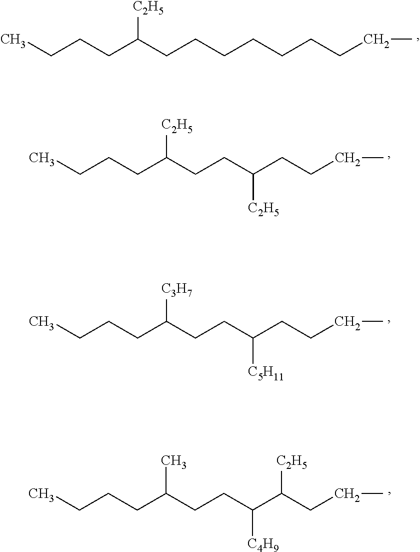

2-ethylhexyl, 2-butylhexyl, 2-hexyloctyl, 2-octyldecyl, 2-decyldodecyl, 2-decyltetradecyl, or 2-dodecylhexadecyl.

Specially, the alkoxy with the 1-20 carbon atoms is at least one of methoxy, ethoxy, n-propoxy, isopropoxy, n-butoxy, isobutoxy, sec-butoxy, tert-butoxy, n-pentyloxy, isopentyloxy, neopentyloxy, sec-pentyloxy, tert-pentyloxy, n-hexyloxy, isohexyloxy, neohexyloxy, sec-hexyloxy, tert-hexyloxy, n-heptyloxy, isoheptyloxy, neoheptyloxy, sec-heptyloxy, tert-heptyloxy, n-octyloxy, isooctyloxy, neooctyloxy, sec-octyloxy, tert-octyloxy, n-dodecyloxy, n-hexadecyloxy, n-octadecyloxy, or n-eicosyloxy.

Specially, the alkylthio with the 1-20 carbon atoms is at least one of methylthio, ethylthio, n-propylthio, isopropylthio, n-butylthio, isobutylthio, sec-butylthio, tert-butylthio, n-pentylthio, isopentylthio, neopentylthio, sec-pentylthio, tert-pentylthio, n-hexylthio, isohexylthio, neohexylthio, sec-hexylthio, tert-hexylthio, n-heptylthio, isoheptylthio, neoheptylthio, sec-heptylthio, tert-heptylthio, n-octylthio, isooctylthio, neooctylthio, sec-octylthio, tert-octylthio, n-dodecylthio, n-hexadecylthio, n-octadecylthio, or n-eicosylthio.

Specially, the acyl with the 1-20 carbon atoms is at least one of

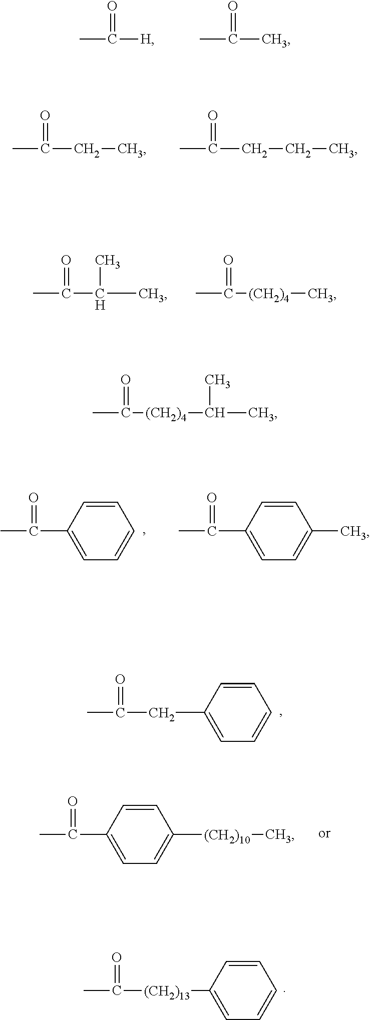

Specially, the ester with the 1-20 carbon atoms is a monovalent group with 1-20 carbon atoms and containing

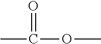

of an ester bond. The ester with the 1-20 carbon atoms is at least one of

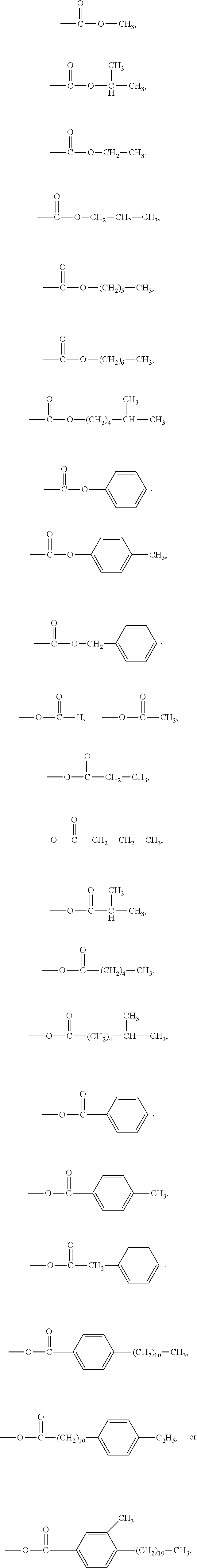

Specially, the amino with the 1-20 carbon atoms is at least one of methylamino, ethylamino, propylamino, butylamino, pentylamino, hexylamino, heptylamino, actylamino, dimethylamino (NMe₂), diethylamino (NEt₂), dipropylamino, dibutylamino, n-dodecylamino, n-hexadecylamino, n-octadecylamino, or n-eicosylamino.

Specially, the amide with the 1-20 carbon atoms is a monovalent group with 1-20 carbon atoms and containing

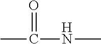

of an amide bond. The amide with the 1-20 carbon atoms is at least one of

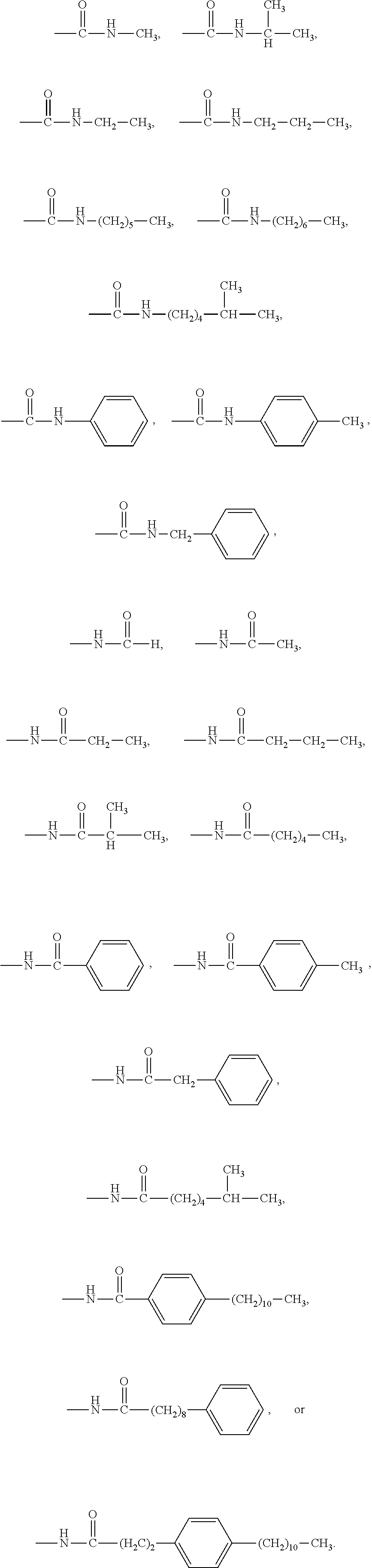

Specially, the amide substituted with 2-20 carbon atoms is a substitution base that hydrogen connected to N in an amide bond

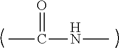

of the amide substituted with 2-20 carbon atoms is substituted by an alkyl with 1-20 carbon atoms, preferably 1-17 carbon atoms, more preferably 1-8 carbon atoms.

Specially, the amide substituted with 2-20 carbon atoms is at least one of

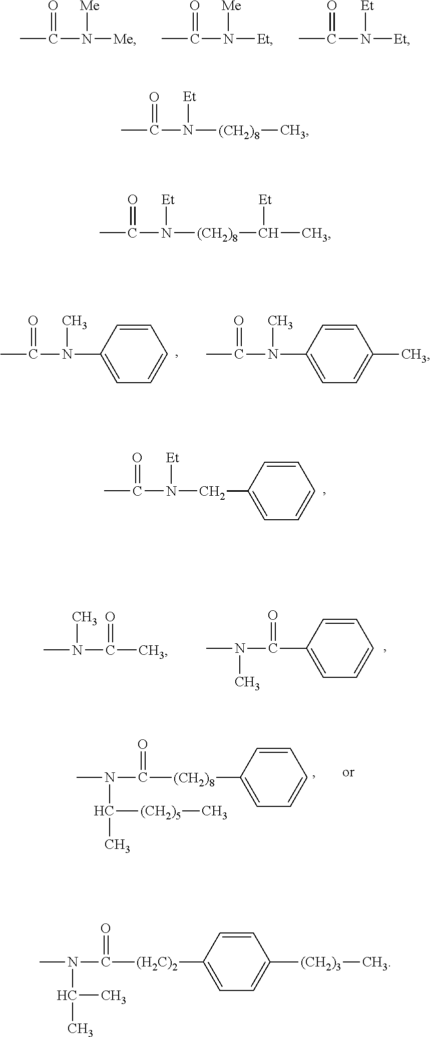

Specially, the cycloalkyl substituted with 3-20 carbon atoms is at least one of cyclopropyl, cyclobutyl, cyclopentyl, cyclohexyl, cycloheptyl, cyclooctyl, cyclododecyl, cyclohexadecyl, cyclooctadecyl, or cycloeicosyl.

Specially, the alkenyl with 2-20 carbon atoms is at least one of

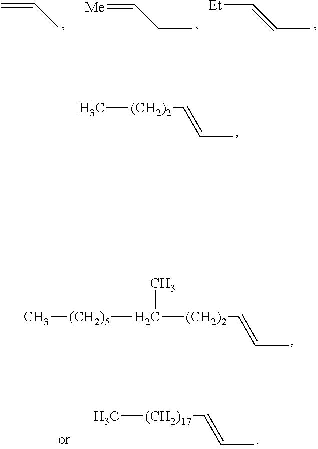

Specially, the alkynyl with 2-20 carbon atoms is at least one of

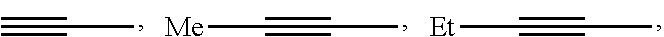

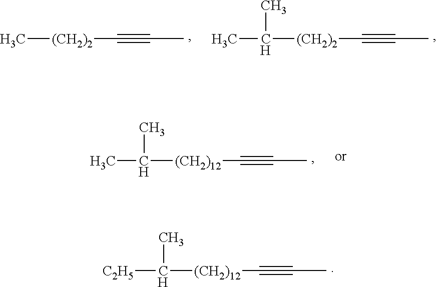

Specially, the substitution base that can improve the water solubility is at least one of a residue of polyethylene glycol, a residue of hyaluronic acid, polyacrylic acid, or a residue of a sugar derivative. The residue of the polyethylene glycol is a remaining part after an H is removed from a hydroxyl group on one end of the polyethylene glycol. A weight-average molecular weight of the polyethylene glycol is 200-200,000. The residue of the hyaluronic acid is a remaining part after an H is removed from a hydroxyl group on D-glucuronic acid or N-acetylglucosamine of the hyaluronic acid or a remaining part after a hydroxyl group (—OH) is removed from a carboxyl of D-glucuronic acid of the hyaluronic acid. A weight-average molecular weight of the hyaluronic acid is 2000-2000000. The residue of sugar derivative is a remaining part after an H is removed from any hydroxyl group of the sugar derivative. The sugar derivative is a derivative of glucose, sucrose, maltose, galactose, lactose, fructose, or sialic acid. The sugar derivative is glucuronic acid, glucose acetal, glucose hemiacetal, or carboxymethyl lactose.

In a preferred embodiment of the present disclosure, the A in the [Os] is at least one of H, F, Cl, Br, or SCN. The L in the [Os] is at least one of a CO ligand, a triphenylphosphine ligand, a trimethylphosphine ligand, or a triethylphosphine ligand.

The conjugated linking group R1 is at least one of

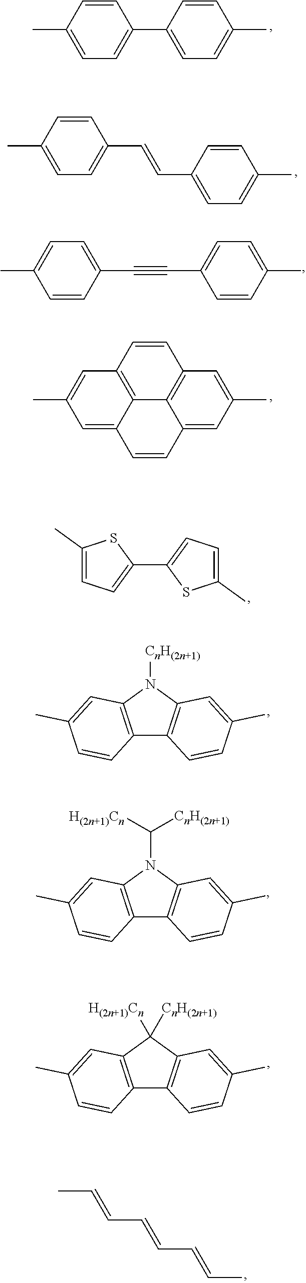

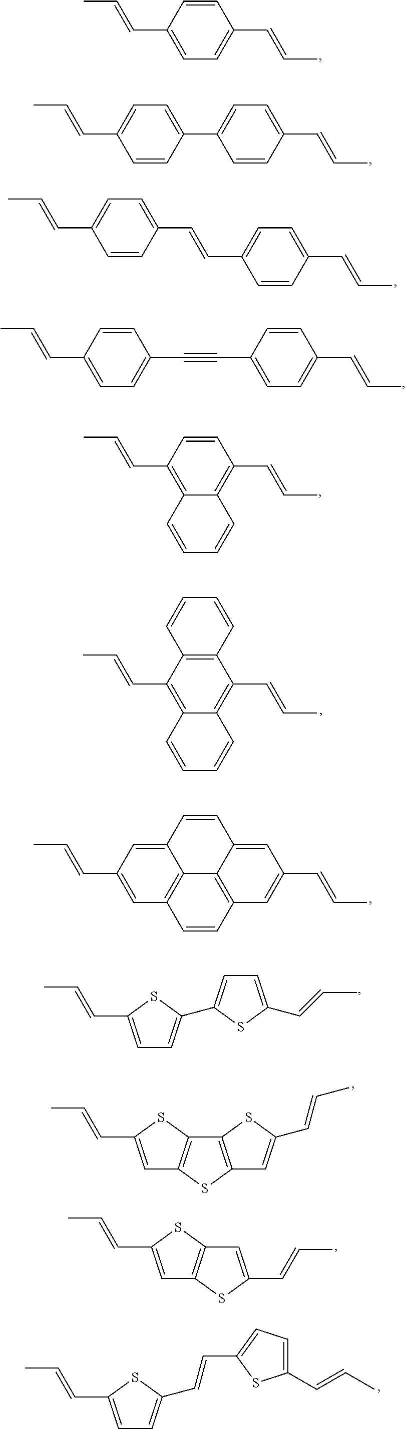

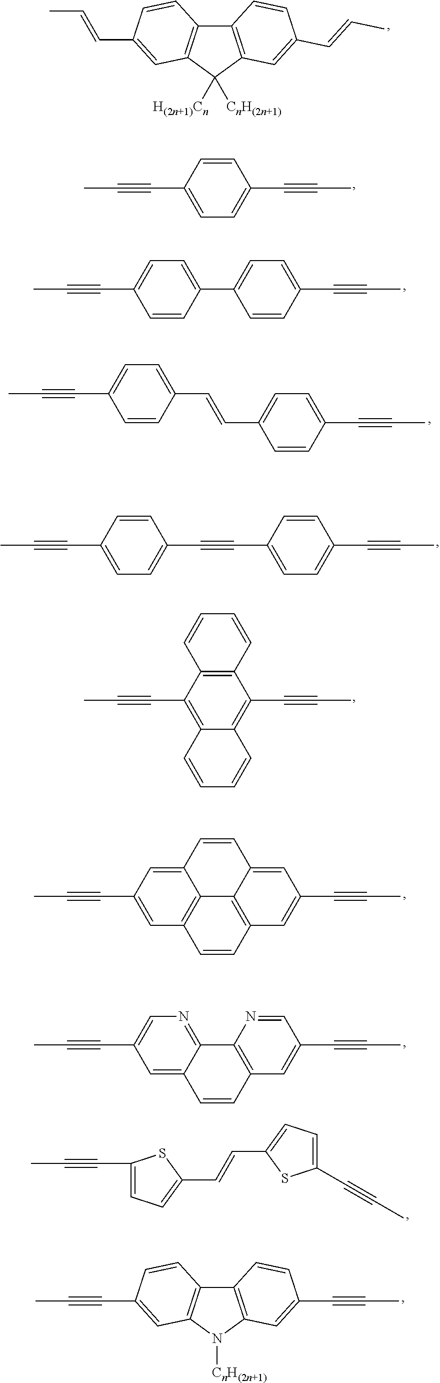

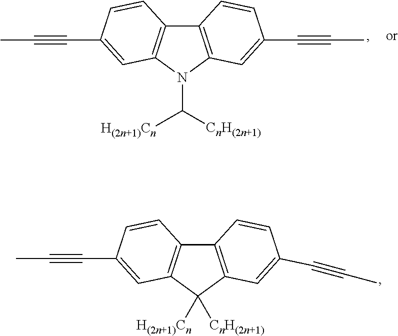

wherein n is an integer between 0 and 30.

The conjugated linking group R2 is at least one of

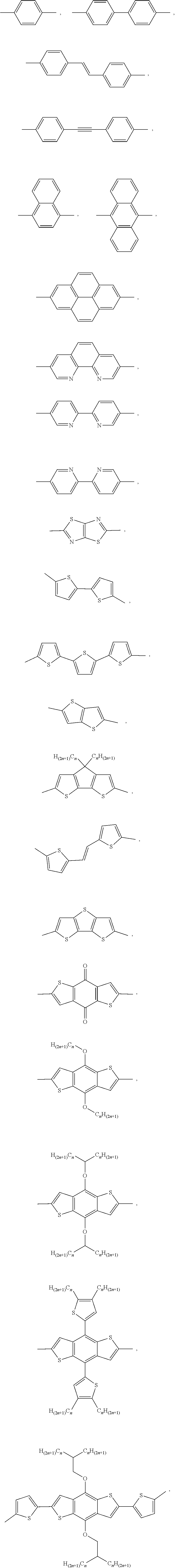

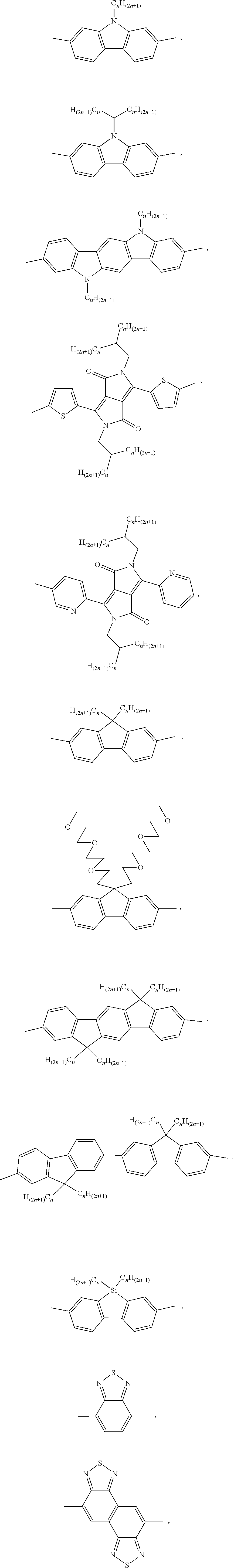

[chemical structure]

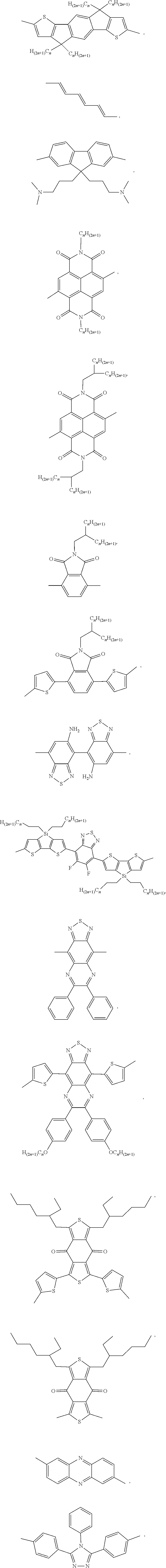

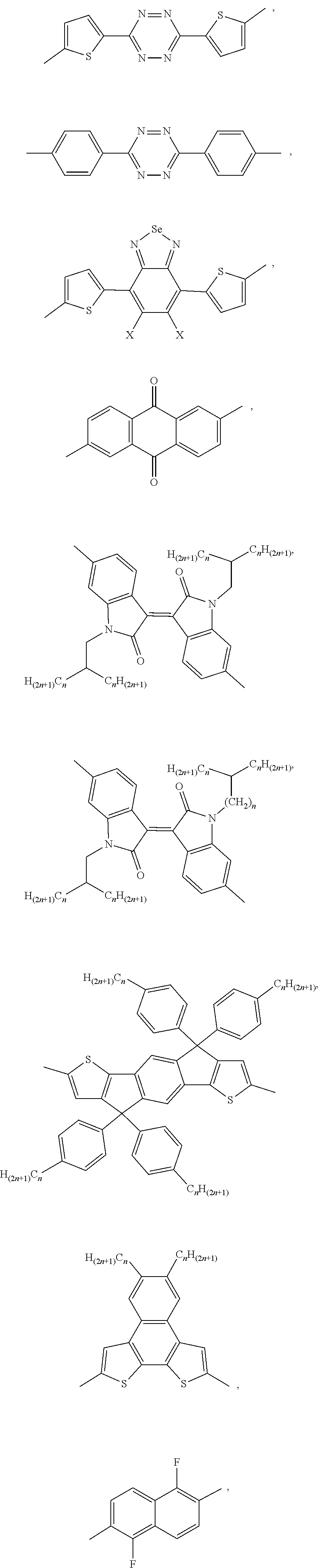

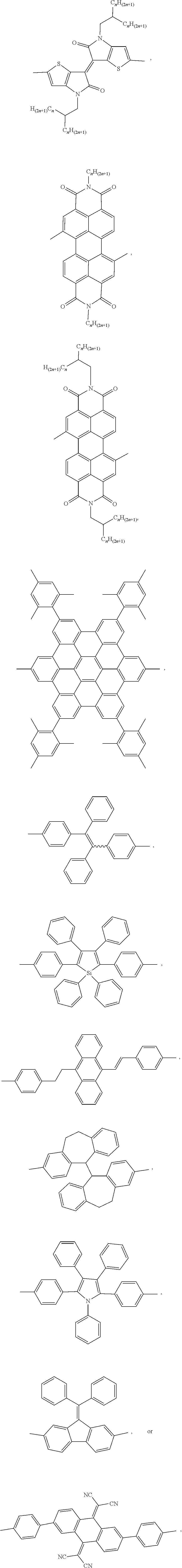

n is an integer between 0 and 30, and X is at least one of hydrogen, fluorine, amino, nitro, or alkoxy with 1-32 carbon atoms.

In a preferred embodiment of the present disclosure, the main chain comprising the osmapentalyne-containing conjugated polymer is at least one of:

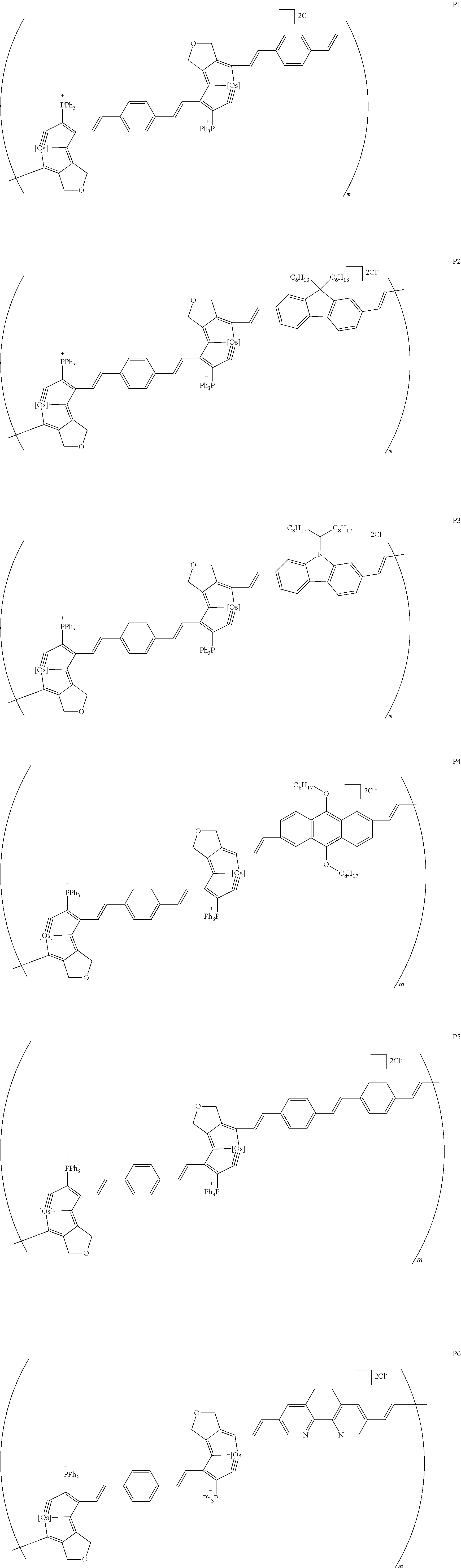

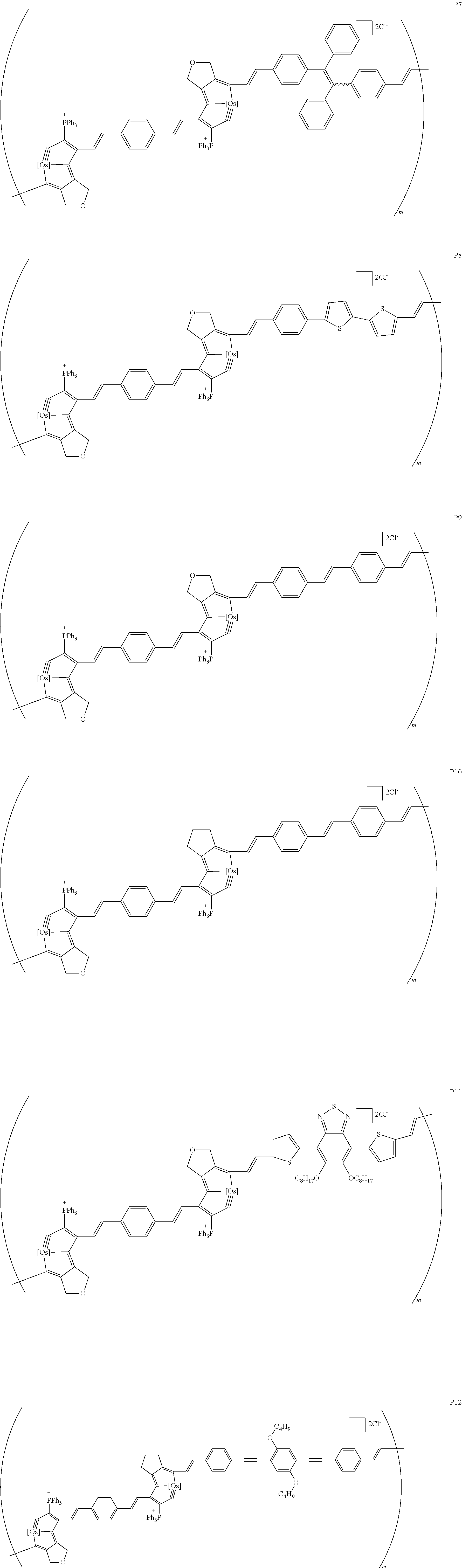

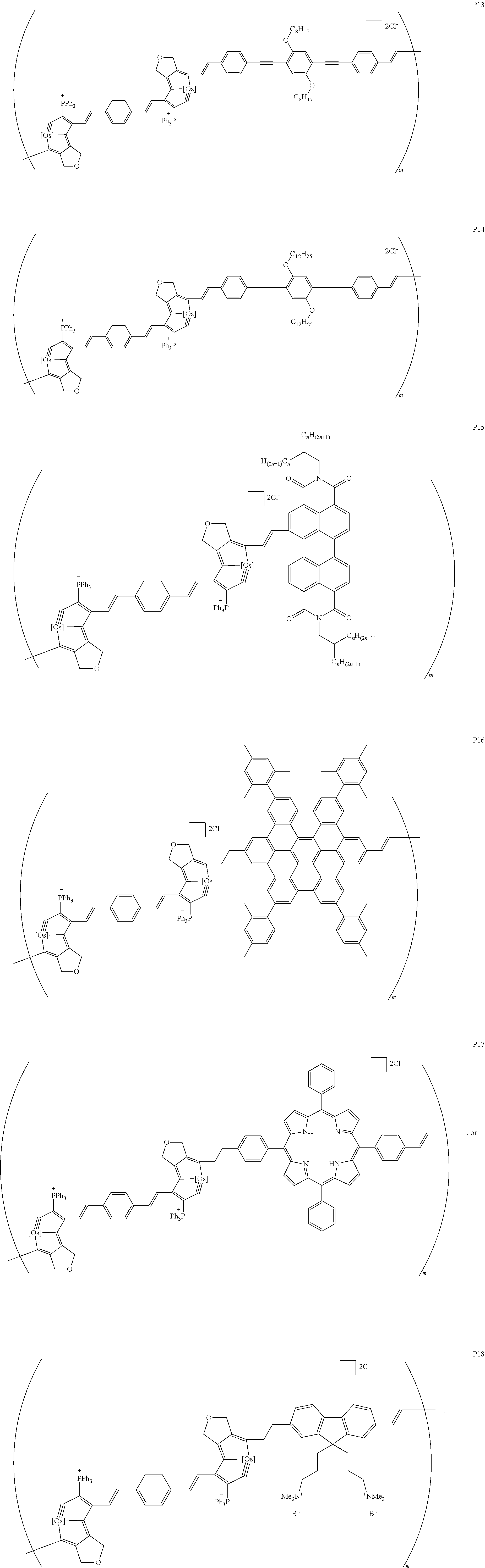

the [Os] is OsCl(PPh₃)₂, n is an integer between 0 and 30, preferably an integer between 0 and 20, more preferably an integer between 0 and 12, and m is an integer between 3 and 300, preferably an integer between 3 and 200, more preferably an integer between 3 and 100.

A method for preparing the main chain comprising the osmapentalyne-containing conjugated polymer comprises: bimetallic heterocyclic osmium heteropentylene and diacetylene monomers are dissolved in an organic solvent, and the polymerization reaction occurs under acidic conditions to obtain the main chain comprising an osmapentalyne-containing conjugated polymer, wherein the reaction formula is as follows.

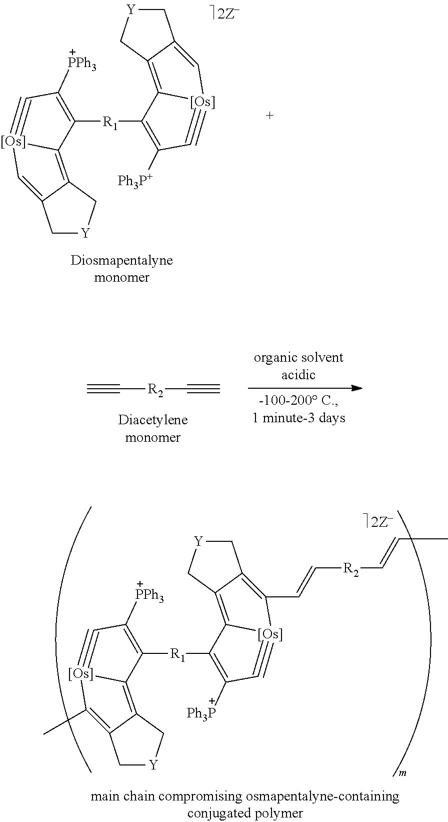

In a preferred embodiment, an acid used in the acidic conditions comprises at least one of an inorganic acid or an organic acid.

Further, the inorganic acid comprises at least one of HClO₄, HI, HBr, HCl, HNO₃, H₂SeO₄, H₂SO₄, HClO₃, H₂C₂O₄, H₂SO₃, H₃PO₄, HNO₂, HF, H₂CO₃, H₂S, HClO, H₃BO₃, or H₂SiO₃.

Further, the organic acid comprises at least one of CH₃SO₃H, CF₃COOH, CCl₃COOH, CHCl₂COOH, CH₃COOH, or HCOOH.

A reaction time is preferably 0.5 hours-1 day.

In a preferred embodiment of the present disclosure, the organic solvent comprises at least one of dichloromethane, 1,2-dichloroethane, chloroform, methanol, ethanol, acetone, butanone, tetrahydrofuran, dimethyl sulfoxide, N, N-dimethylformamide, dioxane, or acetonitrile, preferably dichloromethane.

A method for applying the main chain comprising the osmapentalyne-containing conjugated polymer comprises using the osmapentalyne-containing conjugated polymer in preparing organic optoelectronic members, wherein the organic optoelectronic members specially comprises solar energy cells, light-emitting diodes, field-effect transistors, chemical sensors, photothermal therapy, or chemical switches.

Preferably, in the main chain comprising the osmapentalyne-containing conjugated polymer, [Os] is OsCl(PPh₃)₂, X is CH₂ or O, the conjugated linking group R1 is divinyl styryl, and the conjugated linking group R2 is fluorenyl substituted with alkyl, preferably fluorenyl substituted with alkyl with 1-28 carbon atoms. The main chain comprising the osmapentalyne-containing conjugated polymer is specially applicable for the solar energy cells. Further, the main chain comprising the osmapentalyne-containing conjugated polymer is used to be a material of an active layer of the solar energy cells.

Preferably, in the main chain comprising the osmapentalyne-containing conjugated polymer, [Os] is OsCl(PPh₃)₂, X is CH₂ or O, the conjugated linking group R1 is divinyl styryl, and the conjugated linking group R2 is a substituted oligostyryl, preferably tetrastyryl substituted with alkyl with 1-28 carbon atoms. The main chain comprising the osmapentalyne-containing conjugated polymer is specially applicable for the light-emitting diodes. Further, the main chain comprising the osmapentalyne-containing conjugated polymer is used to be a material of a light-emitting layer of the light-emitting diodes.

Preferably, in the main chain comprising the osmapentalyne-containing conjugated polymer, [Os] is OsCl(PPh₃)₂, X is CH₂ or O, the conjugated linking group R1 is divinyl styryl, and the conjugated linking group R2 is a substituted oligothienyl, preferably a dithienyl substituted with alkyl-with 1-28 carbon atoms. The main chain comprising the osmapentalyne-containing conjugated polymer is specially applicable for the photothermal therapy. Further, the main chain comprising the osmapentalyne-containing conjugated polymer is used to be a photothermal material for 808 nm laser.

The present disclosure has the following advantages.

1. The osmium-containing conjugated polymer of the present disclosure is a new conjugated polymer with a main chain containing metal. The osmium-containing conjugated polymer has good stability, solubility, and processability. A structure of the osmium-containing conjugated polymer is infinitely variable to provide a rich basis for performance research due to various conjugated groups of the osmium-containing conjugated polymer. At the same time, the osmium-containing conjugated polymer is a new π-conjugated polymer system containing d_{π}-p_{π} conjugations to exhibit a high molar light absorption coefficient and good electrochemical performance. The osmium-containing conjugated polymer can be widely used in solar energy cells, light-emitting diodes, field-effect transistors, chemical sensors, chemical switches, and other fields.

2. The polymerization method of the present disclosure has the following advantages: simple synthesis operation, high efficiency, specificity, mild conditions, high tolerance of functional groups, and 100% atom conversion efficiency. A yield of the osmium-containing conjugated polymer prepared by the method is high, up to 99%, a Mw molecular weight is high, and a molecular weight distribution is extremely narrow.

3. The main chain comprising the osmapentalyne-containing conjugated polymer of the present disclosure has good stability, solubility, and processability. A structure of the main chain comprising the osmapentalyne-containing conjugated polymer is endlessly various by polymerizing diosmpentalyne with different conjugated groups and diacetylene to provide a rich material basis for performance research.

4. The main chain comprising the osmapentalyne-containing conjugated polymer of the present disclosure is a new π-conjugated polymer system containing d_{π}-p_{π} conjugations to exhibit a high molar light absorption coefficient and good electrochemical performance. The main chain comprising the osmapentalyne-containing conjugated polymer can be widely used in solar energy cells, light-emitting diodes, field-effect transistors, chemical sensors, chemical switches, and other fields.

The method for preparing the main chain comprising the osmapentalyne-containing conjugated polymer of the present disclosure has the following advantages: simple synthesis operation, high efficiency, specificity, mild conditions, and high tolerance of functional groups.

### BRIEF DESCRIPTION OF THE DRAWINGS

FIG. 1 illustrates a gel permeation chromatography (GPC) molecular weight distribution chart of an osmium-containing conjugated polymer I-1 of Embodiment 1 of the present disclosure.

FIG. 2 illustrates ultraviolet-visible absorption spectra of the osmium-containing conjugated polymer I-1 and an osmium-containing conjugated polymer I-383 of Embodiment 1 and Embodiment 3 of the present disclosure.

FIG. 3 illustrates a GPC molecular weight distribution chart (polystyrene is used as a standard sample, a test is performed in a pure N,N-dimethylformamide (DMF) mobile phase) of a main chain comprising an osmapentalyne-containing conjugated polymer P2 of Embodiment 12 of the present disclosure.

FIG. 4 illustrates ultraviolet-visible absorption spectra of a main chain comprising an osmapentalyne-containing conjugated polymer P8 and a main chain comprising an osmapentalyne-containing conjugated polymer P9 of Embodiment 18 and Embodiment 19 of the present disclosure.

FIG. 5 illustrates a cyclic voltammetry (CV) curve of a main chain comprising an osmapentalyne-containing conjugated polymer P14 of Embodiment 24 of the present disclosure.

### DETAILED DESCRIPTION OF THE EMBODIMENTS

The present disclosure will be further described below through embodiments.

A formula M of osmapentalyne monomer used in the following embodiments is prepared in accordance with methods disclosed in a literature Zhuo, Q.; Lin, J.; Hua, Y.; Zhou, X.; Shao, Y.; Chen, S.; Chen, Z.; Zhu, J.; Zhang, H.; Xia, H.* Multiyne Chains Chelating Osmium via Three Metalcarbon σ Bonds. Nat. Commun. 2017, 8, 1912. and Wu, F.; Huang, W.; Zhuo, K.; Hua, Y.; Lin, J.; He, G.;* Chen, J.; Nie, L.;* Xia, H.* Carbolong Complexes as Photothermal Materials. Chin. J. Org. Chem. 2019, 39, 1743-1752.

### Embodiment 1

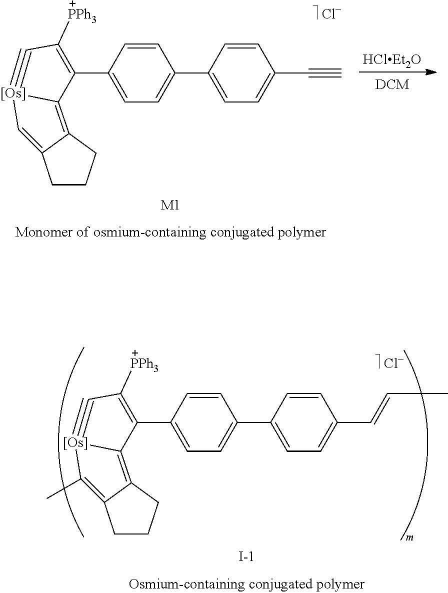

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

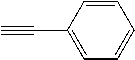

(phenylacetylene, which is purchased from Bailingwei Technology Co., Ltd., a trade name is 445058), and dichloromethane (DCM) used in the above-mentioned formula is a redistilled solvent of dichloromethane.

A method for preparing the osmium-containing conjugated polymer is as follows. An osmapentalyne monomer M1 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M1 at room temperature (e.g., 20-25° C.) for 24 hours, the phenylacetylene is added to terminate the reaction, the reaction is performed at room temperature for another 2 hours, a large amount of ethyl ether is then added, a purple-red solid compound is precipitated and filtered, and the purple-red solid compound is repeatedly washed with ethyl ether and dried to obtain 90 mg of the osmium-containing conjugated polymer in purple-red color.

A data acknowledgement of a structure of the osmium-containing conjugated polymer is as follows: ¹H NMR (600.1 MHz, CD₂Cl₂): δ=6.81-7.78 (br, 53H), 6.23 (d, J=17.71 Hz, 1H), 5.79 (br, 2H), 3.00 (br, 2H), 2.08 (br, 2H), 1.62 (br, 2H); ³¹P{¹H}-NMR (242.9 MHz, CD₂Cl₂): δ=4.57 (br, CPPh₃), −1.20 (br, OsPPh₃).

A characterization data of a molecular weight of the osmium-containing conjugated polymer is as follows: a weight average molecular weight is 48227 Da, a number average molecular weight is 36989 Da, and a molecular weight distribution index of the osmium-containing conjugated polymer is 1.30.

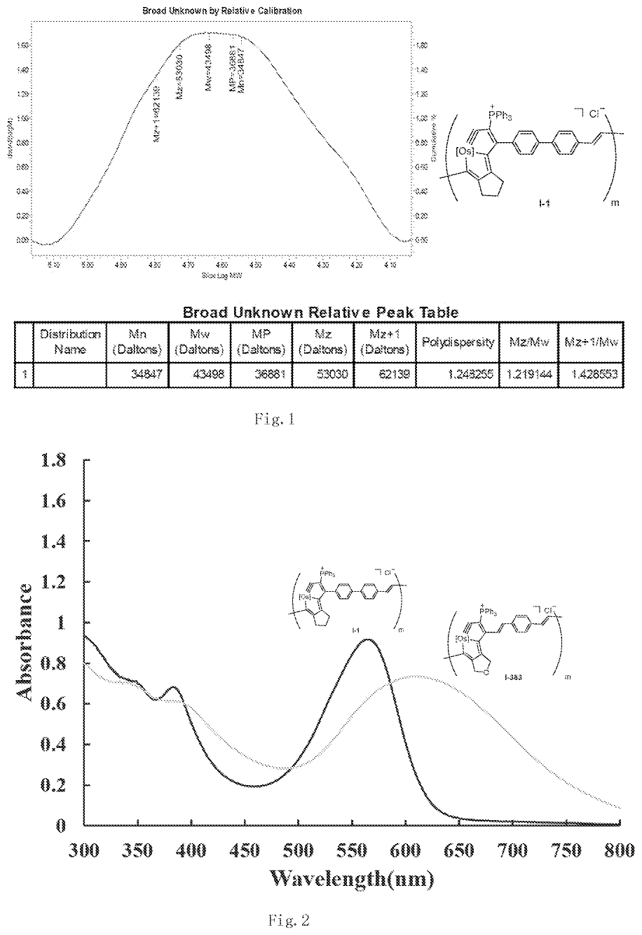

In this embodiment, a gel permeation chromatography (GPC) molecular weight distribution chart of an osmium-containing conjugated polymer I-1 is illustrated in FIG. 1.

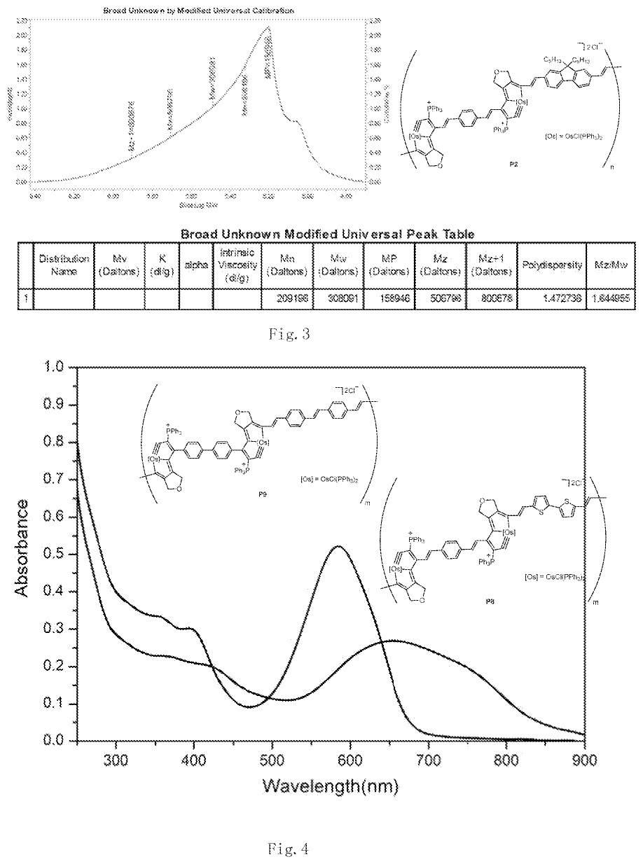

In this embodiment, an ultraviolet-visible absorption spectrum of the osmium-containing conjugated polymer I-1 is illustrated in FIG. 2.

### Embodiment 2

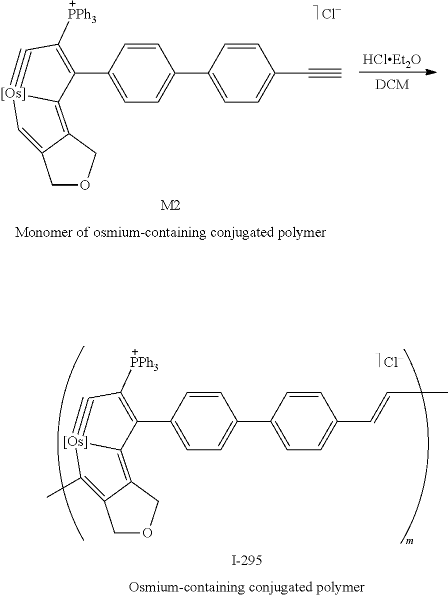

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

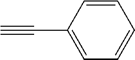

(phenylacetylene, which is purchased from Bailingwei Technology Co., Ltd., a trade name is 445058), and DCM used in the above-mentioned formula is a redistilled solvent of dichloromethane.

A method for preparing the osmium-containing conjugated polymer is as follows. An osmapentalyne monomer M2 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M2 at room temperature (e.g., 20-25° C.) for 24 hours, the phenylacetylene is added to terminate the reaction, the reaction is performed at room temperature for another 2 hours, a large amount of ethyl ether is then added, a purple solid compound is precipitated and filtered, and the purple solid compound is repeatedly washed with ethyl ether and dried to obtain 92 mg of the osmium-containing conjugated polymer in purple-red color.

A data acknowledgement of a structure of the osmium-containing conjugated polymer is as follows: ¹H NMR (600.1 MHz, CD₂Cl₂): δ=6.81-7.98 (br, 53H), 6.23 (d, J=17.71 Hz, 1H), 5.82 (br, 2H), 5.17 (br, 2H), 4.30 (br, 2H); ³¹P{¹H}-NMR (242.9 MHz, CD₂Cl₂): δ=4.57 (br, CPPh₃), −0.08 (br, OsPPh₃).

A characterization data of a molecular weight of the osmium-containing conjugated polymer is as follows: a weight average molecular weight is 60383 Da, a number average molecular weight is 43130 Da, and a molecular weight distribution index of the osmium-containing conjugated polymer is 1.40.

### Embodiment 3

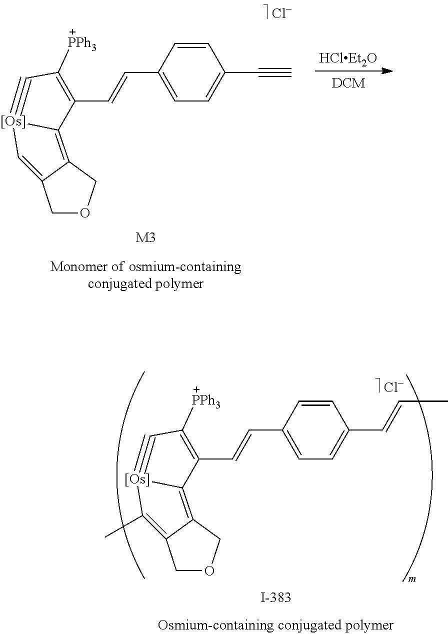

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

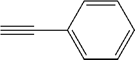

(phenylacetylene, which is purchased from Bailingwei Technology Co., Ltd., a trade name is 445058), and DCM used in the above-mentioned formula is a redistilled solvent of dichloromethane.

A method for preparing the osmium-containing conjugated polymer is as follows. An osmapentalyne monomer M3 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M3 at room temperature (e.g., 20-25° C.) for 24 hours, the phenylacetylene is added to terminate the reaction, the reaction is performed at room temperature for another 2 hours, a large amount of ethyl ether is then added, a blue solid compound is precipitated and filtered, and the blue solid compound is repeatedly washed with ethyl ether and dried to obtain 95 mg of the osmium-containing conjugated polymer.

A data acknowledgement of a structure of the osmium-containing conjugated polymer is as follows: ¹H NMR (600.1 MHz, CD₂Cl₂): δ=6.83-7.85 (br, 46H), 5.97 (d, J=16.38 Hz, 1H), 5.82 (br, 1H), 5.17 (br, 2H), 4.30 (br, 2H); ³¹P{¹H}-NMR (242.9 MHz, CD₂Cl₂): δ=4.81 (br, CPPh₃), −0.08 (br, OsPPh₃).

A characterization data of a molecular weight is as follows: a weight average molecular weight is 52927 Da, a number average molecular weight is 39205 Da, and a molecular weight distribution index of the osmium-containing conjugated polymer is 1.35.

In this embodiment, an ultraviolet-visible absorption spectrum of the osmium-containing conjugated polymer I-383 is illustrated in FIG. 2.

### Embodiment 4

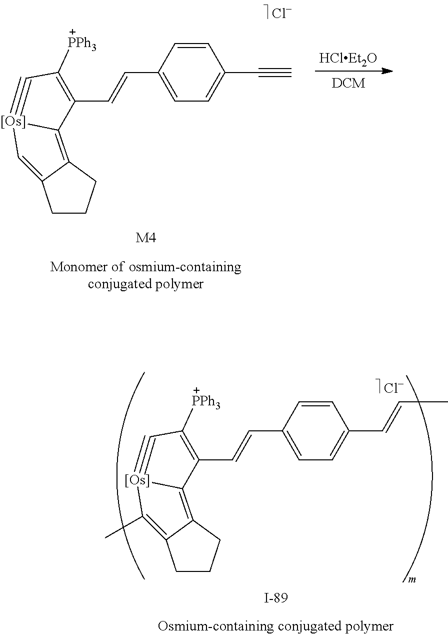

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

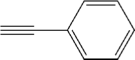

(phenylacetylene, which is purchased from Bailingwei Technology Co., Ltd., a trade name is 445058), and DCM used in the above-mentioned formula is a redistilled solvent of dichloromethane.

A method for preparing the osmium-containing conjugated polymer is as follows. An osmapentalyne monomer M4 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M4 at room temperature (e.g., 20-25° C.) for 24 hours, the phenylacetylene is added to terminate the reaction, the reaction is performed at room temperature for another 2 hours, a large amount of ethyl ether is then added, a blue-purple solid compound is precipitated and filtered, and the blue-purple solid compound is repeatedly washed with ethyl ether and dried to obtain 95 mg of the osmium-containing conjugated polymer.

A data acknowledgement of a structure of the osmium-containing conjugated polymer is as follows: ¹H NMR (600.1 MHz, CD₂Cl₂): δ=6.83-7.85 (br, 46H), 5.97 (d, J=17.38 Hz, 1H), 5.82 (br, 2H), 3.01 (br, 2H), 2.07 (br, 2H), 1.65 (br, 2H); ³¹P{¹H}-NMR (242.9 MHz, CD₂Cl₂): δ=4.71 (br, CPPh₃), −0.12 (br, OsPPh₃).

A characterization data of a molecular weight of the osmium-containing conjugated polymer is as follows: a weight average molecular weight is 58220 Da, a number average molecular weight is 41005 Da, and a molecular weight distribution index of the osmium-containing conjugated polymer is 1.41.

### Embodiment 5

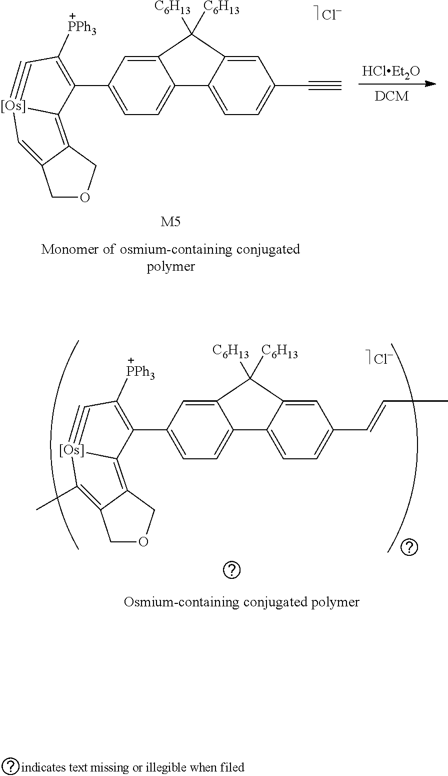

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

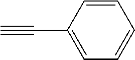

(phenylacetylene, which is purchased from Bailingwei Technology Co., Ltd., a trade name is 445058), and DCM used in the above-mentioned formula is a redistilled solvent of dichloromethane.

A method for preparing the osmium-containing conjugated polymer is as follows. An osmapentalyne monomer M5 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M5 at room temperature (e.g., 20-25° C.) for 24 hours, the phenylacetylene is added to terminate the reaction, the reaction is performed at room temperature for another 2 hours, a large amount of ethyl ether is then added, a purple-black solid compound is precipitated and filtered, and the purple-black solid compound is repeatedly washed with ethyl ether and dried to obtain 93 mg of the osmium-containing conjugated polymer.

A data acknowledgement of a structure of the osmium-containing conjugated polymer is as follows: ¹H NMR (600.1 MHz, CD₂Cl₂): δ=6.93-8.31 (br, 52H), 5.84 (d, J=16.54 Hz, 1H), 5.17 (br, 2H), 3.73 (br, 2H), 0.70-1.40 (br, 26H); ³¹P{¹H}-NMR (242.9 MHz, CD₂Cl₂): δ=4.49 (br, CPPh₃), −1.58 (br, OsPPh₃).

A characterization data of a molecular weight of the osmium-containing conjugated polymer is as follows: a weight average molecular weight is 34642 Da, a number average molecular weight is 29357 Da, and a molecular weight distribution index of the osmium-containing conjugated polymer is 1.18.

### Embodiment 6

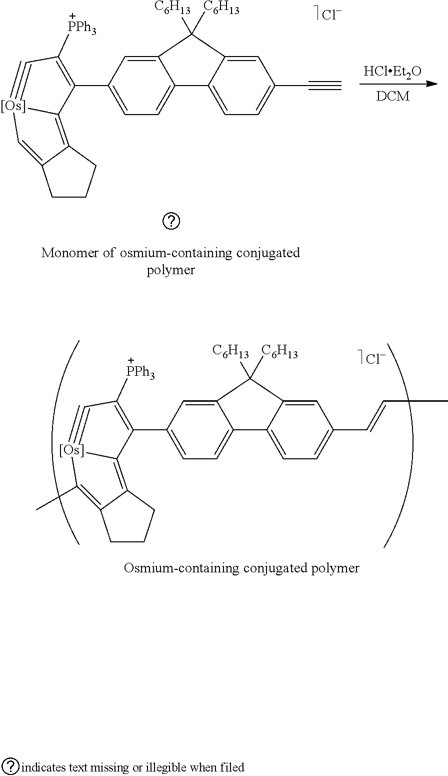

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

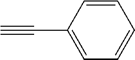

(phenylacetylene, which is purchased from Bailingwei Technology Co., Ltd., a trade name is 445058), and DCM used in the above-mentioned formula is a redistilled solvent of dichloromethane.

A method for preparing the osmium-containing conjugated polymer is as follows. An osmapentalyne monomer M6 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M6 at room temperature (e.g., 20-25° C.) for 24 hours, the phenylacetylene is added to terminate the reaction, the reaction is performed at room temperature for another 2 hours, a large amount of ethyl ether is then added, a purple-black solid compound is precipitated and filtered, and the purple-black solid compound is repeatedly washed with ethyl ether and dried to obtain 92 mg of the osmium-containing conjugated polymer.

A data acknowledgement of a structure of the osmium-containing conjugated polymer is as follows: ¹H NMR (600.1 MHz, CD₂Cl₂): δ=6.48-8.31 (br, 52H), 6.25 (br, 1H), 3.11 (br, 2H), 2.37 (br, 2H), 1.24 (br, 2H), 0.72-1.40 (br, 26H); ³¹P{¹H}-NMR (242.9 MHz, CD₂Cl₂): δ=4.13 (br, CPPh₃), −1.18 (br, OsPPh₃).

A characterization data of a molecular weight of the osmium-containing conjugated polymer is as follows: a weight average molecular weight is 45633 Da, a number average molecular weight is 35931 Da, and a molecular weight distribution index of the osmium-containing conjugated polymer is 1.27.

### Embodiment 7

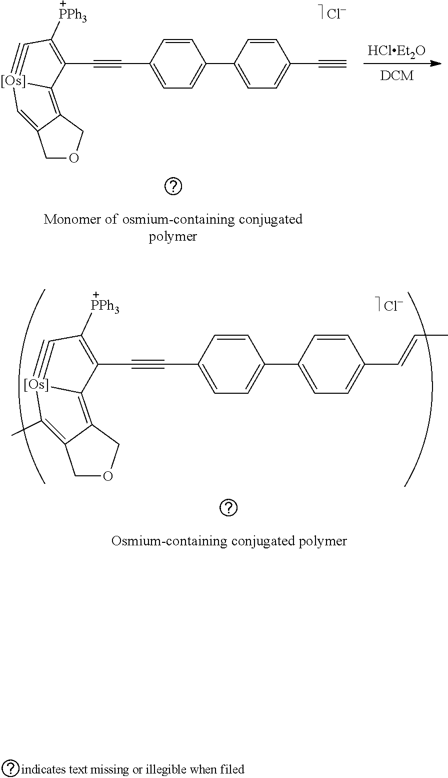

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

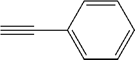

(phenylacetylene, which is purchased from Bailingwei Technology Co., Ltd., a trade name is 445058), and DCM used in the above-mentioned formula is a redistilled solvent of dichloromethane.

A method for preparing the osmium-containing conjugated polymer is as follows. An osmapentalyne monomer M7 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M7 at room temperature (e.g., 20-25° C.) for 24 hours, the phenylacetylene is added to terminate the reaction, the reaction is performed at room temperature for another 2 hours, a large amount of ethyl ether is then added, a blue-green solid compound is precipitated and filtered, and the blue-green solid compound is repeatedly washed with ethyl ether and dried to obtain 89 mg of the osmium-containing conjugated polymer.

A data acknowledgement of a structure of the osmium-containing conjugated polymer is as follows: ¹H NMR (600.1 MHz, CD₂Cl₂): δ=6.98-7.87 (br, 46H), 6.08 (br, 1H), 5.19 (br, 2H), 4.39 (br, 2H); ³¹P{¹H}-NMR (242.9 MHz, CD₂Cl₂): δ=5.36 (s, CPPh₃), 0.07 (s, OsPPh₃).

A characterization data of a molecular weight of the osmium-containing conjugated polymer is as follows: a weight average molecular weight is 42622 Da, a number average molecular weight is 34761 Da, and a molecular weight distribution index of the osmium-containing conjugated polymer is 1.23.

### Embodiment 8

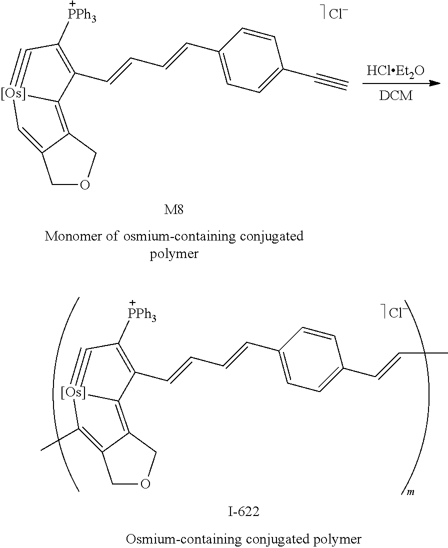

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

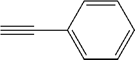

(phenylacetylene, which is purchased from Bailingwei Technology Co., Ltd., a trade name is 445058), and DCM used in the above-mentioned formula is a redistilled solvent of dichloromethane.

A method for preparing the osmium-containing conjugated polymer is as follows. An osmapentalyne monomer M8 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M8 at room temperature (e.g., 20-25° C.) for 24 hours, the phenylacetylene is added to terminate the reaction, the reaction is performed at room temperature for another 2 hours, a large amount of ethyl ether is then added, a blue solid compound is precipitated and filtered, and the blue solid compound is repeatedly washed with ethyl ether and dried to obtain 91 mg of the osmium-containing conjugated polymer.

A data acknowledgement of a structure of the osmium-containing conjugated polymer is as follows: ¹H NMR (600.1 MHz, CD₂Cl₂): δ=6.98-7.83 (br, 49H), 6.08 (br, 1H), 6.50 (q, 1H), 6.24 (d, 1H), 5.71 (q, 1H), 5.54 (d, 1H), 4.66 (br, 2H), 3.87 (br, 2H); ³¹P{¹H}-NMR (242.9 MHz, CD₂Cl₂): δ=5.14 (s, CPPh₃), −0.23 (s, OsPPh₃).

A characterization data of a molecular weight of the osmium-containing conjugated polymer is as follows: a weight average molecular weight is 53567 Da, a number average molecular weight is 40023 Da, and a molecular weight distribution index of the osmium-containing conjugated polymer is 1.34.

### Embodiment 9

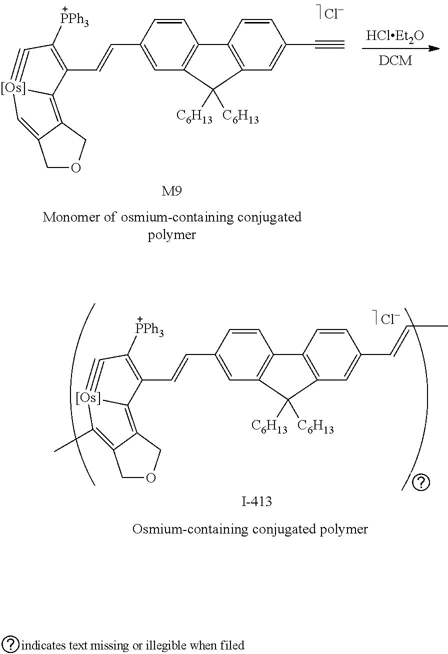

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000),

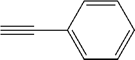

(phenylacetylene, which is purchased from Bailingwei Technology Co., Ltd., a trade name is 445058), and DCM used in the above-mentioned formula is a redistilled solvent of dichloromethane.

A method for preparing the osmium-containing conjugated polymer is as follows. An osmapentalyne monomer M9 (0.1 mmol) is dissolved in 5 mL of the redistilled solvent of the dichloromethane by a magnetic stirrer under a nitrogen atmosphere, and 0.5 mL of 2 mol/L of the hydrochloric acid in the ethyl ether is quickly added and is reacted with the osmapentalyne monomer M9 at room temperature (e.g., 20-25° C.) for 24 hours, the phenylacetylene is added to terminate the reaction, the reaction is performed at room temperature for another 2 hours, a large amount of ethyl ether is then added, a blue solid compound is precipitated and filtered, and the blue solid compound is repeatedly washed with ethyl ether and dried to obtain 93 mg of the osmium-containing conjugated polymer.

A data acknowledgement of a structure of the osmium-containing conjugated polymer is as follows: ¹H NMR (600.1 MHz, CD₂Cl₂): δ=6.48-8.31 (br, 52H), 6.25 (br, 2H), 5.97 (d, J=18.18 Hz, 1H), 3.12 (br, 2H), 2.36 (br, 2H), 1.22 (br, 2H), 0.72-1.40 (br, 26H); ³¹P{¹H}-NMR (242.9 MHz, CD₂Cl₂): δ=4.98 (br, CPPh₃), −1.12 (br, OsPPh₃).

A characterization data of a molecular weight of the osmium-containing conjugated polymer is as follows: a weight average molecular weight is 38978 Da, a number average molecular weight is 29986 Da, and a molecular weight distribution index of the osmium-containing conjugated polymer is 1.30.

A summary table of energy level information of all osmium-containing conjugated polymers in the above-mentioned embodiments is shown in Table 1.

TABLE 1
The summary table of the energy level information of osmium-
containing conjugated polymers of the present disclosure

| | EOX | EHOMO | ERED | ELUMO |
|---|---|---|---|---|
| Samples | [V] | [eV] | [V] | [eV] |
| 1-1 | 0.94 | −5.34 | −0.68 | −3.72 |
| 1-319 | 1.00 | −5.40 | −0.65 | −3.75 |
| 1-490 | 0.98 | −5.38 | −0.67 | −3.73 |
| 1-383 | 1.10 | −5.50 | −0.54 | −3.86 |
| PC70BM | 1.54 | −5.94 | −0.51 | −3.89 |

### Embodiment 10

In the following examples, methods for preparing diosmapentalyne monomers M100-M300 are as follows, wherein polyacetylene carbon chains L1-L3 used as raw materials can be prepared in accordance with similar methods disclosed in Nat. Commun. 2017, 8, 1912. and Nat. Commun. 2020, 11, 4651.

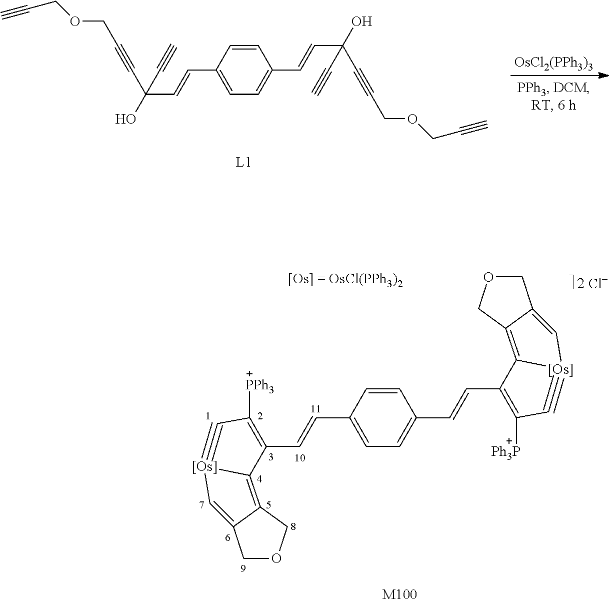

A method for preparing a diosmapentalyne monomer M100 is as follows: a polyacetylene carbon chain L1 (1.50 g, 3.55 mmol), triphenylphosphine (9.32 g, 35.5 mmol), and a tris(triphenylphosphine) osmium dichloride complex OsCl₂(PPh₃)₃ (11.18 g, 10.65 mmol) are dissolved in 80 mL of dichloromethane under a nitrogen atmosphere by a magnetic stirrer and reacted at room temperature (e.g., 20-25° C.) for 6 hours, a reaction solution is then concentrated to 15 mL and is added with 200 mL of ethyl ether, a solid product is precipitated and filtered, and the solid product is then washed with ethyl ether (e.g., 3×150 mL) several times. The solid product is further separated and purified through a silica gel column (a washing solution of dichloromethane and methanol with a volume ratio of 10:1 is used) to obtain 5.73 g of a tan solid product with a yield of 65%. A data acknowledgement of a structure of the diosmapentalyne monomer M100 is as follows: ¹H NMR plus ¹H-¹³C HSQC (600.1 MHz, CD₂Cl₂): δ=13.09 (s, 2H, C⁷H), 7.95-6.92 (94H, other aromatic protons), 5.95-5.79 (dd, J=16.55 Hz, J=78.83 Hz, 4H, C¹¹H and C¹⁰H), 4.67 (s, 4H, C⁹H), 3.85 ppm (s, 4H, C⁸H). ³¹P NMR (242.9 MHz, CD₂Cl₂): δ=6.11 (t, J_{P—P}=5.86 Hz, CPPh₃), 2.68 ppm (d, J_{P—P}=5.86 Hz, OsPPh₃). ¹³C NMR plus DEPT-135, ¹H-¹³C HSQC and ¹H-¹³C HMBC (150.9 MHz, CD₂Cl₂): δ=318.1 (dt, apparent q, J_{P—C}=12.91 Hz, J_{P—C}=12.91 Hz, C¹), 210.6 (m, C⁷), 172.2 (s, C⁵), 171.5 (s, C⁶), 168.8 (d, J_{P—C}=22.27 Hz, C⁴), 161.7 (d, J_{P—C}=15.26 Hz, C³), 136.6 (s, C¹⁰), 125.3 (s, C¹¹), 73.66 (s, C⁸), 68.80 (s, C⁹), 135.7-119.4 ppm (other aromatic carbons). Elemental analysis calculated (%) for C₁₃₆H₁₀₈Cl₄O₂Os₂P₆: C, 65.80, H, 4.39; found: C, 65.67, H, 4.25. HRMS (ESI): m/z calculated for [C₁₃₆H₁₀₈Cl₂O₂Os₂P₆]²⁺, 1205.2674; found, 1205.2845.

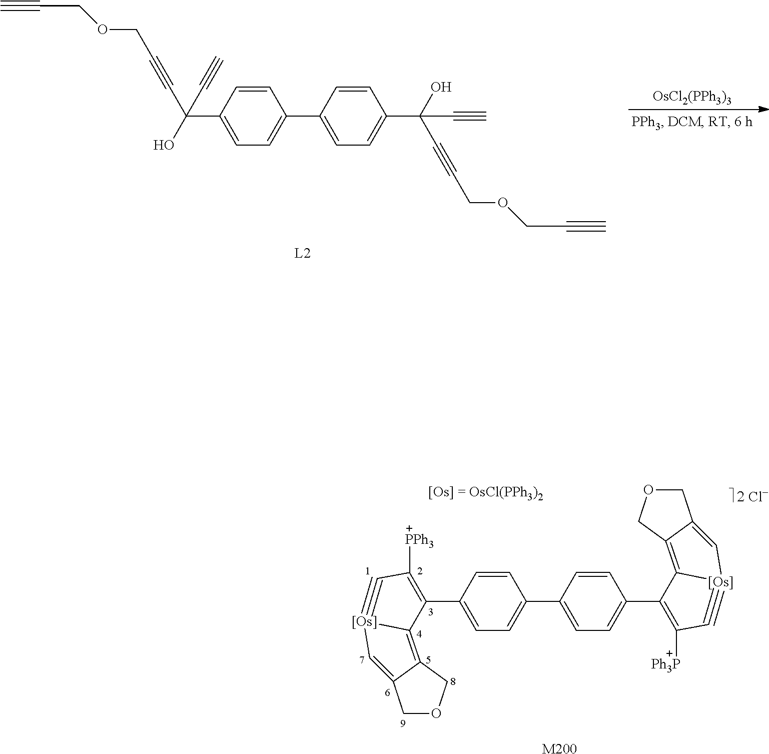

A method for preparing a diosmapentalyne monomer M200 is as follows: a polyacetylene carbon chain L2 (1.50 g, 3.36 mmol), triphenylphosphine (8.83 g, 33.6 mmol), and a tris(triphenylphosphine) osmium dichloride complex OsCl₂(PPh₃)₃ (10.58 g, 10.08 mmol) are dissolved in 120 mL of dichloromethane under a nitrogen atmosphere by a magnetic stirrer and reacted at room temperature (e.g., 20-25° C.) for 6 hours, a reaction solution is then concentrated to 15 mL and is added with 180 mL of ethyl ether, a solid product is precipitated and filtered, and the solid product is then washed with ethyl ether (e.g., 3×120 mL) several times. The solid product is further separated and purified through a silica gel column (a washing solution of dichloromethane and methanol with a volume ratio of 10:1 is used) to obtain 6.06 g of a tan solid product with a yield of 72%. A data acknowledgement of a structure of the monomer of the diosmapentalyne monomer M200 is as follows: ¹H NMR plus ¹H-¹³C HSQC (600.1 MHz, CD₂Cl₂): δ=13.11 (s, 2H, C⁷H), 7.89-6.19 (98H, other aromatic protons), 4.61 (s, 4H, C⁹H), 3.23 ppm (s, 4H, C⁸H). ³¹P NMR (242.9 MHz, CD₂Cl₂): δ=5.96 (s, CPPh₃), 3.01 ppm (s, OsPPh₃). ¹³C NMR plus DEPT-135, ¹H-¹³C HSQC and ¹H-¹³C HMBC (150.9 MHz, CD₂Cl₂): δ=317.9 (s, C¹), 210.7 (s, C⁷), 173.2 (s, C⁵), 171.9 (s, C⁶), 166.6 (s, C⁴), 164.9 (s, C³), 73.03 (s, C⁸), 68.56 (s, C⁹), 140.0-119.7 ppm (other aromatic carbons). Elemental analysis calculated (%) for C₁₃₈H₁₀₈Cl₄O₂Os₂P₆: C, 66.13, H, 4.34; found: C, 66.34, H, 4.25. HRMS (ESI): m/z calculated for [C₁₃₈H₁₀₈Cl₂O₂Os₂P₆]²⁺, 1217.2674; found, 1217.2823.

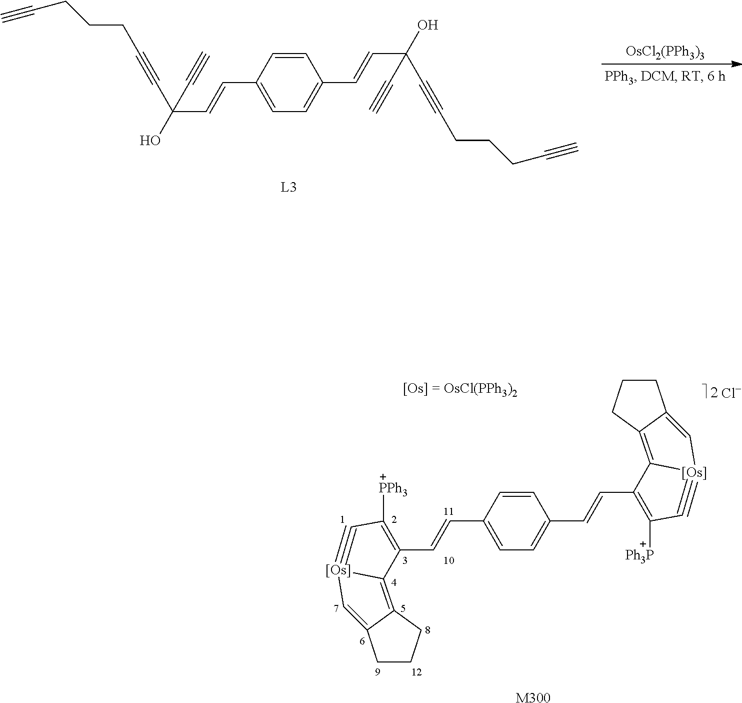

A method for preparing a diosmapentalyne monomer M300 is as follows: a polyacetylene carbon chain L3 (1.50 g, 3.59 mmol), triphenylphosphine (9.43 g, 35.9 mmol), and a tris(triphenylphosphine) osmium dichloride complex OsCl₂(PPh₃)₃ (11.31 g, 10.77 mmol) are dissolved in 120 mL of dichloromethane under a nitrogen atmosphere by a magnetic stirrer and reacted at room temperature (e.g., 20-25° C.) for 6 hours, a reaction solution is then concentrated to 15 mL and is added with 180 mL of ethyl ether, a solid product is precipitated and filtered, and the solid product is then washed with ethyl ether (e.g., 3×120 mL) several times. The solid product is further separated and purified through a silica gel column (a washing solution of dichloromethane and methanol with a volume ratio of 10:1 is used) to obtain 6.05 g of a tan solid product with a yield of 68%. A data acknowledgement of a structure of the diosmapentalyne monomer M300 is as follows: ¹H NMR plus ¹H-¹³C HSQC (600.1 MHz, CD₂Cl₂): δ=13.15 (s, 2H, C⁷H), 7.91-6.88 (94H, other aromatic protons), 6.19 (d, J=16.71 Hz, 2H, C¹¹H), 5.73 (d, J=16.71 Hz, 2H, C¹⁰H), 2.57 (m, 4H, C⁹H), 1.99 (m, 4H, C¹²H), 1.81 (t, J=7.26 Hz, 4H, C⁸H). ³¹P NMR (242.9 MHz, CD₂Cl₂): δ=5.89 (t, J_{P—P}=5.85 Hz, CPPh₃), 3.53 ppm (s, OsPPh₃). ¹³C NMR plus DEPT-135, ¹H-¹³C HSQC and ¹H-¹³C HMBC (150.9 MHz, CD₂Cl₂): δ=318.5 (dt, apparent q, J_{P—C}=13.16 Hz, J_{P—C}=13.16 Hz, C¹), 215.0 (m, C⁷), 179.1 (s, C⁵), 175.8 (s, C⁶), 170.9 (d, J_{P—C}=22.23 Hz, C⁴), 160.0 (d, J_{P—C}=15.53 Hz, C³), 135.8 (s, C¹⁰), 126.6 (s, C¹¹), 36.43 (s, C⁸), 29.75 (s, C⁹), 29.62 (s, C¹²), 135.5-120.1 ppm (other aromatic carbons). Elemental analysis calculated (%) for C₁₃₈H₁₁₂Cl₄Os₂P₆: C, 66.88, H, 4.55; found: C, 66.74, H, 4.73. HRMS (ESI): m/z calculated for [C₁₃₈H₁₁₂Cl₂Os₂P₆]²⁺, 1203.2881; found, 1203.3015.

### Embodiment 11

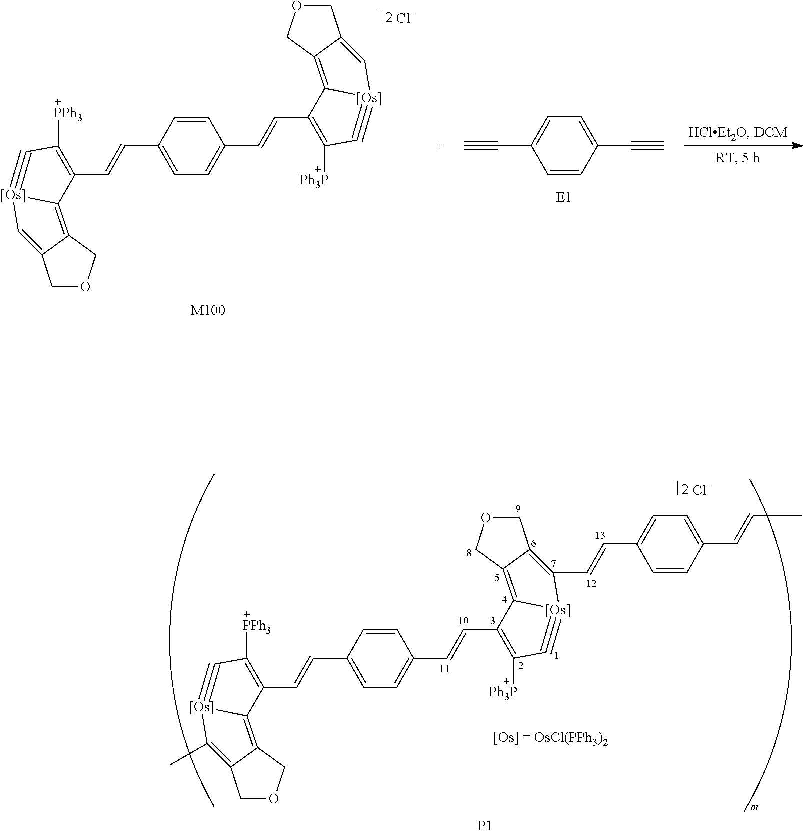

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), 1,4-Diethynylbenzene E1 is purchased from Bailingwei Technology Co., Ltd., a trade name is 009135, and DCM used in the above-mentioned formula is a redistilled solvent of dichloromethane.

A method for preparing a main chain comprising an osmapentalyne-containing conjugated polymer P1 is as follows. The diosmapentalyne monomer M100 (0.08 mmol) and the 1,4-diethynylbenzene (0.081 mmol) are dissolved in 10 mL of the redistilled solvent of the dichloromethane by a magnetic stirrer under a nitrogen atmosphere, and 1 mL of 2 mol/L of the hydrochloric acid in the ethyl ether is quickly added and is reacted with the diosmapentalyne monomer M100 at room temperature (e.g., 20-25° C.) for 5 hours, a large amount of ethyl ether is then added, a blue solid compound is precipitated and filtered, and the blue solid compound is repeatedly washed with ethyl ether and dried to obtain 188 mg of the main chain comprising the osmapentalyne-containing conjugated polymer P1.

A data acknowledgement of a structure of the main chain comprising the osmapentalyne-containing conjugated polymer P1 is as follows: ¹H NMR (500.2 MHz, CD₂Cl₂): δ=5.81 (br, 6H, C¹⁰H, C¹¹H, and C¹³H), 5.15 (br, 4H, C⁹H), 4.32 (br, 4H, C⁸H), 7.86-7.09 ppm (100H, other aromatic protons and C¹²H). ³¹P NMR (202.5 MHz, CD₂Cl₂): δ=4.81 (s, CPPh₃), 0.02 ppm (s, OsPPh₃). ¹³C NMR (150.9 MHz, CD₂Cl₂): δ=316.1 (s, C¹), 217.4 (s, C⁷), 172.4 (s, C⁵), 169.4 (s, C⁶), 168.1 (s, C⁴), 159.5 (s, C³), 83.92 (end-capper alkyne), 78.67 (end-capper alkyne), 74.26 (m, C⁸), 70.93 (s, C⁹), 143.5-112.8 ppm (other aromatic carbons).

A characterization data of a molecular weight of the main chain comprising the osmapentalyne-containing conjugated polymer P1 is as follows: polystyrene is used as a standard sample, and a weight average molecular weight measured in a N,N-dimethylformamide (DMF) solvent is 219448 Da, a number average molecular weight is 161669 Da, and a molecular weight distribution index is 1.36.

### Embodiment 12

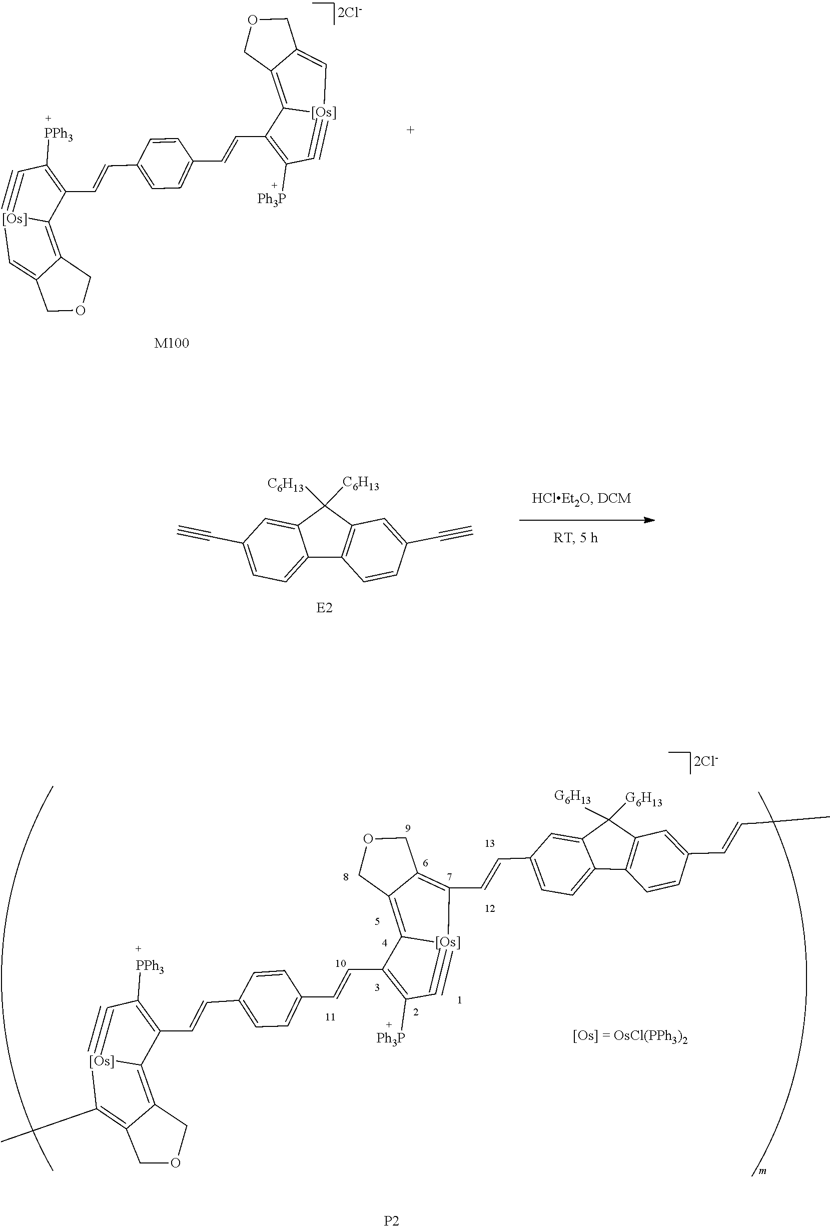

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E2 is synthesized according to the method reported in Organometallics, 2001, 20(11), 2262-2269, and DCM used in the above-mentioned formula is a redistilled solvent of dichloromethane.

A method for preparing a main chain comprising an osmapentalyne-containing conjugated polymer P2 is as follows. The diosmapentalyne monomer M100 (0.10 mmol) and the diacetylene E2 (0.101 mmol) are dissolved in 12 mL of the redistilled solvent of the dichloromethane by a magnetic stirrer under a nitrogen atmosphere, and 1.2 mL of 2 mol/L of the hydrochloric acid in the ethyl ether is quickly added, a large amount of ethyl ether is then added, a purple solid compound is precipitated and filtered, and the purple solid compound is repeatedly washed with ethyl ether and dried to obtain 252 mg of the main chain comprising the osmapentalyne-containing conjugated polymer P2 shown in FIG. 3.

A data acknowledgement of a structure of the main chain comprising the osmapentalyne-containing conjugated polymer P2 is as follows: ¹H NMR (500.2 MHz, CD₂Cl₂): δ=5.92 (br, 4H, C¹⁰H and C¹¹H), 5.62 (s, 2H, C¹³H), 5.18 (br, 4H, C⁹H), 4.36 (br, 4H, C⁸H), 2.08 (s, 4H, CH₂C₅H₁₁), 1.14 (s, 16H, CH₂C₄H₈CH₃), 0.76 (s, 6H, CH₃), 7.86-7.10 ppm (102H, other aromatic protons and C¹²H). ³¹P NMR (202.5 MHz, CD₂Cl₂): δ=4.73 (s, CPPh₃), 0.01 ppm (s, OsPPh₃). ¹³C NMR (150.9 MHz, CD₂Cl₂): δ=316.4 (s, C¹), 218.7 (s, C⁷), 172.3 (s, C⁵), 168.9 (s, C⁶), 167.6 (d, J_{P—C}=20.59 Hz, C⁴), 158.5 (d, J_{P—C}=13.52 Hz, C³), 73.69 (s, C⁸), 71.00 (s, C⁹), 55.21 (s, C¹⁴), 40.31 (m), 31.78 (m), 29.78 (m), 23.92 (m), 22.61 (m), 13.80 (m), 163.4-112.4 ppm (other aromatic carbons).

A characterization data of a molecular weight of the main chain comprising the osmapentalyne-containing conjugated polymer P2 is as follows: polystyrene is used as a standard sample, and a weight average molecular weight measured in a N,N-dimethylformamide (DMF) solvent is 308091 Da, a number average molecular weight is 209196 Da, and a molecular weight distribution index is 1.47.

### Embodiment 13

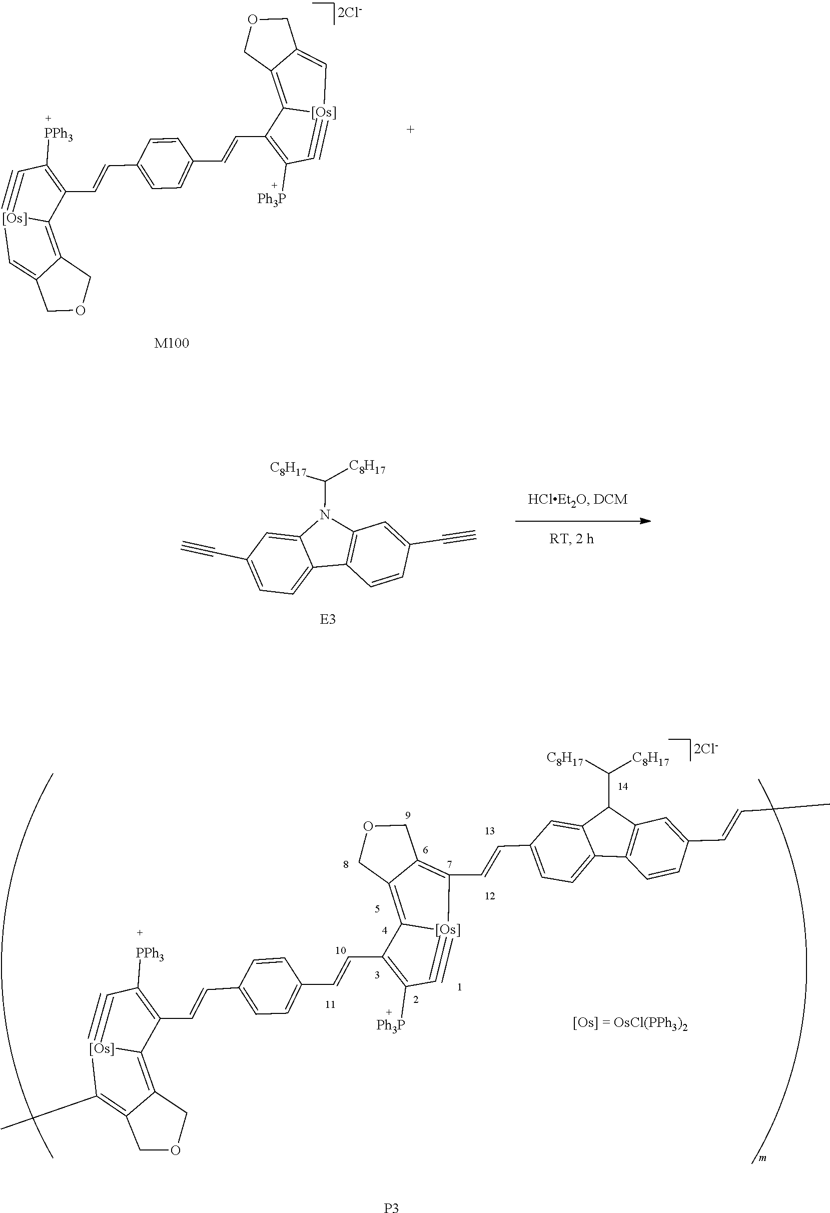

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E3 is purchased from Beijing Huaweiruike Chemical Co., Ltd. with a product number of 2135944-48-6, and DCM used in the above-mentioned formula is a redistilled solvent of dichloromethane.

A method for preparing a main chain comprising an osmapentalyne-containing conjugated polymer P3 is as follows. The diosmapentalyne monomer M100 (0.09 mmol) and the diacetylene E3 (0.091 mmol) are dissolved in 10 mL of the redistilled solvent of the dichloromethane by a magnetic stirrer under a nitrogen atmosphere, and 1 mL of 2 mol/L of the hydrochloric acid in the ethyl ether is quickly added and is reacted with the diosmapentalyne monomer M100 at room temperature (e.g., 20-25° C.) for 2 hours, a large amount of ethyl ether is then added, a blue-purple solid compound is precipitated and filtered, and the blue-purple solid compound is repeatedly washed with ethyl ether and dried to obtain 224 mg of the main chain comprising the osmapentalyne-containing conjugated polymer P3.

A data acknowledgement of a structure of the main chain comprising the osmapentalyne-containing conjugated polymer P3 is as follows: ¹H NMR (500.2 MHz, CD₂Cl₂): δ=6.06-5.96 (m, 4H, C¹⁰H and C¹¹H), 5.66 (s, 2H, C¹³H), 5.24 (br, 4H, C⁹H), 4.55 (br, 1H, C¹⁴H), 4.35 (br, 4H, C⁸H), 2.03 (s, 4H, CH₂C₇H₁₅), 1.16 (m, 24H, CH₂C₆H₁₂CH₃), 0.83 (s, 6H, CH₃), 7.85-7.10 ppm (102H, other aromatic protons and C¹²H). ³¹P NMR (202.5 MHz, CD₂Cl₂): δ=4.71 (s, CPPh₃), 0.30 ppm (s, OsPPh₃). ¹³C NMR (150.9 MHz, CD₂Cl₂): δ=316.5 (s, C¹), 218.9 (s, C⁷), 172.4 (s, C⁵), 168.8 (s, C⁶), 167.5 (s, C⁴), 158.2 (s, C³), 74.01 (m, C⁸), 71.00 (s, C⁹), 57.08 (s, C¹⁴), 33.82, 31.71, 29.43, 29.15, 27.29, 26.92, 22.56, 13.85, 163.4-107.8 ppm (other aromatic carbons).

A characterization data of a molecular weight of the main chain comprising the osmapentalyne-containing conjugated polymer P3 is as follows: polystyrene is used as a standard sample, and a weight average molecular weight measured in a N,N-dimethylformamide (DMF) solvent is 342486 Da, a number average molecular weight is 276301 Da, and a molecular weight distribution index is 1.23.

### Embodiment 14

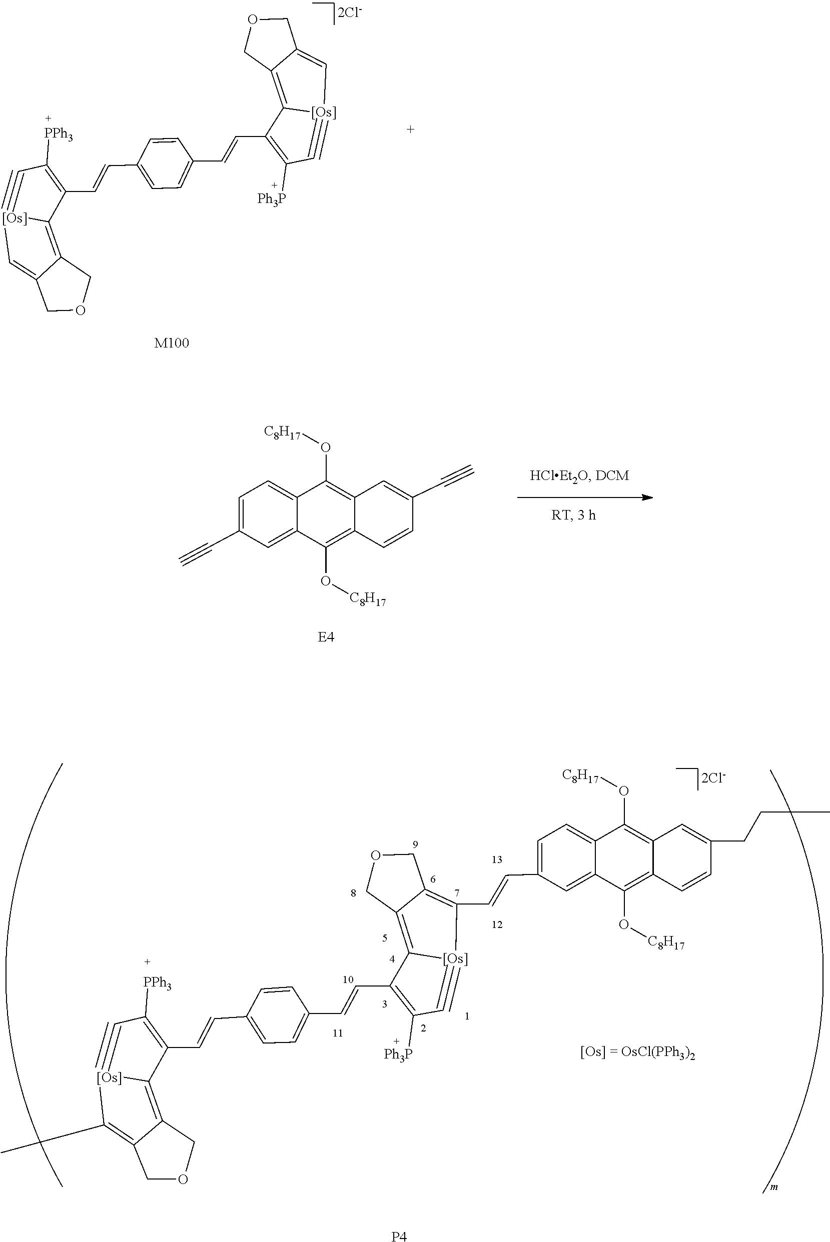

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E4 is synthesized by a method similar with the method disclosed in Tetrahedron Letters, 2012, 53(47), 6383-6387, and DCM used in the above-mentioned formula is a redistilled solvent of dichloromethane.

A method for preparing a main chain comprising an osmapentalyne-containing conjugated polymer P4 is as follows. The diosmapentalyne monomer M100 (0.08 mmol) and the diacetylene E4 (0.081 mmol) are dissolved in 12 mL of the redistilled solvent of the dichloromethane by a magnetic stirrer under a nitrogen atmosphere, and 1.2 mL of 2 mol/L of the hydrochloric acid in the ethyl ether is quickly added and is reacted with the diosmapentalyne monomer M100 at room temperature (e.g., 20-25° C.) for 3 hours, a large amount of ethyl ether is then added, a dark-blue solid compound is precipitated and filtered, and the dark-blue solid compound is repeatedly washed with ethyl ether and dried to obtain 204 mg of the main chain comprising the osmapentalyne-containing conjugated polymer P4.

A data acknowledgement of a structure of the main chain comprising the osmapentalyne-containing conjugated polymer P4 is as follows: ¹H NMR (500.2 MHz, CD₂Cl₂): δ=6.10 (br, 4H, C¹⁰H and C¹¹H), 5.76 (m, 2H, C¹³H), 5.24 (br, 4H, C⁹H), 4.36 (br, 4H, C⁸H), 4.23 (s, 4H, OCH₂C₇H₁₅), 2.10 (s, 4H, OCH₂CH₂C₆H₁₃), 1.71 (s, 4H, OC₂H₄CH₂C₅H₁₁), 1.37-1.30 (m, 16H, OC₂H₄C₄H₈CH₃), 0.95 (s, 6H, CH₃), 8.31-7.11 ppm (102H, other aromatic protons and C¹²H). ³¹P NMR (202.5 MHz, CD₂Cl₂): δ=4.77 (s, CPPh₃), −0.06 ppm (s, OsPPh₃). ¹³C NMR (150.9 MHz, CD₂Cl₂): δ=316.3 (s, C¹), 217.5 (s, C⁷), 172.3 (s, C⁵), 169.2 (s, C⁶), 168.1 (s, C⁴), 159.1 (s, C³), 76.79 (s, OCH₂C₇H₁₅), 74.04 (m, C⁸), 70.95 (s, C⁹), 31.88, 30.64, 29.59, 29.35, 26.78, 22.71, 13.99, 163.4-113.4 ppm (other aromatic carbons).

A characterization data of a molecular weight of the main chain comprising the osmapentalyne-containing conjugated polymer P4 is as follows: polystyrene is used as a standard sample, and a weight average molecular weight measured in a N,N-dimethylformamide (DMF) solvent is 435639 Da, a number average molecular weight is 243582 Da, and a molecular weight distribution index is 1.78.

### Embodiment 15

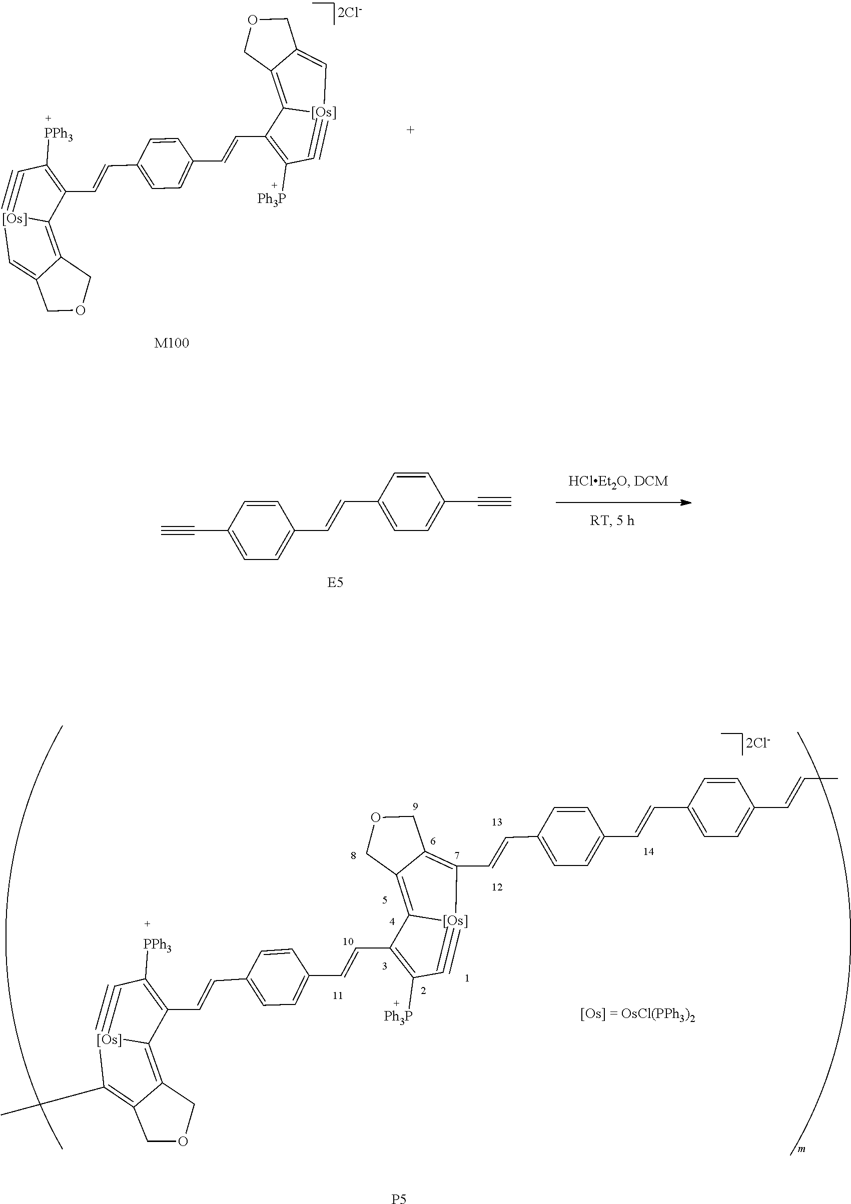

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E5 is synthesized according to the method reported in Polymer Chemistry, 2014, 5(7), 2301-2308, and DCM used in the above-mentioned formula is a redistilled solvent of dichloromethane.

A method for preparing a main chain comprising an osmapentalyne-containing conjugated polymer P5 is as follows. The diosmapentalyne monomer M100 (0.085 mmol) and the diacetylene E5 (0.085 mmol) are dissolved in 10 mL of the redistilled solvent of the dichloromethane by a magnetic stirrer under a nitrogen atmosphere, and 1 mL of 2 mol/L of the hydrochloric acid in the ethyl ether is quickly added and is reacted with the diosmapentalyne monomer M100 at room temperature (e.g., 20-25° C.) for 5 hours, a large amount of ethyl ether is then added, a purple-red solid compound is precipitated and filtered, and the purple-red solid compound is repeatedly washed with ethyl ether and dried to obtain 193 mg of the main chain comprising the osmapentalyne-containing conjugated polymer P5.

A data acknowledgement of a structure of the main chain comprising the osmapentalyne-containing conjugated polymer P5 is as follows: ¹H NMR (500.2 MHz, CD₂Cl₂): δ=5.90 (br, 4H, C¹⁰H and C¹¹H), 5.80 (m, 2H, C¹⁴H), 5.60 (m, 2H, C¹³H), 5.16 (br, 4H, C⁹H), 4.32 (br, 4H, C⁸H), 7.88-7.10 ppm (104H, other aromatic protons and C¹²H). ³¹P NMR (202.5 MHz, CD₂Cl₂): δ=4.75 (s, CPPh₃), 0.08 ppm (s, OsPPh₃). ¹³C NMR (150.9 MHz, CD₂Cl₂): δ=316.3 (s, C¹), 218.1 (s, C⁷), 172.3 (s, C⁵), 169.1 (s, C⁶), 168.0 (d, J_{P—C}=20.47 Hz, C⁴), 158.8 (d, J_{P—C}=13.19 Hz, C³), 83.53 (end-capper alkyne), 78.19 (end-capper alkyne), 74.29 (m, C⁸), 71.04 (s, C⁹), 163.4-112.7 ppm (other aromatic carbons).

A characterization data of a molecular weight of the main chain comprising the osmapentalyne-containing conjugated polymer P5 is as follows: polystyrene is used as a standard sample, and a weight average molecular weight measured in a N,N-dimethylformamide (DMF) solvent is 320820 Da, a number average molecular weight is 223498 Da, and a molecular weight distribution index is 1.43.

### Embodiment 16

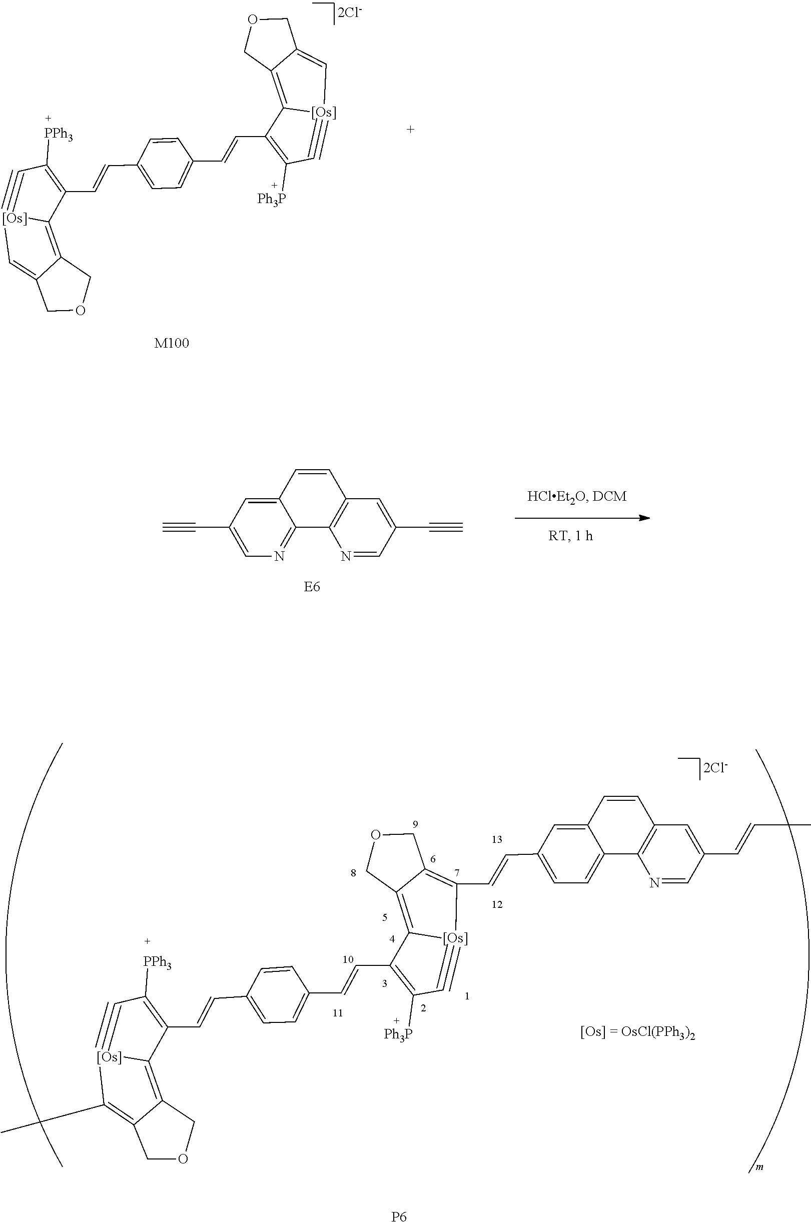

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E6 (i.e., 3,8-diynyl-1,10-phenanthroline) is purchased from Shanghai Kaiyulin Pharmaceutical Technology Co., Ltd. with a trade name is 640297-84-3, and DCM used in the above-mentioned formula is a redistilled solvent of dichloromethane.

A method for preparing a main chain comprising an osmapentalyne-containing conjugated polymer P6 is as follows. The diosmapentalyne monomer M100 (0.089 mmol) and the diacetylene E6 (0.090 mmol) are dissolved in 10 mL of the redistilled solvent of the dichloromethane by a magnetic stirrer under a nitrogen atmosphere, and 1 mL of 2 mol/L of the hydrochloric acid in the ethyl ether is quickly added and is reacted with the diosmapentalyne monomer M100 at room temperature (e.g., 20-25° C.) for 1 hour, a large amount of ethyl ether is then added, a dark-blue solid compound is precipitated and filtered, and the dark-blue solid compound is repeatedly washed with ethyl ether and dried to obtain 181 mg of the main chain comprising the osmapentalyne-containing conjugated polymer P6.

A data acknowledgement of a structure of the main chain comprising the osmapentalyne-containing conjugated polymer P6 is as follows: ¹H NMR (500.2 MHz, CD₂Cl₂): δ=6.36 (m, 2H, C¹³H), 5.90 (br, 4H, C¹⁰H and C¹¹H), 5.36 (br, 4H, C⁹H), 4.54 (br, 4H, C⁸H), 9.23-7.28 ppm (102H, other aromatic protons and C¹²H). ³¹P NMR (202.5 MHz, DMF-D7): δ=4.79 (s, CPPh₃), −0.87 ppm (s, OsPPh₃).

A characterization data of a molecular weight of the main chain comprising the osmapentalyne-containing conjugated polymer P6 is as follows: a weight average molecular weight is 16573 Da, a number average molecular weight is 15493 Da, and a molecular weight distribution index is 1.07.

### Embodiment 17

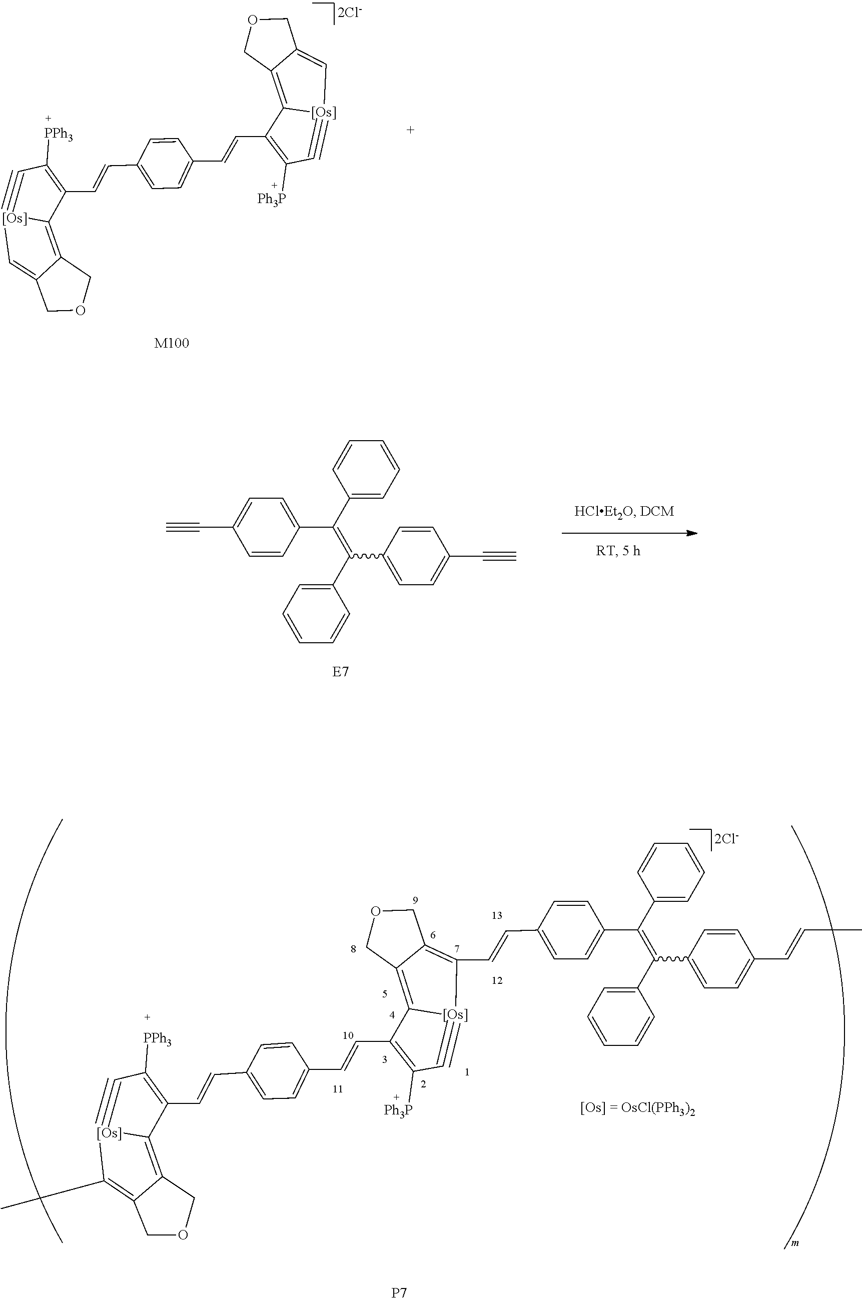

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E7 (i.e., [1,2-diphenyl-1,2-bis(4-ynyl) Phenyl] ethylene) is purchased from Beijing Huaweiruike Chemical Co., Ltd. with a trade name is 1240785-42-5, and DCM used in the above-mentioned formula is a redistilled solvent of dichloromethane.

A method for preparing a main chain comprising an osmapentalyne-containing conjugated polymer P7 is as follows. The diosmapentalyne monomer M100 (0.088 mmol) and the diacetylene E7 (0.090 mmol) are dissolved in 10 mL of the redistilled solvent of the dichloromethane by a magnetic stirrer under a nitrogen atmosphere, and 1 mL of 2 mol/L of the hydrochloric acid in the ethyl ether is quickly added and is reacted with the diosmapentalyne monomer M100 at room temperature (e.g., 20-25° C.) for 5 hours, a large amount of ethyl ether is then added, a blue-black solid compound is precipitated and filtered, and the blue-black solid compound is repeatedly washed with ethyl ether and dried to obtain 219 mg of the main chain comprising the osmapentalyne-containing conjugated polymer P7.

A data acknowledgement of a structure of the main chain comprising the osmapentalyne-containing conjugated polymer P7 is as follows: ¹H NMR (500.2 MHz, CD₂Cl₂): δ=5.77 (br, 6H, C¹³H, C¹⁰H and C¹¹H), 5.09 (br, 4H, C⁹H), 4.25 (br, 4H, C⁸H), 8.32-6.94 ppm (114H, other aromatic protons and C¹²H). ³¹P NMR (202.5 MHz, CD₂Cl₂): δ=4.79 (s, CPPh₃), 0.22 ppm (s, OsPPh₃). ¹³C NMR (150.9 MHz, CD₂Cl₂): δ=316.3 (s, C¹), 218.5 (s, C⁷), 172.4 (s, C⁵), 169.0 (s, C⁶), 167.8 (d, J_{P—C}=20.10 Hz, C⁴), 158.6 (d, J_{P—C}=12.84 Hz, C³), 83.43 (end-capper alkyne), 77.77 (end-capper alkyne), 73.74 (m, C⁸), 70.79 (s, C⁹), 144.8-119.4 ppm (other aromatic carbons).

A characterization data of a molecular weight of the main chain comprising the osmapentalyne-containing conjugated polymer P7 is as follows: a weight average molecular weight is 17260 Da, a number average molecular weight is 11217 Da, and a molecular weight distribution index is 1.54.

### Embodiment 18

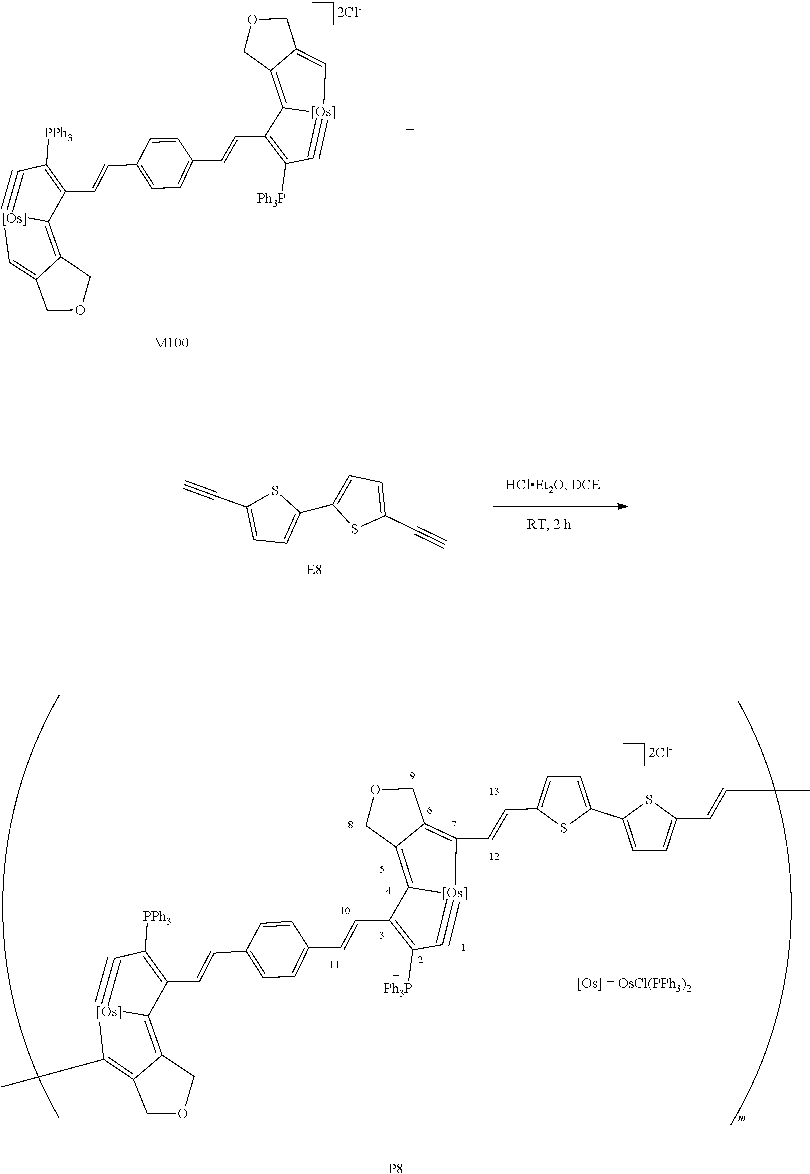

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E8 is synthesized according to the method reported in Journal of Physical Chemistry B, 2007, 111(37), 10871-10880, and DCE used in the above-mentioned formula is 1,2-dichloroethane of China National Pharmaceutical Group Co., Ltd. (Sinopharm).

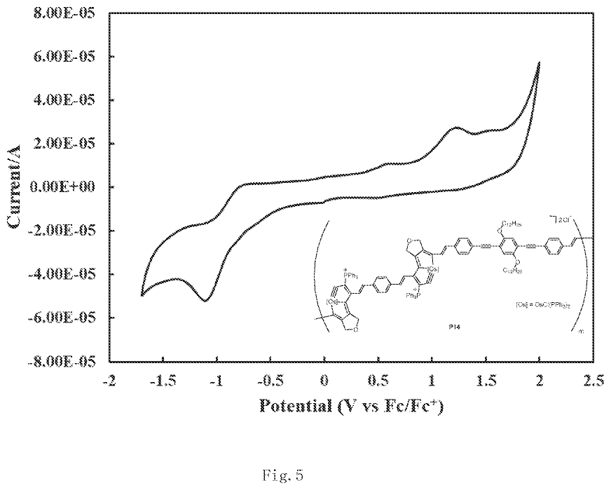

A method for preparing a main chain comprising an osmapentalyne-containing conjugated polymer P8 is as follows. The diosmapentalyne monomer M100 (0.055 mmol) and the diacetylene E8 (0.056 mmol) are dissolved in 8 mL of the 1,2-dichloroethane by a magnetic stirrer under a nitrogen atmosphere, and 0.3 mL of 2 mol/L of the hydrochloric acid in the ethyl ether is quickly added and is reacted with the diosmapentalyne monomer M100 at room temperature (e.g., 20-25° C.) for 5 hours, a large amount of ethyl ether is then added, a dark-green solid compound is precipitated and filtered, and the dark-green solid compound is repeatedly washed with ethyl ether and dried to obtain 118 mg of the main chain comprising the osmapentalyne-containing conjugated polymer P8 shown in FIG. 4.

A data acknowledgement of a structure of the main chain comprising the osmapentalyne-containing conjugated polymer P8 is as follows: ¹H NMR (500.2 MHz, CD₂Cl₂): δ=5.99 (br, 4H, C¹⁰H and C¹¹H), 5.67 (br, 2H, C¹³H), 5.08 (br, 4H, C⁹H), 4.35 (br, 4H, C⁸H), 8.00-6.90 ppm (100H, other aromatic protons and C¹²H). ³¹P NMR (202.5 MHz, CD₂Cl₂): δ=4.71 (s, CPPh₃), −0.21 ppm (s, OsPPh₃). ¹³C NMR (150.9 MHz, CD₂Cl₂): δ=316.1 (s, C¹), 190.2 (s, C⁷), 171.9 (s, C⁵), 169.0 (s, C⁶), 167.8 (s, C⁴), 158.6 (s, C³), 74.20 (m, C⁸), 70.91 (s, C⁹), 145.4-111.4 ppm (other aromatic carbons).

A characterization data of a molecular weight of the main chain comprising the osmapentalyne-containing conjugated polymer P8 is as follows: a weight average molecular weight is 16123 Da, a number average molecular weight is 15577 Da, and a molecular weight distribution index is 1.04.

### Embodiment 19

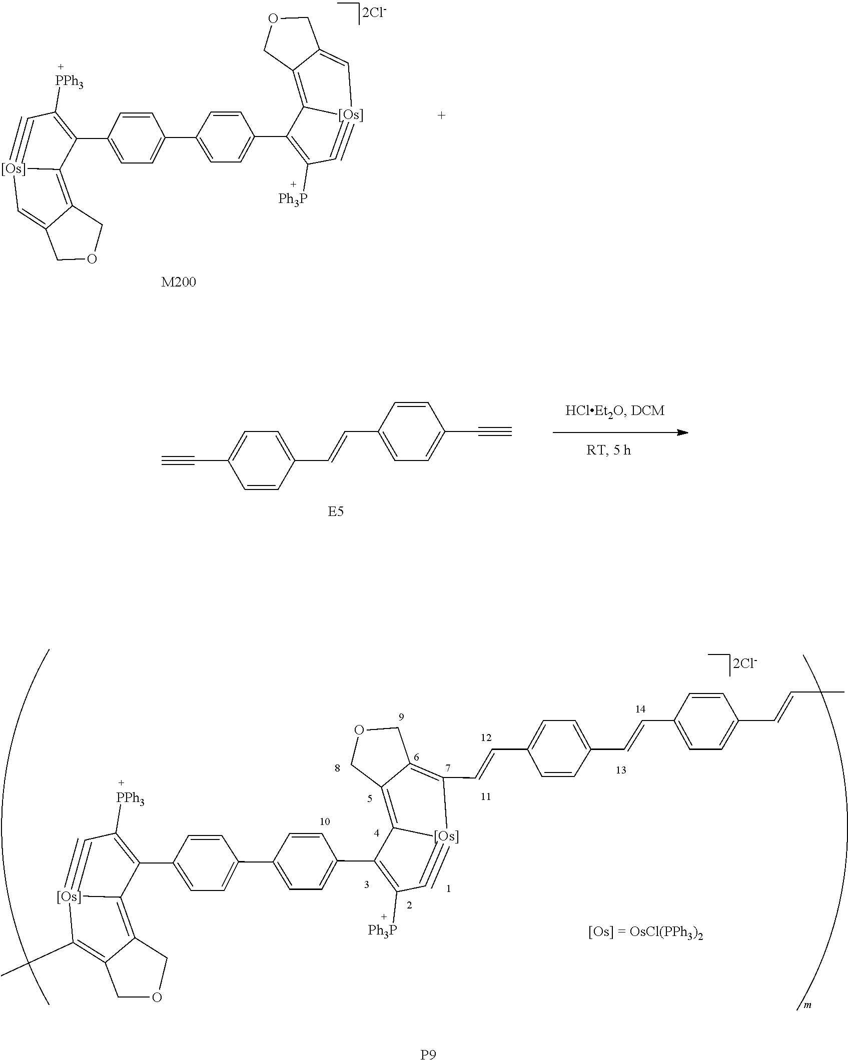

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E5 is synthesized according to the method reported in Polymer Chemistry, 2014, 5(7), 2301-2308, and DCM used in the above-mentioned formula is a redistilled solvent of dichloromethane.

A method for preparing a main chain comprising an osmapentalyne-containing conjugated polymer P9 is as follows. The diosmapentalyne monomer M200 (0.091 mmol) and the diacetylene E5 (0.092 mmol) are dissolved in 10 mL of the redistilled solvent of the dichloromethane by a magnetic stirrer under a nitrogen atmosphere, and 1 mL of 2 mol/L of the hydrochloric acid in the ethyl ether is quickly added and is reacted with the diosmapentalyne monomer M200 at room temperature (e.g., 20-25° C.) for 5 hours, a large amount of ethyl ether is then added, a purple-red solid compound is precipitated and filtered, and the purple-red solid compound is repeatedly washed with ethyl ether and dried to obtain 209 mg of the main chain comprising the osmapentalyne-containing conjugated polymer P9 shown in FIG. 4.

A data acknowledgement of a structure of the main chain comprising the osmapentalyne-containing conjugated polymer P9 is as follows: ¹H NMR (500.2 MHz, CD₂Cl₂): δ=5.96 (br, 4H, C¹⁰H), 5.89 (s, 1H, C¹³H), 5.77 (d, J=16.25 Hz, 2H, C¹²H), 5.59 (s, 1H, C¹⁴H), 5.12 (br, 4H, C⁹H), 3.68 (br, 4H, C⁸H), 7.96-7.07 ppm (108H, other aromatic protons and C¹¹H). ³¹P NMR (202.5 MHz, CD₂Cl₂): δ=4.41 (s, CPPh₃), −0.81 ppm (s, OsPPh₃). ¹³C NMR (150.9 MHz, CD₂Cl₂): δ=316.0 (s, C¹), 217.8 (s, C⁷), 173.3 (s, C⁵), 168.9 (s, C⁶), 165.3 (s, C⁴), 162.1 (s, C³), 73.17 (s, C⁸), 70.73 (s, C⁹), 142.4-112.6 ppm (other aromatic carbons).

A characterization data of a molecular weight of the main chain comprising the osmapentalyne-containing conjugated polymer P9 is as follows: diffusion coefficients D of the main chain comprising the osmapentalyne-containing conjugated polymer P9 and a model compound are tested using a Nuclear Magnetic Resonance (NMR) diffusion order spectroscopy (DOSY) technology (Macromolecules, 2012, 45, 9595-9603) to speculate an average molecular weight of the main chain comprising the osmapentalyne-containing conjugated polymer P9 to be 41892.

### Embodiment 20

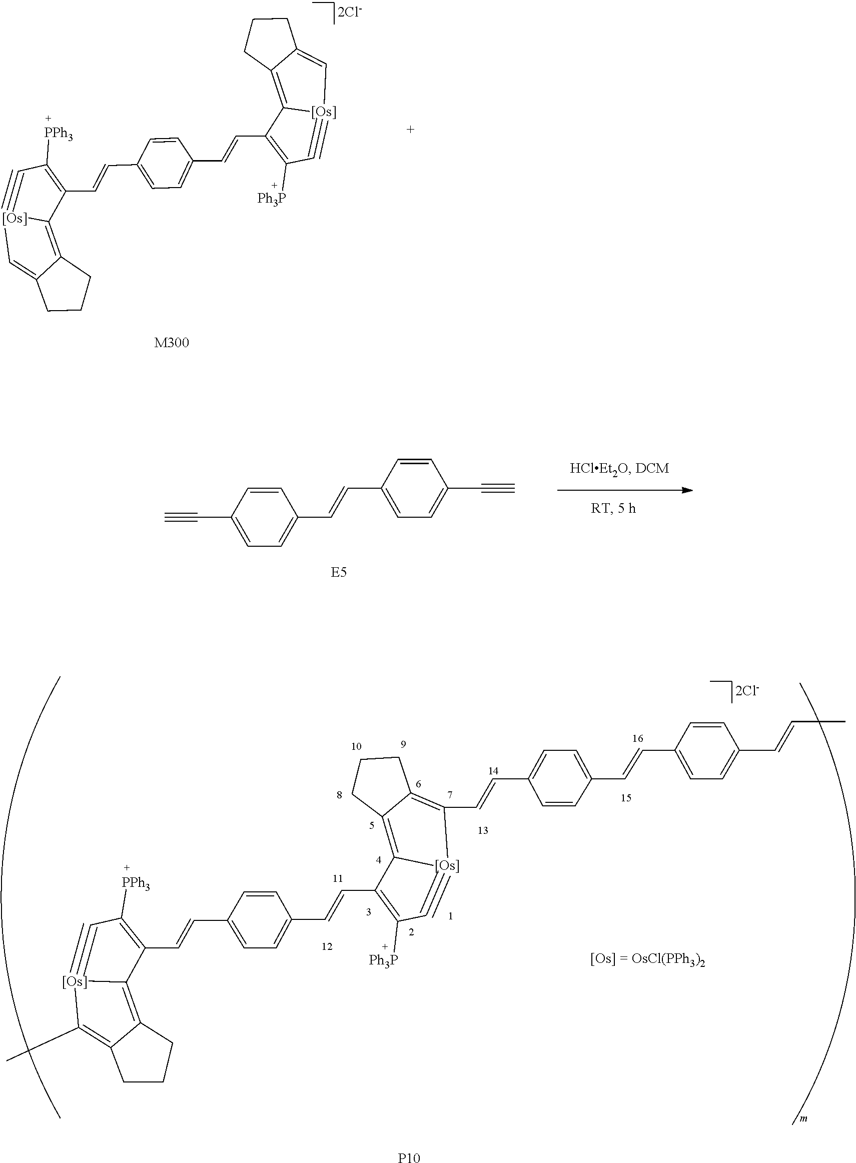

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E5 is synthesized according to the method reported in Polymer Chemistry, 2014, 5(7), 2301-2308, and DCM used in the above-mentioned formula is a redistilled solvent of dichloromethane.

A method for preparing a main chain comprising an osmapentalyne-containing conjugated polymer P10 is as follows. The diosmapentalyne monomer M300 (0.10 mmol) and the diacetylene E5 (0.101 mmol) are dissolved in 10 mL of the redistilled solvent of the dichloromethane by a magnetic stirrer under a nitrogen atmosphere, and 1 mL of 2 mol/L of the hydrochloric acid in the ethyl ether is quickly added and is reacted with the diosmapentalyne monomer M300 at room temperature (e.g., 20-25° C.) for 5 hours, a large amount of ethyl ether is then added, a dark-blue solid compound is precipitated and filtered, and the dark-blue solid compound is repeatedly washed with ethyl ether and dried to obtain 225 mg of the main chain comprising the osmapentalyne-containing conjugated polymer P10.

A data acknowledgement of a structure of the main chain comprising the osmapentalyne-containing conjugated polymer P10 is as follows: ¹H NMR (500.2 MHz, CD₂Cl₂): δ=6.23 (d, J=16.11 Hz, 4H, C¹¹H and C¹²H), 5.89 (s, 1H, C¹⁵H), 5.67 (br, 2H, C¹⁴H), 5.59 (s, 1H, C¹⁶H), 3.02 (br, 4H, C¹⁰H), 2.09 (br, 4H, C⁹H), 1.30 (br, 4H, C⁸H), 7.96-6.98 ppm (104H, other aromatic protons and C¹³). ³¹P NMR (202.5 MHz, CD₂Cl₂): δ=4.45 (s, CPPh₃), 1.08 ppm (s, OsPPh₃). ¹³C NMR (150.9 MHz, CD₂Cl₂): δ=316.4 (s, C¹), 220.4 (s, C⁷), 179.3 (s, C⁵), 174.2 (s, C⁶), 170.7 (s, C⁴), 157.6 (s, C³), 37.12 (s, C⁸), 32.54 (s, C⁹), 30.34 (s, C¹⁰), 163.3-112.6 ppm (other aromatic carbons).

A characterization data of a molecular weight of the main chain comprising the osmapentalyne-containing conjugated polymer P10 is as follows: diffusion coefficients D of the main chain comprising the osmapentalyne-containing conjugated polymer P10 and a model compound are tested using a Nuclear Magnetic Resonance (NMR) diffusion order spectroscopy (DOSY) (Macromolecules, 2012, 45, 9595-9603) to speculate an average molecular weight of the main chain comprising the osmapentalyne-containing conjugated polymer P10 to be 21322.

### Embodiment 21

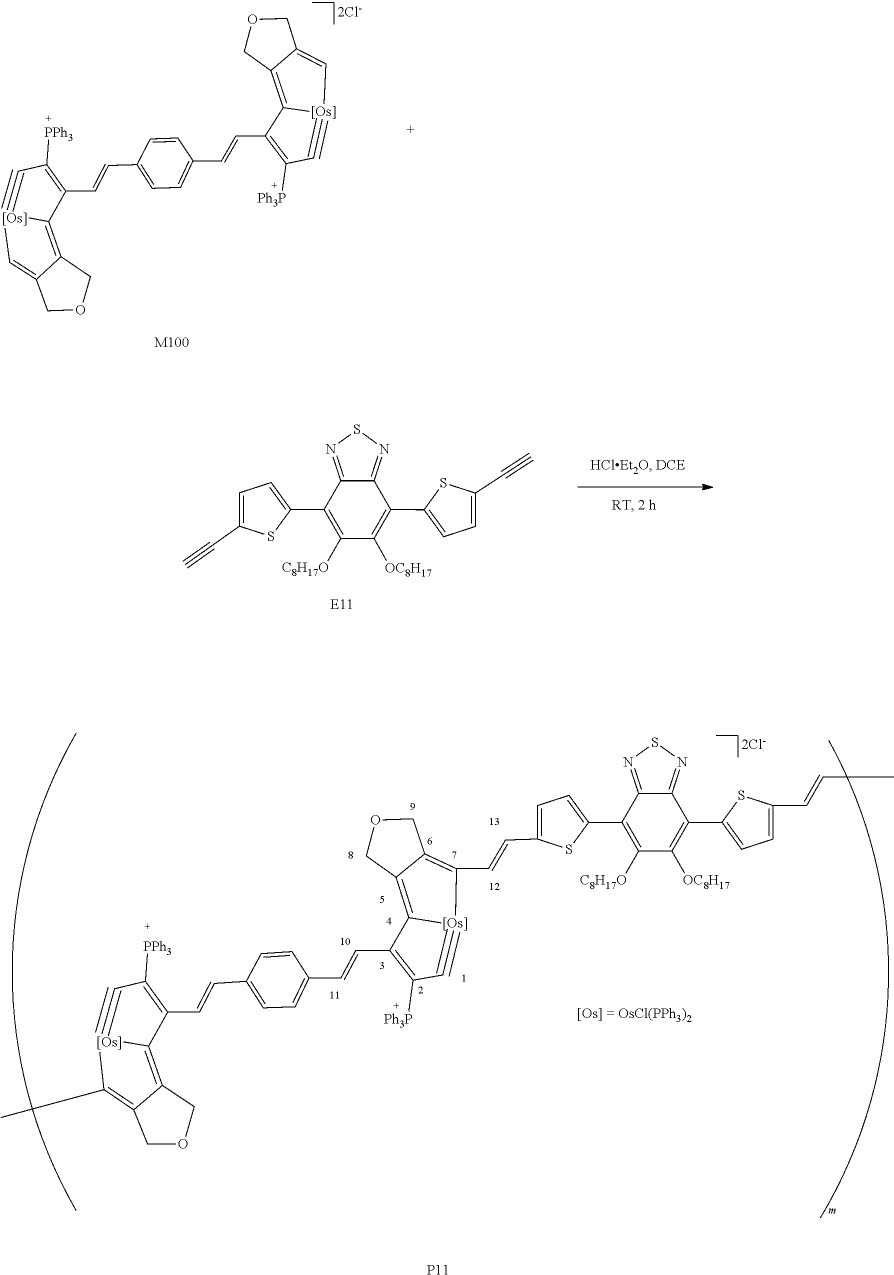

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E11 is purchased from Beijing Huaweiruike Chemical Co., Ltd. with a product number of HWG58301-5g, and DCM used in the above-mentioned formula is 1,2-Dichloroethane.

A method for preparing a main chain comprising an osmapentalyne-containing conjugated polymer P11 is as follows. The diosmapentalyne monomer M100 (0.08 mmol) and the diacetylene E11 (0.08 mmol) are dissolved in 10 mL of the 1,2-dichloroethane by a magnetic stirrer under a nitrogen atmosphere, and 0.4 mL of 2 mol/L of the hydrochloric acid in the ethyl ether is quickly added and is reacted with the diosmapentalyne monomer M100 at room temperature (e.g., 20-25° C.) for 2 hours, a large amount of ethyl ether is then added, a dark-blue solid compound is precipitated and filtered, and the dark-blue solid compound is repeatedly washed with ethyl ether and dried to obtain 192 mg of the main chain comprising the osmapentalyne-containing conjugated polymer P11.

A data acknowledgement of a structure of the main chain comprising the osmapentalyne-containing conjugated polymer P11 is as follows: ¹H NMR (500.2 MHz, CD₂Cl₂): δ=6.10 (m, 4H, C¹⁰H and C¹¹H), 5.90 (s, 2H, C¹²H), 5.50 (s, 2H, C¹³H), 5.12 (s, 4H, C⁹H), 4.37 (s, 4H, C⁸H), 4.23 (m, 4H, OCH₂C₇H₁₅), 2.05 (m, 4H, OCH₂CH₂C₆H₁₃), 1.53-1.30 (m, 20H, OC₂H₄C₅H₁₀CH₃), 0.92 (m, 6H, OC₇H₁₄CH₃), 8.62-6.88 ppm (98H, other aromatic protons). ³¹P NMR (202.5 MHz, CD₂Cl₂): δ=4.55 (s, CPPh₃), −0.20 ppm (s, OsPPh₃). ¹³C NMR (150.9 MHz, CD₂Cl₂): δ=316.3 (s, C¹), 216.7 (s, C⁷), 171.8 (s, C⁵), 168.9 (s, C⁶), 167.7 (s, C⁴), 158.2 (s, C³), 74.55, 73.87 (s, C⁸), 70.94 (s, C⁹), 31.78, 30.40, 29.55, 29.36, 26.03, 22.68, 13.99, 152.0-112.3 ppm (other aromatic carbons).

A characterization data of a molecular weight of the main chain comprising the osmapentalyne-containing conjugated polymer P11 is as follows: a weight average molecular weight is 29122 Da, a number average molecular weight is 14433 Da, and a molecular weight distribution index is 2.01.

### Embodiment 22

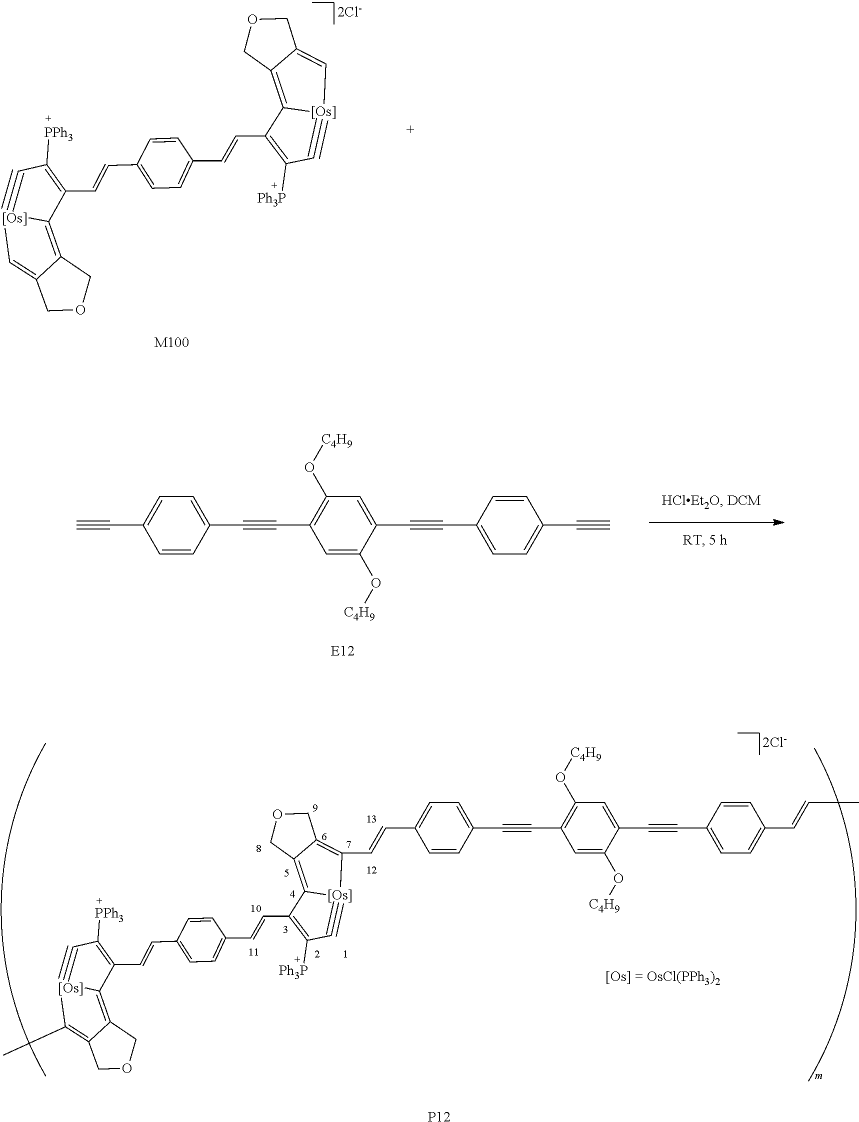

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E12 is synthesized by a method similar with the method disclosed in Inorganic Chemistry, 2009, 48(14), 6534-6547, and DCM used in the above-mentioned formula is a redistilled solvent of dichloromethane.

A method for preparing a main chain comprising an osmapentalyne-containing conjugated polymer P12 is as follows. The diosmapentalyne monomer M100 (0.20 mmol) and the diacetylene E12 (0.201 mmol) are dissolved in 20 mL of the redistilled solvent of the dichloromethane by a magnetic stirrer under a nitrogen atmosphere, and 2 mL of 2 mol/L of the hydrochloric acid in the ethyl ether is quickly added and is reacted with the diosmapentalyne monomer M100 at room temperature (e.g., 20-25° C.) for 5 hours, a large amount of ethyl ether is then added, a dark-blue solid compound is precipitated and filtered, and the dark-blue solid compound is repeatedly washed with ethyl ether and dried to obtain 490 mg of the main chain comprising the osmapentalyne-containing conjugated polymer P12.

A data acknowledgement of a structure of the main chain comprising the osmapentalyne-containing conjugated polymer P12 is as follows: ¹H NMR (500.2 MHz, CD₂Cl₂): δ=5.84 (br, 6H, C¹⁰H, C¹¹H, and C¹³H), 5.12 (br, 4H, C⁹H), 4.29 (br, 4H, C⁸H), 4.10 (s, 4H, OCH₂CH₂CH₂), 1.08 (s, 8H, OCH₂CH₂CH₂), 0.92-0.89 (br, 6H, CH₃), 7.88-7.09 ppm (106H, other aromatic protons and C¹²H). ³¹P NMR (202.5 MHz, CD₂Cl₂): δ=4.83 (s, CPPh₃), −0.03 ppm (s, OsPPh₃). ¹³C NMR (150.9 MHz, CD₂Cl₂): δ=316.1 (s, C¹), 217.1 (s, C⁷), 172.3 (s, C⁵), 169.3 (s, C⁶), 168.1 (s, C⁴), 159.5 (s, C³), 95.64 (s, C¹⁵), 94.23 (end-capper alkyne), 88.08 (s, C¹⁴), 88.07 (end-capper alkyne), 83.05 (end-capper alkyne), 79.06 (end-capper alkyne), 73.70 (m, C⁸), 70.86 (s, C⁹), 69.35, 31.38, 19.32, 13.73, 163.4-114.1 ppm (other aromatic carbons).

A characterization data of a molecular weight of the main chain comprising the osmapentalyne-containing conjugated polymer P12 is as follows: diffusion coefficients D of the main chain comprising the osmapentalyne-containing conjugated polymer P12 and a model compound are tested using a Nuclear Magnetic Resonance (NMR) diffusion order spectroscopy (DOSY) (Macromolecules, 2012, 45, 9595-9603) to speculate an average molecular weight of the main chain comprising the osmapentalyne-containing conjugated polymer P12 to be 83497.

### Embodiment 23

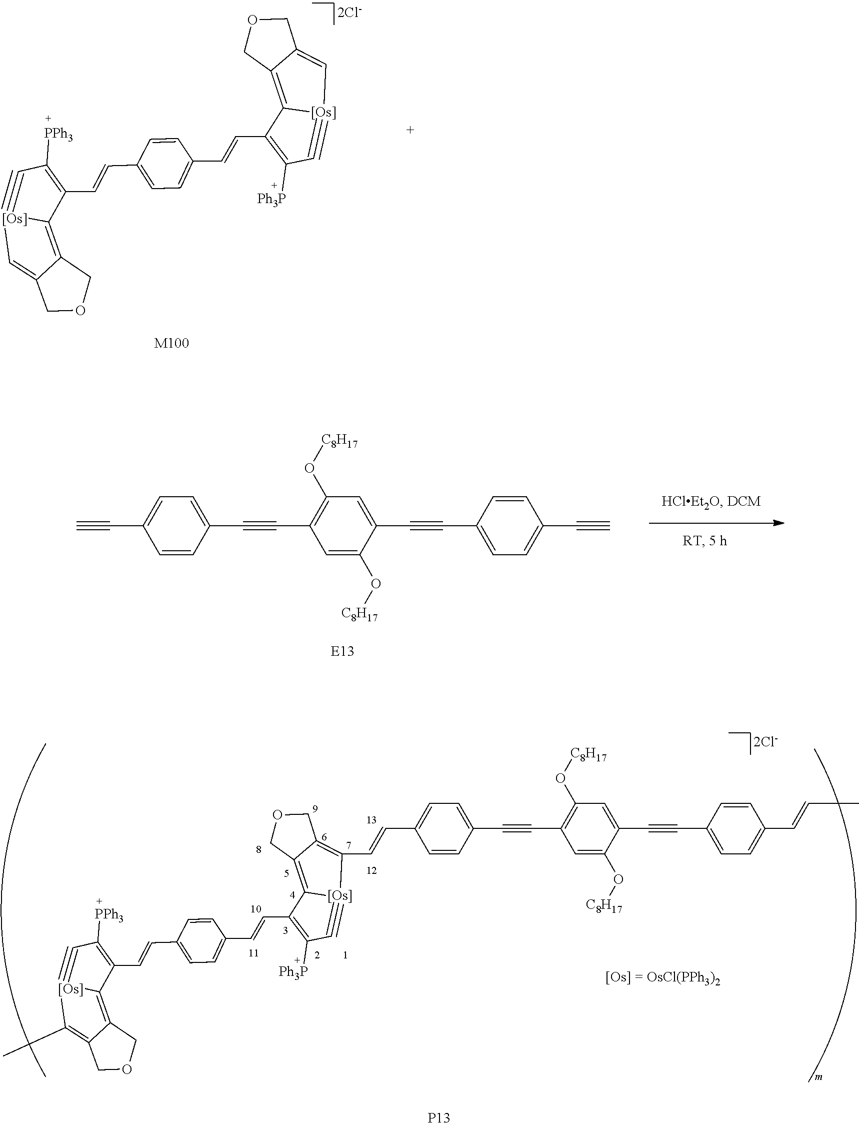

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E13 is synthesized by a method similar with the method disclosed in Inorganic Chemistry, 2009, 48(14), 6534-6547, and DCM used in the above-mentioned formula is a redistilled solvent of dichloromethane.

A method for preparing a main chain comprising an osmapentalyne-containing conjugated polymer P13 is as follows. The diosmapentalyne monomer M100 (0.15 mmol) and the diacetylene E13 (0.151 mmol) are dissolved in 15 mL of the redistilled solvent of the dichloromethane by a magnetic stirrer under a nitrogen atmosphere, and 1.5 mL of 2 mol/L of the hydrochloric acid in the ethyl ether is quickly added and is reacted with the diosmapentalyne monomer M100 at room temperature (e.g., 20-25° C.) for 5 hours, a large amount of ethyl ether is then added, a dark-blue solid compound is precipitated and filtered, and the dark-blue solid compound is repeatedly washed with ethyl ether and dried to obtain 386 mg of the main chain comprising the osmapentalyne-containing conjugated polymer P13.

A data acknowledgement of a structure of the main chain comprising the osmapentalyne-containing conjugated polymer P13 is as follows: ¹H NMR (500.2 MHz, CD₂Cl₂): δ=5.83 (br, 6H, C¹⁰H, C¹¹H, and C¹³H), 5.12 (br, 4H, C⁹H), 4.31 (br, 4H, C⁸H), 4.09 (s, 4H, OCH₂C₇H₁₅), 1.33-1.30 (m, 24H, OCH₂C₅H₁₂CH₃), 0.91-0.90 (br, 6H, CH₃), 7.88-7.09 ppm (106H, other aromatic protons and C¹²H). ³¹P NMR (202.5 MHz, CD₂Cl₂): δ=4.82 (s, CPPh₃), −0.04 ppm (s, OsPPh₃). ¹³C NMR (150.9 MHz, CD₂Cl₂): δ=316.2 (s, C¹), 217.0 (s, C⁷), 172.2 (s, C⁵), 169.2 (s, C⁶), 168.1 (s, C⁴), 159.5 (s, C³), 95.66 (s, C¹⁵), 94.25 (end-capper alkyne), 88.10 (s, C¹⁴), 88.09 (end-capper alkyne), 83.06 (end-capper alkyne), 79.07 (end-capper alkyne), 74.36 (m, C⁸), 70.92 (s, C⁹), 69.63, 31.84, 29.35, 26.09, 22.70, 13.94, 153.6-113.7 ppm (other aromatic carbons).

A characterization data of a molecular weight of the main chain comprising the osmapentalyne-containing conjugated polymer P13 is as follows: diffusion coefficients D of the main chain comprising the osmapentalyne-containing conjugated polymer P13 and a model compound are tested using a Nuclear Magnetic Resonance (NMR) diffusion order spectroscopy (DOSY) (Macromolecules, 2012, 45, 9595-9603) to speculate an average molecular weight of the main chain comprising the osmapentalyne-containing conjugated polymer P13 to be 40014.

### Embodiment 24

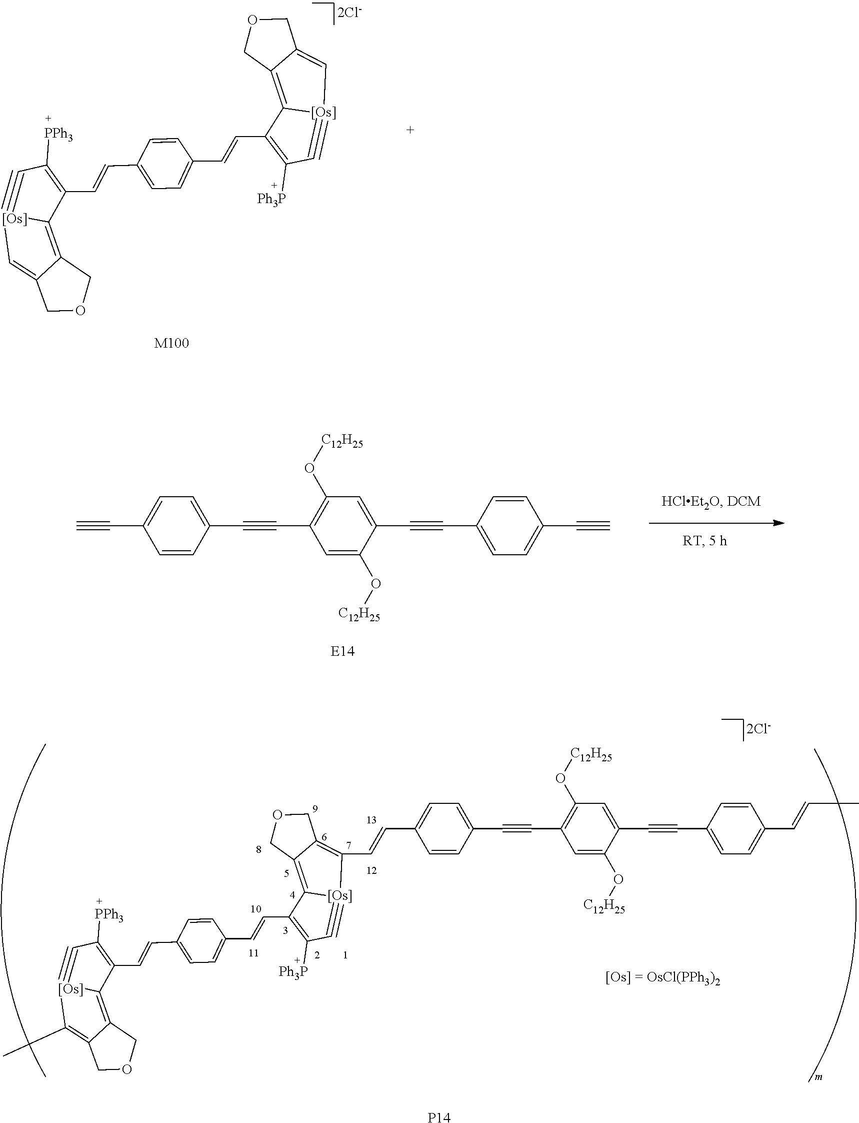

In the above-mentioned formula, [Os] is OsCl(PPh₃)₂, wherein HCl.Et₂O is hydrochloric acid in ethyl ether (which is purchased from Saen Chemical Technology (Shanghai) Co., Ltd., a trade name is A01W8101821000), diacetylene E14 is synthesized by a method similar with the method disclosed in Inorganic Chemistry, 2009, 48(14), 6534-6547, and DCM used in the above-mentioned formula is a redistilled solvent of dichloromethane.

A method for preparing a main chain comprising an osmapentalyne-containing conjugated polymer P14 is as follows. The diosmapentalyne monomer M100 (0.33 mmol) and the diacetylene E14 (0.331 mmol) are dissolved in 30 mL of the redistilled solvent of the dichloromethane by a magnetic stirrer under a nitrogen atmosphere, and 3 mL of 2 mol/L of the hydrochloric acid in the ethyl ether is quickly added and is reacted with the diosmapentalyne monomer M100 at room temperature (e.g., 20-25° C.) for 5 hours, a large amount of ethyl ether is then added, a dark-blue solid compound is precipitated and filtered, and the dark-blue solid compound is repeatedly washed with ethyl ether and hexane and dried to obtain 849 mg of the main chain comprising the osmapentalyne-containing conjugated polymer P14 shown in FIG. 5.

A data acknowledgement of a structure of the main chain comprising the osmapentalyne-containing conjugated polymer P14 is as follows: ¹H NMR (500.2 MHz, CD₂Cl₂): δ=5.82 (br, 6H, C¹⁰H, C¹¹H, and C¹³H), 5.14 (br, 4H, C⁹H), 4.30 (br, 4H, C⁸H), 4.09 (s, 4H, OCH₂C₁₁H₂₃), 1.45-1.24 (m, 40H, OCH₂C₅H₁₂CH₃), 0.90 (s, 6H, CH₃), 7.88-7.09 ppm (106H, other aromatic protons and C¹²H). ³¹P NMR (202.5 MHz, CD₂Cl₂): δ=4.84 (s, CPPh₃), −0.04 ppm (s, OsPPh₃). ¹³C NMR (150.9 MHz, CD₂Cl₂): δ=316.1 (s, C¹), 217.1 (s, C⁷), 172.3 (s, C⁵), 169.3 (s, C⁶), 168.1 (s, C⁴), 159.5 (s, C³), 95.62 (s, C¹⁵), 94.25 (end-capper alkyne), 88.08 (s, C¹⁴), 88.07 (end-capper alkyne), 83.05 (end-capper alkyne), 79.03 (end-capper alkyne), 74.33 (m, C⁸), 70.95 (s, C⁹), 69.62 (s, OCH₂C₁₁H₂₃), 31.92, 29.66, 29.36, 26.03, 22.70, 13.93, 163.4-114.1 ppm (other aromatic carbons).

A characterization data of a molecular weight of the main chain comprising the osmapentalyne-containing conjugated polymer P14 is as follows: polystyrene is used as a standard sample, and a weight average molecular weight measured in a N,N-dimethylformamide (DMF) solvent is 462172 Da, a number average molecular weight is 380070 Da, and a molecular weight distribution index is 1.22.

The aforementioned embodiments are merely some embodiments of the present disclosure, and the scope of the disclosure is not limited thereto. Thus, it is intended that the present disclosure cover any modifications and variations of the presently presented embodiments provided they are made without departing from the appended claims and the specification of the present disclosure.

What is claimed is:

1. An osmium-containing conjugated polymer, wherein:
a repeating unit of the osmium-containing conjugated polymer consists of osmapentalyne groups, a conjugated linking group R₁, and a vinyl group,
a third position of an osmapentalyne group is connected to the conjugated linking group R₁, and the conjugated linking group R₁ is then connected to the vinyl group, and
the vinyl group is connected to a seventh position of a next osmapentalyne group, and a structural formula of the osmium-containing conjugated polymer is as follows: 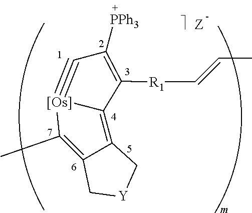
the [Os] is OsAL₂, OsA₂L, or OsL₃, wherein A is at least one of —H, halogen group, —SCN, or —CN, and L is at least one of a phosphine ligand, a CO ligand, a pyridine ligand, a nitrogen heterocyclic carbene ligand, a nitrile ligand, or an isocyanic two-electron ligands, wherein the halogen group is at least one of —F, —Cl, —Br, or —I,
the Y is at least one of CH₂, O, C(COO(CH₂)ₖMe)₂, N, or S, wherein k is an integer between 0 and 18,
the conjugated linking group R₁ is at least one of a first substituted aryl group, a first unsubstituted aryl group, a substituted alkenyl group, an unsubstituted alkenyl group, a substituted alkynyl group, or an unsubstituted alkynyl group, wherein a substituted vinyl group or an unsubstituted vinyl group is a trans vinyl group when the substituted alkenyl group or the unsubstituted alkenyl group is the substituted vinyl group or the unsubstituted vinyl group,
the Z⁻ is an anion, and
the m is an integer between 3 and 300.

2. The osmium-containing conjugated polymer according to claim 1, wherein the anion comprises at least one of F⁻, Cl⁻, Br⁻, I⁻, BF₄⁻, H₂PO₄⁻, C₂O₄²⁻, SO₄²⁻, CF₃SO₃⁻, CH₃COO⁻, (CF₃SO₂)₂N⁻, NO₃⁻, ClO₄⁻, PF₆⁻, or BPh₄⁻.

3. The osmium-containing conjugated polymer according to claim 1, wherein:
the L in the [Os] is at least one of triphenylphosphine, trimethylphosphine, triethylphosphine, tripropylphosphine, triisopropylphosphine, tri-tert-butylphosphine, tricyclohexylphosphine, methylpyridine, ethylpyridine, 1,4-bipyridine, 1,2-bis(4-pyridyl)ethylene, vinylpyridine, ethynyl Pyridine, pyridine boronic acid, aminopyridine, cyanopyridine, mercaptopyridine, dimethylaminopyridine, phenylpyridine, 1,2-bis(4-pyridyl)ethane, imidazole-type N-heterocyclic carbene, imidazoline-type N-heterocyclic carbene, thiazole-type N-heterocyclic carbene, triazol-type N-heterocyclic carbene, acetonitrile, propionitrile, benzonitrile, cyclohexyl isocyanide, tert-butyl isocyanide, or phenyl isocyanide,
the L₂ in the [Os] is integrated, and L₂ is at least one of ethylenediamine, 2,2′-bipyridine, 1,10-phenanthroline, 1,1-bis(diphenylphosphine)methane, 1,2-bis (diphenylphosphine)ethane, 1,3-bis(diphenylphosphine)propane, ortho-phenylpyridine, or 8-hydroxyquinoline, and
the AL₂ in the [Os] is integrated, and the AL₂ is at least one of a terpyridine, a PPP-type tridentate ligand, a PNP-type tridentate ligand, a PCP-type tridentate ligand, an NNN-type tridentate ligand, an NCN-type tridentate ligand, an NPN-type tridentate ligand, an ONO-type tridentate ligand, an OPO-type tridentate ligand, an OCO-type tridentate ligand, an SCS-type tridentate ligand, or a CCC-type tridentate ligand.

3. The osmium-containing conjugated polymer according to claim 1, wherein the first substituted aryl group or the first unsubstituted aryl group is at least one of phenyl, diphenyl, terphenyl, naphthyl, anthryl, fiki, pyrene, thienyl, dithienyl, terthienyl, dithienylethene, thiazolyl, thiadiazolyl, bis-thiadiazolyl, bis-terthienyl, furanyl, pyridyl, pyrrolyl, porphyrin, fluorenyl, bifluorenyl, terfluorenyl, carbazolyl, bicarbazolyl, tercarbazolyl, benzothiadiazolyl, tetrastyryl, hexabenzocoronyl, diketopyrrolopyrrole-based, benzodithienyl, indacenodithienyl, silyl fluorenyl, dithienocyclodecadiene, dithienosilole-based, dithienopyrrole-based, triphenylamino, naphthalenedithiadiazolyl, naphthalenetetracarboxylic diimide-based, perylenetetracarboxylic diimide-based, isoindigo-based, thienopyrroledione-based, benzopyrroledione-based, benzotriazolyl, thiadiazolobenzotriazolyl, pyridothiadiazolyl, or thieno[3,4-b]thienyl.

4. The osmium-containing conjugated polymer according to claim 1, wherein:
a substituent reacts with an alkenyl group,
the alkenyl group consists of 2-80 carbon atoms of a second substituted aryl group and a second unsubstituted aryl group, and
the second substituted aryl group or the second unsubstituted aryl group is the same the first substituted aryl group or the first unsubstituted aryl group.

6. The osmium-containing conjugated polymer according to claim 1, wherein the conjugated linking group R1 is at least one of 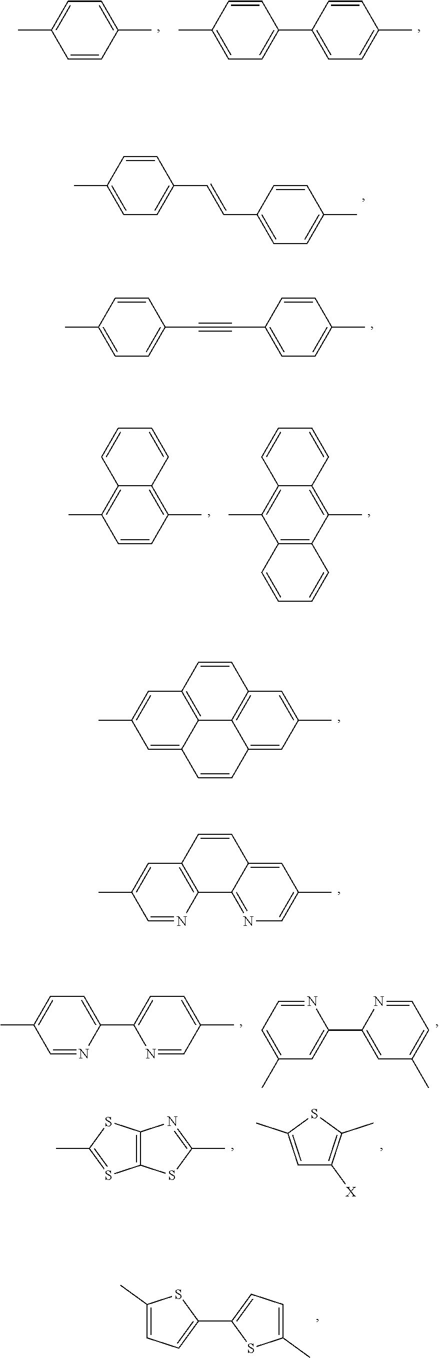 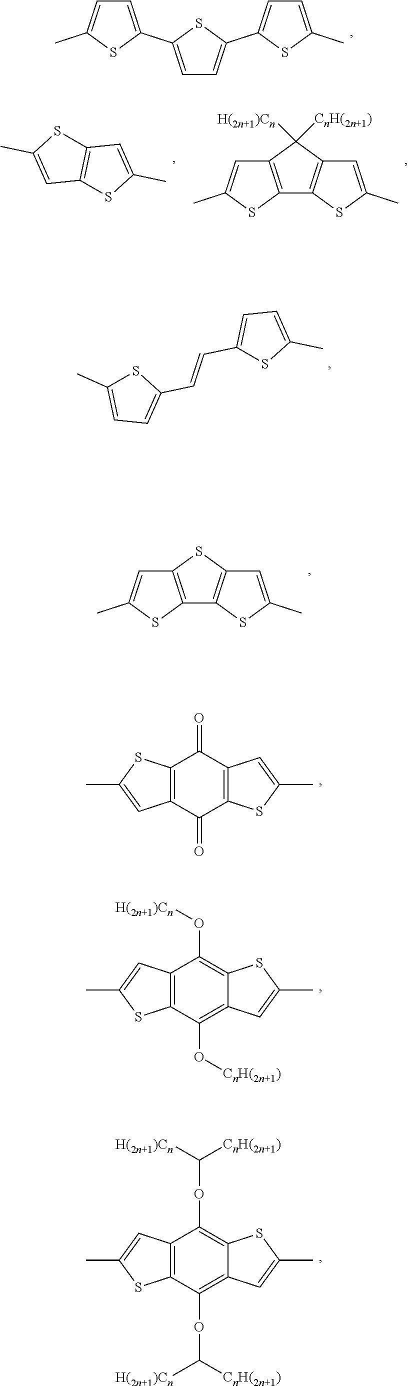 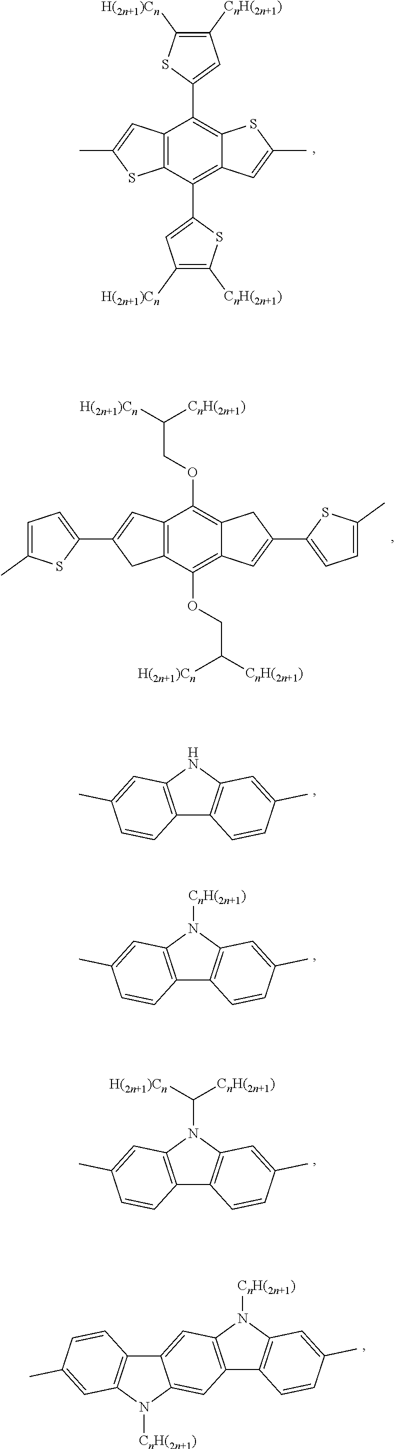 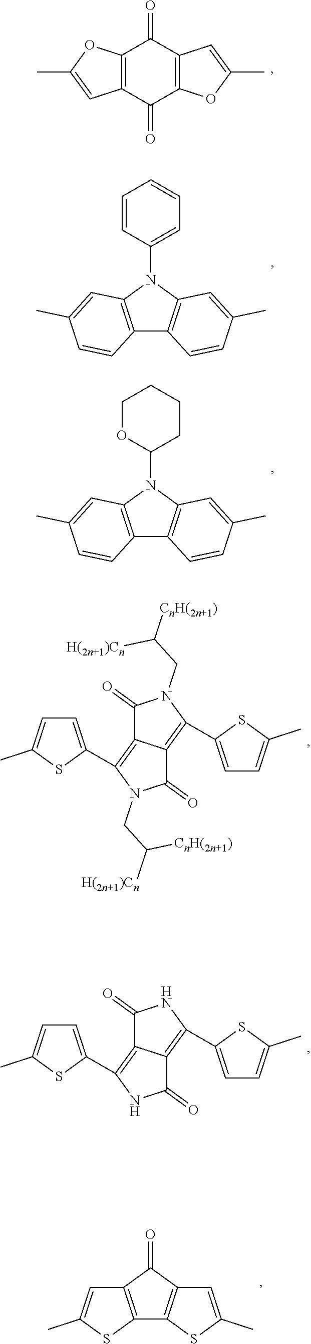 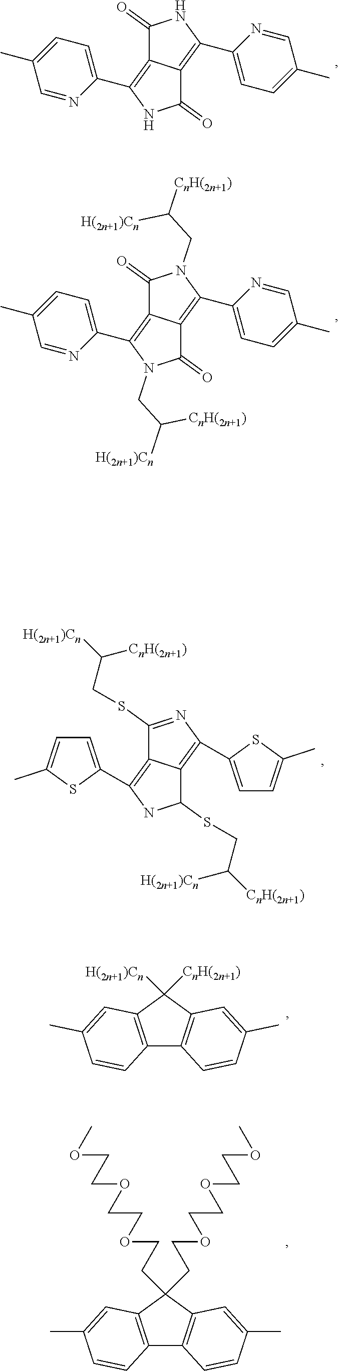 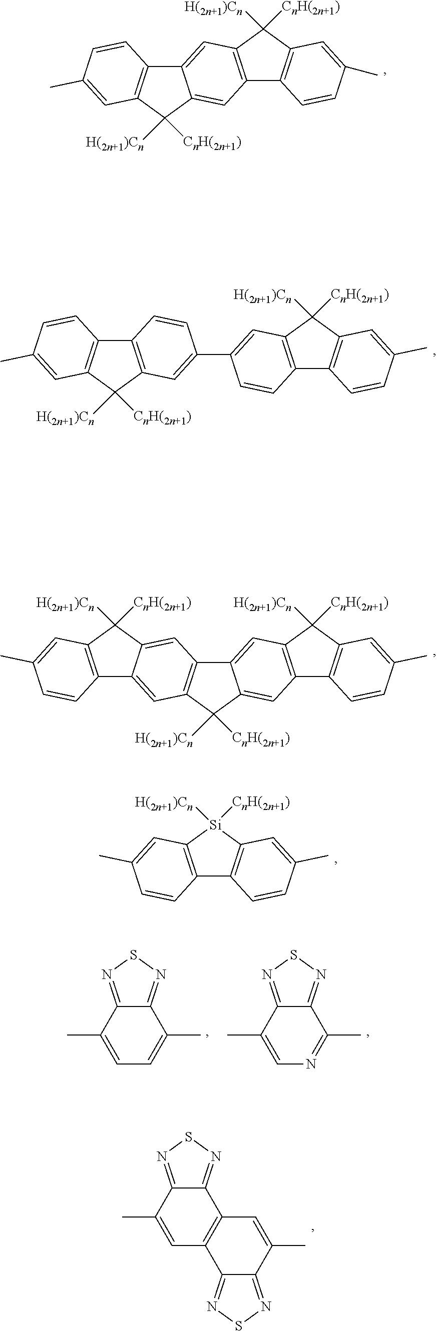 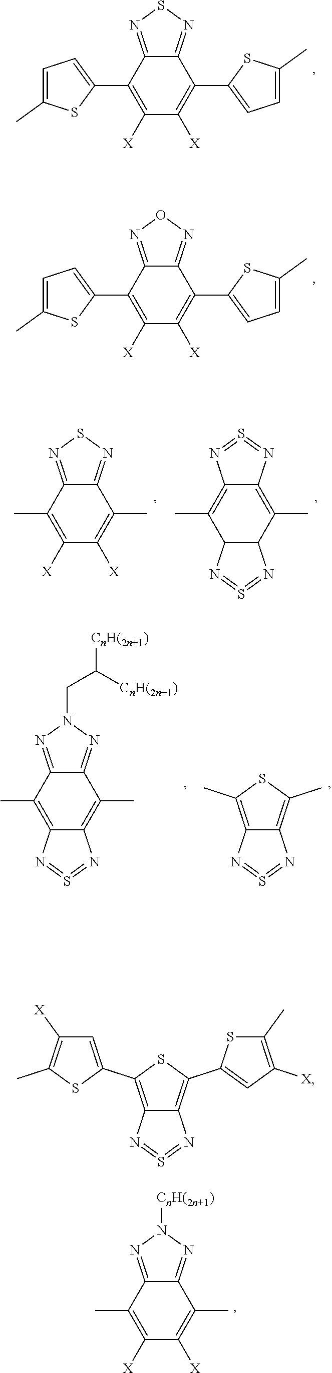 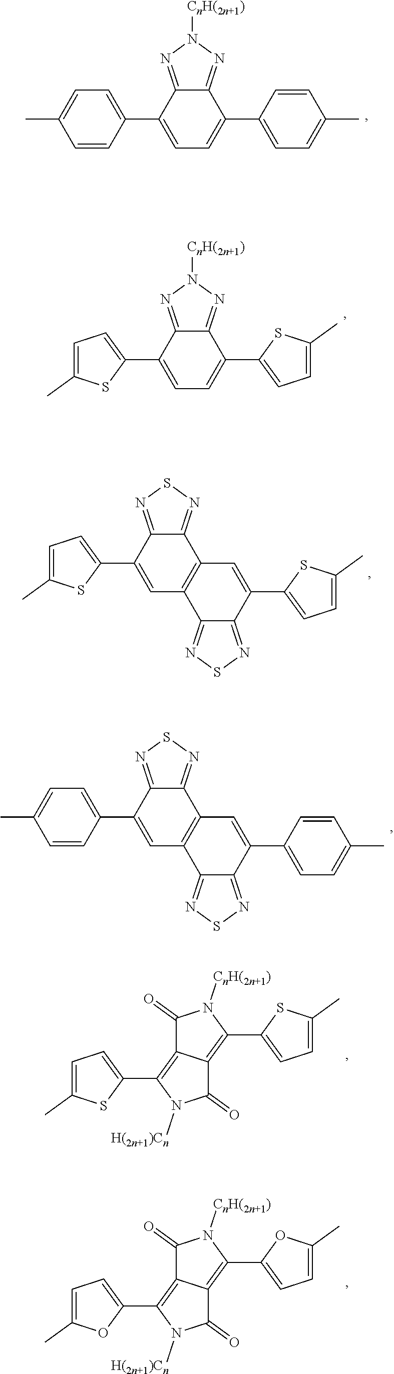 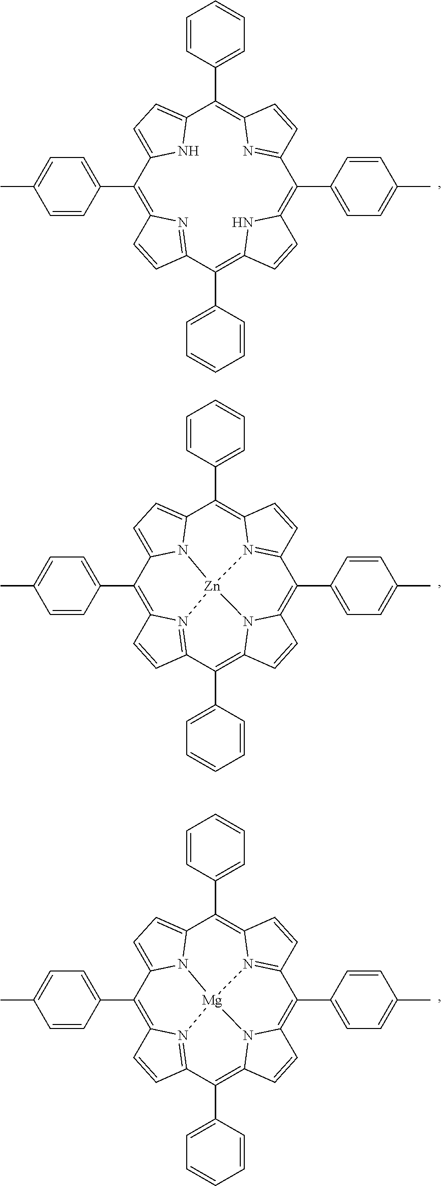 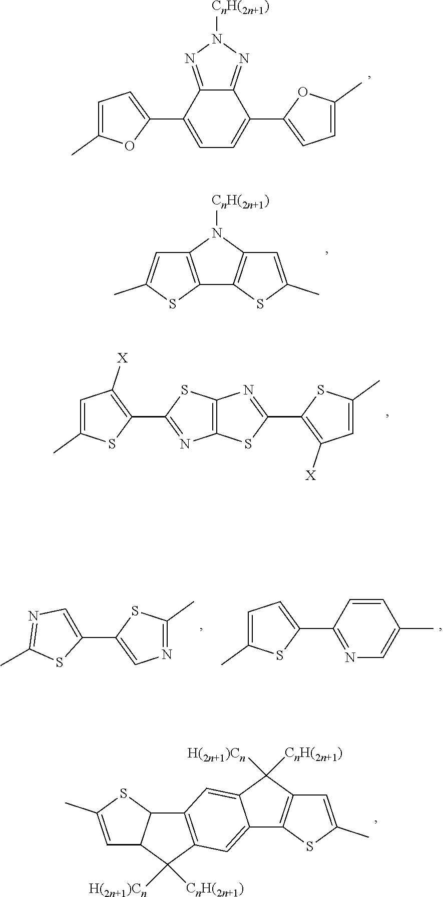 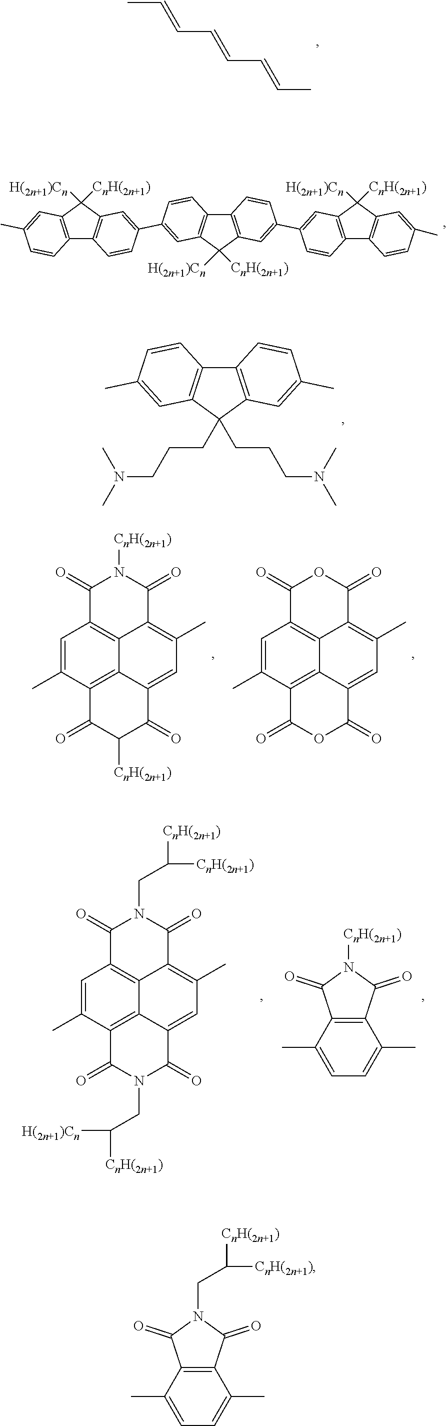 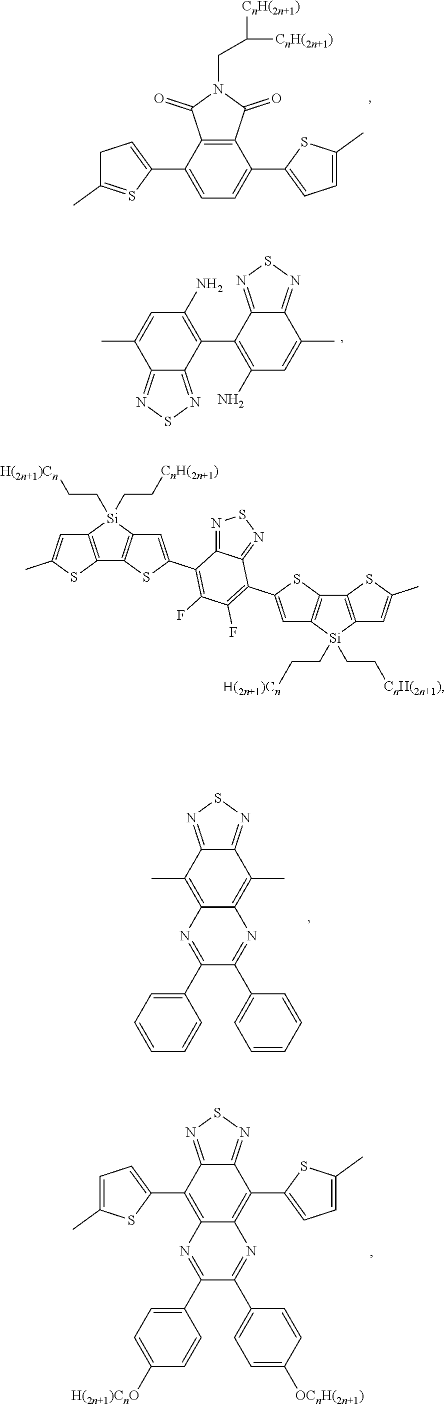 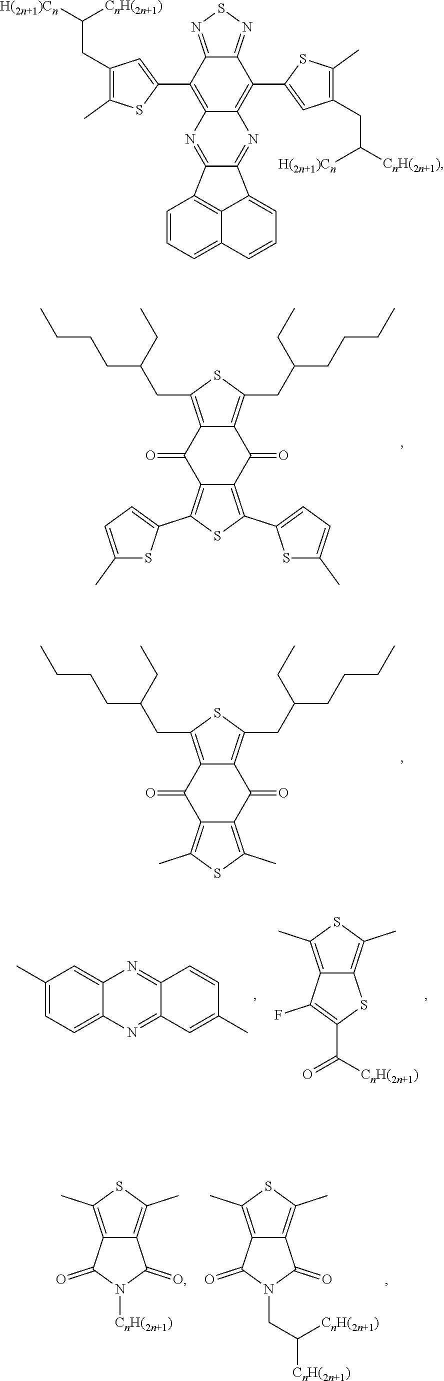 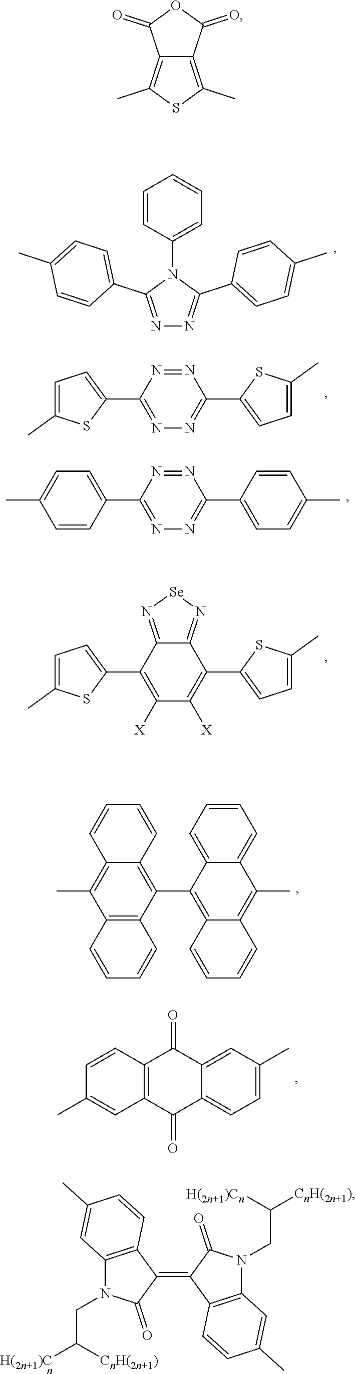 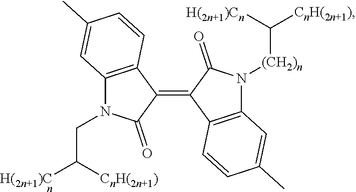 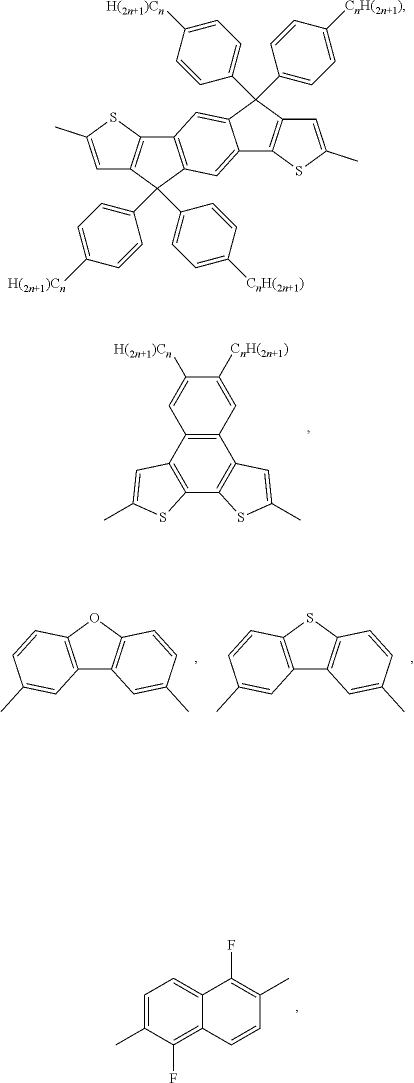 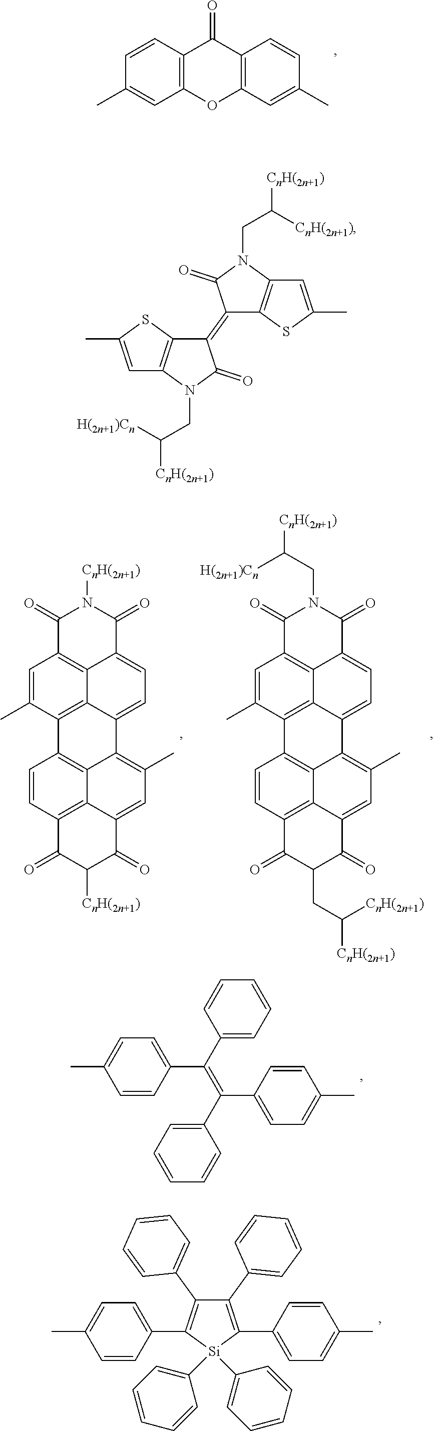 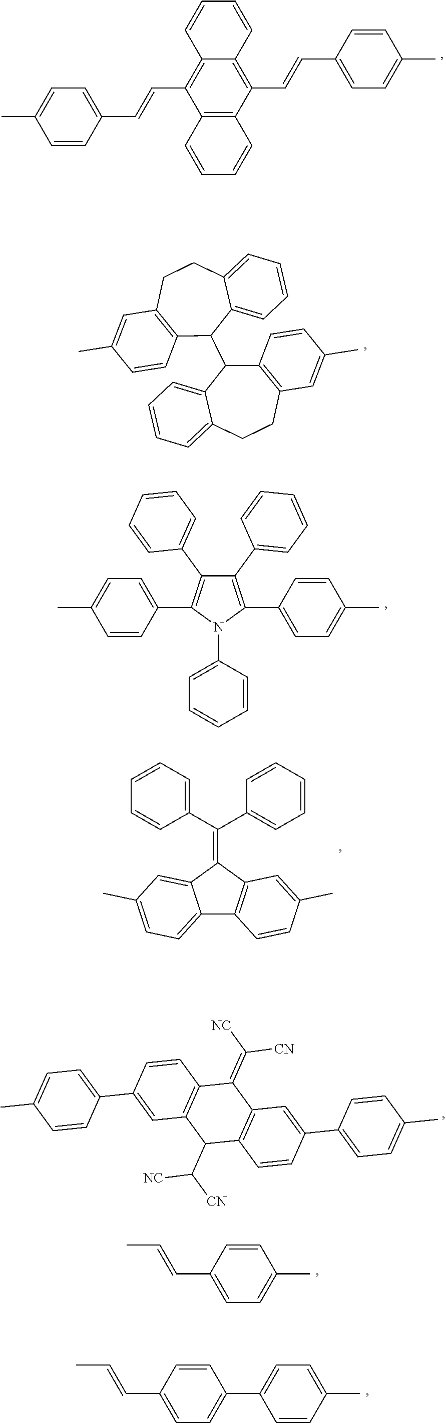 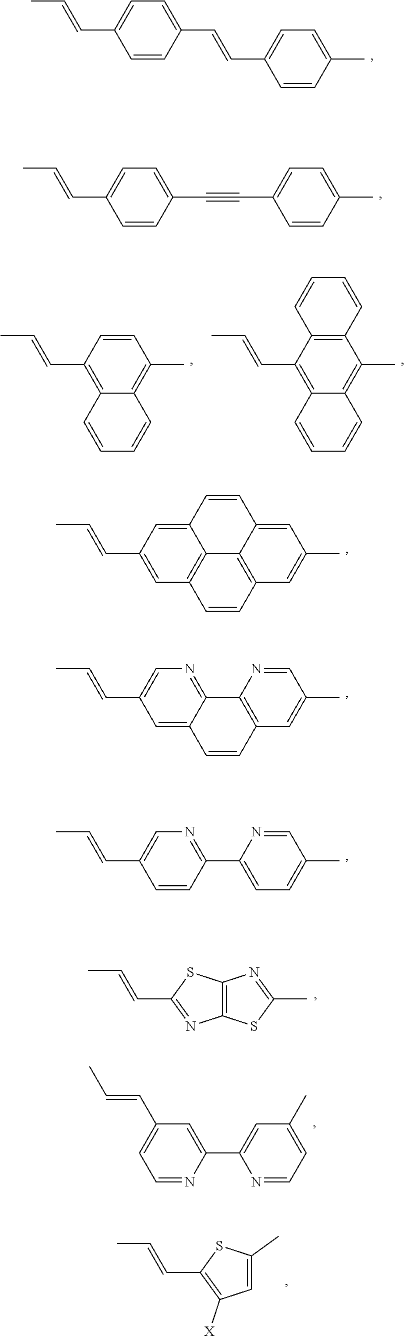 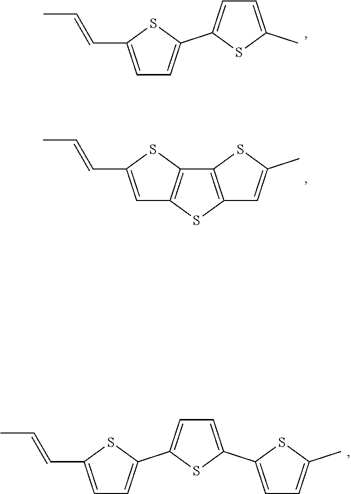 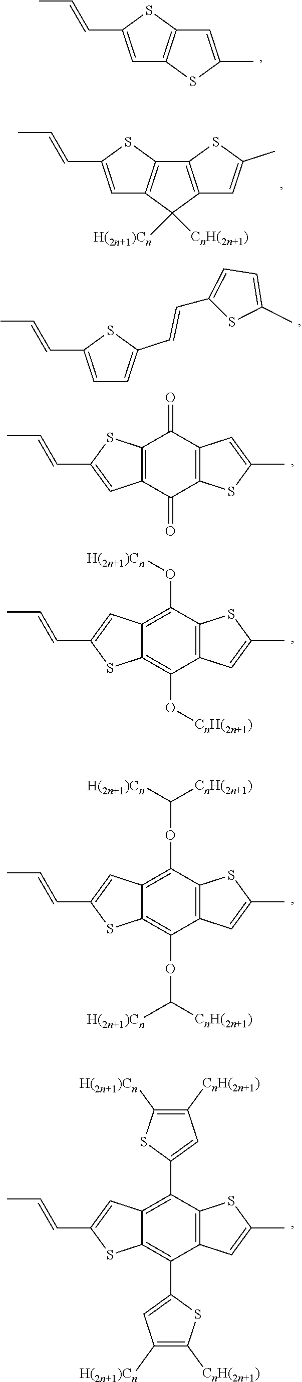 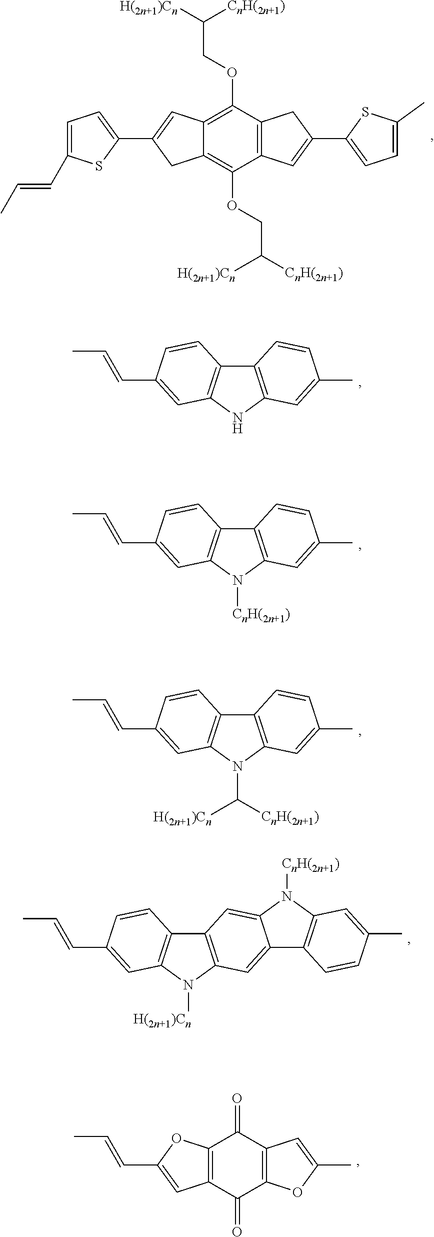 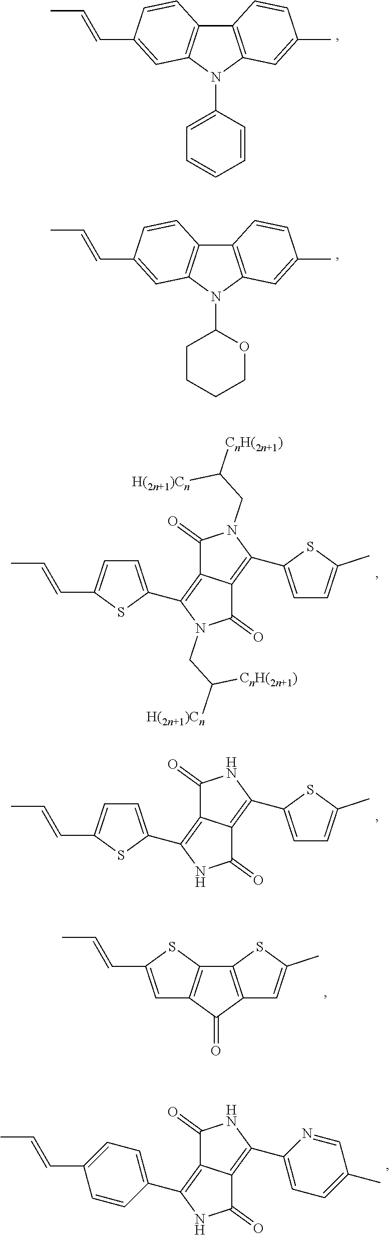 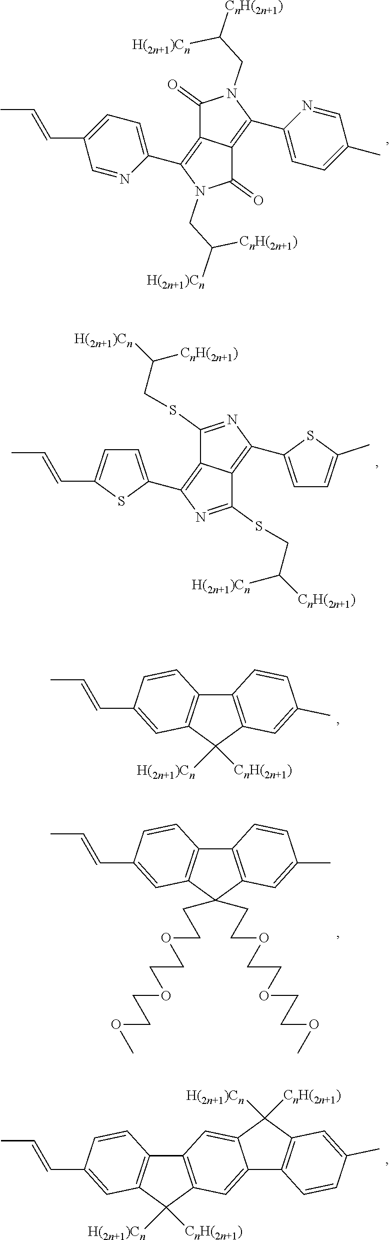 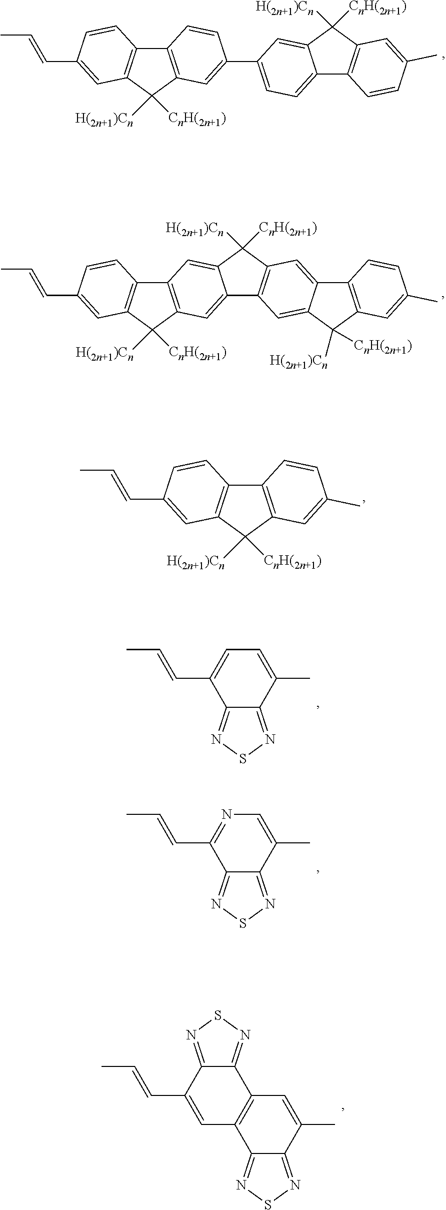 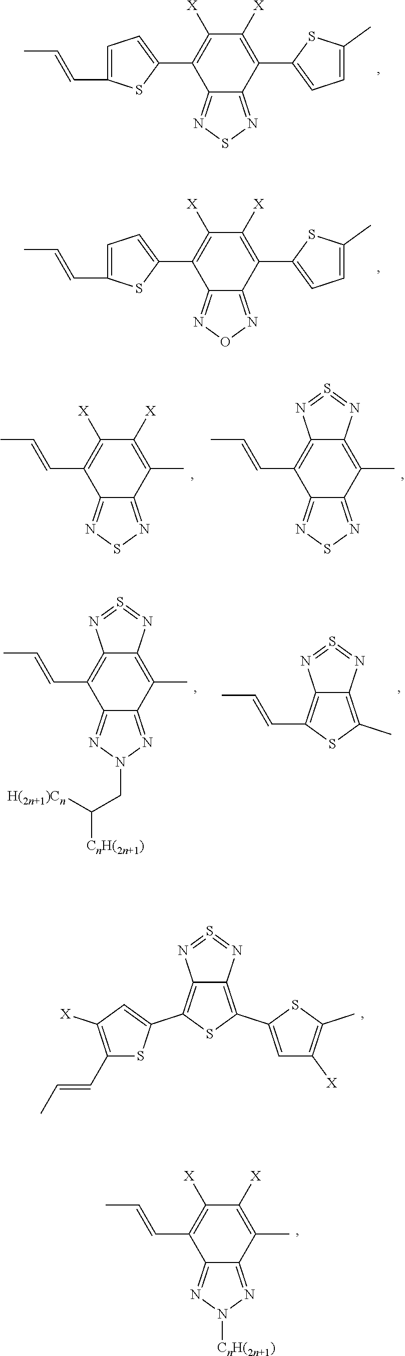 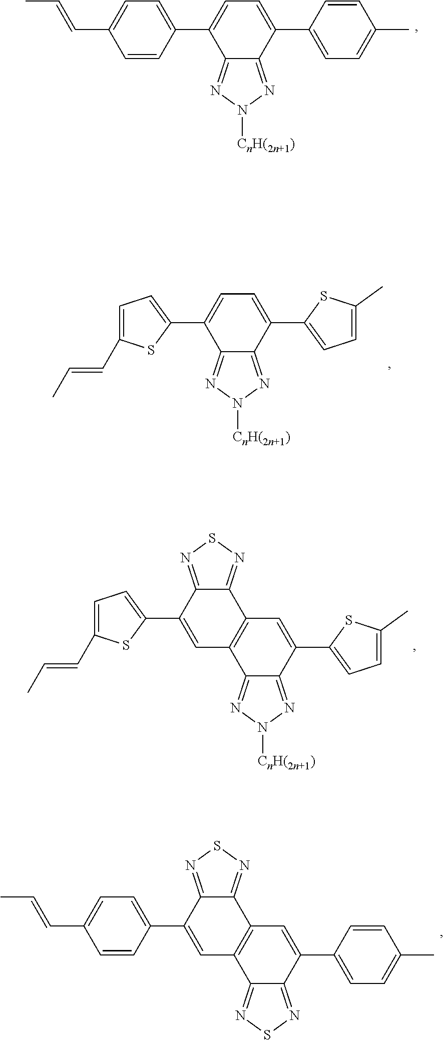 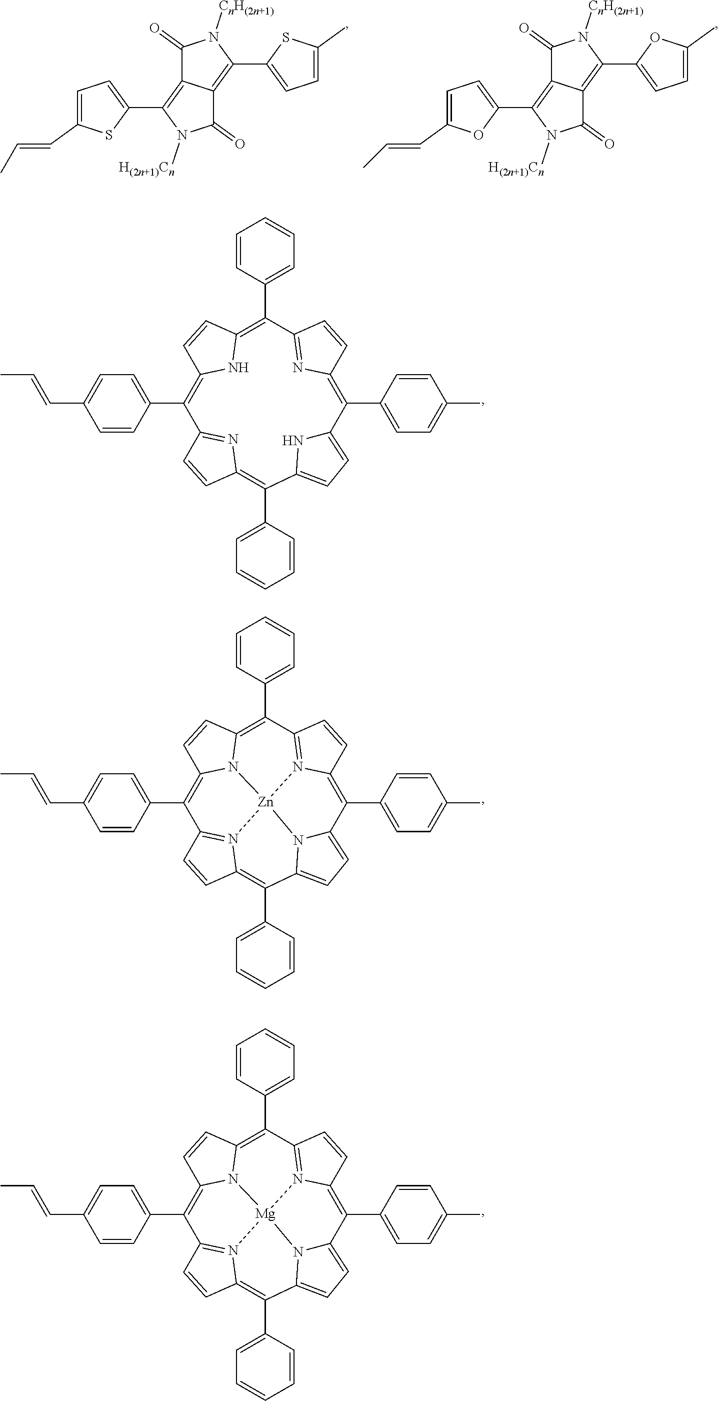 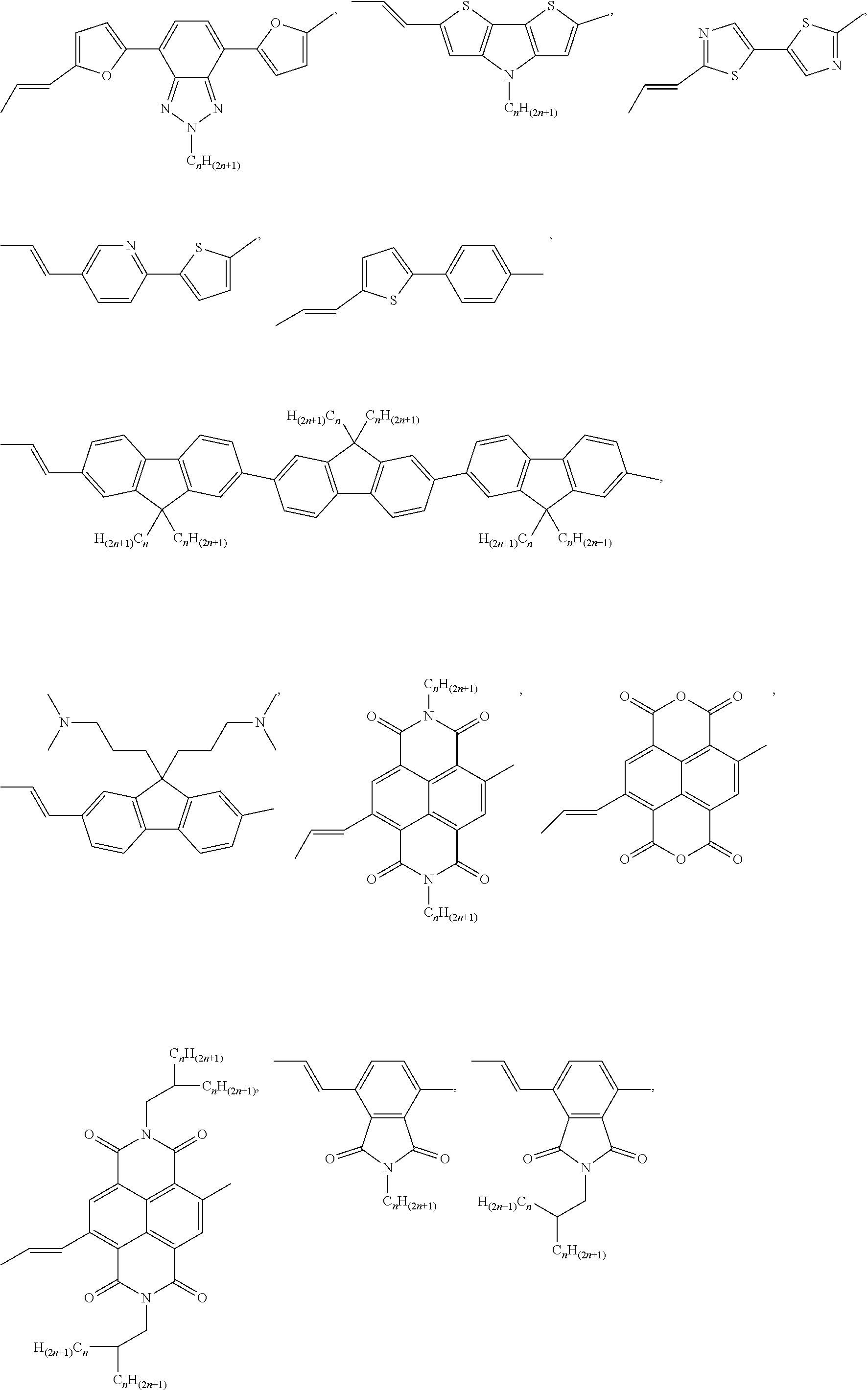 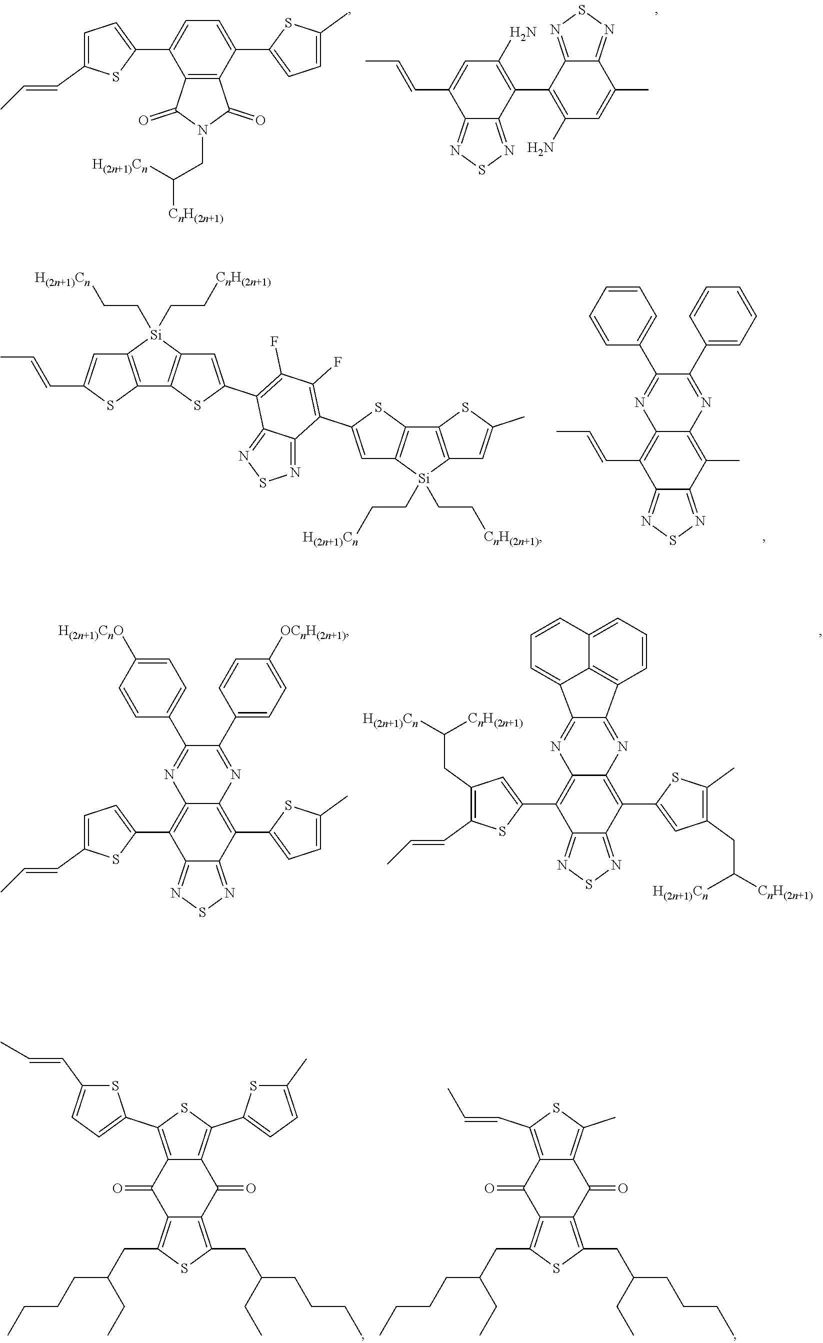 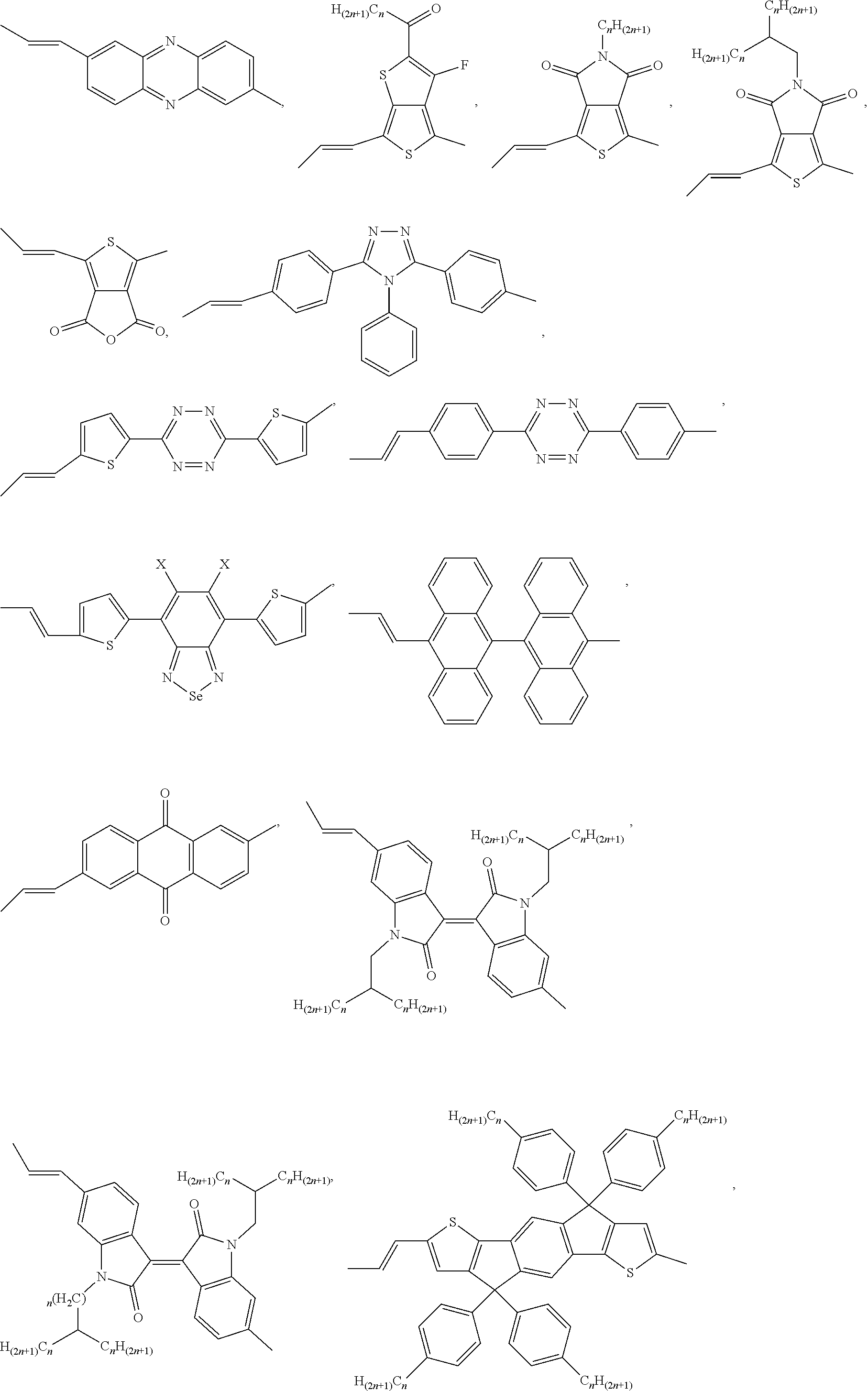 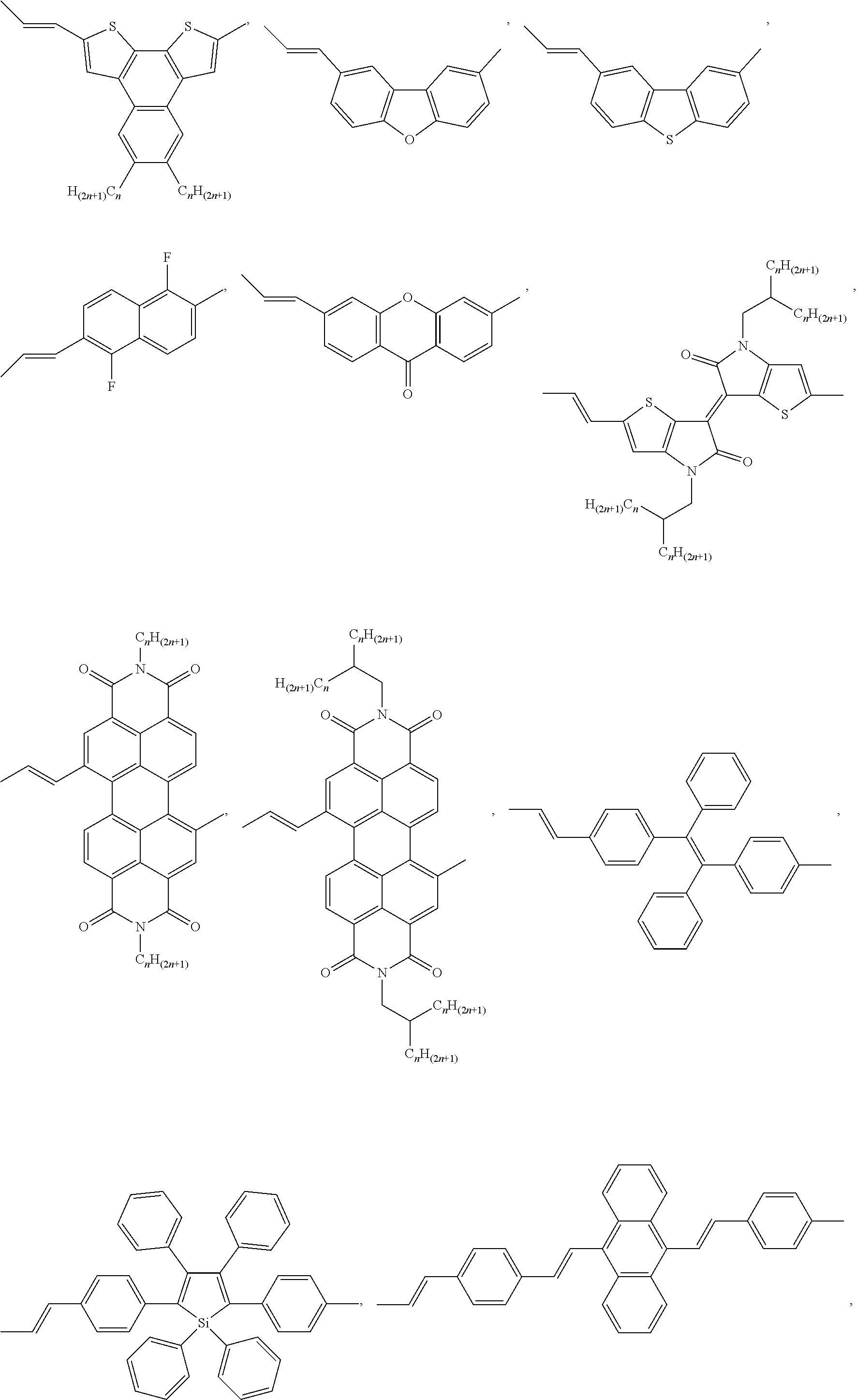 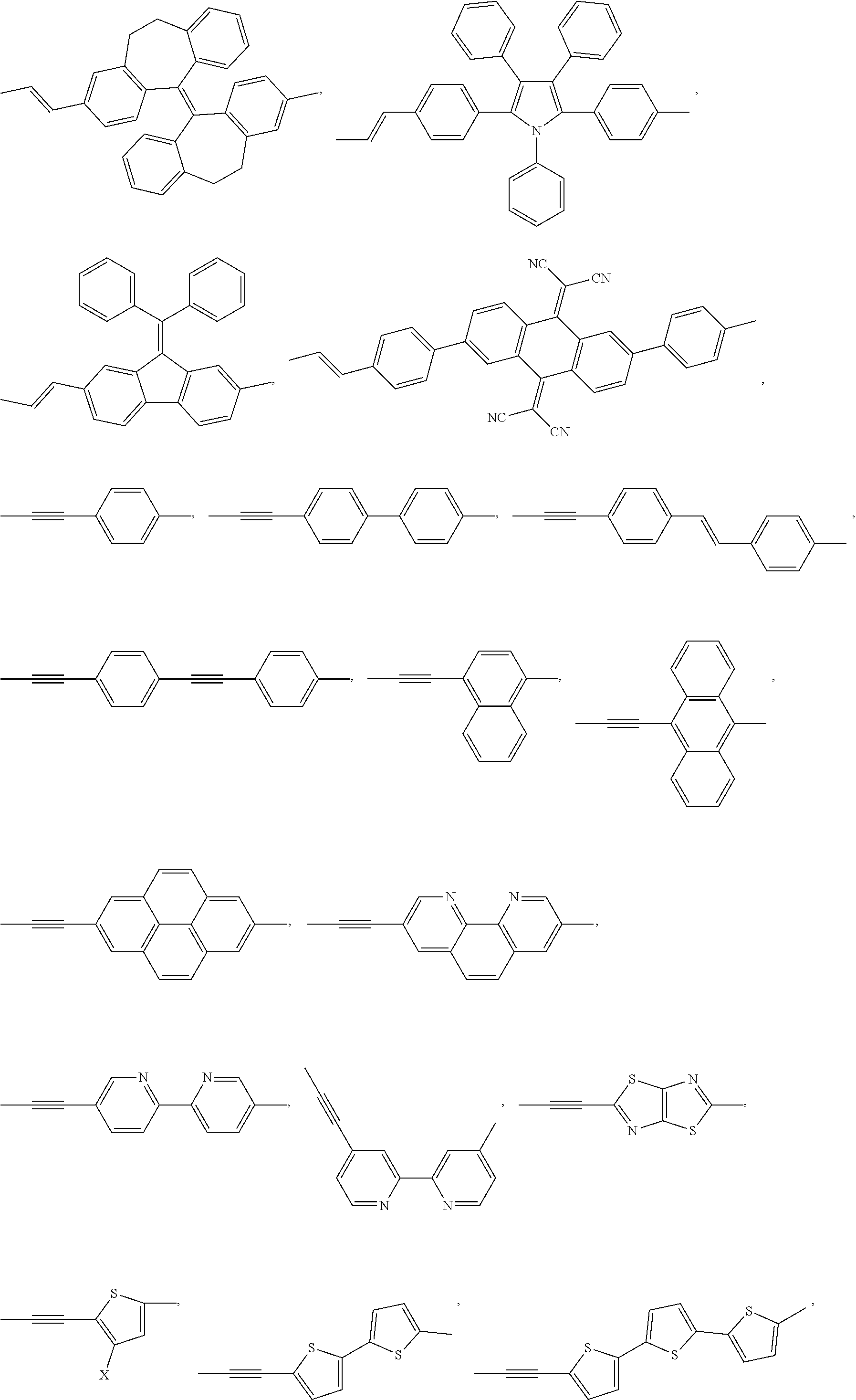 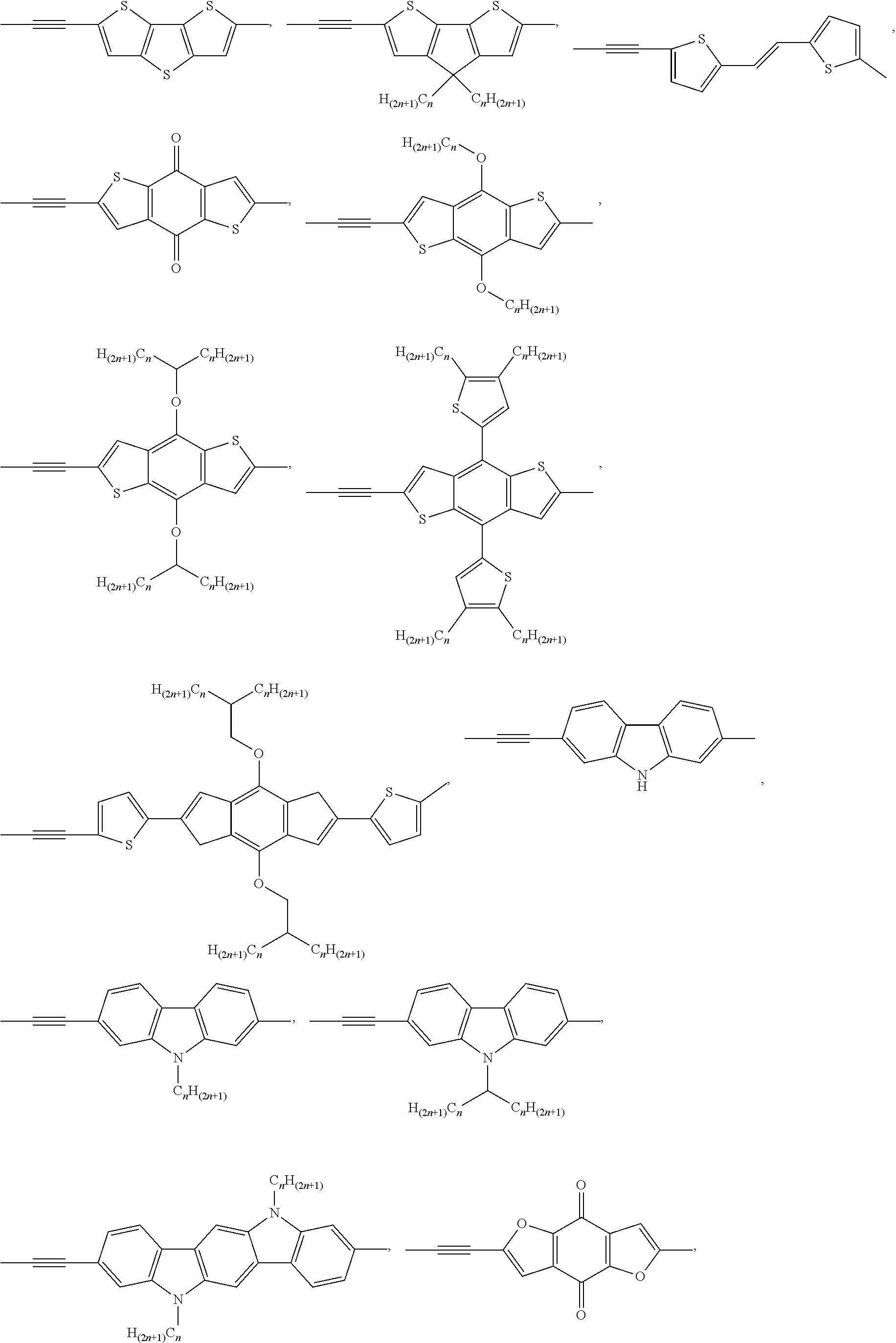 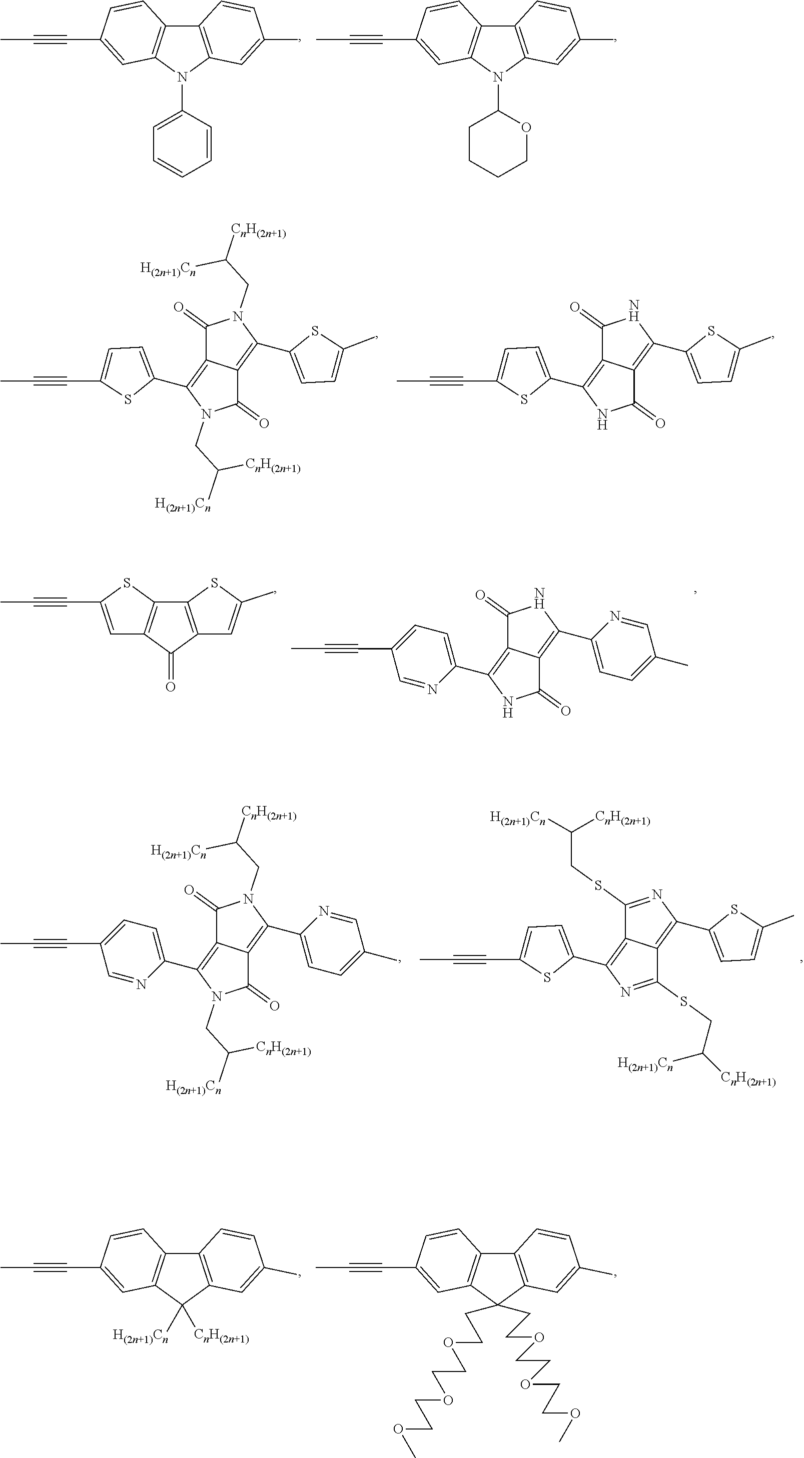 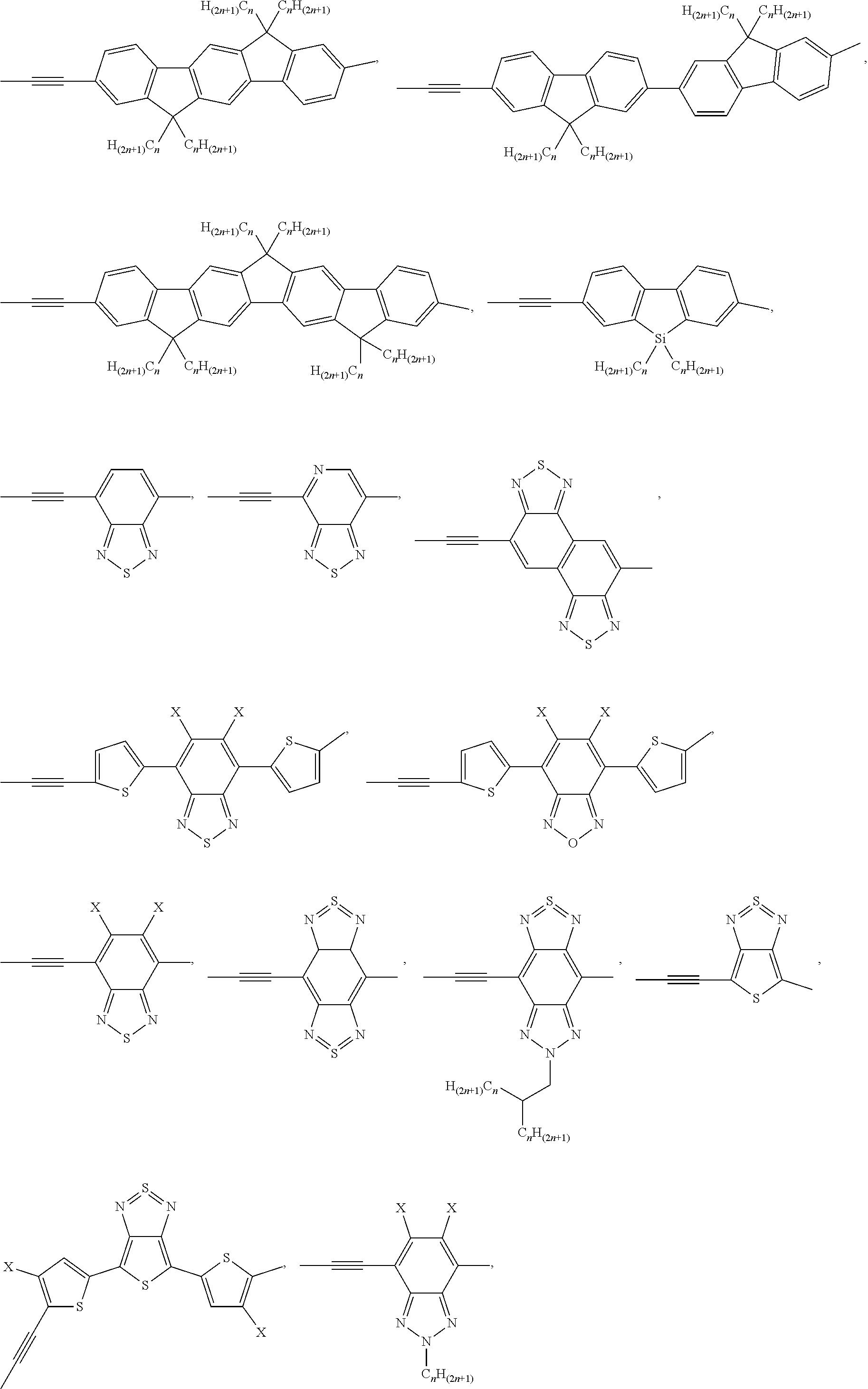 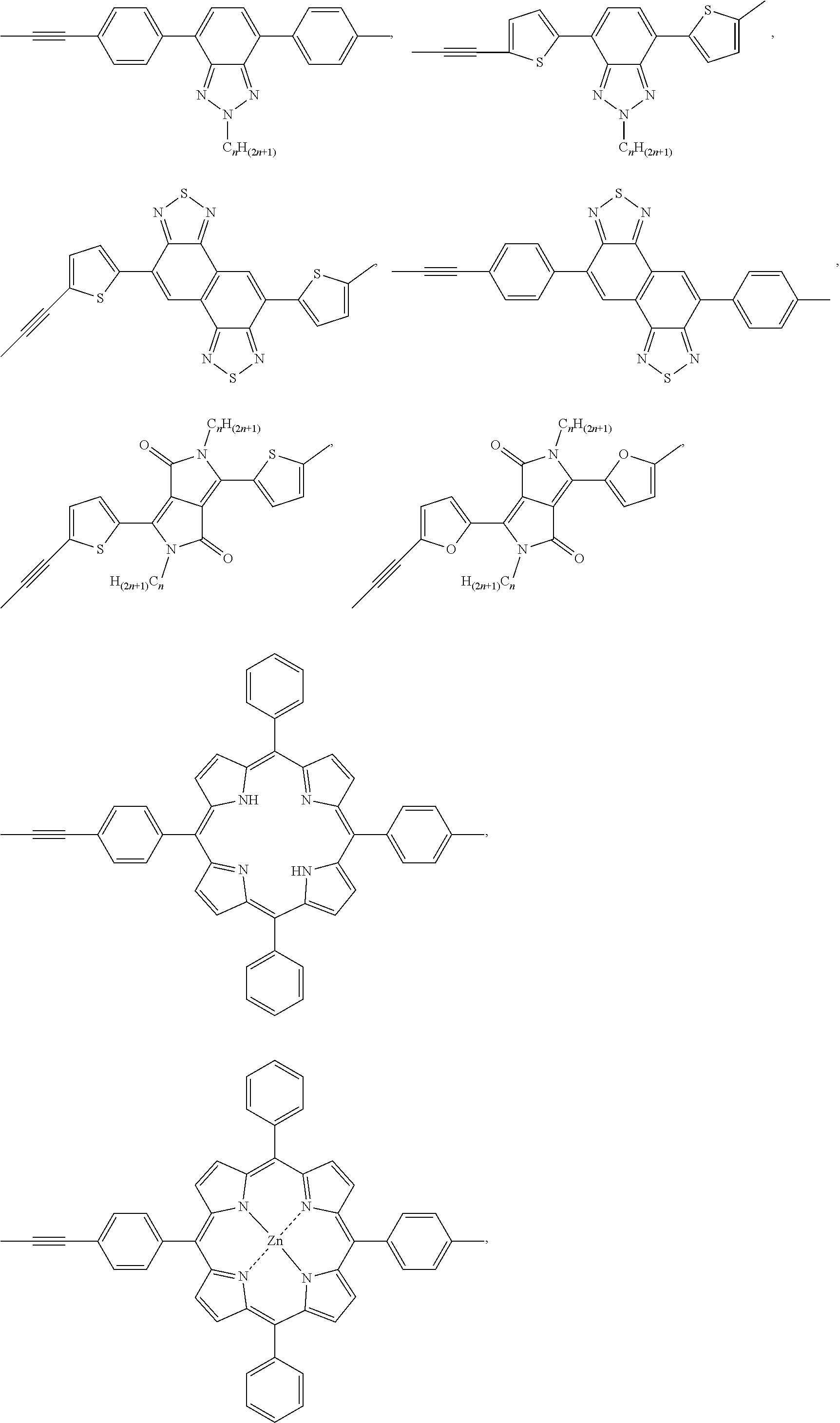 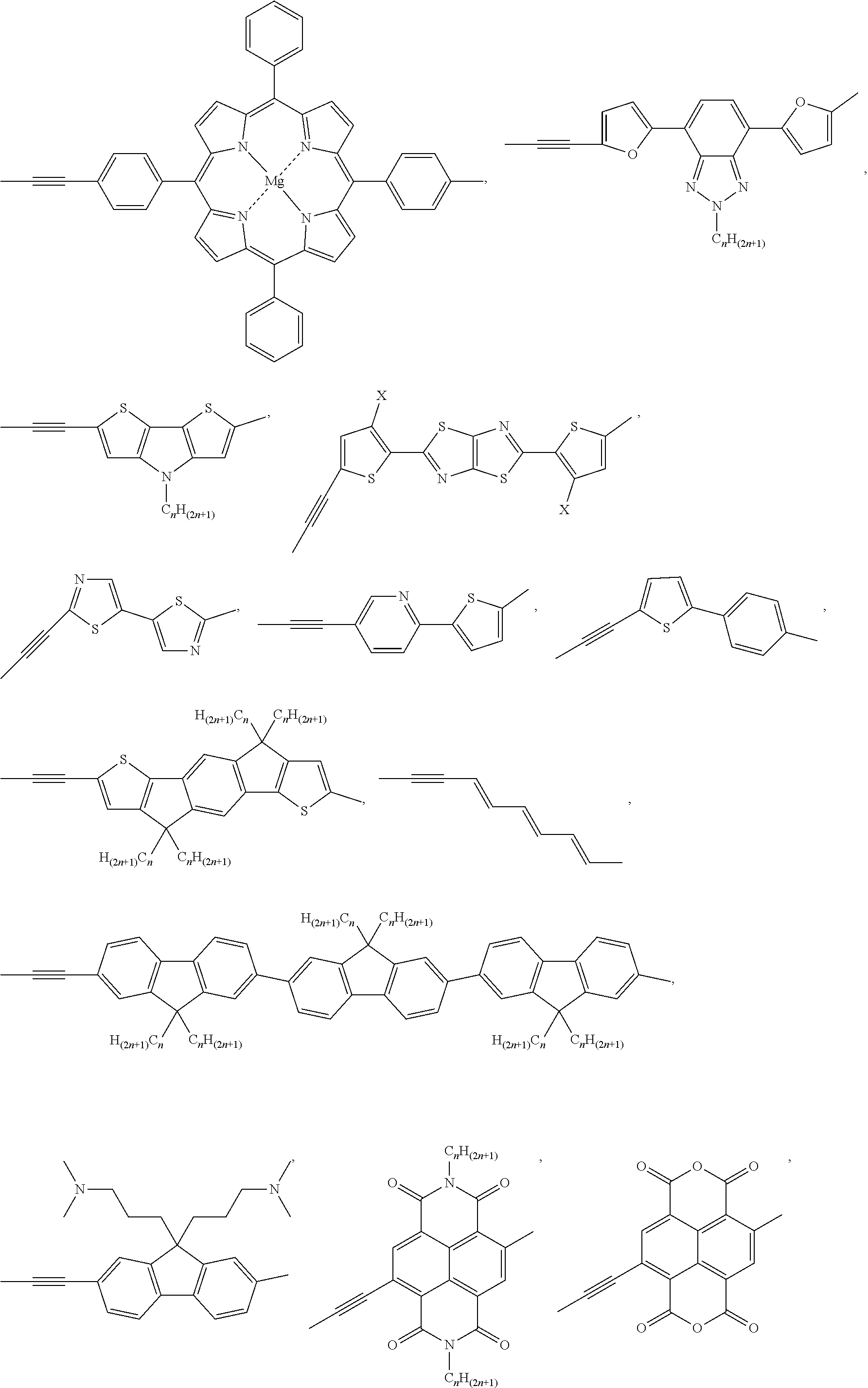 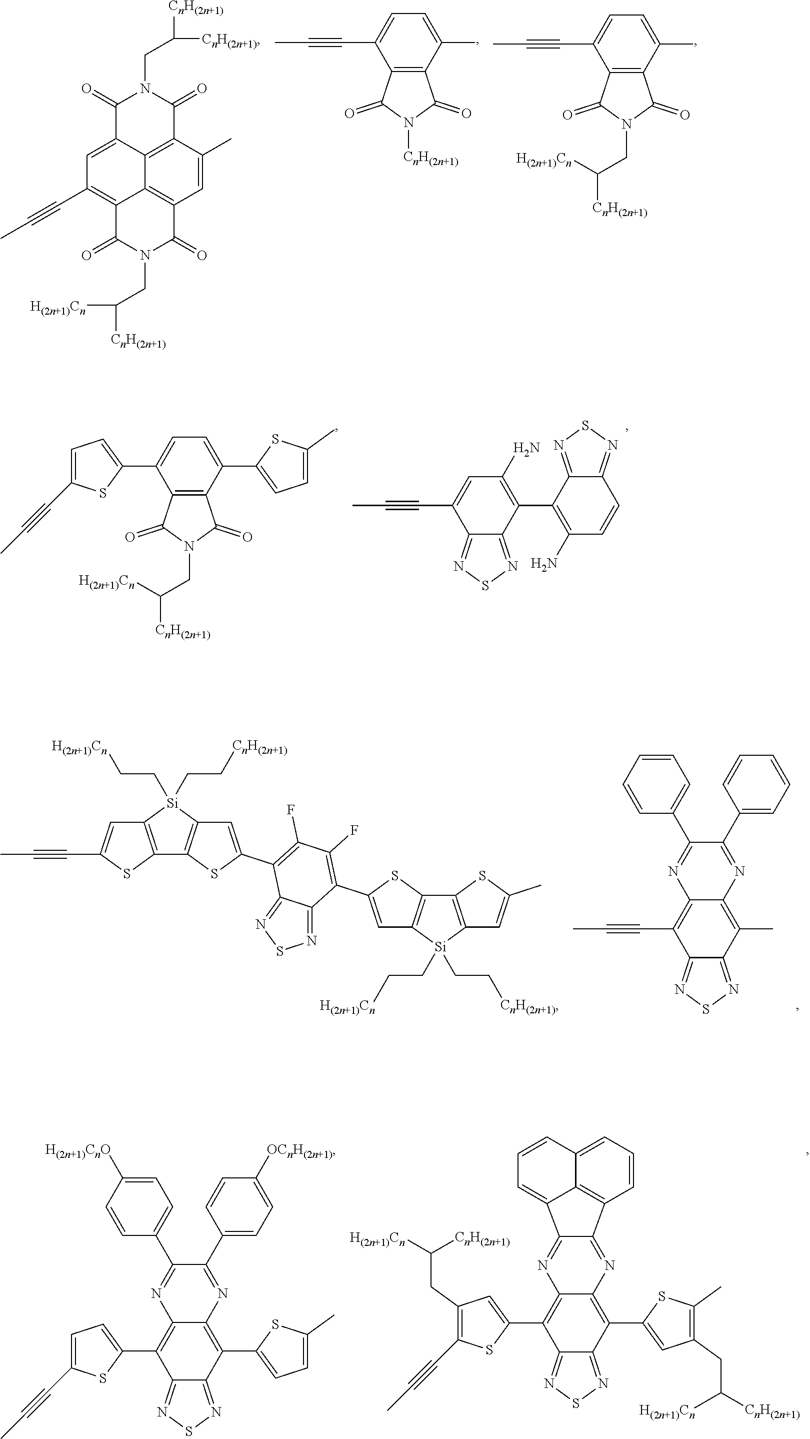 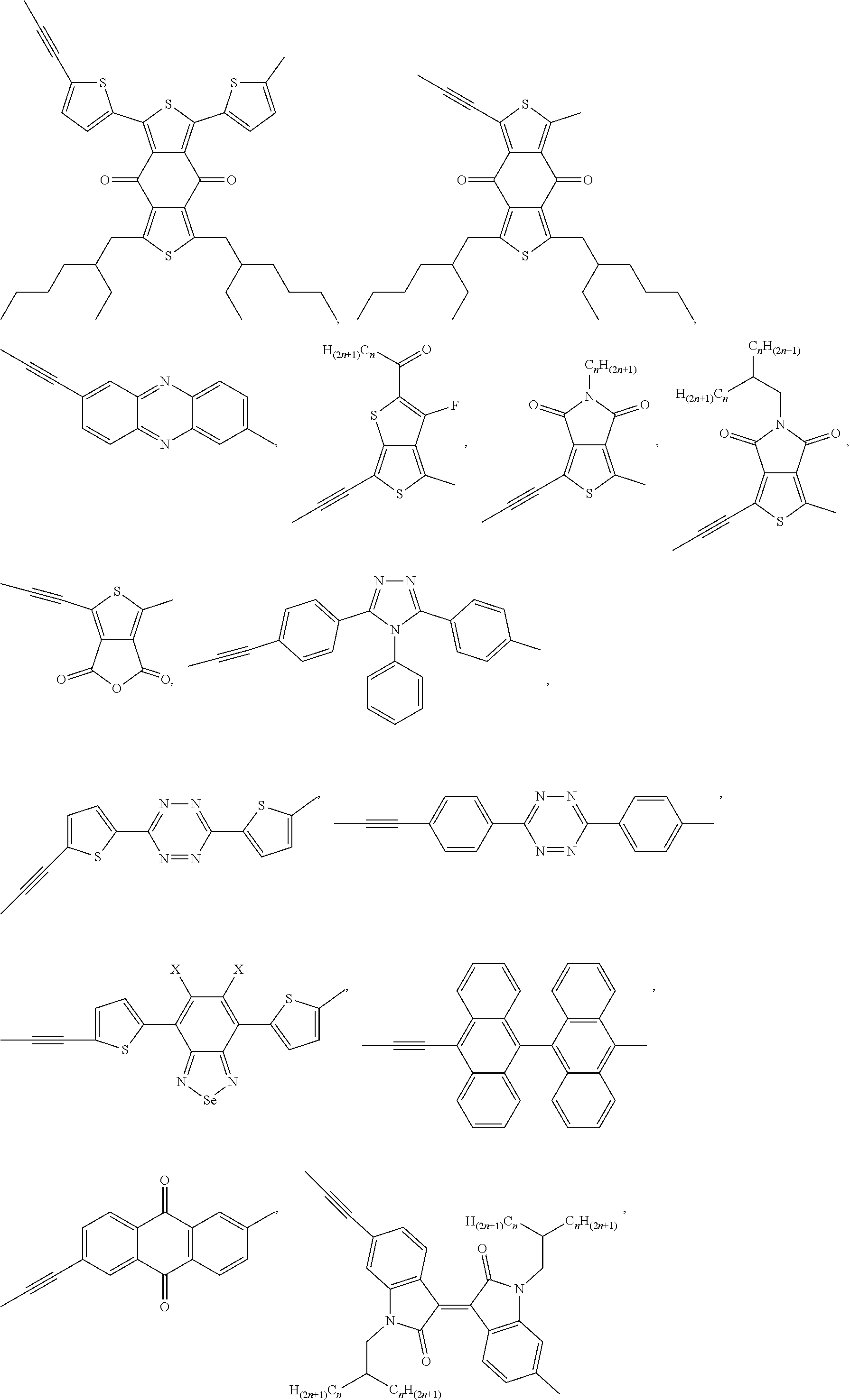 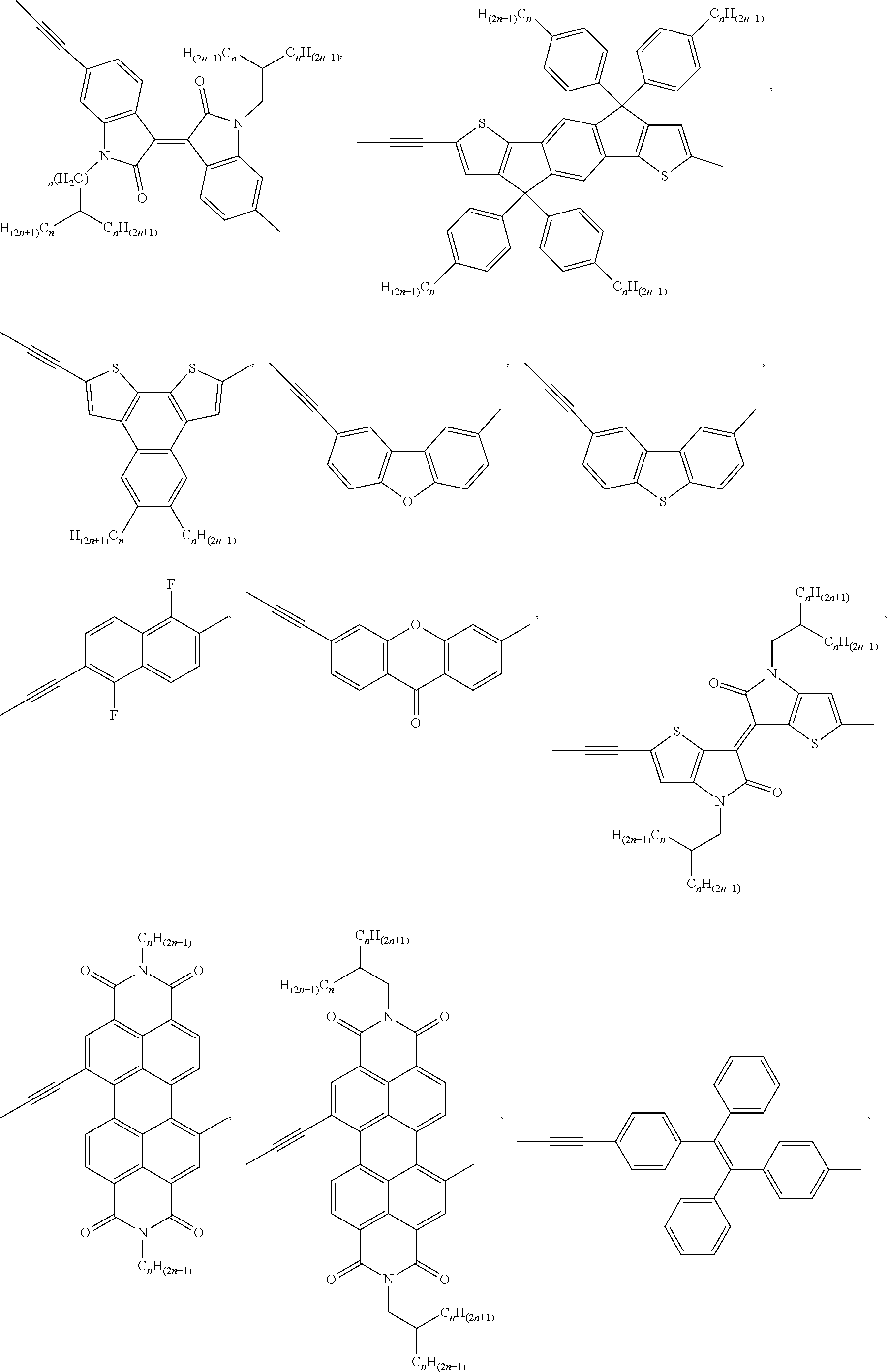 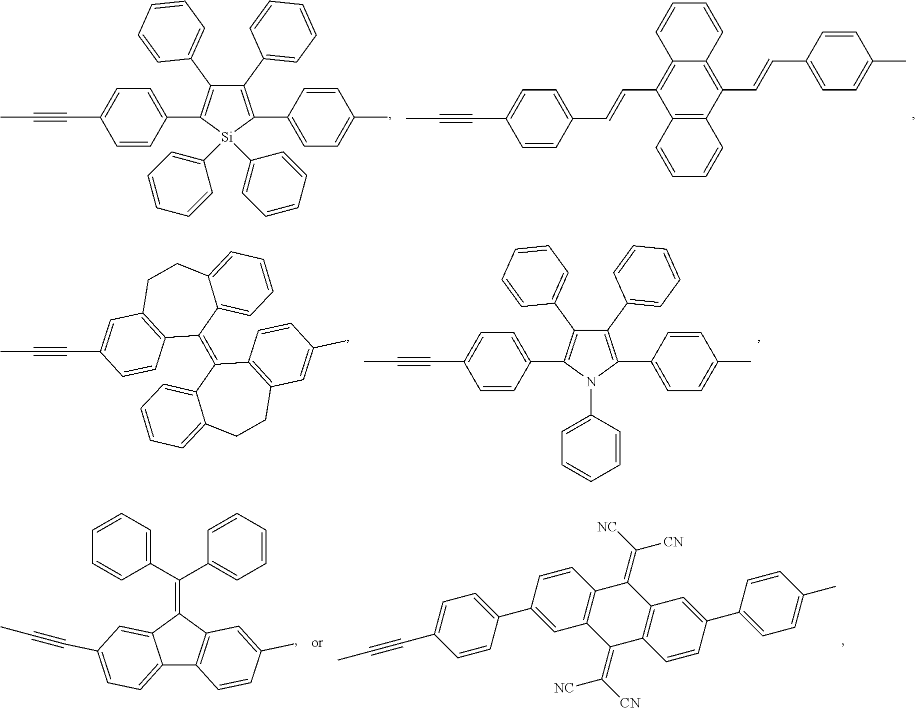
wherein n is an integer between 0 and 30, and X is hydrogen, fluorine, amino, nitro, or alkoxy with 1-32 carbon atoms.

7. The osmium-containing conjugated polymer according to claim 1, wherein the osmium-containing conjugated polymer is at least one of 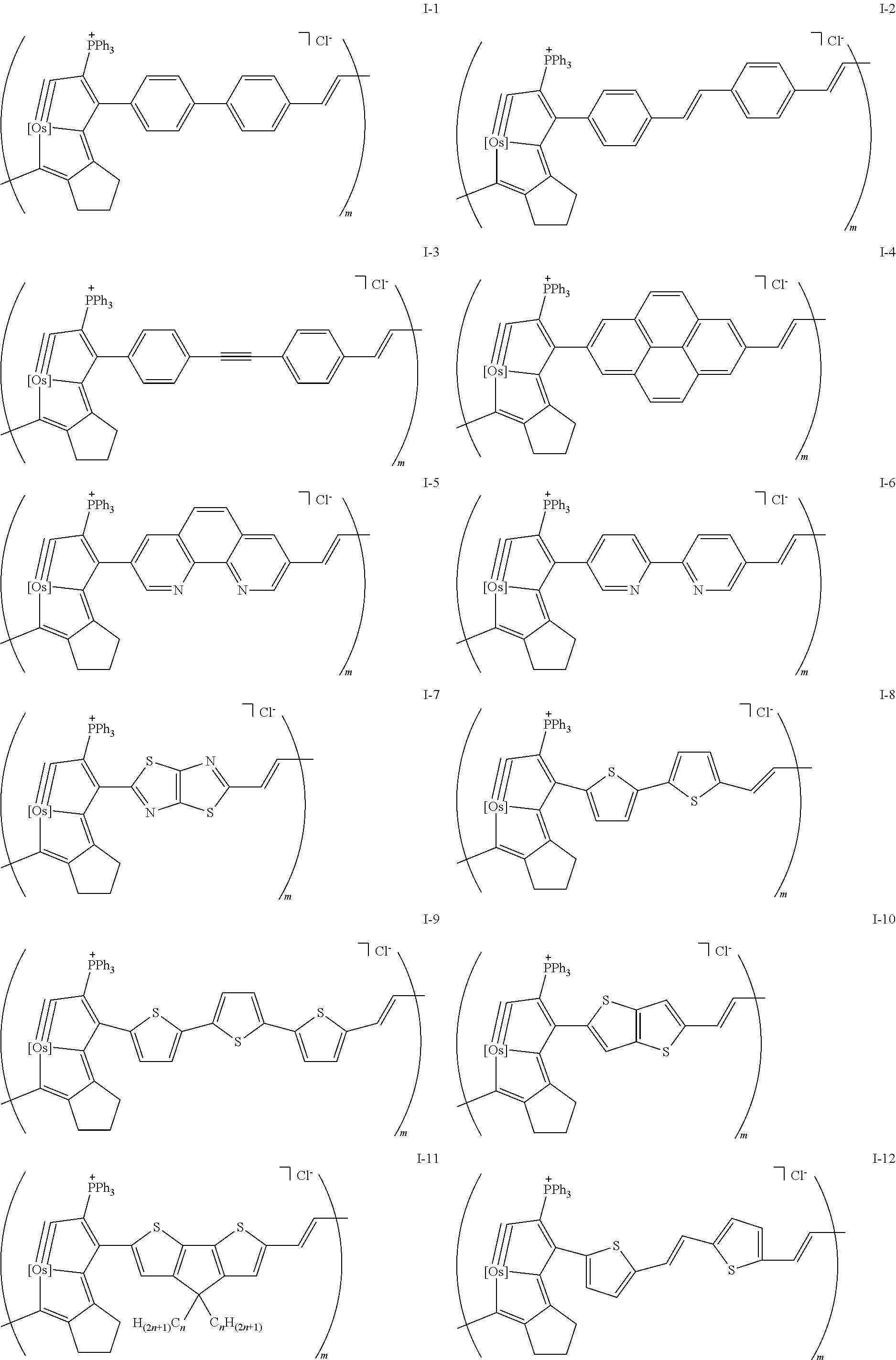 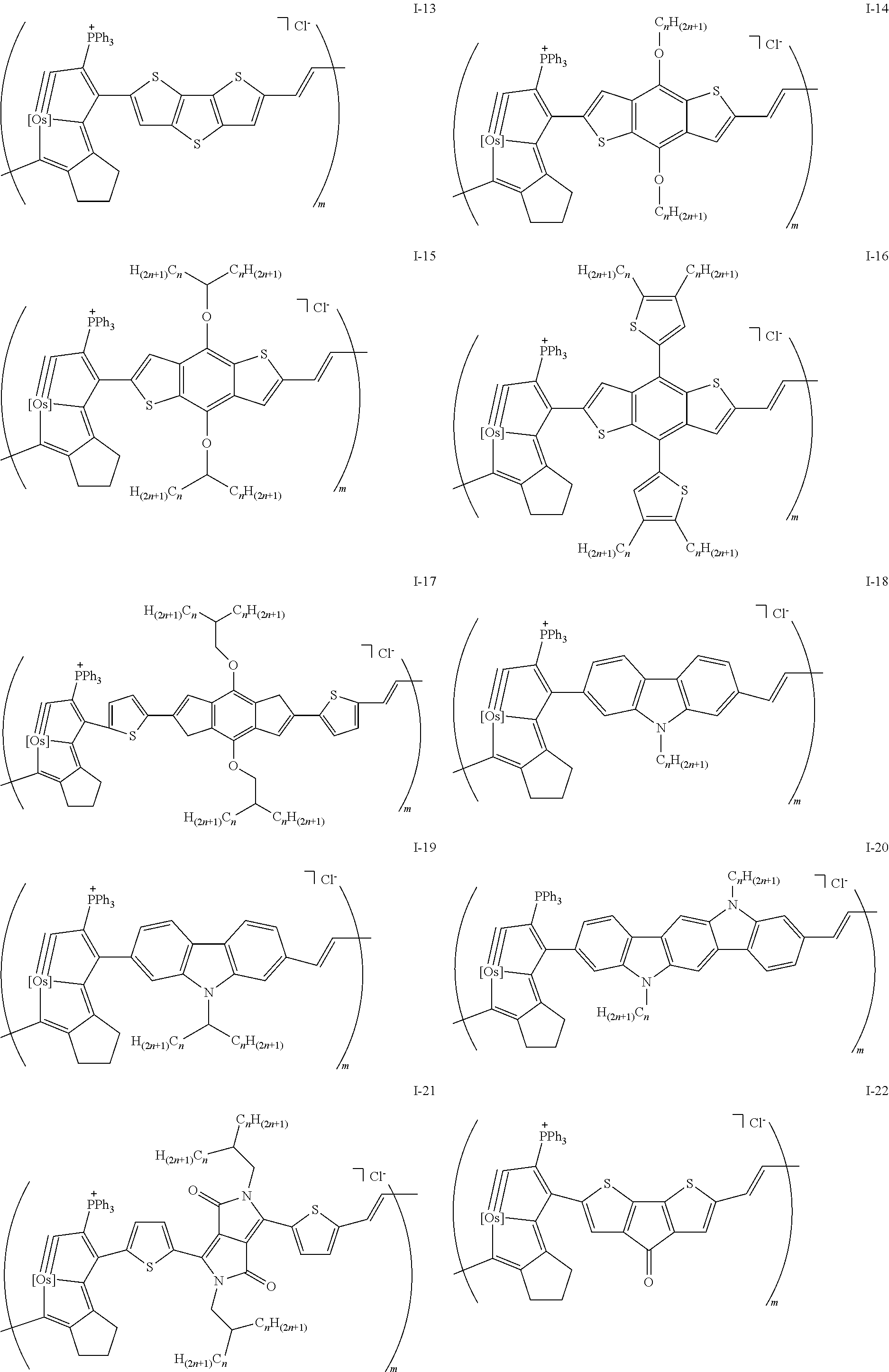 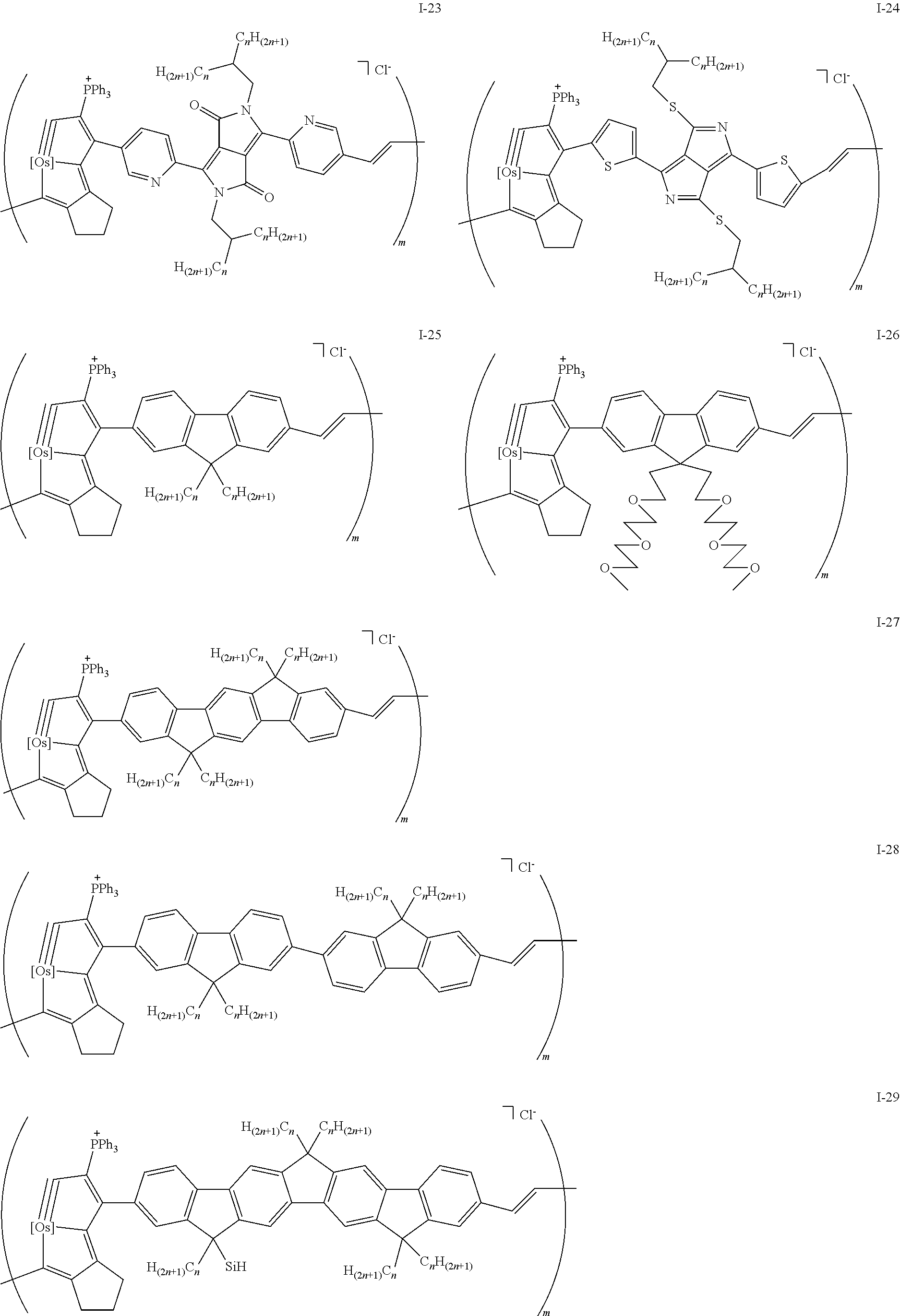 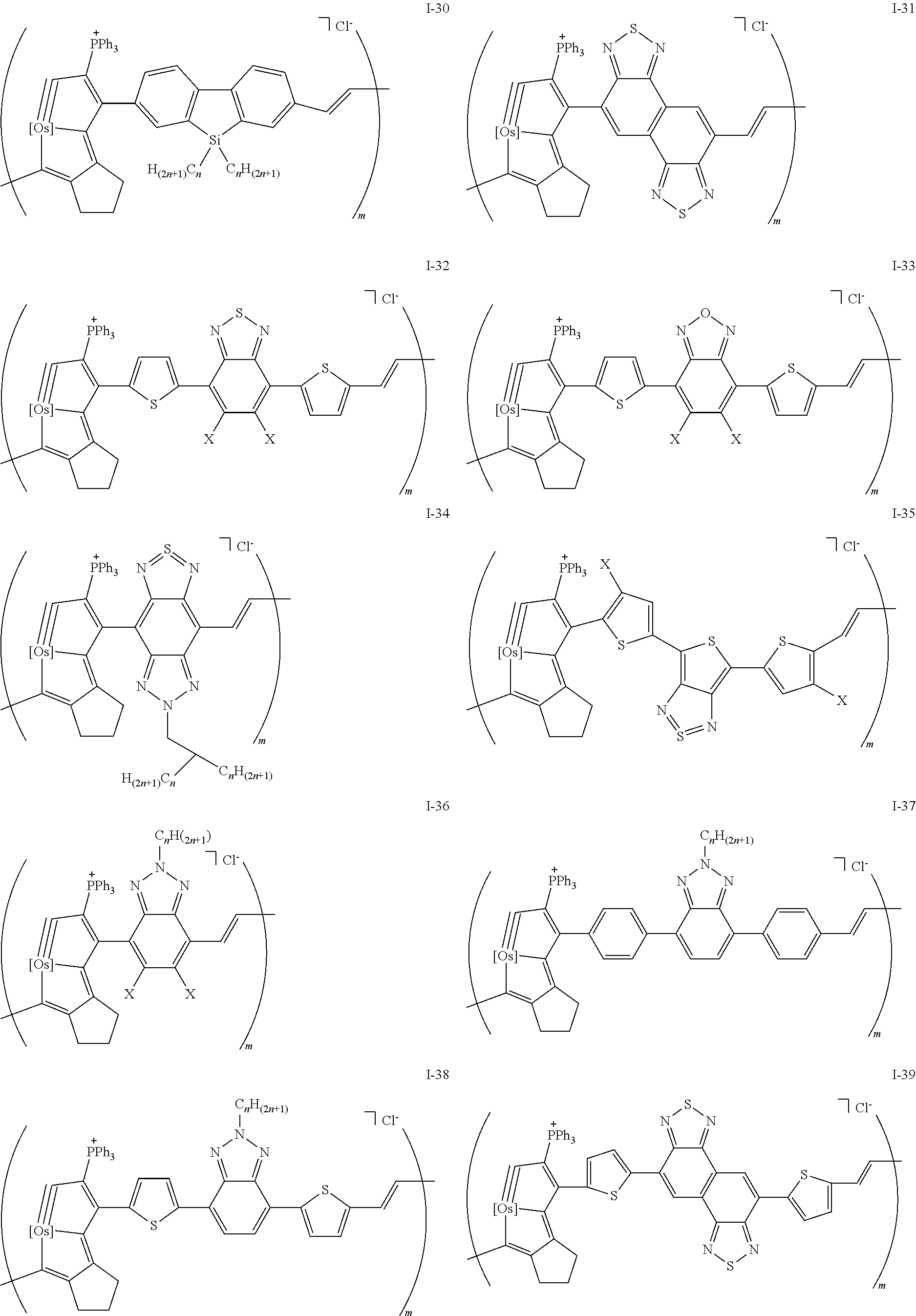 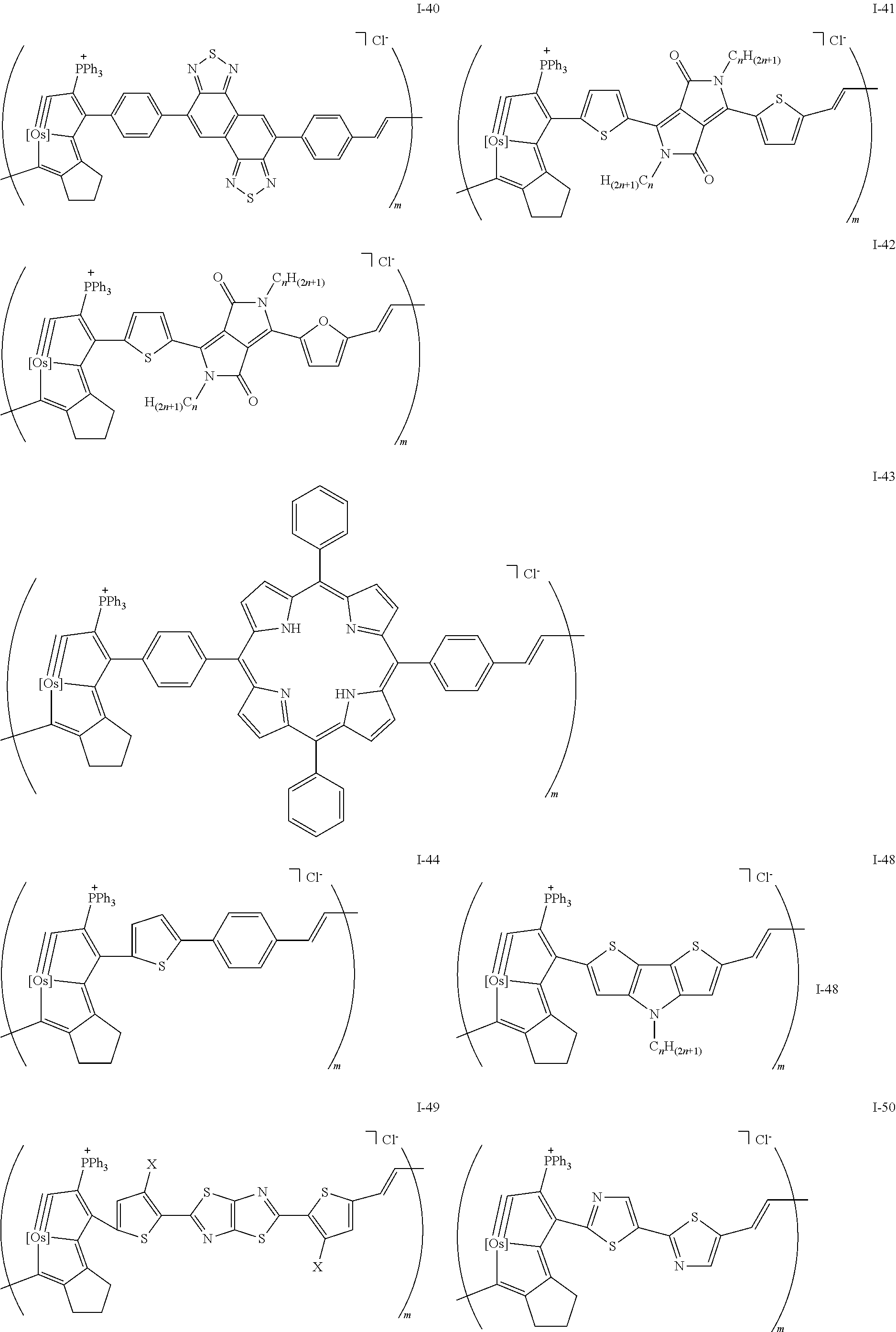 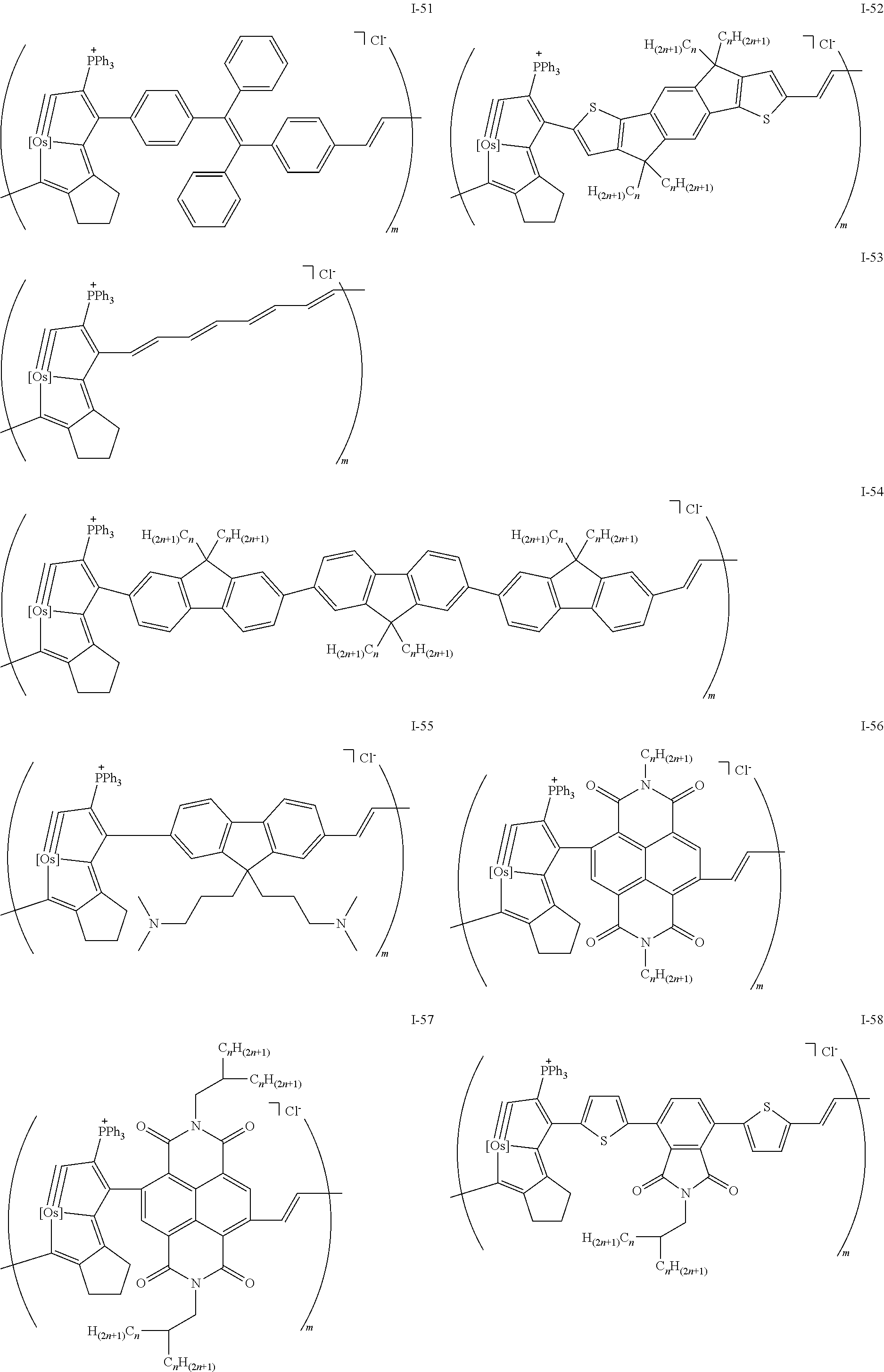 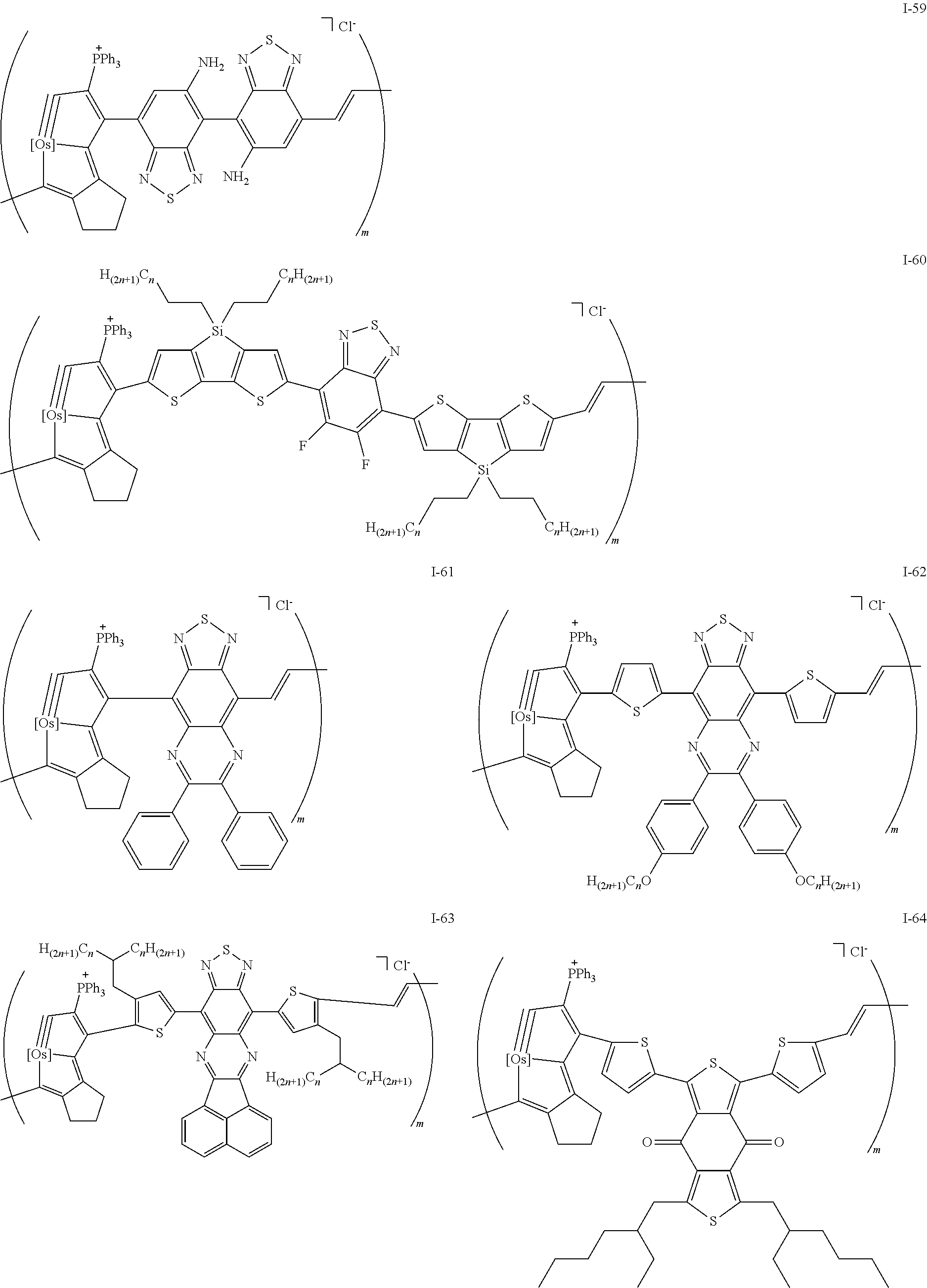 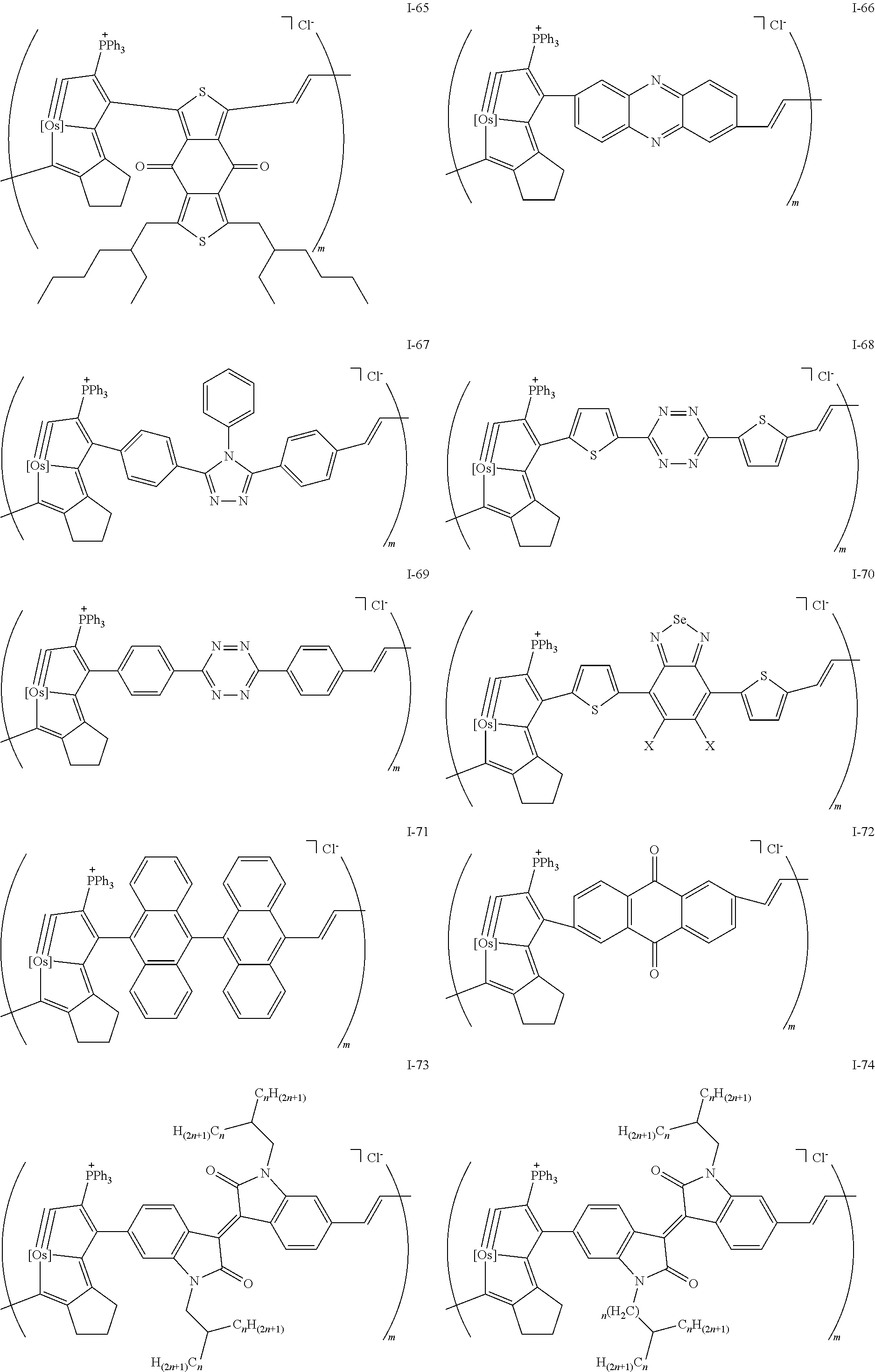 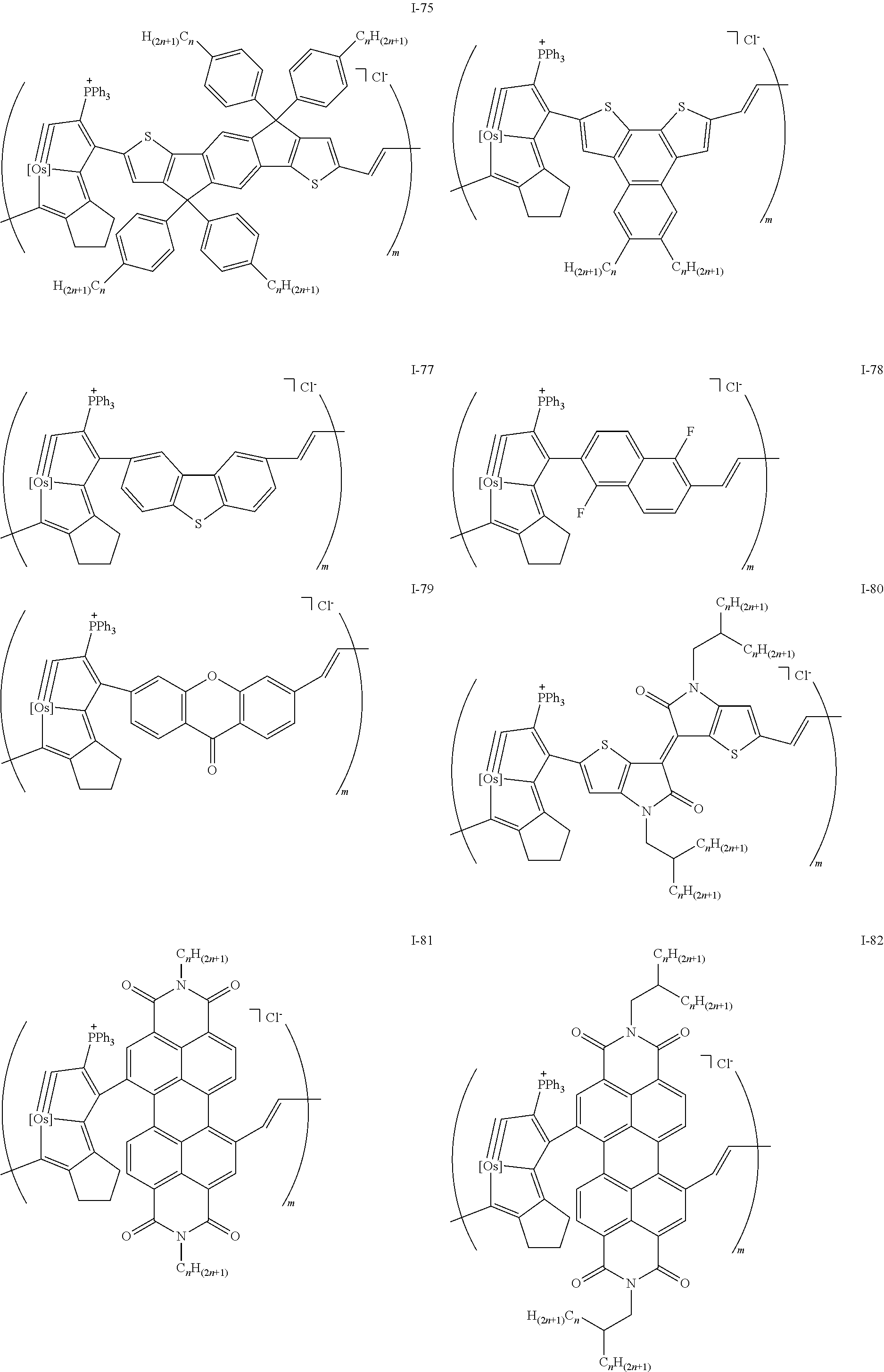 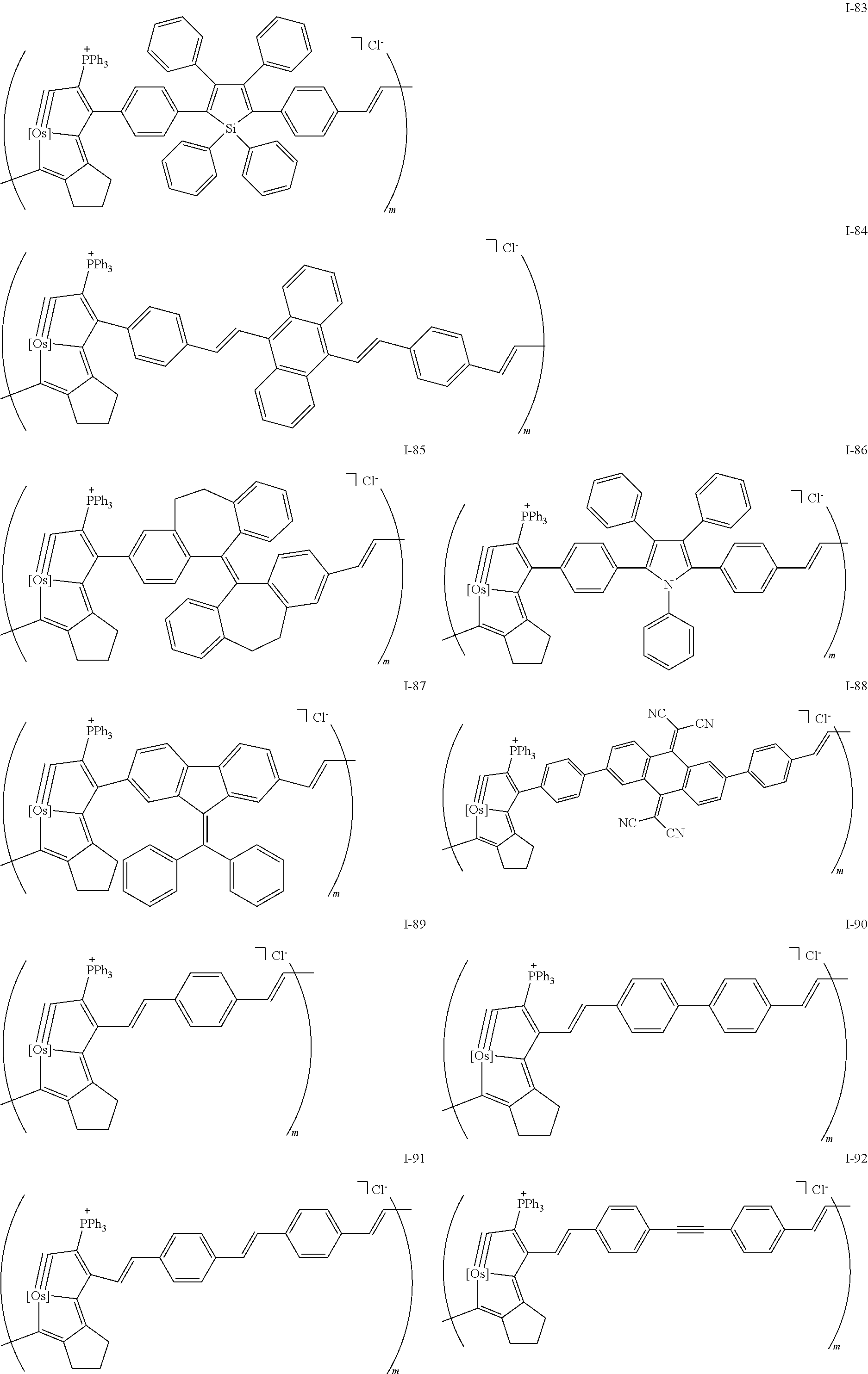 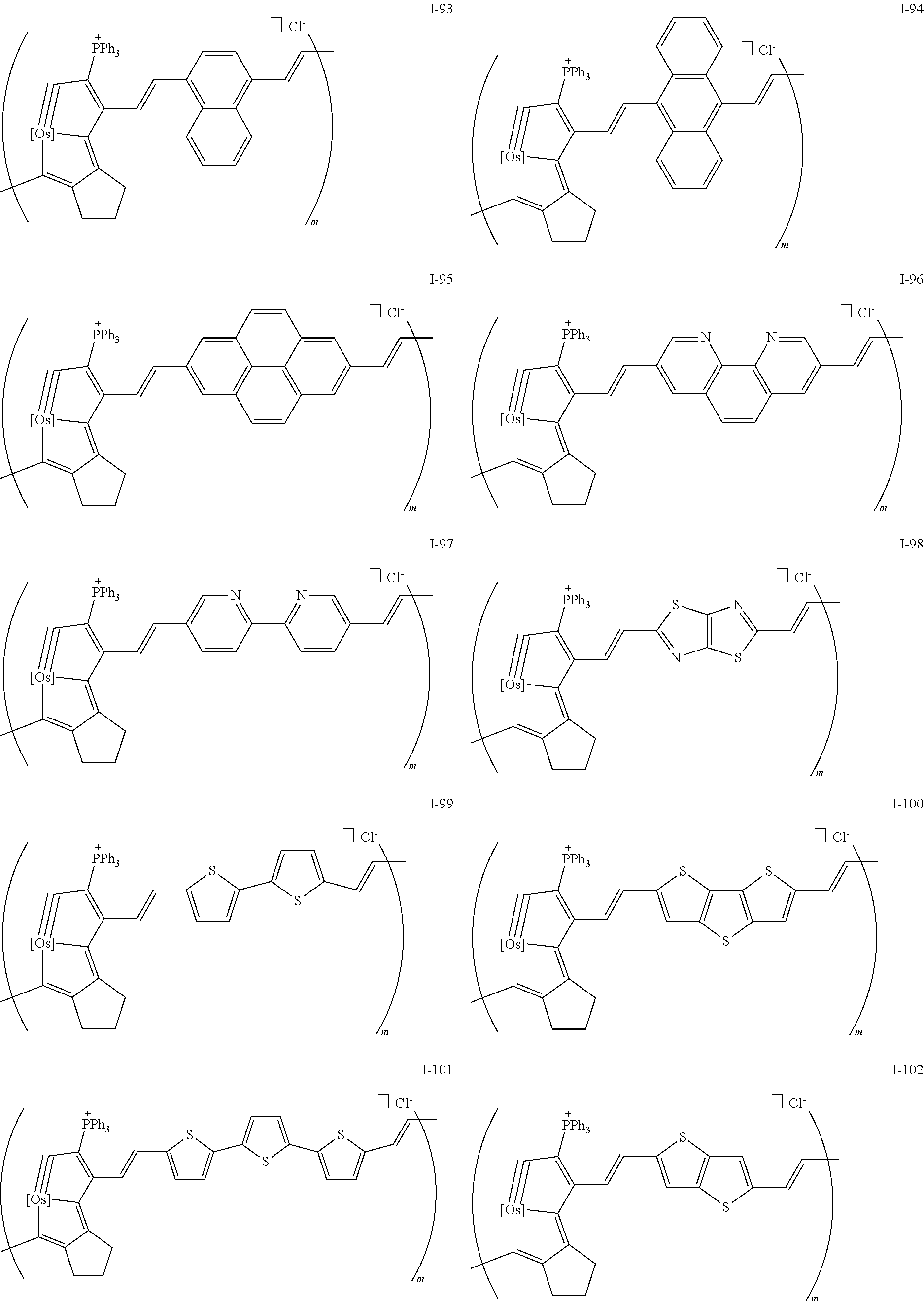 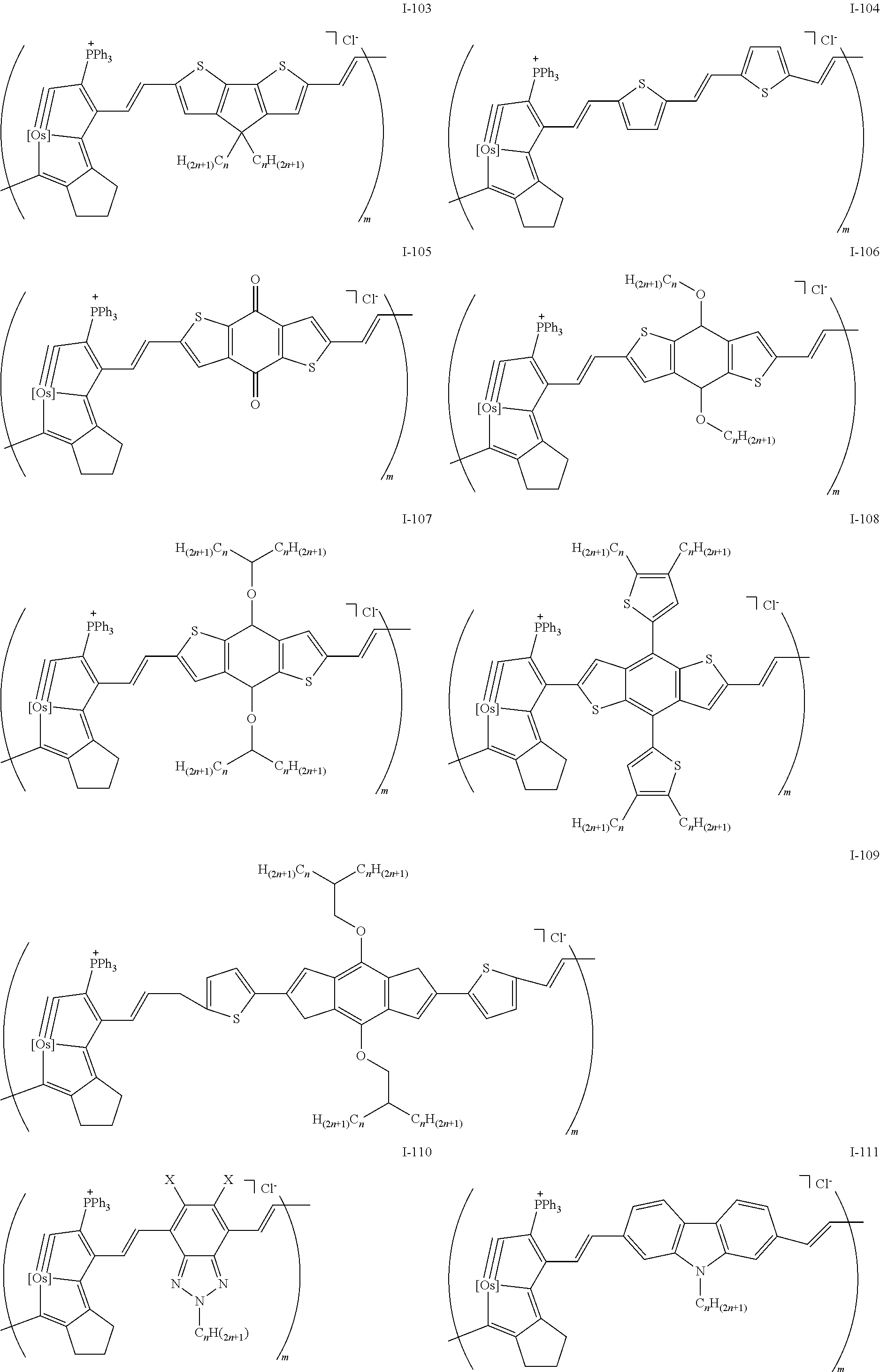 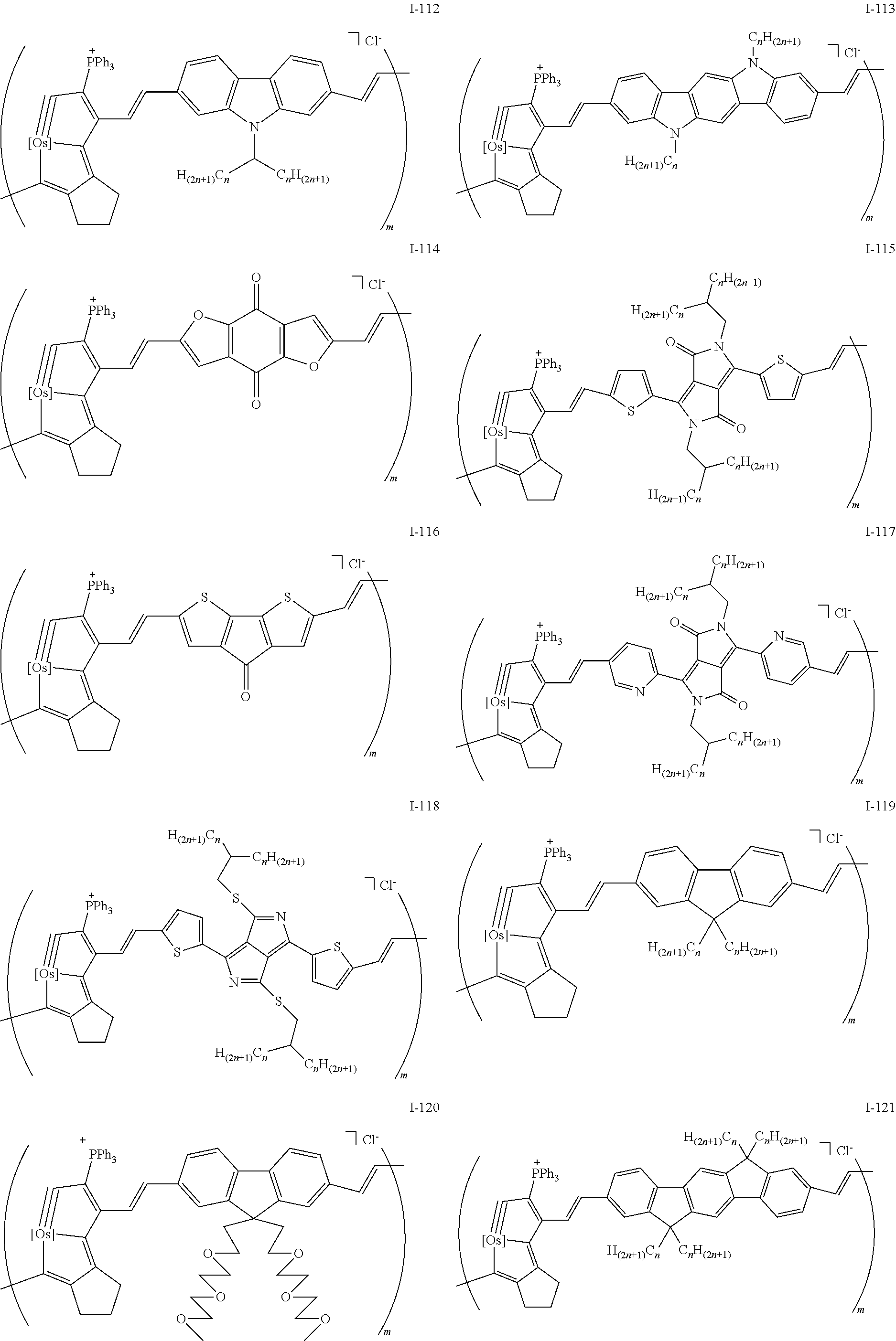 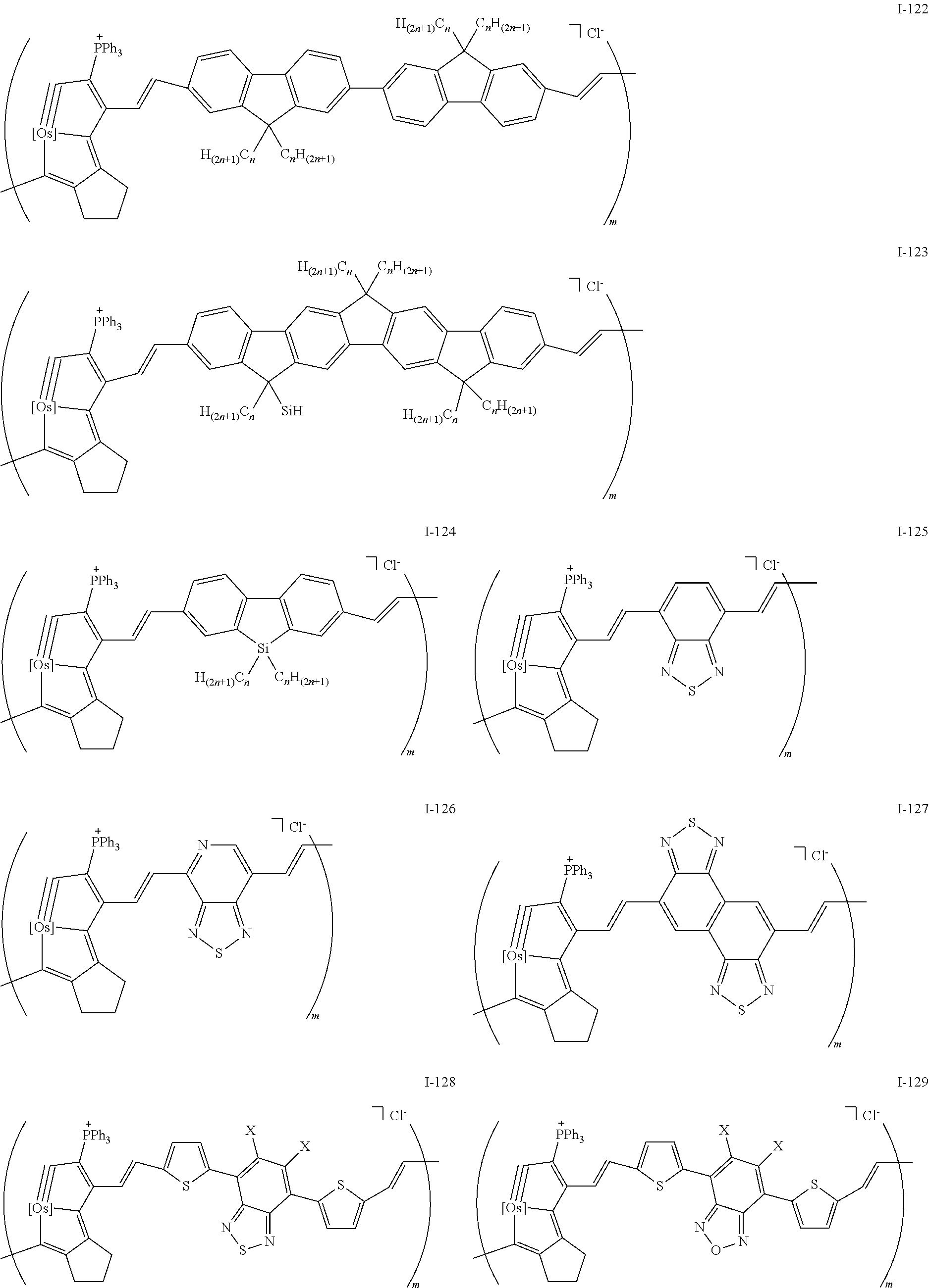 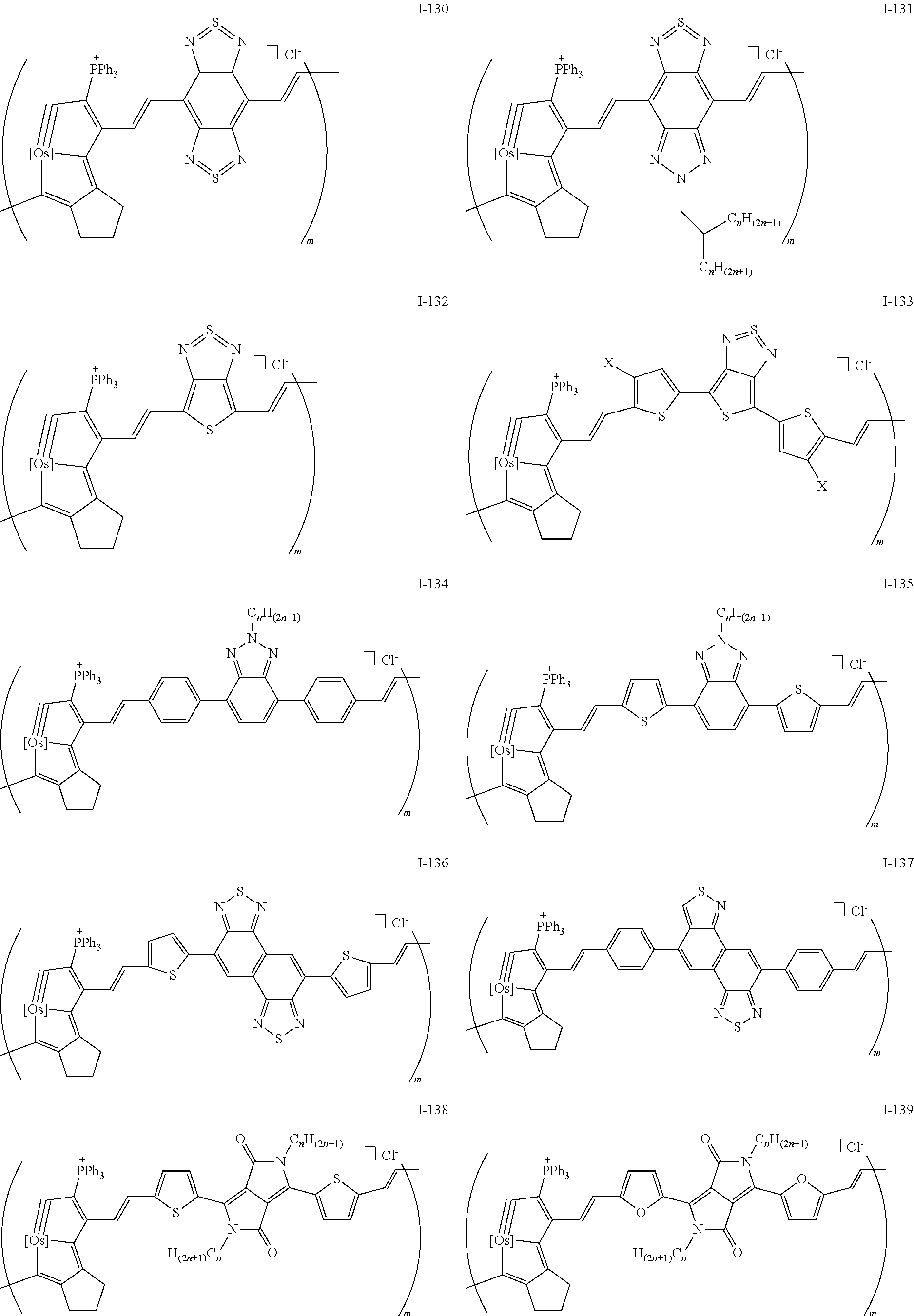 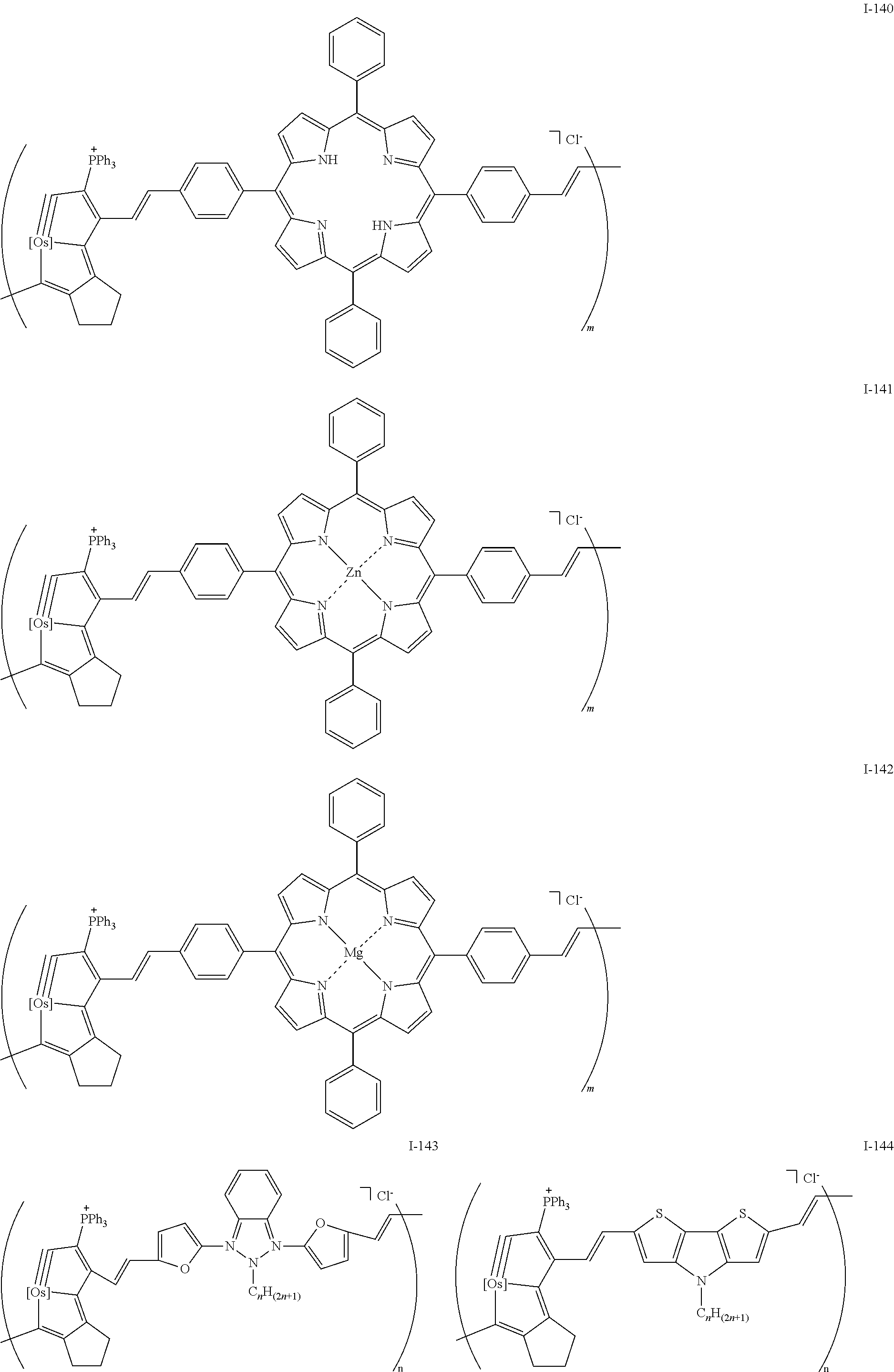 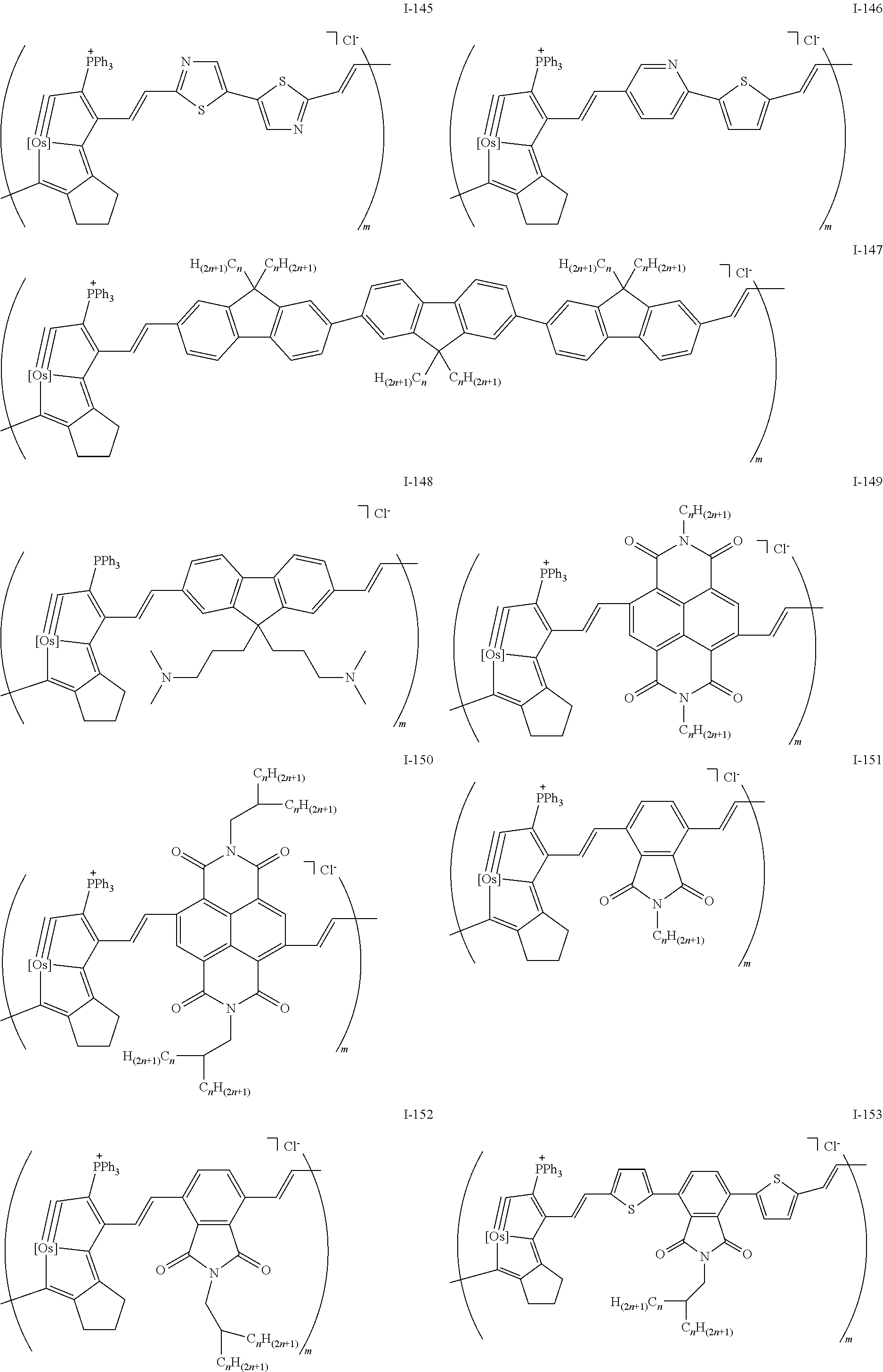 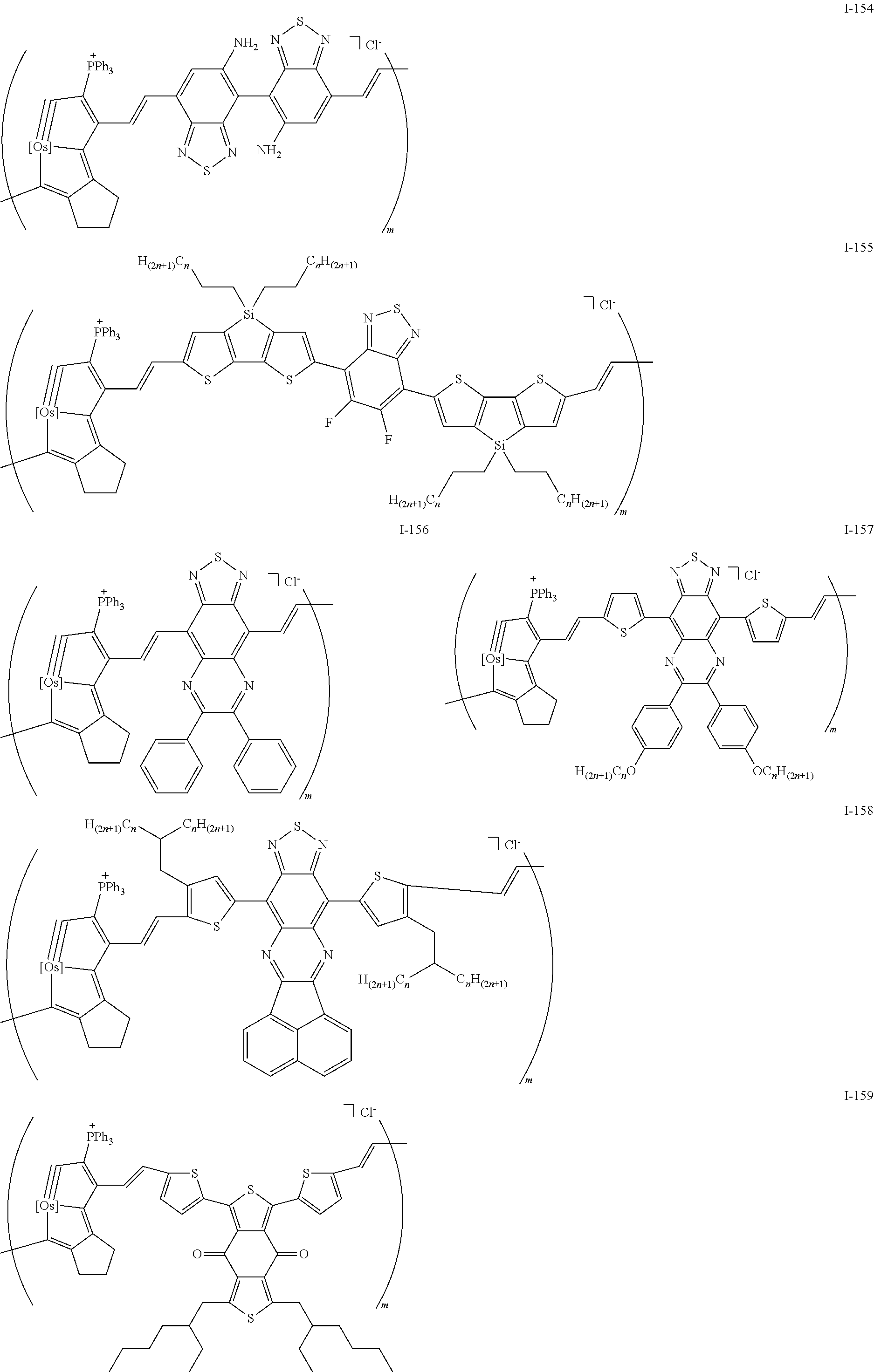 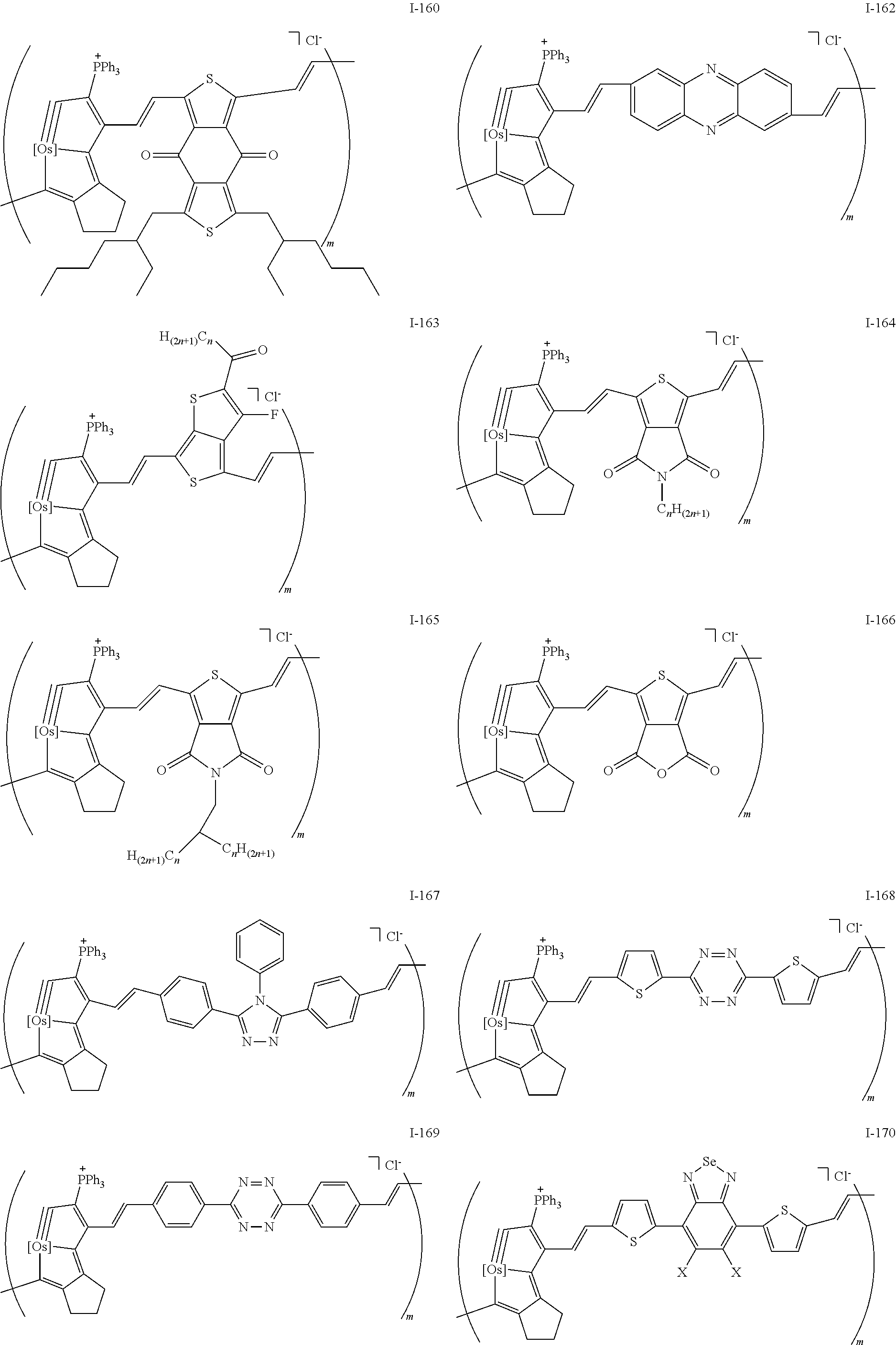 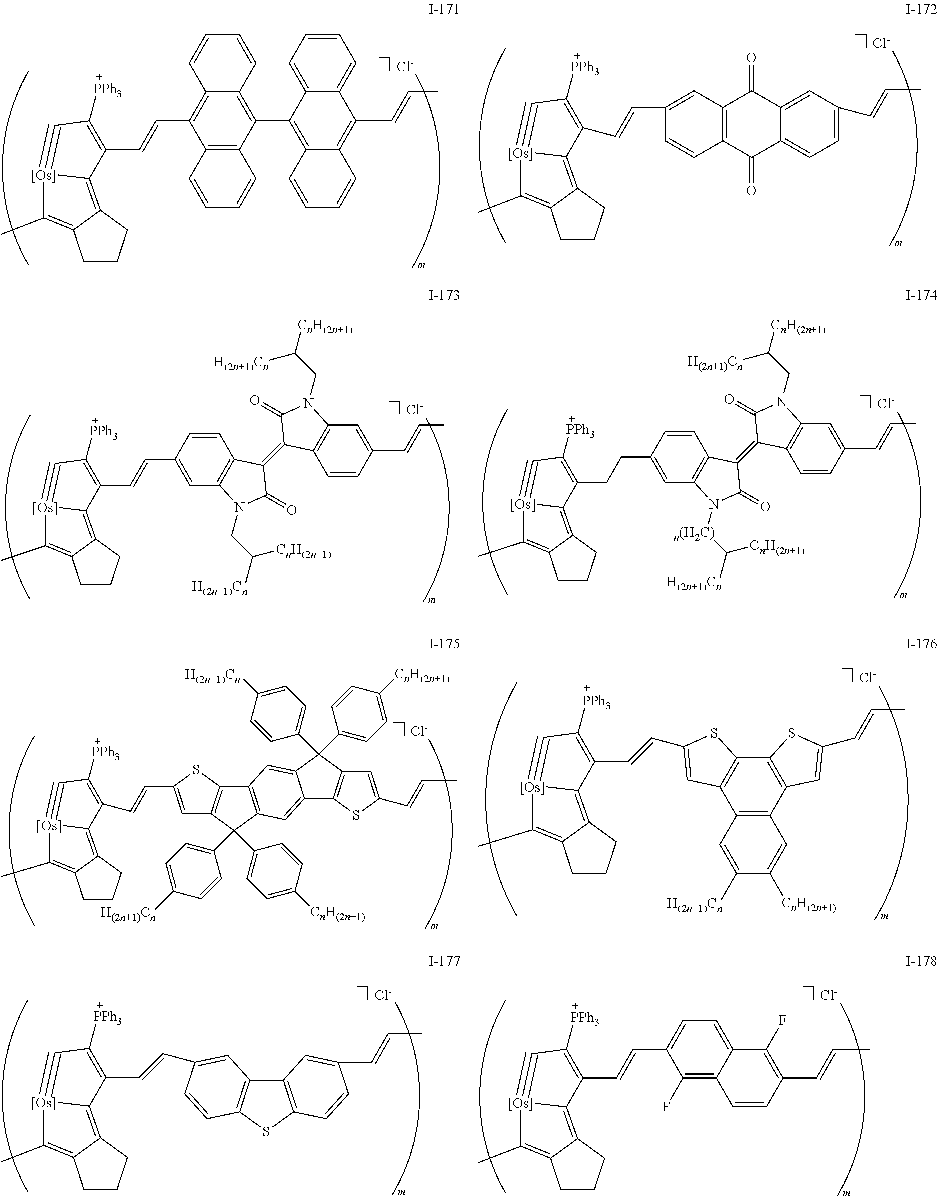 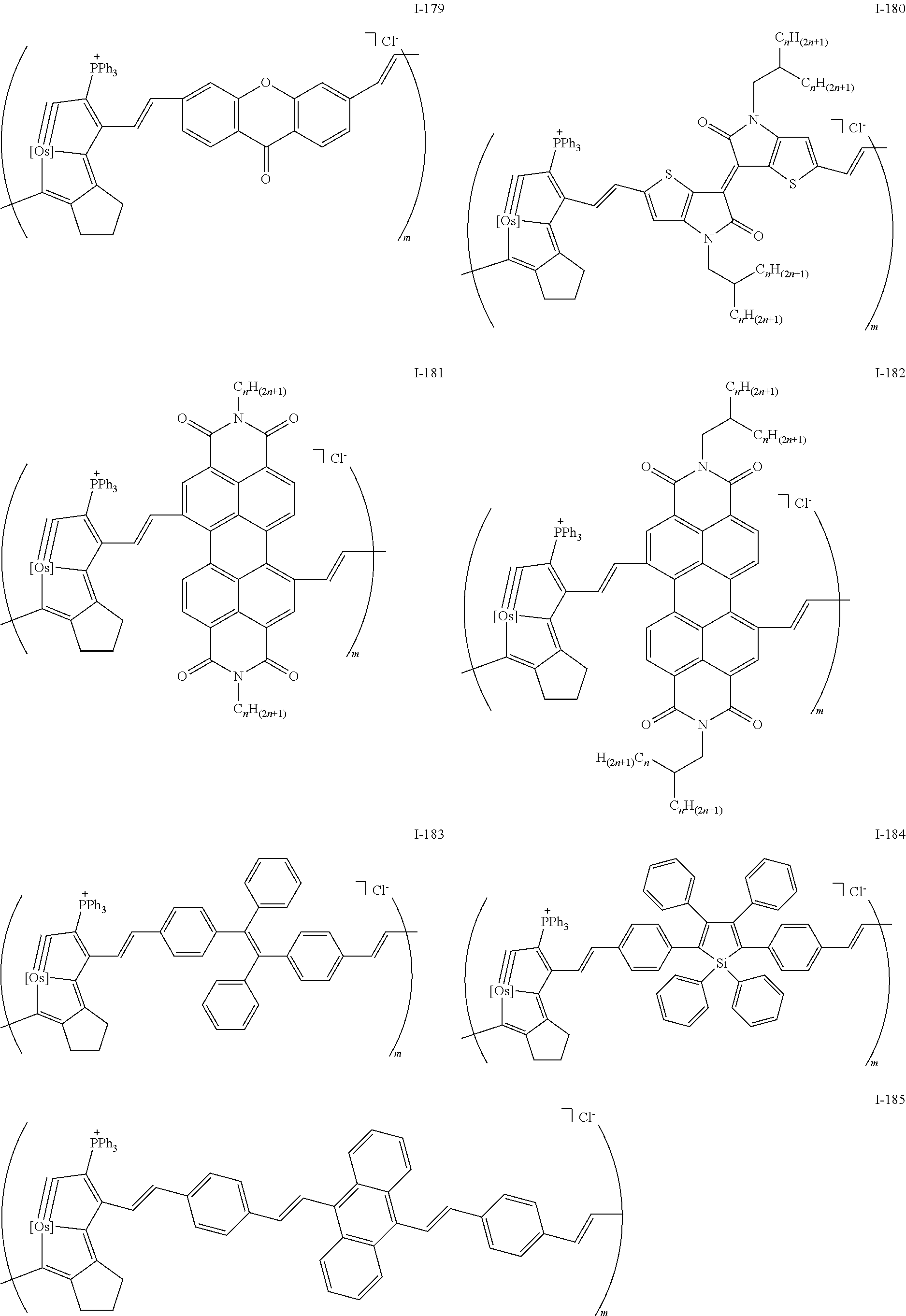 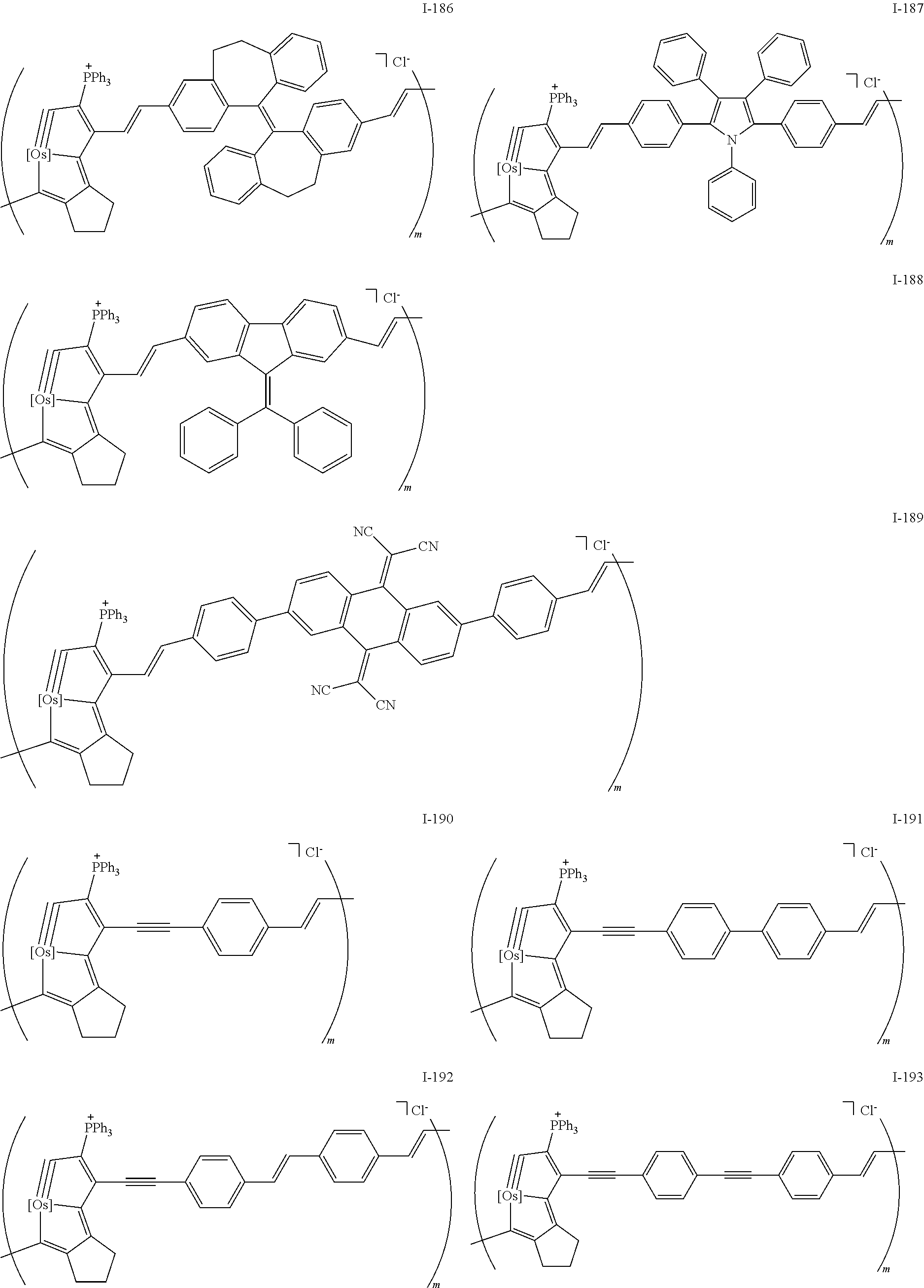 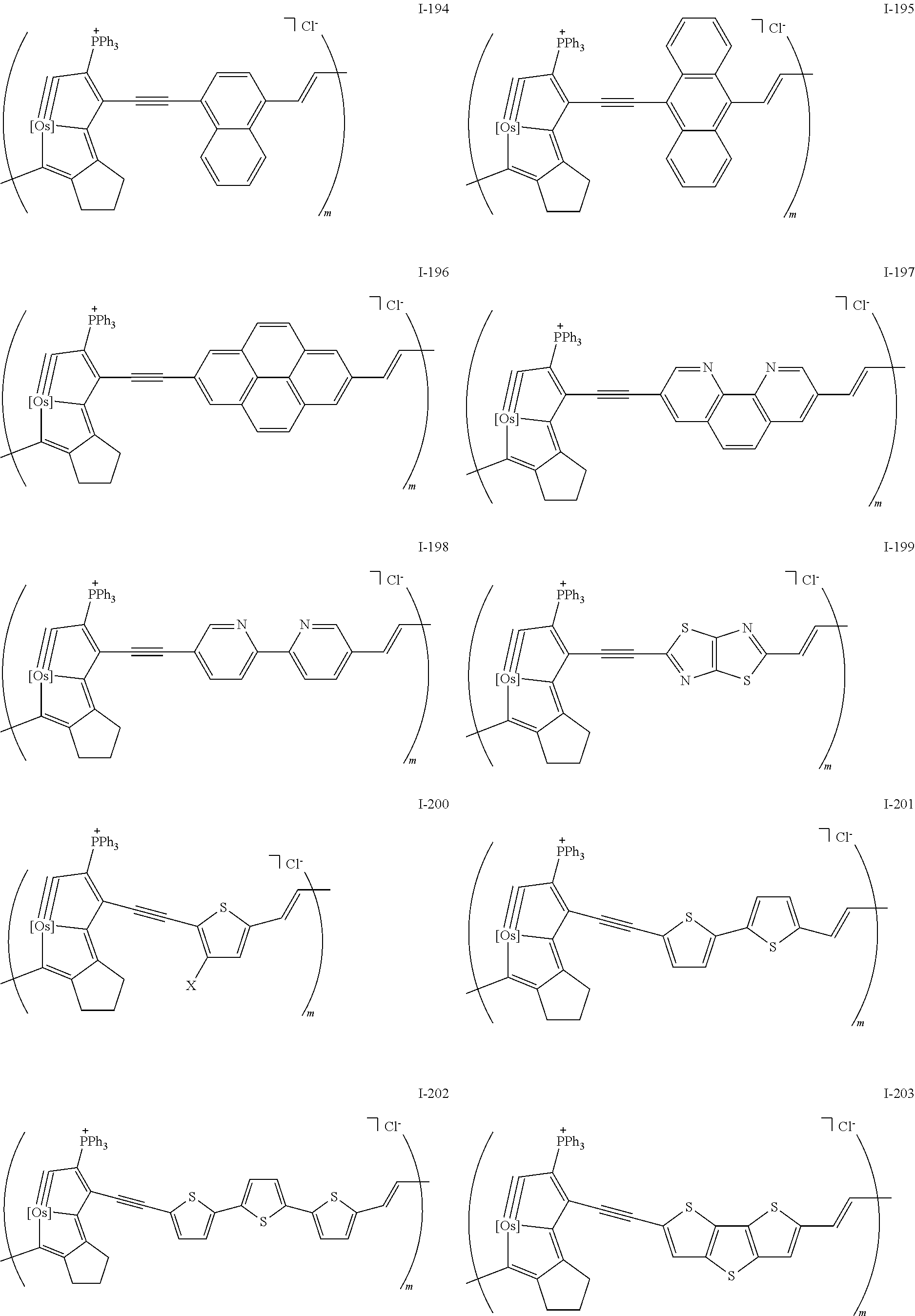 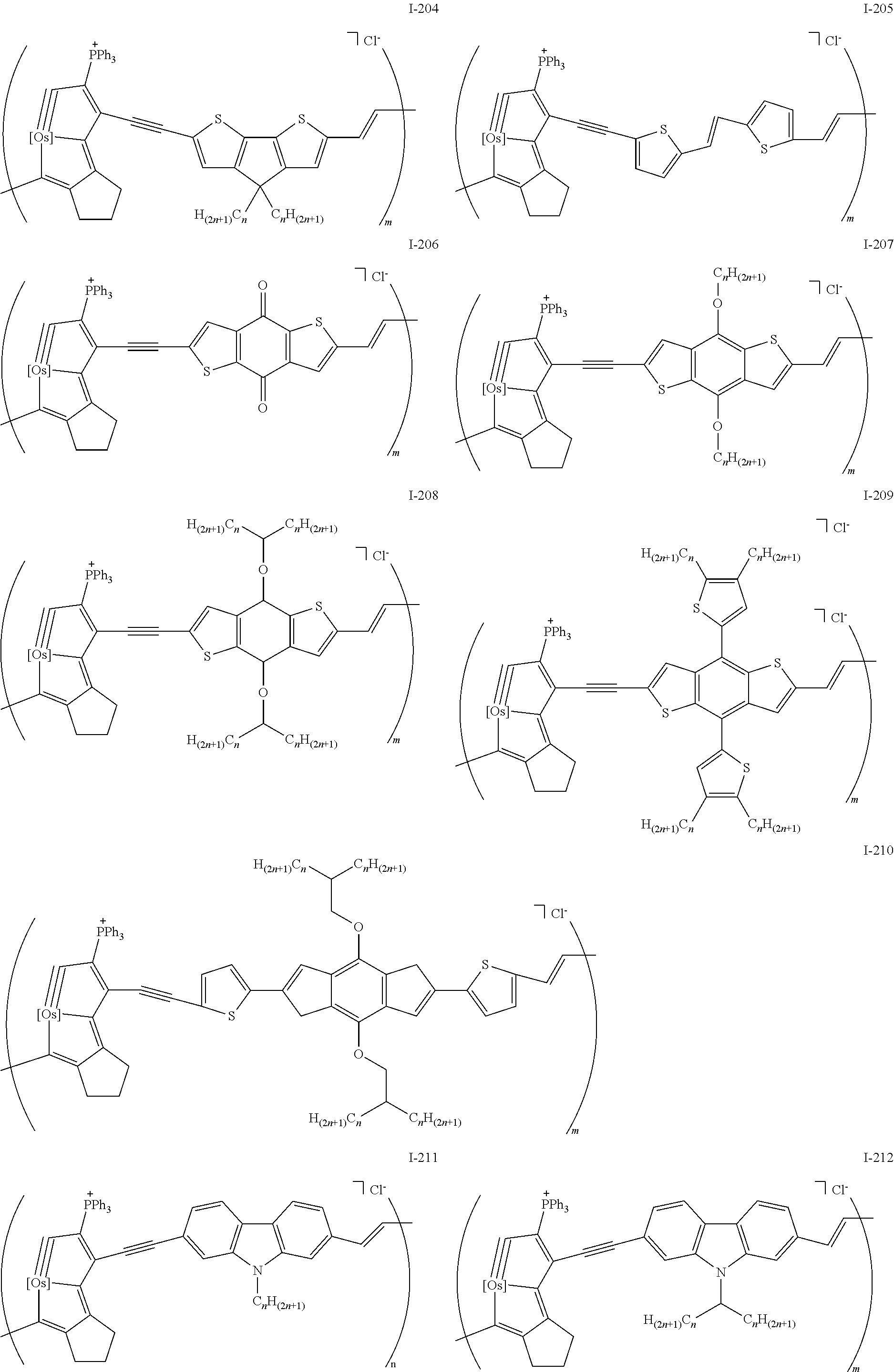 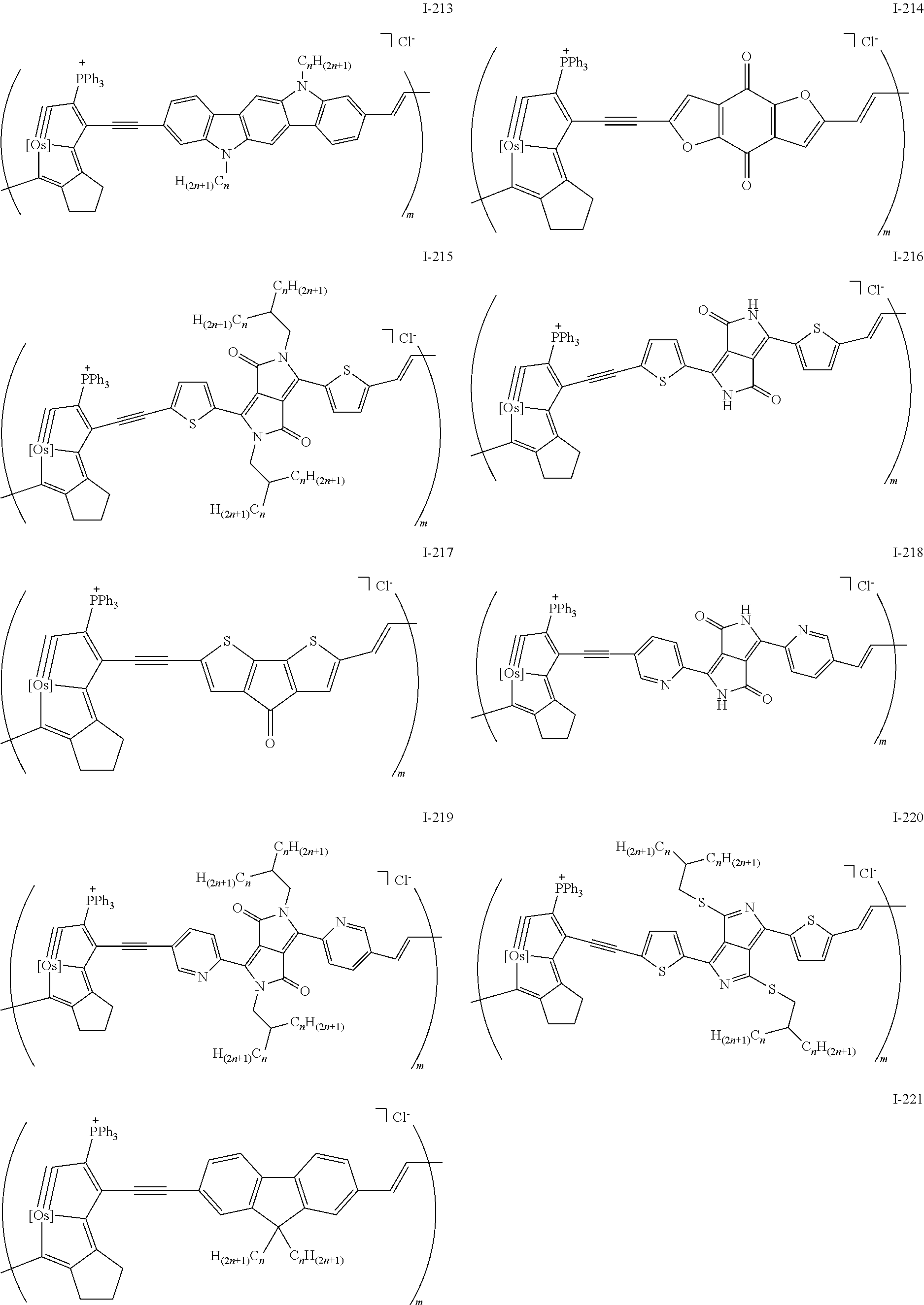 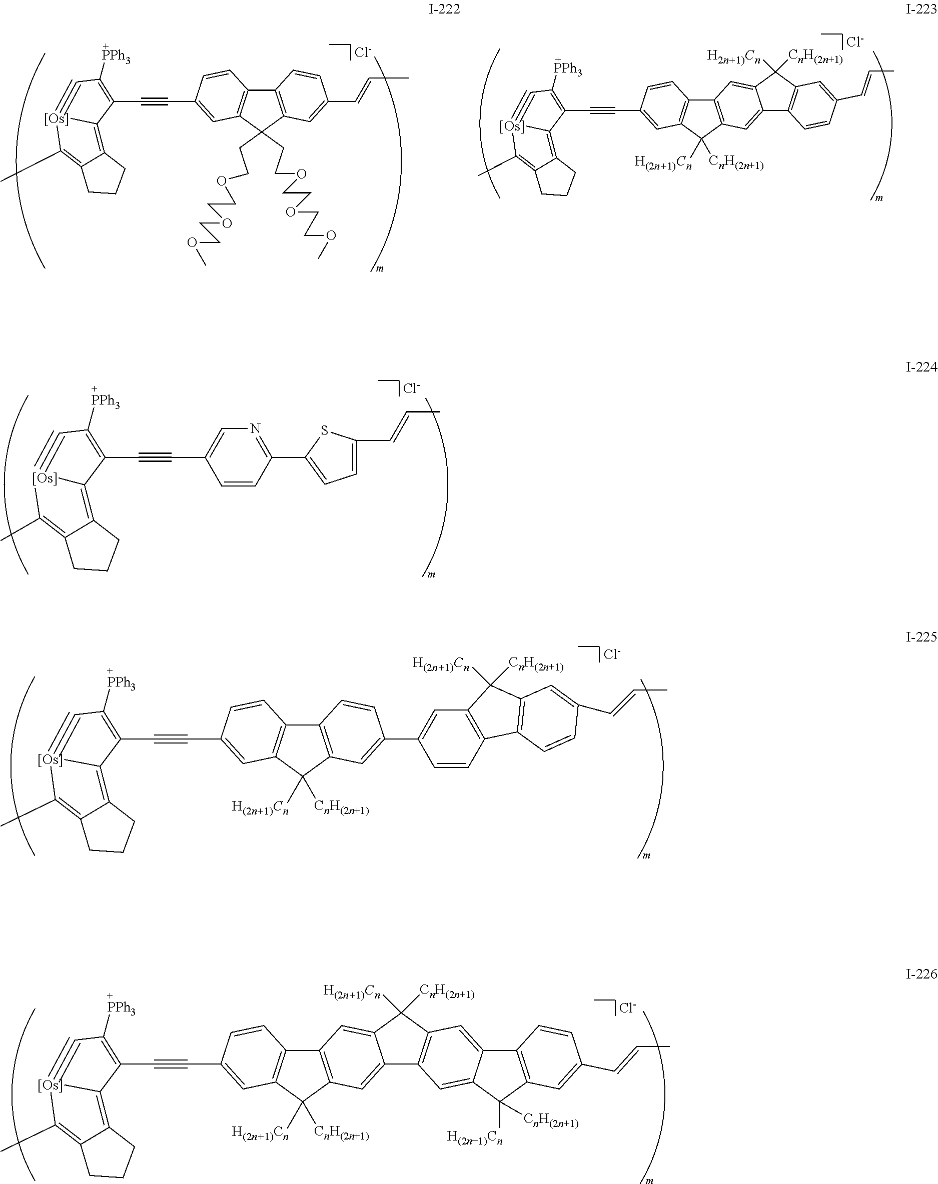 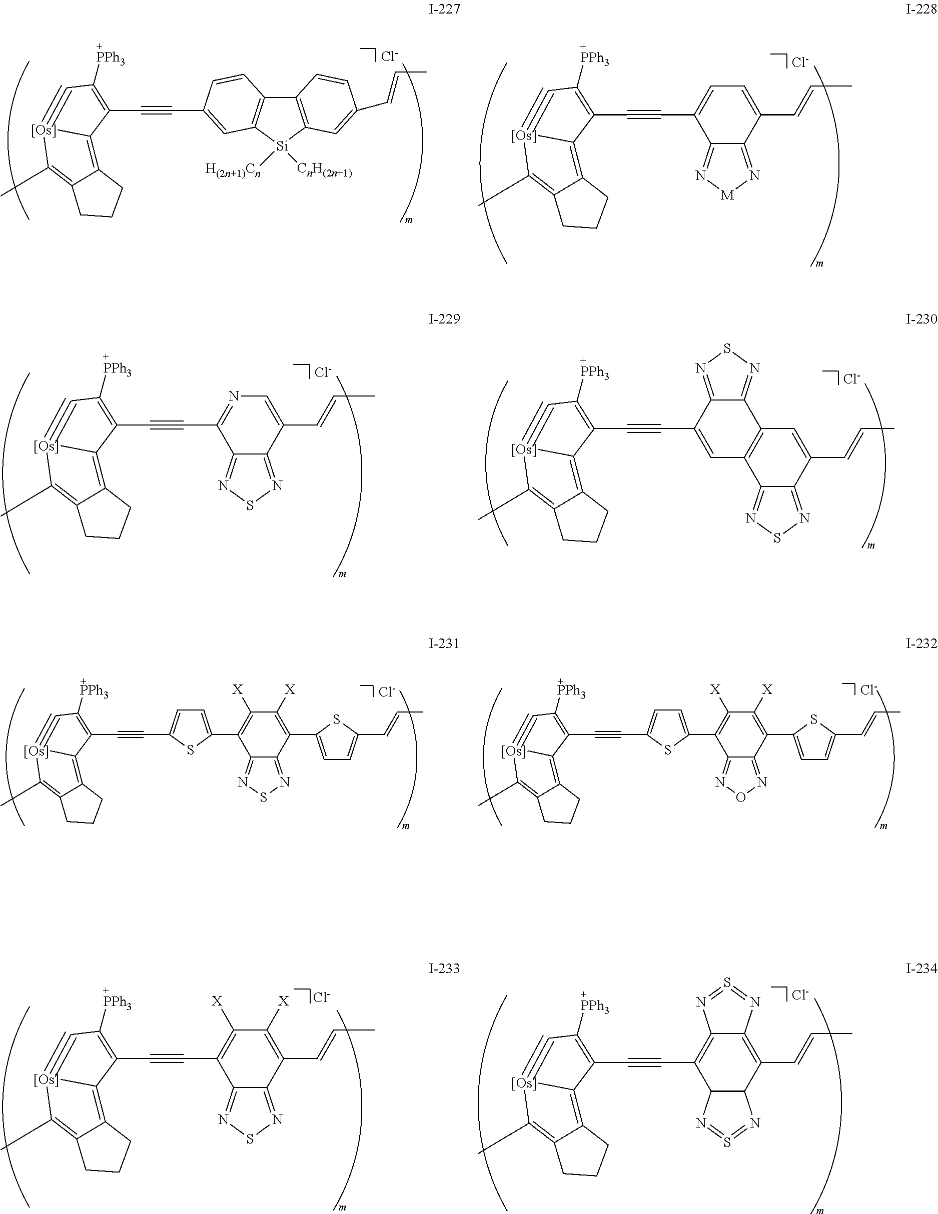 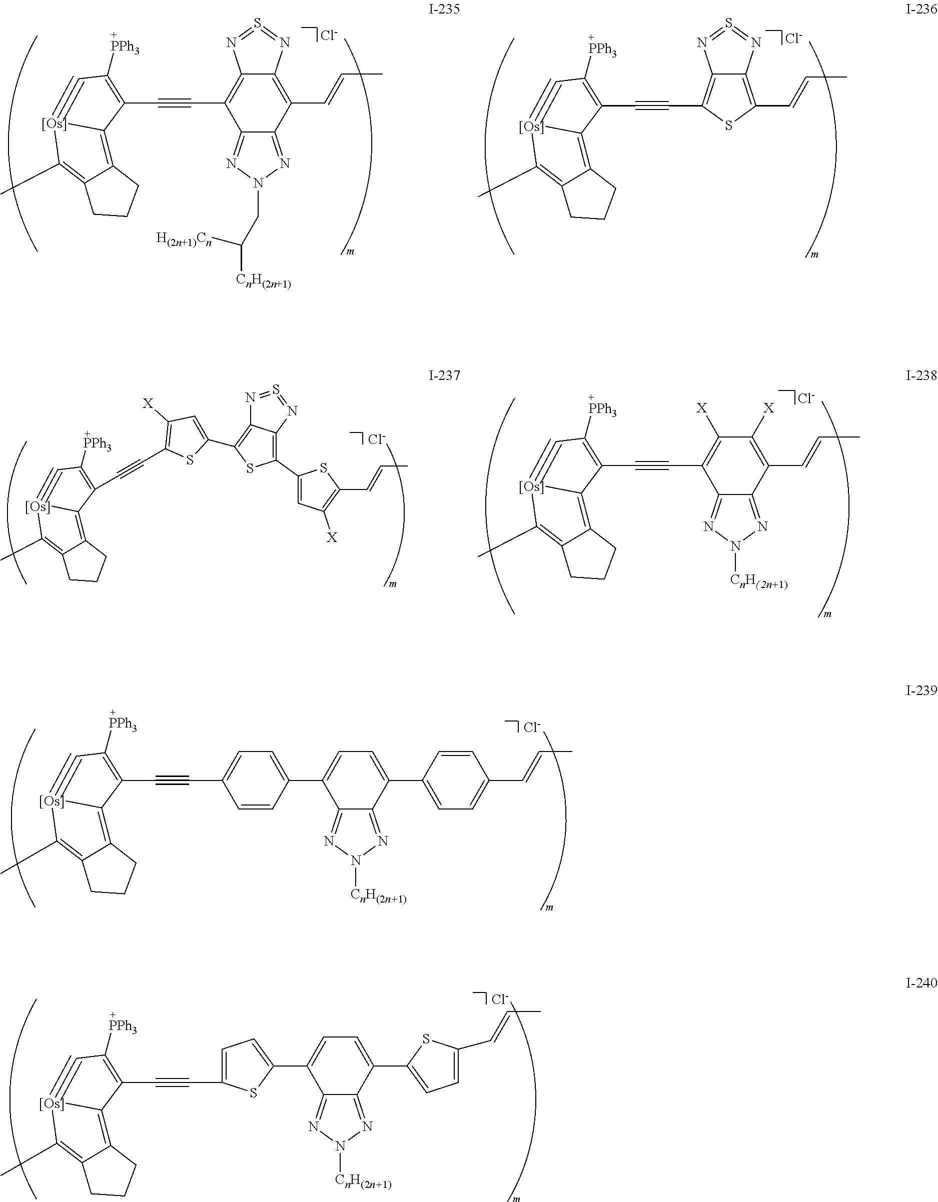 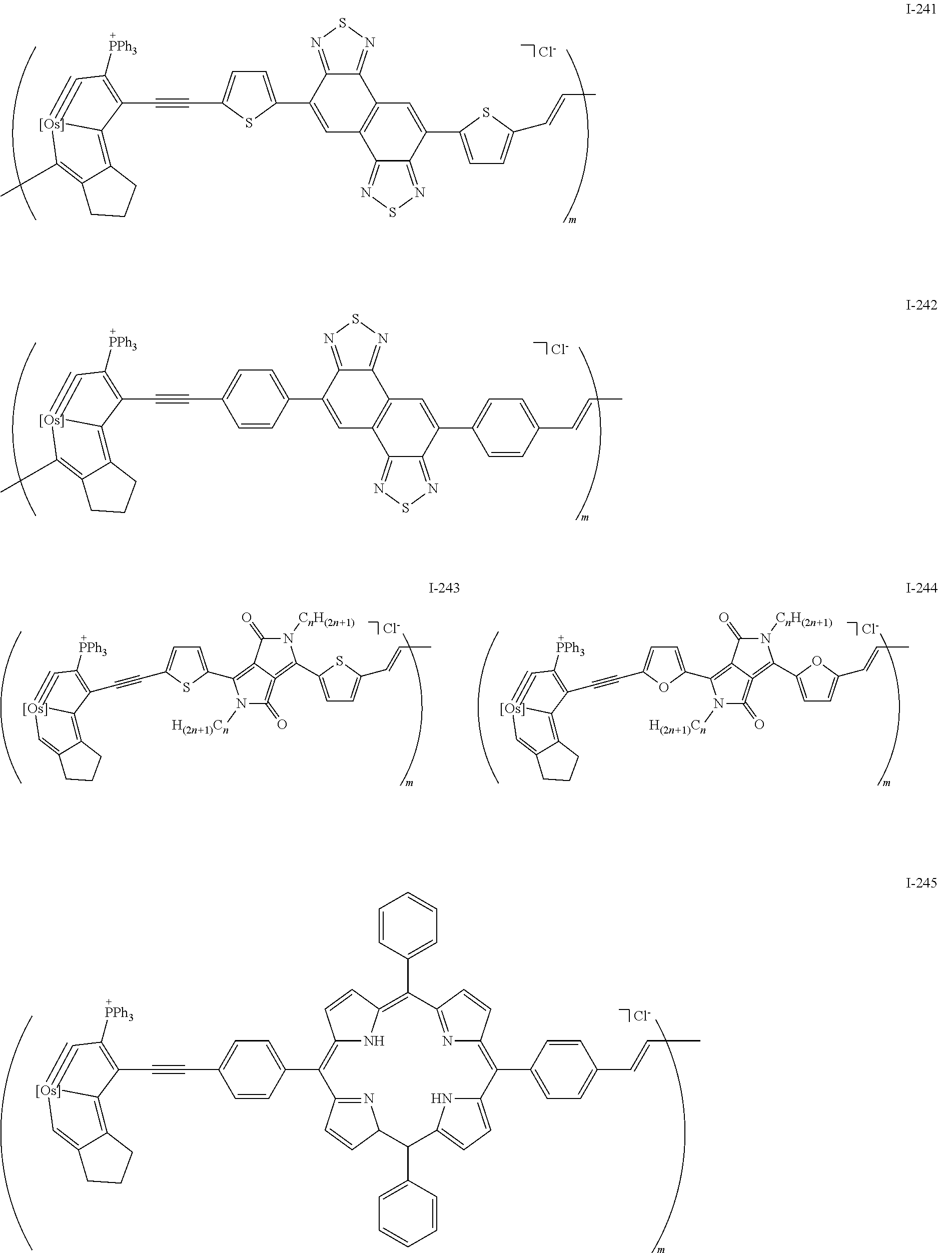 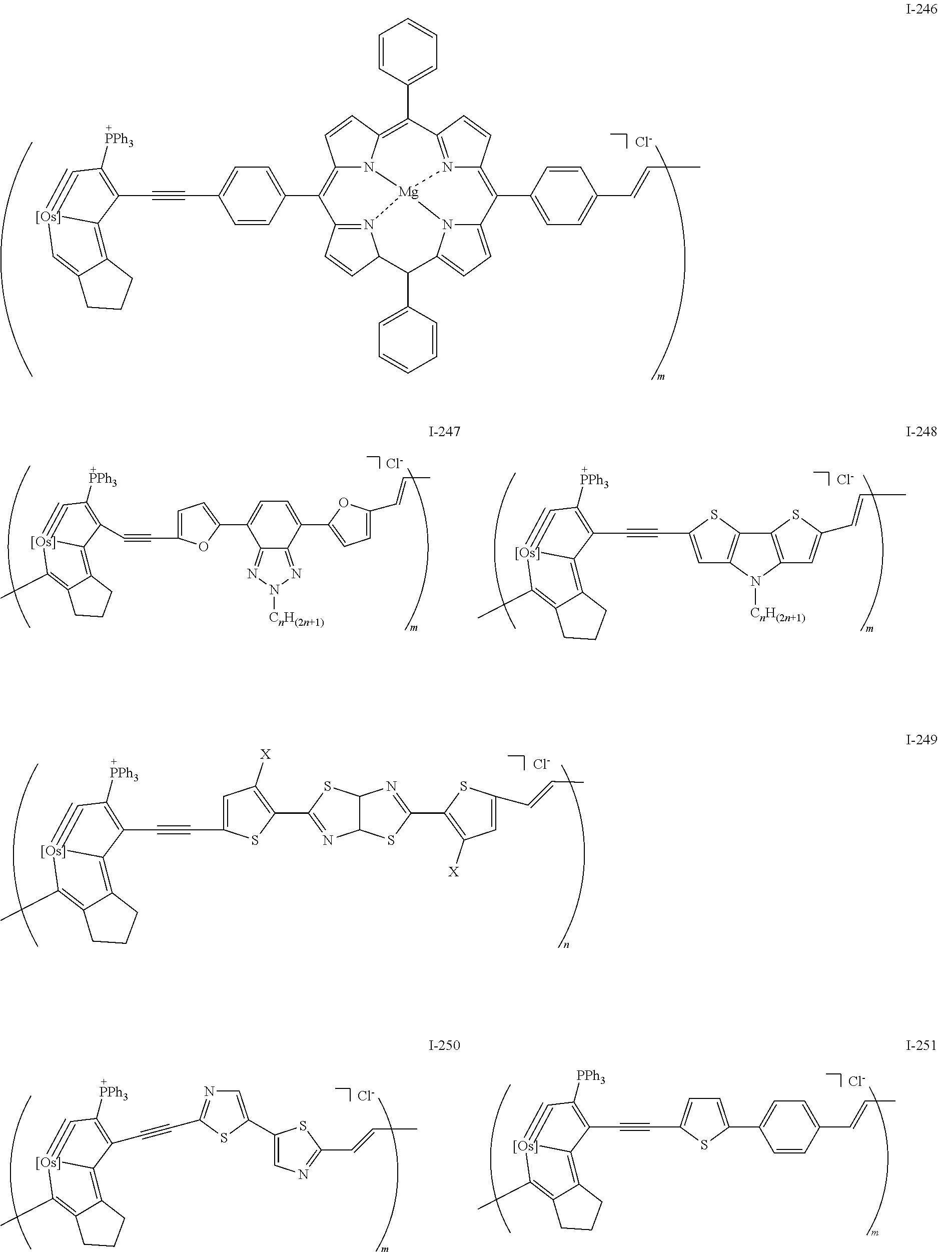 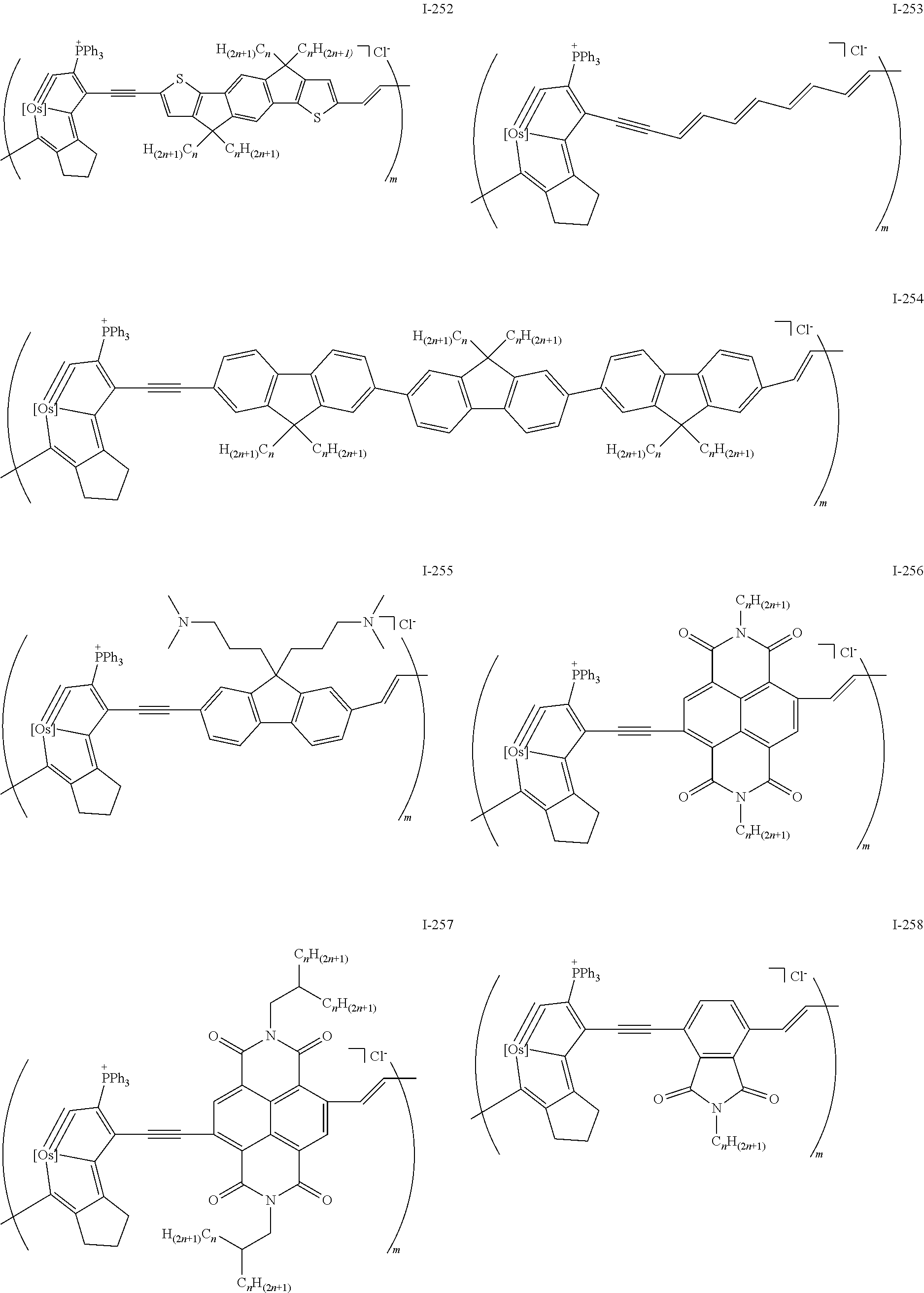 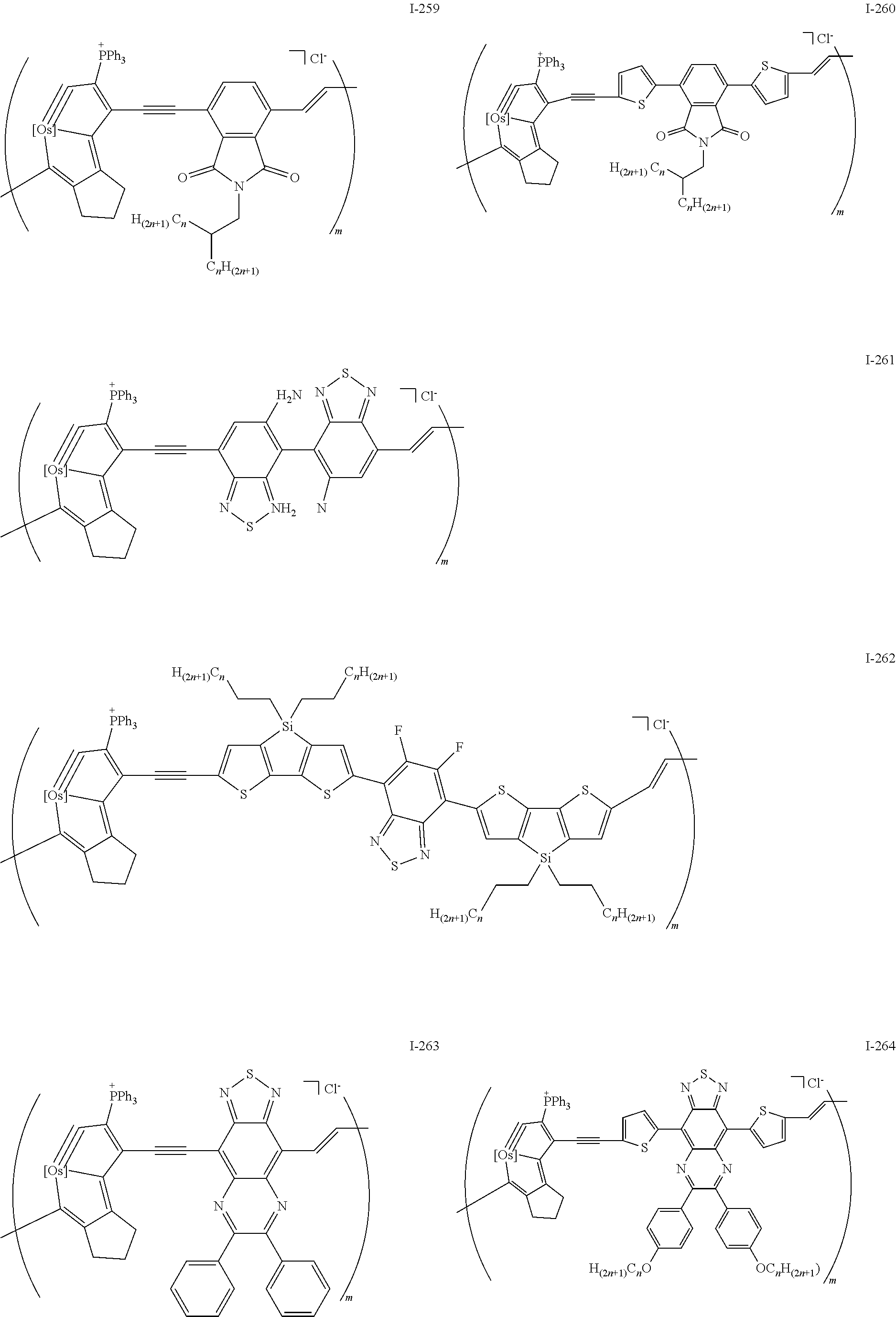 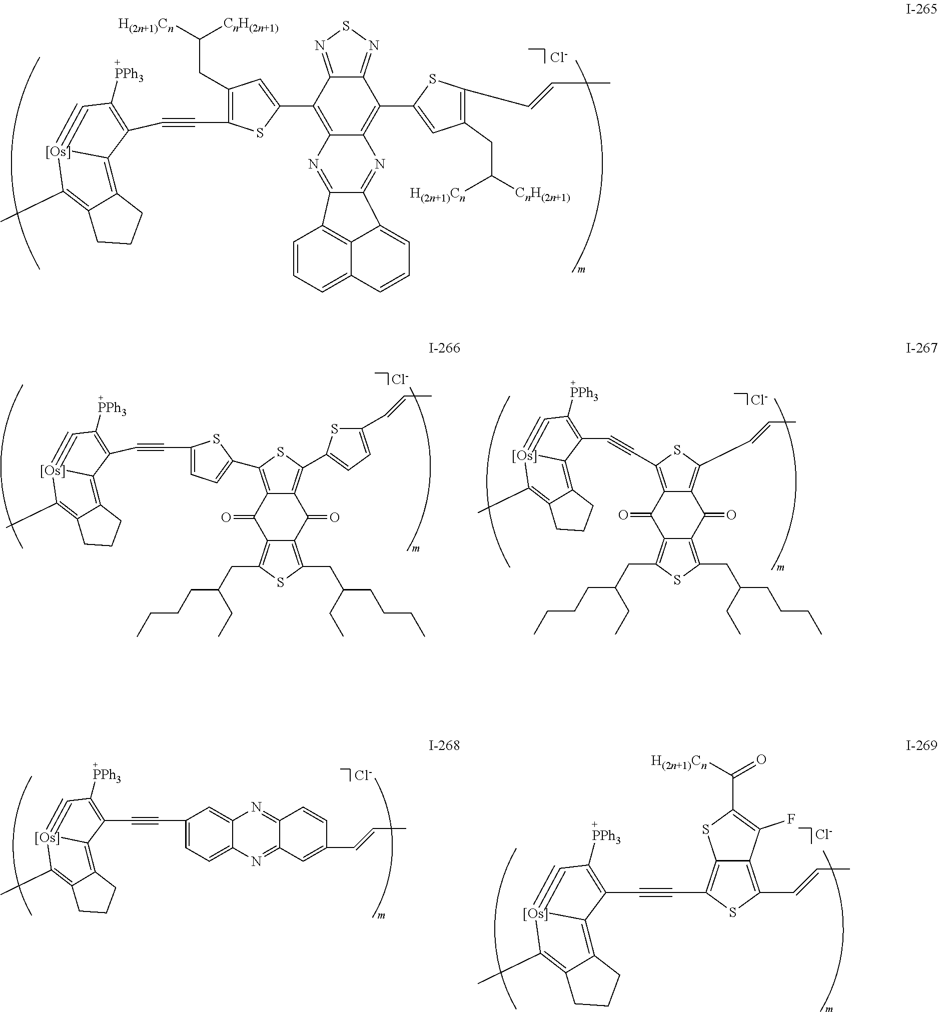 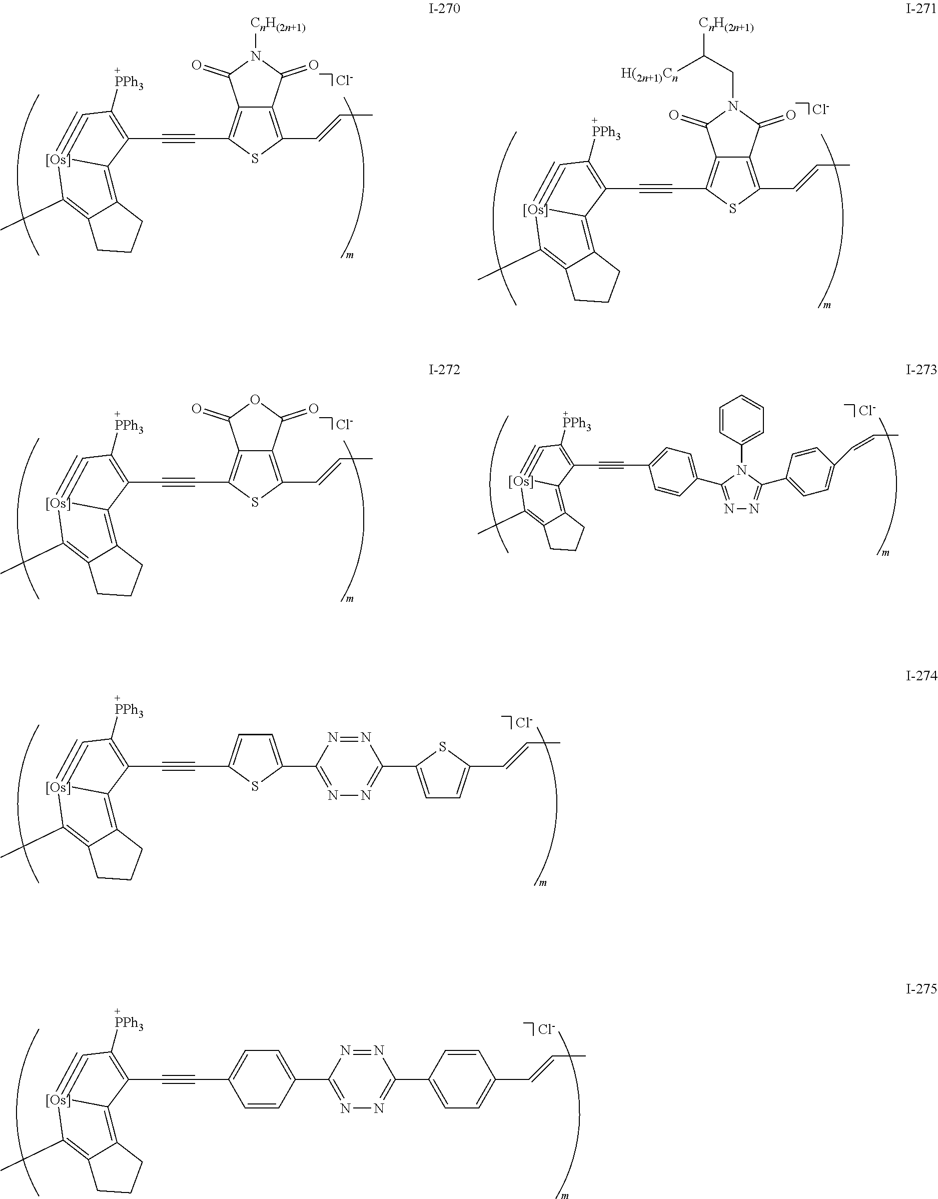 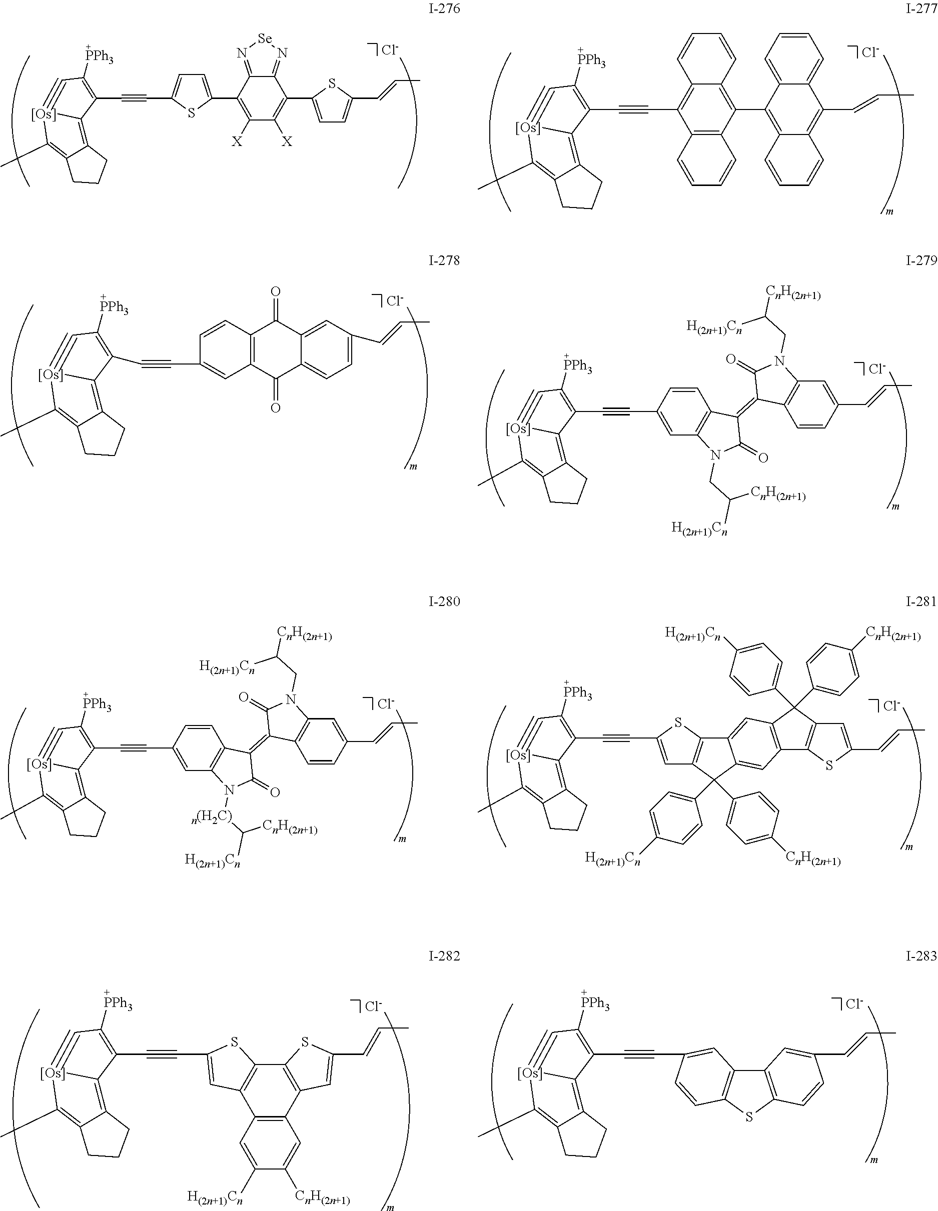 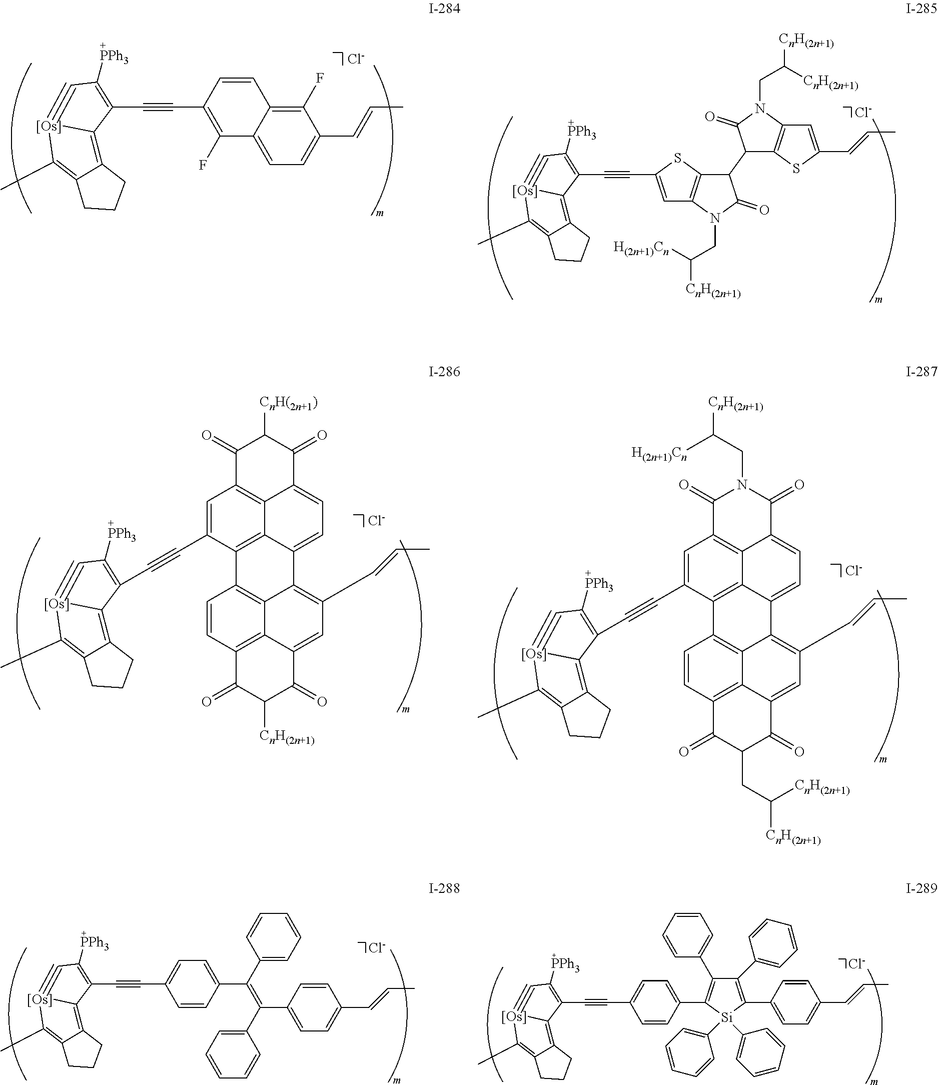 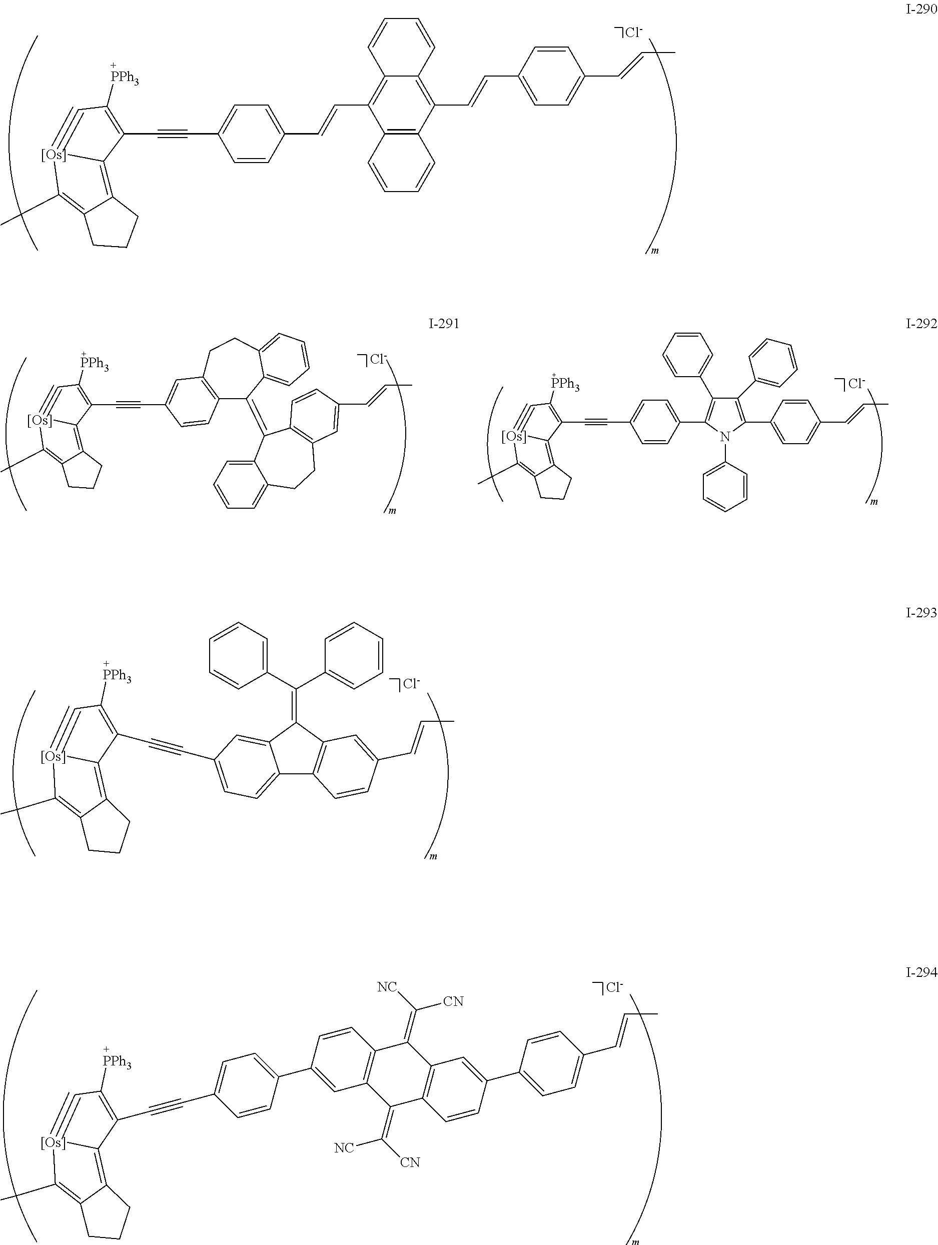 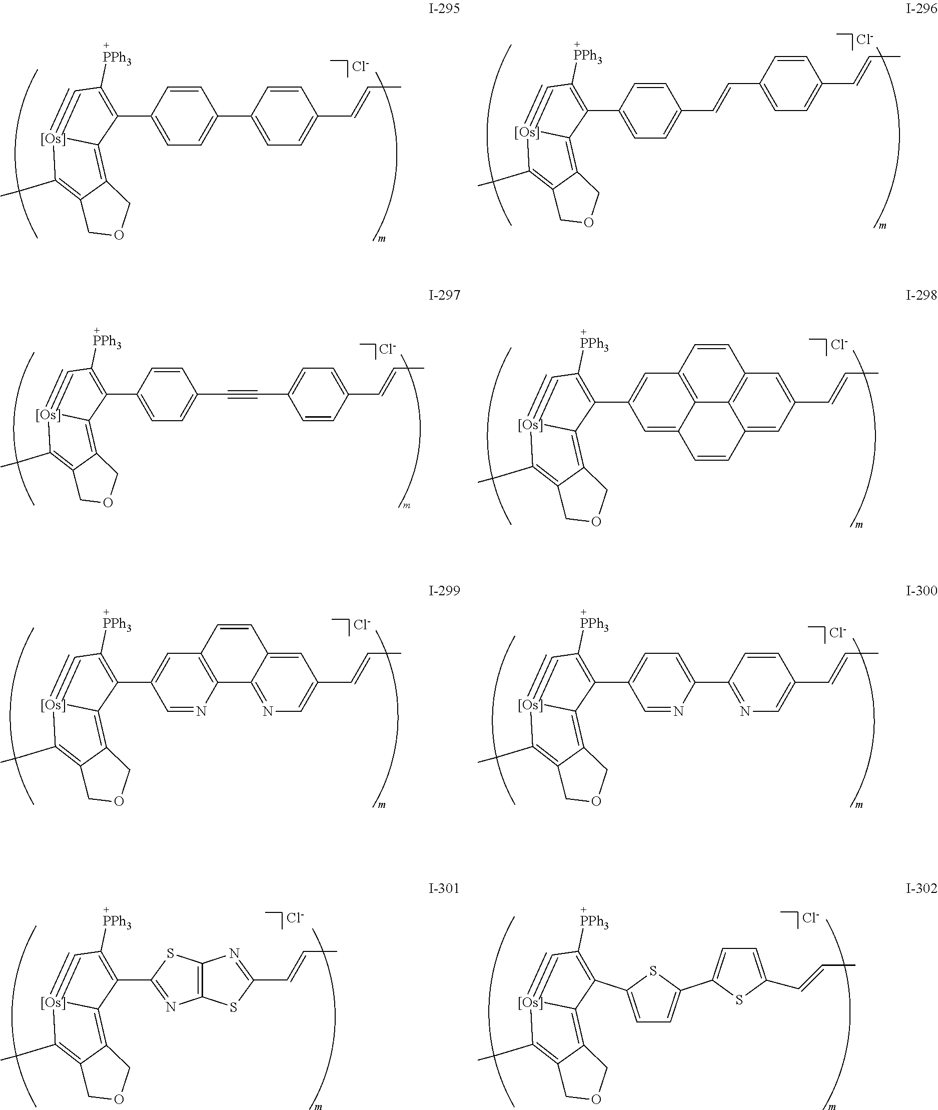 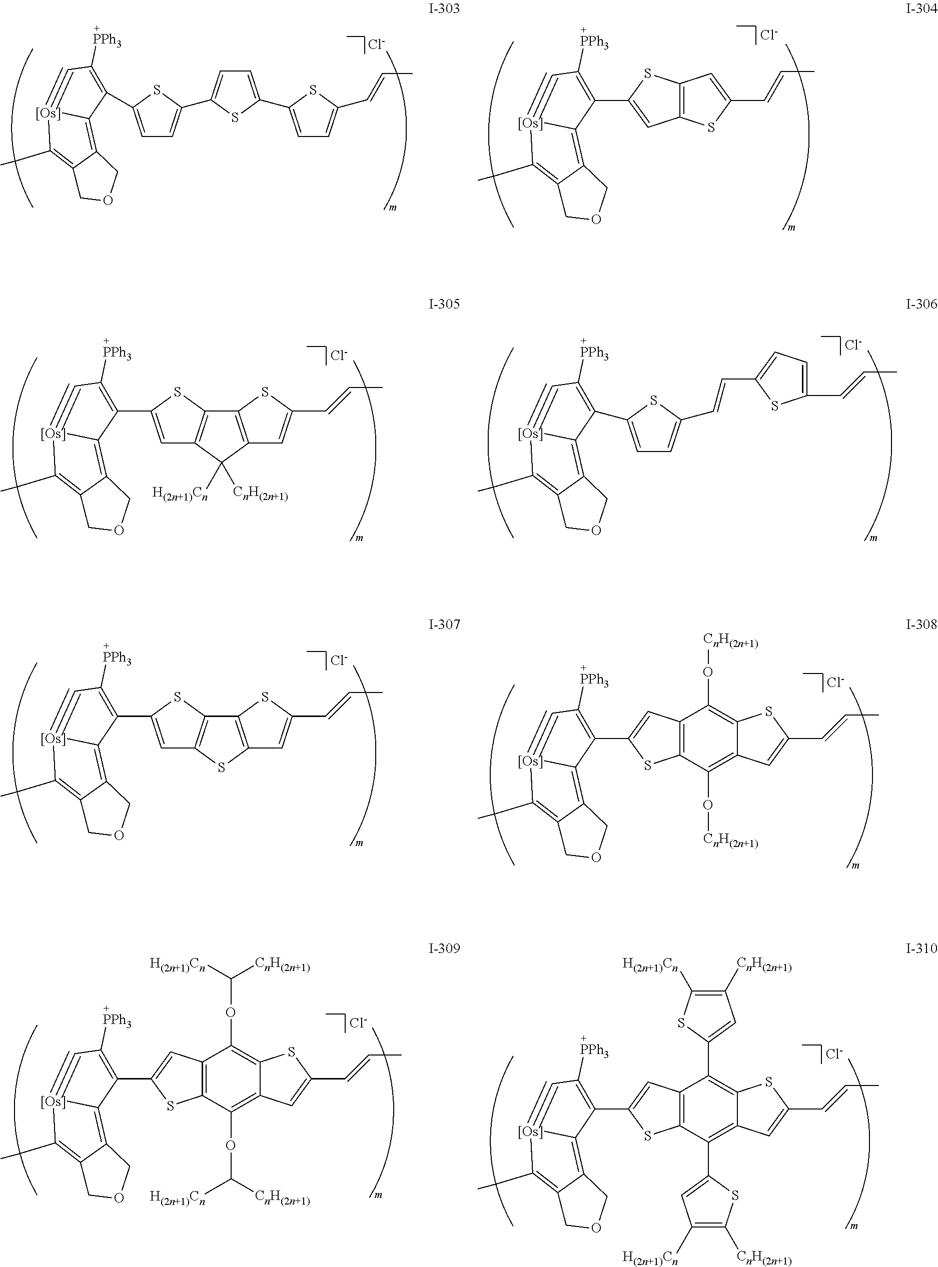 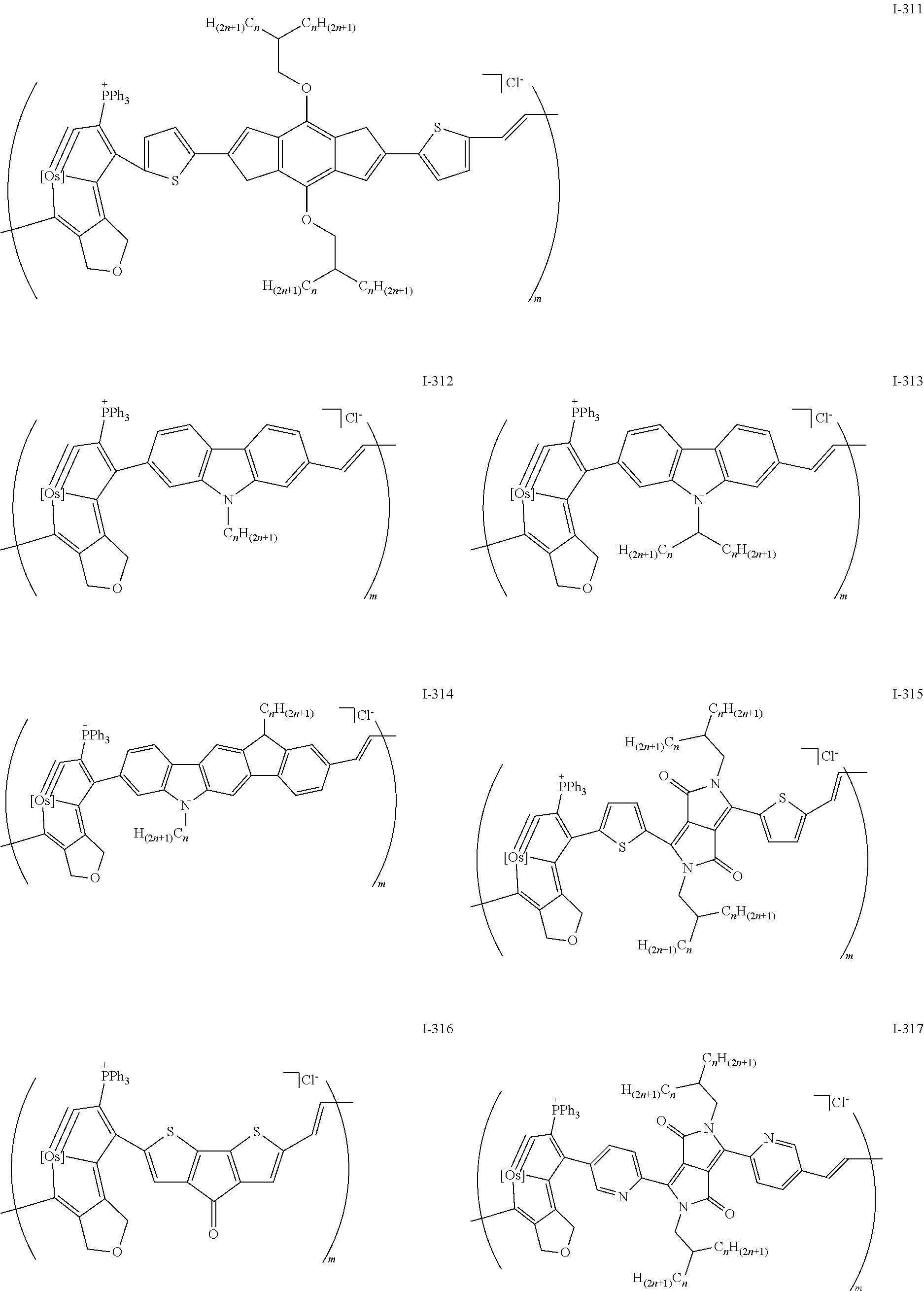 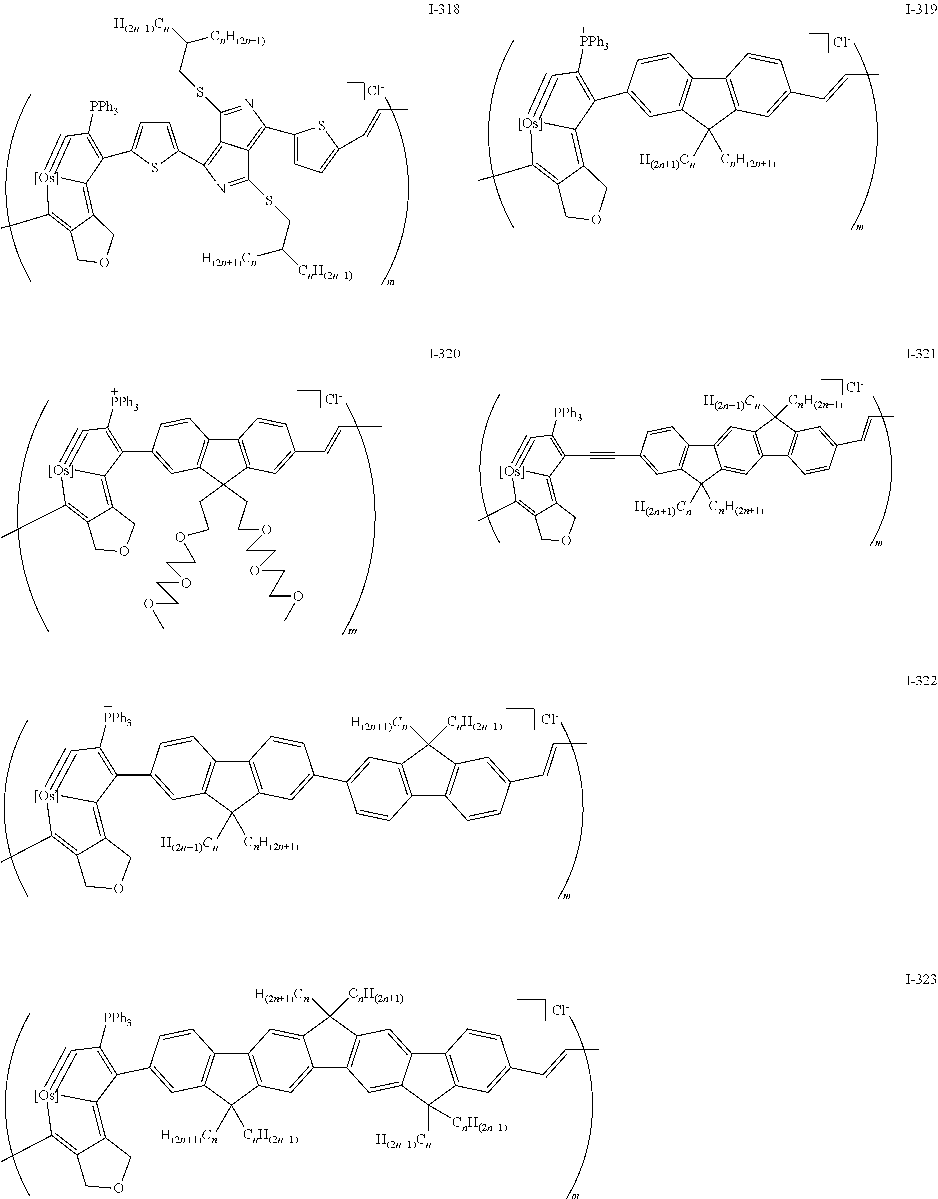 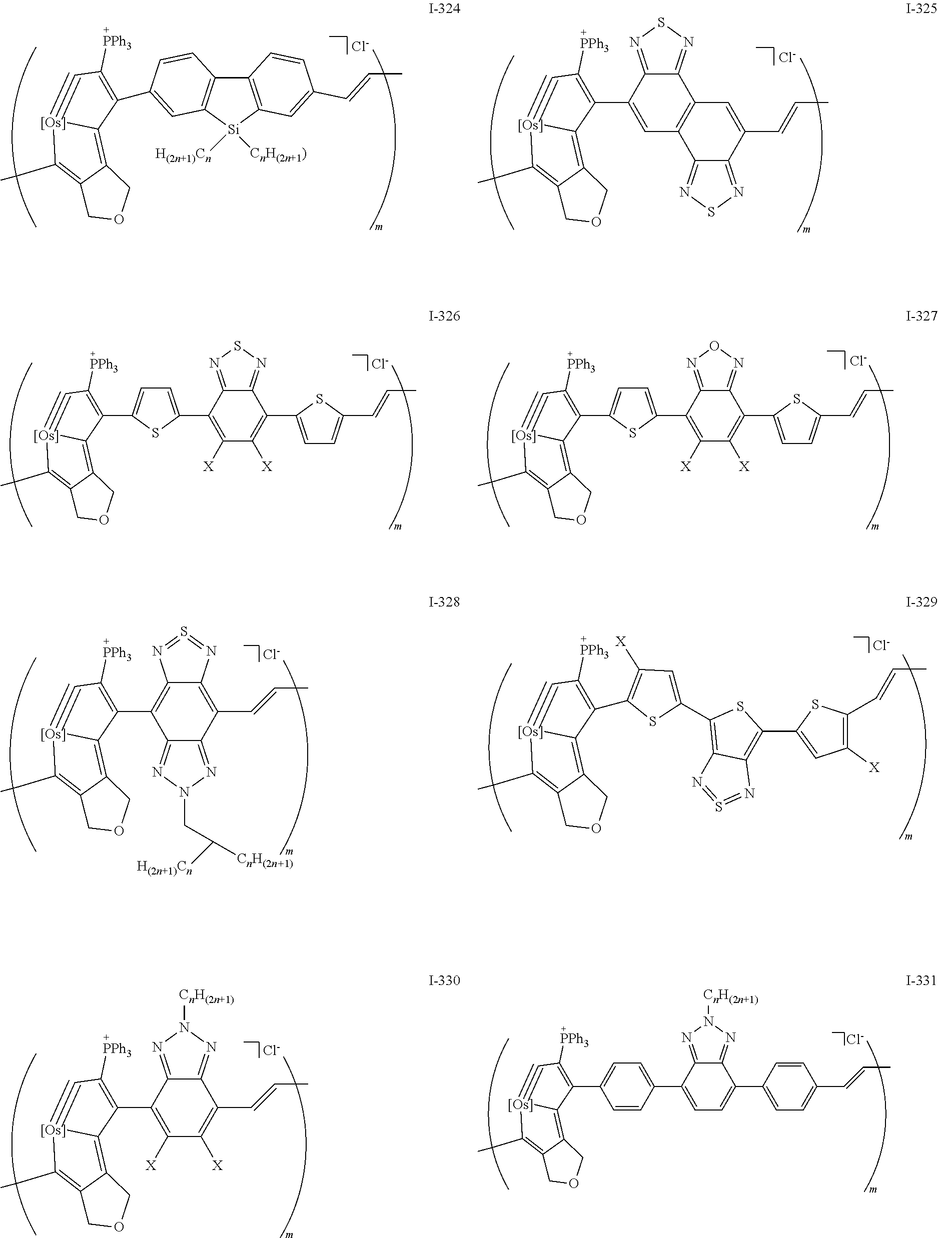 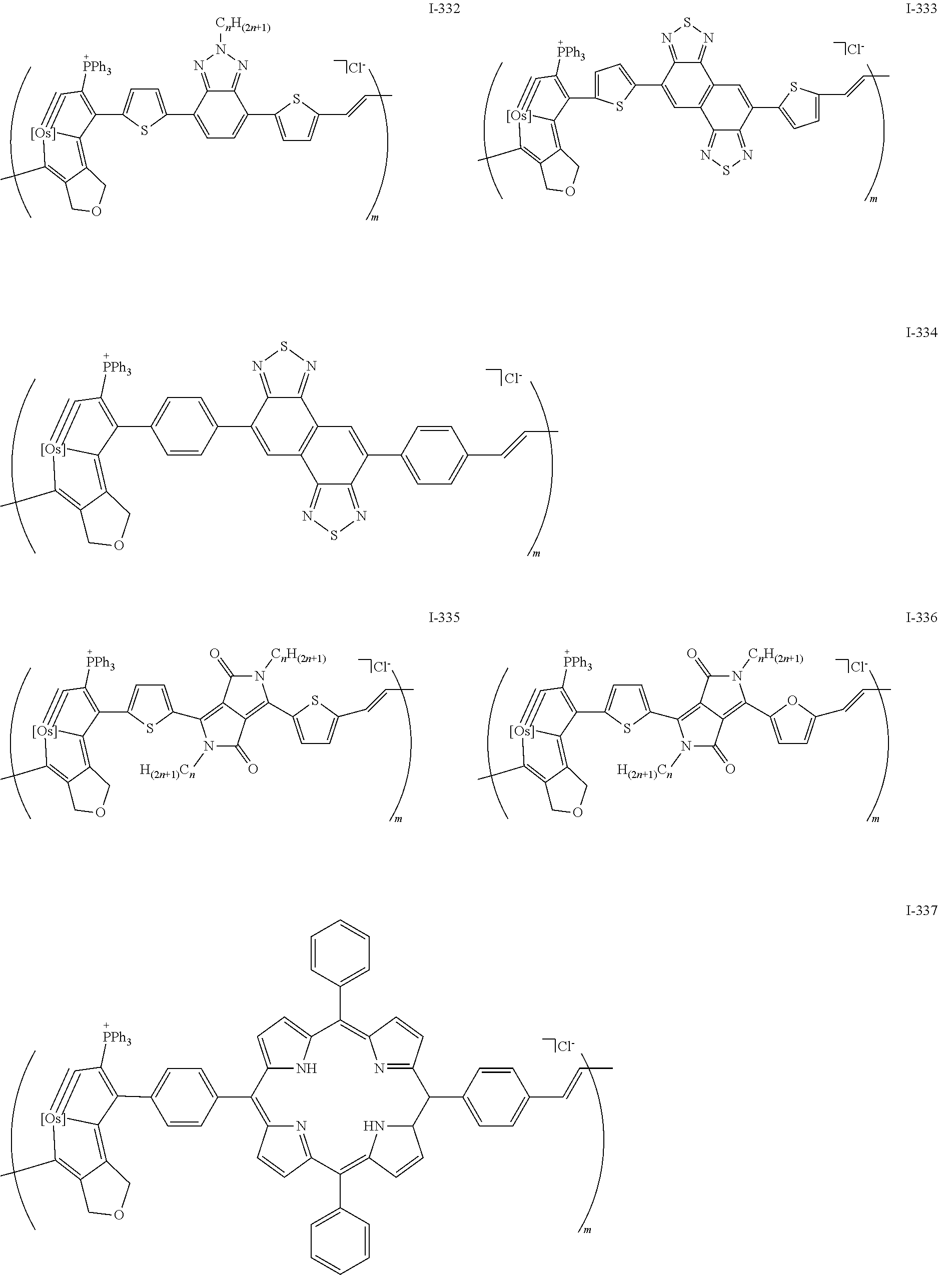 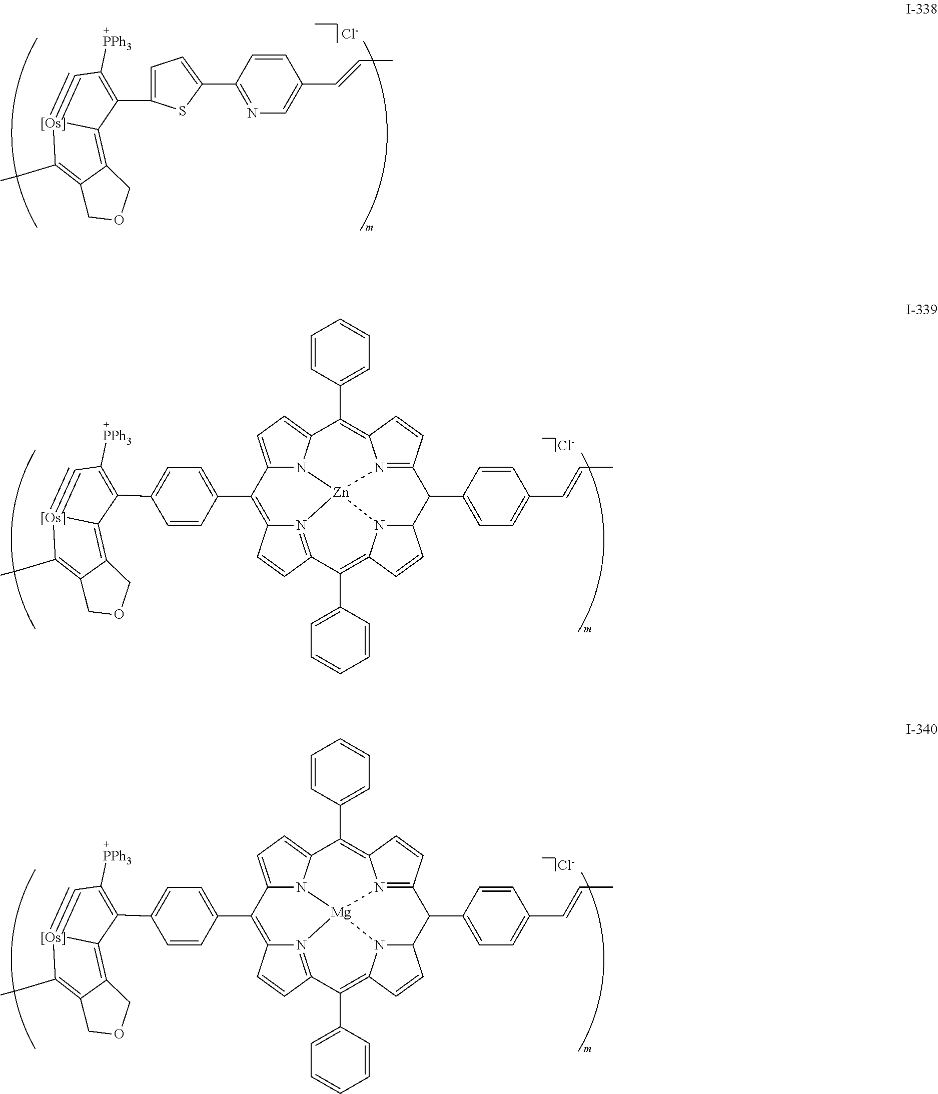 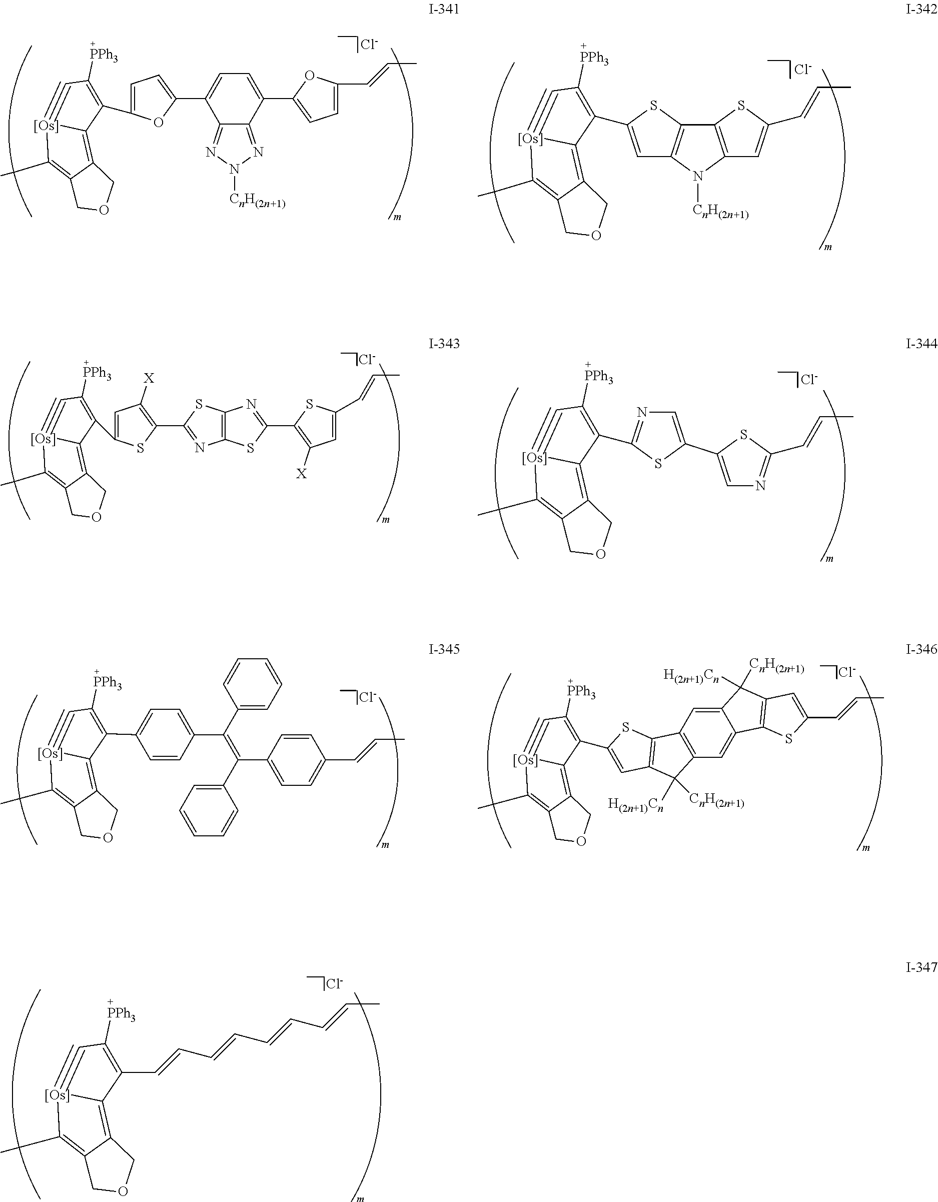 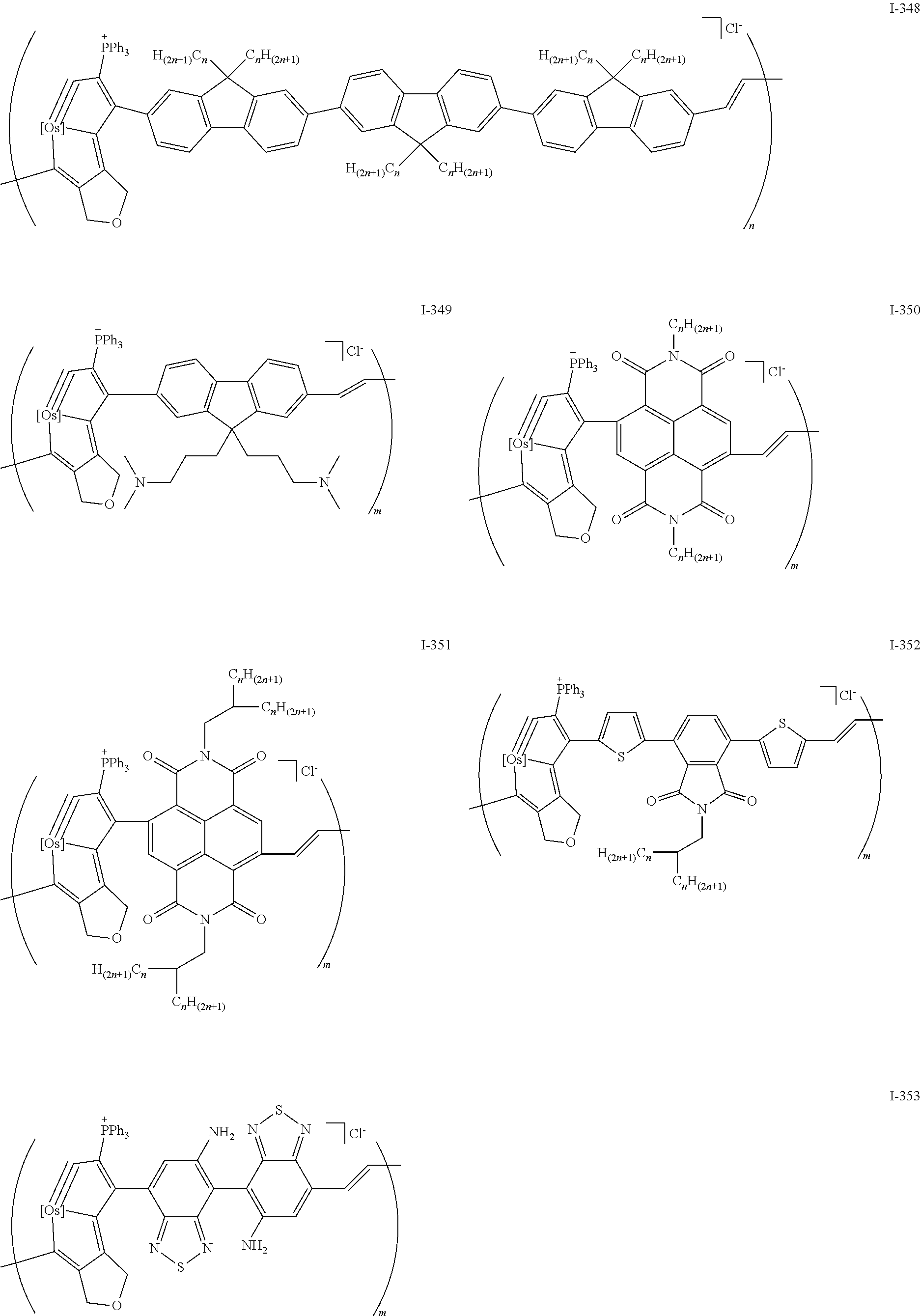 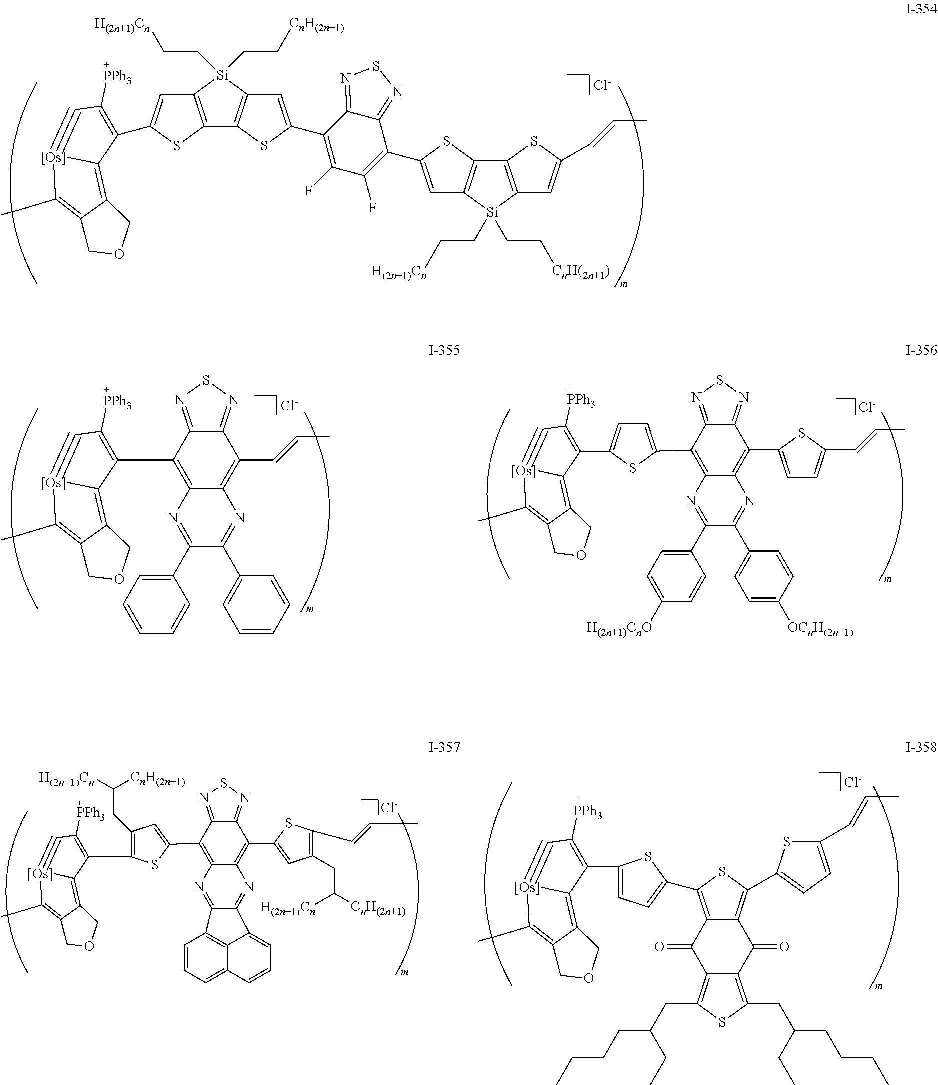 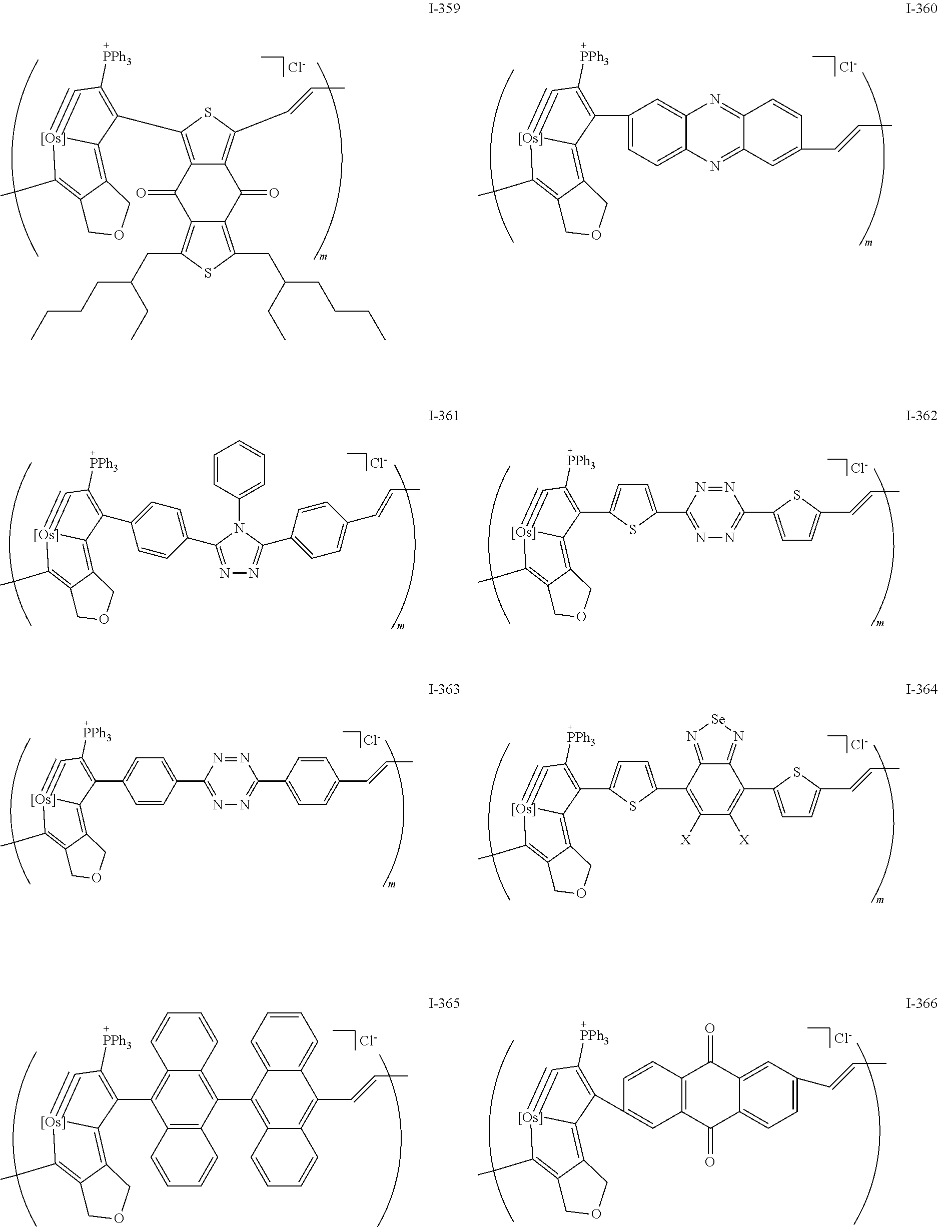 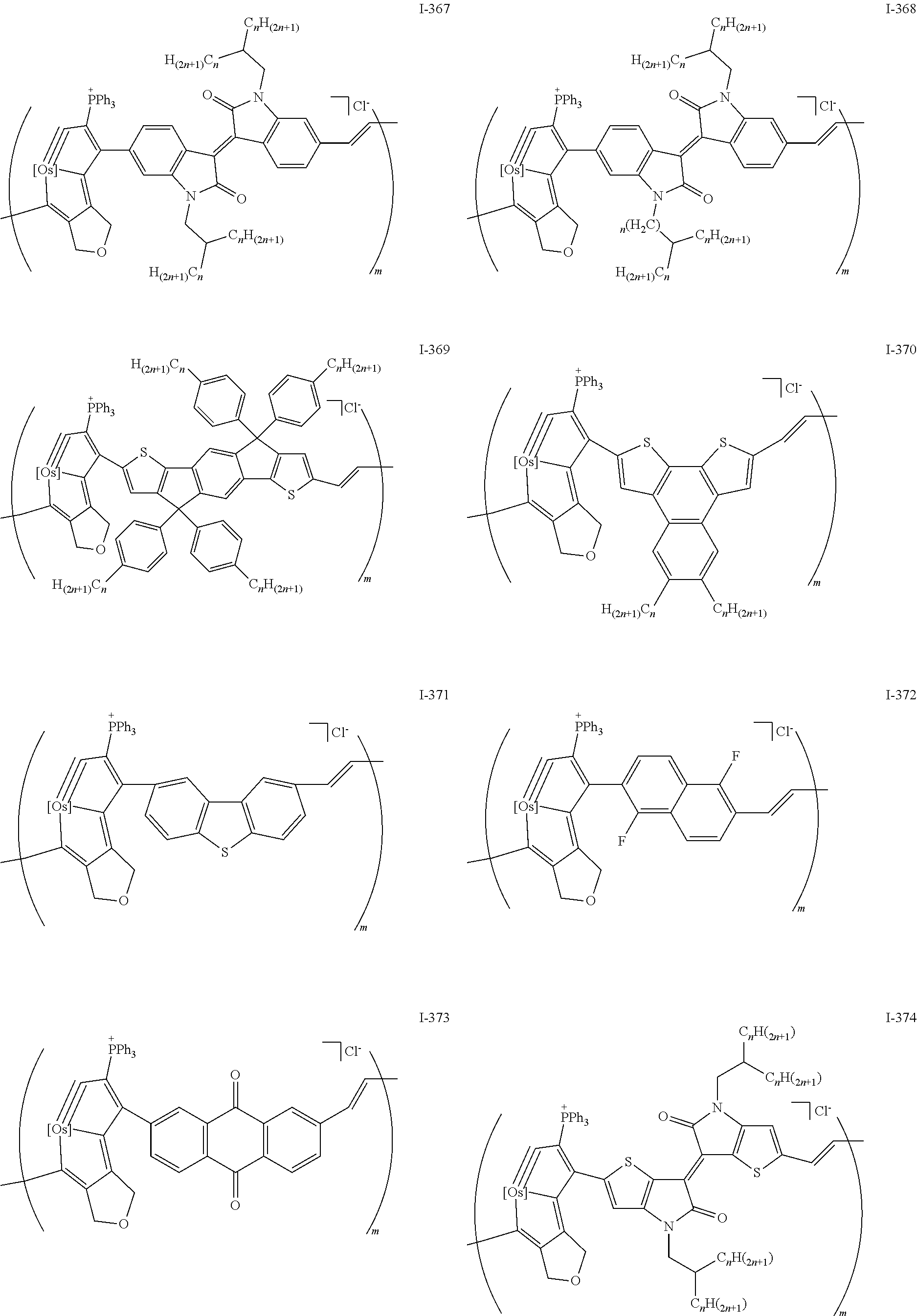 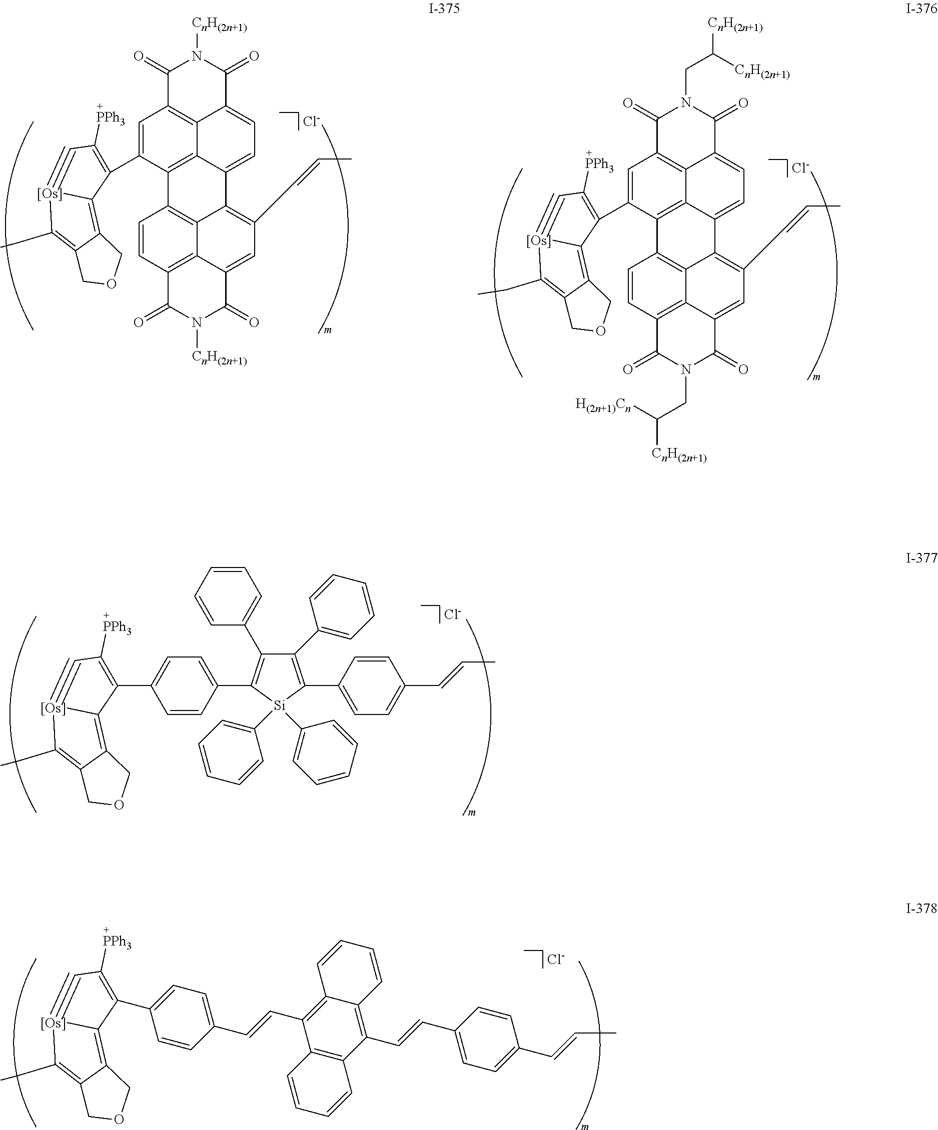 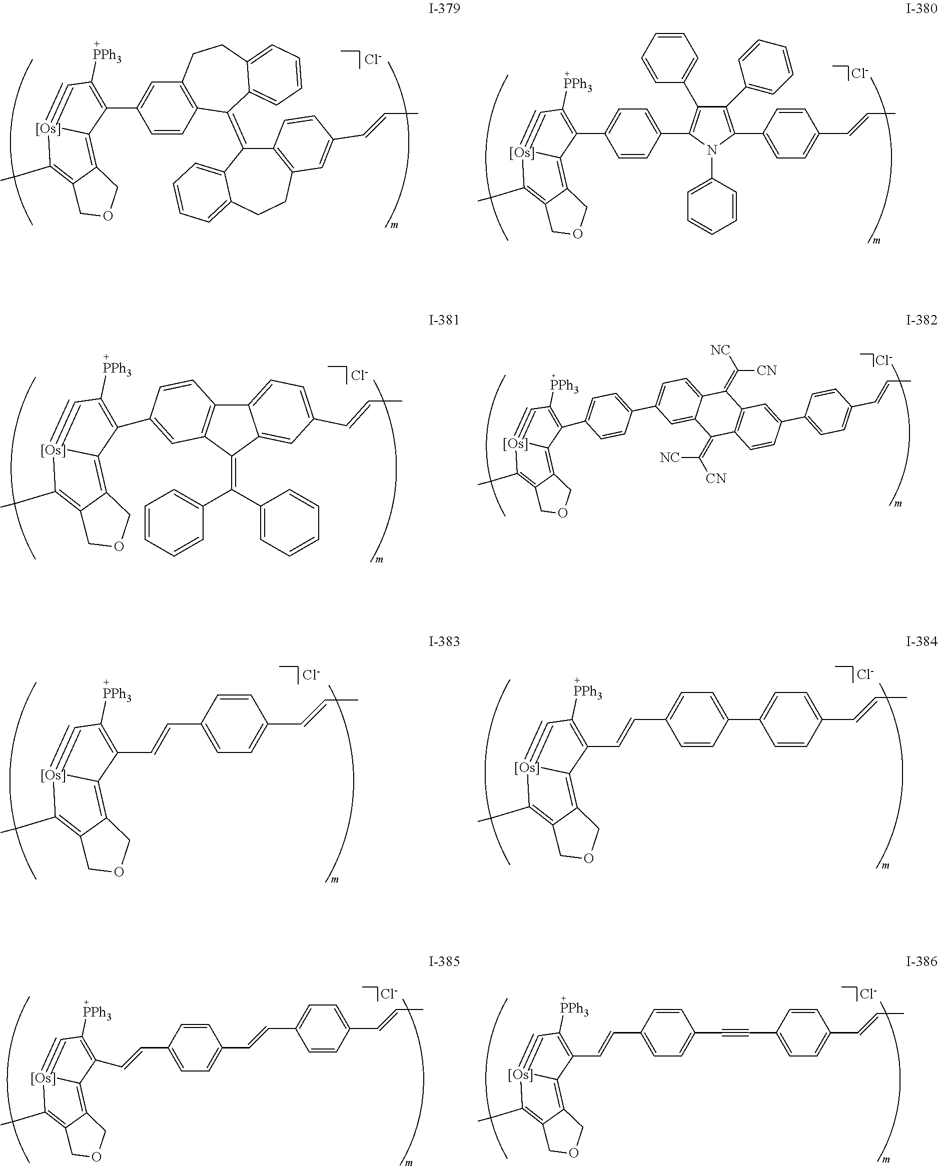 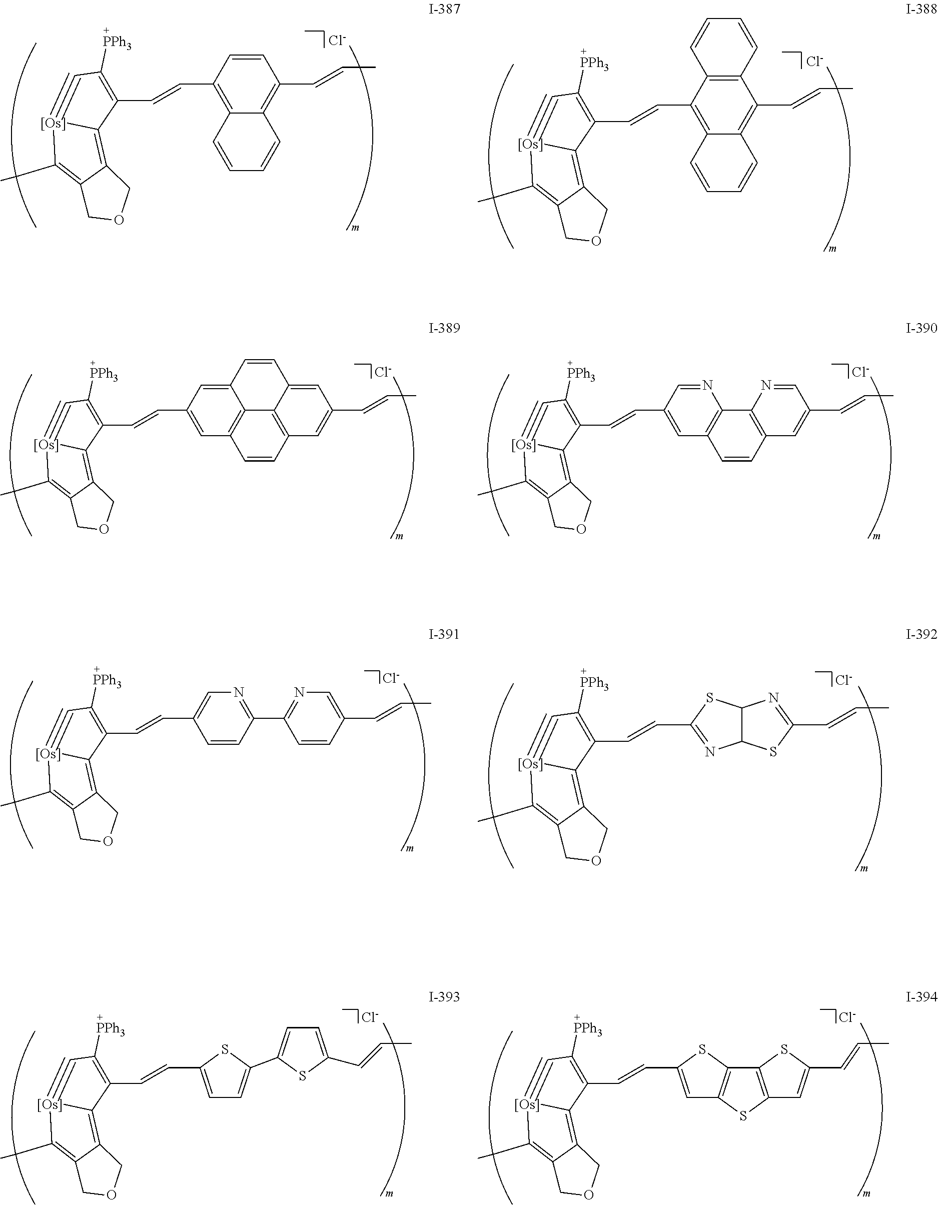 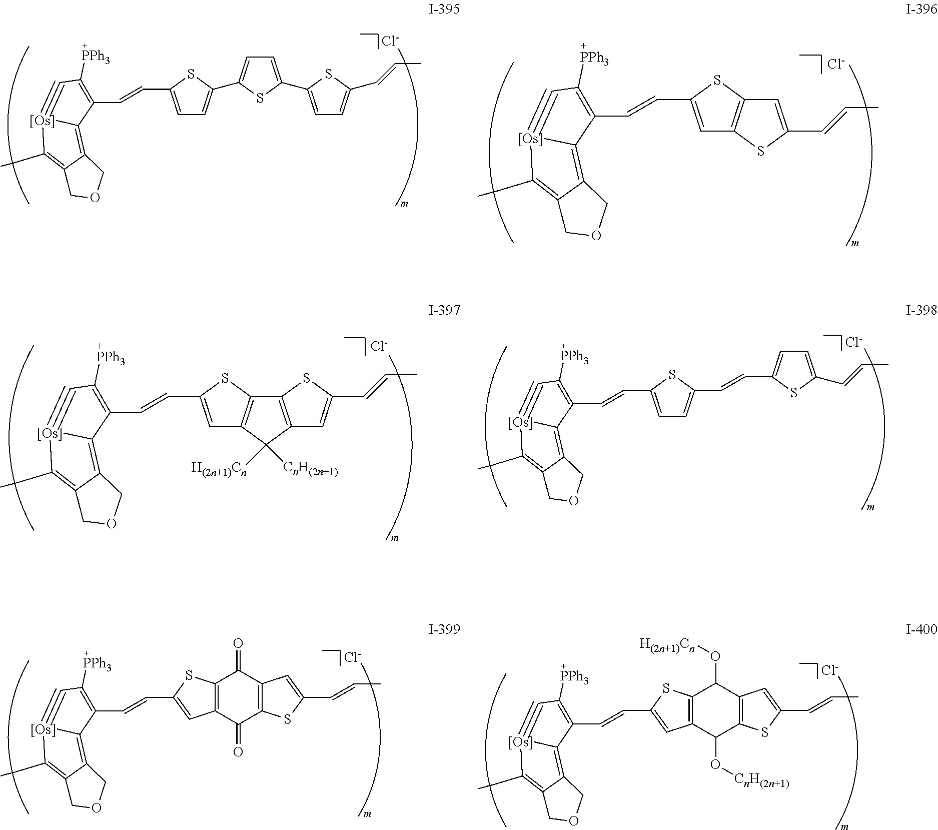 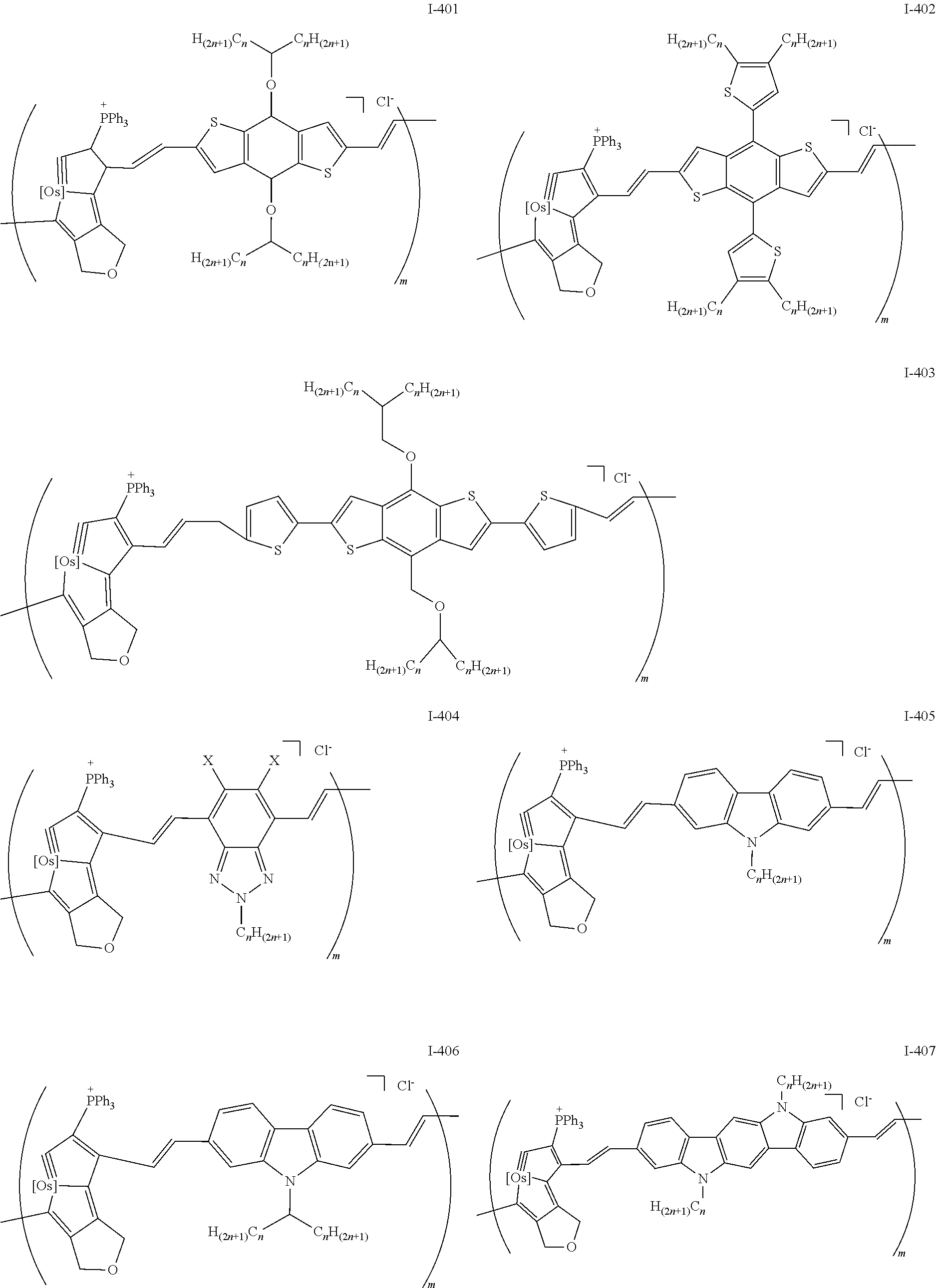 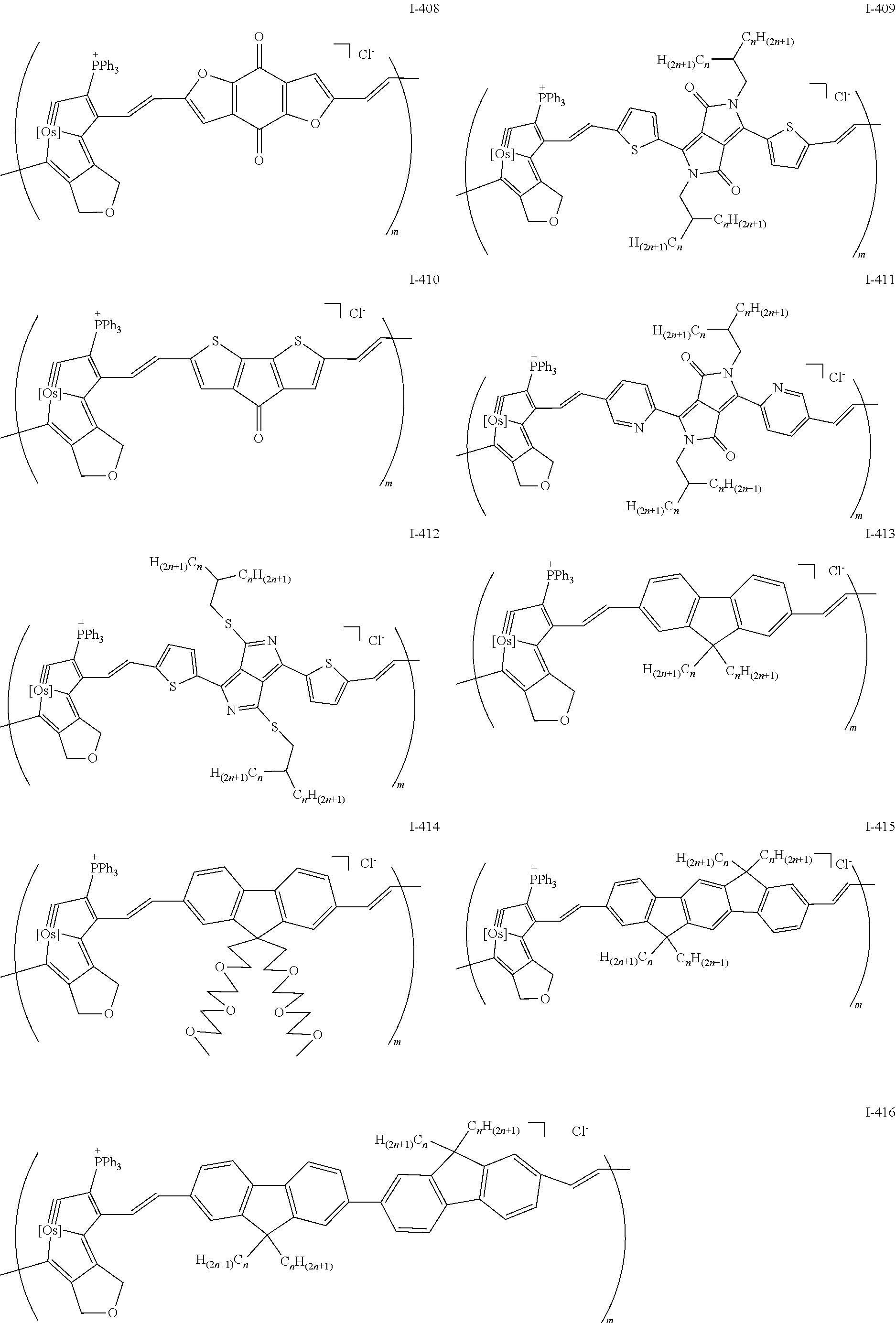 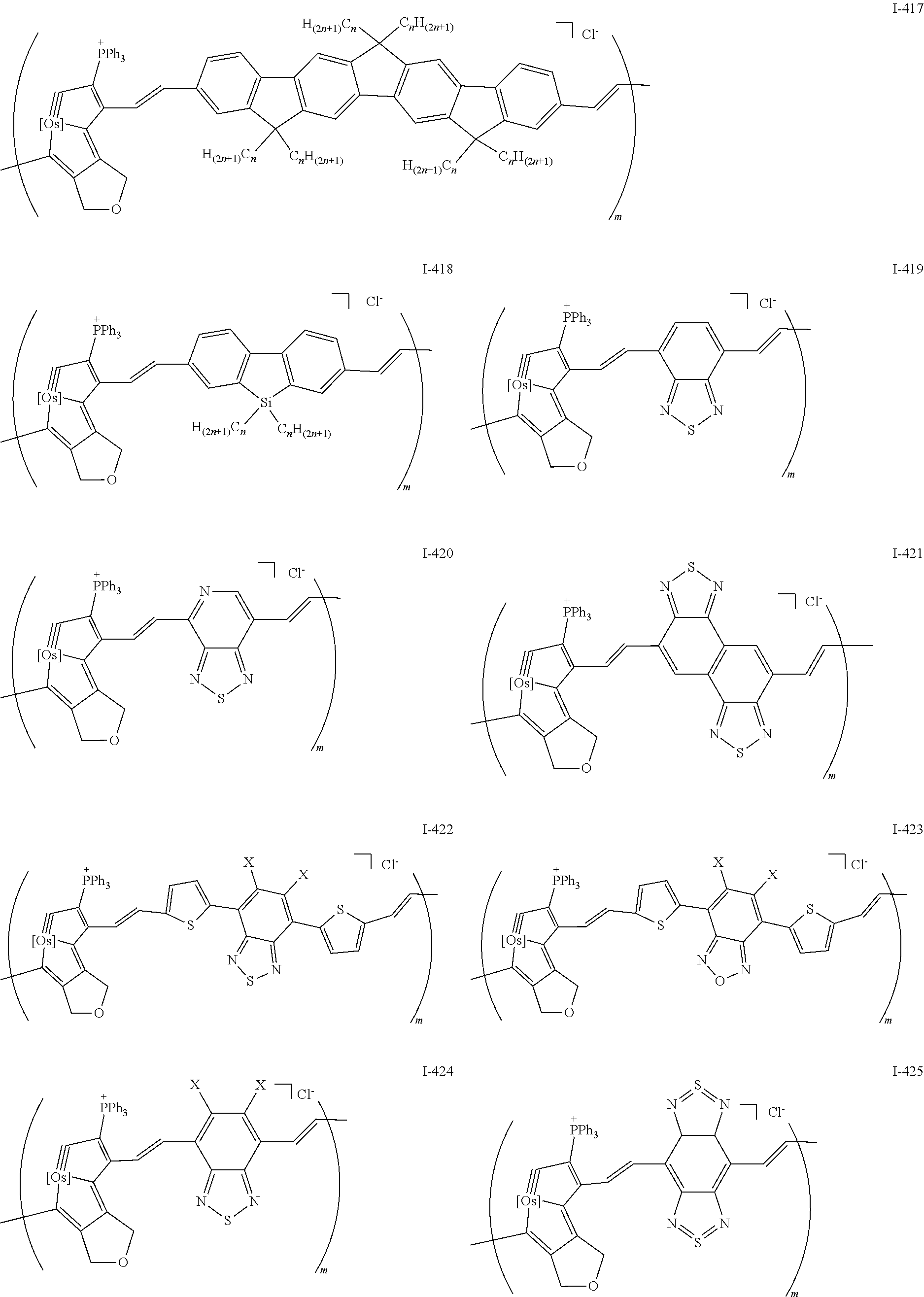 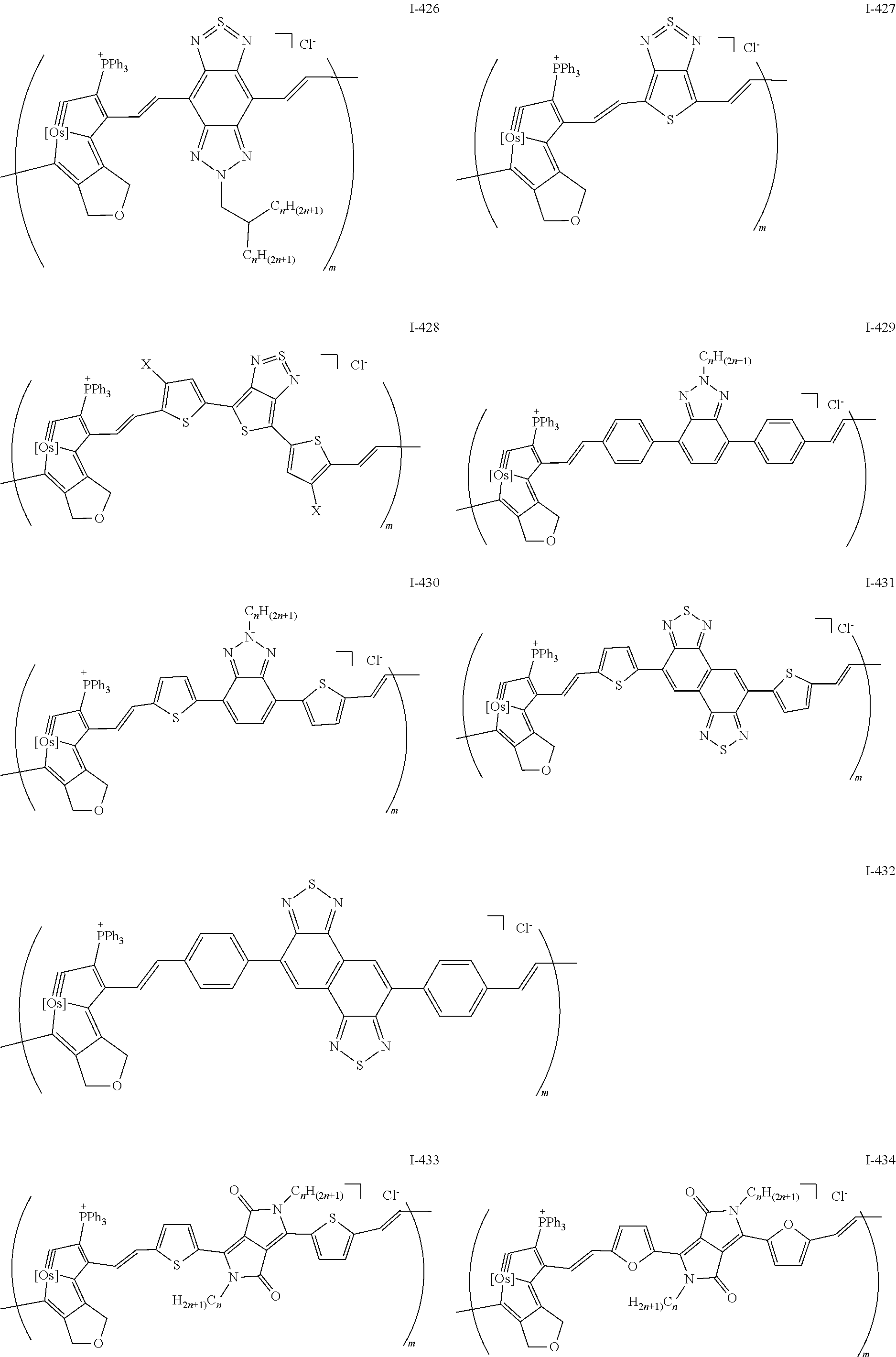 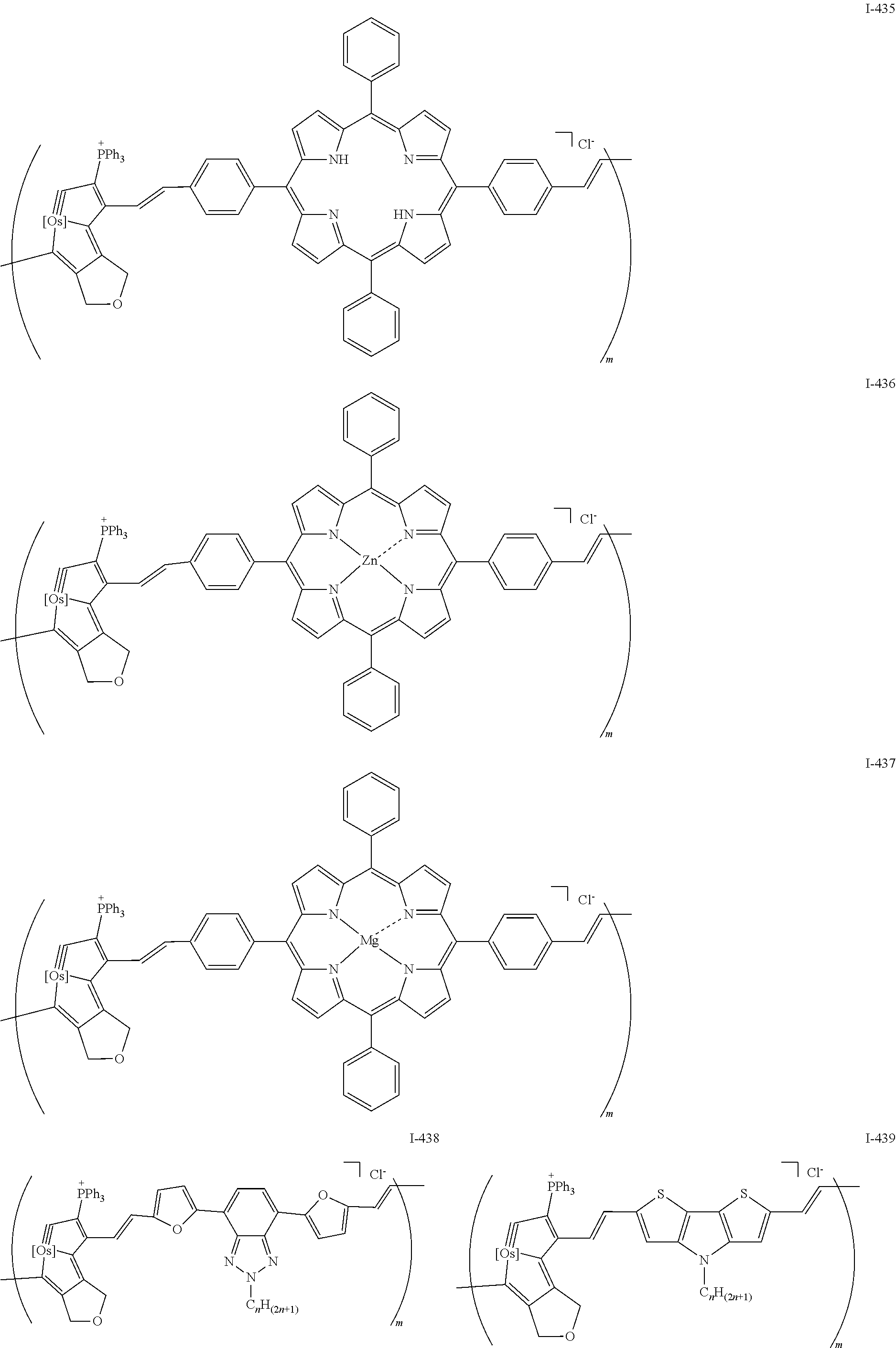 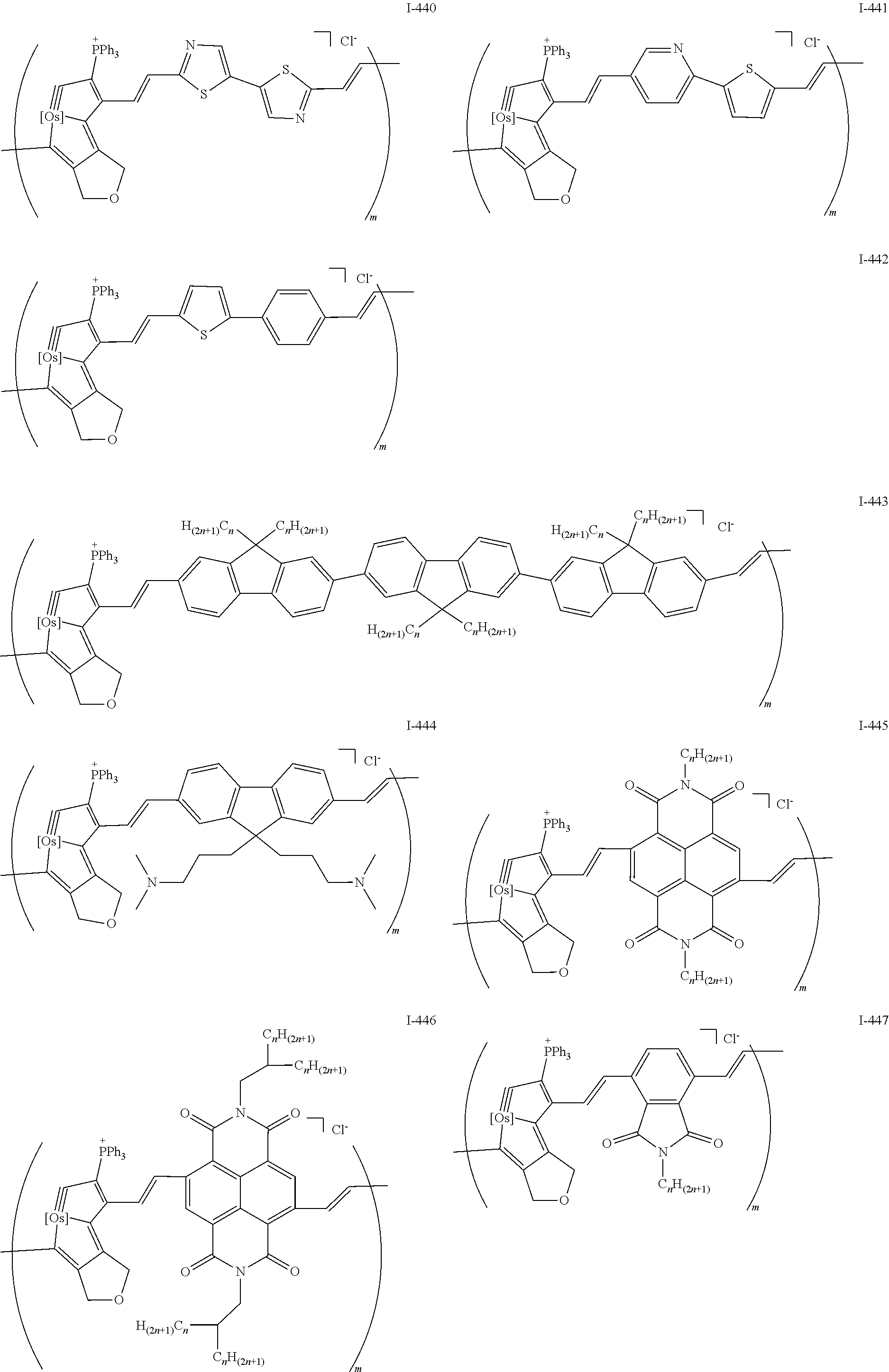 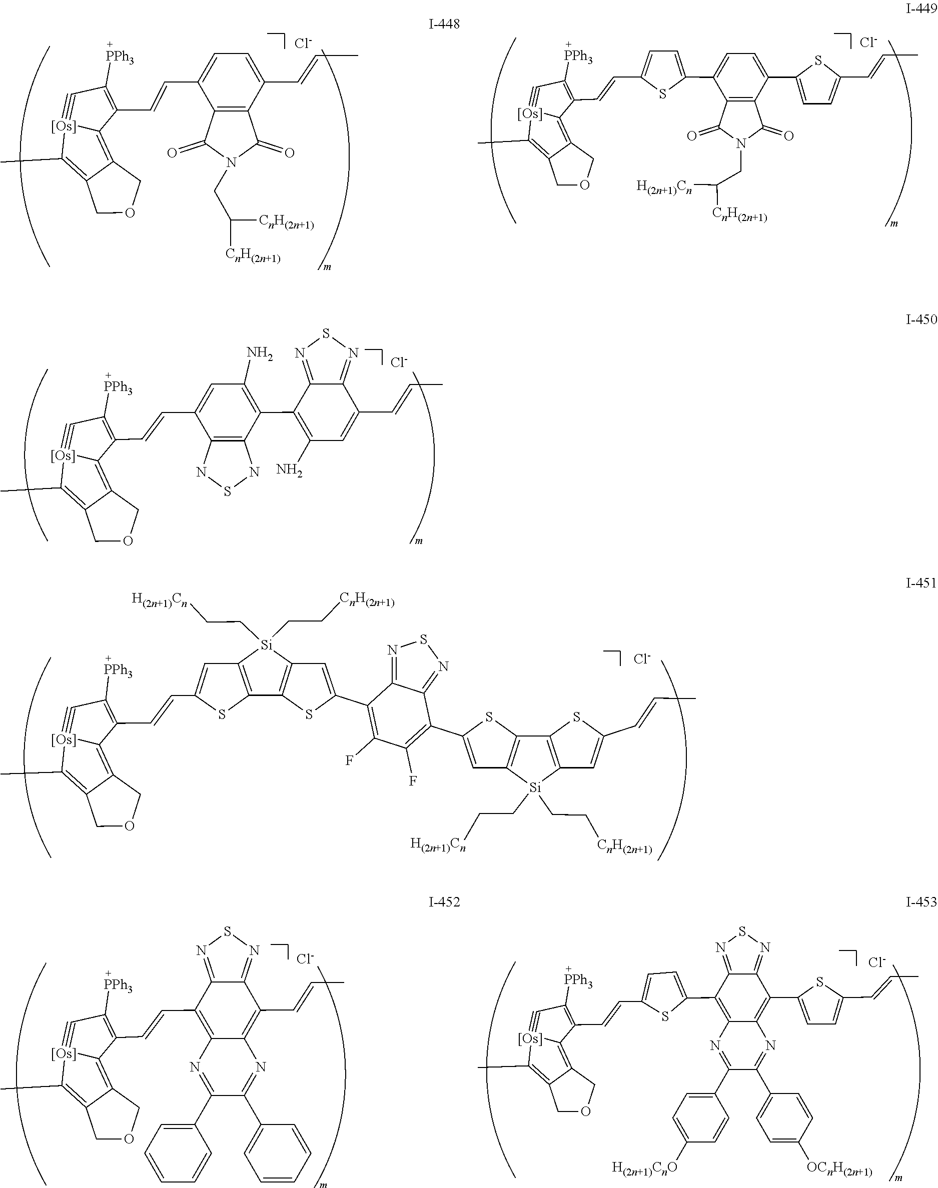 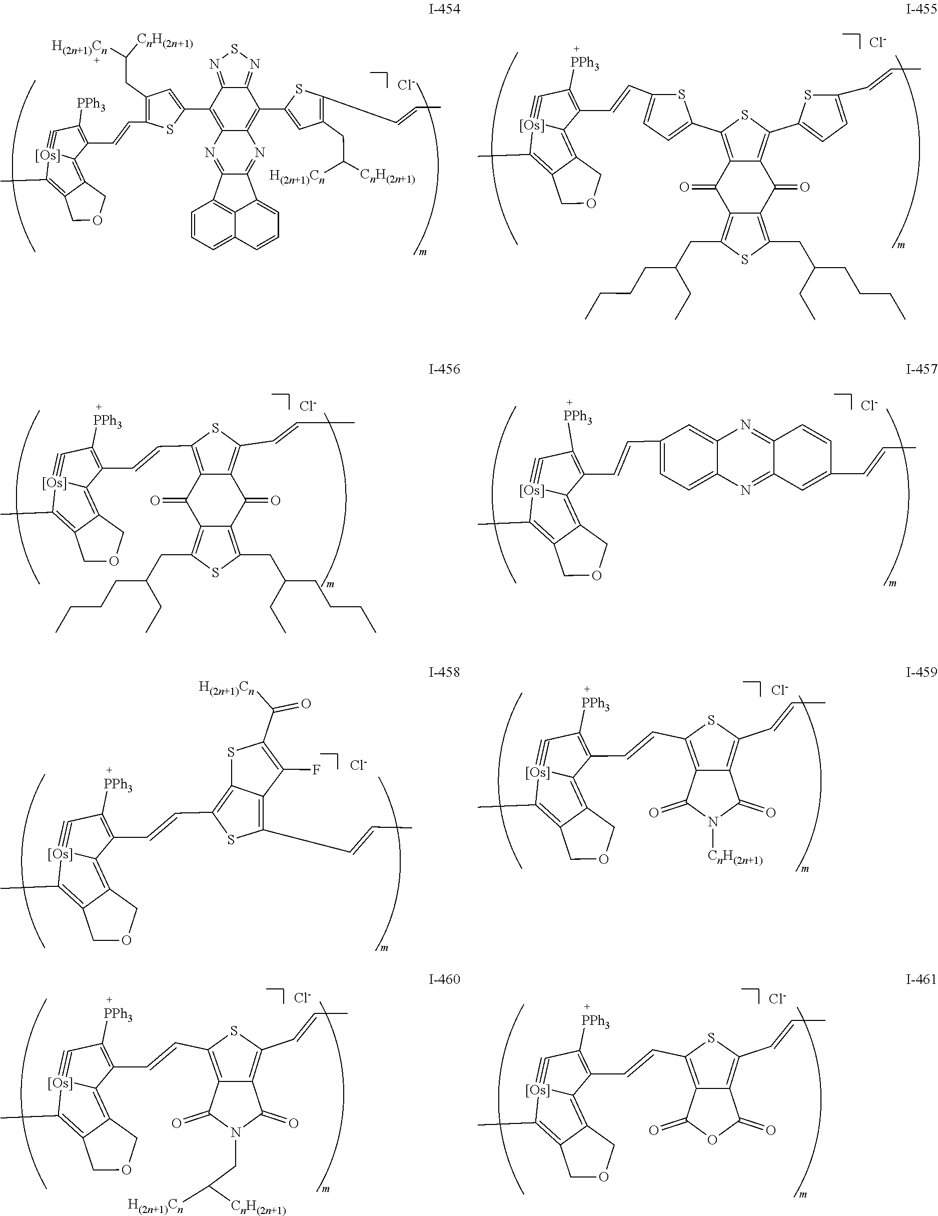 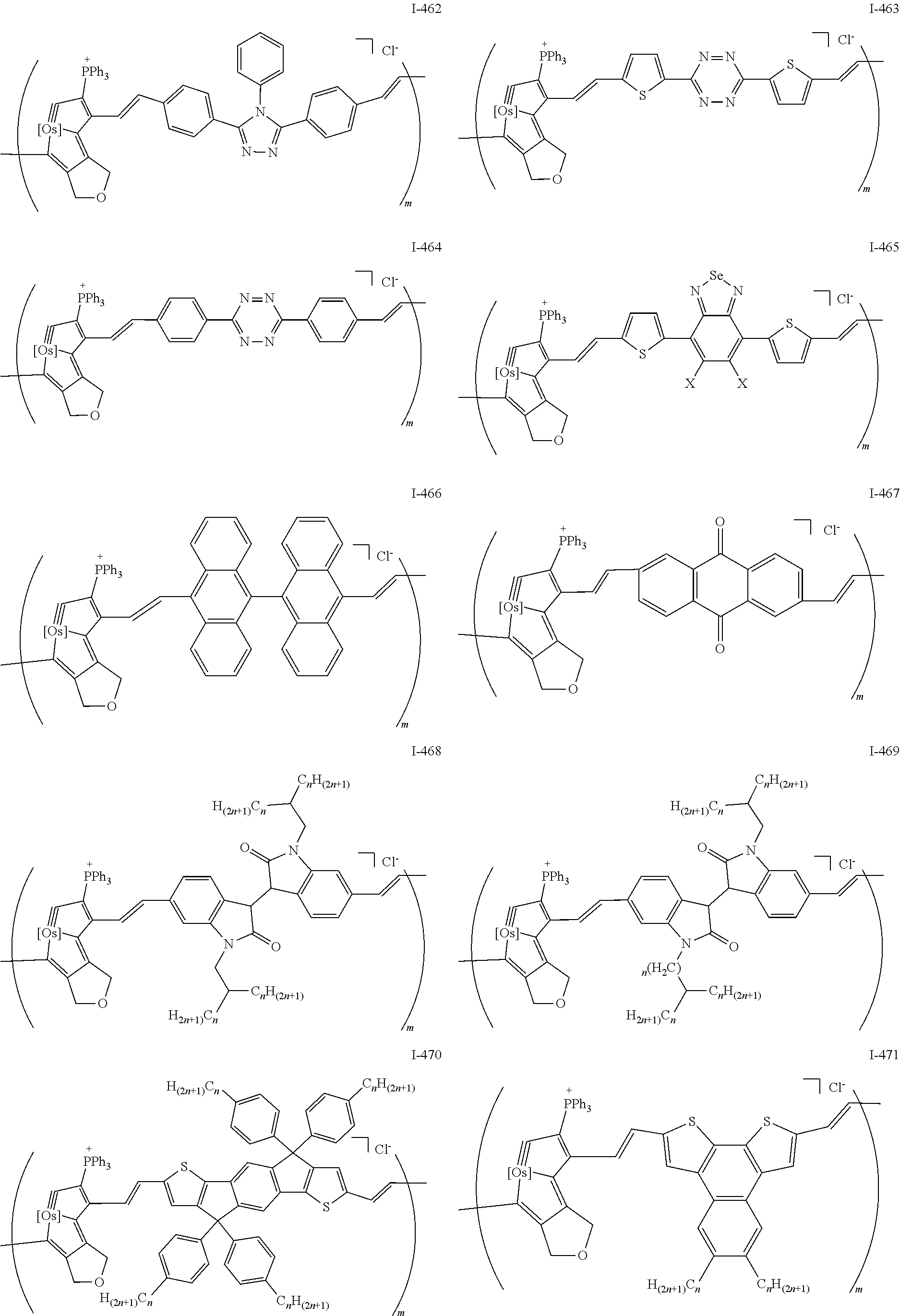 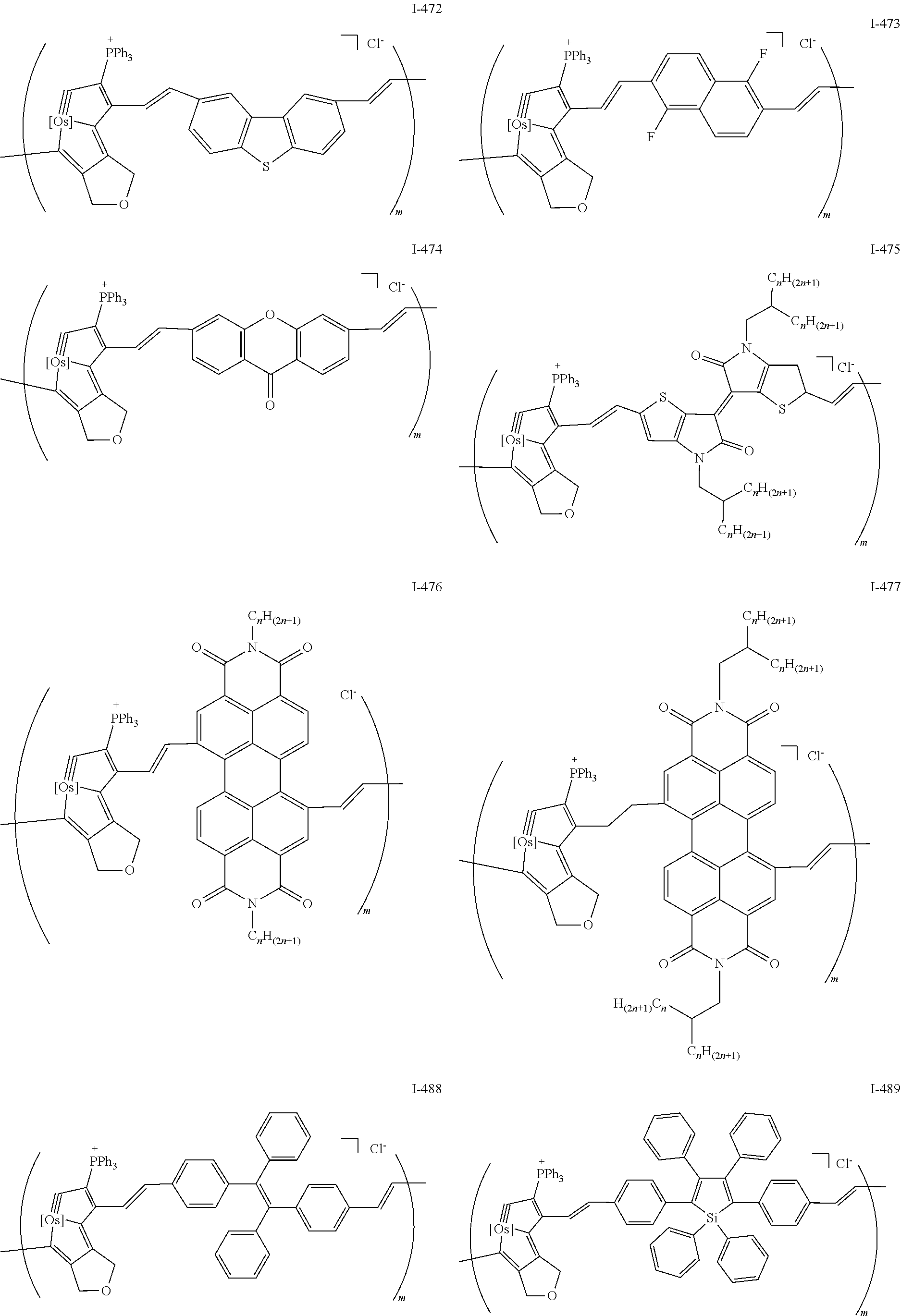 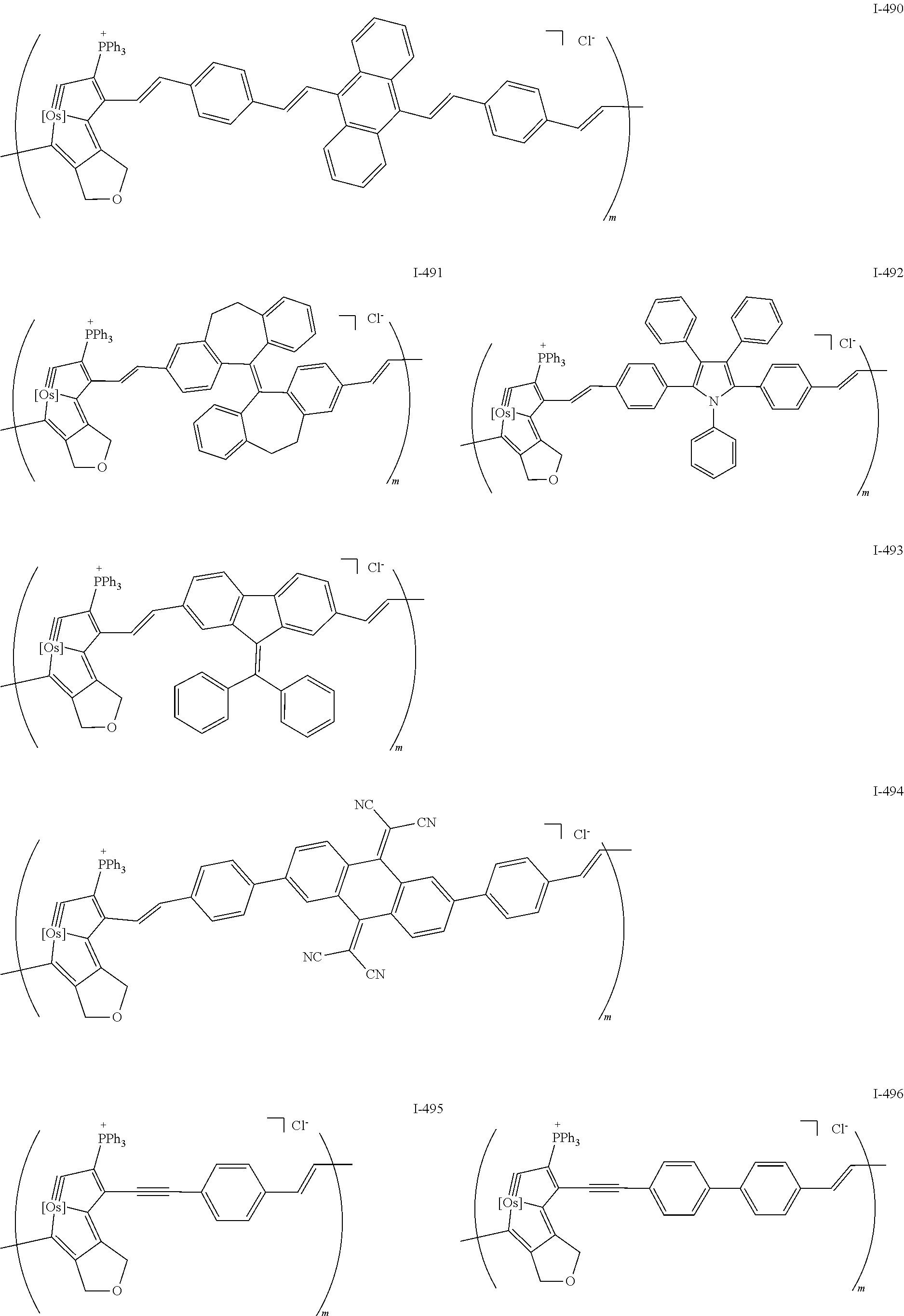 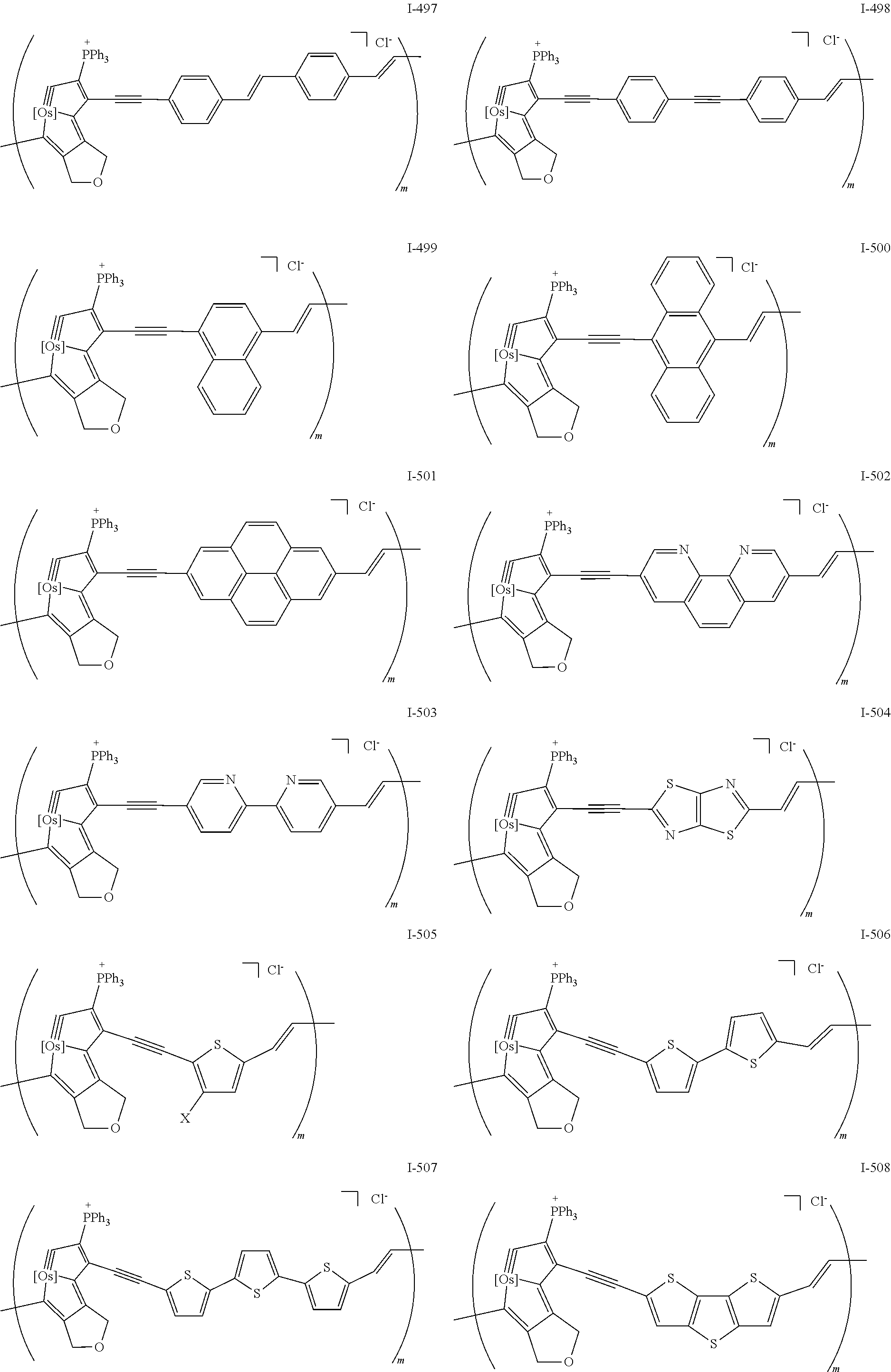 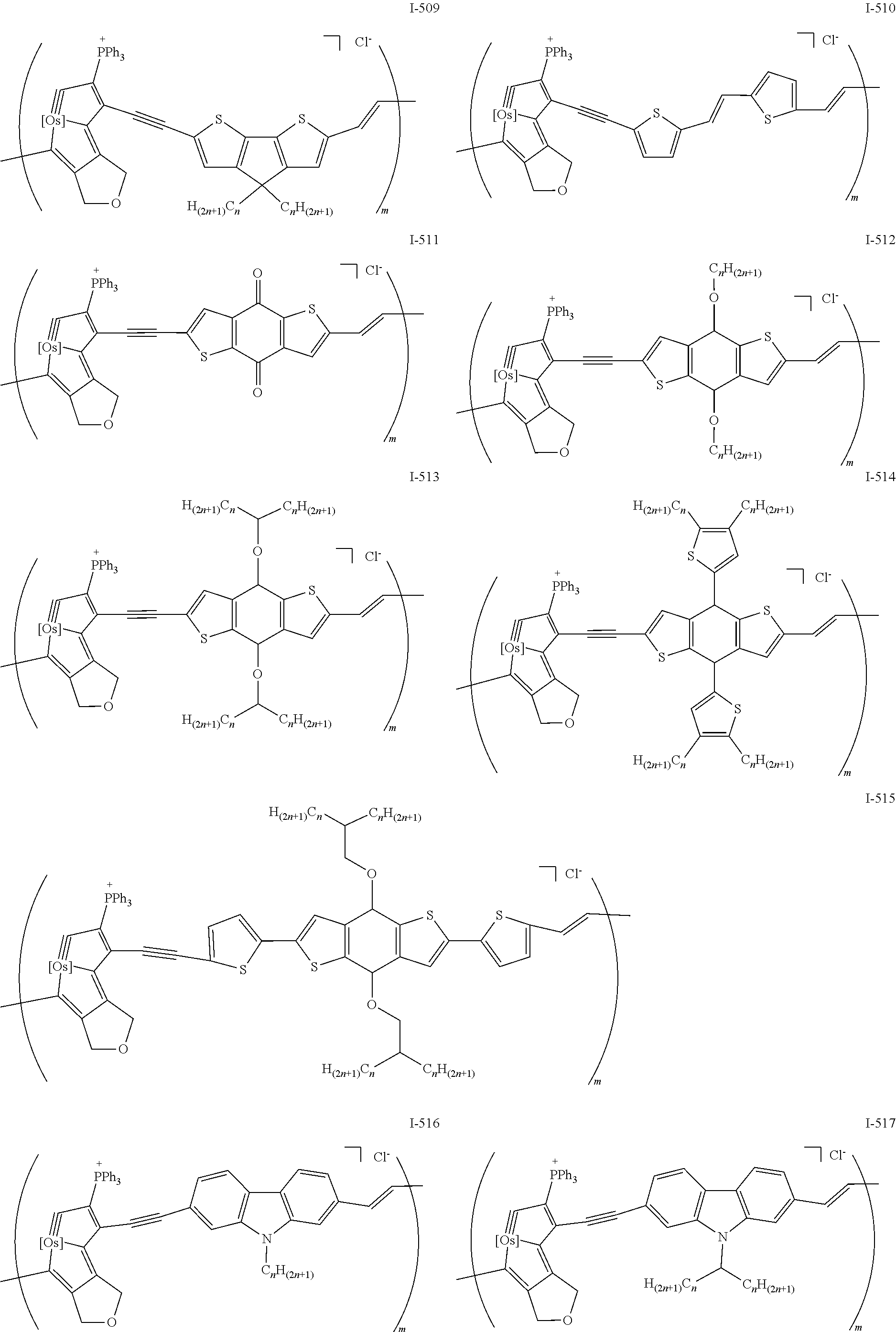 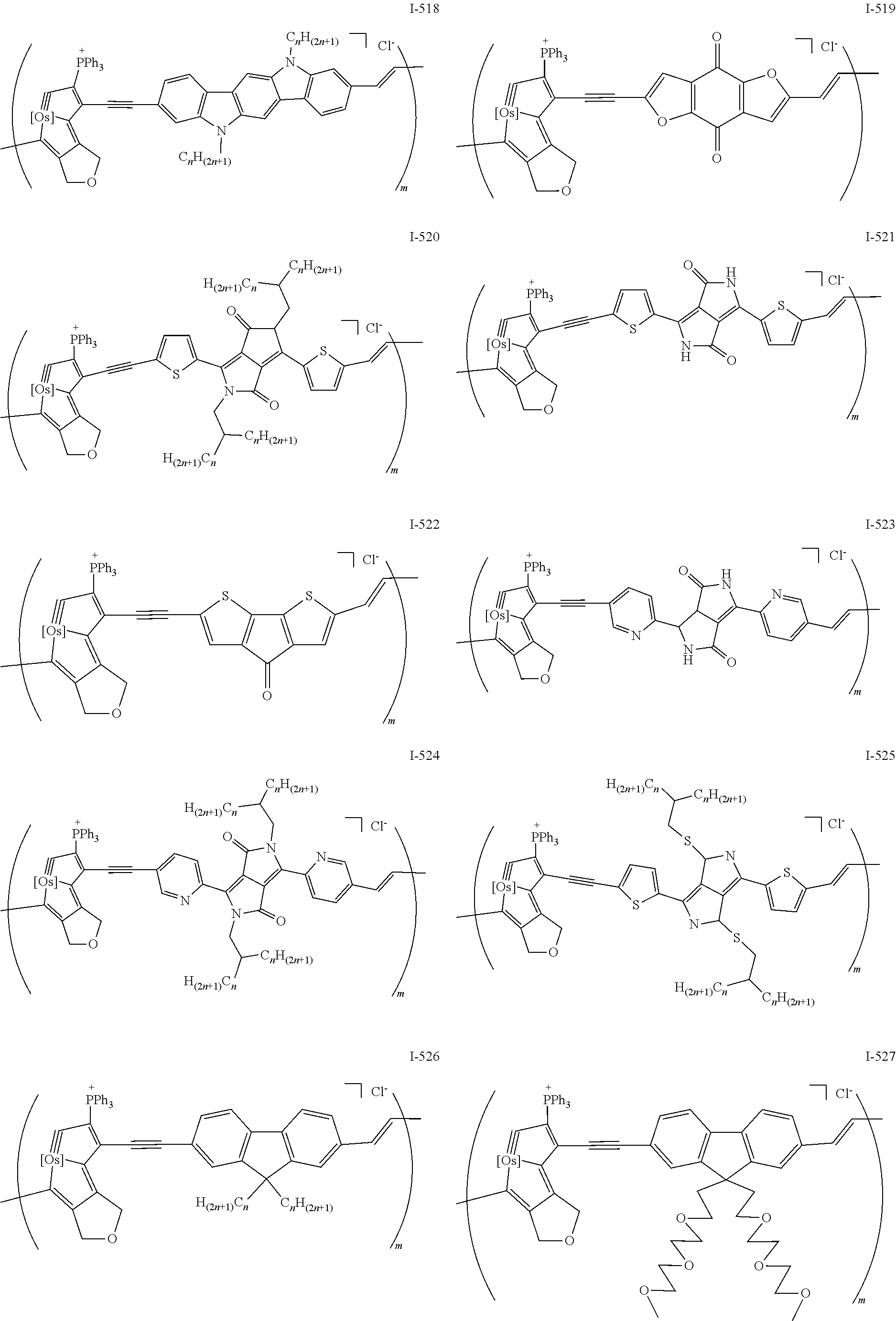 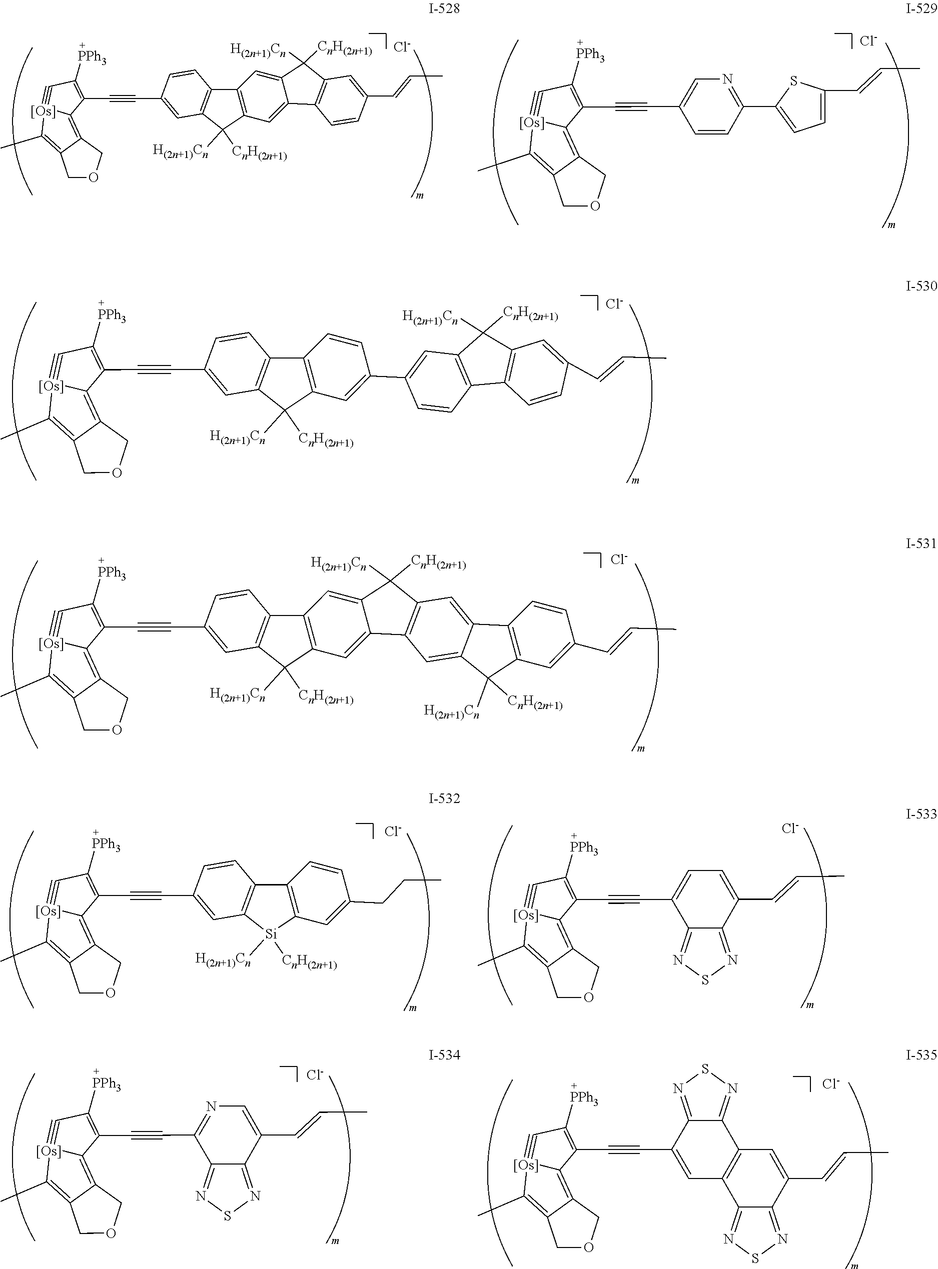 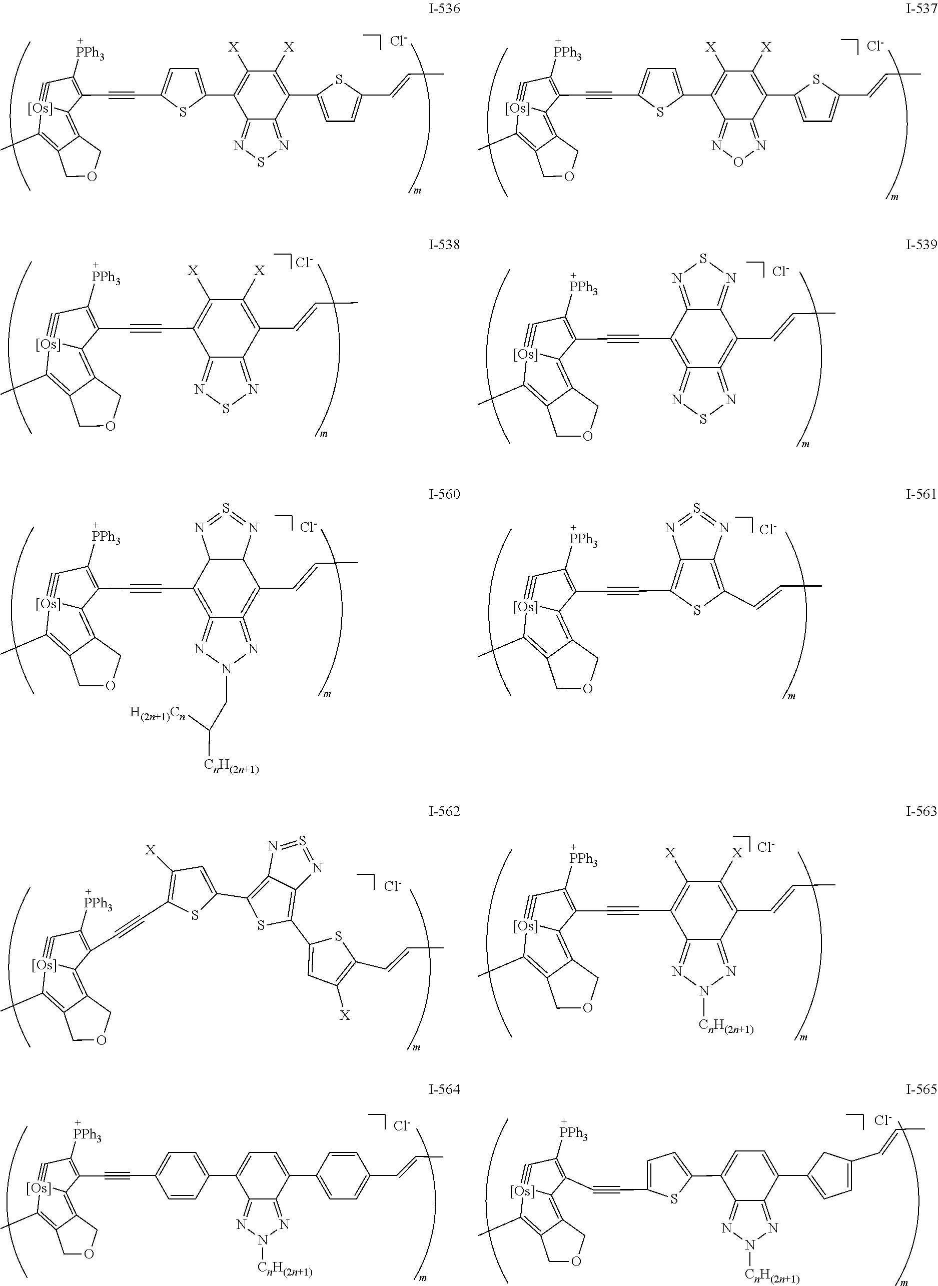 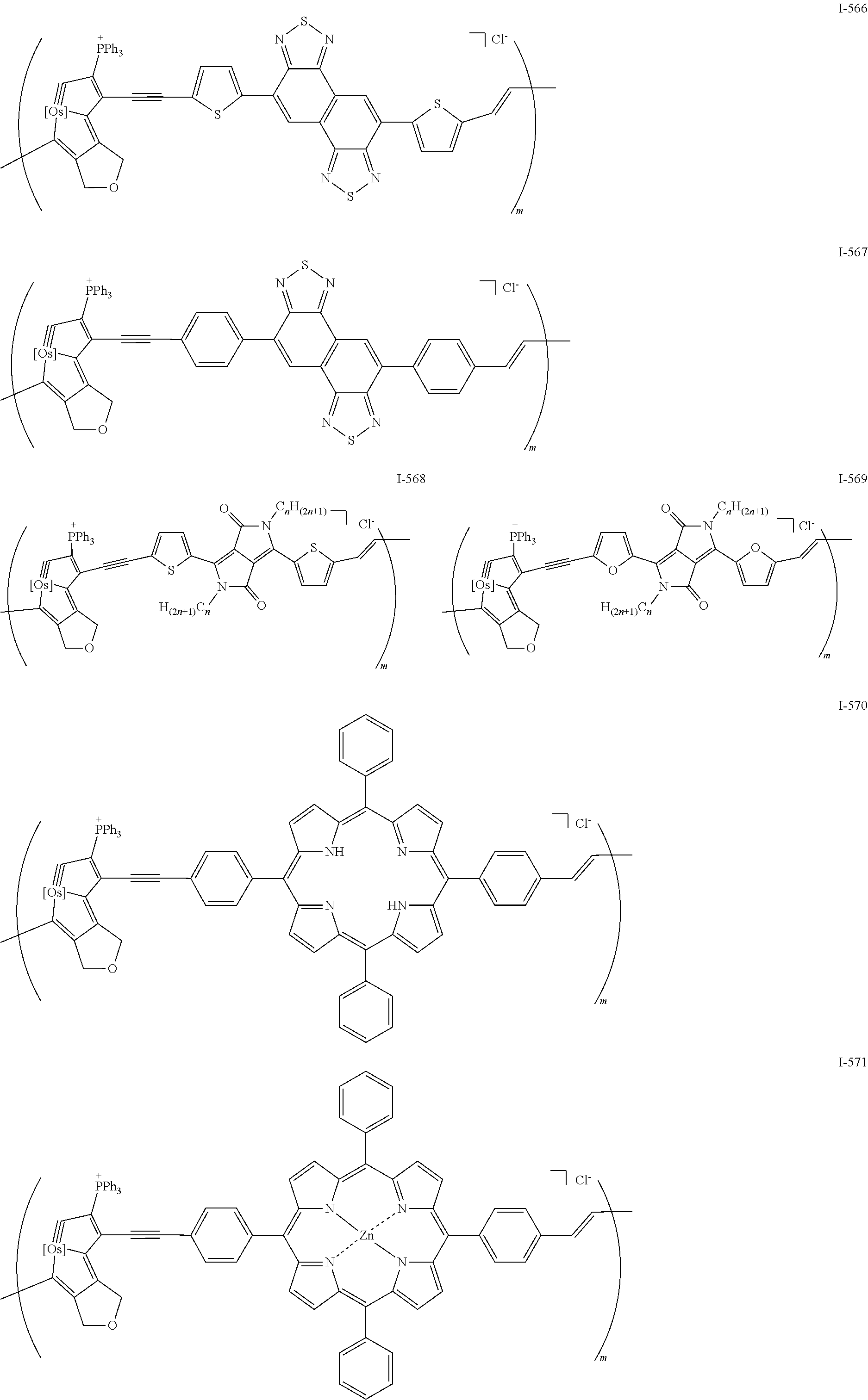 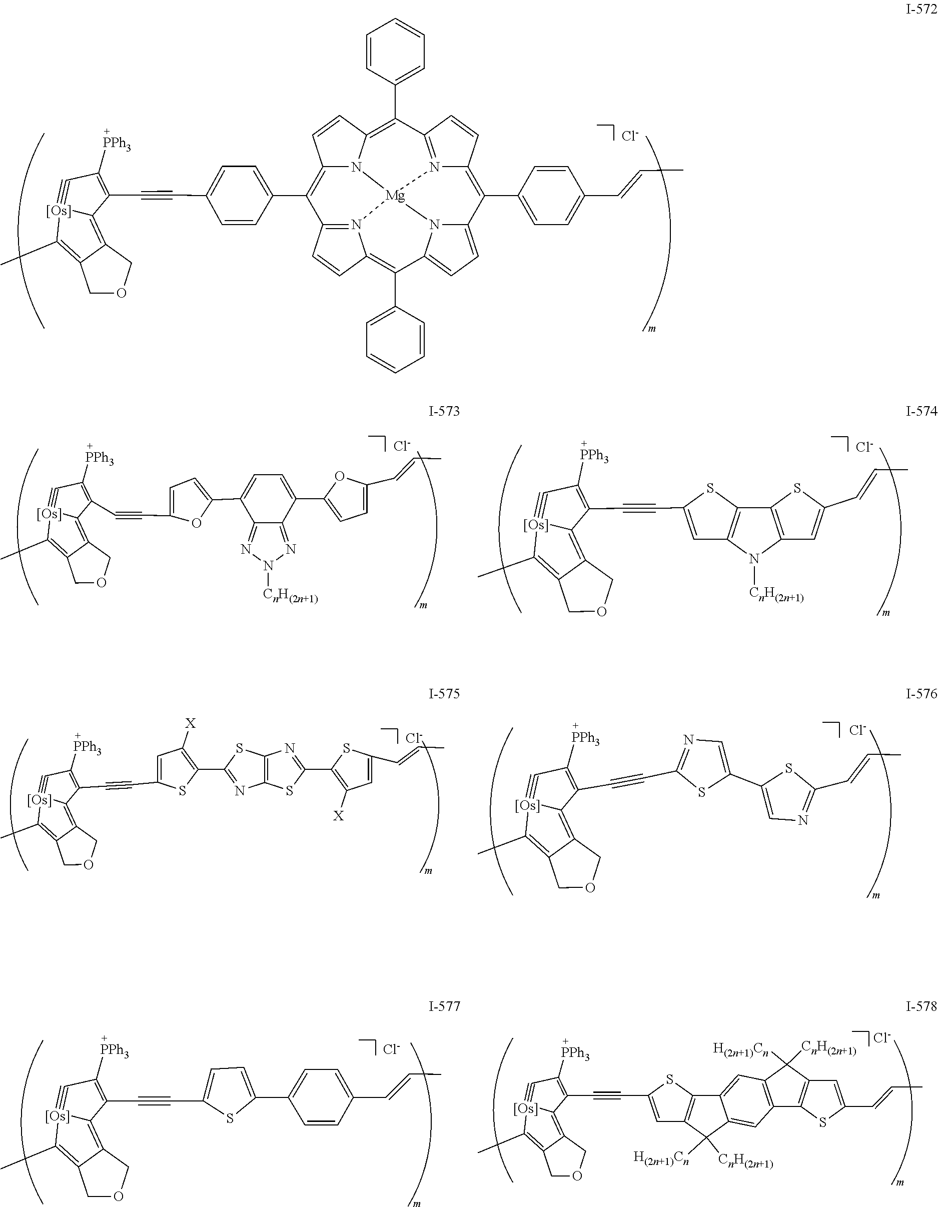 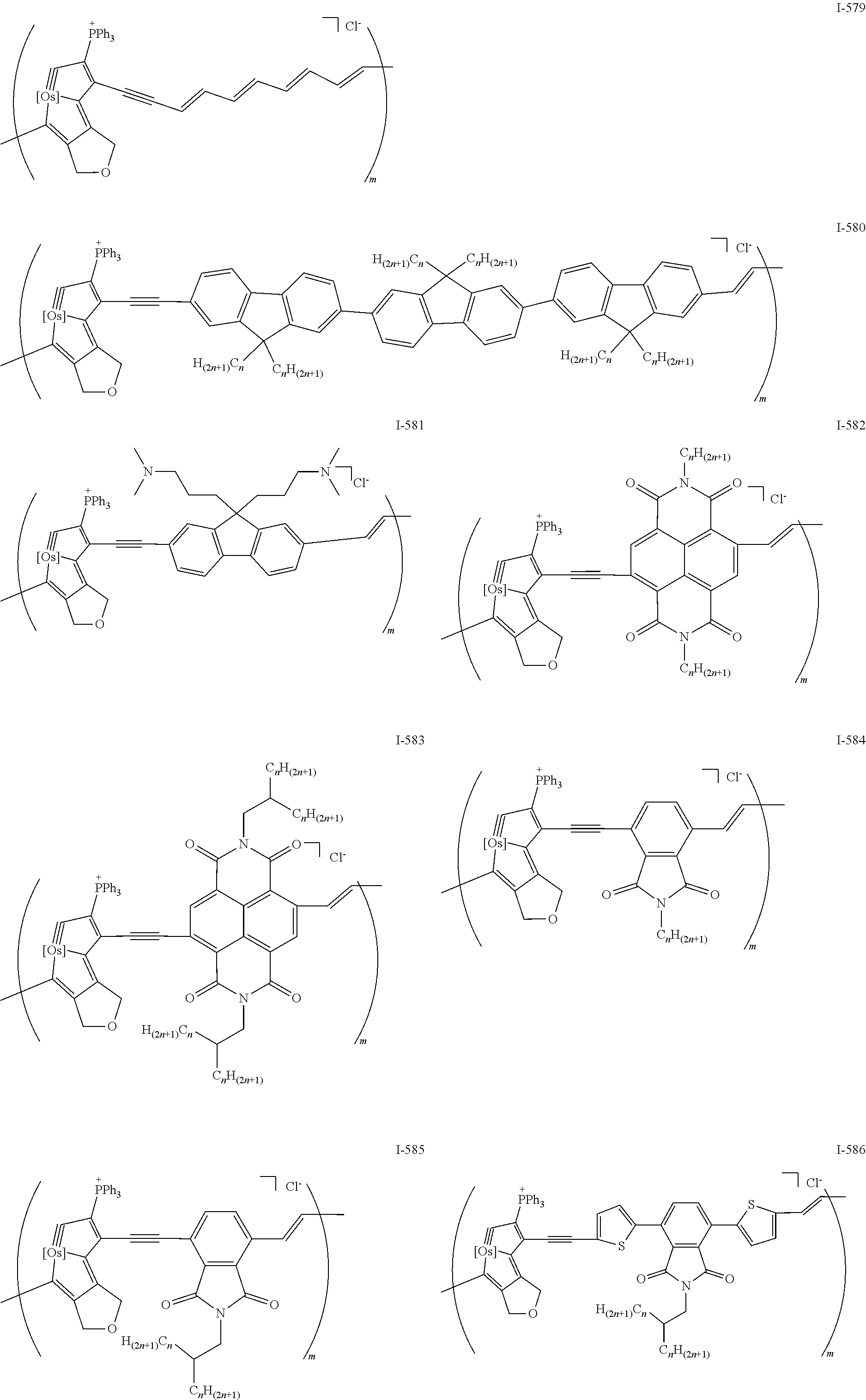 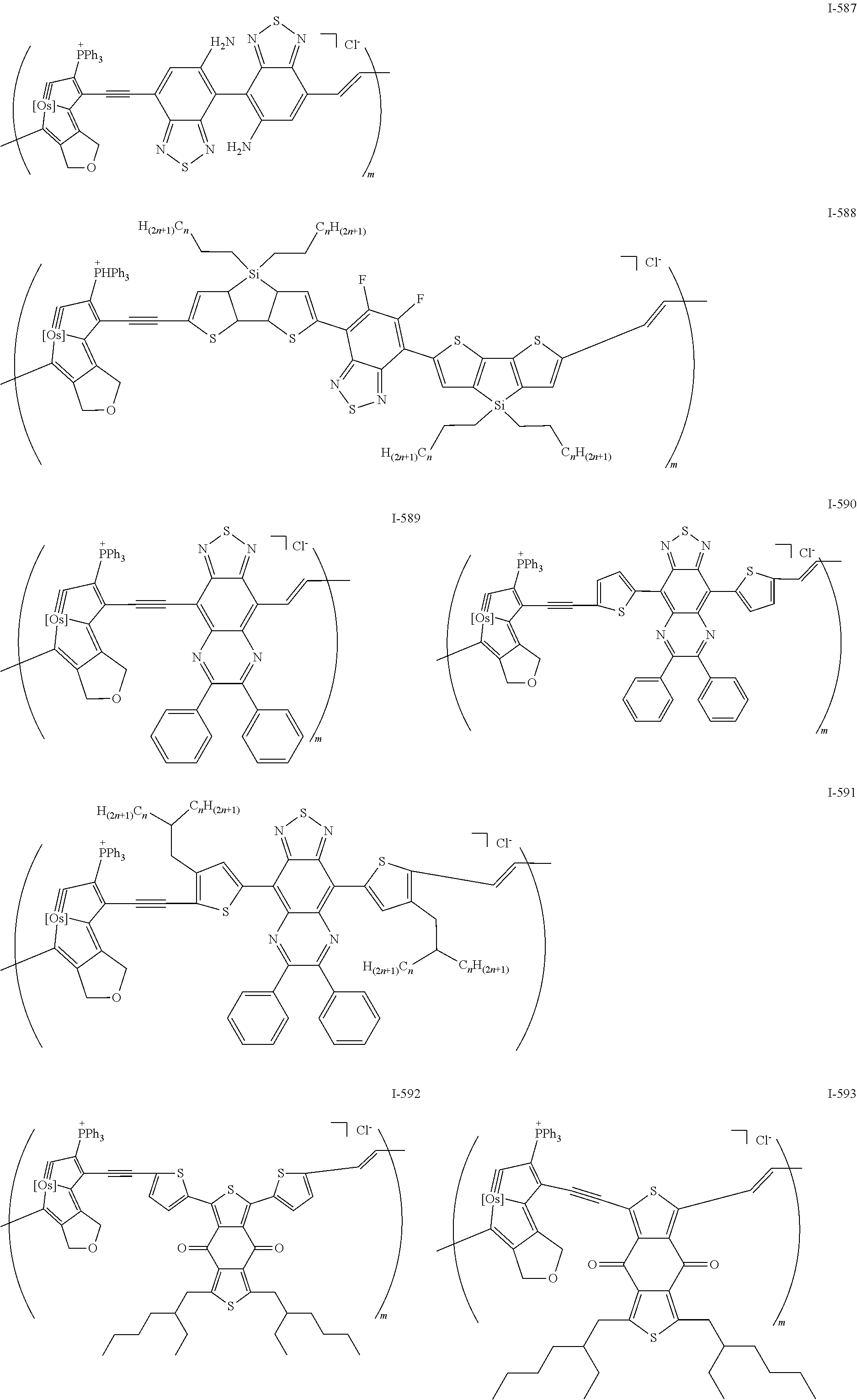 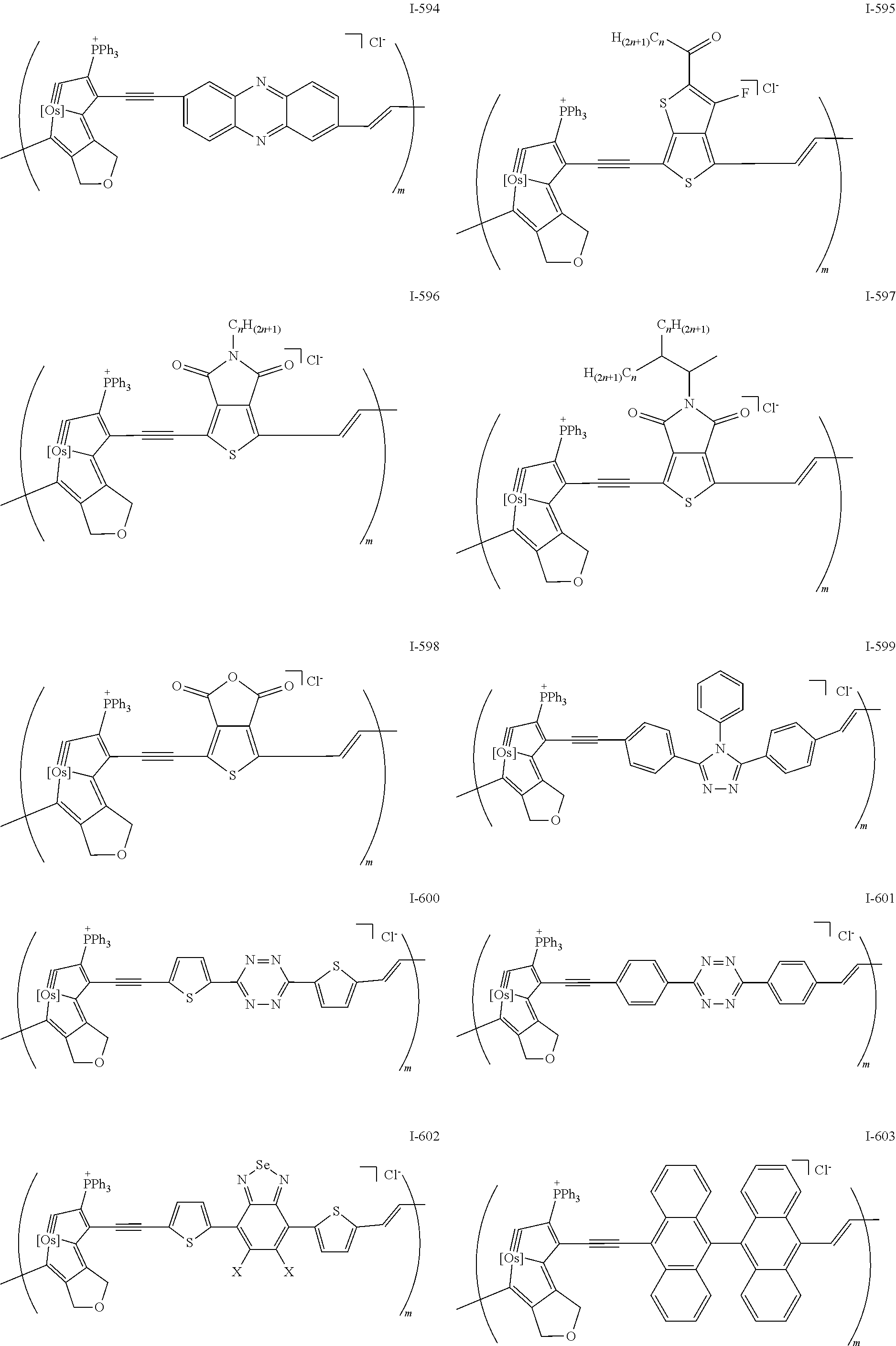 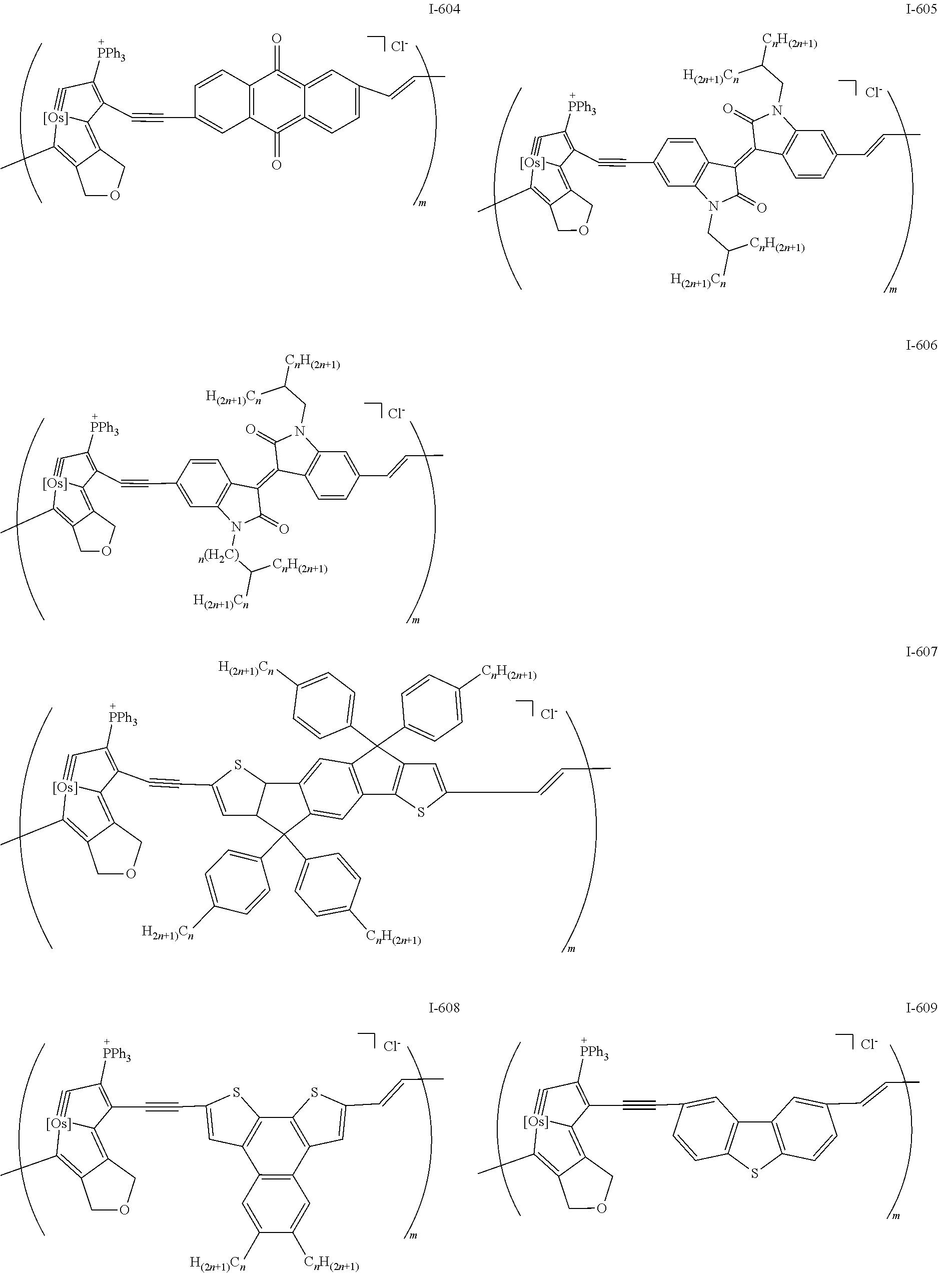 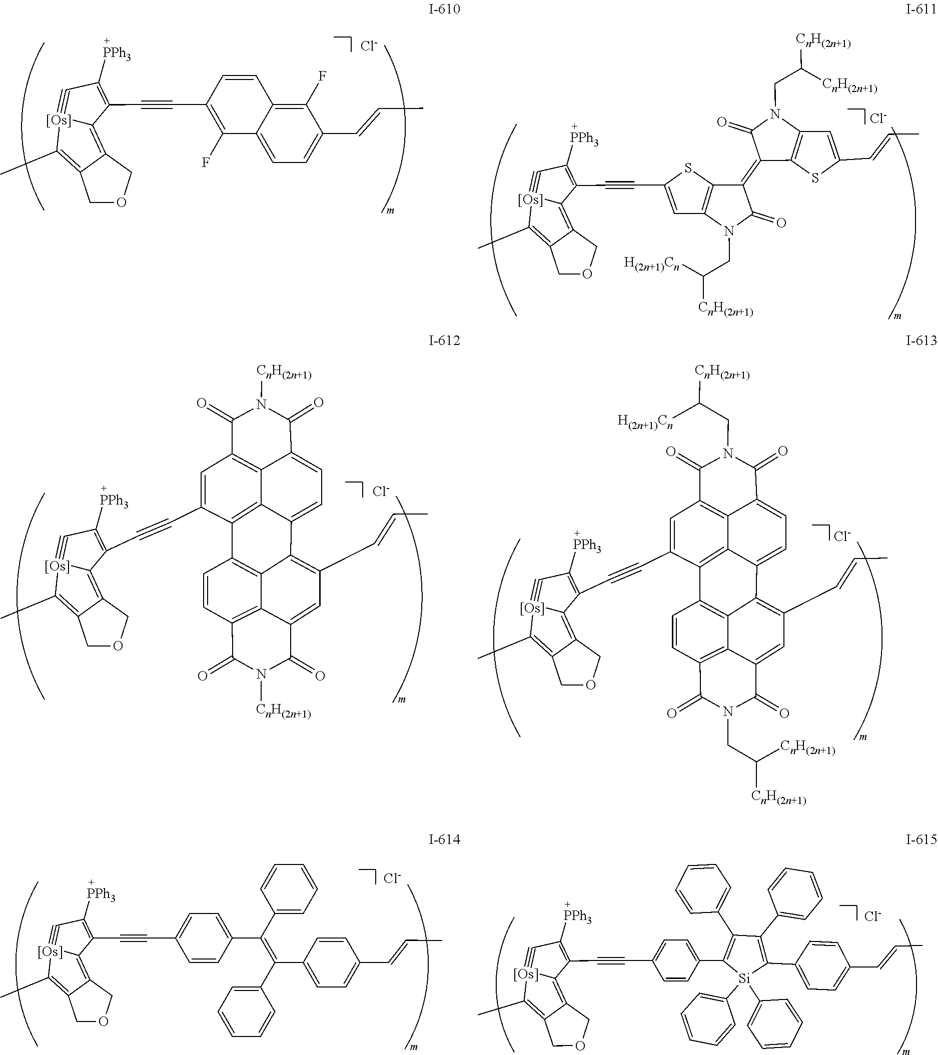 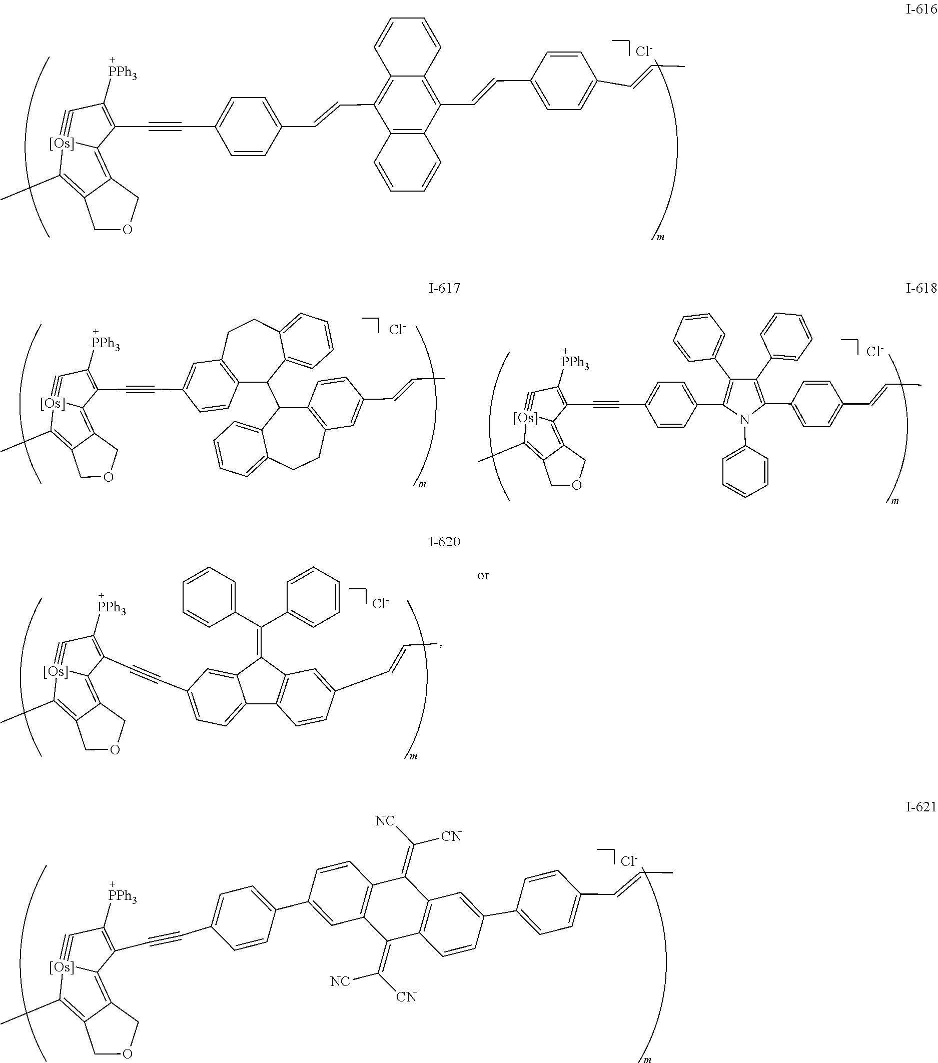
wherein the [Os] is OsCl(PPh₃)₂, n is an integer between 0 and 30, m is an integer between 3 and 300, and X is hydrogen, fluorine, amino, nitro, or alkoxy with 1-32 carbon atoms.

8. A method for preparing the osmium-containing conjugated polymer according to claim 1, comprising:
dissolving a monomer of the osmium-containing conjugated polymer in an organic solvent; and
processing a polymerization reaction under acidic conditions to obtain the osmium-containing conjugated polymer, wherein a reaction formula of the method is as follows:

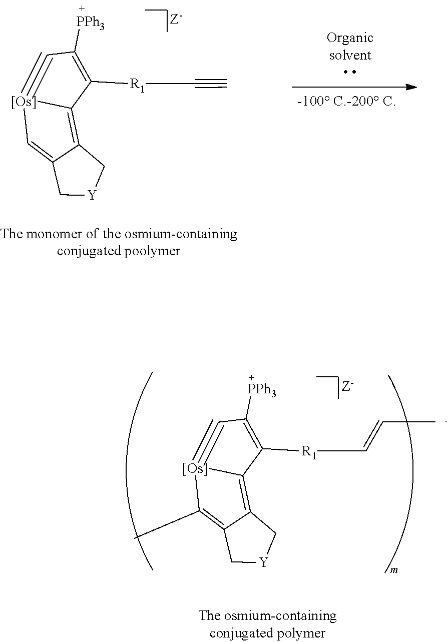

9. The method according to claim 8, wherein:
an acid used in the acidic conditions comprises at least one of an inorganic acid or an organic acid,
the inorganic acid comprises at least one of HClO₄, HI, HBr, HCl, HNO₃, H₂SeO₄, H₂SO₄, HClO₃, H₂C₂O₄, H₂SO₃, H₃PO₄, HNO₂, HF, H₂CO₃, H₂S, HClO, H₃BO₃, or H₂SiO₃, and
the organic acid comprises at least one of CH₃SO₃H, CF₃COOH, CCl₃COOH, CHCl₂COOH, CH₃COOH, or HCOOH.

10. The method according to claim 8, comprising:
terminating the polymerization reaction by a terminal alkyne substituted with a substituent of 2-80 carbon atoms, wherein the substituent comprises at least one of a third substituted aryl group, a third unsubstituted aryl group, a substituted alkyl group, an unsubstituted alkyl group, a substituted cycloalkyl group, or an unsubstituted cycloalkyl group.

11. A method, comprising:
using the osmium-containing conjugated polymer according to claim 1 in organic optoelectronic devices.

12. A main chain comprising an osmapentalyne-containing conjugated polymer, wherein:
a repeating unit of the osmapentalyne-containing conjugated polymer consists of a first group and a second group,
the first group consists of a diosmapentalyne compound bridged with a conjugated linking group R₁,
the second group consists of a divinyl group bridged with a conjugated linking group R₂,
a specific structural formula of the repeating unit is as follows: 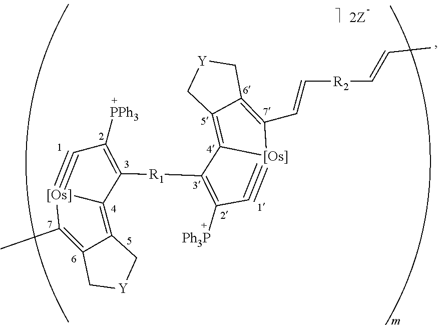
a 3rd position and a 3′rd position in the repeating unit are connected by the conjugated linking group R₁,
the divinyl group is connected to a 7th position and a 7′th position of the bis-diosmapentalyne compound;
the [Os] is OsAL₂, wherein A is at least one of —H, halogen, —SCN, or —CN, and L is at least one of a phosphine ligand, a CO ligand, a pyridine ligand, a nitrile ligand, or an isocyanide two-electron ligand,
the Y is at least one of CH₂, O, or C(COO(CH₂)ₖMe)₂, and k is an integer between 0 and 18,
the conjugated linking group R₁ is at least one of a first substituted aryl group, a first unsubstituted aryl group, a substituted alkenyl group, an unsubstituted alkenyl group, a substituted alkynyl group, or an unsubstituted alkynyl group, wherein a substituted vinyl group or an unsubstituted vinyl group is a trans vinyl group when the substituted alkenyl group or the unsubstituted alkenyl group is the substituted vinyl group or the unsubstituted vinyl group,
the conjugated linking group R₂ is at least one of the first substituted aryl group, the first unsubstituted aryl group, the substituted alkenyl group, the unsubstituted alkenyl group, the substituted alkynyl group, or the unsubstituted alkynyl group, wherein the substituted vinyl group or the unsubstituted vinyl group is the trans vinyl group when the substituted alkenyl group or the unsubstituted alkenyl group is the substituted vinyl group or the unsubstituted vinyl group,
the Z⁻ is an anion, and
the m is an integer between 3 and 300.

13. The main chain comprising the osmapentalyne-containing conjugated polymer according to claim 12, wherein the anion comprises at least one of F⁻, Cl⁻, Br⁻, I⁻, BF₄⁻, H₂PO₄⁻, C₂O₄²⁻, SO₄²⁻, CF₃SO₃⁻, CH₃COO⁻, (CF₃SO₂)₂N⁻, NO₃⁻, ClO₄⁻, PF₆⁻ or BPh₄⁻.

14. The main chain comprising the osmapentalyne-containing conjugated polymer according to claim 12, wherein:
the L in the [Os] is at least one of triphenylphosphine, trimethylphosphine, triethylphosphine, tripropylphosphine, triisopropylphosphine, tri-tert-butylphosphine, tricyclohexylphosphine, methylpyridine, ethylpyridine, 1,4-bipyridine, 1,2-bis(4-pyridyl)ethylene, vinylpyridine, ethynyl Pyridine, pyridine boronic acid, aminopyridine, cyanopyridine, mercaptopyridine, dimethylaminopyridine, phenylpyridine, 1,2-bis(4-pyridyl)ethane, acetonitrile, propionitrile, benzonitrile, cyclohexyl isocyanide, tert-butyl isocyanide, or phenyl isocyanide, or
the L₂ in the [Os] is integrated, and L₂ is at least one of ethylenediamine, 2,2′-bipyridine, 1,10-phenanthroline, 1,1-bis(diphenylphosphine)methane, 1,2-bis (diphenylphosphine)ethane, 1,3-bis(diphenylphosphine)propane, ortho-phenylpyridine, 8-hydroxyquinoline, or terpyridine.

15. The main chain comprising the osmapentalyne-containing conjugated polymer according to claim 12, wherein:
the substituted aryl group or the unsubstituted aryl group is at least one of phenyl, diphenyl, terphenyl, naphthyl, anthryl, fiki, pyrene, thienyl, dithienyl, terthienyl, dithienylethene, thiazolyl, thiadiazolyl, bis-thiadiazolyl, bis-terthienyl, furanyl, pyridyl, pyrrolyl, porphyrin, fluorenyl, bifluorenyl, terfluorenyl, carbazolyl, bicarbazolyl, tercarbazolyl, benzothiadiazolyl, tetrastyryl, hexabenzocoronyl, diketopyrrolopyrrole-based, benzodithienyl, indacenodithienyl, silyl fluorenyl, dithienocyclodecadiene, dithienosilole-based, dithienopyrrole-based, triphenylamino, naphthalenedithiadiazolyl, naphthalenetetracarboxylic diimide-based, perylenetetracarboxylic diimide-based, isoindigo-based, thienopyrroledione-based, benzopyrroledione-based, benzotriazolyl, thiadiazolobenzotriazolyl, pyridothiadiazolyl, or thieno[3,4-b]thienyl, and
a substituent of the substituted aryl group or the unsubstituted aryl group comprises at least one of an alkyl with 1-28 carbon atoms, an alkoxy with 1-20 carbon atoms, an alkylthio with 1-20 carbon atoms, an acyl with 1-20 carbon atoms, an ester with 1-20 carbon atoms, an amino with 1-20 carbon atoms, an amide with 1-20 carbon atoms, an amide substituted with 2-20 carbon atoms, a cycloalkyl with 3-20 carbon atoms, an alkenyl with 1-20 carbon atoms, an alkynyl with 1-20 carbon atoms, nitro, cyano, or halogen.

16. The main chain comprising the osmapentalyne-containing conjugated polymer according to claim 12, wherein:
the A in the [Os] is at least one of H, F, Cl, Br, or SCN,
the L in the [Os] is at least one of a CO ligand, a triphenylphosphine ligand, a trimethylphosphine ligand, or a triethylphosphine ligand,
the Z⁻ is at least one of Cl⁻, Br⁻, BF₄⁻, CF₃SO₃⁻, PF₆⁻, or BPh₄⁻,
the conjugated linking group R₁ is at least one of 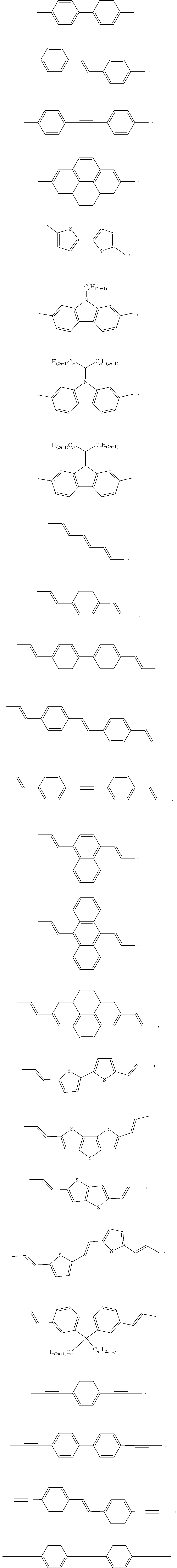 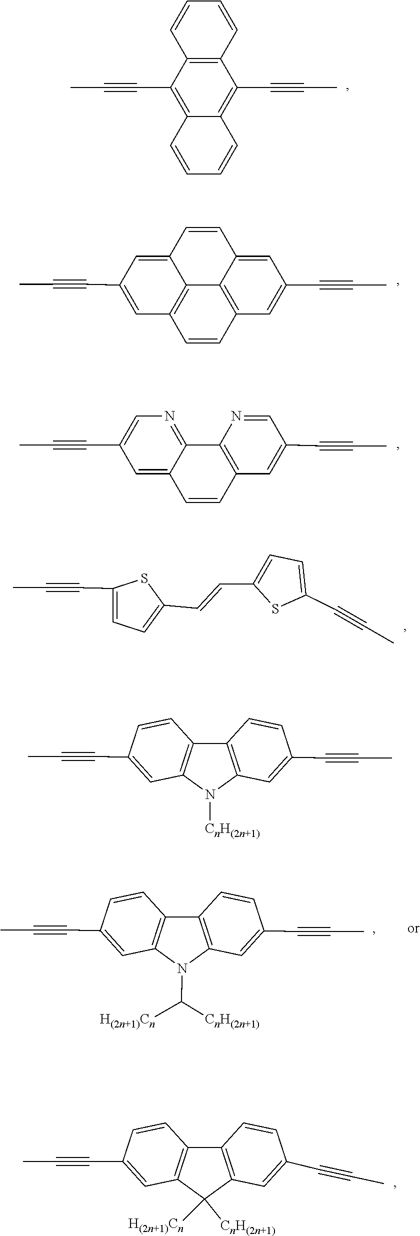
wherein n is an integer between 0 and 30,
the conjugated linking group R₂ is at least one of 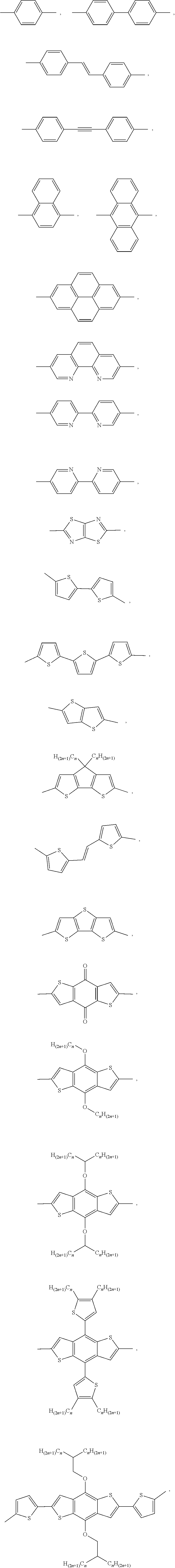 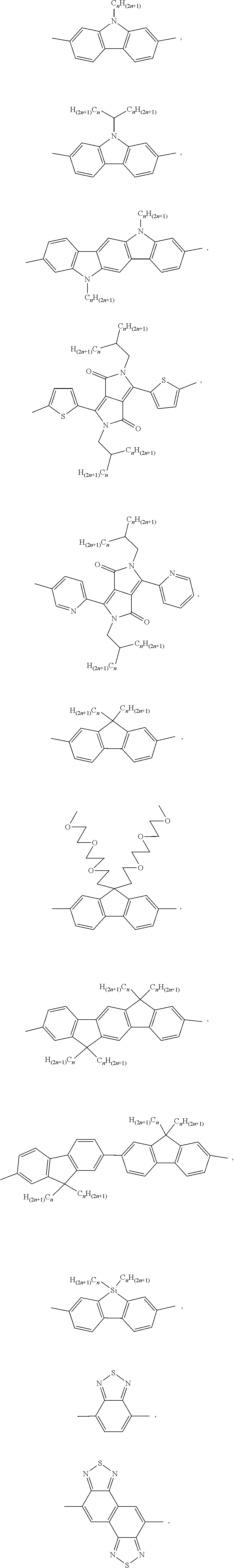 [chemical structure] 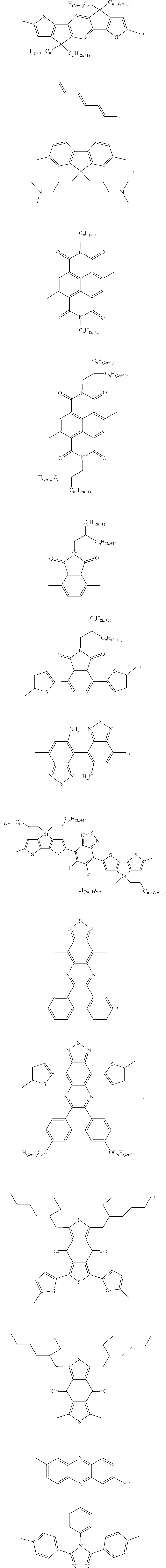 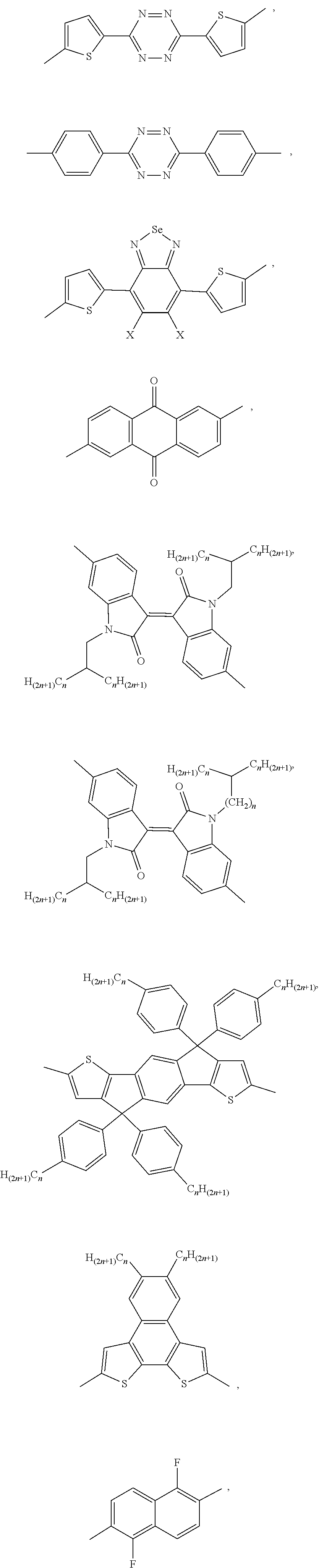 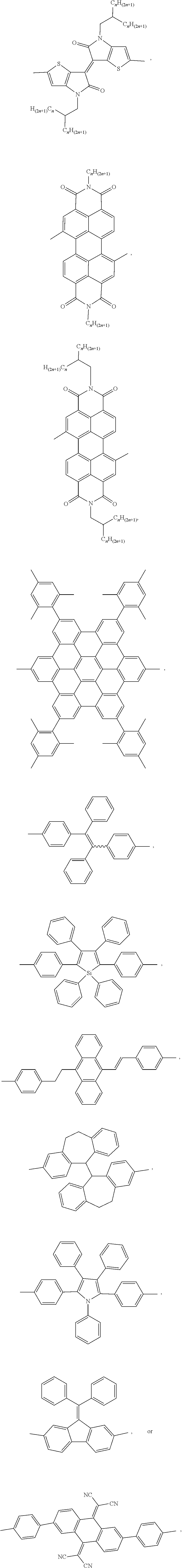
n is an integer between 0 and 30, and X is at least one of hydrogen, fluorine, amino, nitro, or alkoxy with 1-32 carbon atoms.

17. The main chain comprising an osmapentalyne-containing conjugated polymer according to claim 12, wherein:
the main chain comprising an osmapentalyne-containing conjugated polymer is one of: 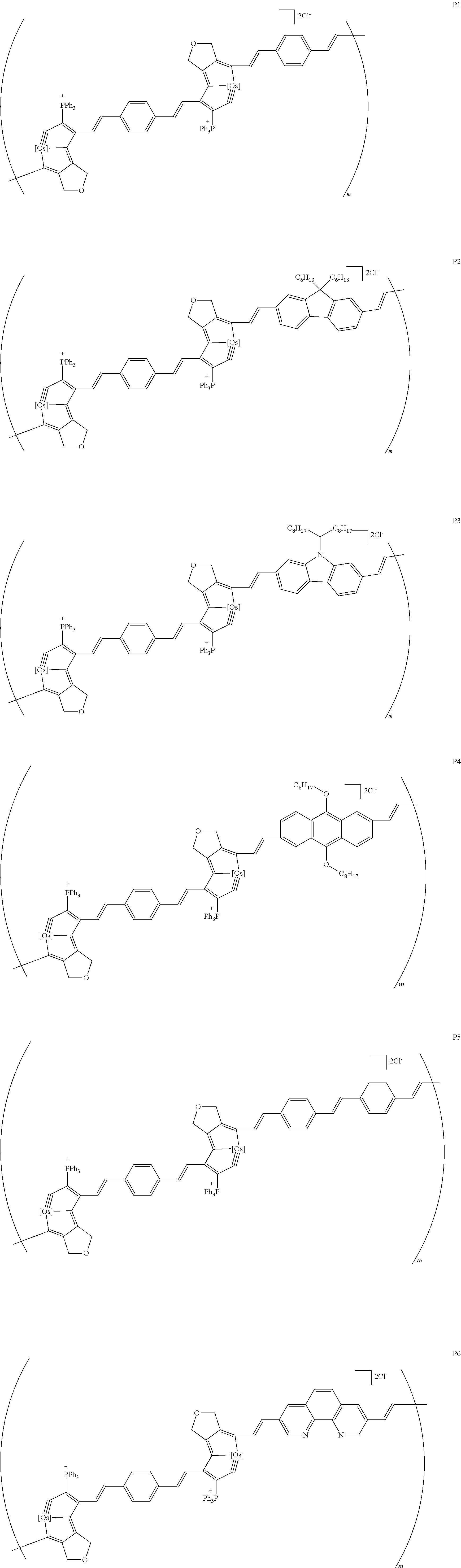 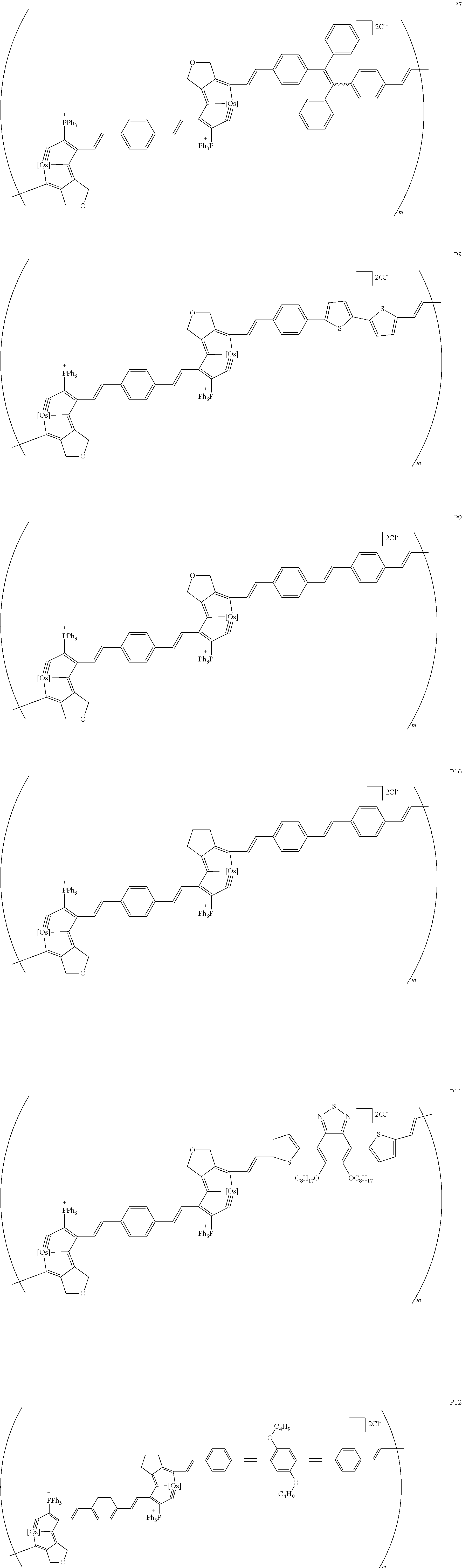 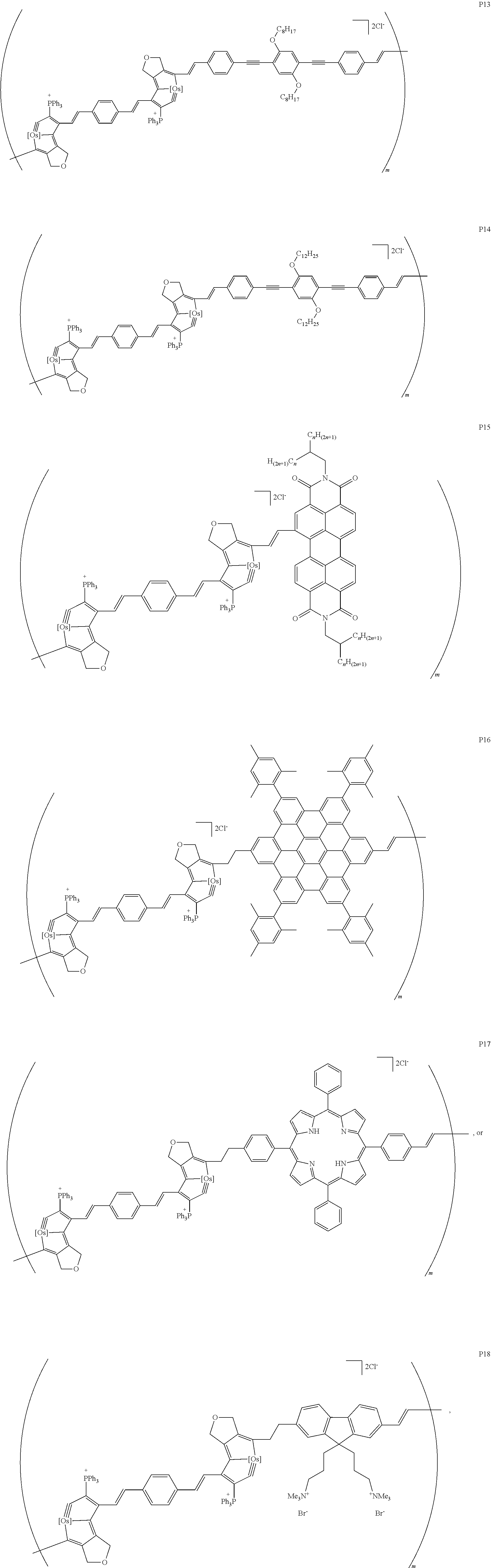
the [Os] is OsCl(PPh₃)₂, n is an integer between 0 and 30, and m is an integer between 3 and 300.

18. A method for preparing the main chain comprising the osmapentalyne-containing conjugated polymer according to claim 12, comprising:
dissolving bimetallic heterocyclic osmium heteropentylene and diacetylene monomers in an organic solvent, and a polymerization reaction occurs under acidic conditions to obtain the main chain comprising the osmapentalyne-containing conjugated polymer; the reaction formula is as follows:

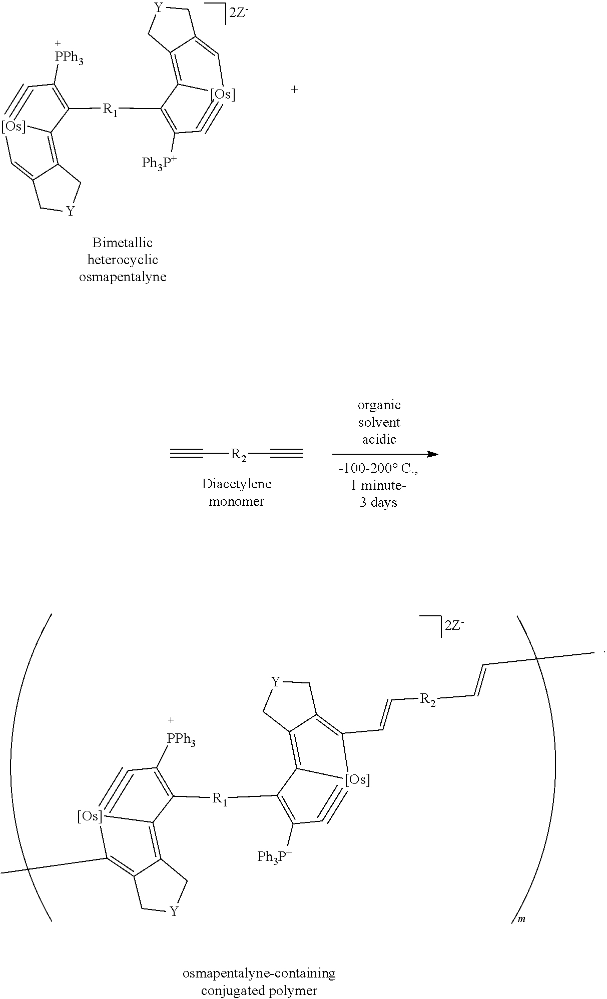

19. The method according to claim 18, wherein:
an acid used in the acidic conditions comprises at least one of an inorganic acid or an organic acid,
when the acid is the inorganic acid, the inorganic acid comprises at least one of HClO₄, HI, HBr, HCl, HNO₃, H₂SeO₄, H₂SO₄, HClO₃, H₂C₂O₄, H₂SO₃, H₃PO₄, HNO₂, HF, H₂CO₃, H₂S, HClO, H₃BO₃, or H₂SiO₃, and
when the acid is the organic acid, the organic acid comprises at least one of CH₃SO₃H, CF₃COOH, CCl₃COOH, CHCl₂COOH, CH₃COOH, or HCOOH.

20. A method for using the main chain comprising the osmapentalyne-containing conjugated polymer according to claim 12, comprising:
applying the main chain comprising the osmapentalyne-containing conjugated polymer in preparing organic optoelectronic devices.
